(19) United States
(12) Patent Application Publication
(10) Pub. No.: US 2024/0298515 A1
(43) Pub. Date: Sep. 5, 2024

(54) TETRADENTATE PLATINUM AND PALLADIUM COMPLEXES BASED ON BISCARBAZOLE AND ANALOGUES

(71) Applicant: Arizona Board of Regents on behalf of Arizona State University, Scottsdale, AZ (US)

(72) Inventors: Jian Li, Tempe, AZ (US); Zhi-Qiang Zhu, Mesa, AZ (US)

(21) Appl. No.: 18/634,083

(22) Filed: Apr. 12, 2024

Related U.S. Application Data
(63) Continuation of application No. 17/379,067, filed on Jul. 19, 2021, now Pat. No. 11,974,495.
Application No. 17/379,067 is a continuation of application No. 15/984,036, filed on May 18, 2018, now Pat. No. 11,101,435.
(60) Provisional application No. 62/508,849, filed on May 19, 2017.

(51) Int. Cl. H10K 85/30; C07F 15/00; C09K 11/06; H10K 50/11; H10K 101/10

(52) U.S. Cl. CPC H10K 85/341; C07F 15/006; C07F 15/0086; C09K 11/06; H10K 85/346; C09K 2211/1029; C09K 2211/1033; C09K 2211/1037; C09K 2211/1044; C09K 2211/185; H10K 50/11; H10K 2101/10

(57) ABSTRACT

Tetradentate platinum and palladium complexes based on biscarbazole and analogues for full color displays and lighting applications.

### CROSS-REFERENCE TO RELATED APPLICATION

This application claims the benefit of U.S. Patent Application No. 62/508,849 entitled “TETRADENTATE PLATINUM AND PALLADIUM COMPLEXES BASED ON BISCARBAZOLE AND ANALOGUES” and filed on May 19, 2017, which is incorporated by reference herein in its entirety.

### TECHNICAL FIELD

This invention relates to tetradentate platinum and palladium complexes based on biscarbazole and analogues for full color displays and lighting applications.

### BACKGROUND

Compounds capable of absorbing or emitting light can be used in a variety of optical and electro-optical devices, including photo-absorbing devices (e.g., solar- and photo-sensitive devices), photo-emitting devices, organic light-emitting diodes (OLEDs), and devices capable of photo-absorption and photo-emission. Much research has been devoted to the discovery and optimization of organic and organometallic materials for use in optical and electro-optical devices. Metal complexes can be used for many applications, such as emitters for OLEDs. Despite advances in research devoted to optical and electro-optical materials, many currently available materials exhibit a number of disadvantages, including poor processing ability, inefficient emission or absorption, and insufficient stability.

### SUMMARY

Tetradentate platinum and palladium complexes based on biscarbazole and analogues for full color displays and lighting applications are shown in General Formulas I-VI.

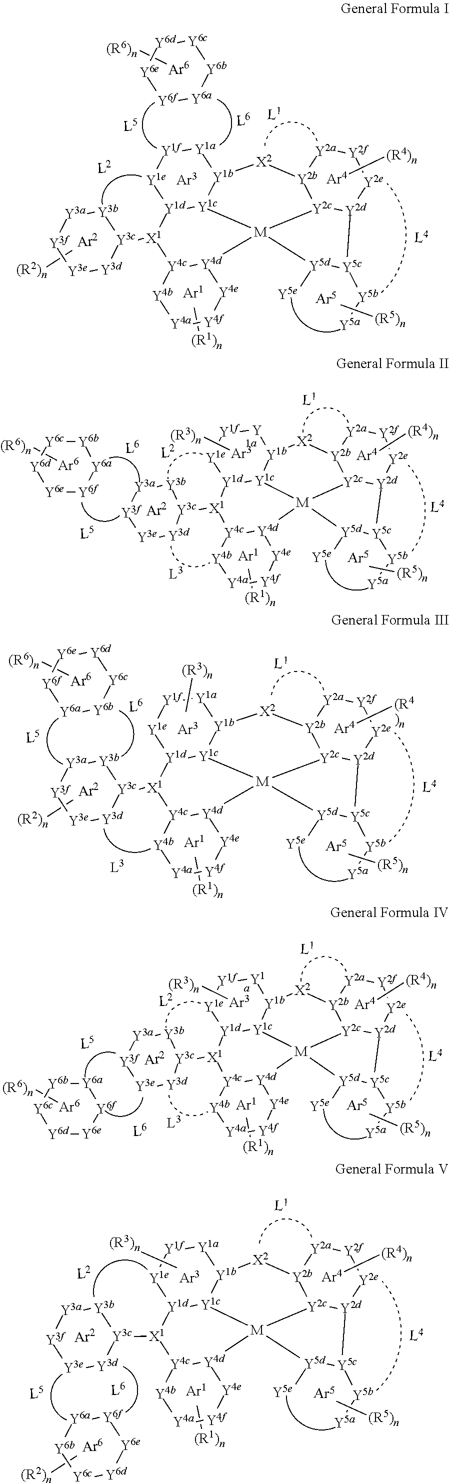

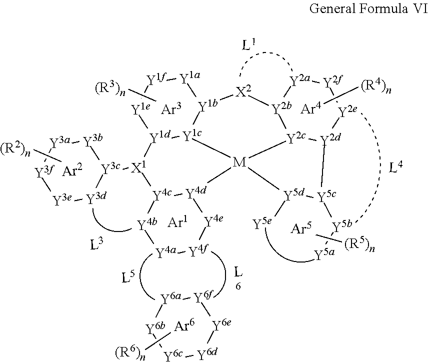

### In General Formulas I-VI,

M is Pt²⁺ or Pd²⁺,
each R¹, R², R³, R⁴, R⁵, and R⁶ independently represents hydrogen, halogen, hydroxy, amino, nitro, cyanide, thiol, or optionally substituted C₁-C₄ alkyl, alkoxy, or aryl,
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{3a}, Y^{3b}, Y^{3c}, Y^{3d}, Y^{3e}, Y^{3f}, Y^{4a}, Y^{4b}, Y^{4c}, Y^{4d}, Y^{4e}, Y^{4f}, Y^{5a}, Y^{5b}, Y^{5c}, Y^{5d}, Y^{5e}, Y^{5f}, Y^{6a}, Y^{6b}, Y^{6c}, Y^{6d}, Y^{6e}, and Y^{6f} each independently represents C, N, Si, O, or S,
each of X¹ and X² is present or absent, and each X¹ and X² present independently represents a single bond, NR, PR, CRR′, SiRR′, CRR′, SiRR′, O, S, S═O, O═S═O, Se, Se═O, or O═Se═O, and wherein R and R′ each independently represents hydrogen, cyanide, halogen, hydroxy, amino, nitro, thiol, or optionally substituted C₁-C₄ alkyl, alkoxy, aryl,
L¹, L², L³, L⁴, L⁵, and L⁶, where indicated by a solid line is present, and where indicated by a dashed line is each independently present or absent, and each of L¹, L², L³, L⁴, L⁵, and L⁶ present independently represents a substituted (valency permitting) or unsubstituted linking atom or group comprising alkyl, alkoxy, alkenyl, alkynyl, hydroxy, amine, amide, thiol, aryl, heteroaryl, cycloalkyl, and heterocyclyl moieties,
each Ar¹, Ar², Ar³, Ar⁴, Ar⁵, and Ar⁶ present is independently an aryl group, and
each n is independently an integer, valency permitting.

Implementations also include a light emitting diode including a complex of General Formulas I-VI and a light emitting device including the light emitting diode.

These general and specific aspects may be implemented using a device, system or method, or any combination of devices, systems, or methods. The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 depicts a cross-sectional view of an organic light emitting diode (OLED).

FIG. 2 shows PL spectra of PdON3N56, prepared as described in Example 9, measured in CH₂Cl₂ at room temperature and in 2-MeTHF at 77K.

FIG. 3 shows PL spectra of PdON8N56tBu, prepared as described in Example 12, measured in CH₂Cl₂ at room temperature and in 2-MeTHF at 77K.

FIG. 4 shows PL spectra of PdON3N54, prepared as described in Example 13, measured in CH₂Cl₂ at room temperature and in 2-MeTHF at 77K.

FIGS. 5A and 5B show an electroluminescence (EL) spectrum and a plot of EQE vs. luminance, respectively, of PdON3S56 in the device structure described in Example 14.

FIG. 6 shows PL spectra of PdON3S56, prepared as described in Example 14, measured in CH₂Cl₂ at room temperature and in 2-MeTHF at 77K.

### DETAILED DESCRIPTION

General Formulas I-VI represent biscarbazole-based platinum (II) and palladium (II) complexes and analogues. These emitters are suitable for full color displays and lighting applications. General Formulas I-VI are shown below.

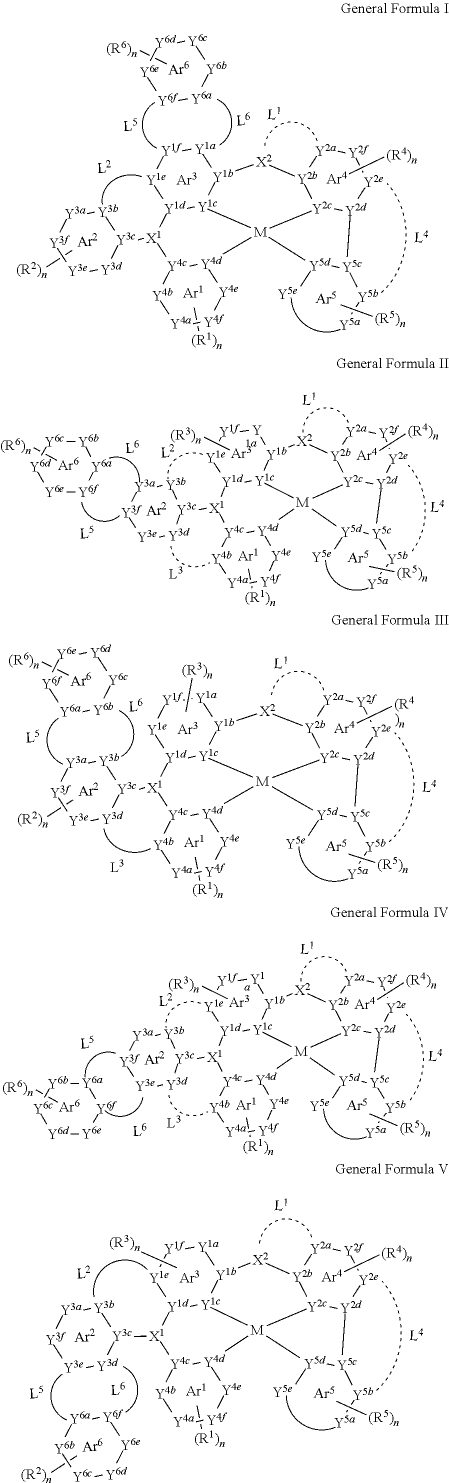

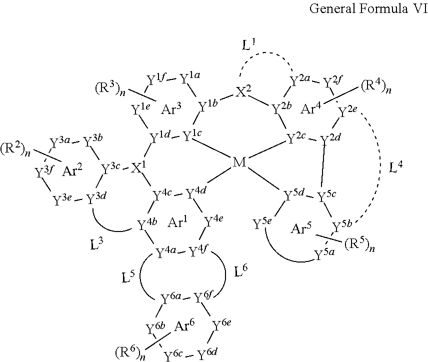

### In General Formulas I-VI:

M is Pt²⁺ or Pd²⁺,
each n independently represents an integer, valency permitting,
each R¹, R², R³, R⁴, R⁵, and R⁶ independently represents hydrogen, halogen, hydroxy, amino, nitro, cyanide, thiol, or optionally substituted C₁-C₄ alkyl, alkoxy, or aryl,
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{3a}, Y^{3b}, Y^{3c}, Y^{3d}, Y^{3e}, Y^{3f}, Y^{4a}, Y^{4b}, Y^{4c}, Y^{4d}, Y^{4e}, Y^{4f}, Y^{5a}, Y^{5b}, Y^{5c}, Y^{5d}, Y^{5e}, Y^{5f}, Y^{6a}, Y^{6b}, Y^{6c}, Y^{6d}, Y^{6e}, and Y^{6f} each independently represents C, N, Si, O, or S,
each of X¹ and X² is present or absent, and each X¹ and X² present independently represents a single bond, NR, PR, CRR′, SiRR′, CRR′, SiRR′, O, S, S═O, O═S═O, Se, Se═O, or O═Se═O, where R and R′ each independently represents hydrogen, cyanide, halogen, hydroxy, amino, nitro, thiol, or optionally substituted C₁-C₄ alkyl, alkoxy, aryl,
L¹, L², L³, L⁴, L⁵, and L⁶, where indicated by a solid line is present, and where indicated by a dashed line is each independently present or absent, and each of L¹, L², L³, L⁴, L⁵, and L⁶ present independently represents a substituted or unsubstituted linking atom or group, valency permitting. Suitable substituents include alkyl, alkoxy, alkenyl, alkynyl, aryl, heteroaryl, cycloalkyl, and heterocyclyl moieties, each Ar¹, Ar², Ar³, Ar⁴, Ar⁵, and Ar⁶ present is independently an aryl group, and each n is independently an integer, valency permitting.

Implementations of General Formulas I-VI are shown below, where

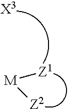

represents one of following chemical moieties:

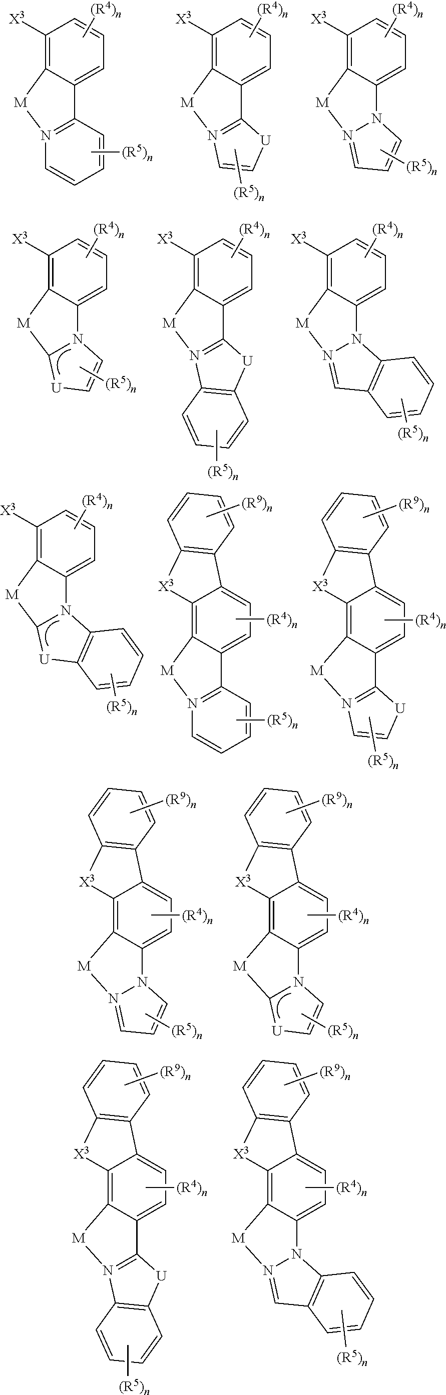

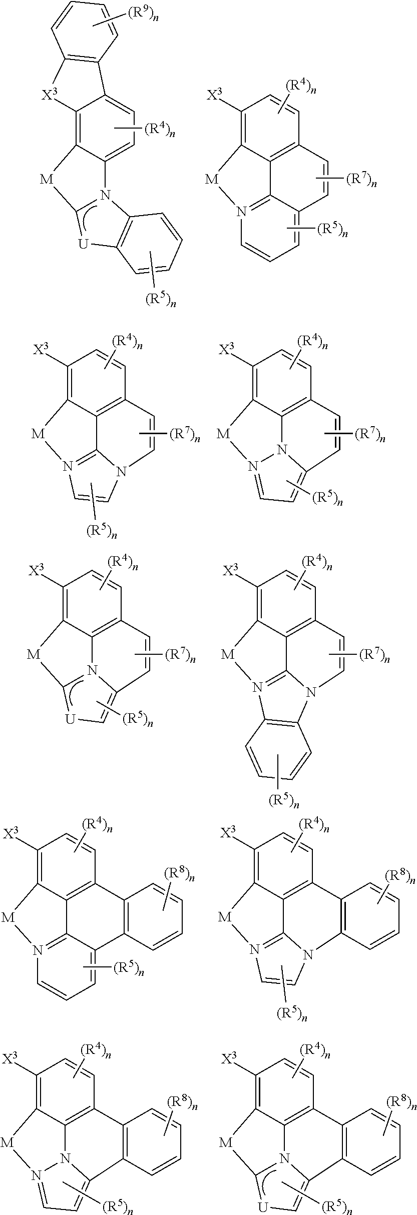

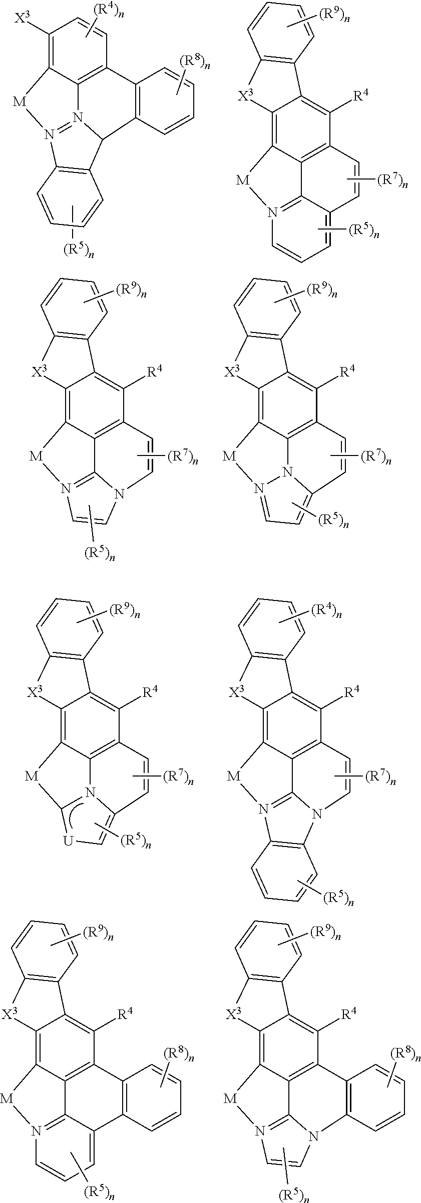

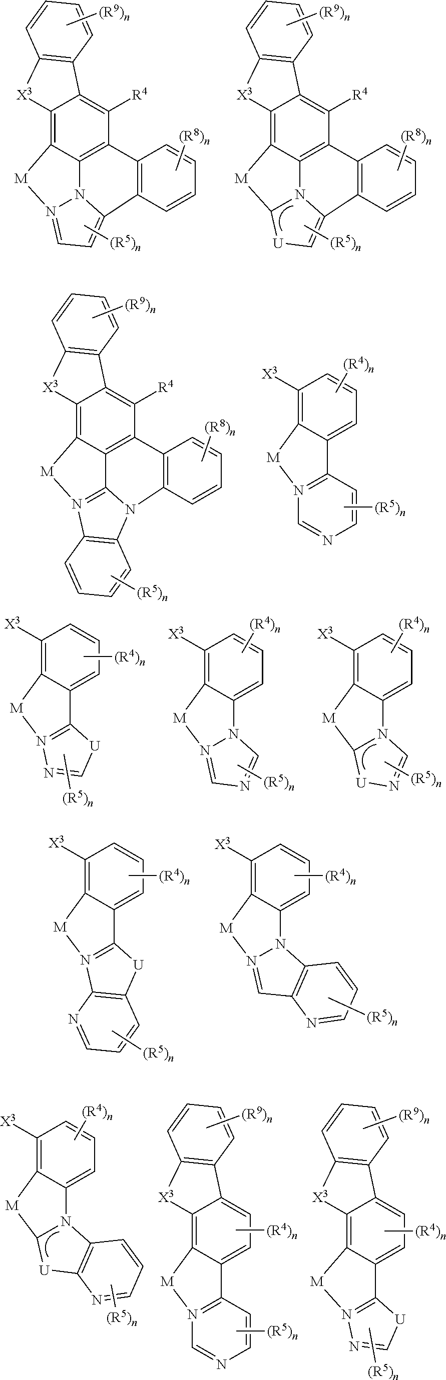

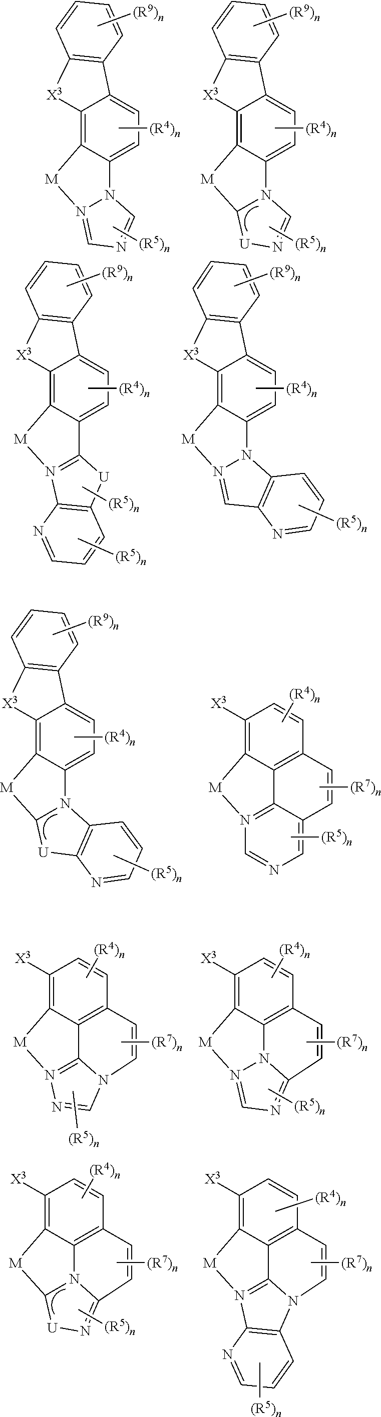

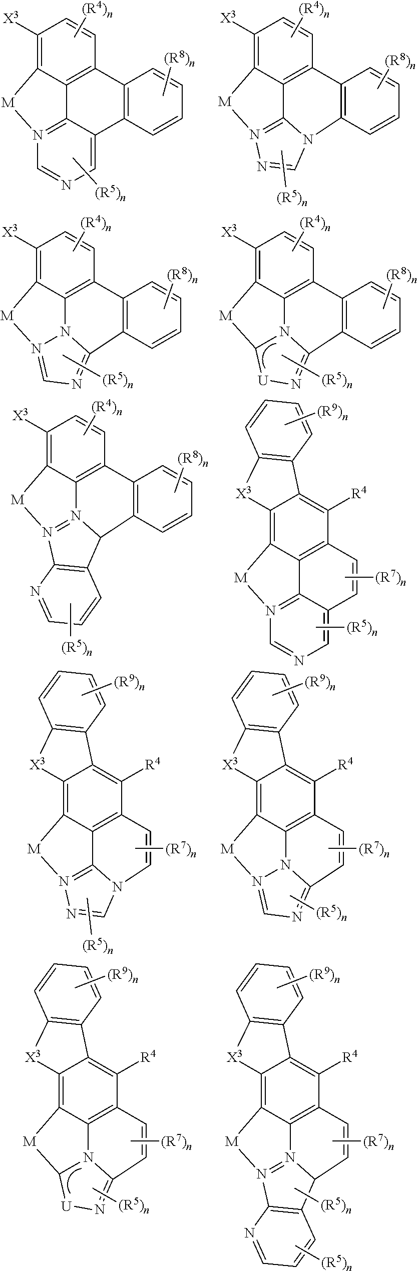

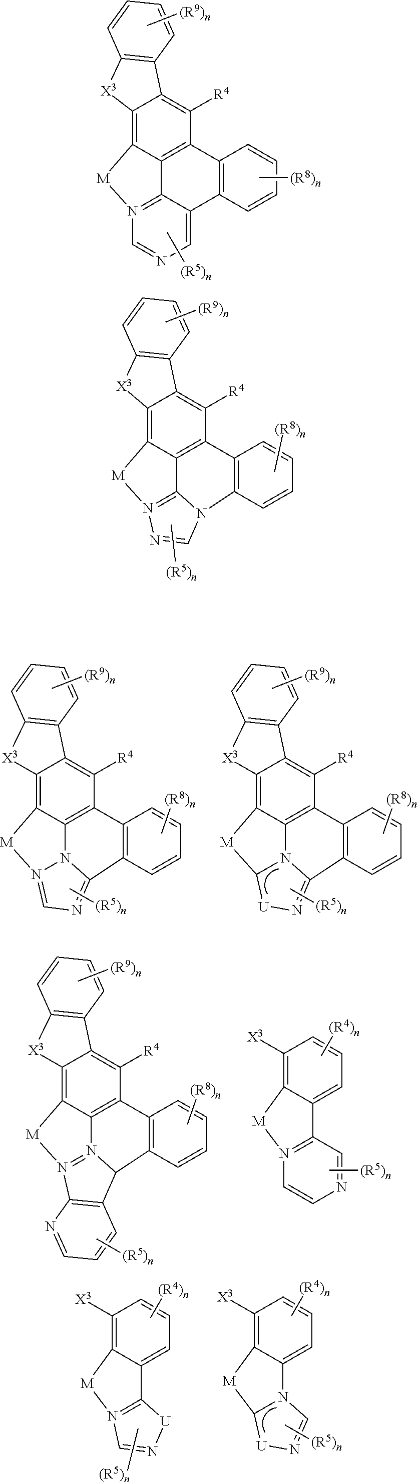

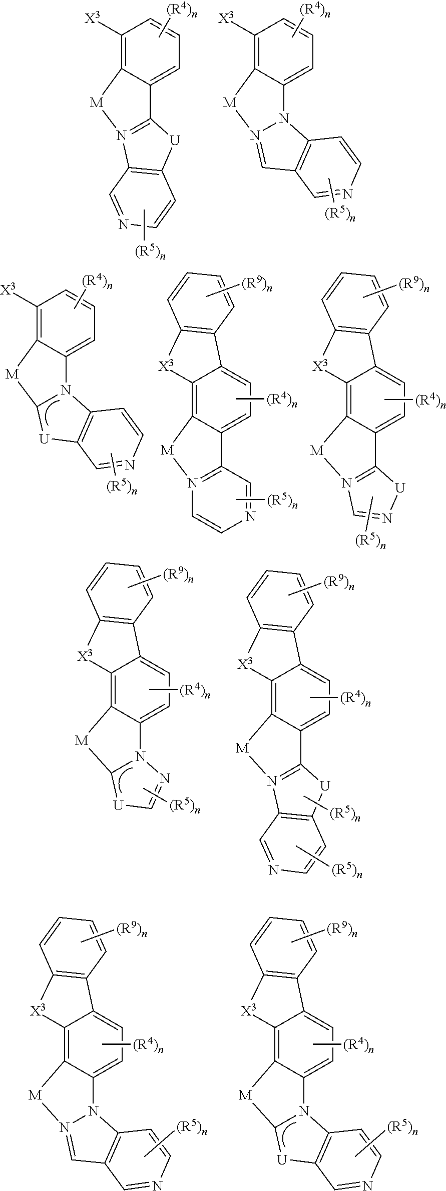

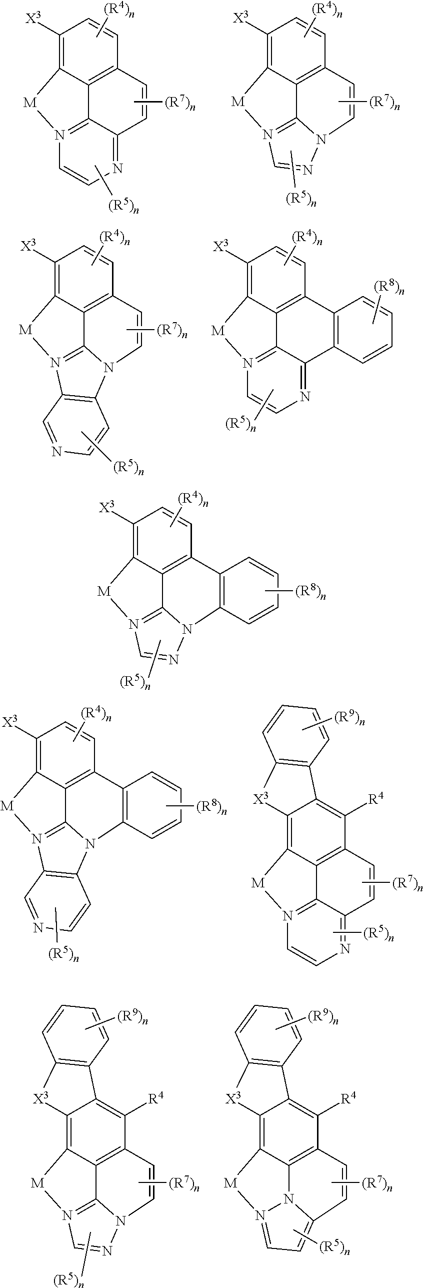

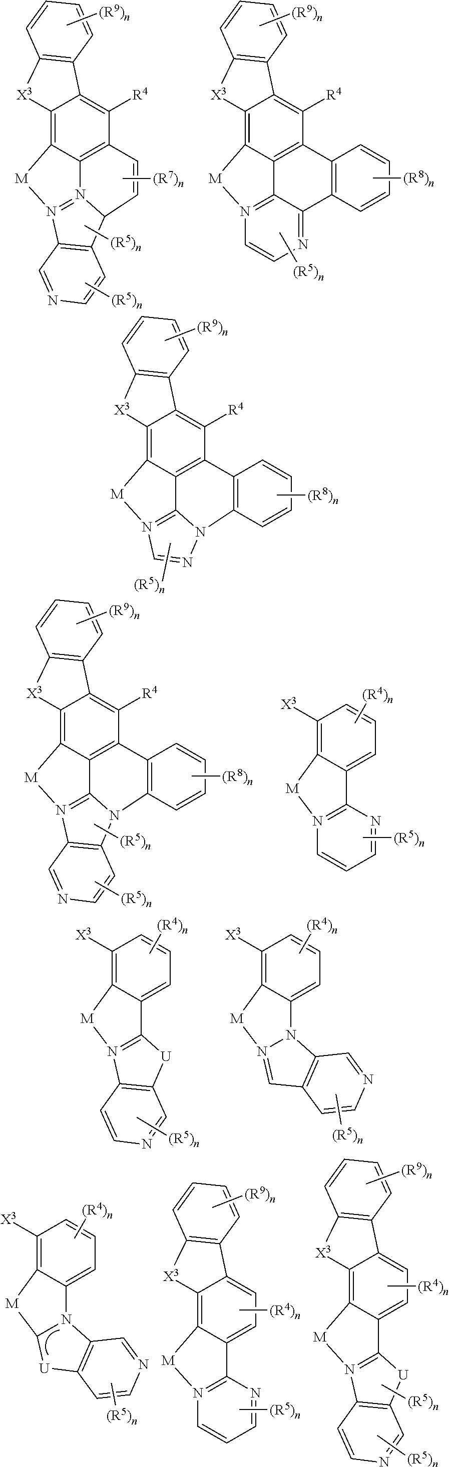

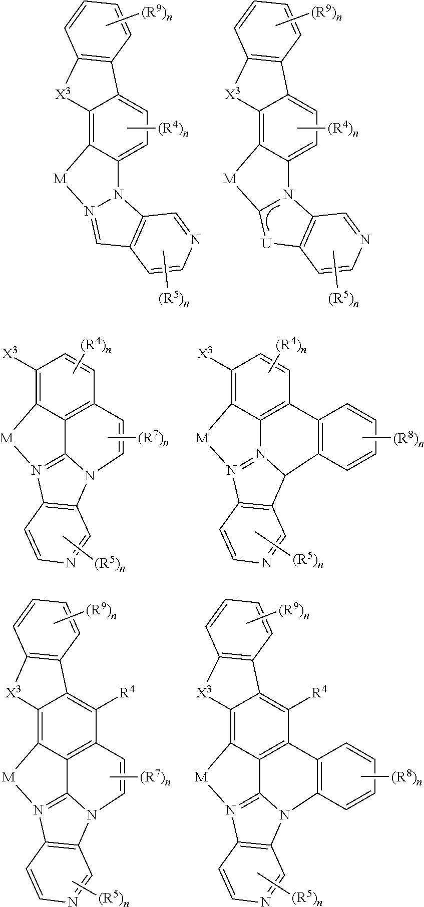

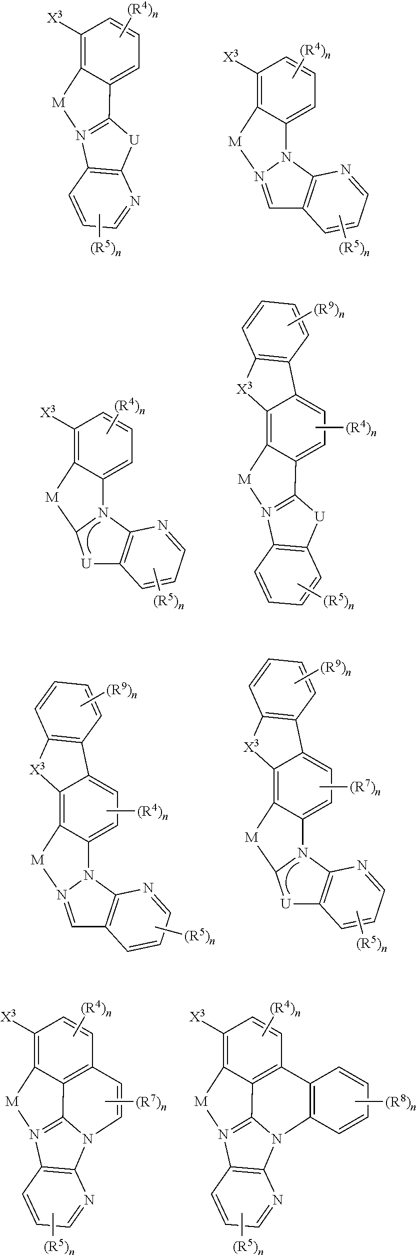

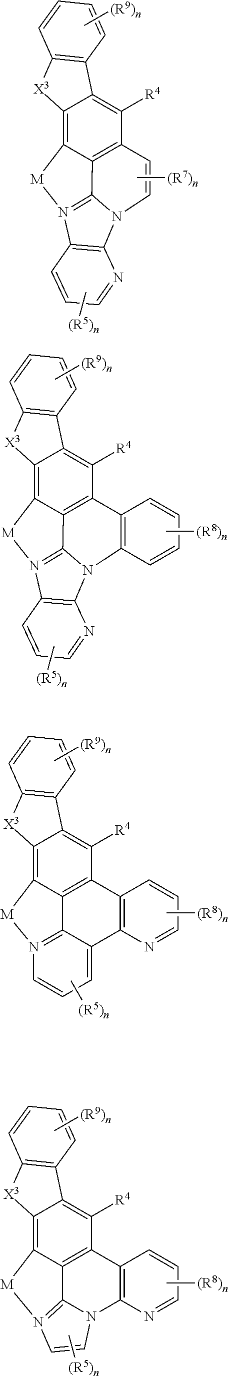

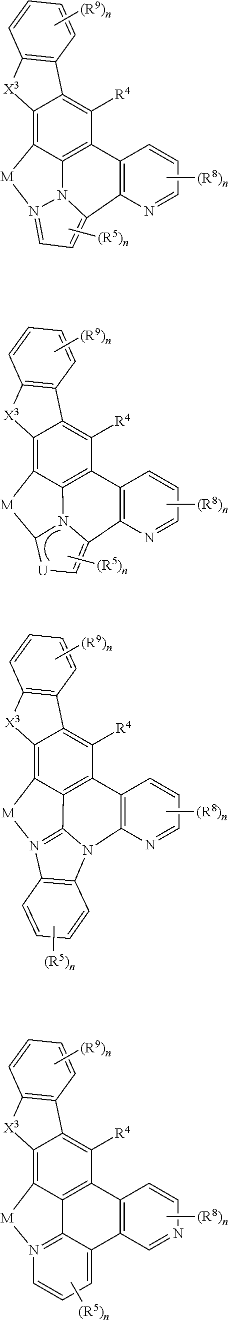

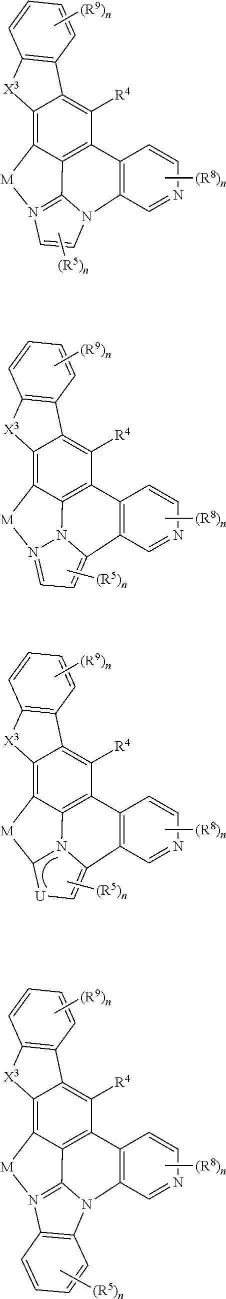

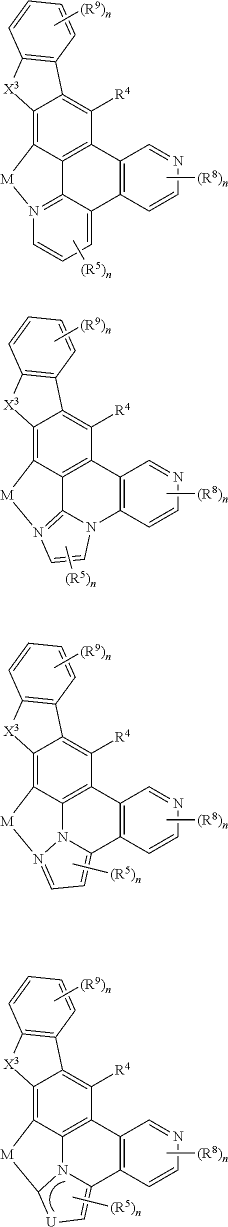

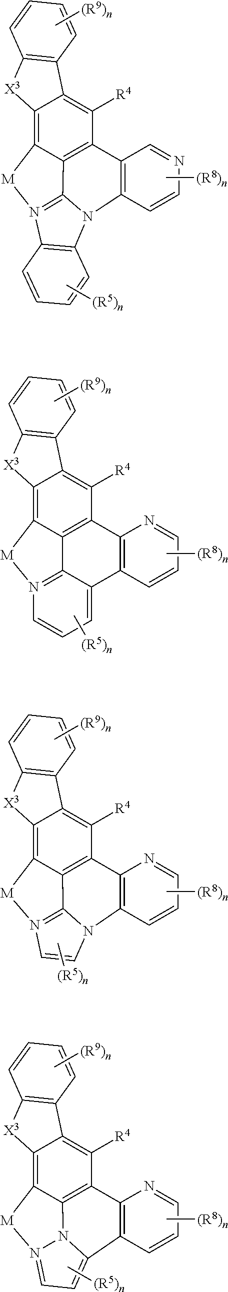

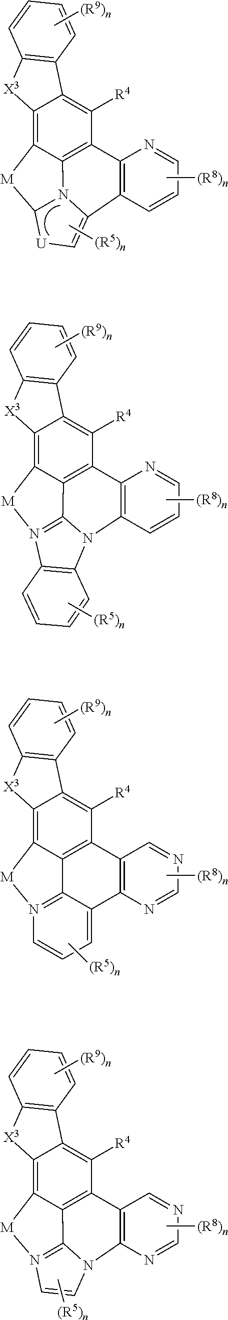

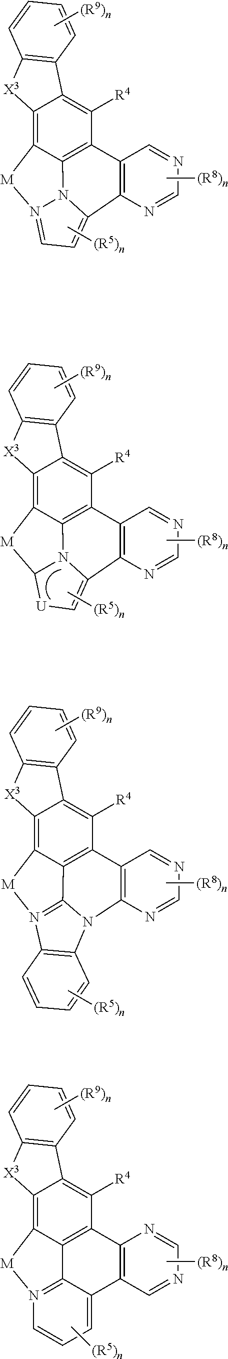

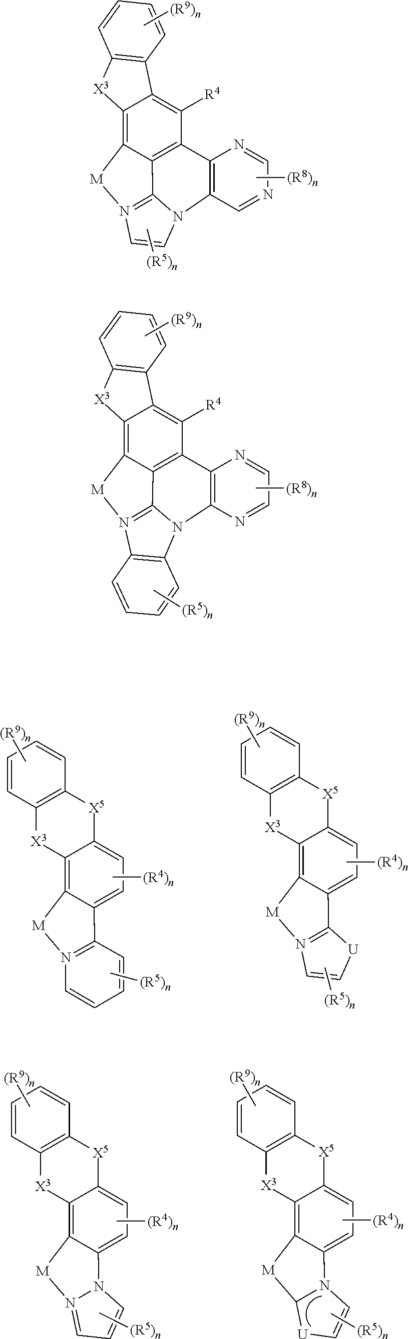

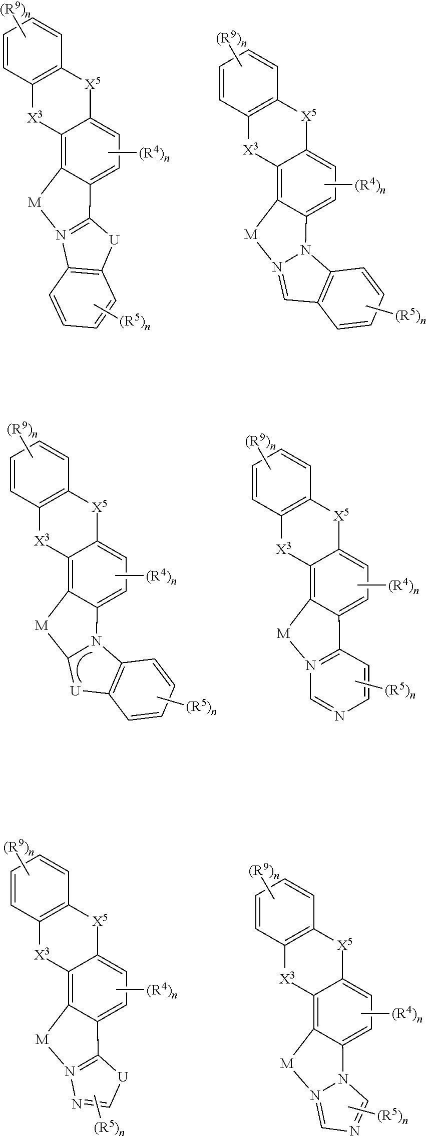

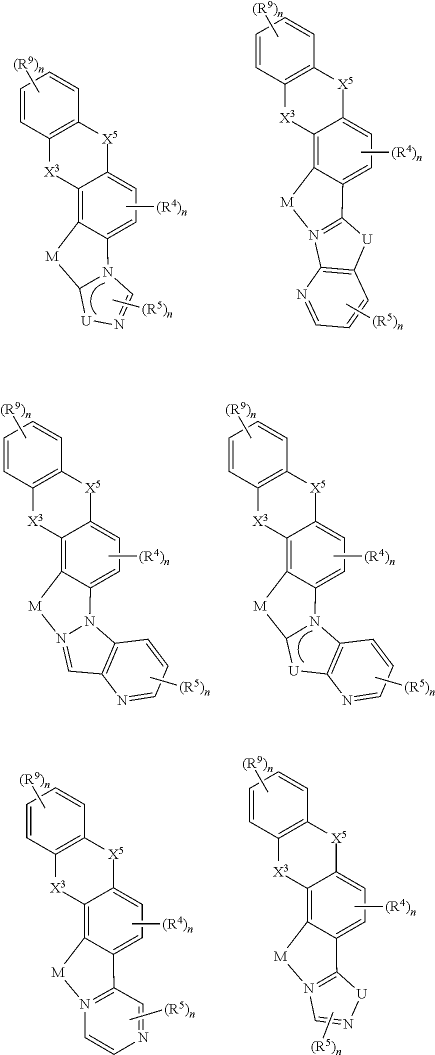

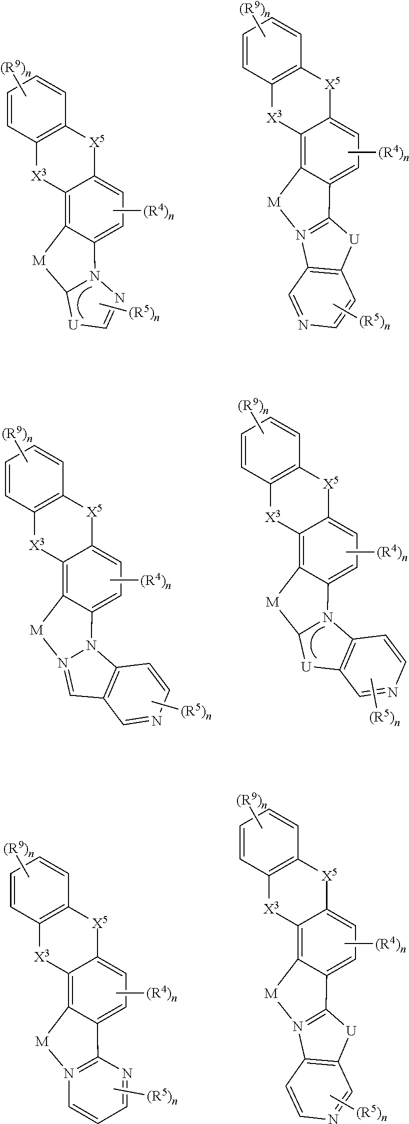

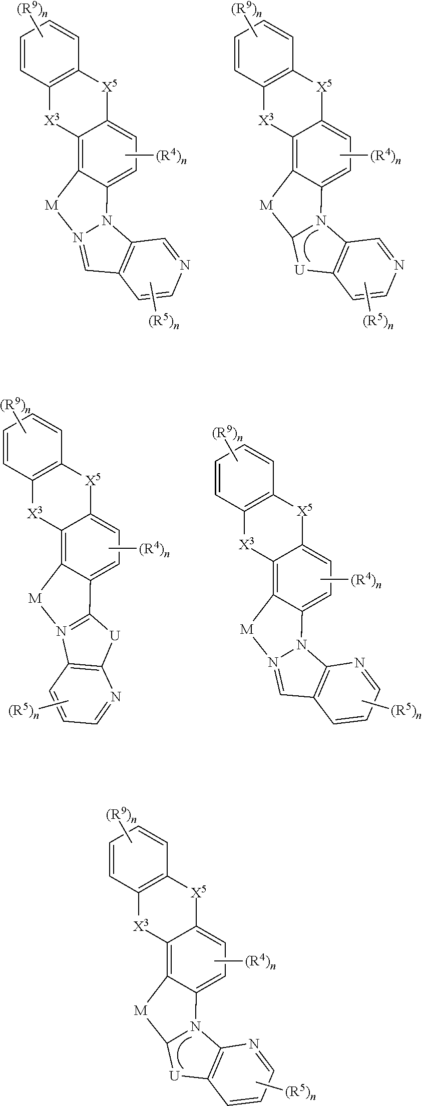

where:
X³ and X⁵ each independently represents NR, PR, CRR′, SiRR′, CRR′, SiRR′, O, S, S═O, O═S═O, Se, Se═O, or O═Se═O, where R and R′ each independently represents hydrogen, cyanide, halogen, hydroxy, amino, nitro, thiol, or optionally substituted C₁-C₄ alkyl, alkoxy, aryl,
R⁴, R⁵, R⁷, R⁸, and R⁹ each independently represents hydrogen, halogen, hydroxy, amino, nitro, cyanide, thiol, and substituted or unsubstituted C₁-C₄ alkyl, alkoxy, or aryl,
U represents O, S, NR, or PR, where R is hydrogen, cyanide, halogen, hydroxy, amino, nitro, thiol, or optionally substituted C₁-C₄ alkyl, alkoxy, aryl, and
each n is independently an integer, valency permitting.

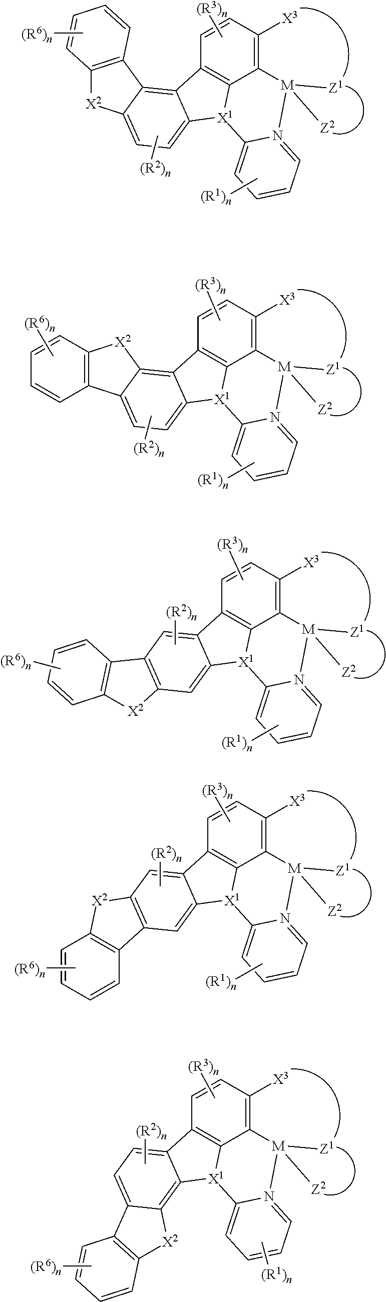

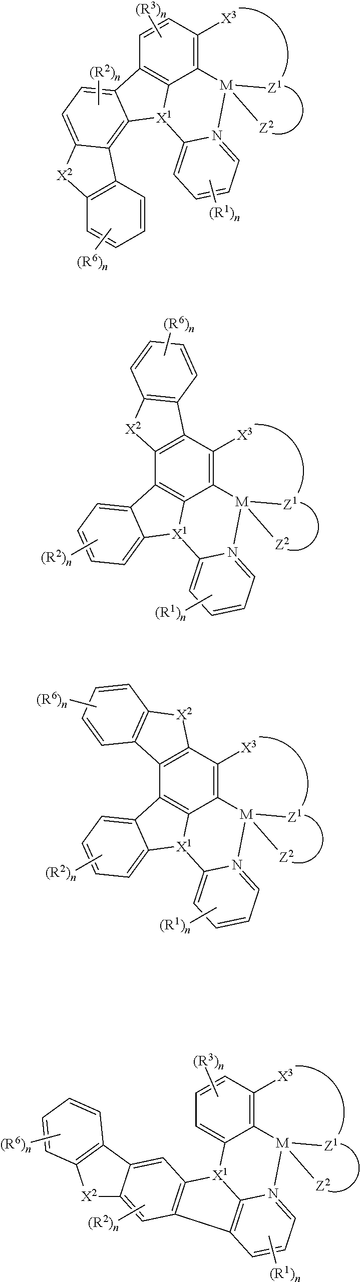

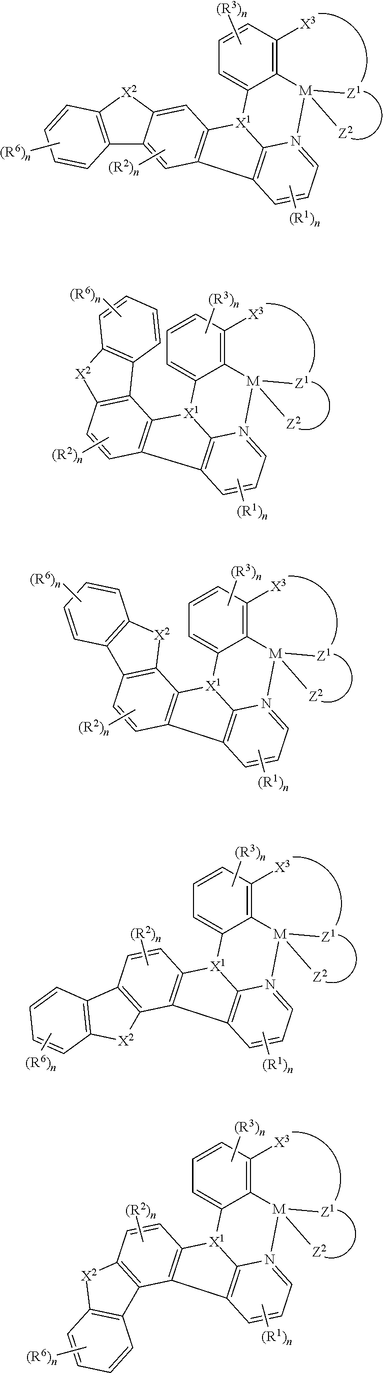

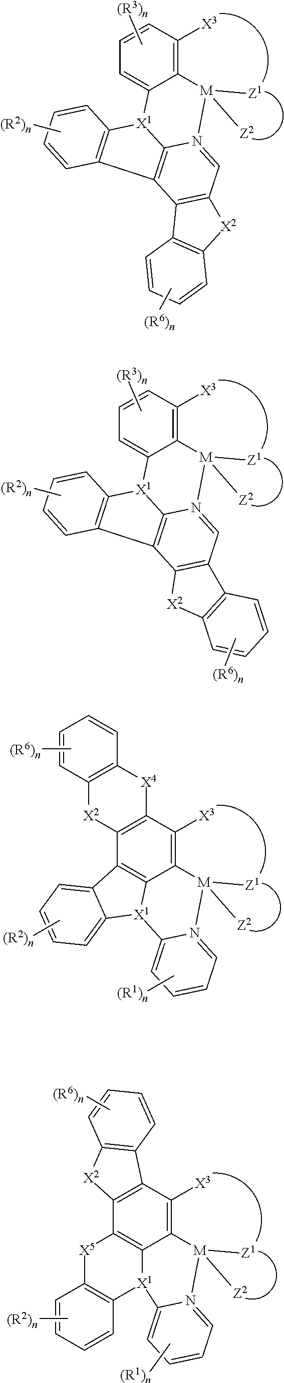

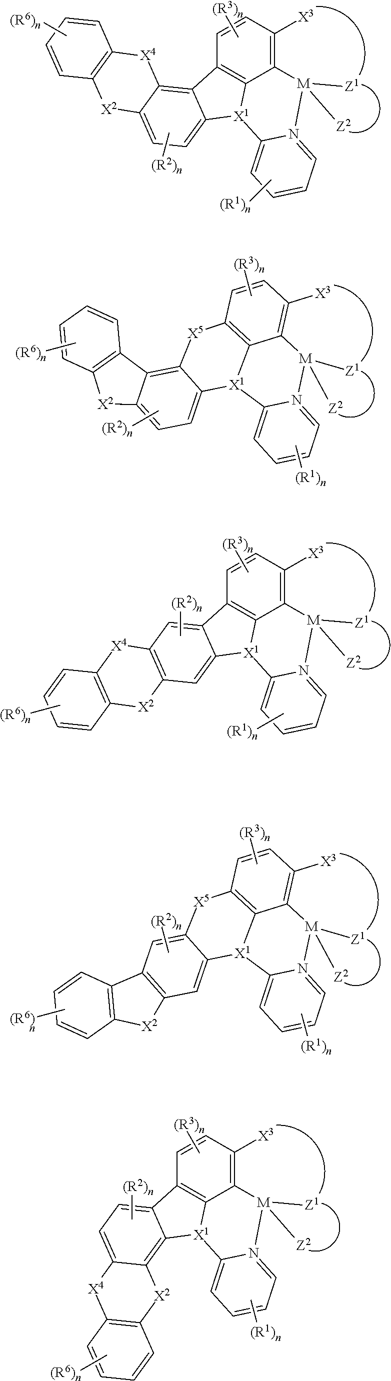

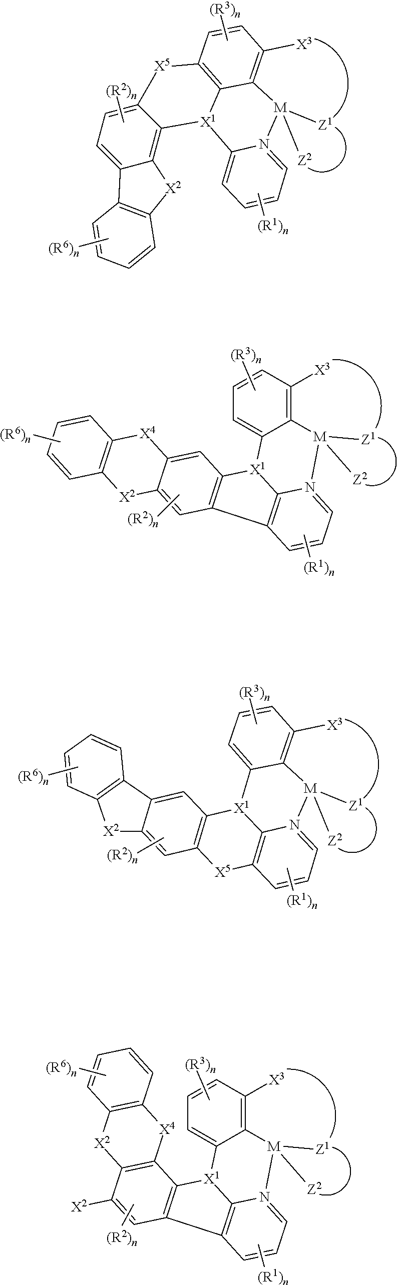

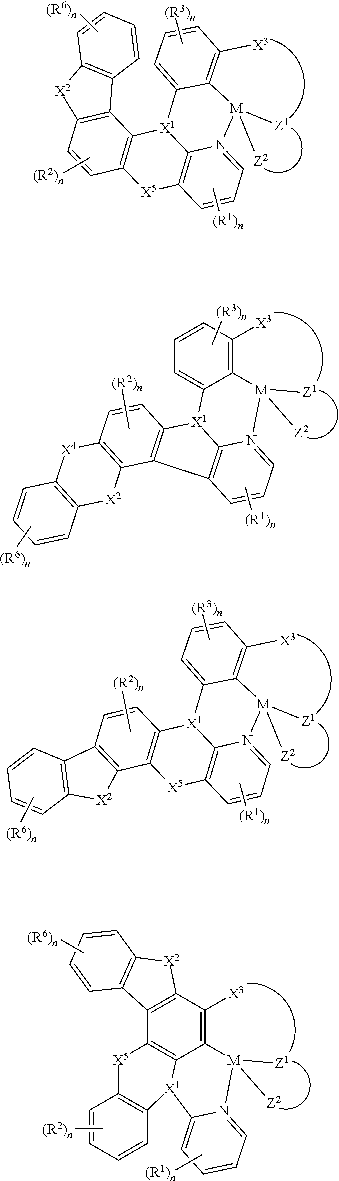

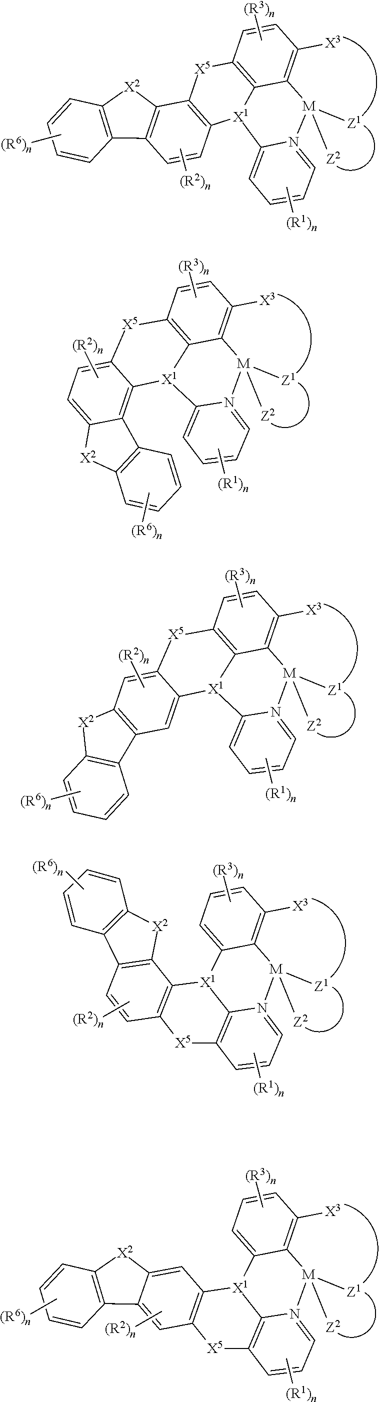

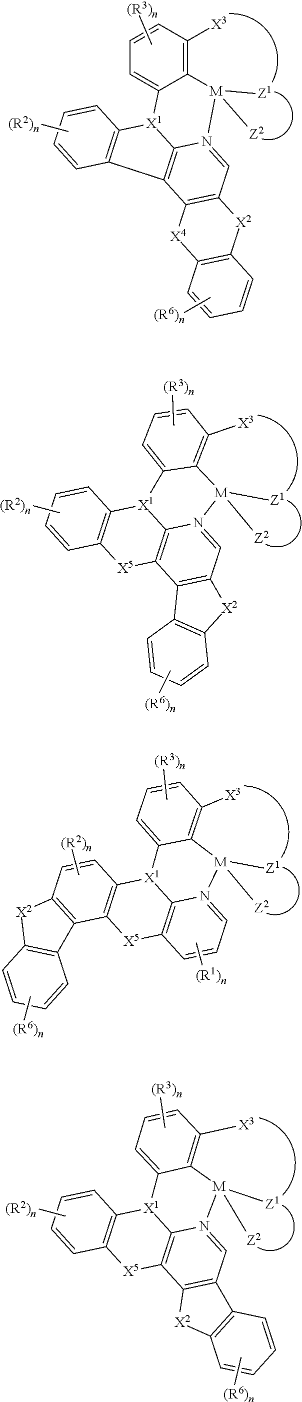

Complexes of General Formulas I-VI are shown below, where Ph is phenyl and

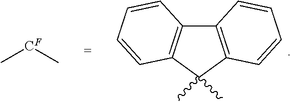

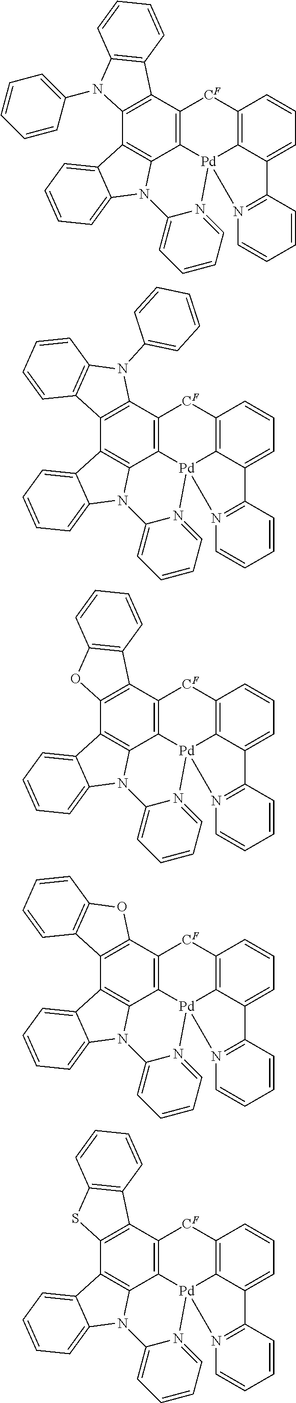

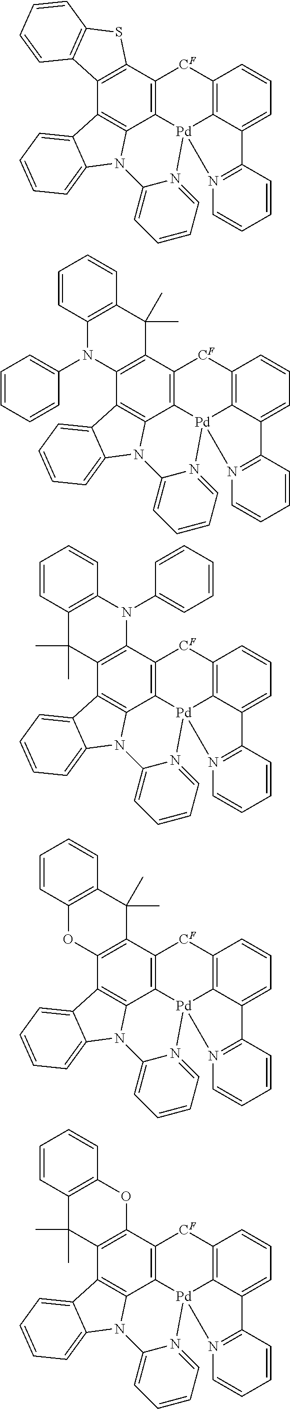

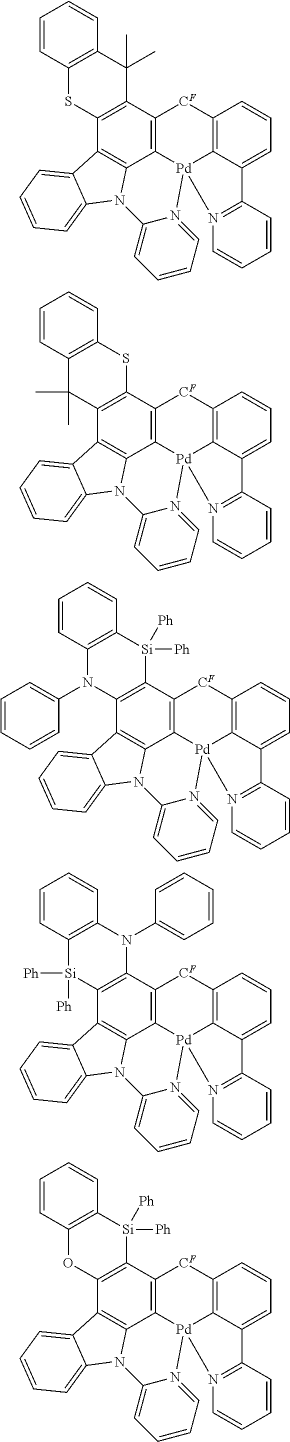

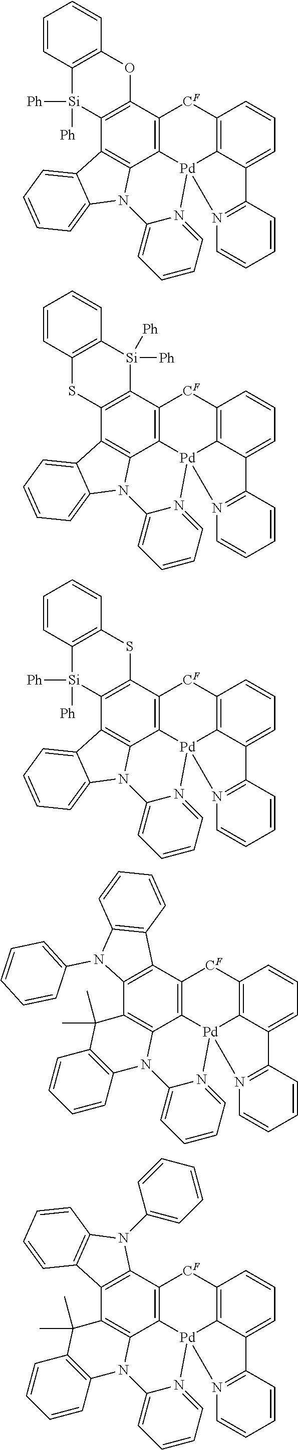

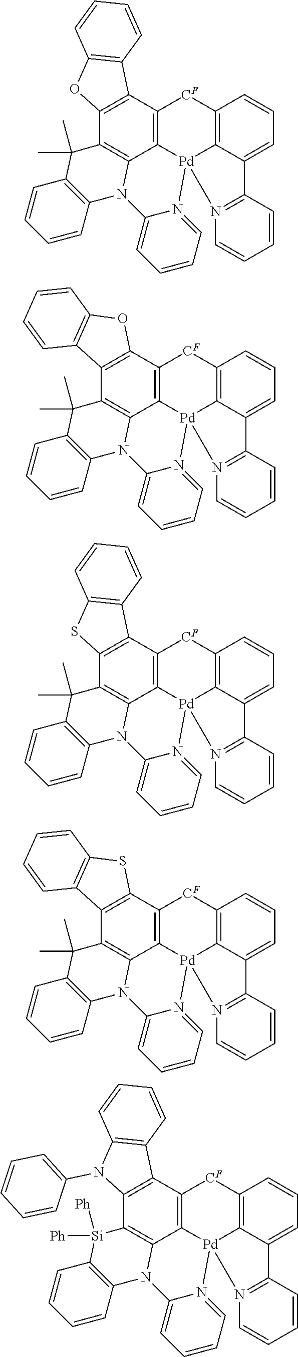

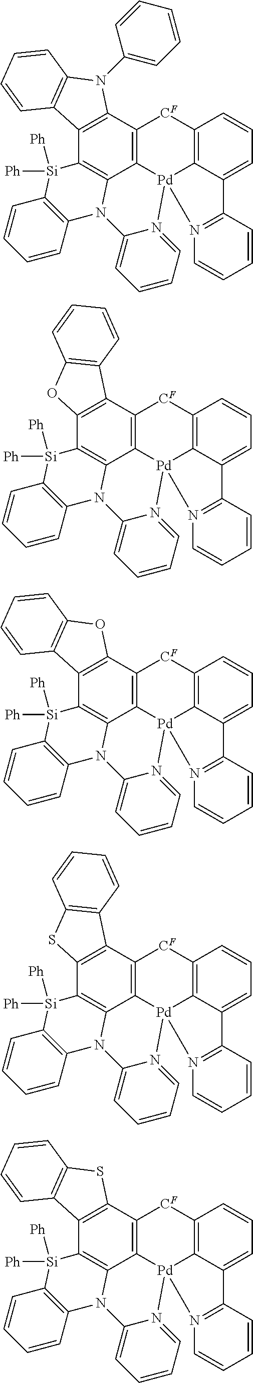

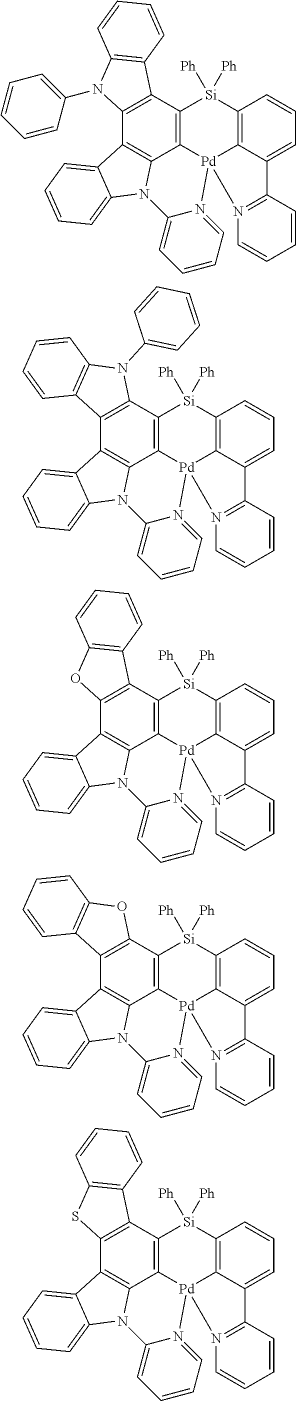

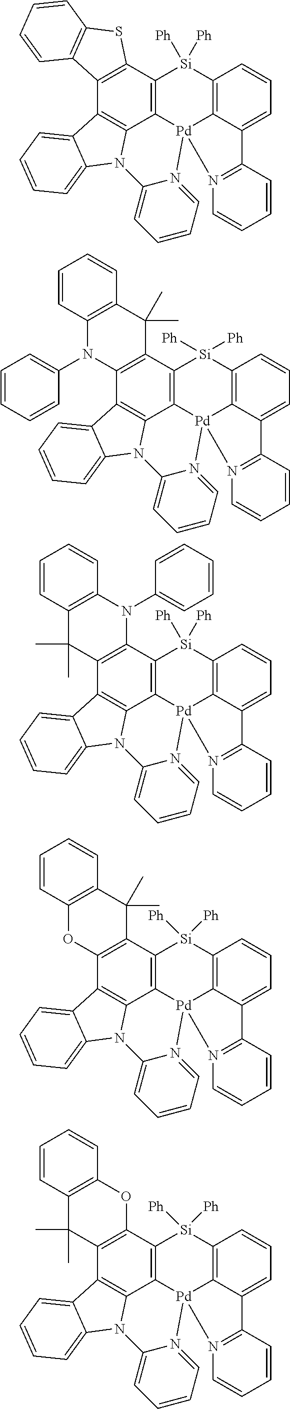

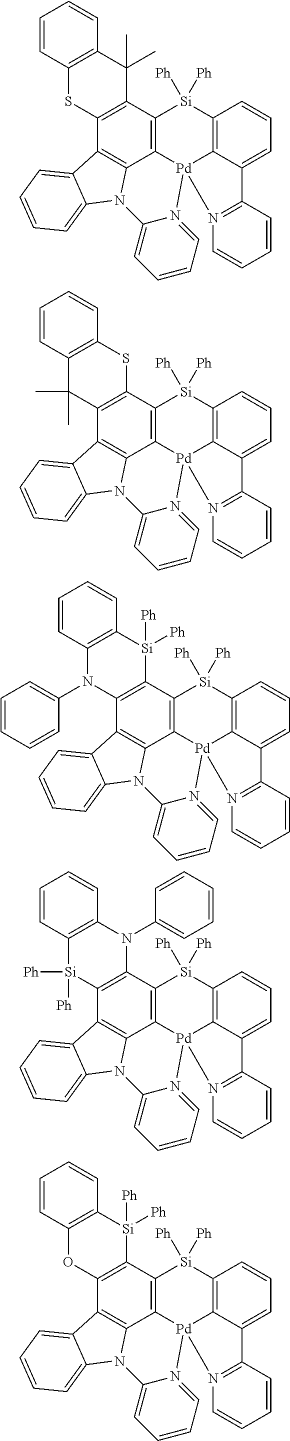

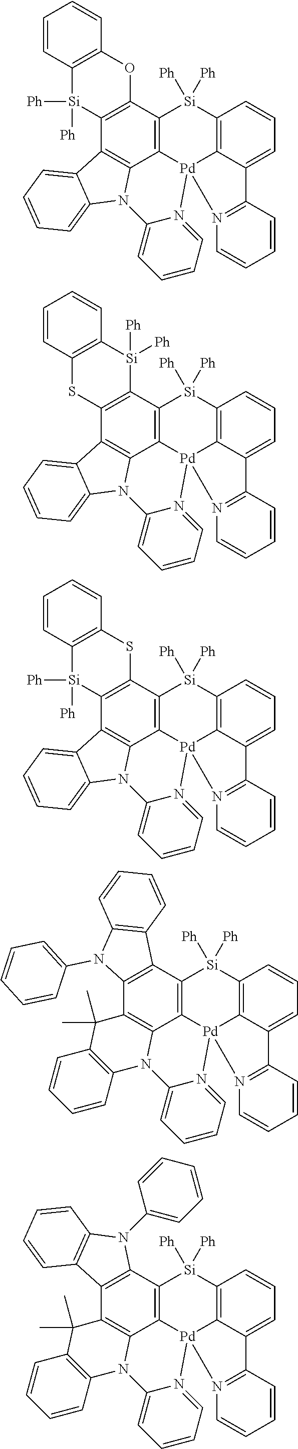

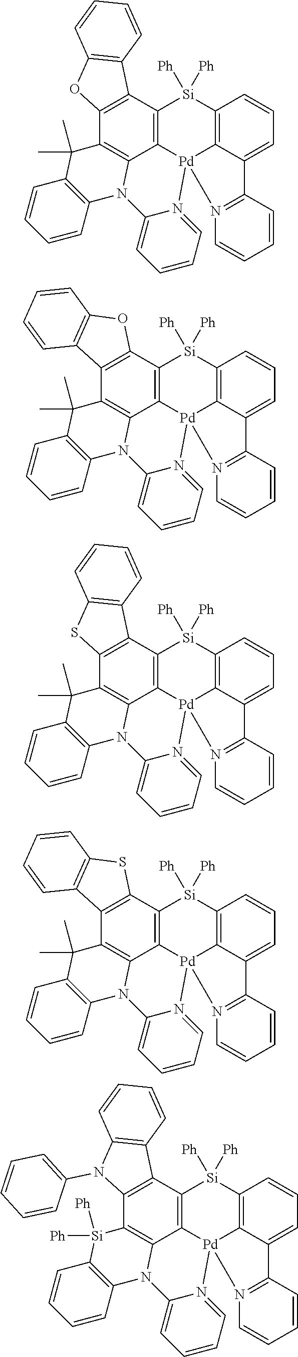

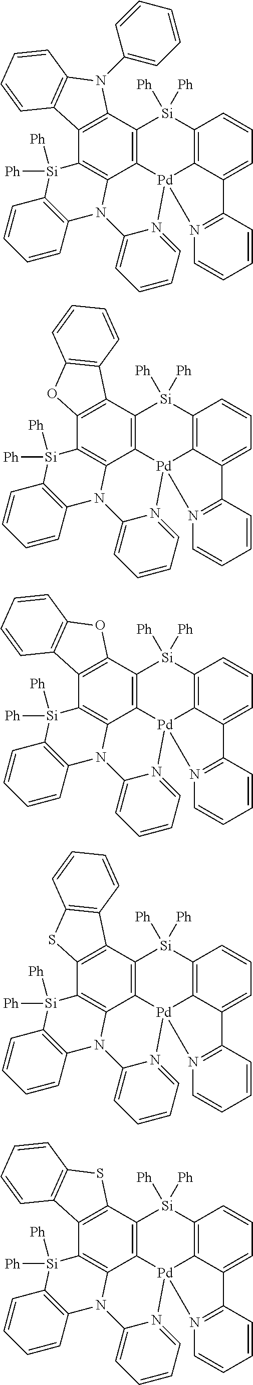

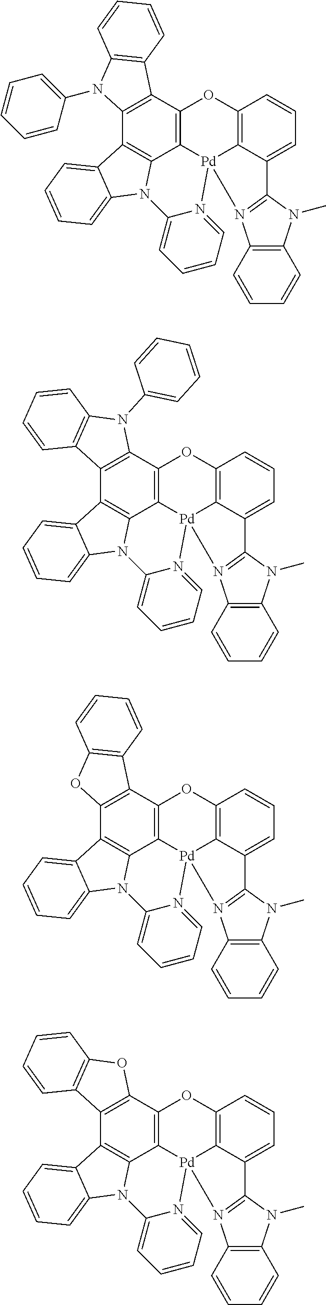

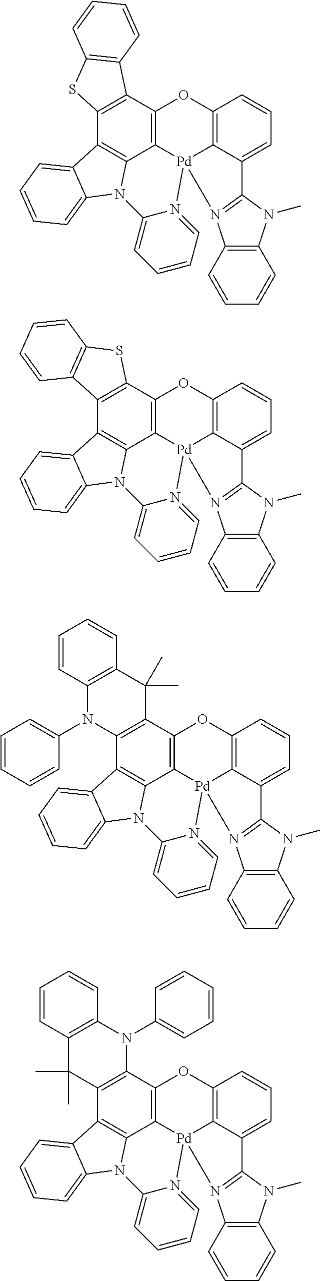

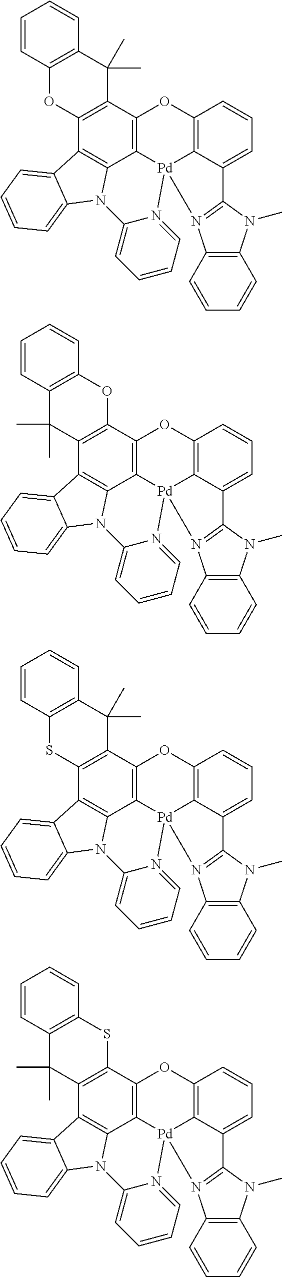

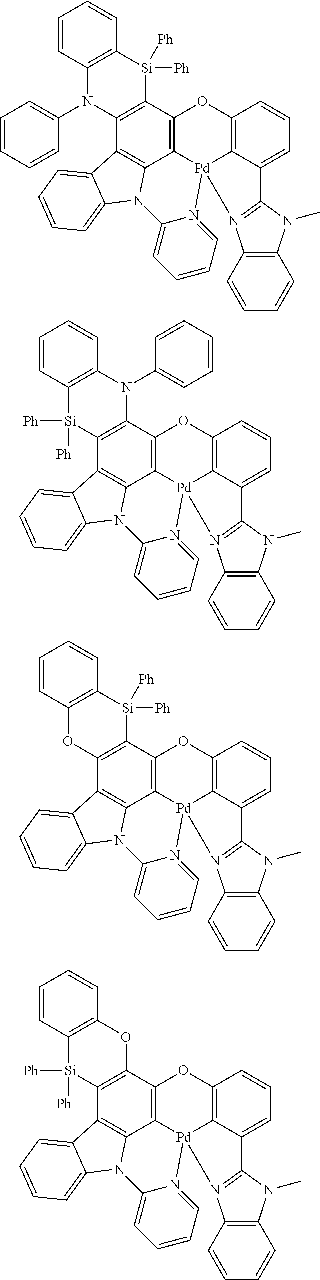

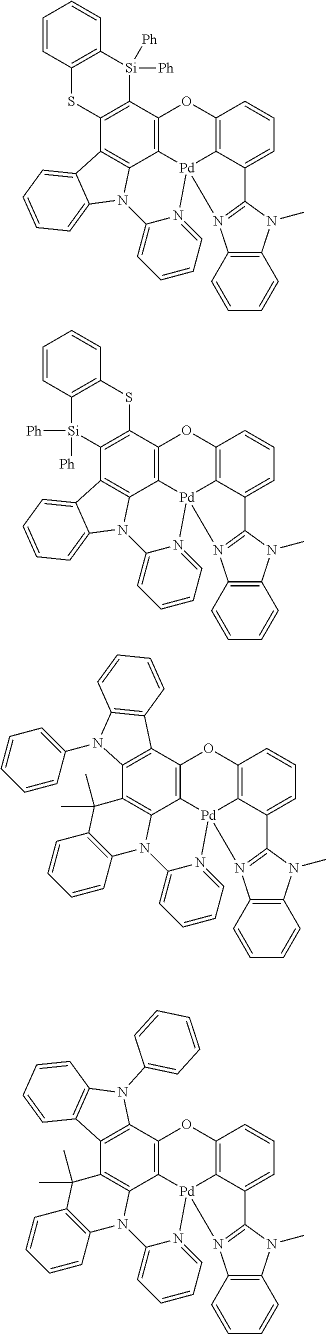

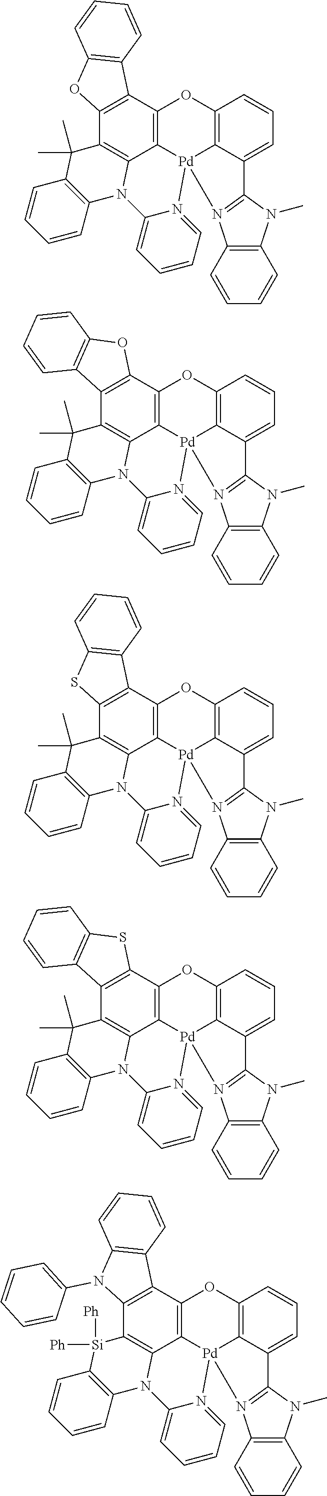

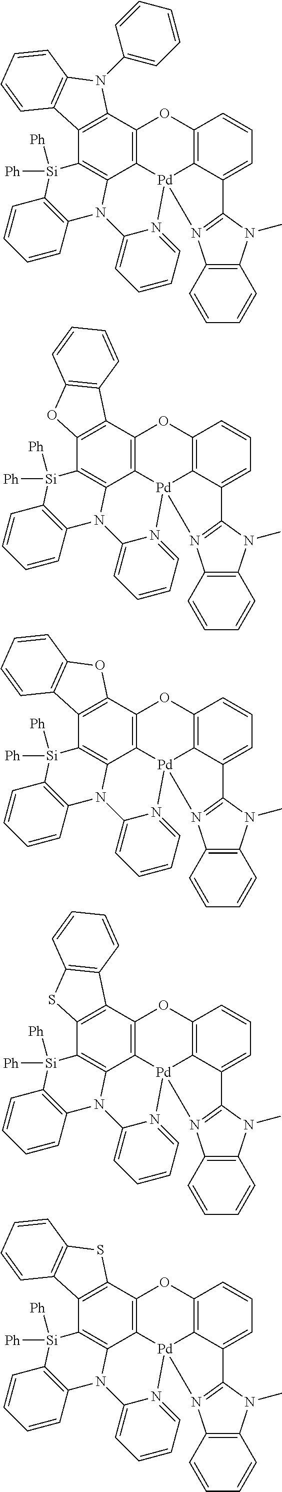

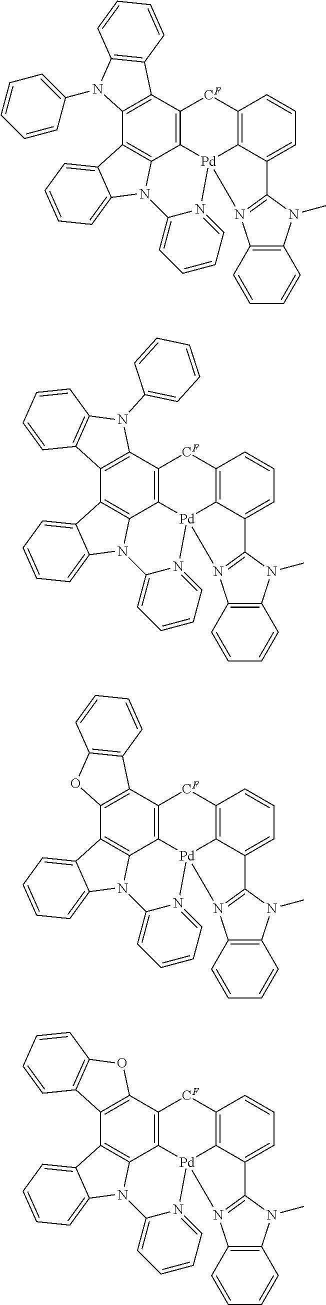

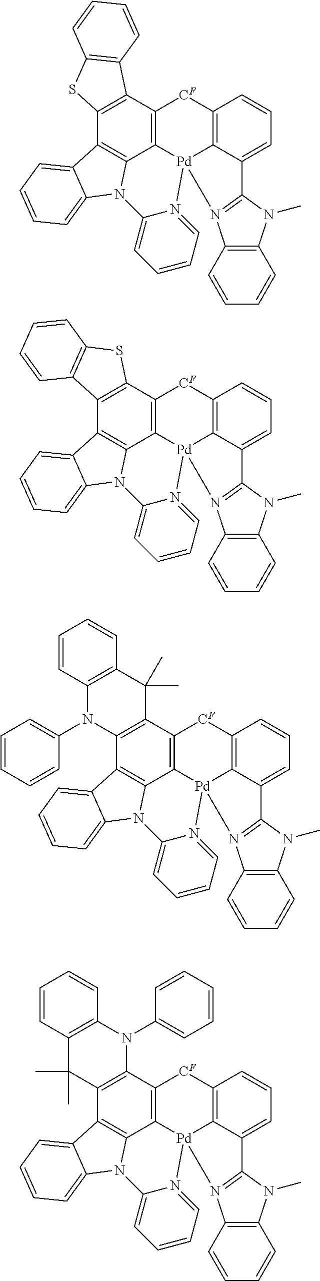

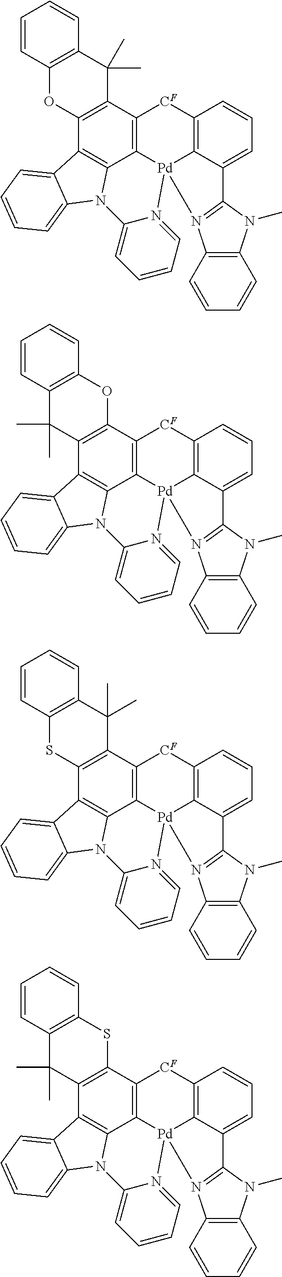

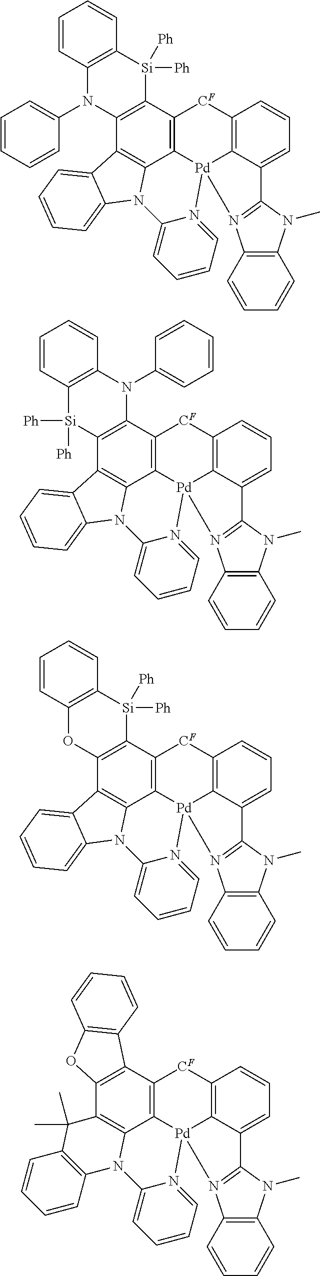

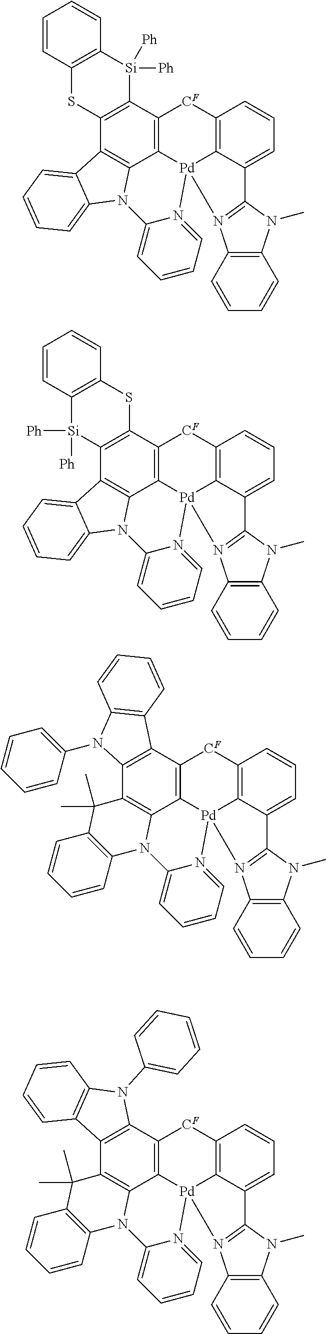

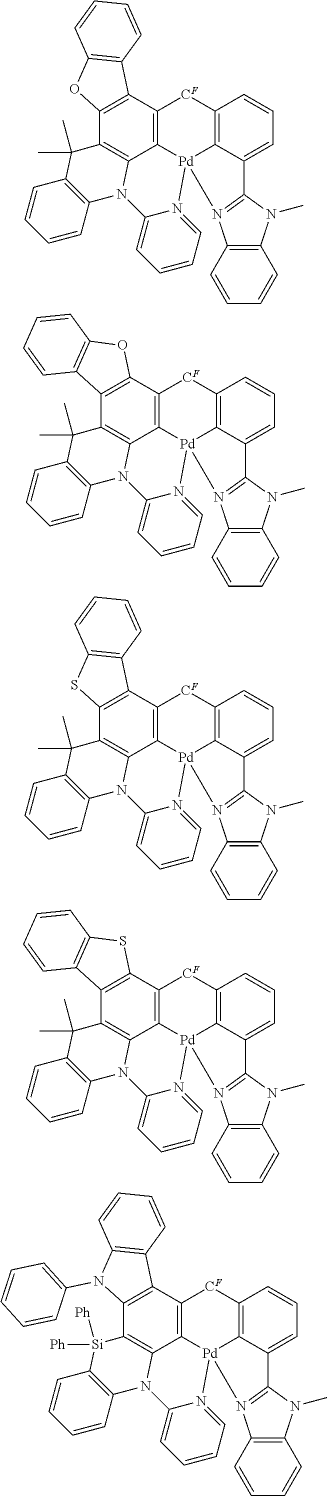

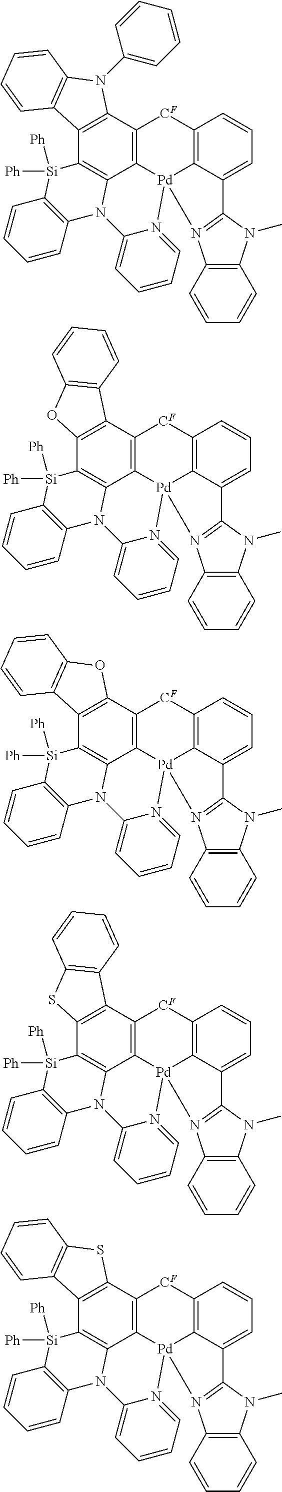

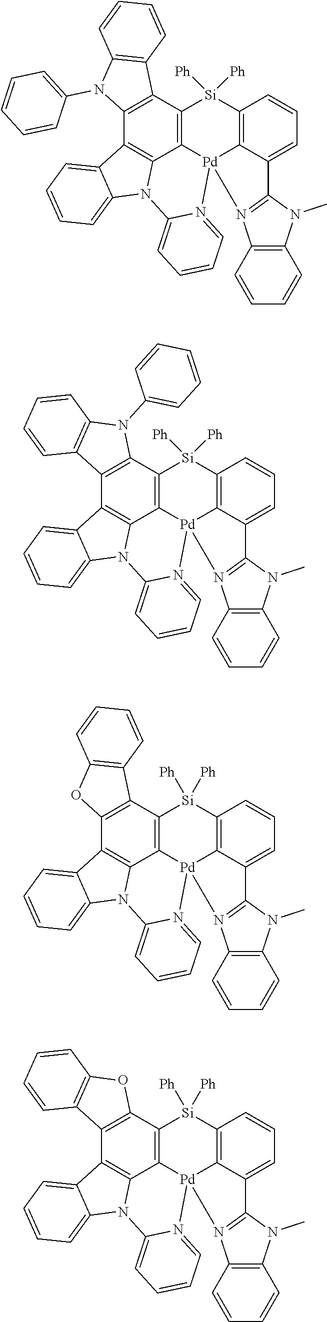

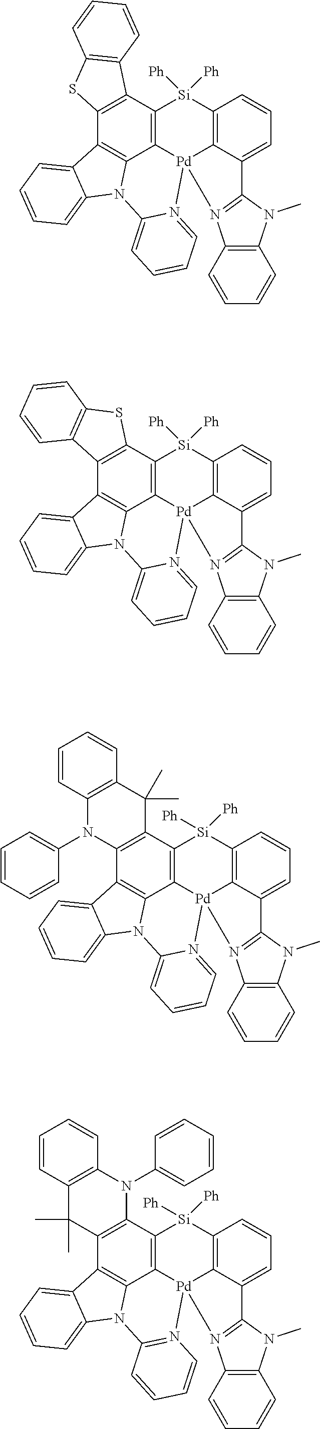

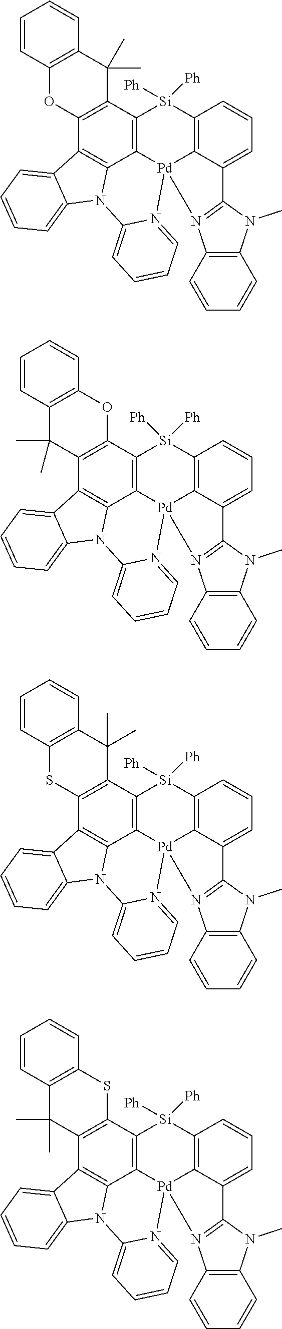

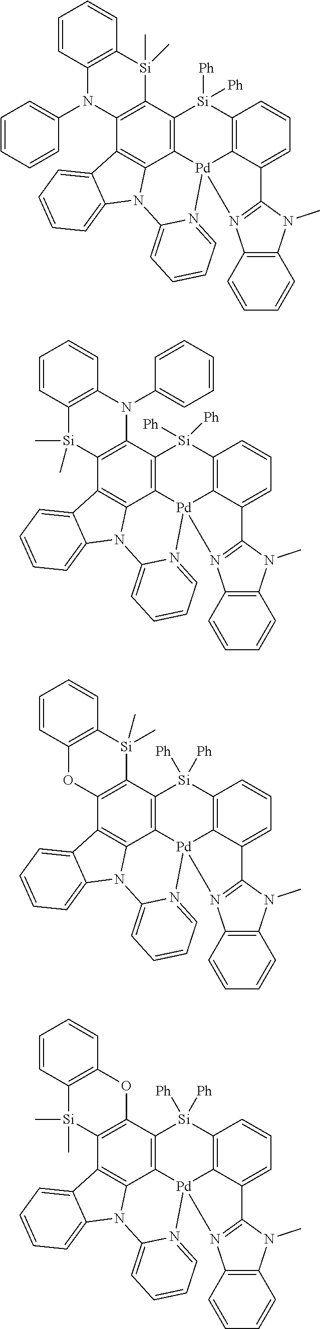

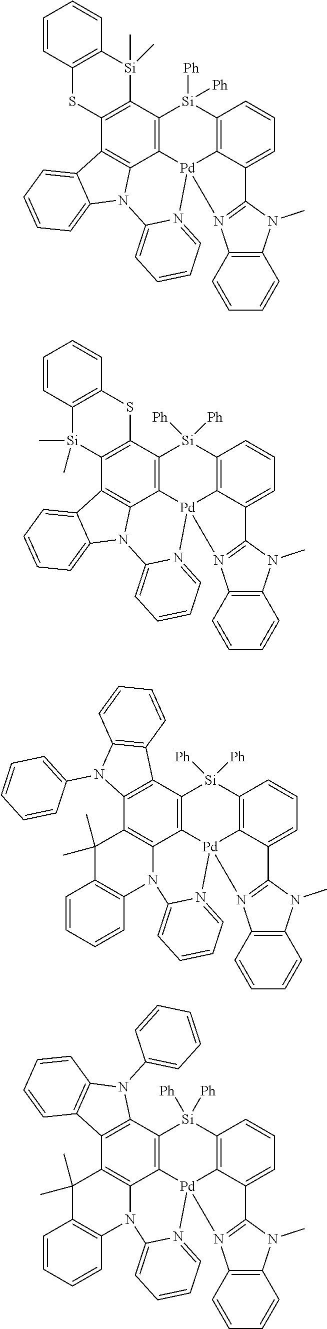

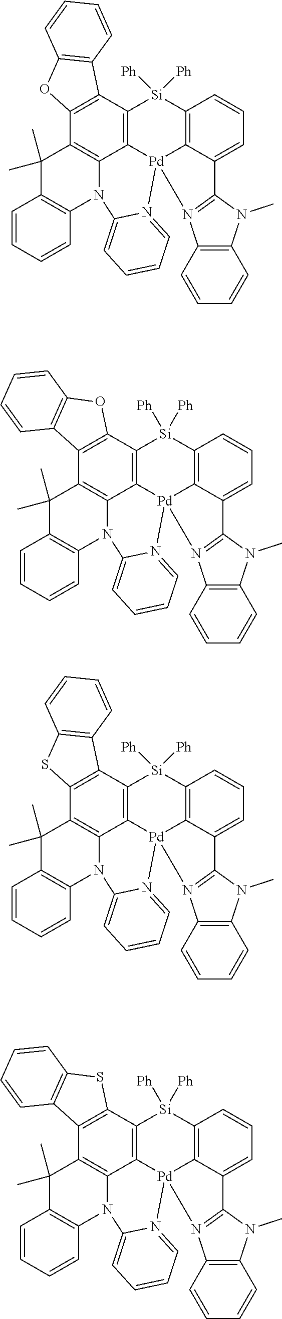

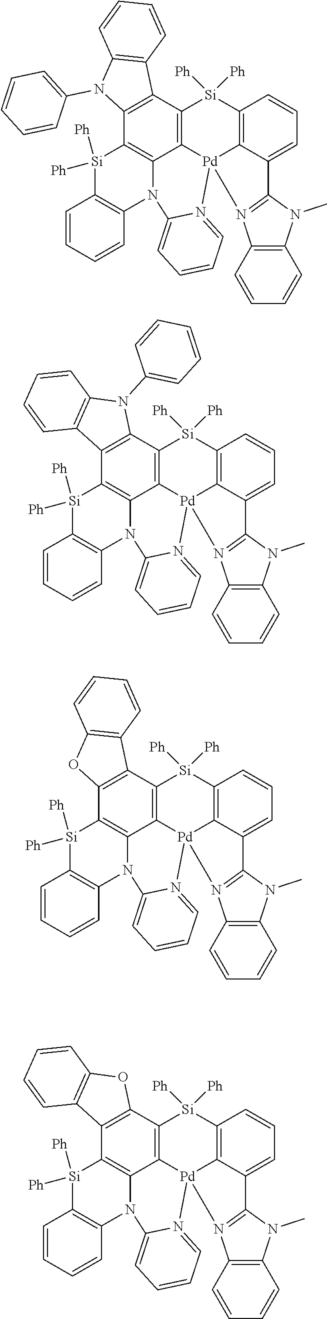

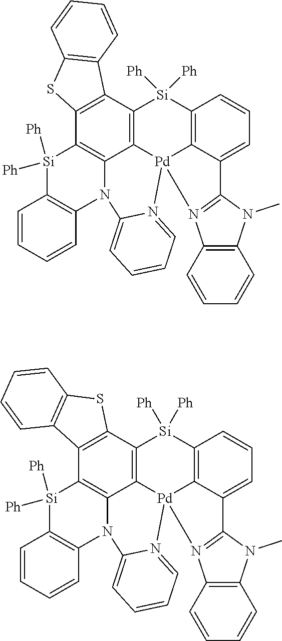

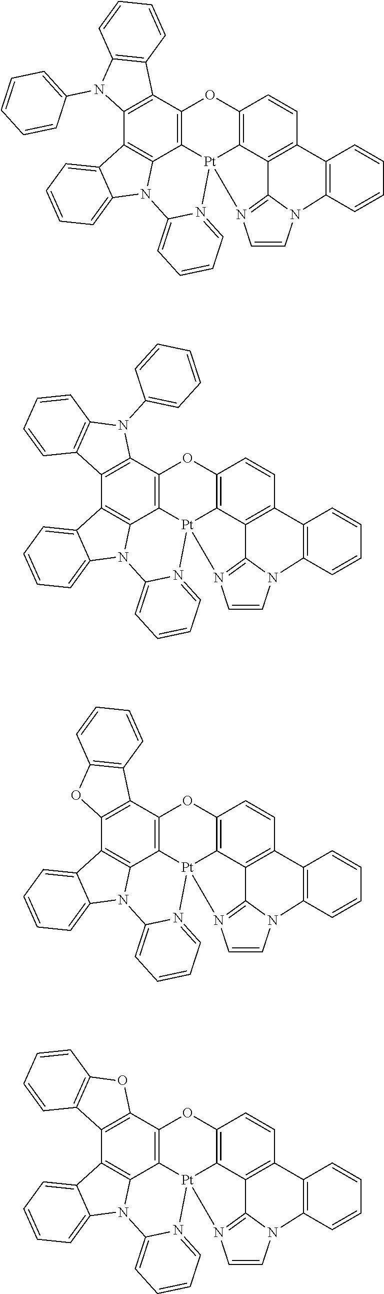

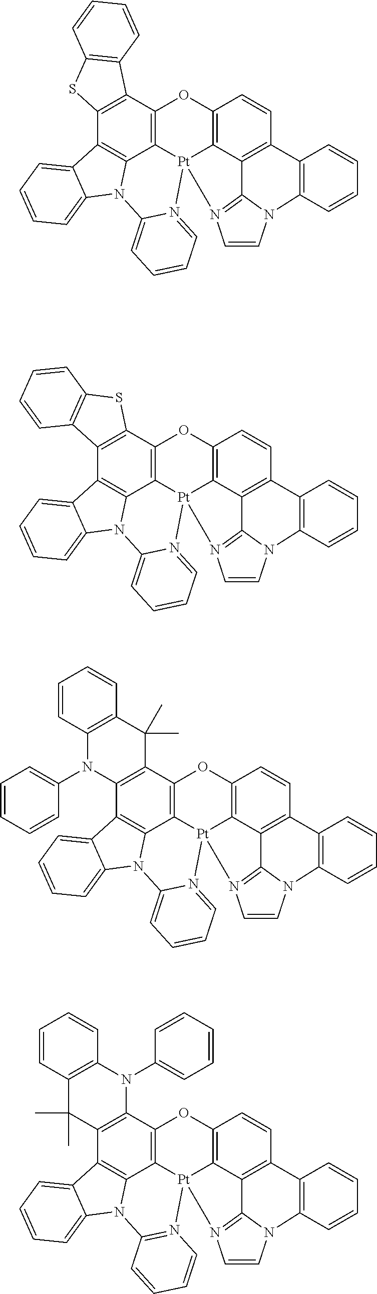

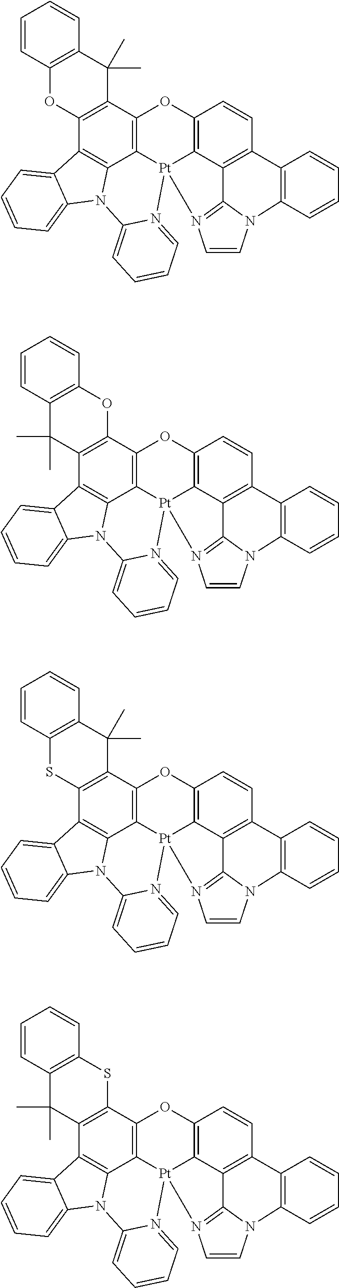

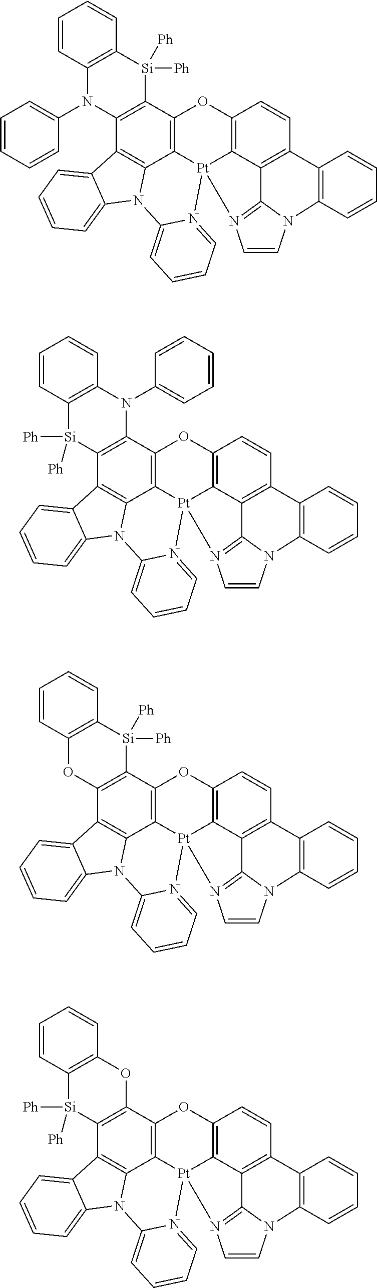

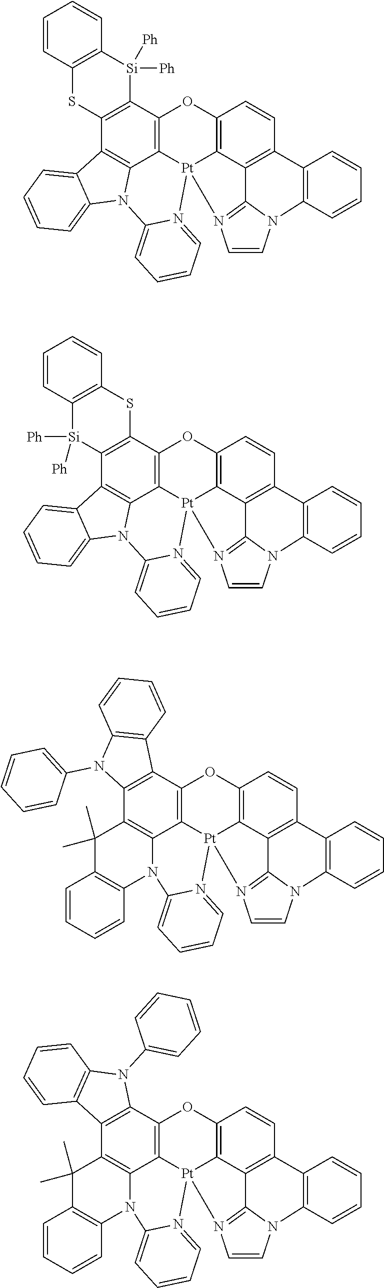

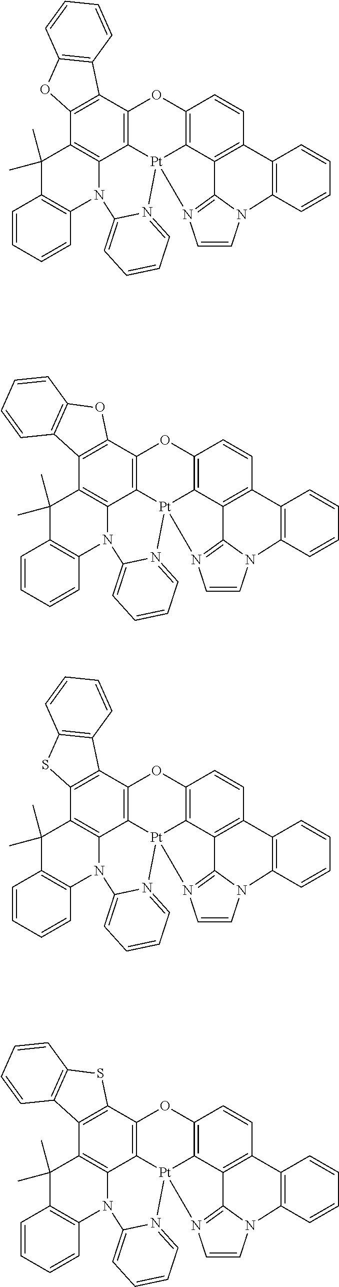

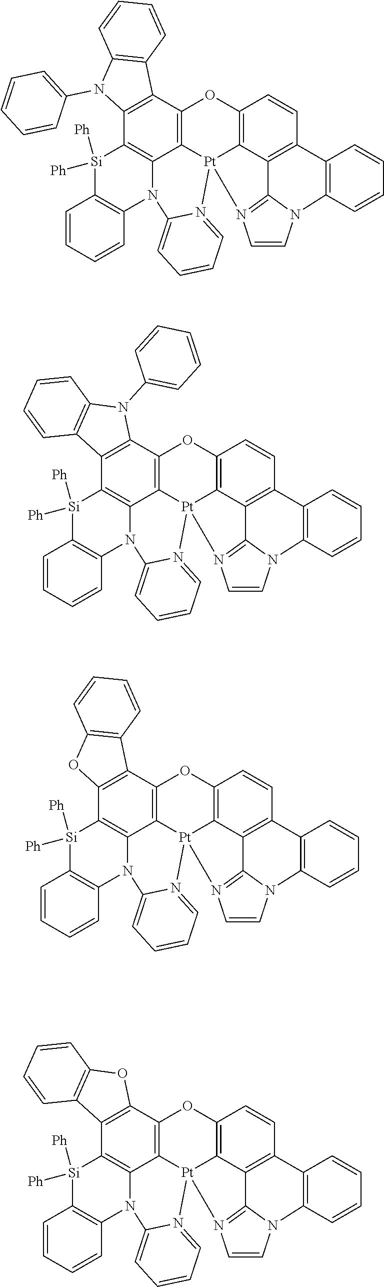

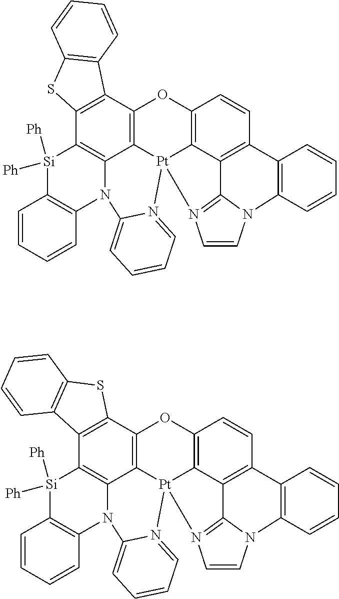

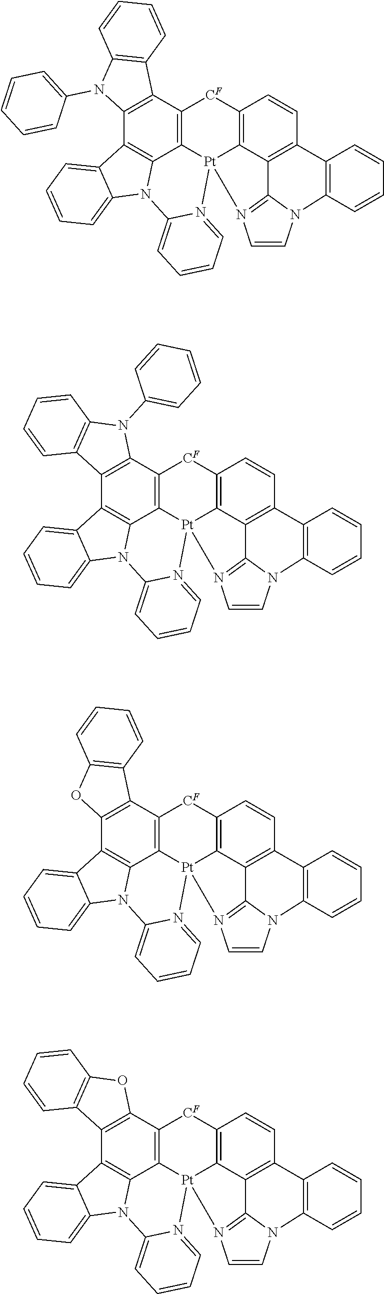

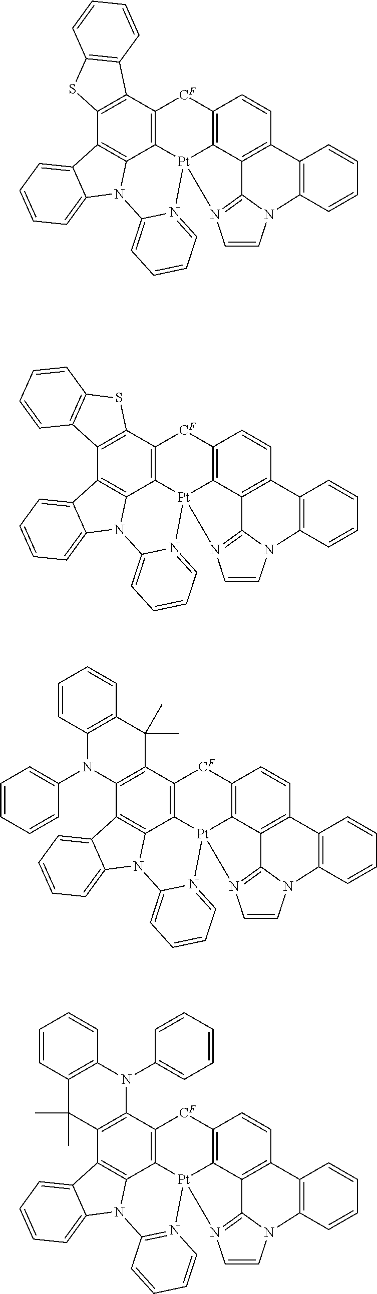

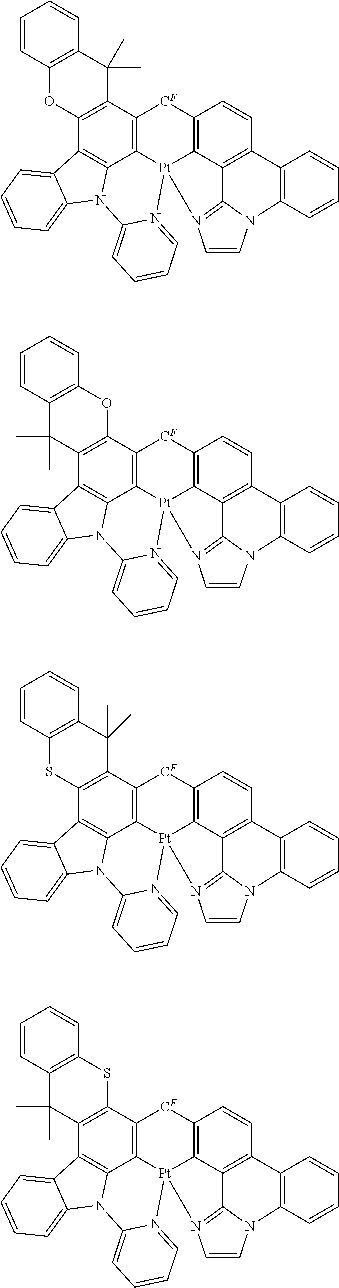

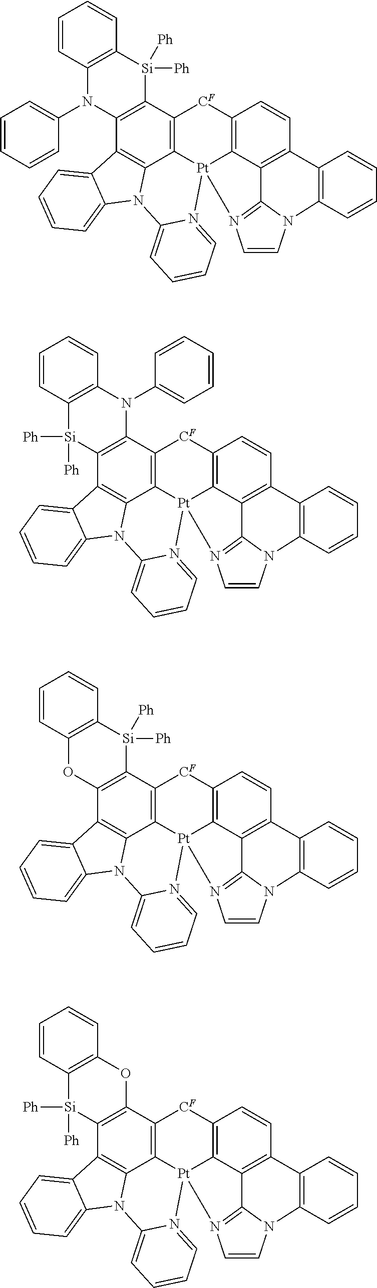

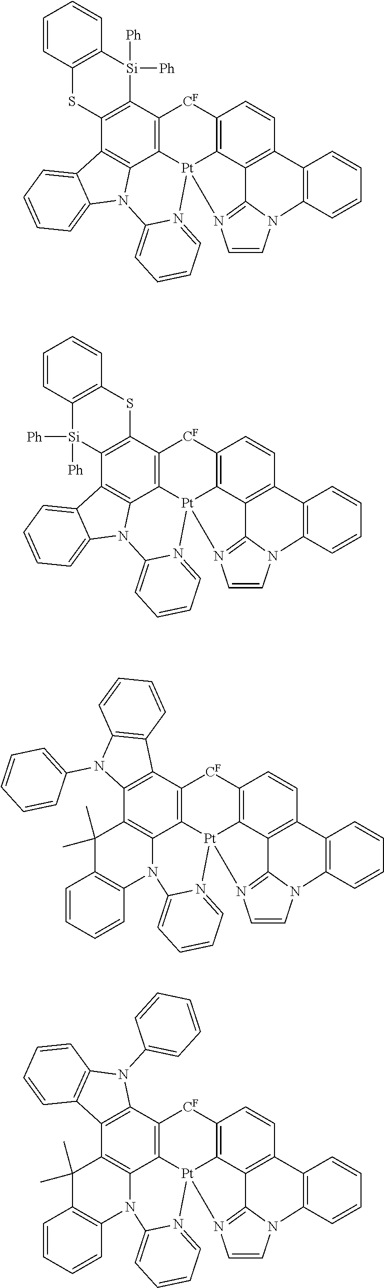

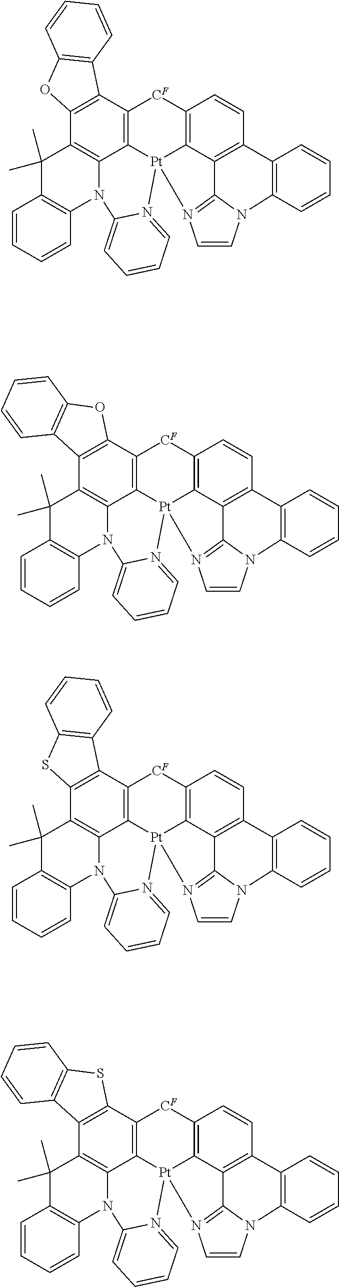

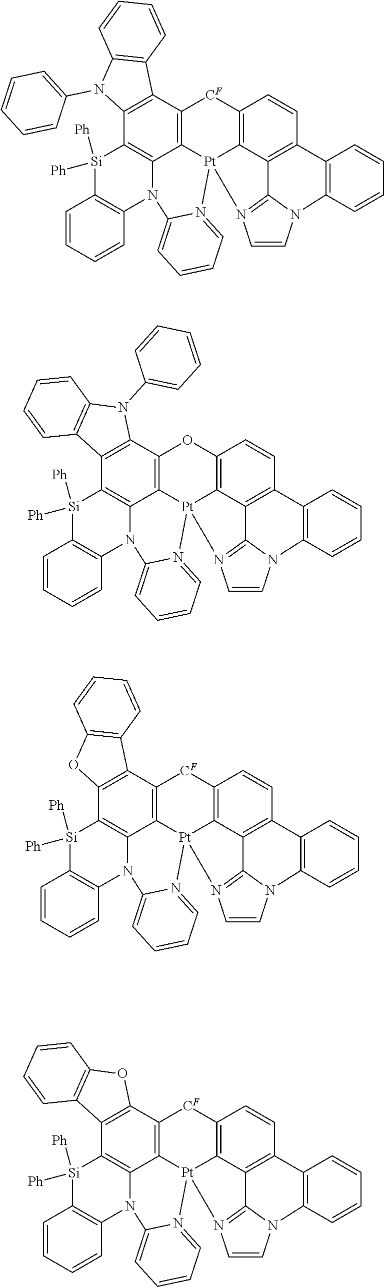

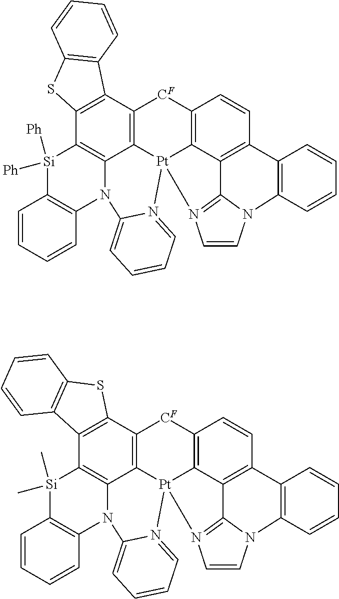

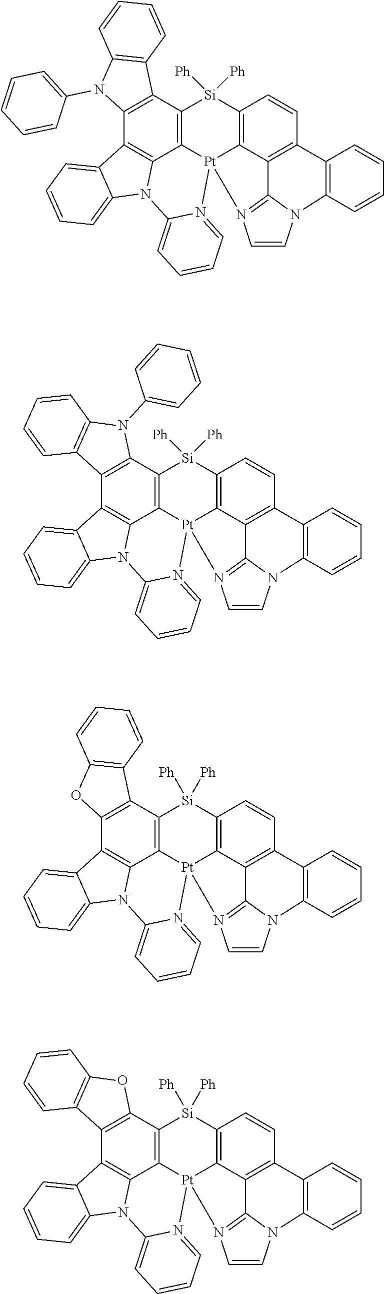

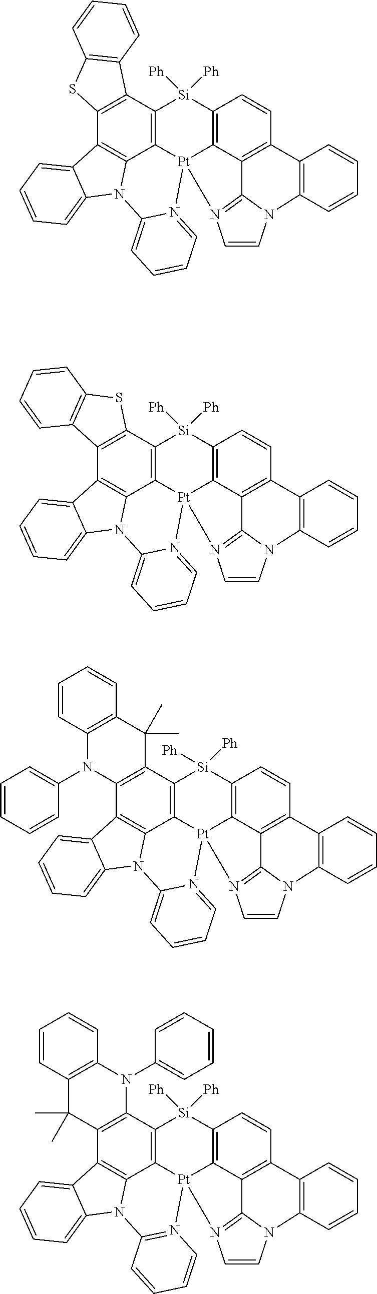

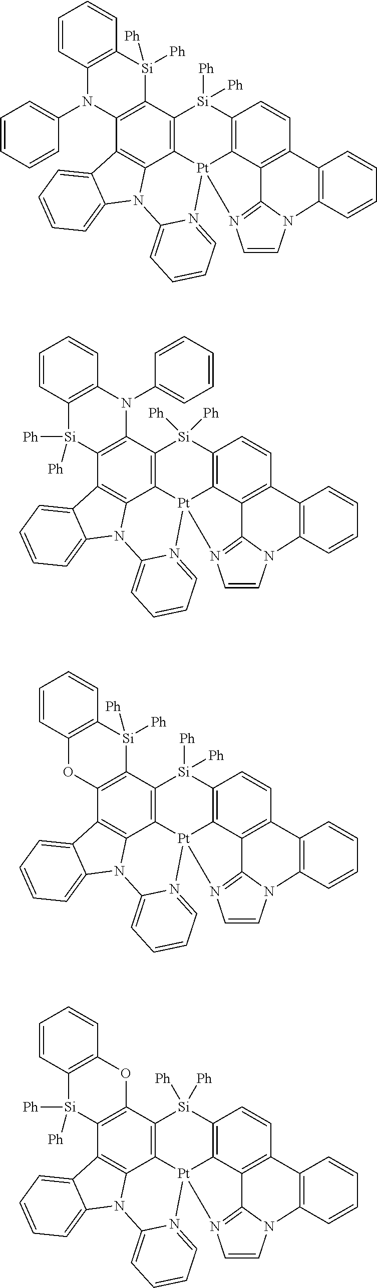

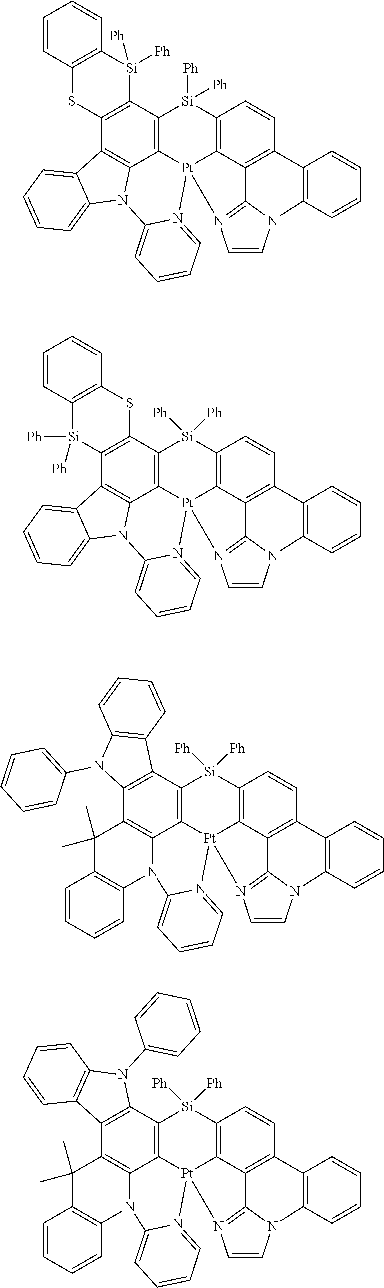

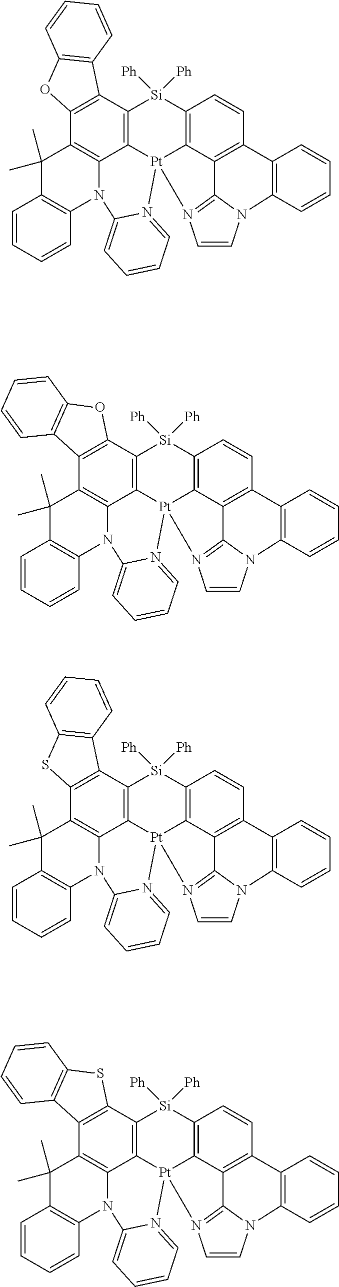

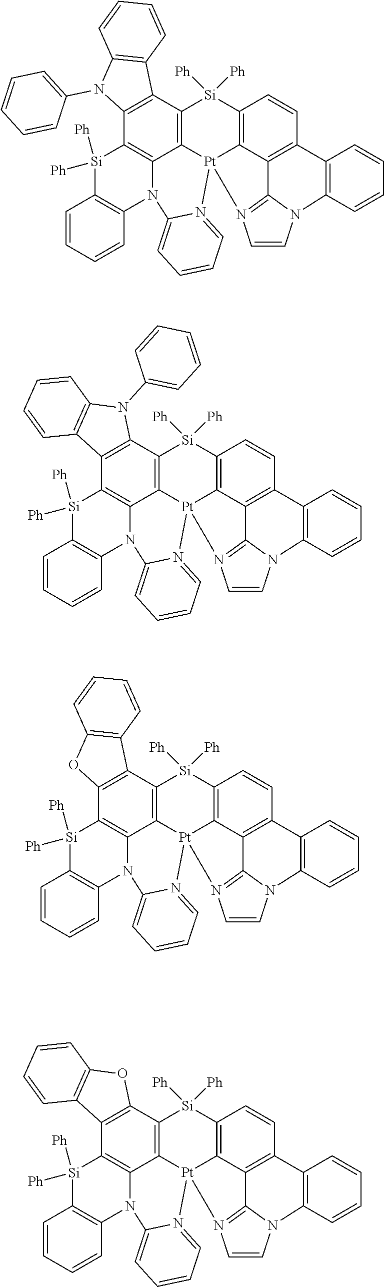

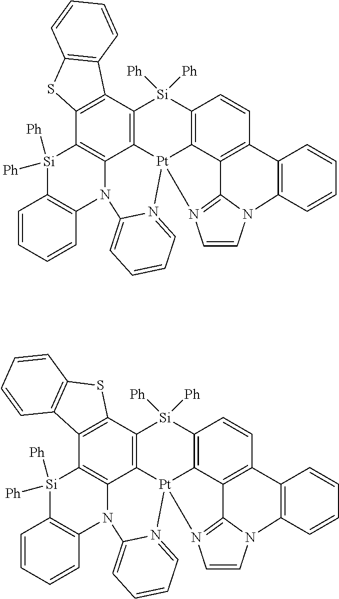

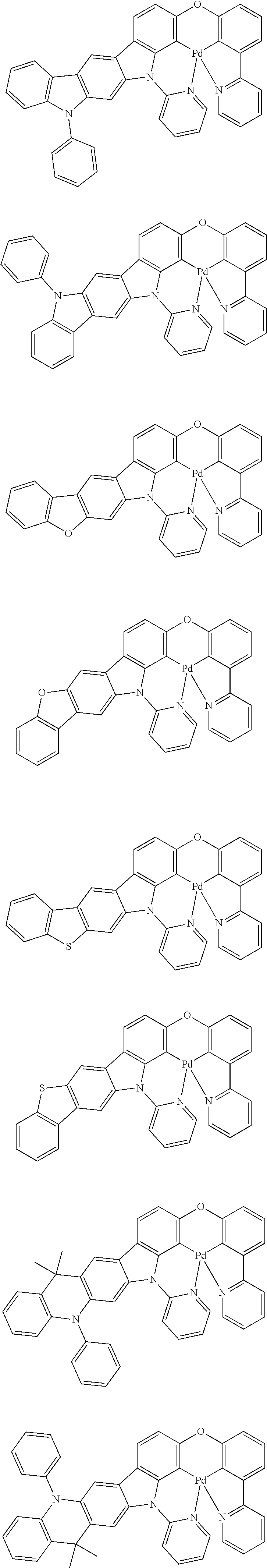

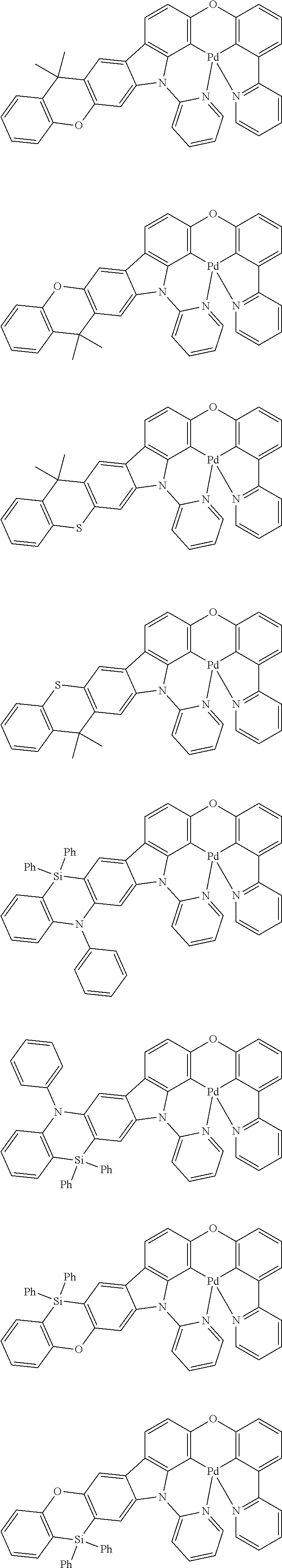

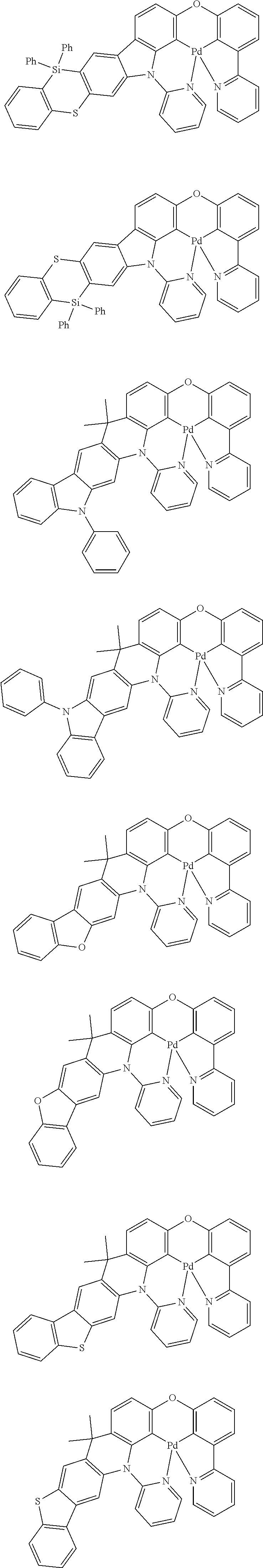

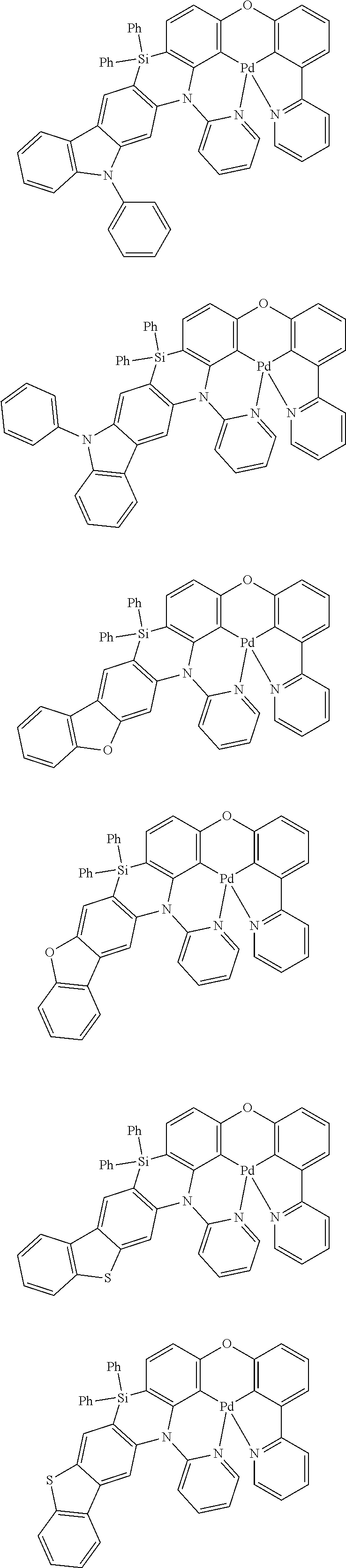

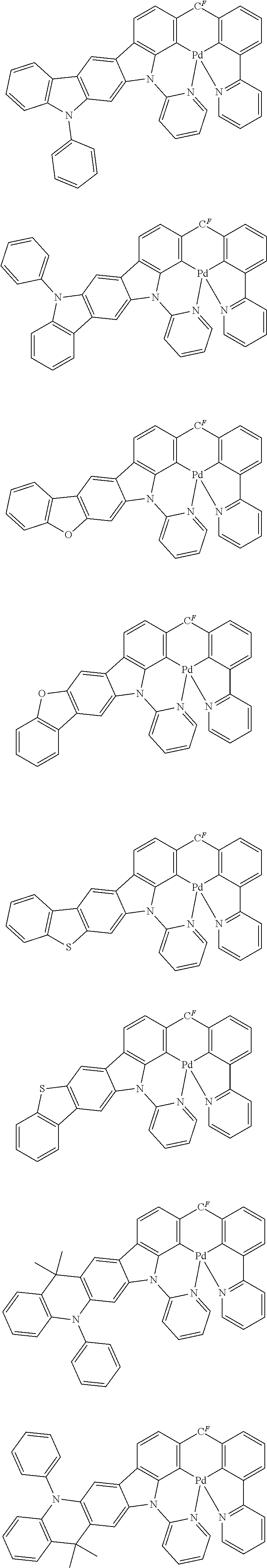

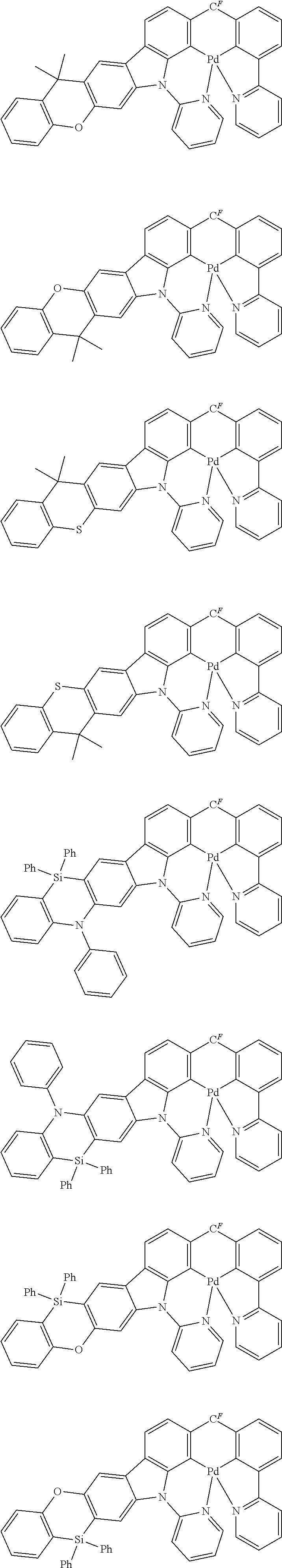

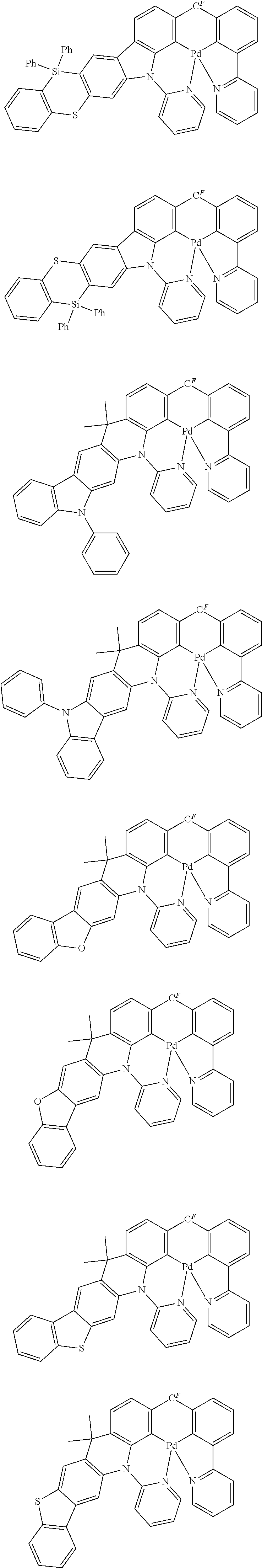

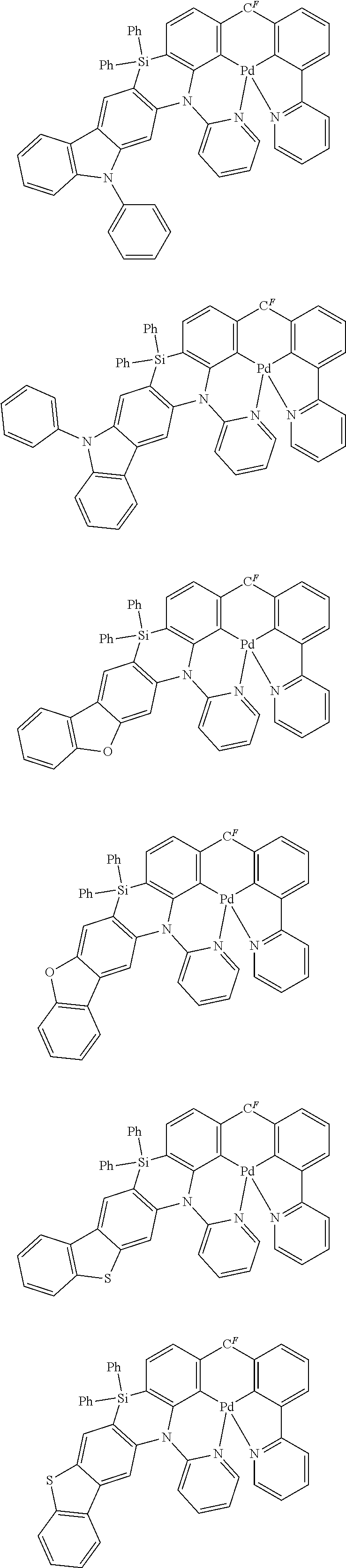

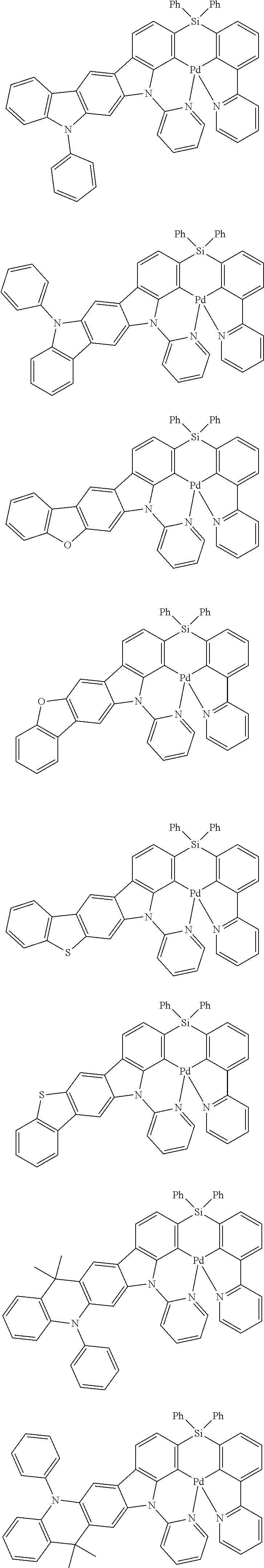

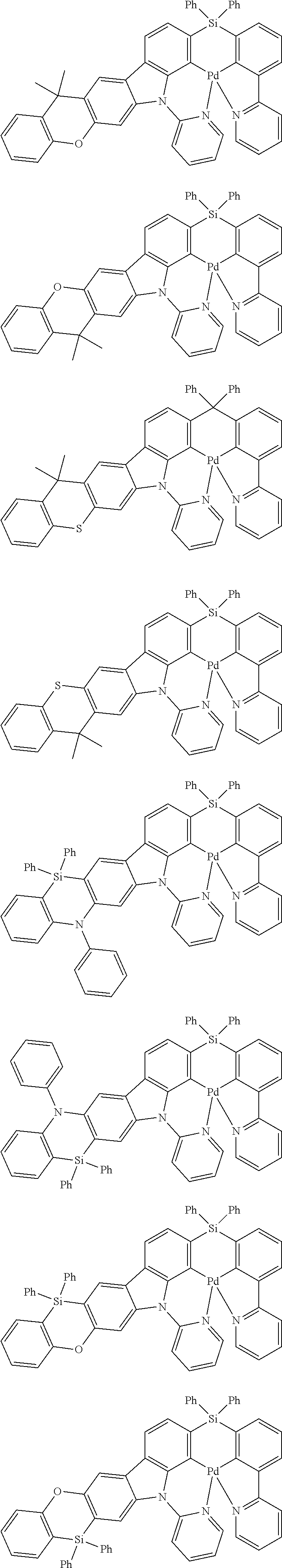

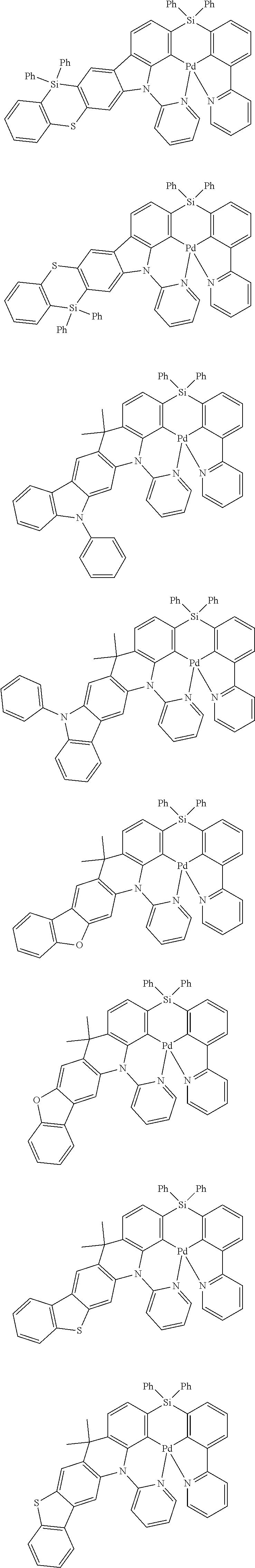

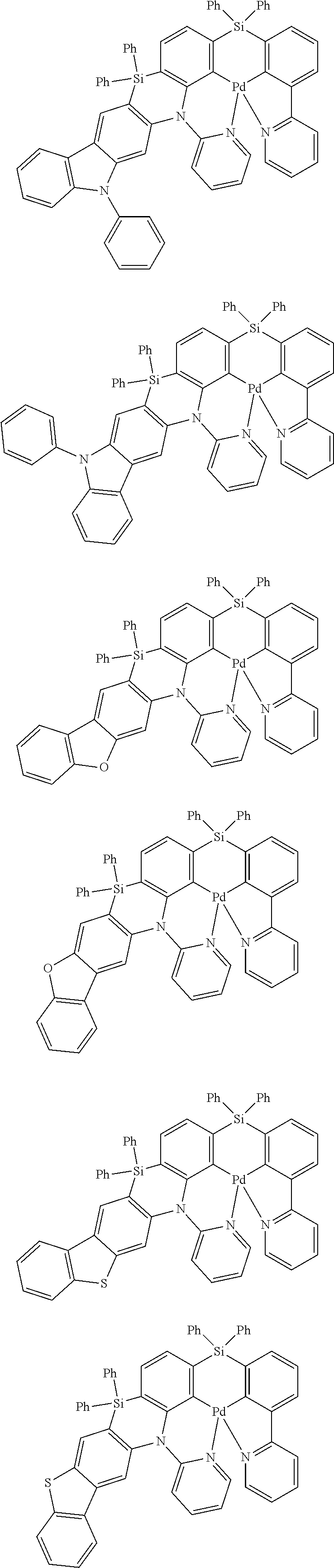

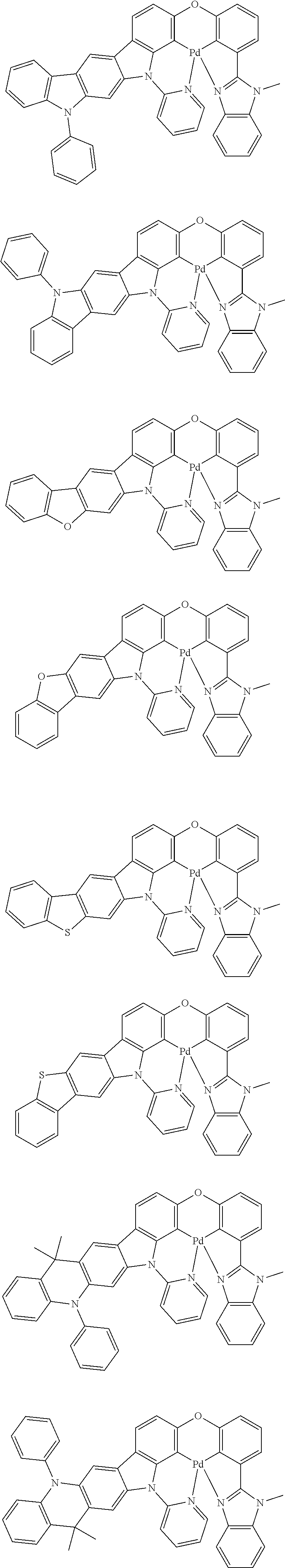

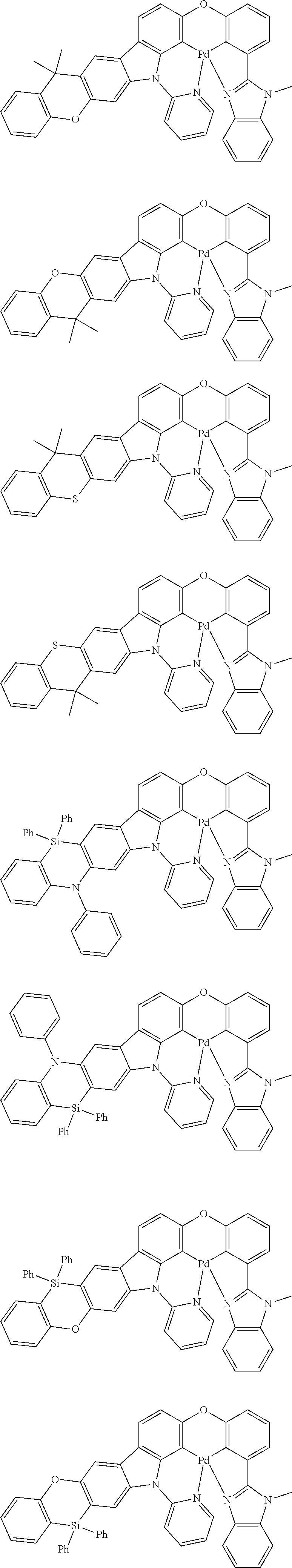

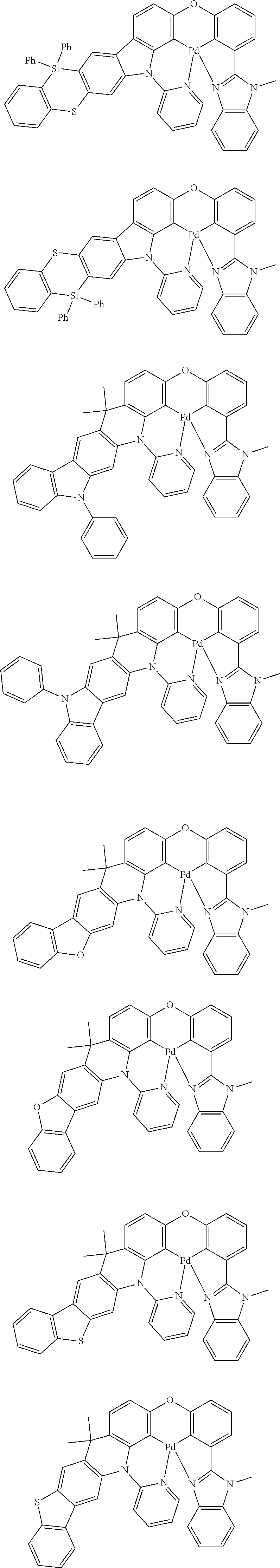

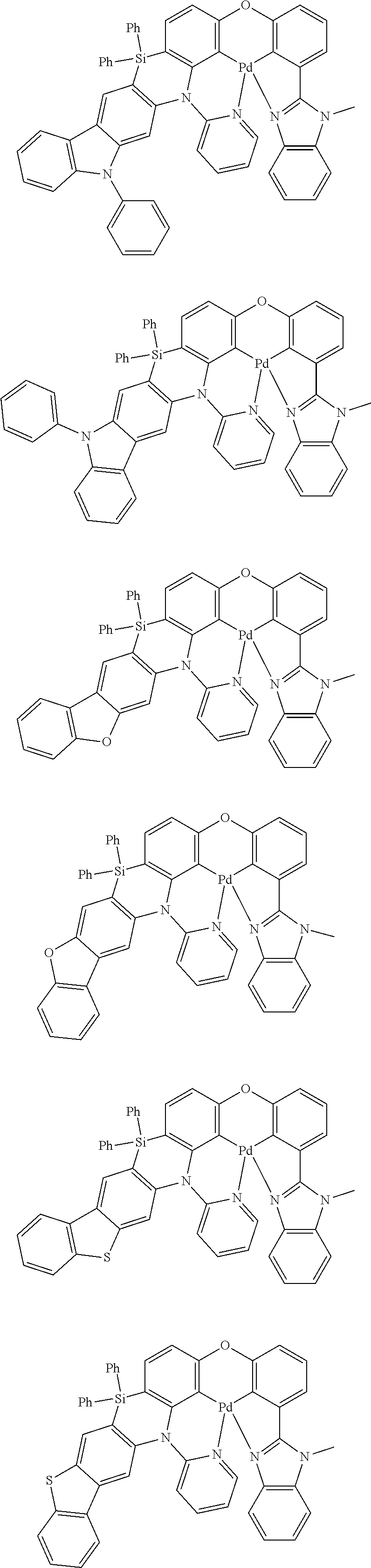

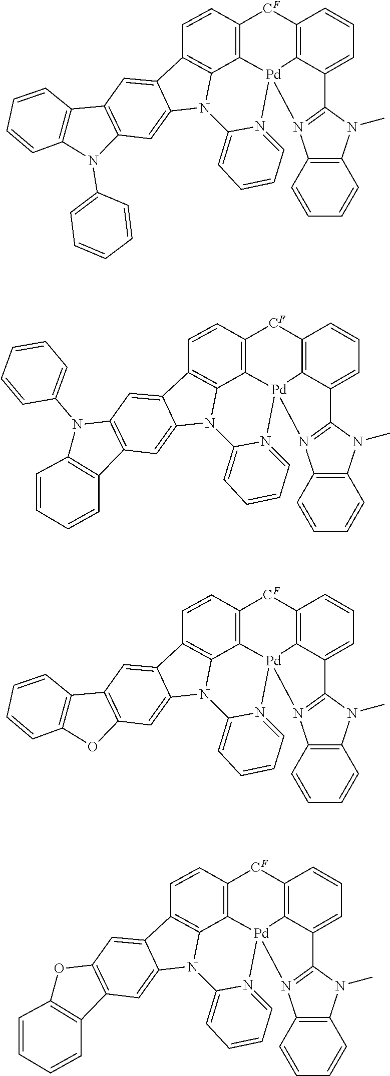

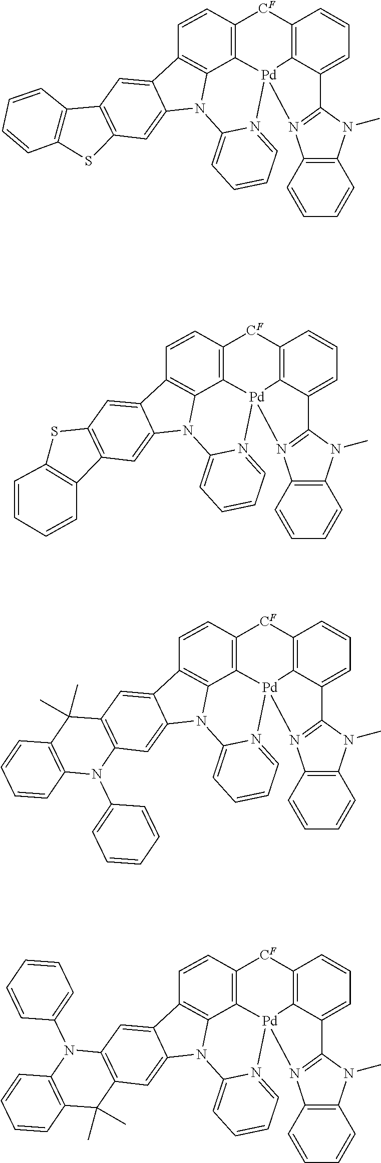

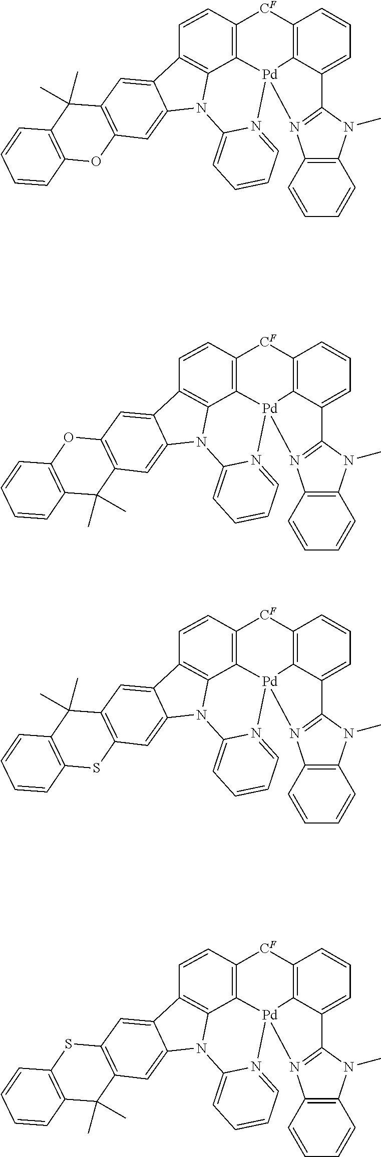

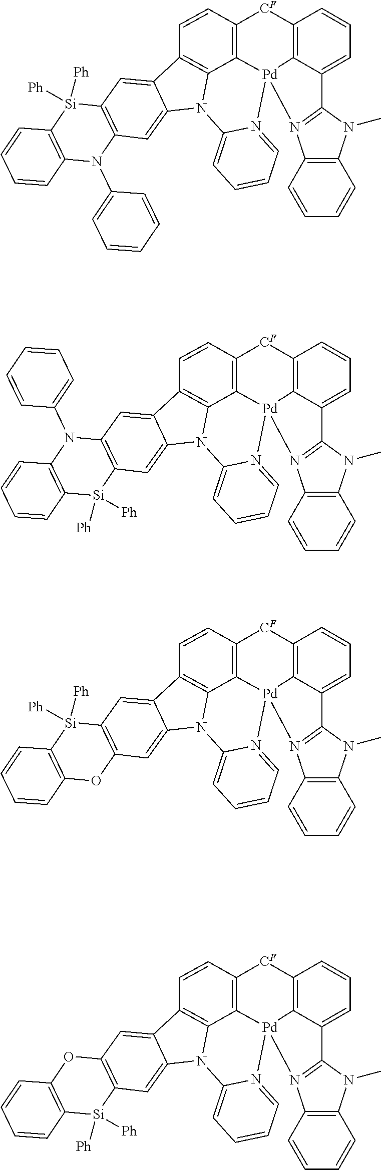

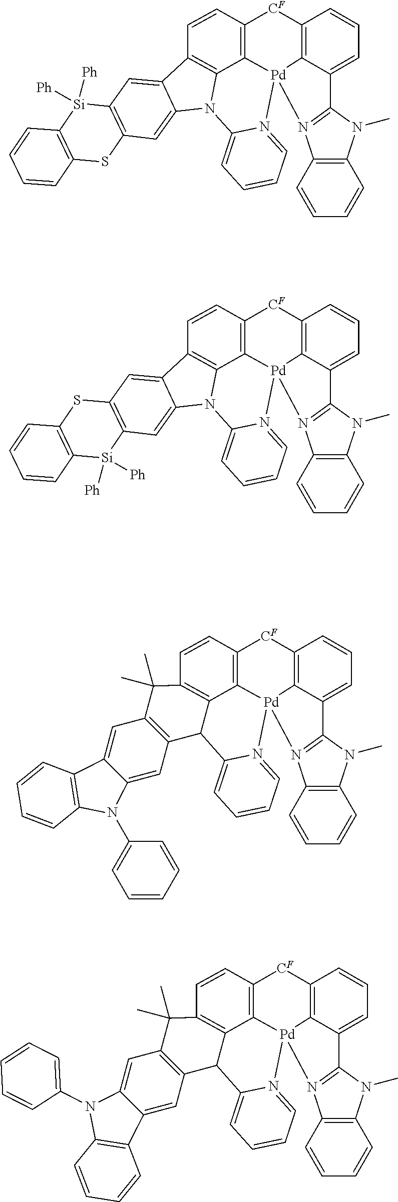

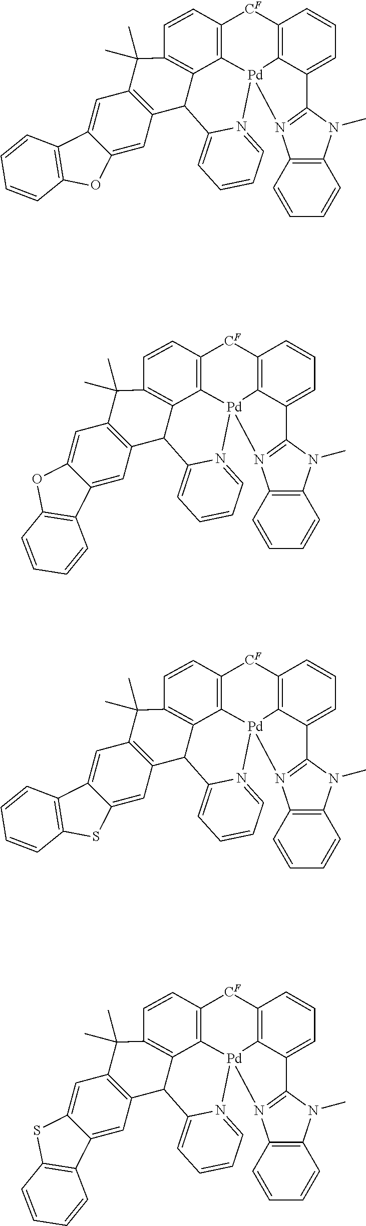

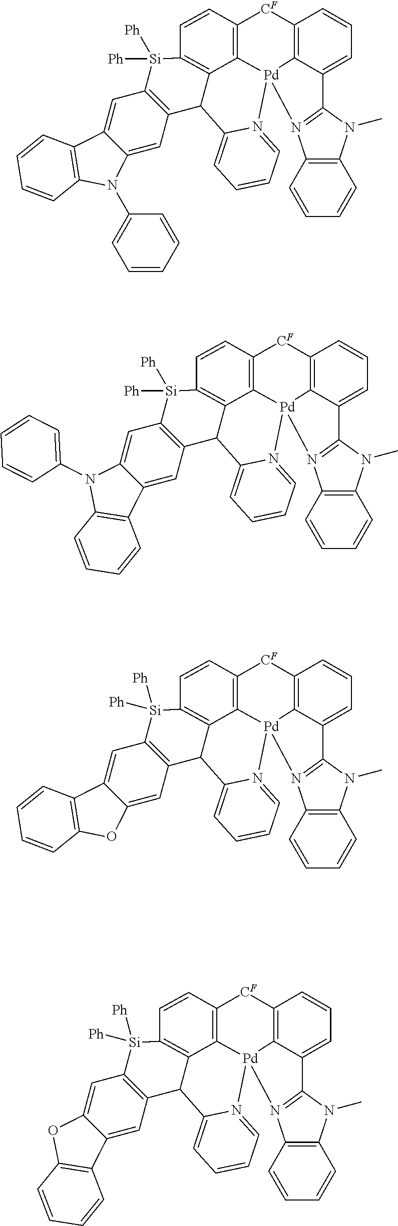

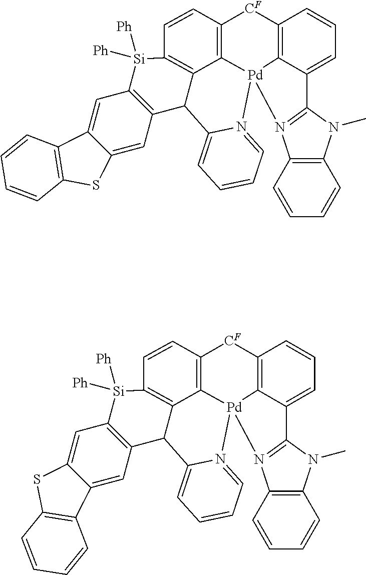

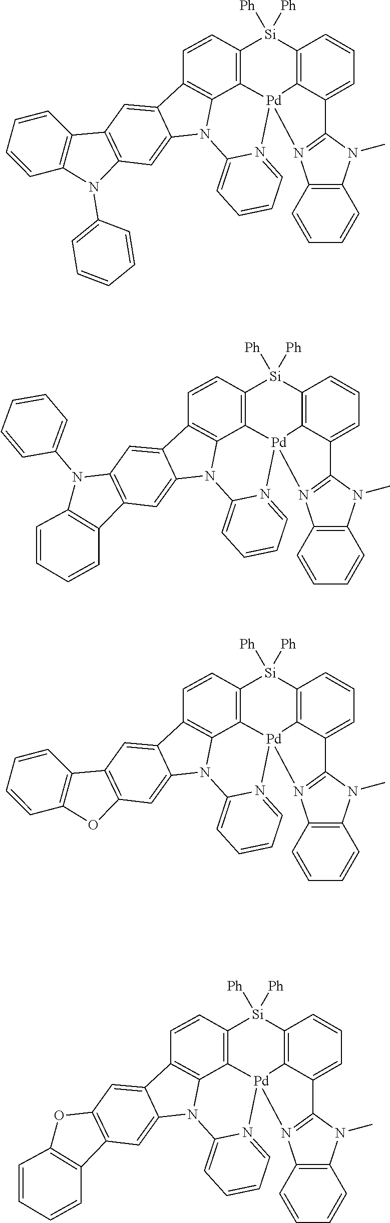

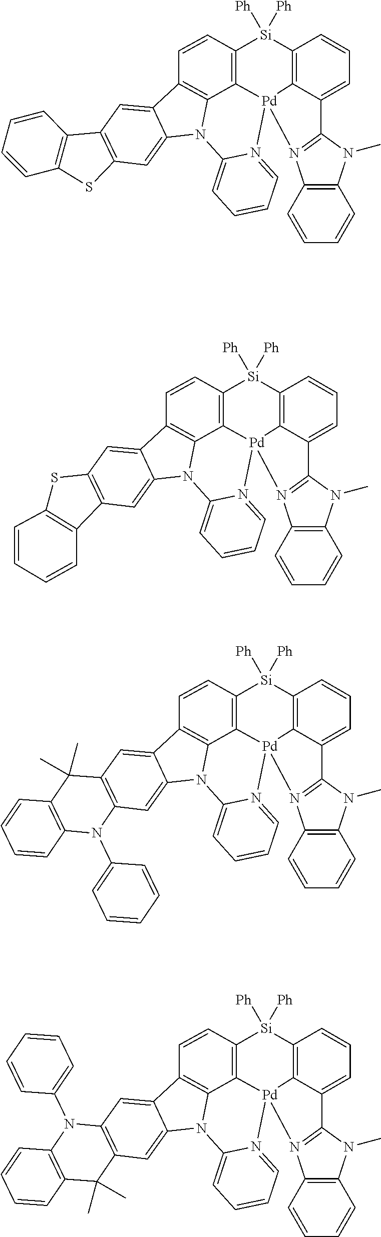

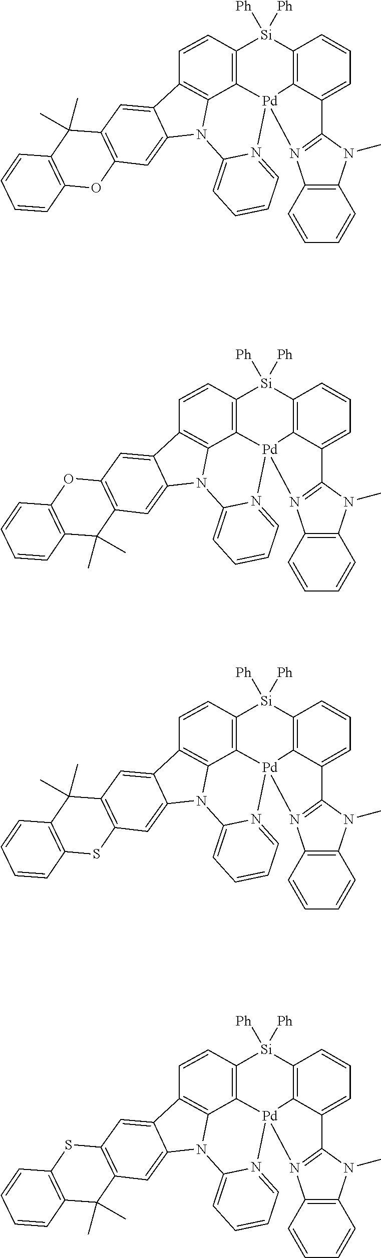

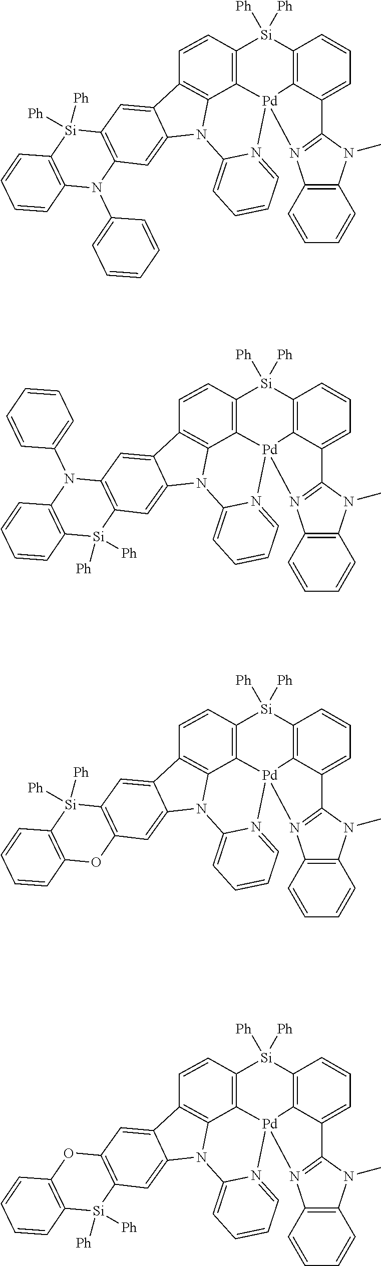

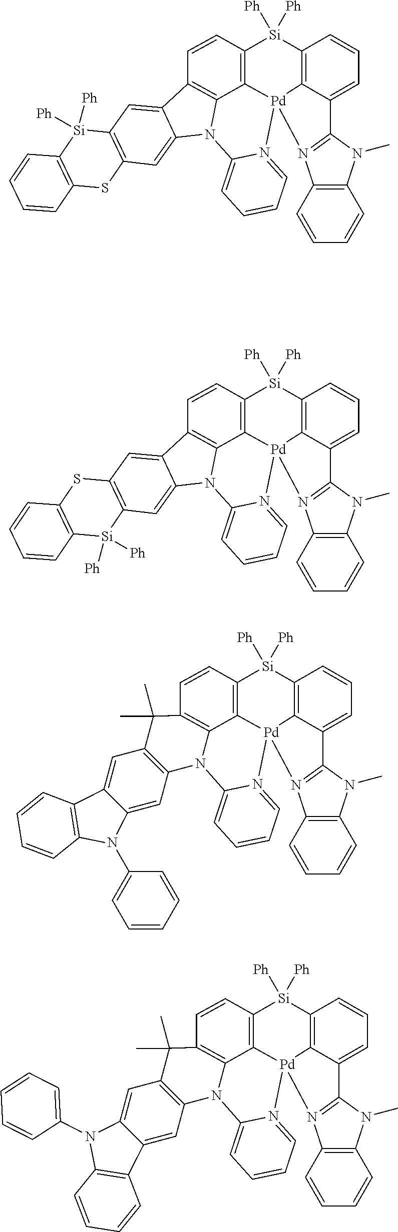

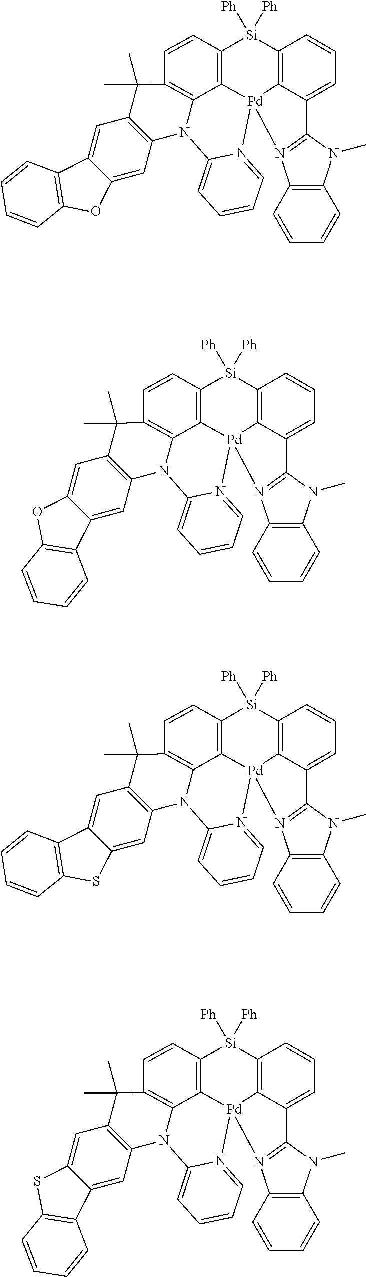

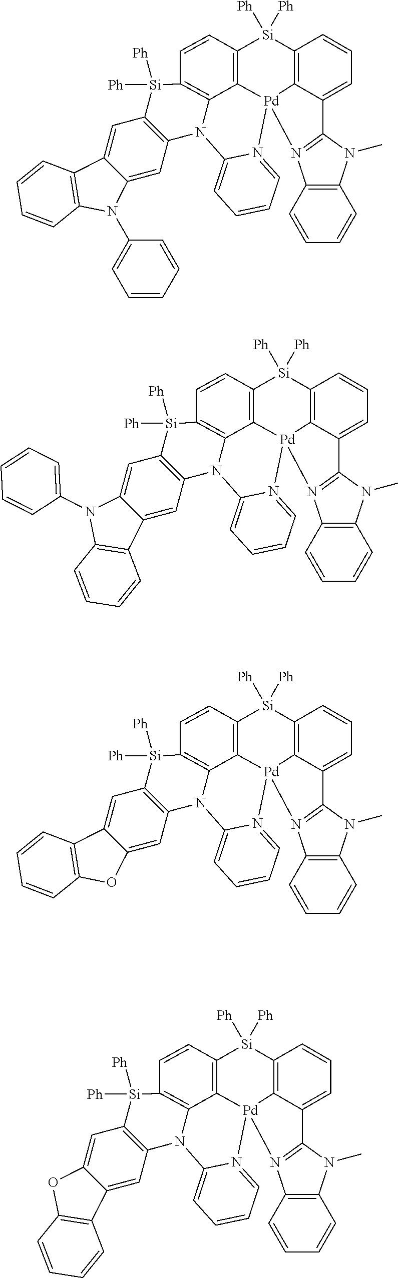

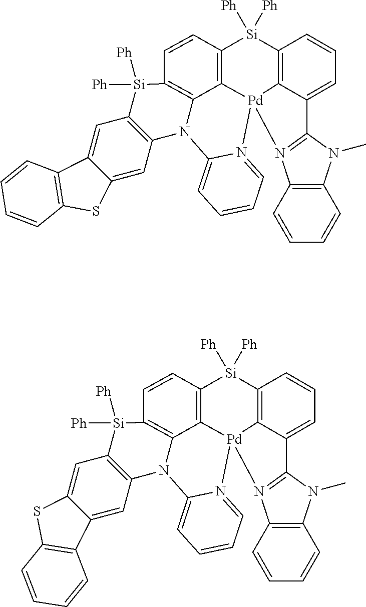

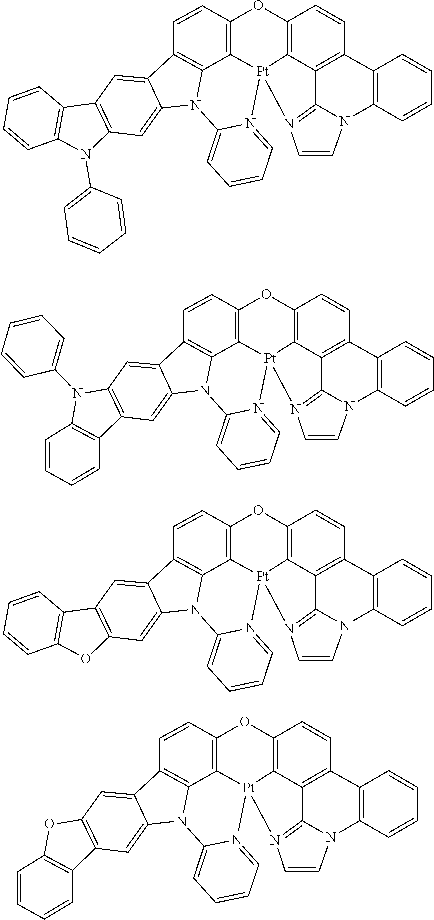

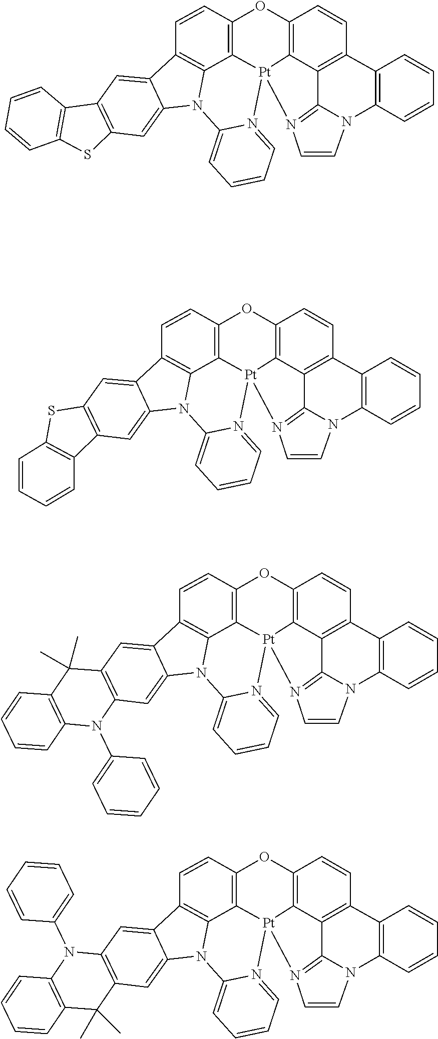

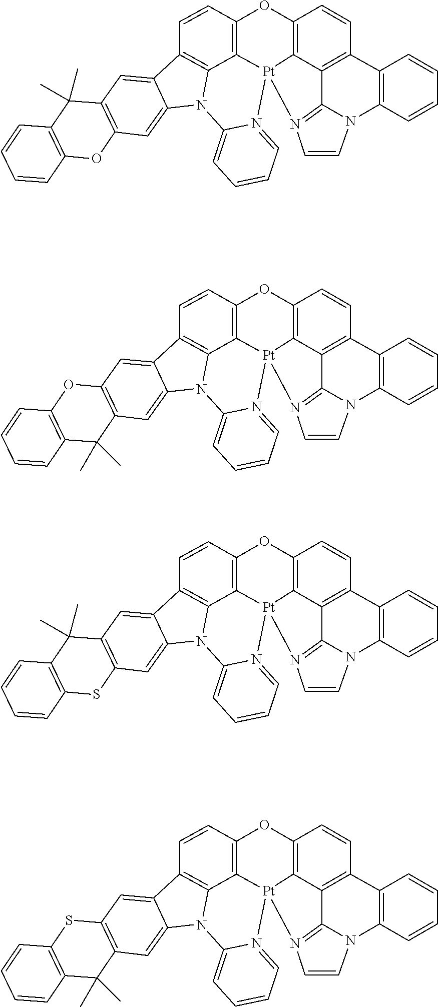

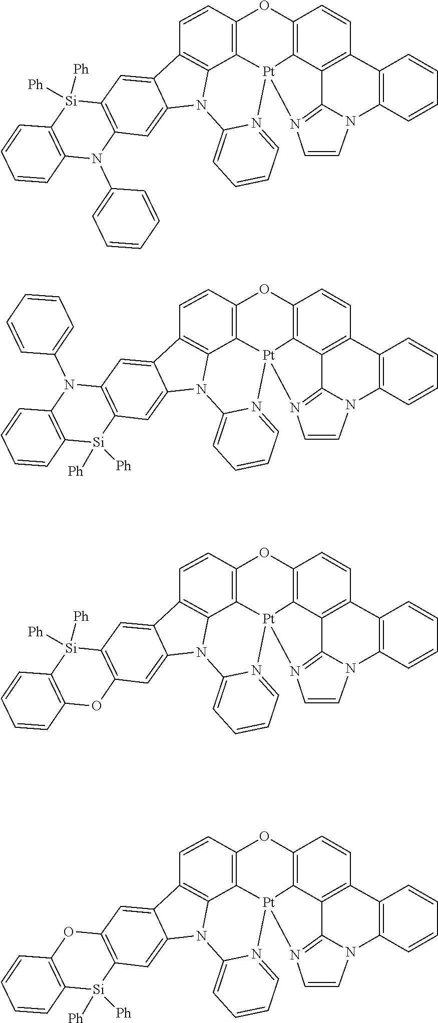

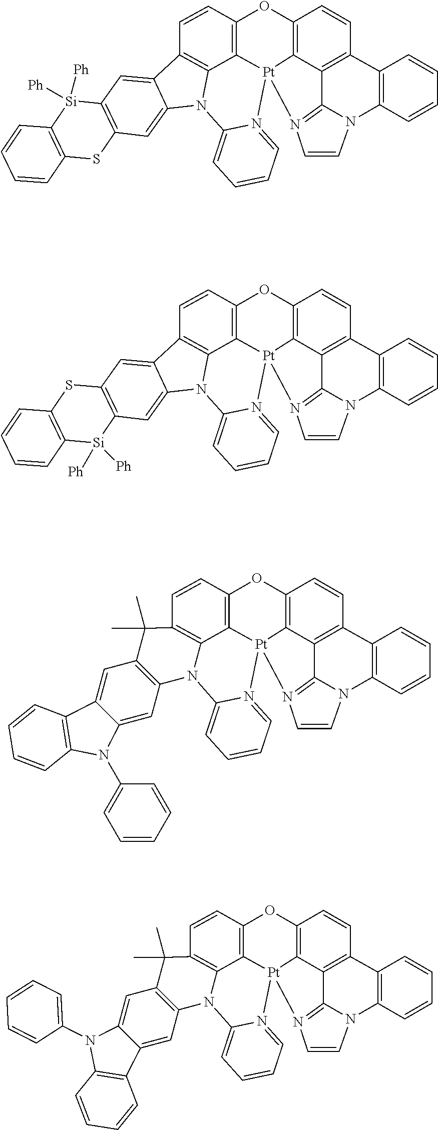

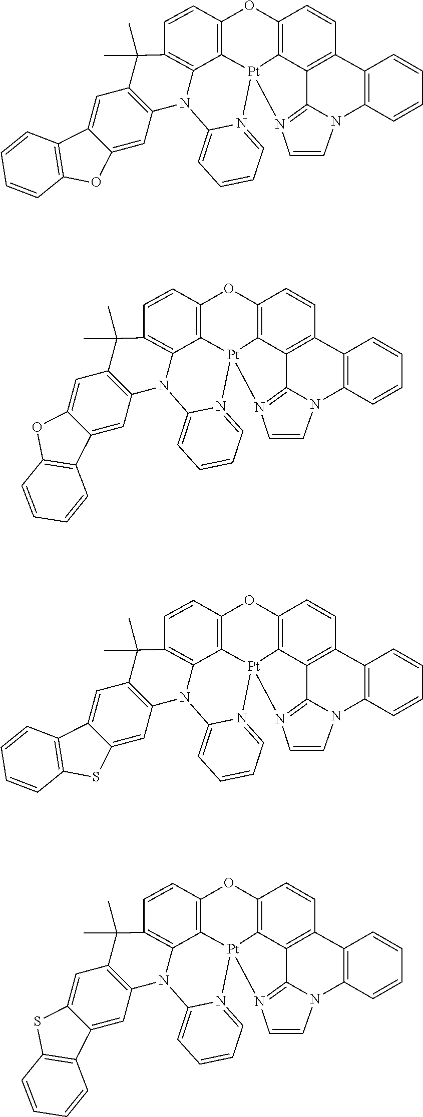

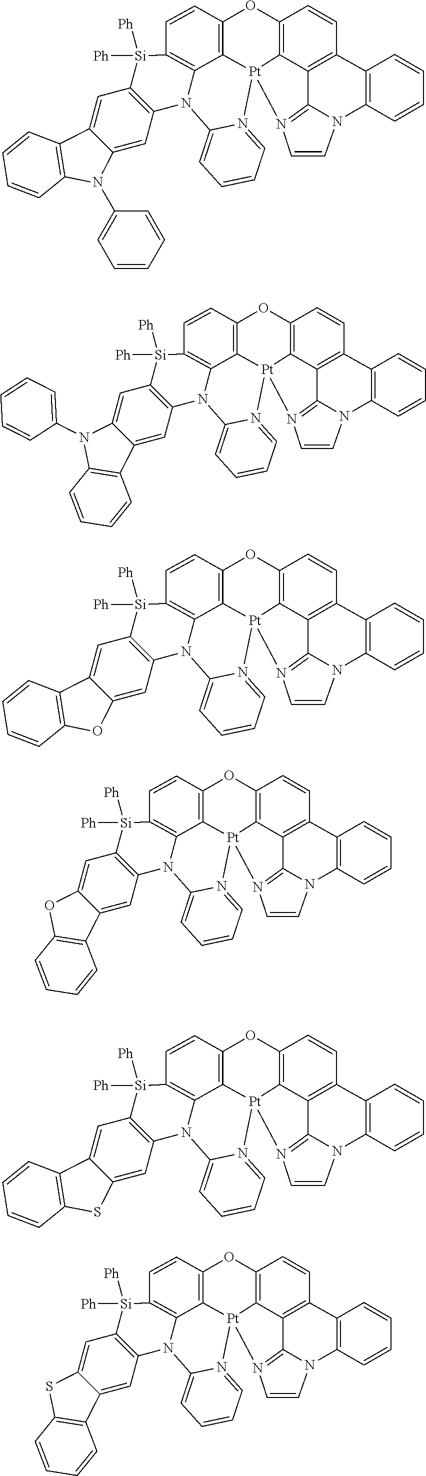

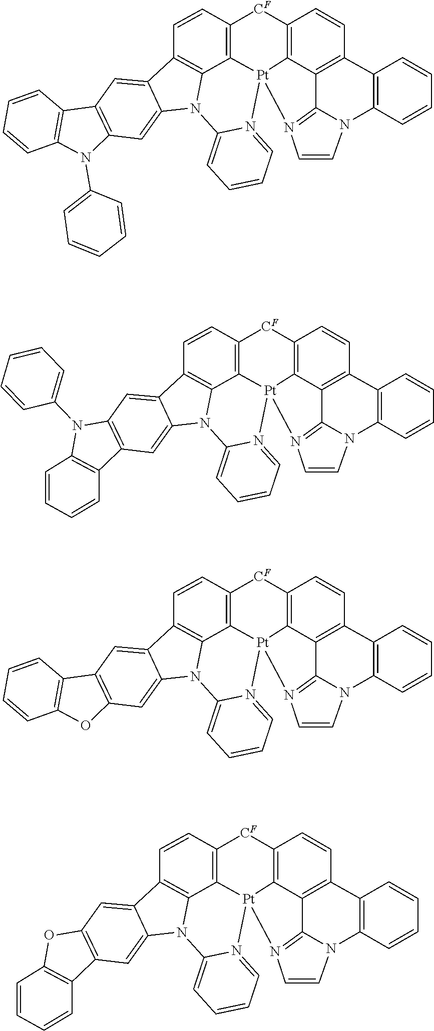

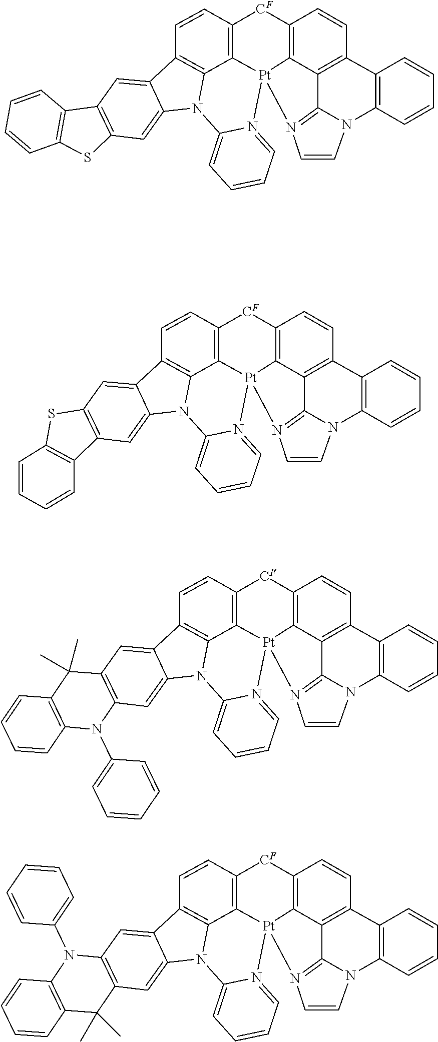

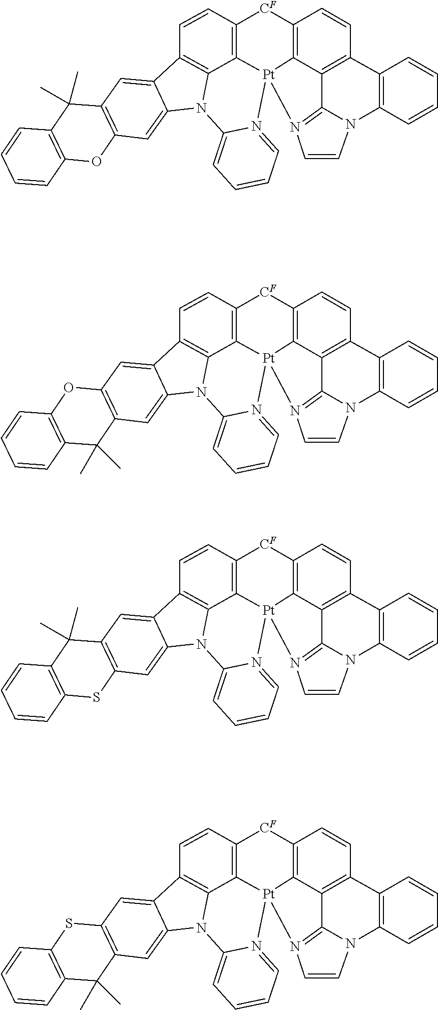

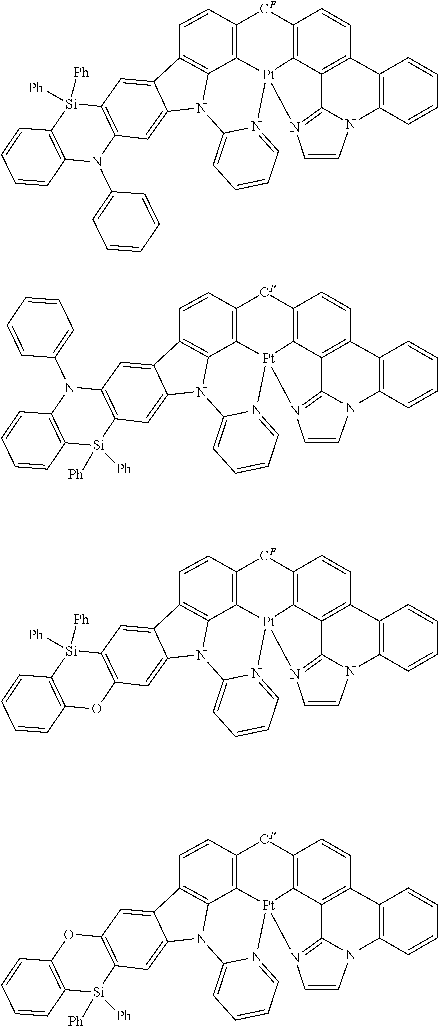

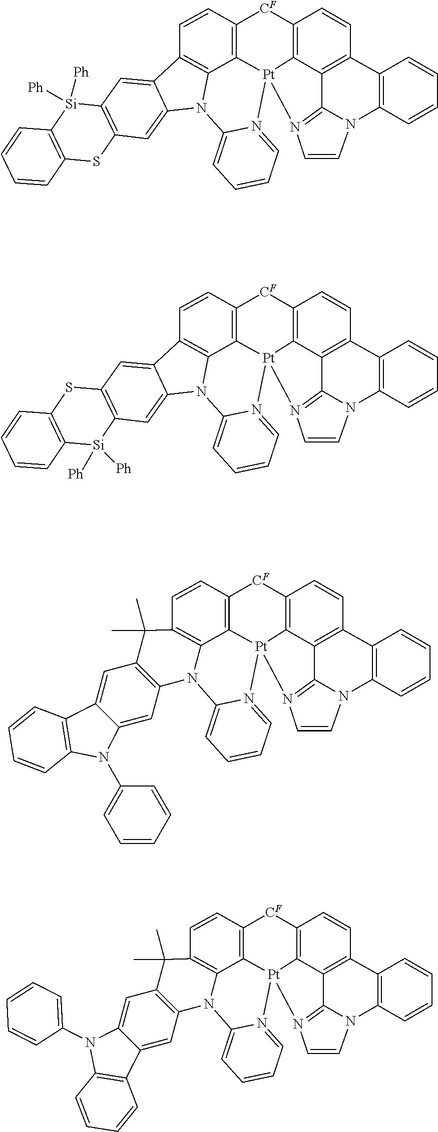

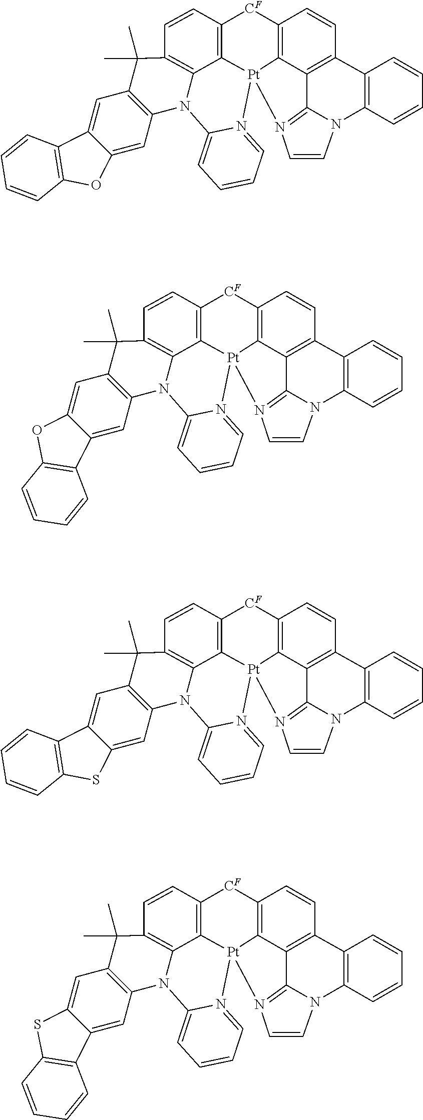

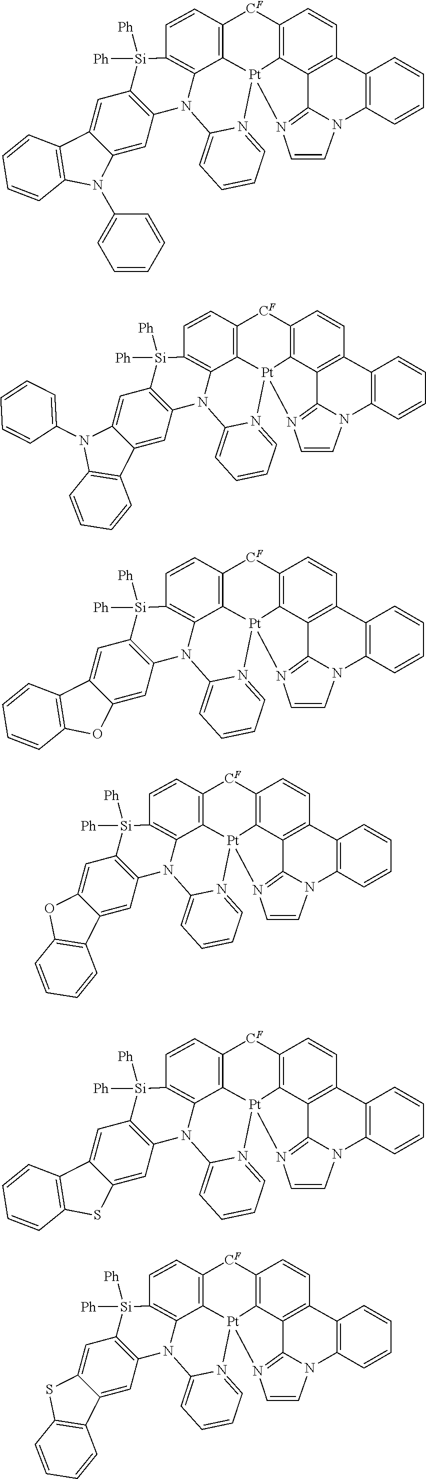

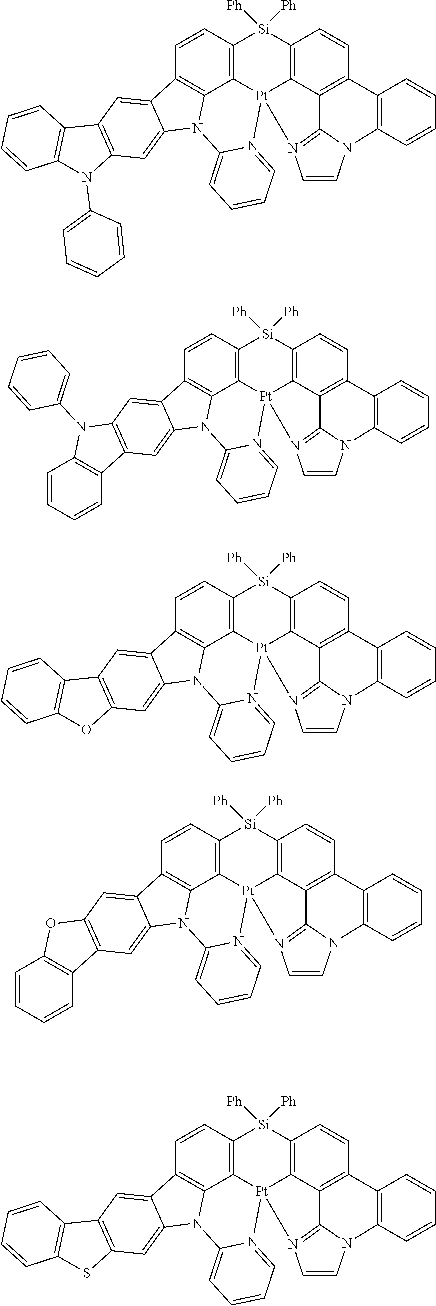

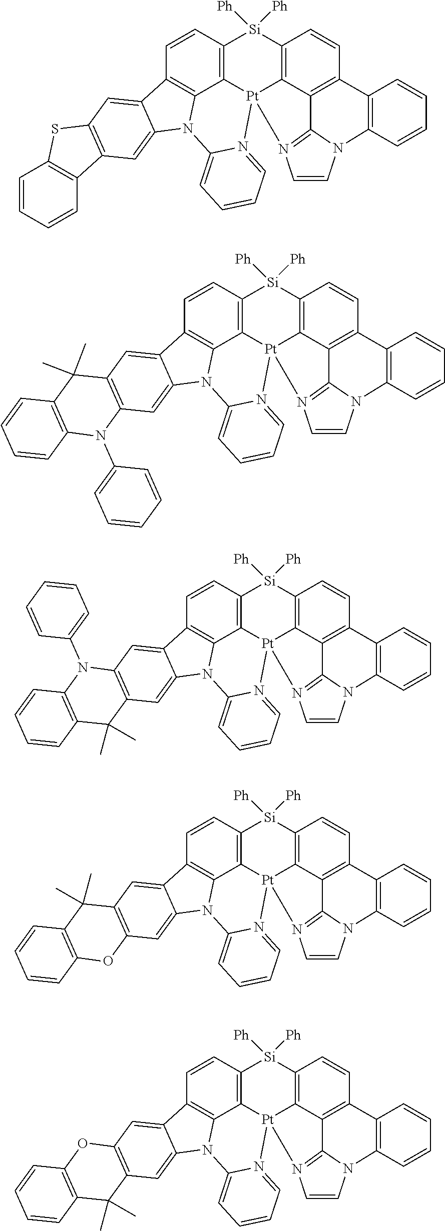

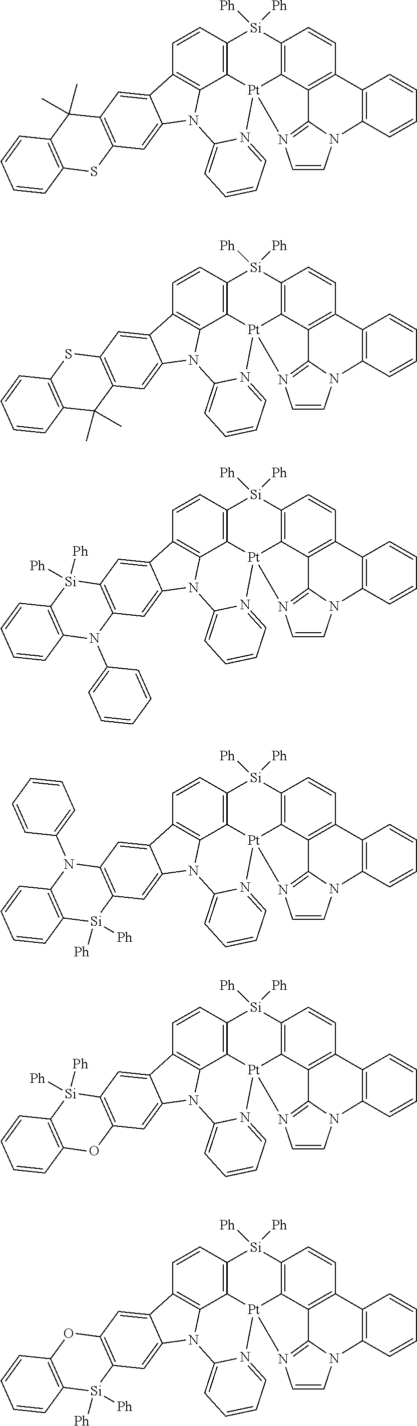

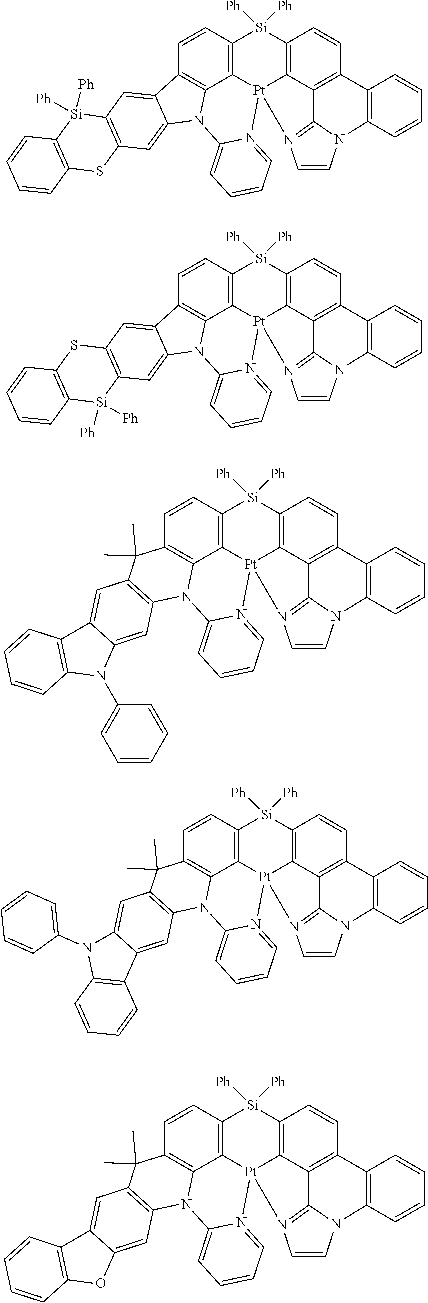

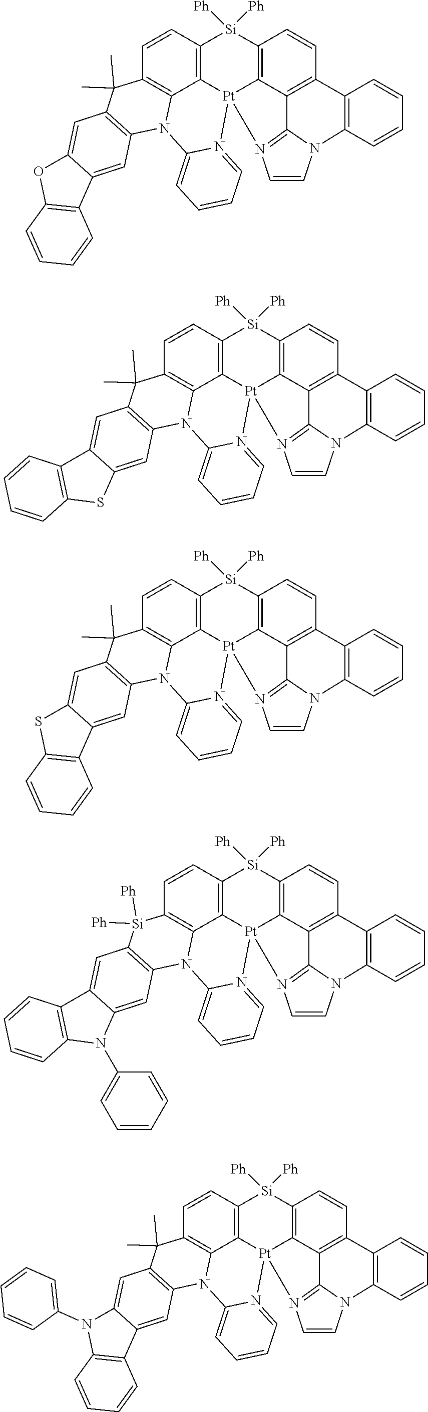

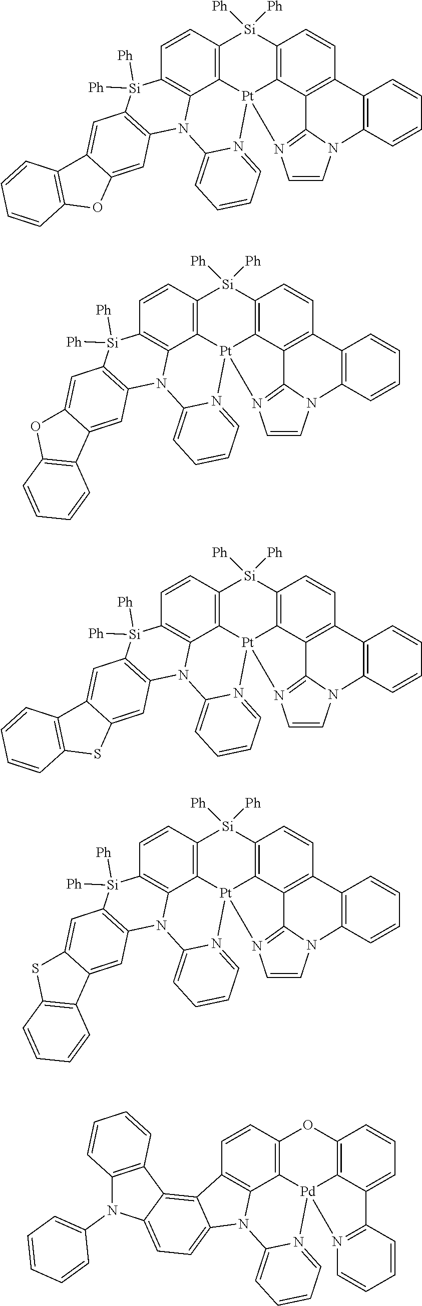

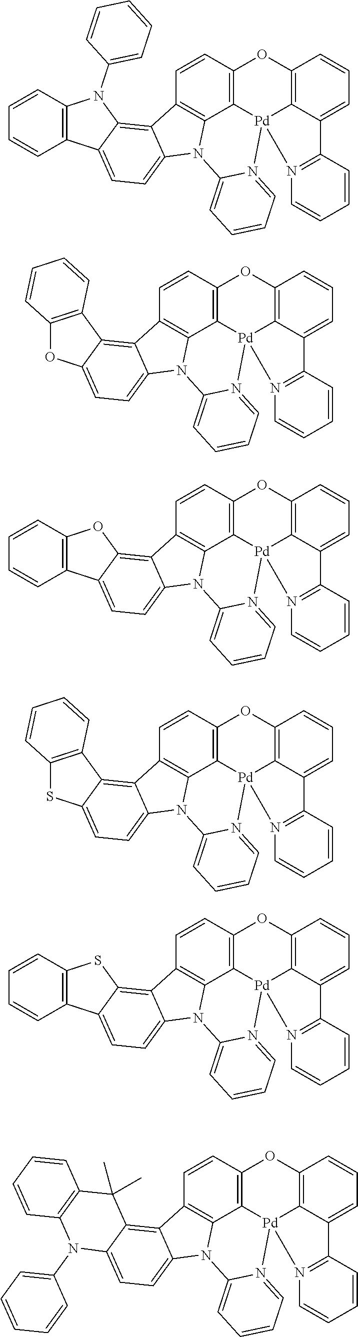

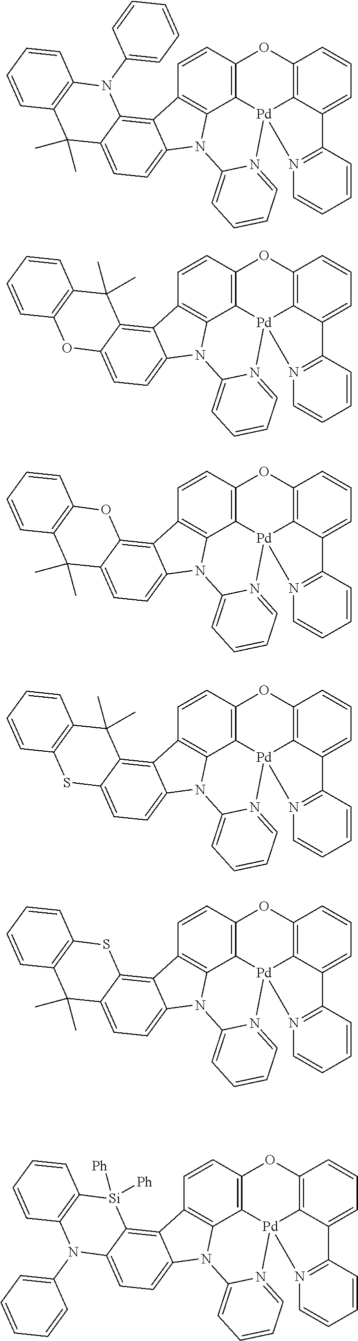

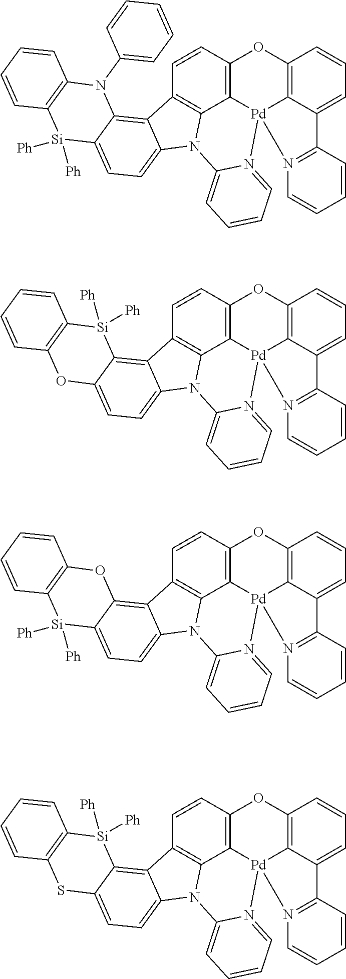

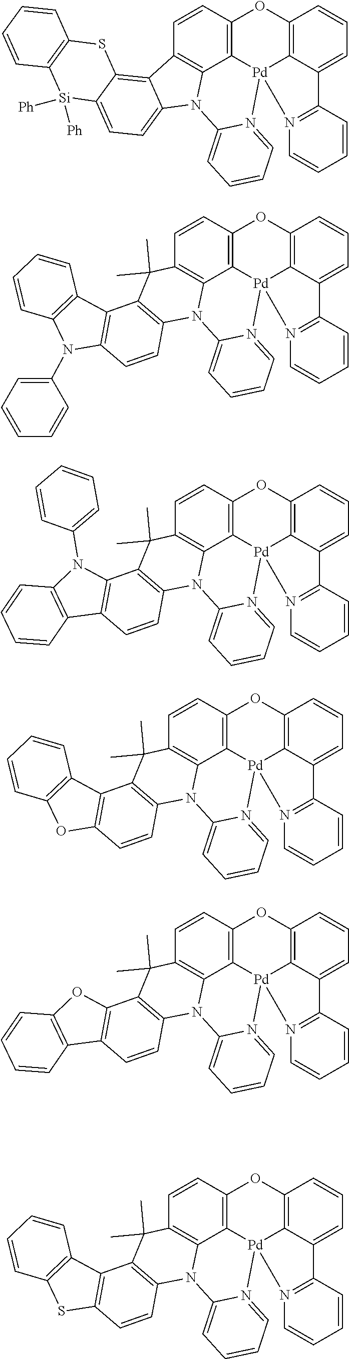

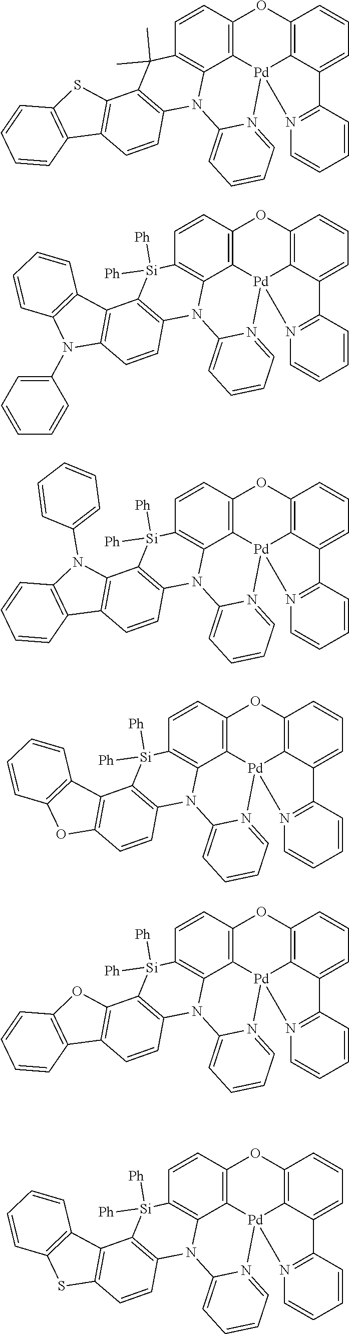

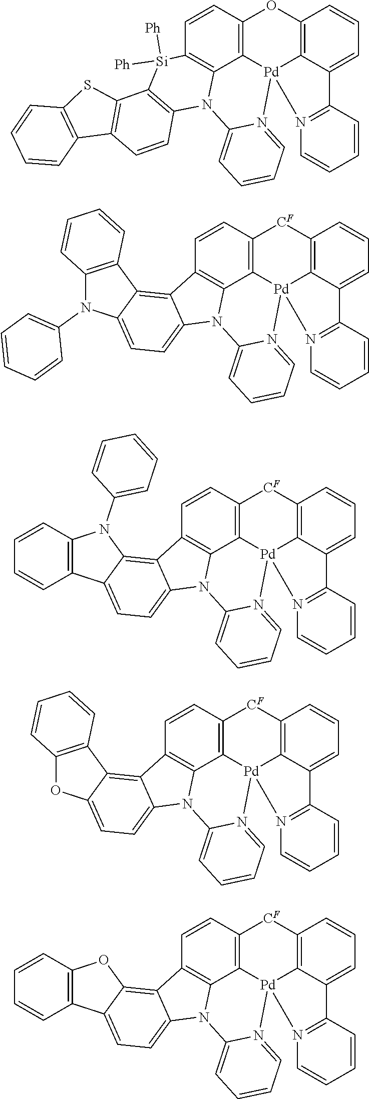

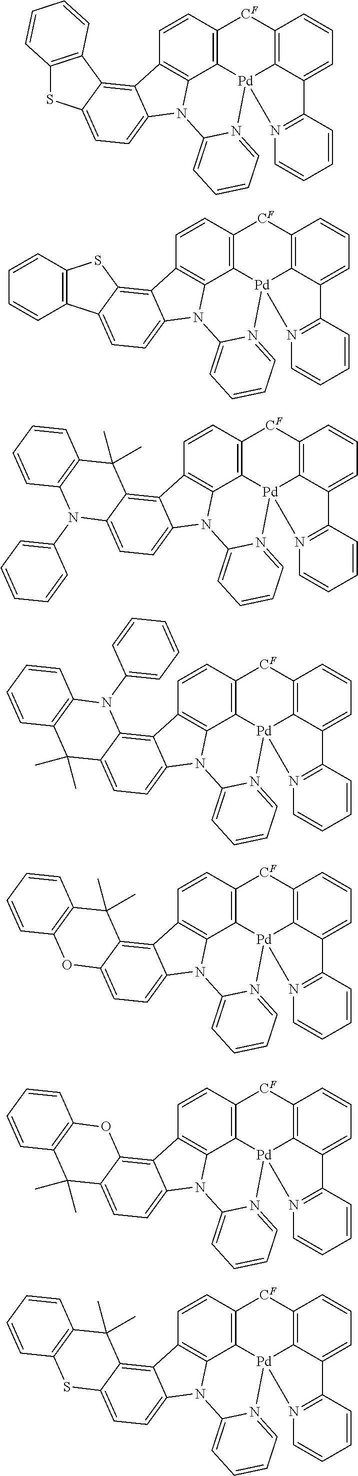

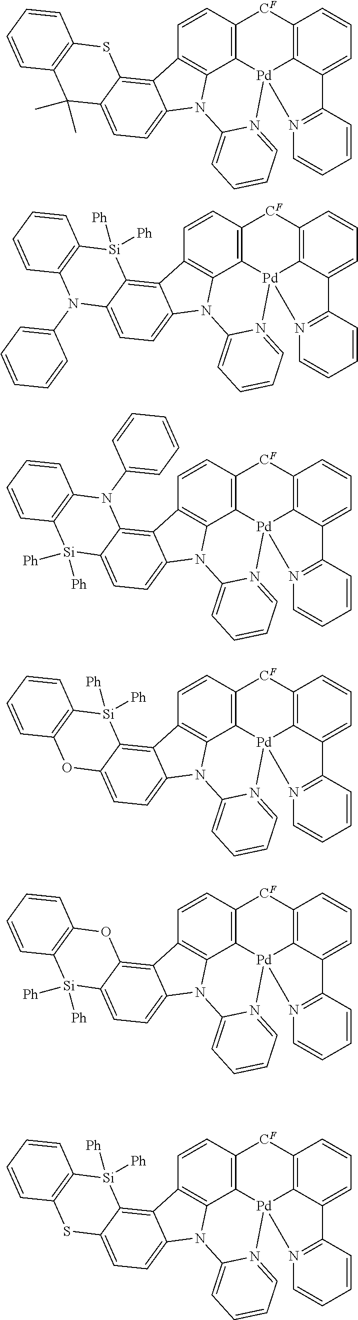

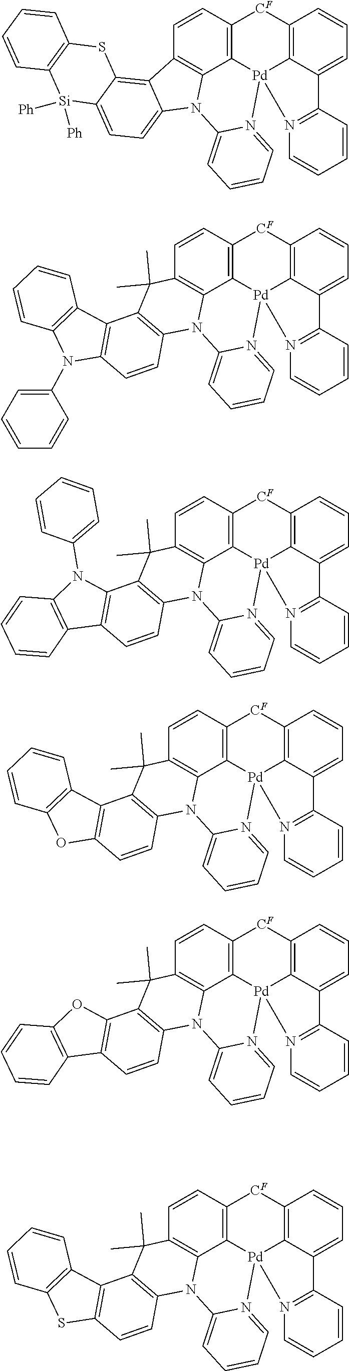

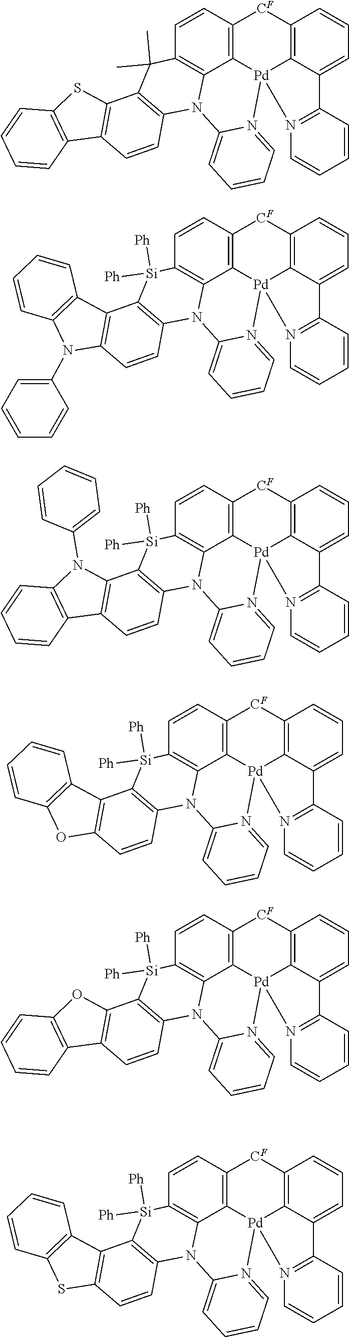

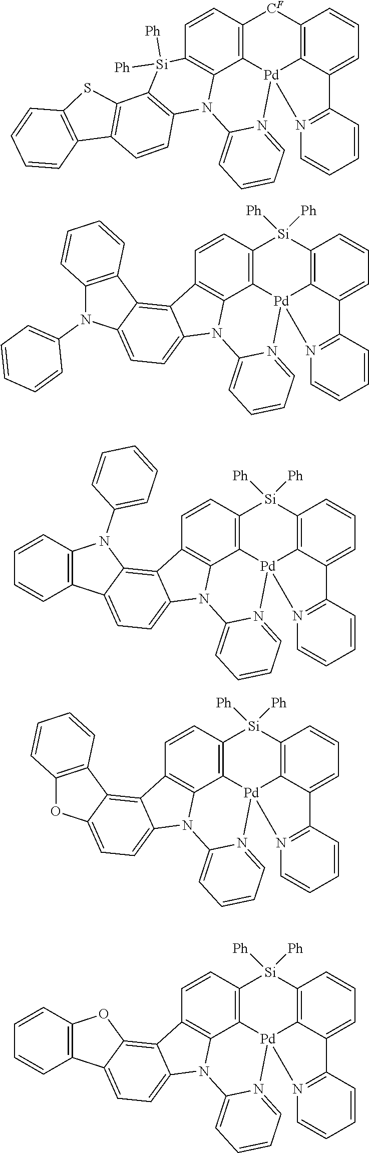

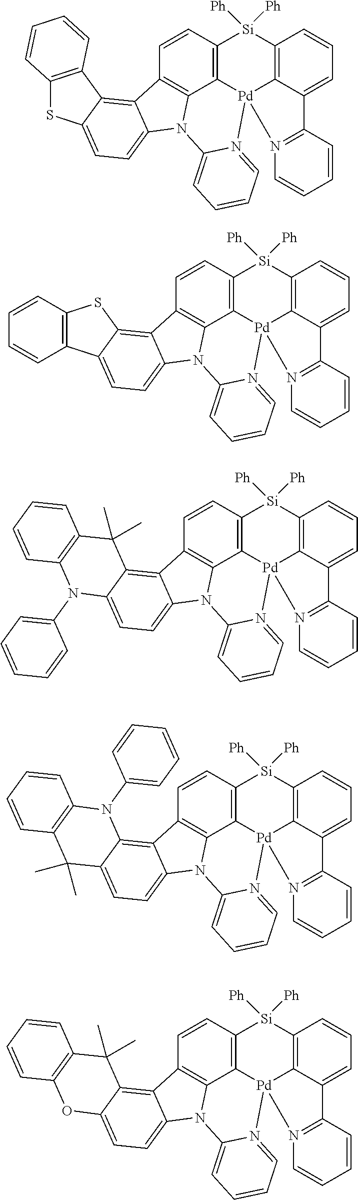

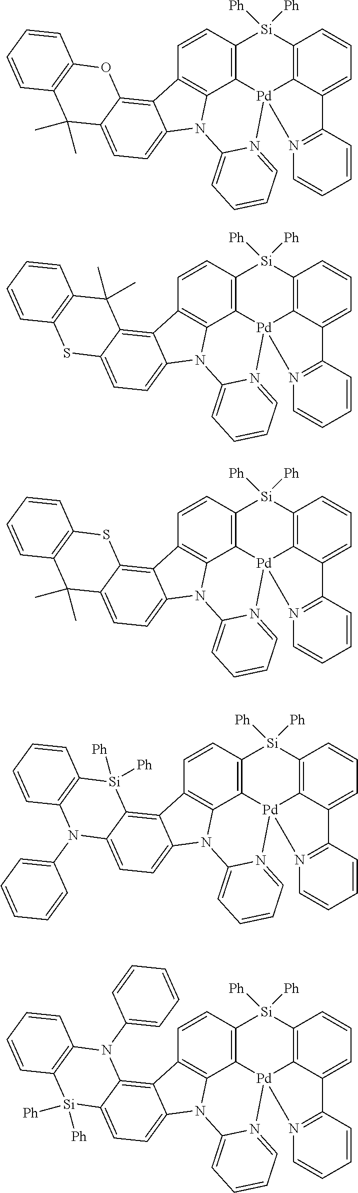

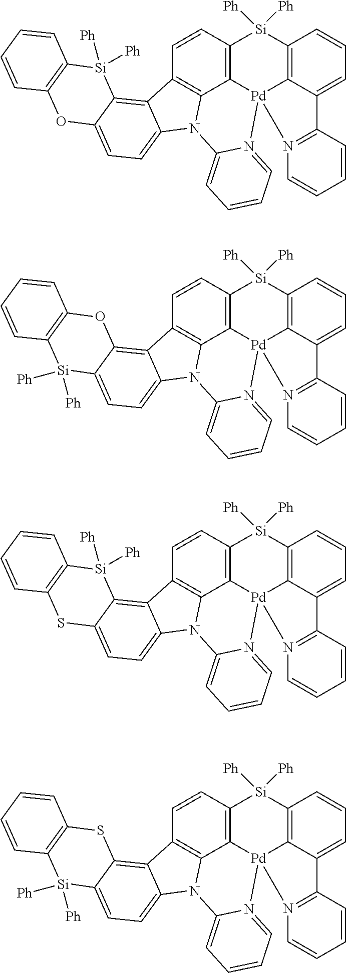

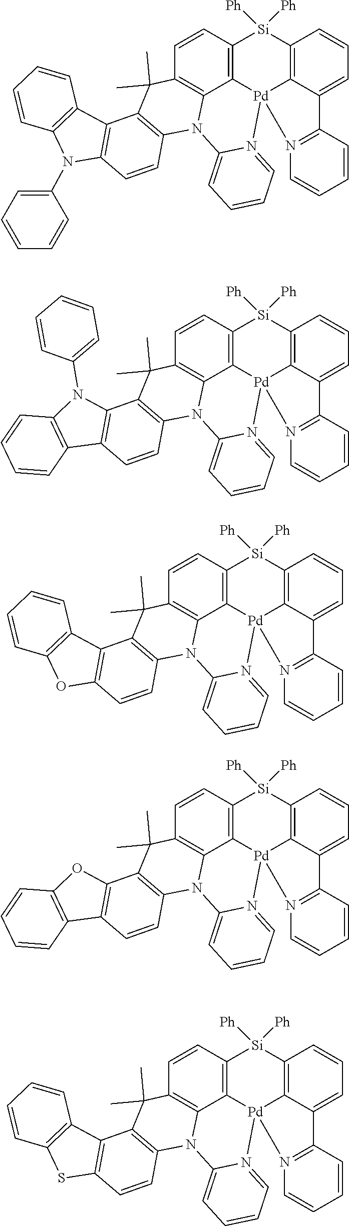

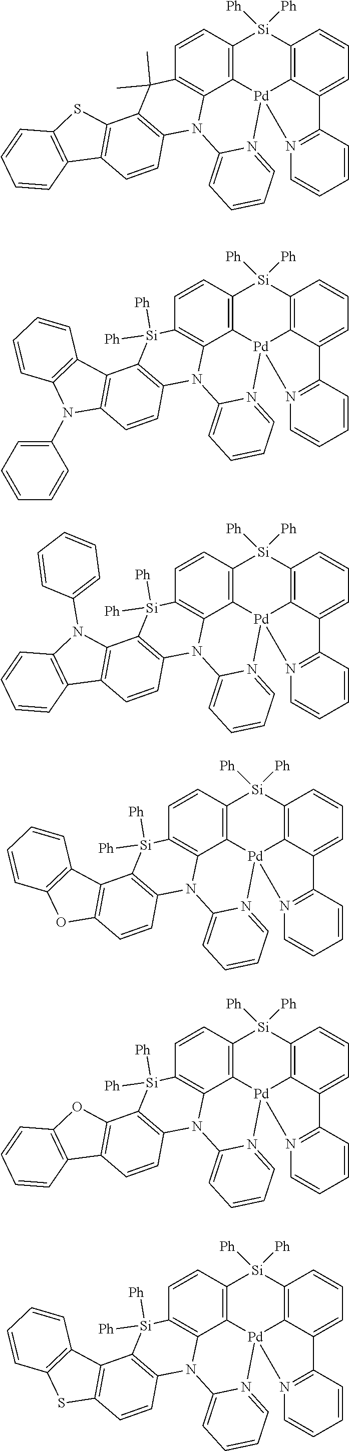

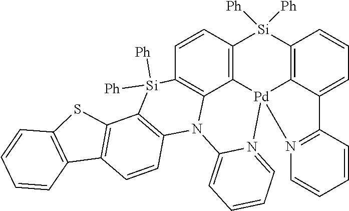

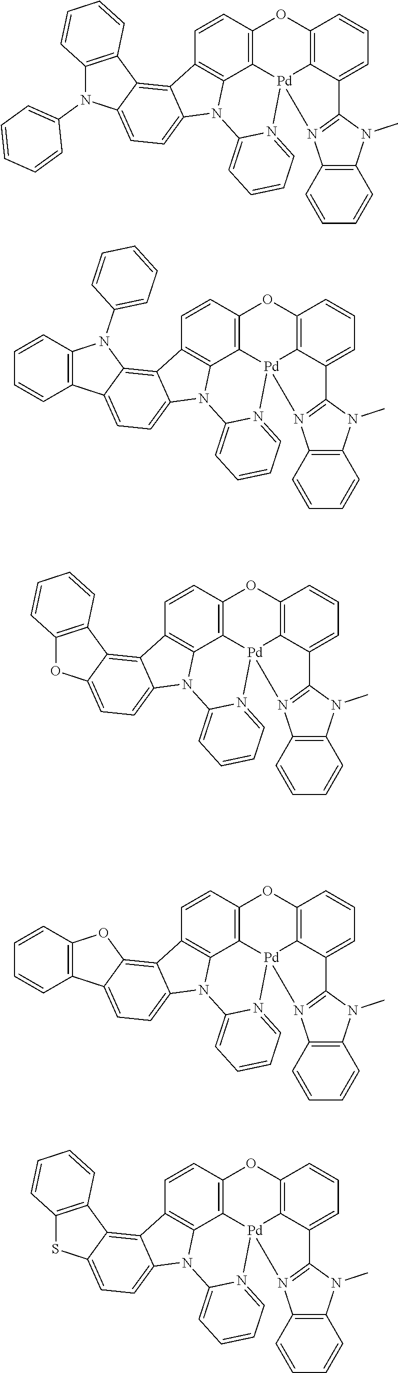

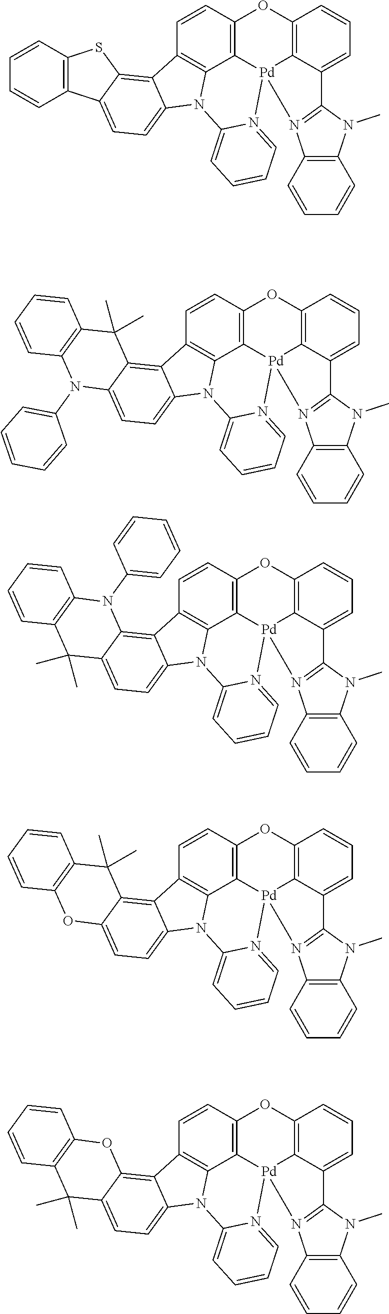

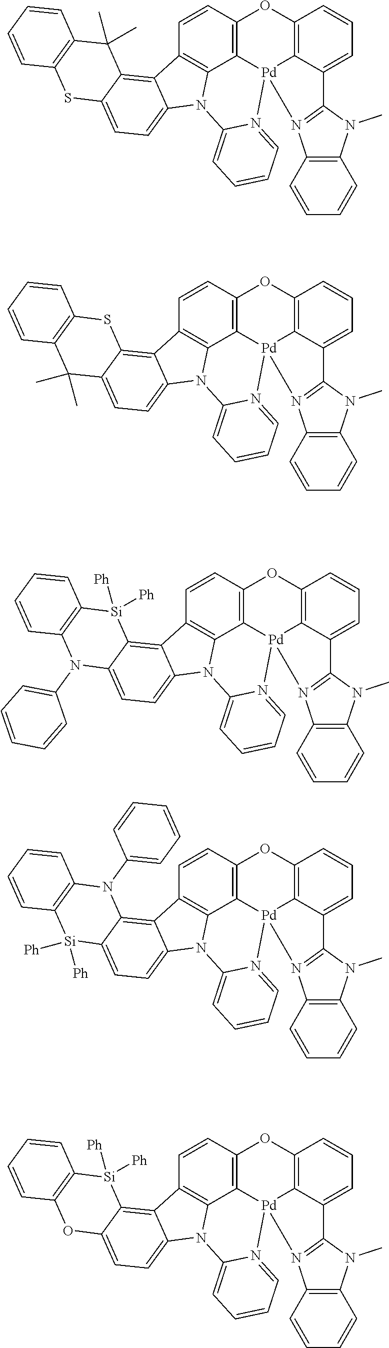

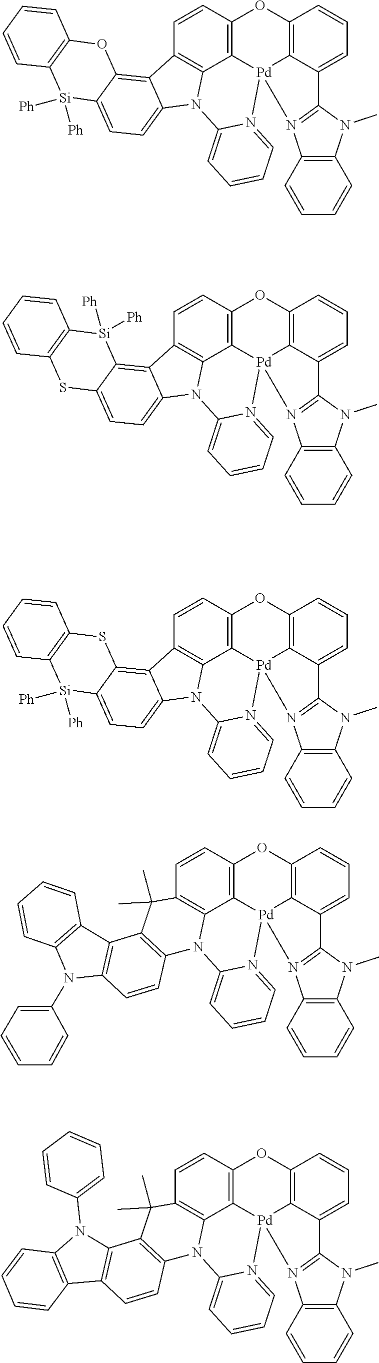

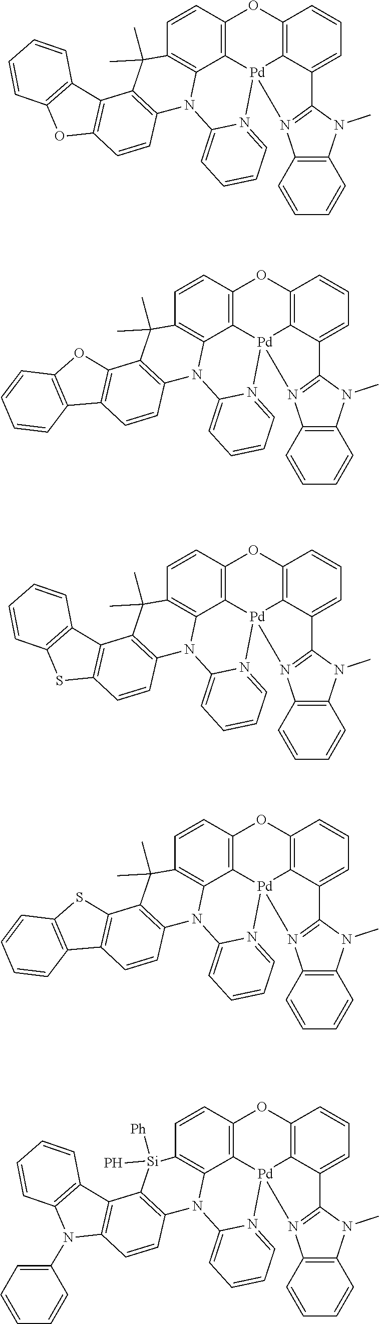

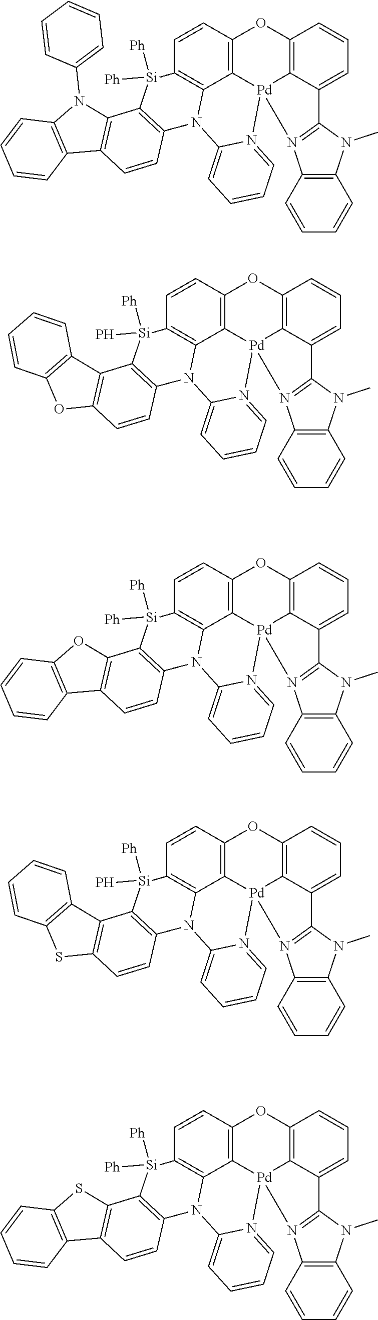

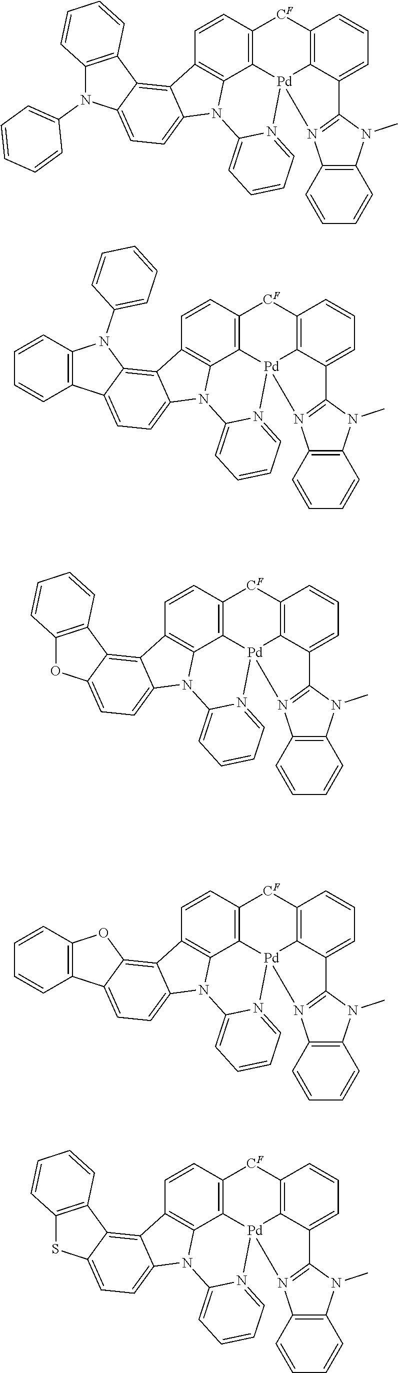

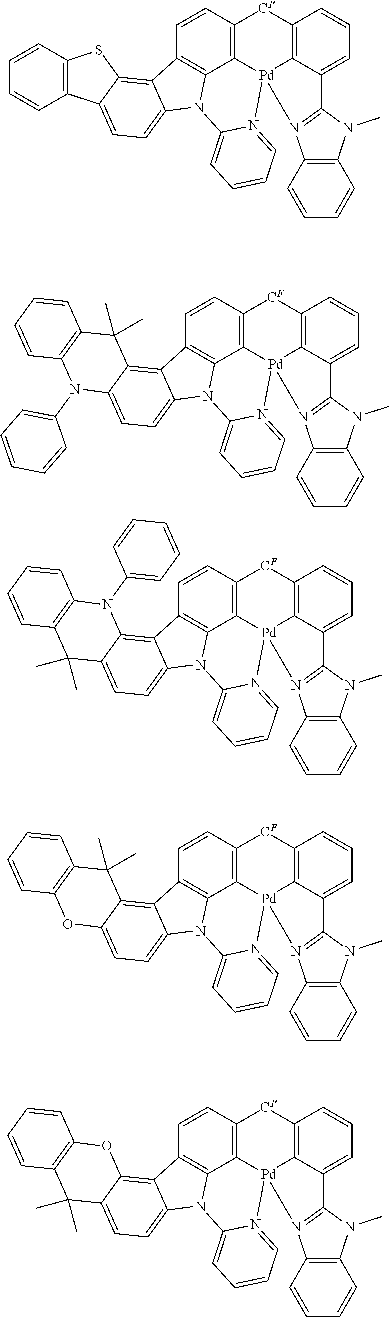

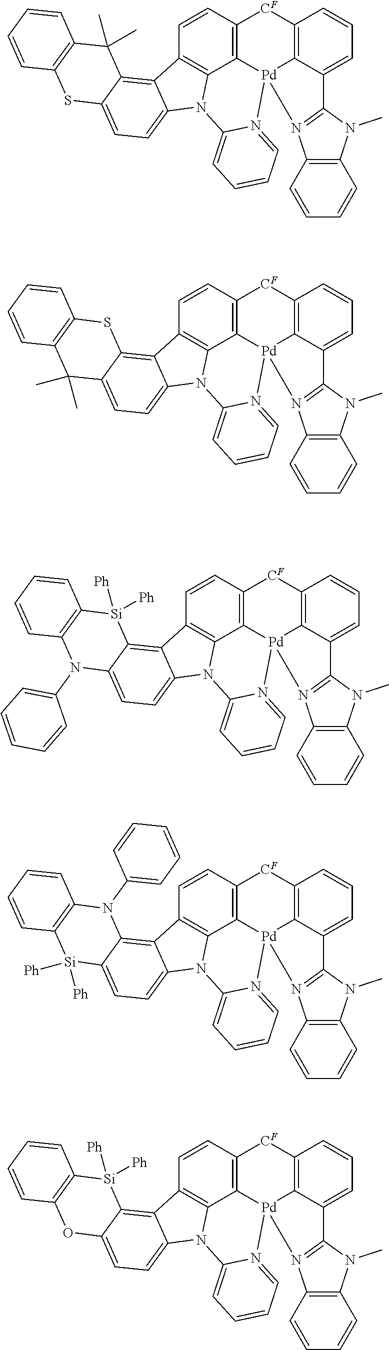

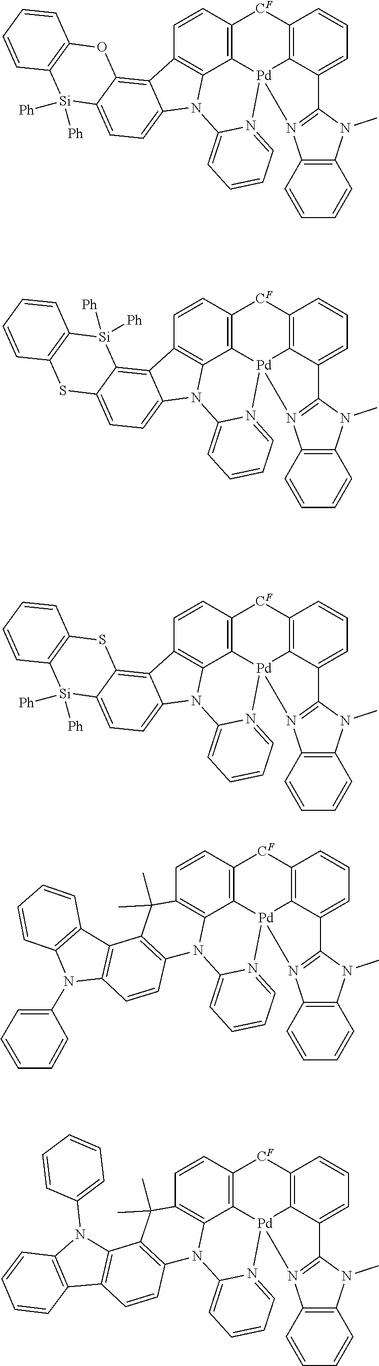

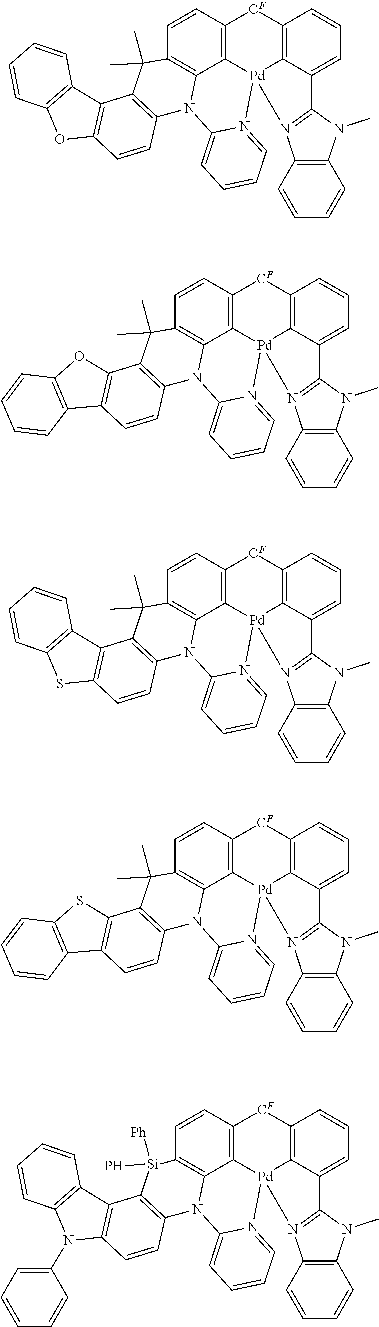

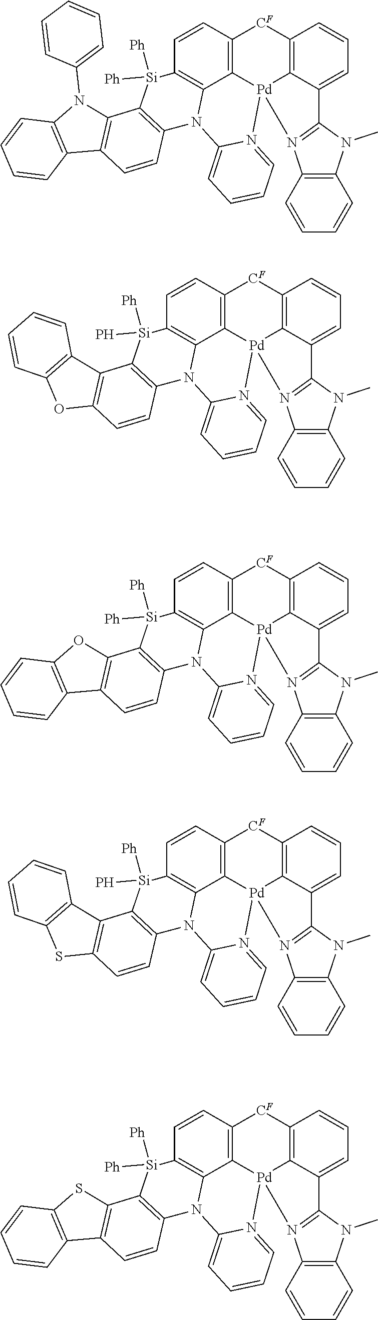

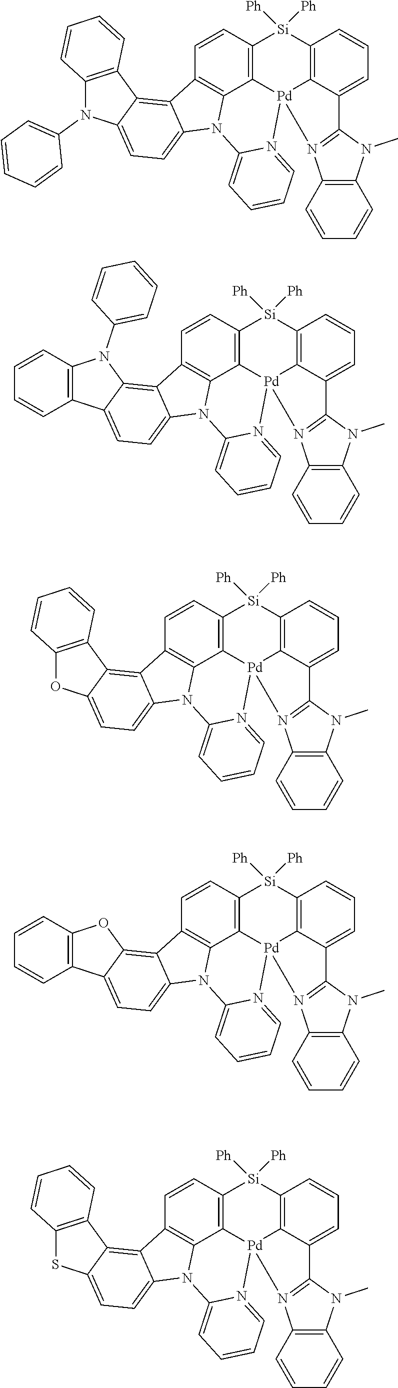

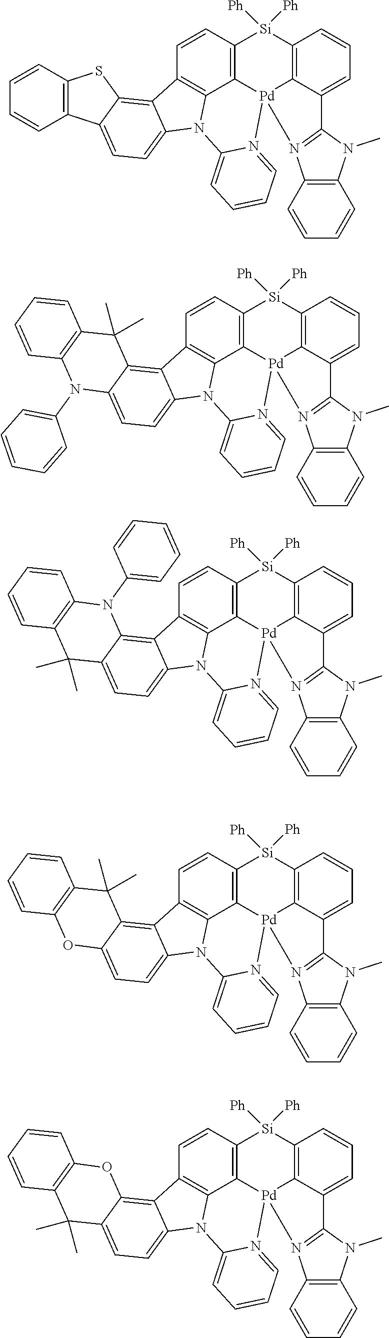

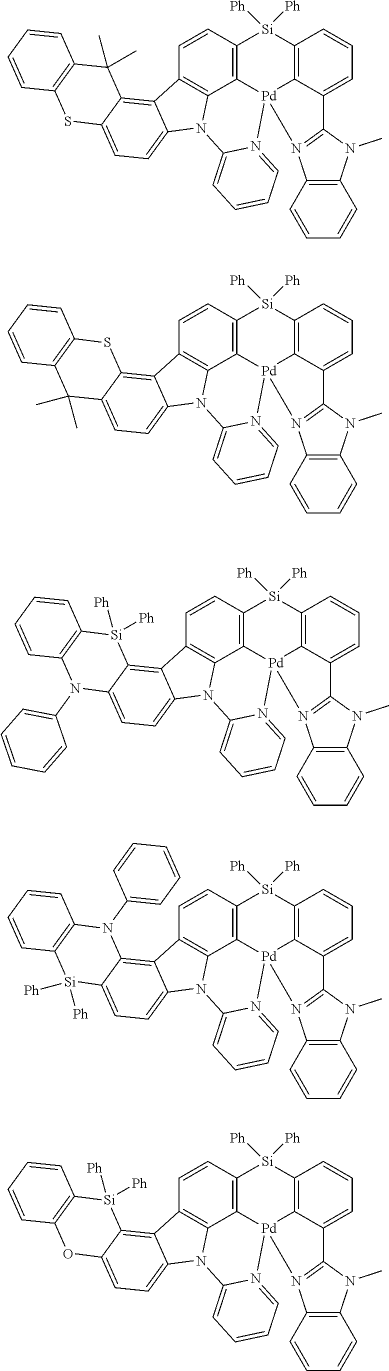

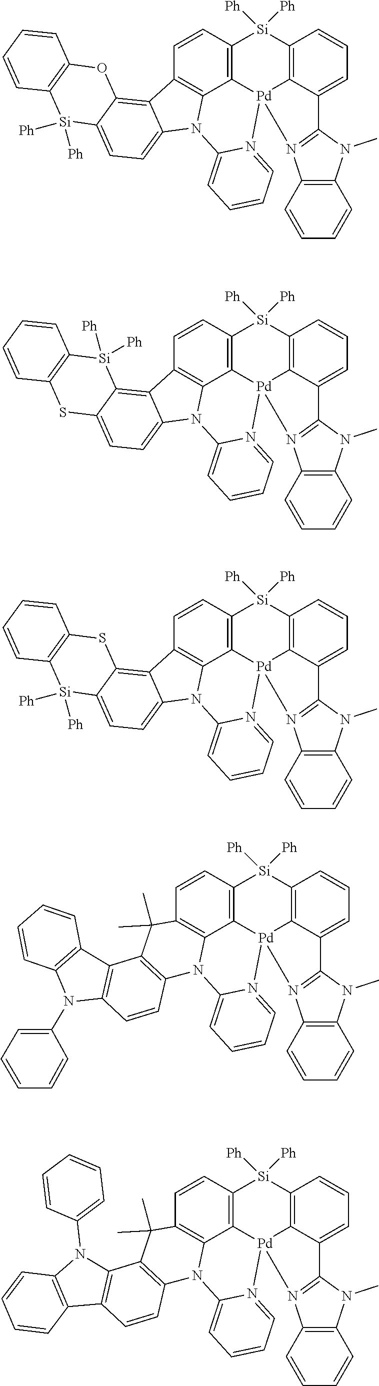

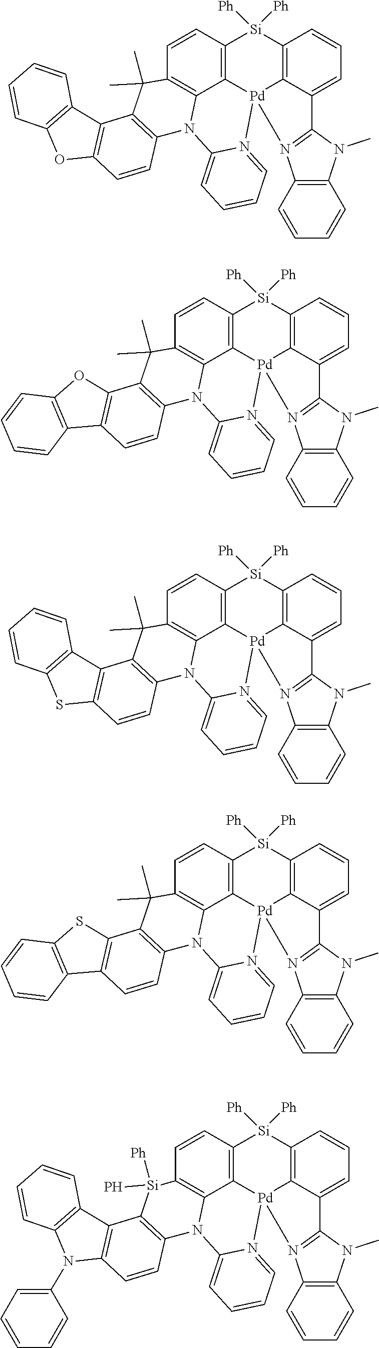

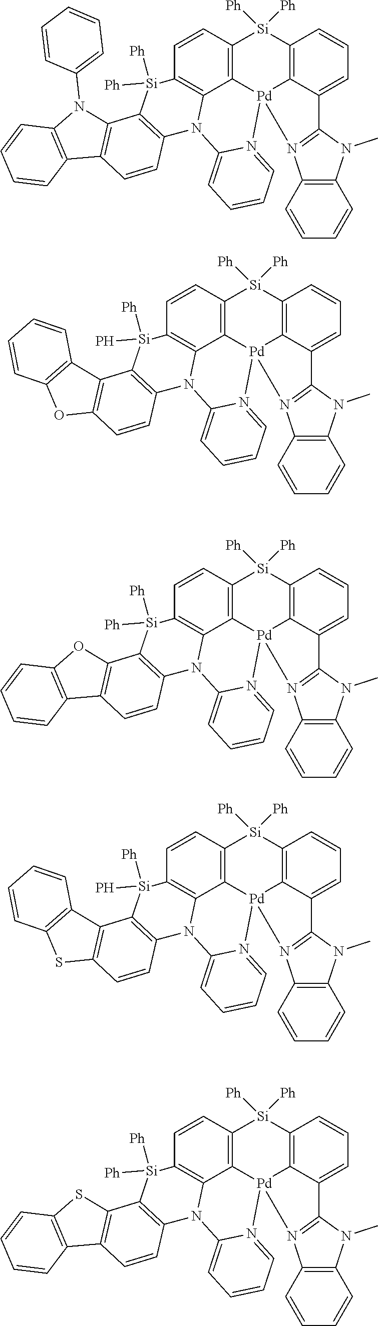

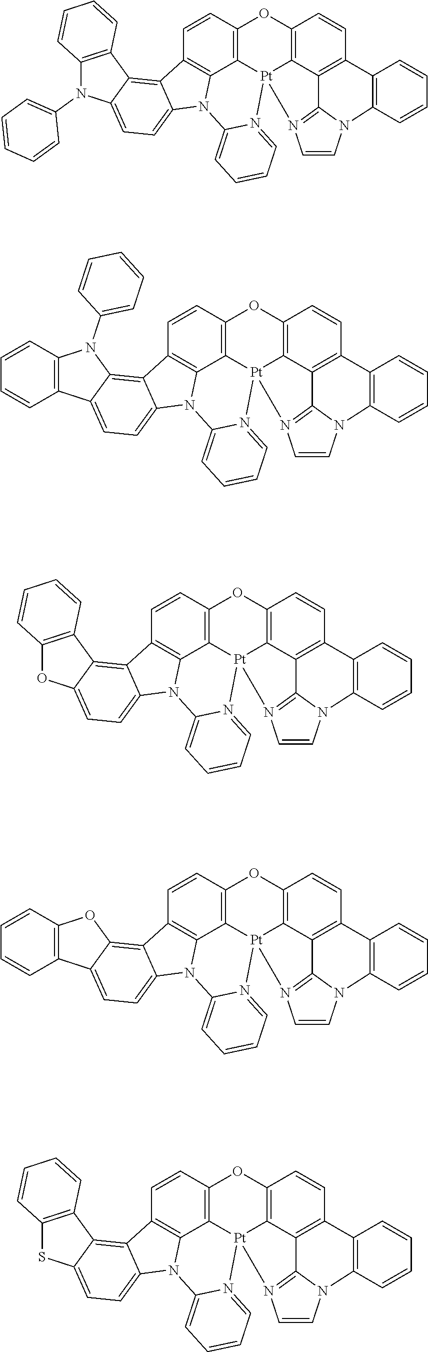

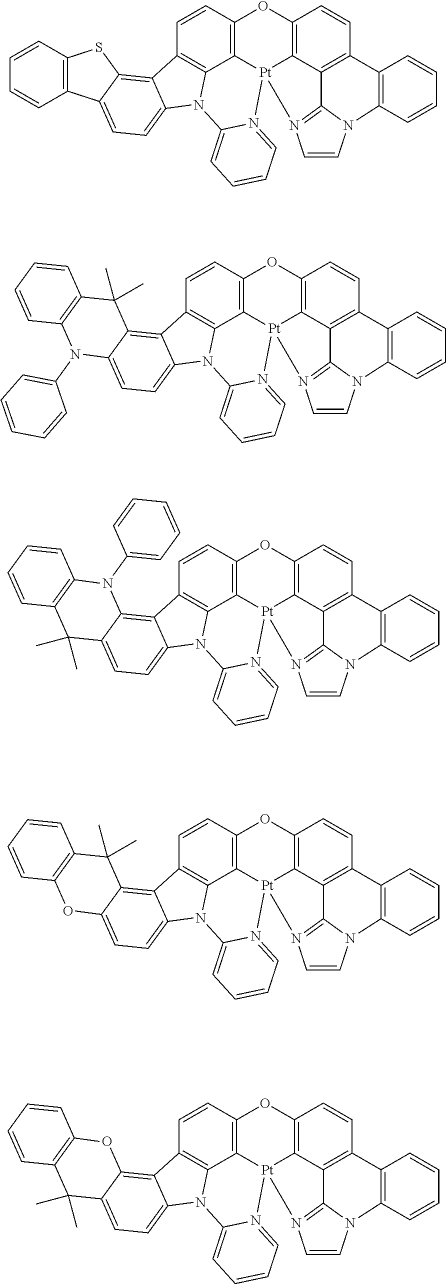

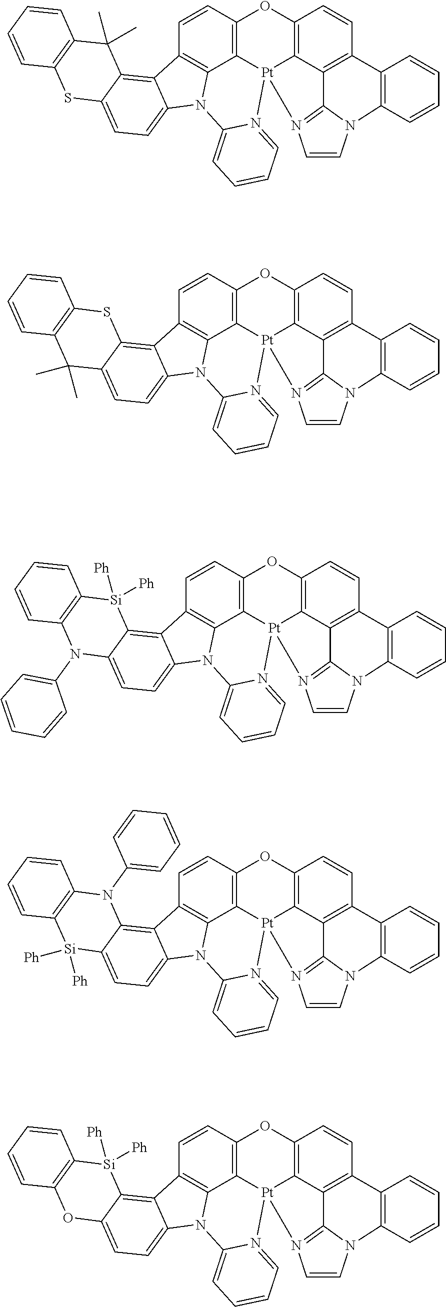

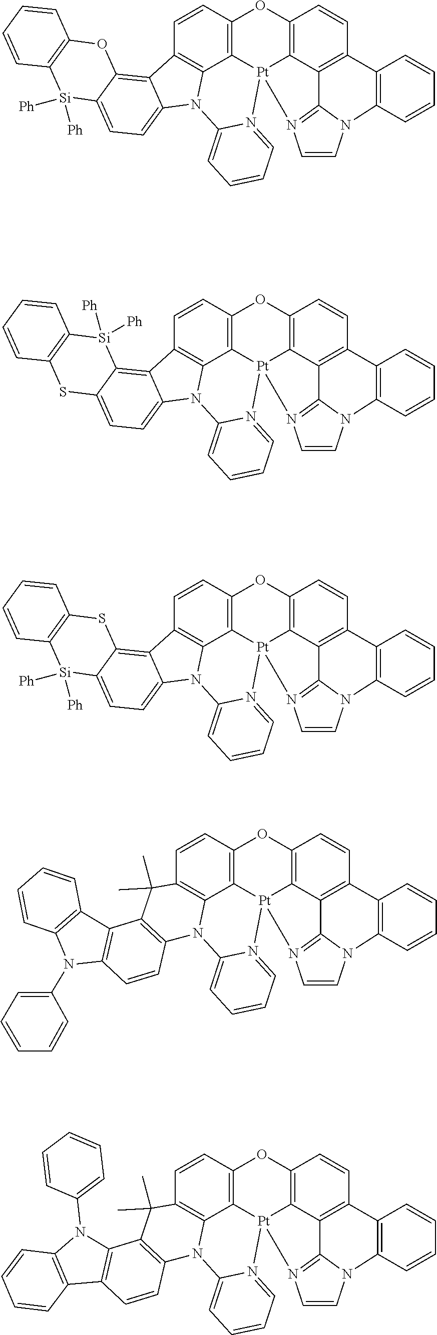

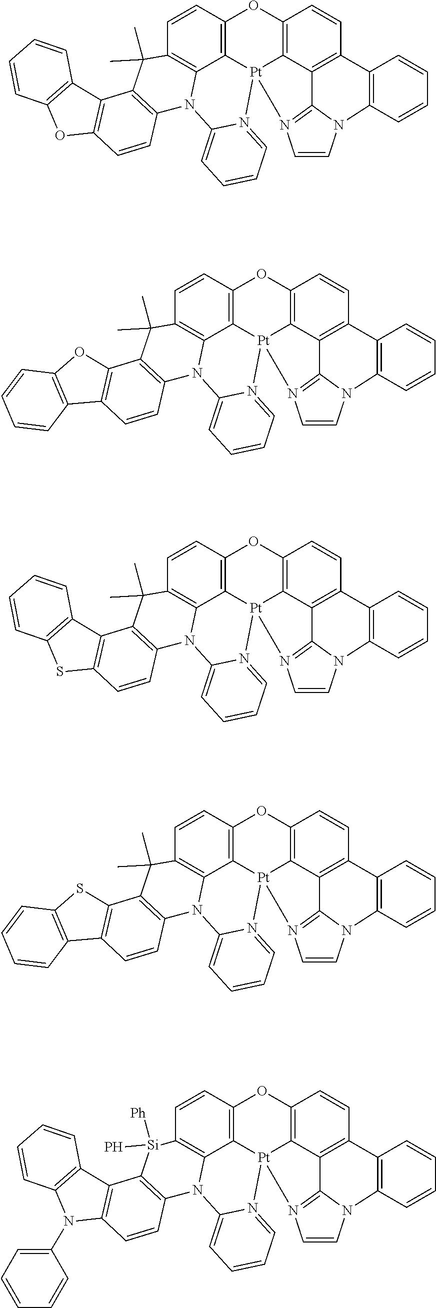

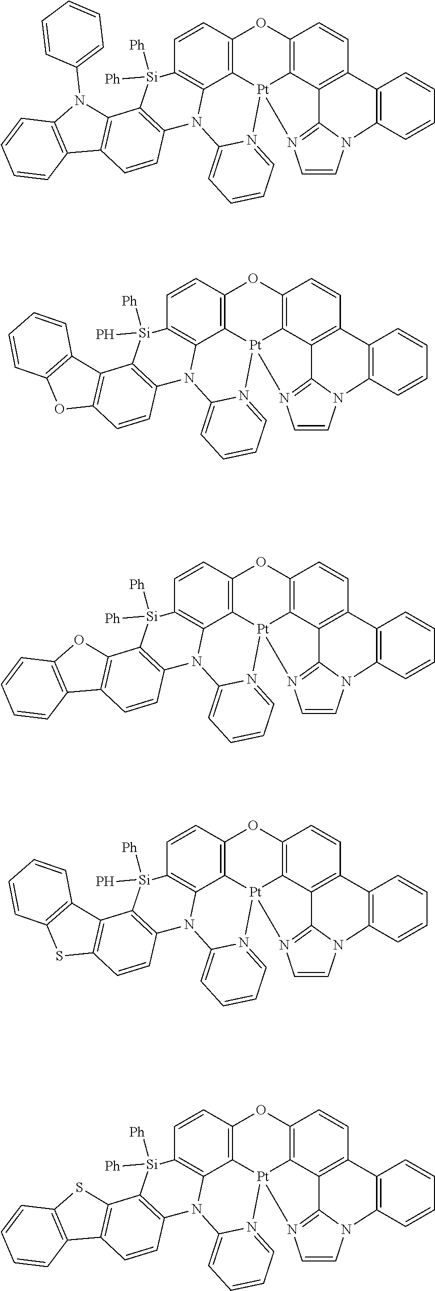

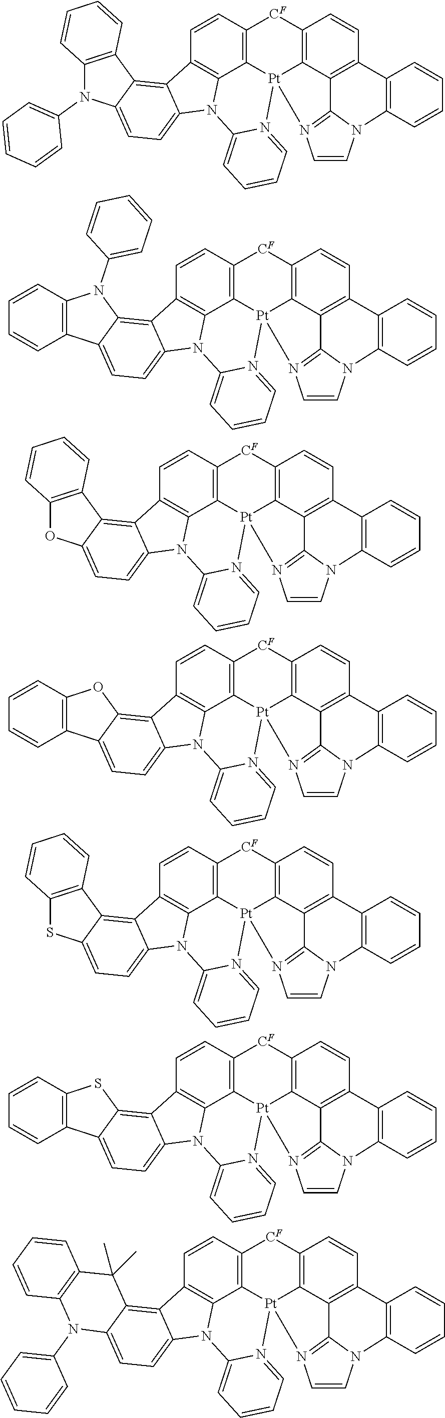

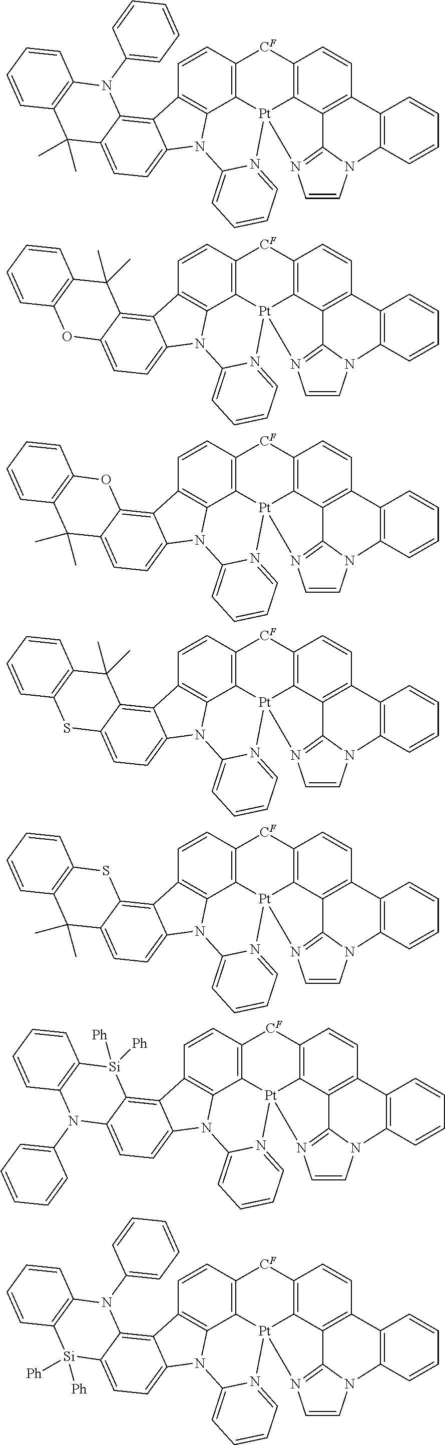

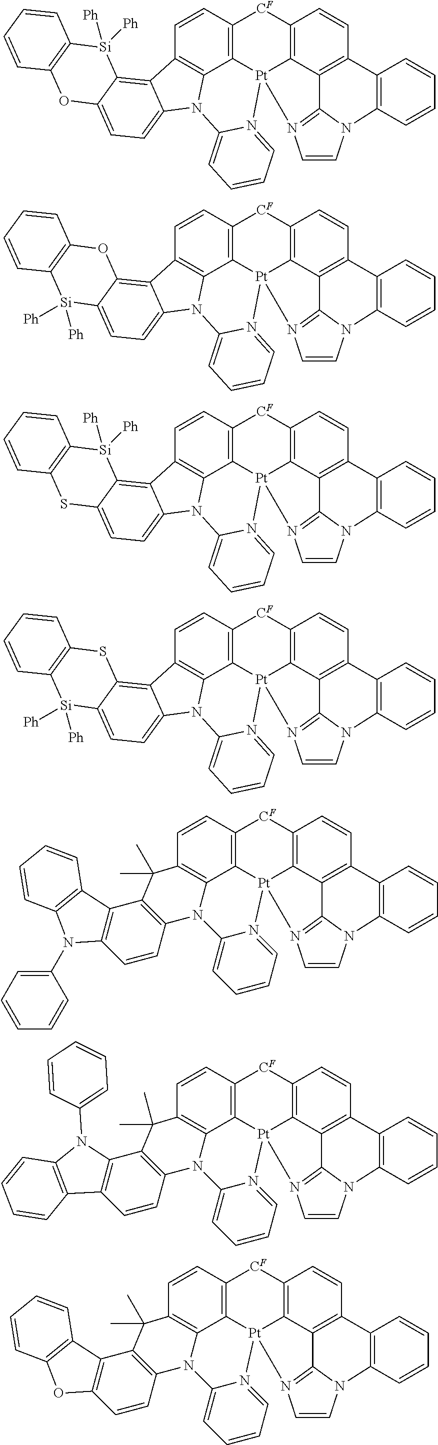

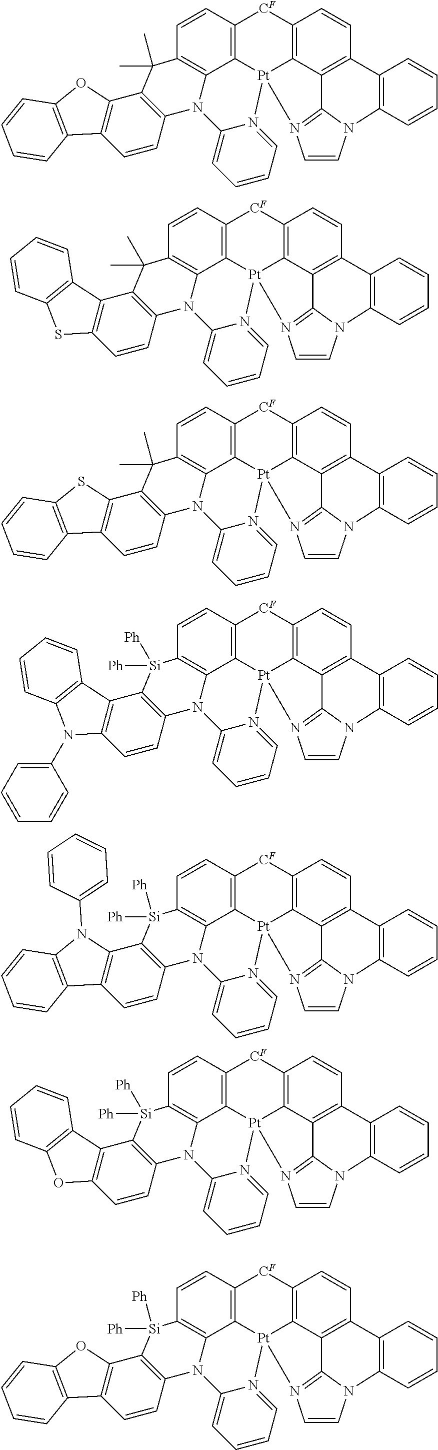

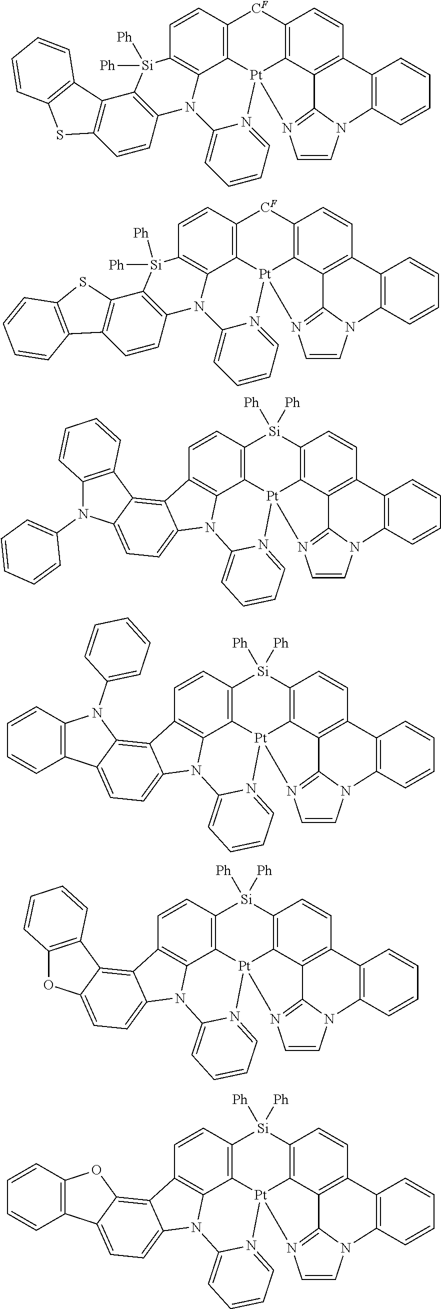

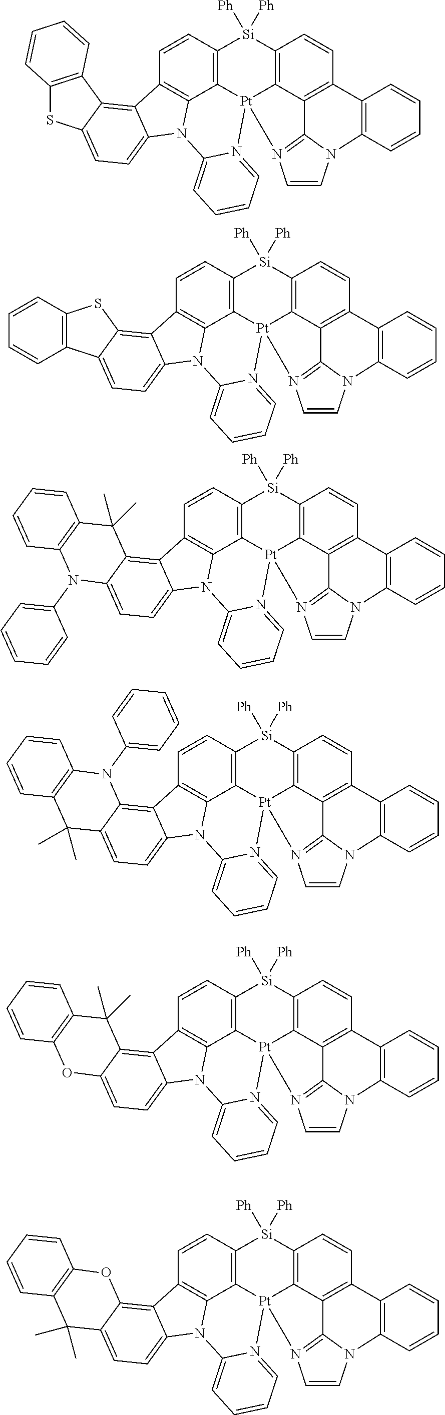

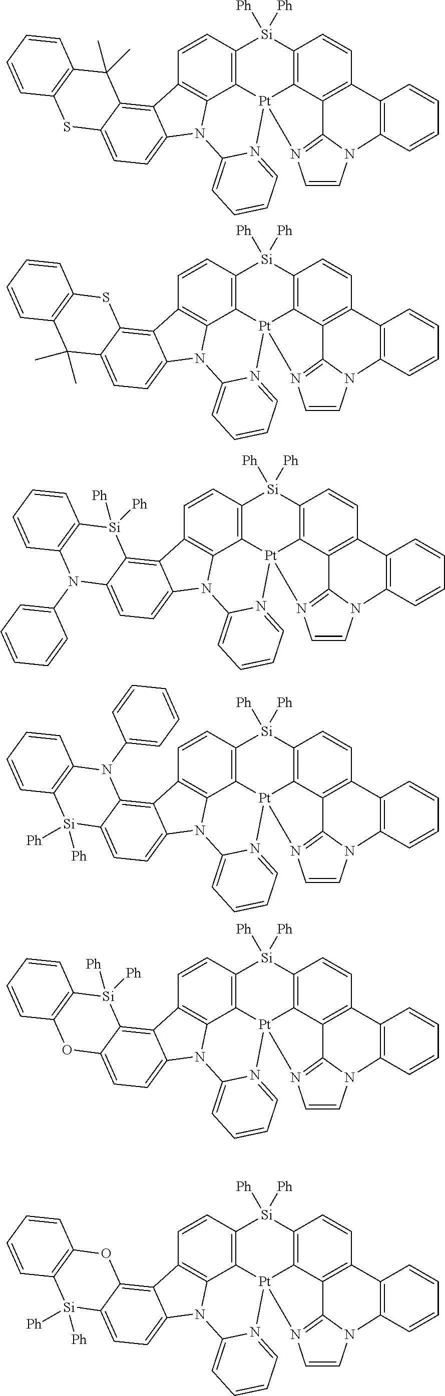

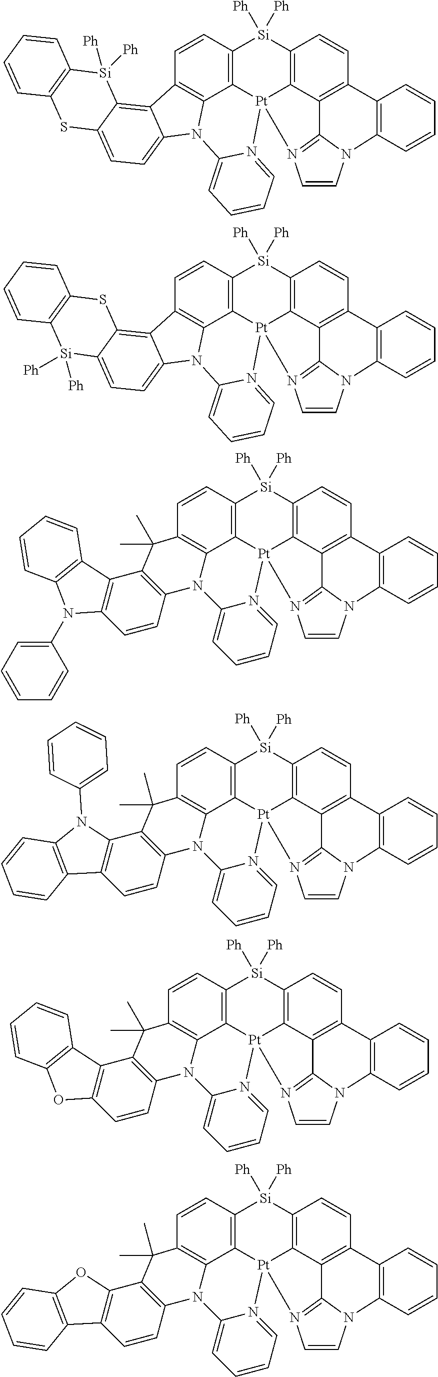

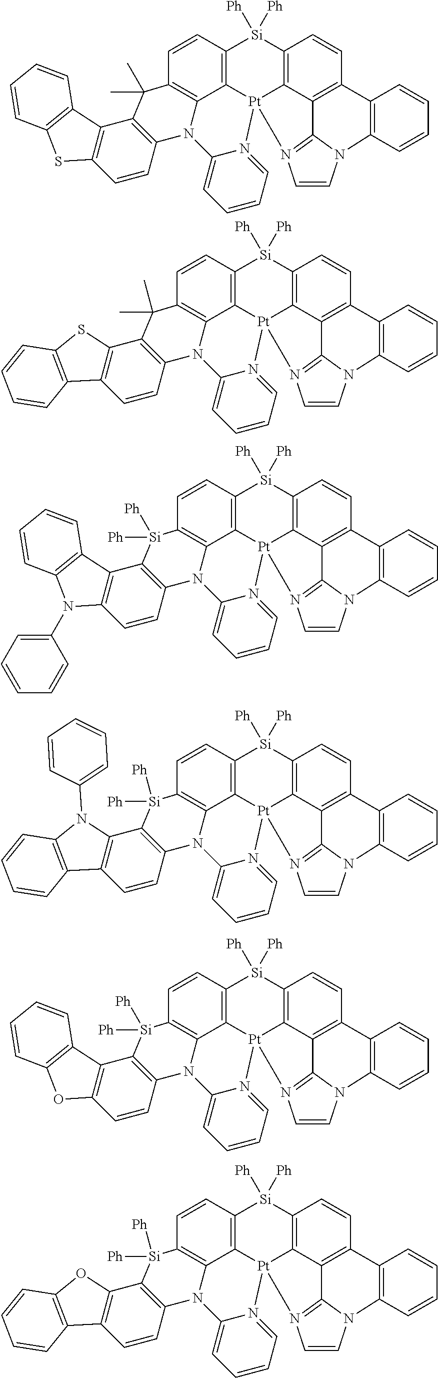

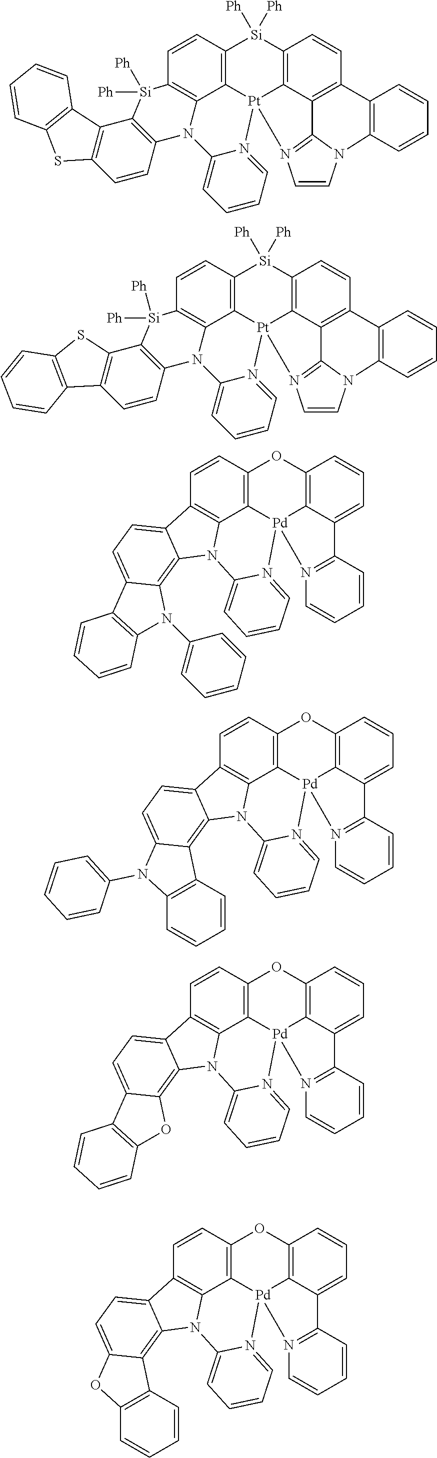

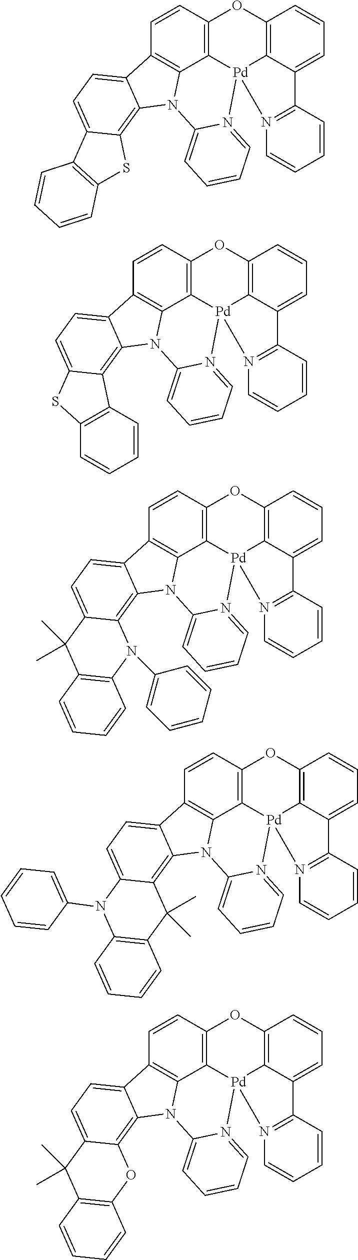

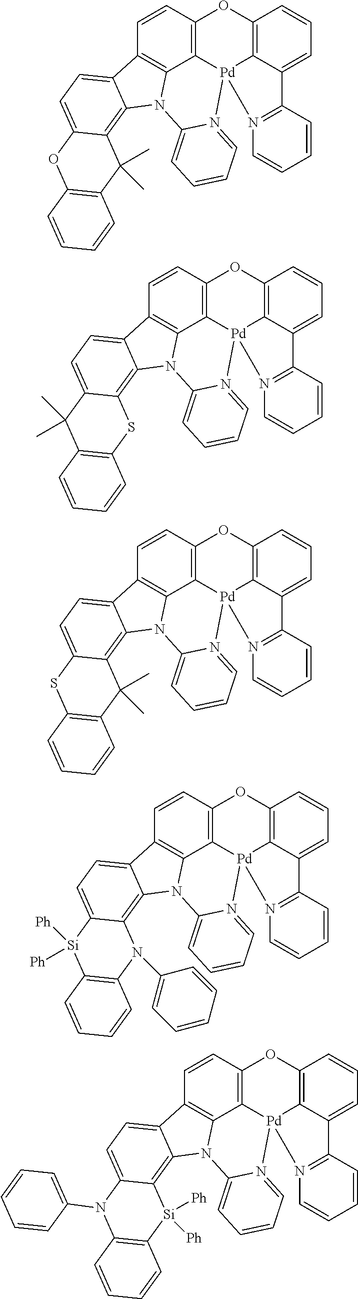

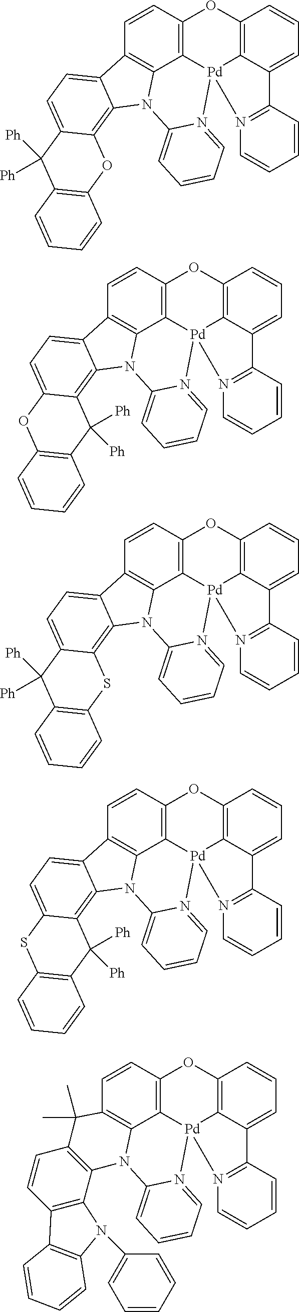

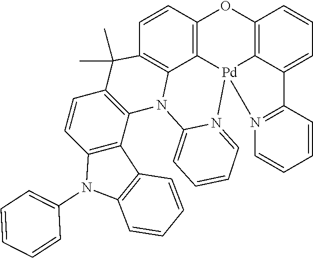

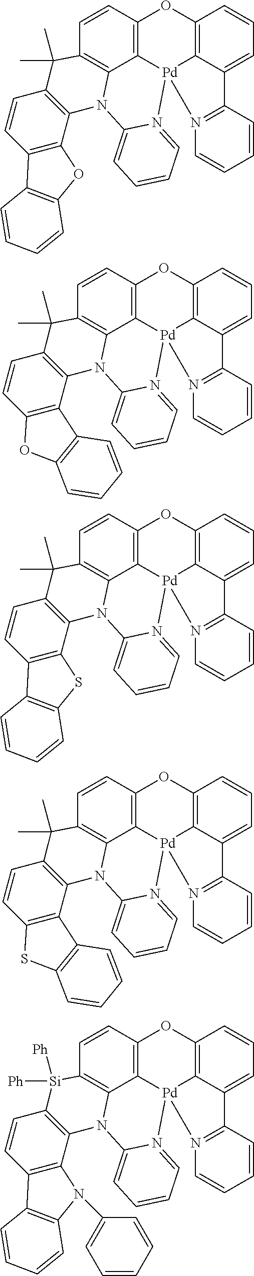

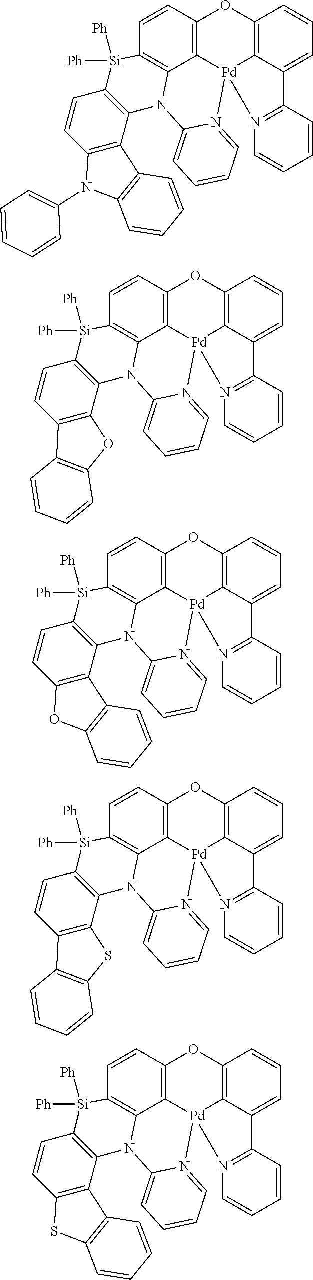

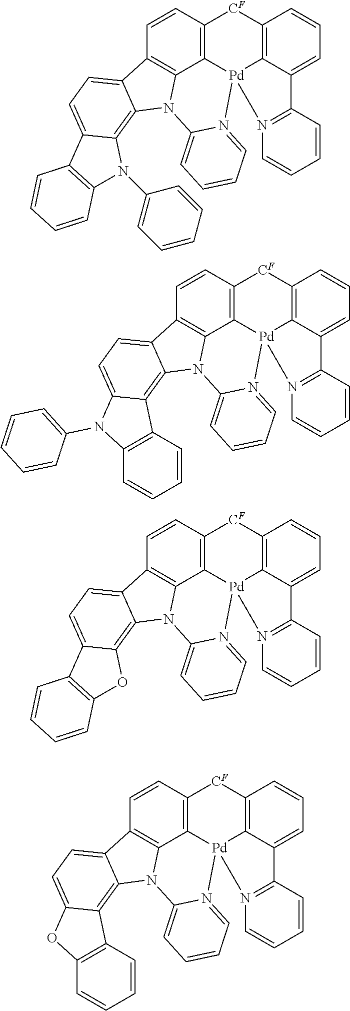

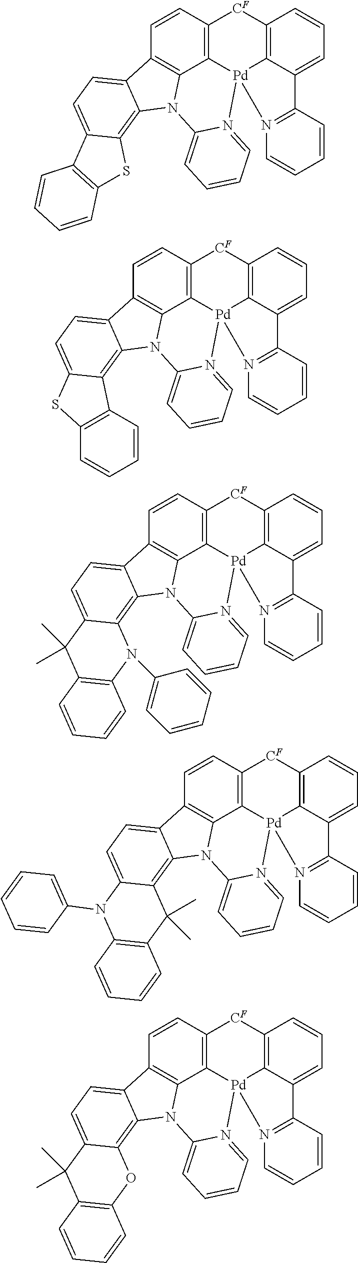

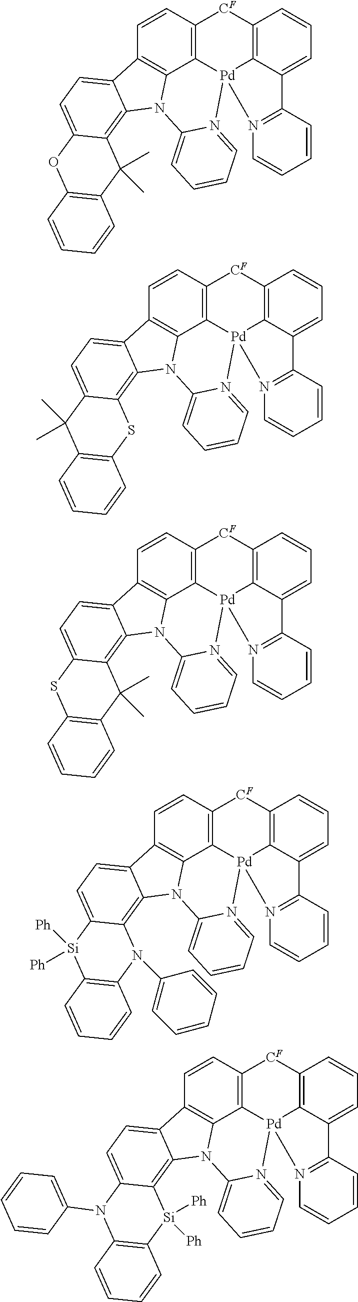

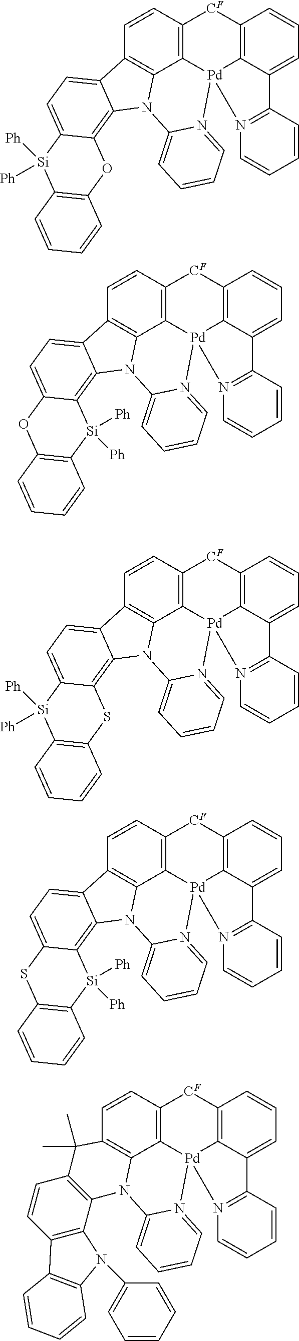

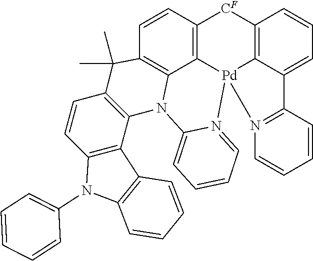

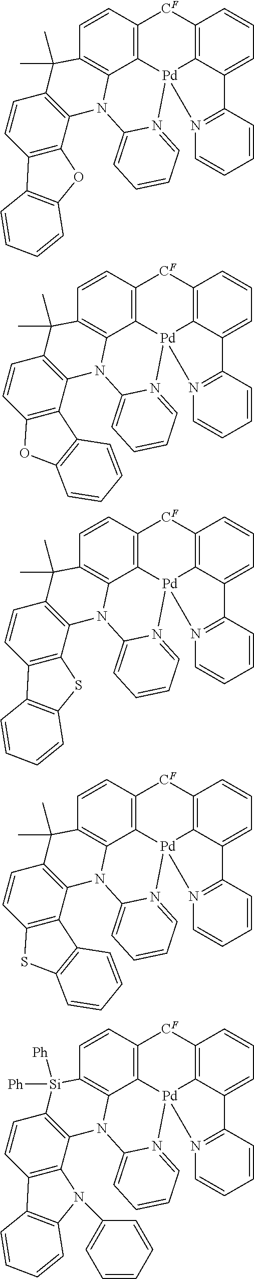

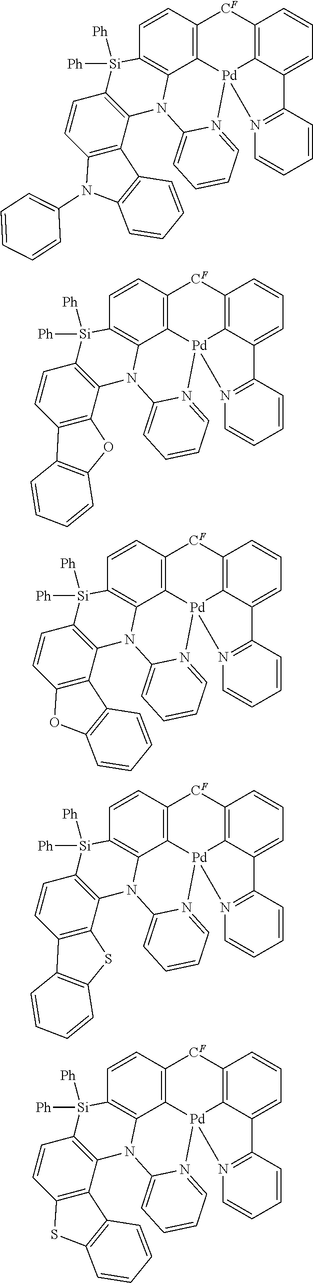

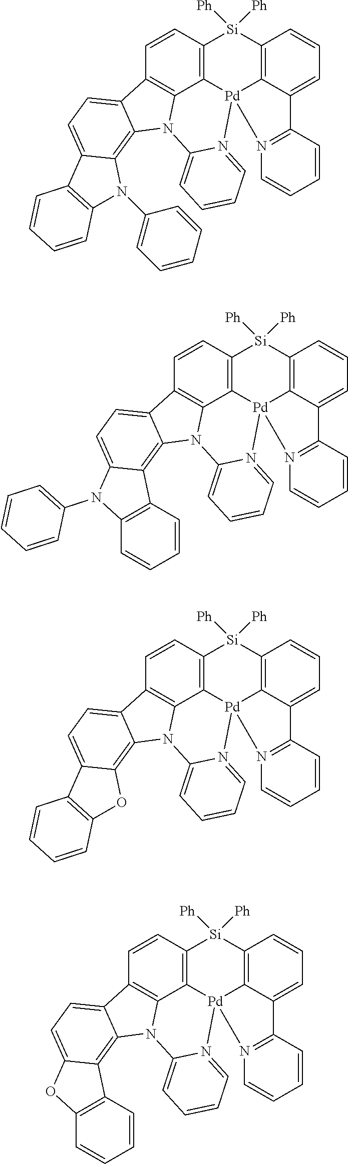

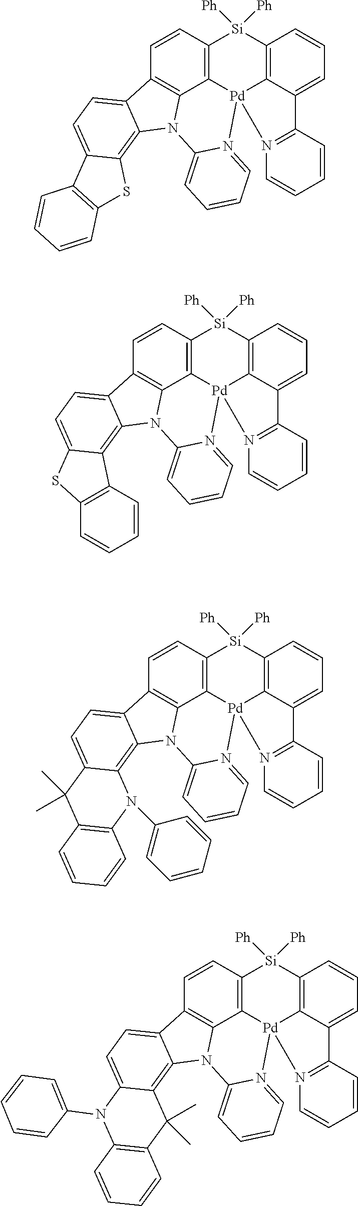

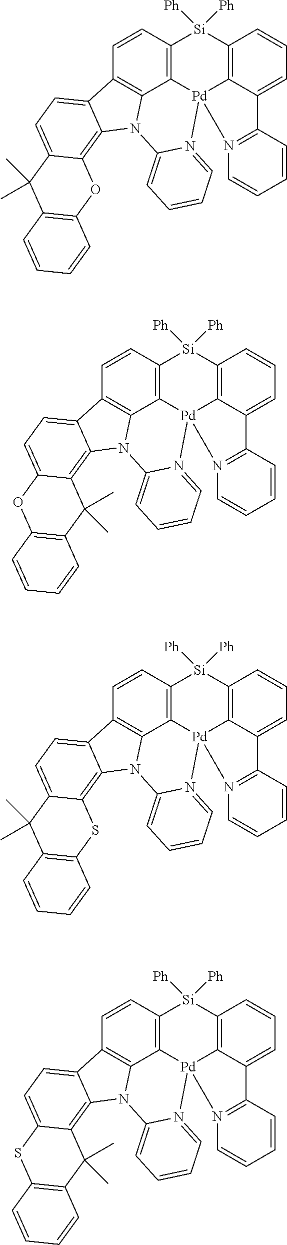

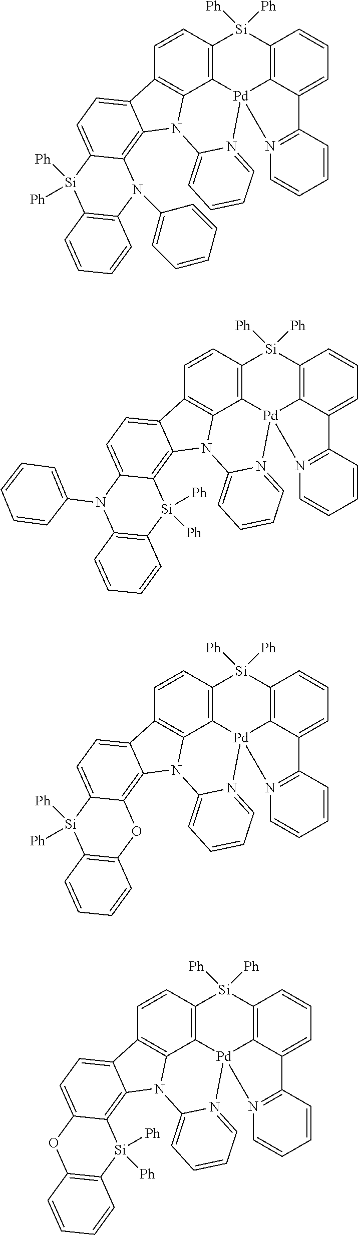

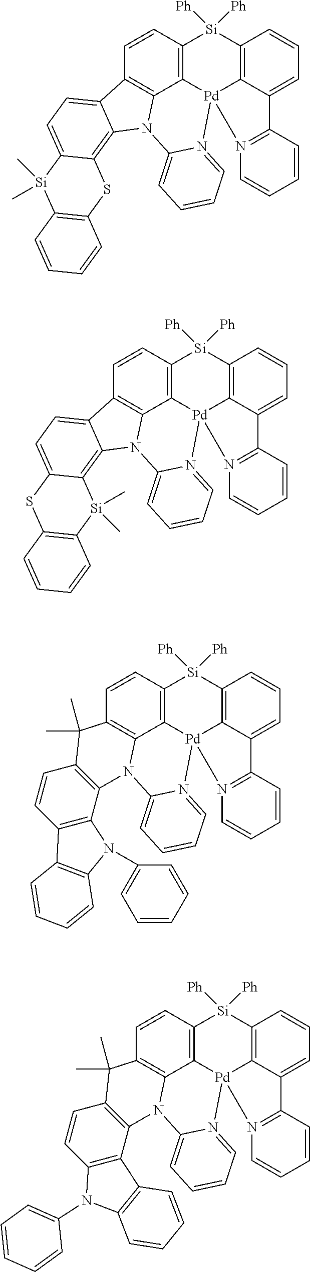

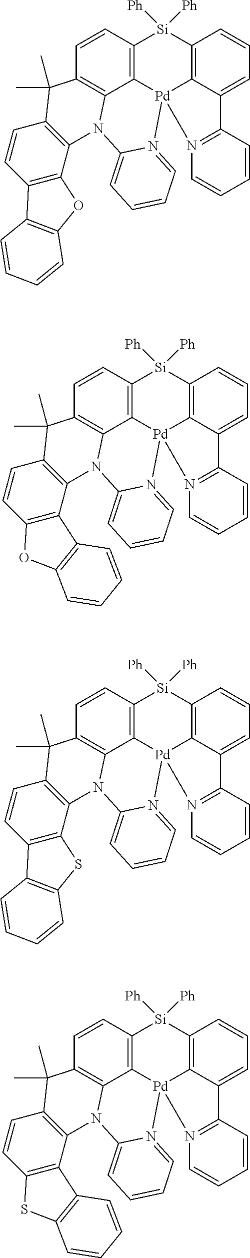

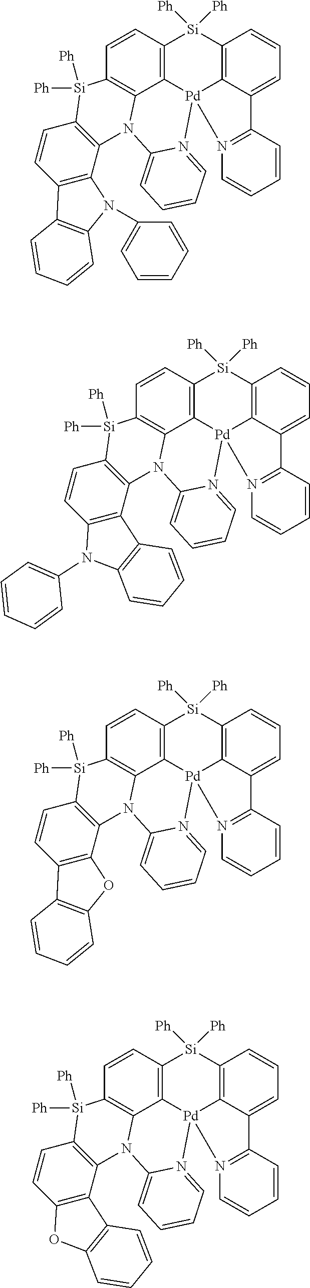

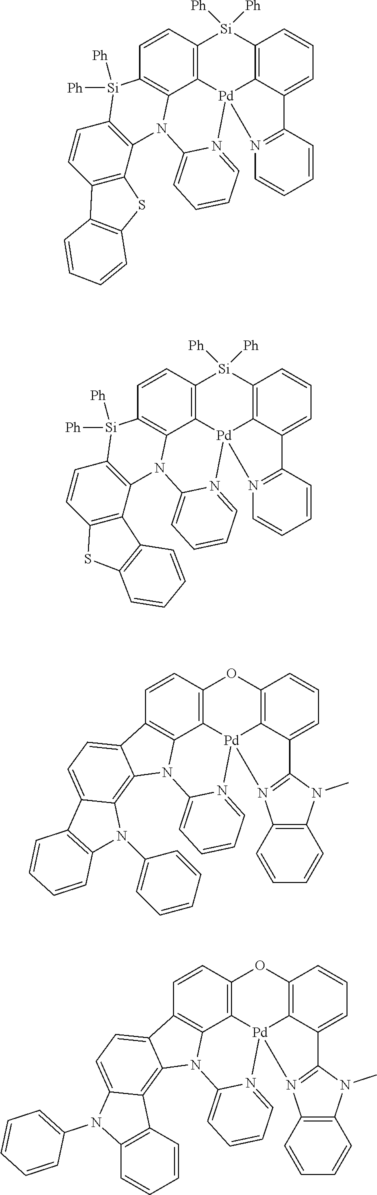

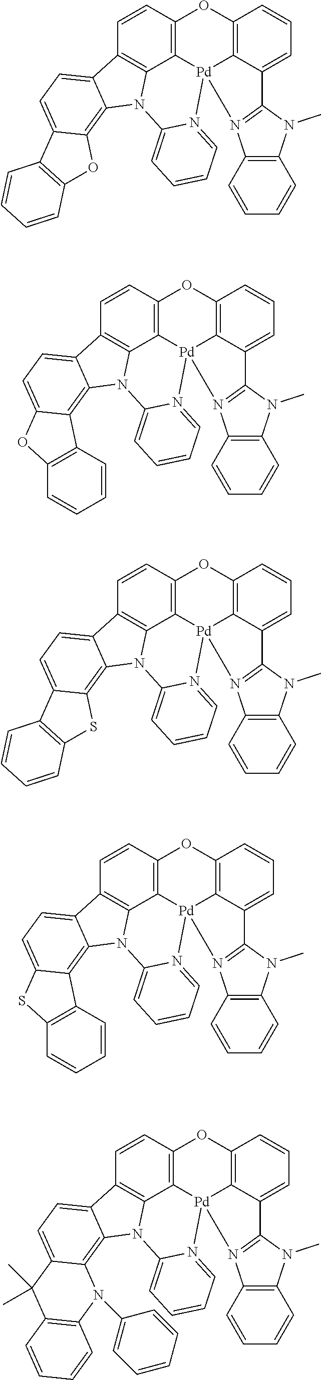

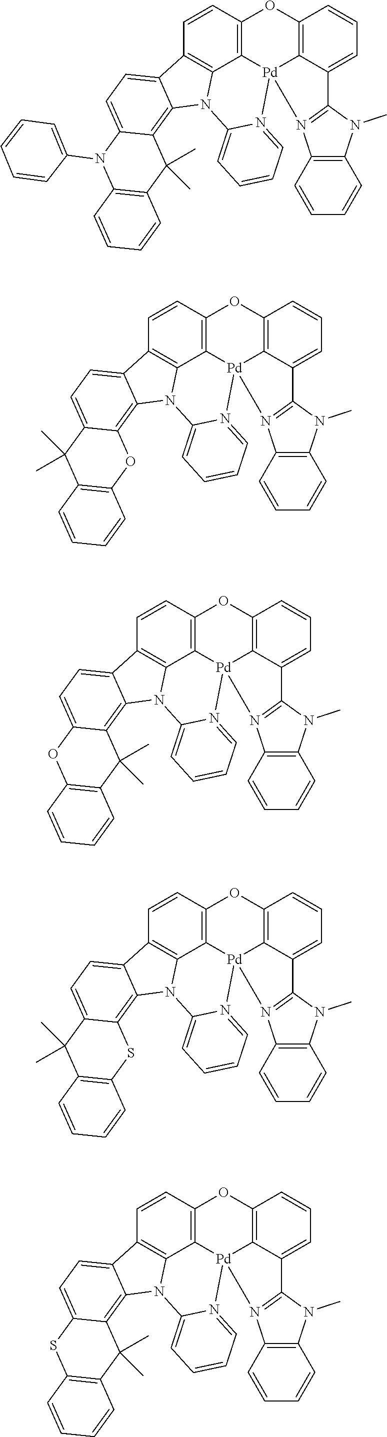

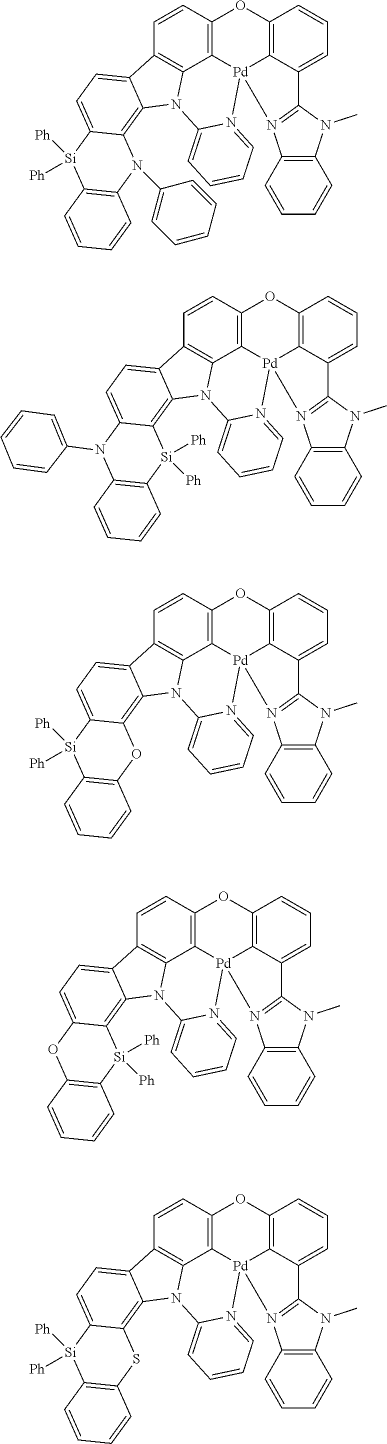

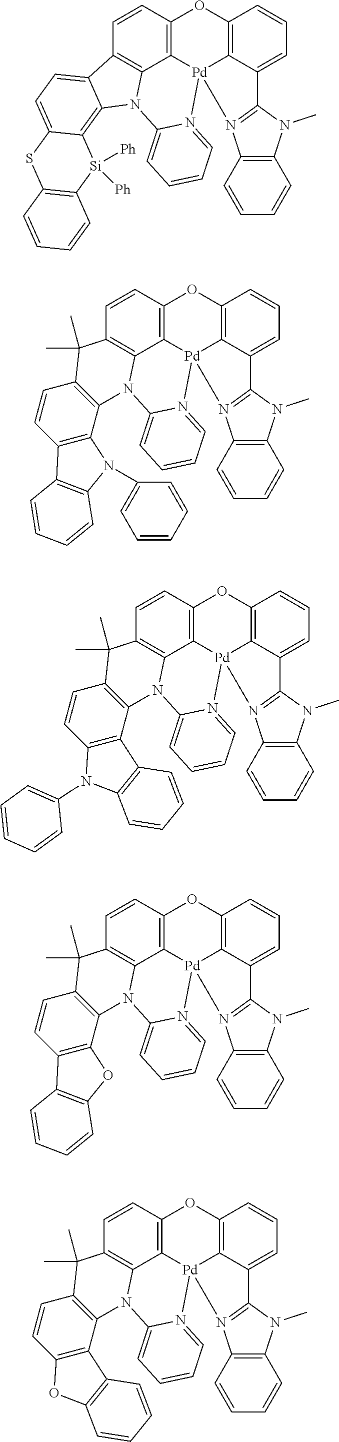

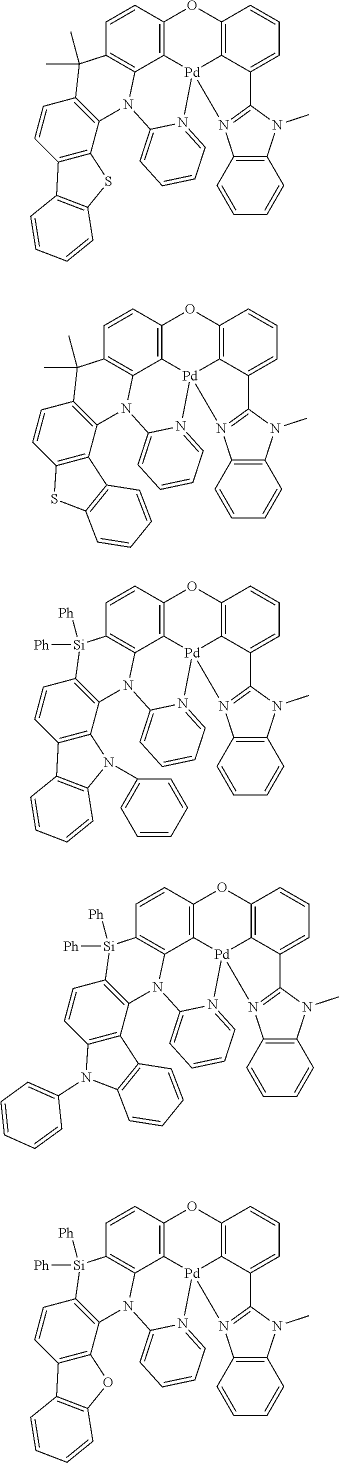

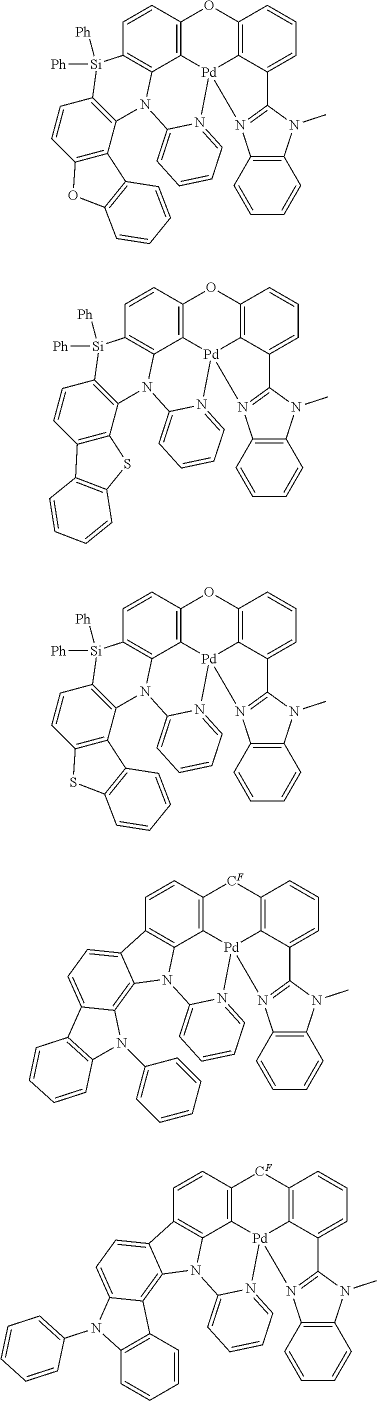

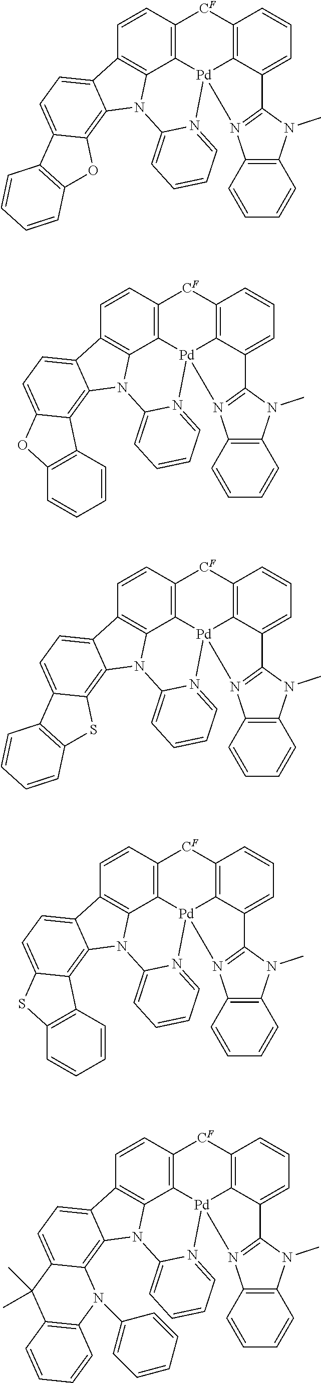

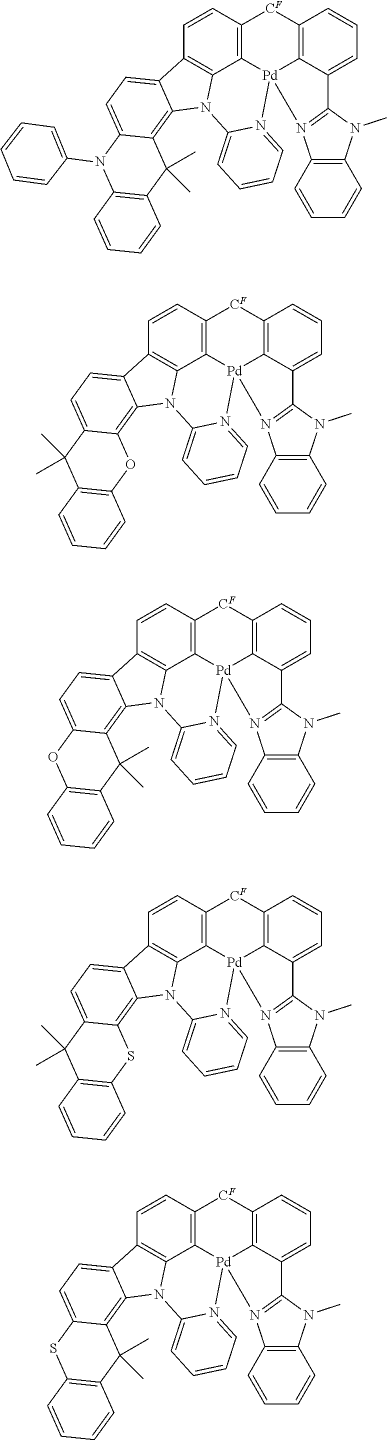

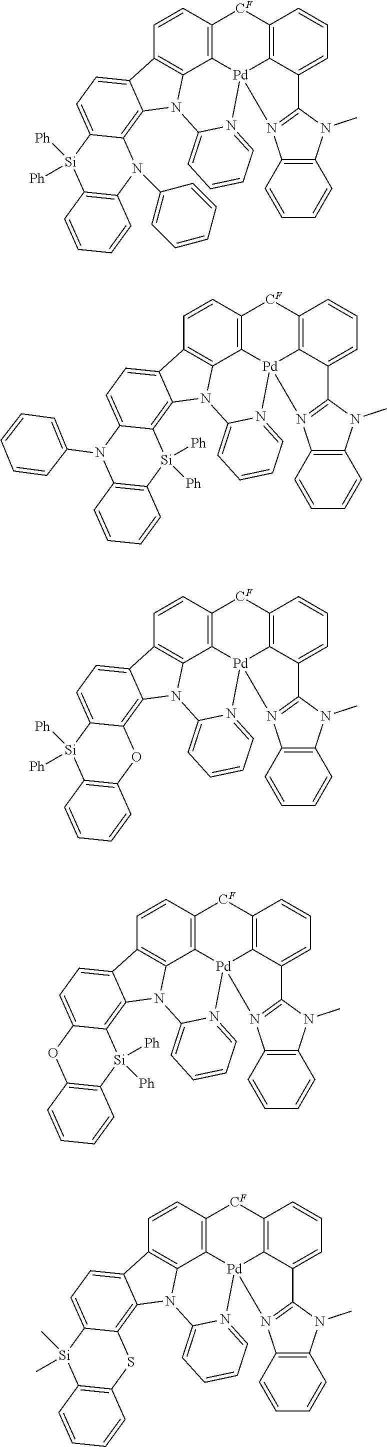

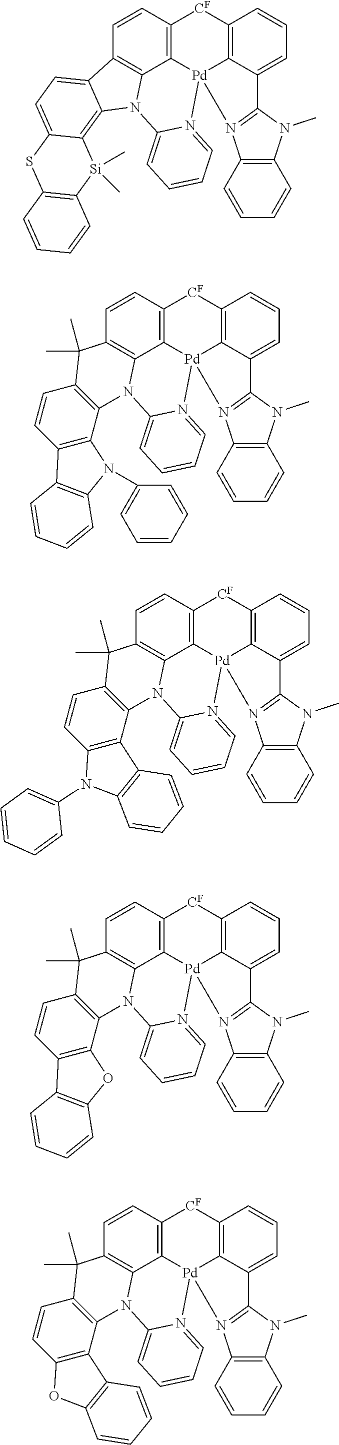

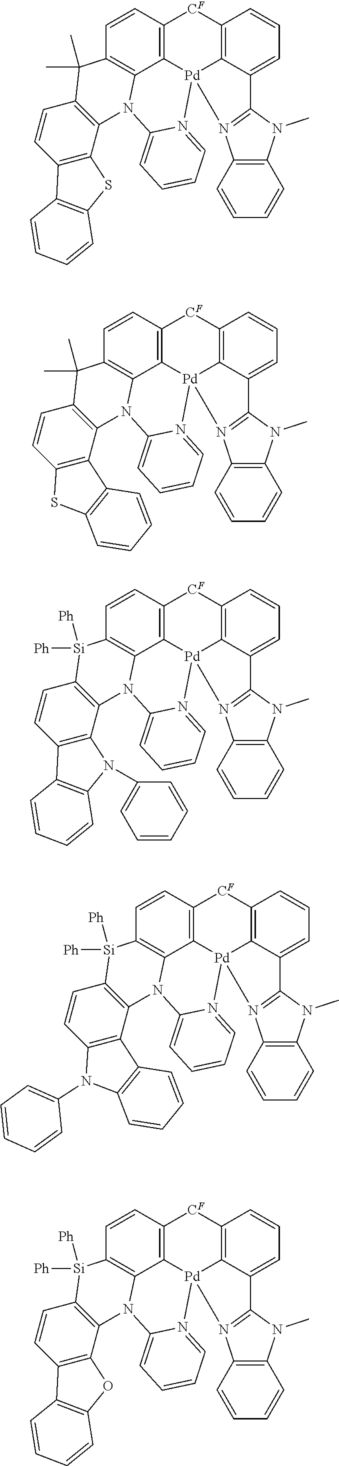

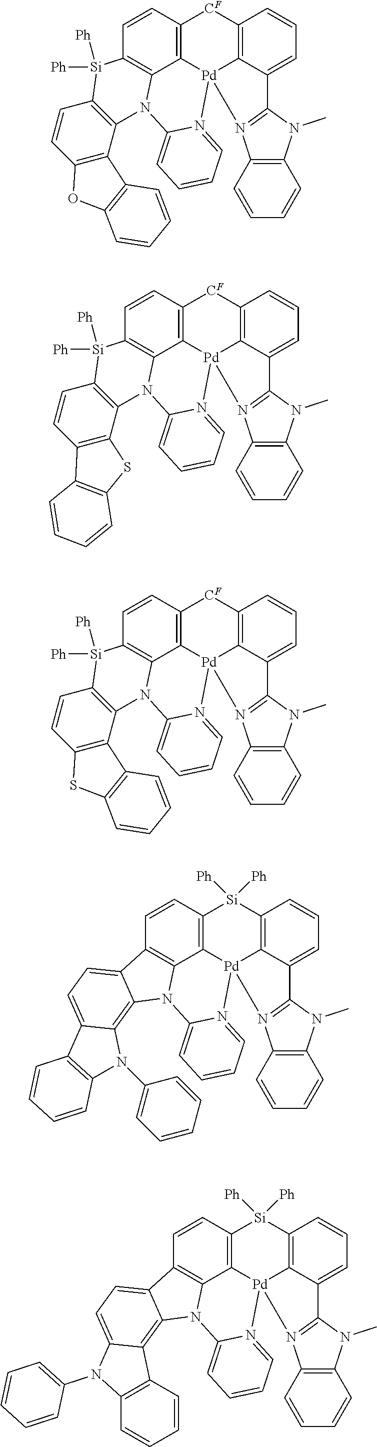

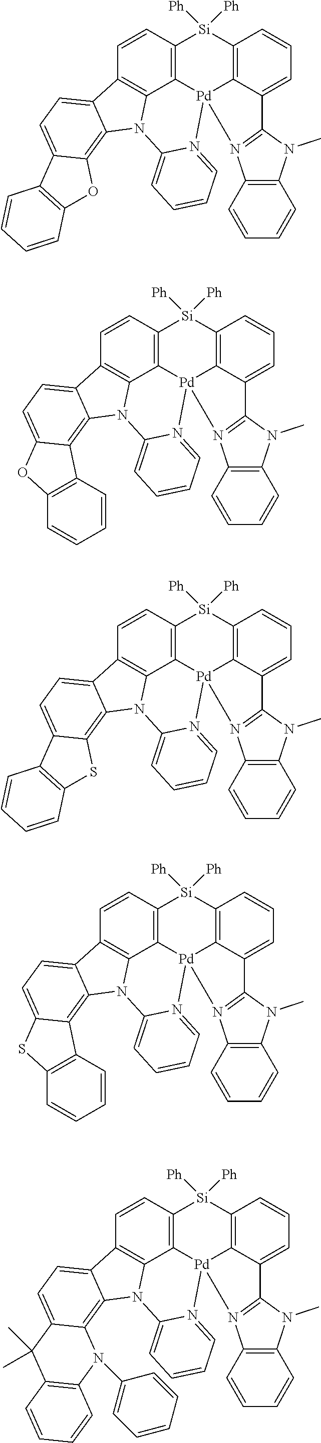

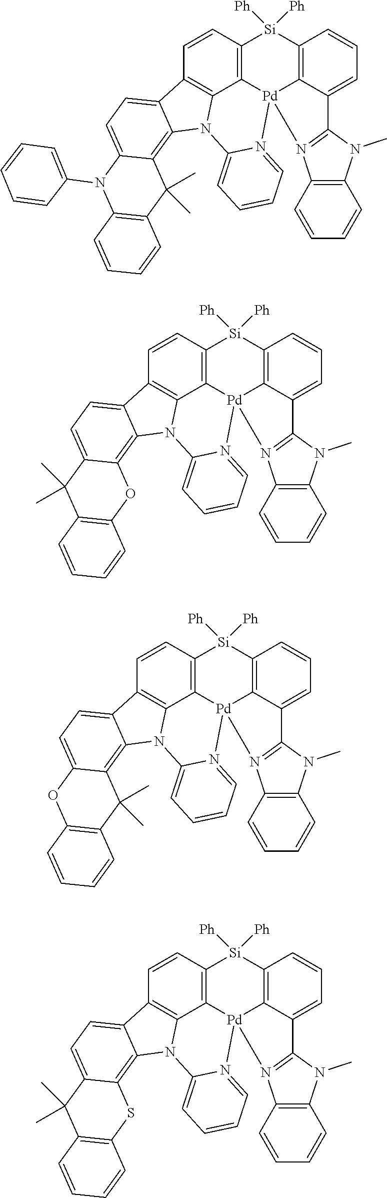

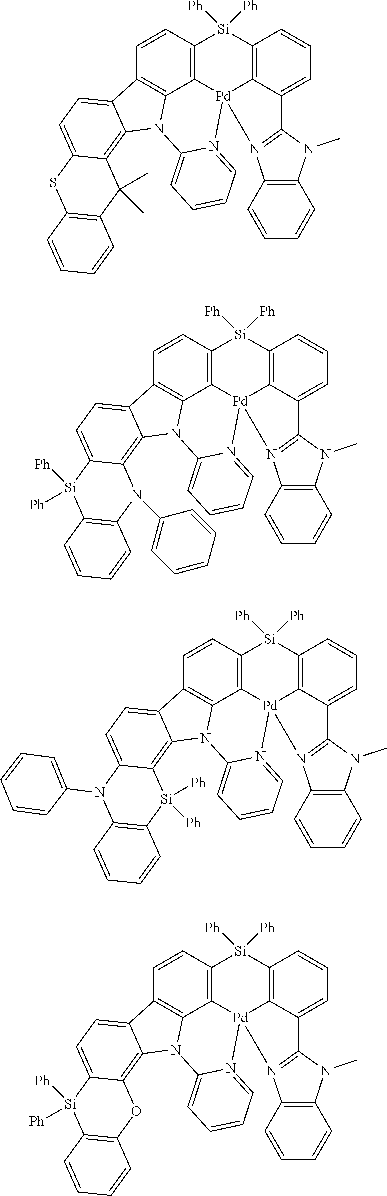

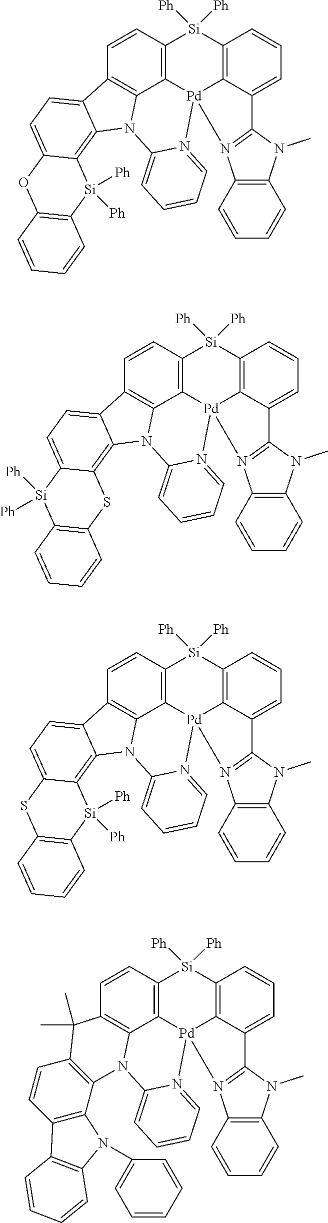

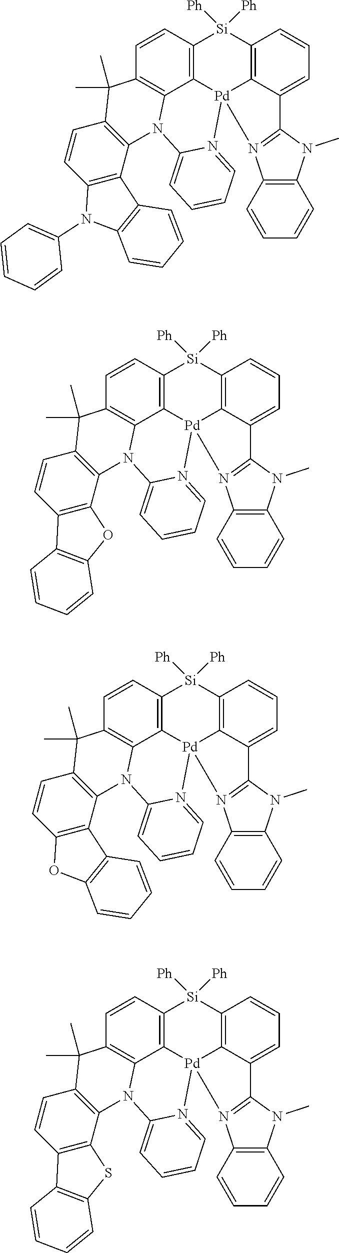

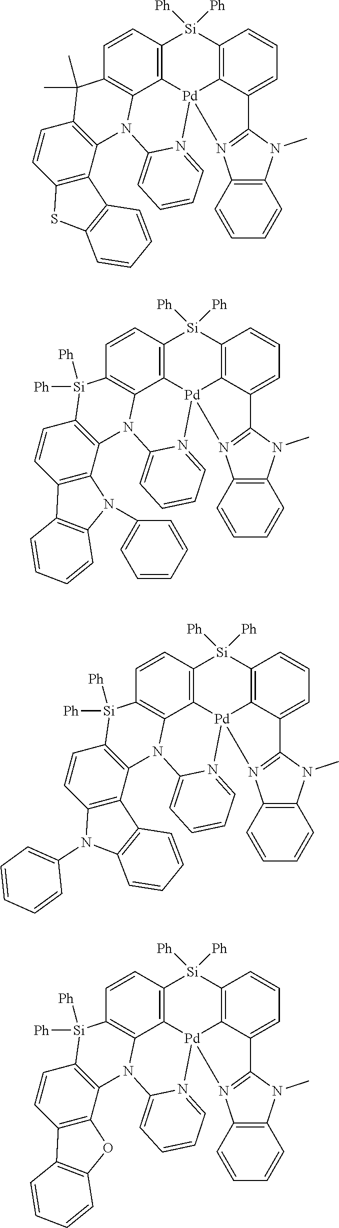

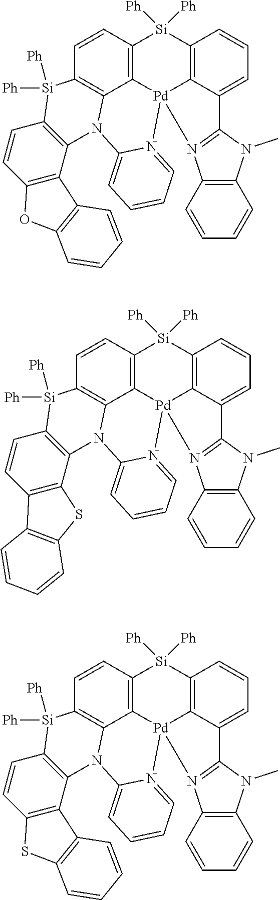

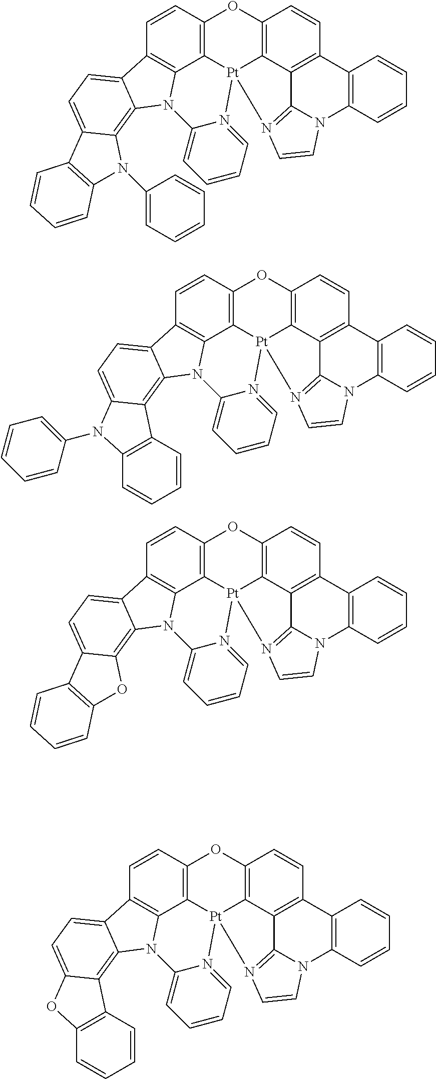

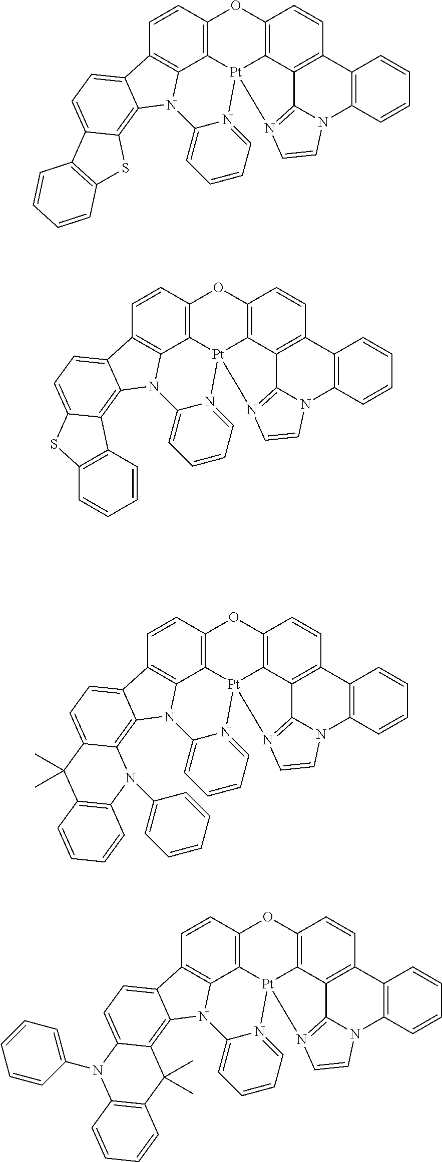

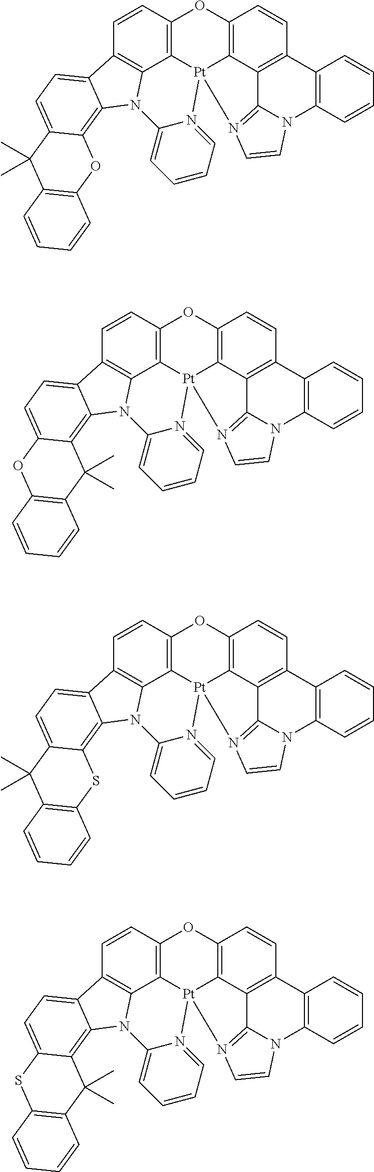

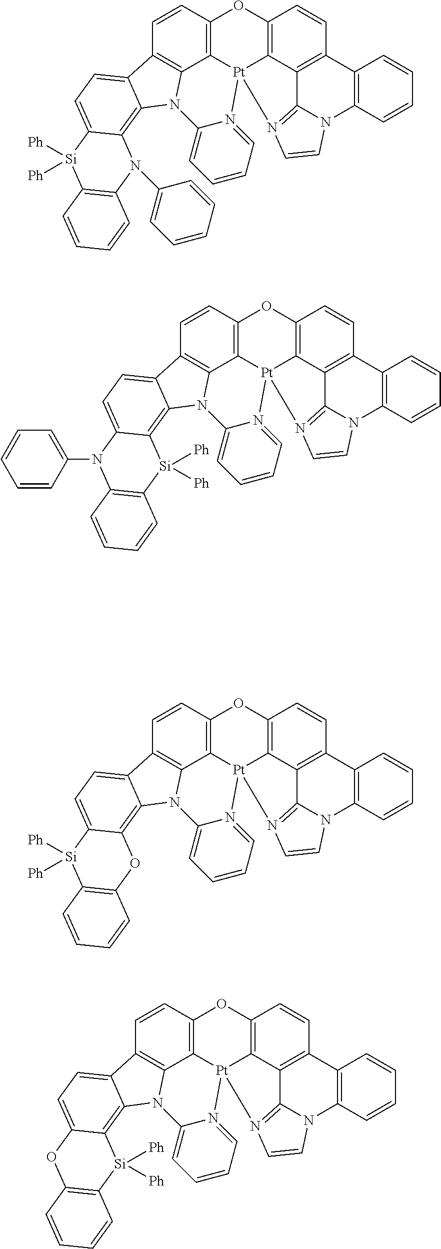

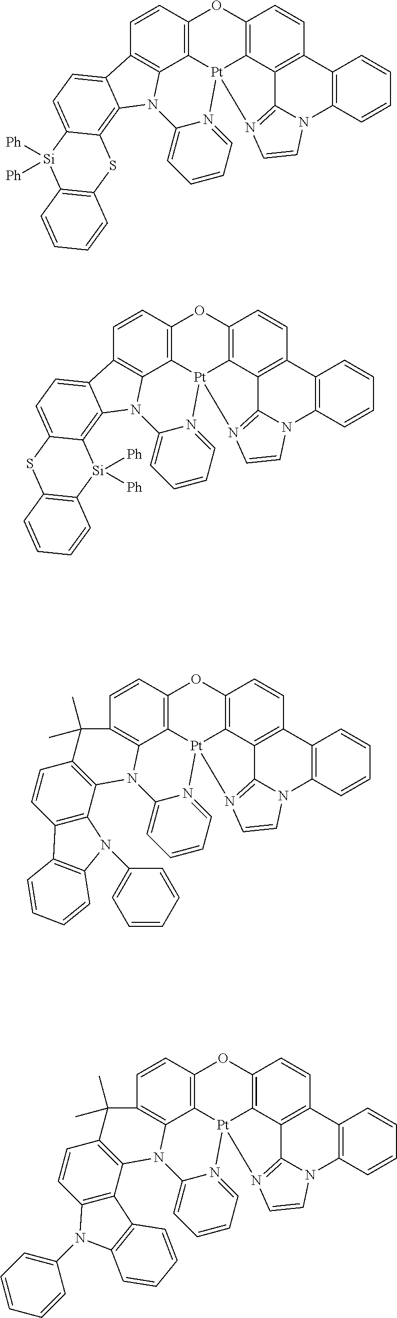

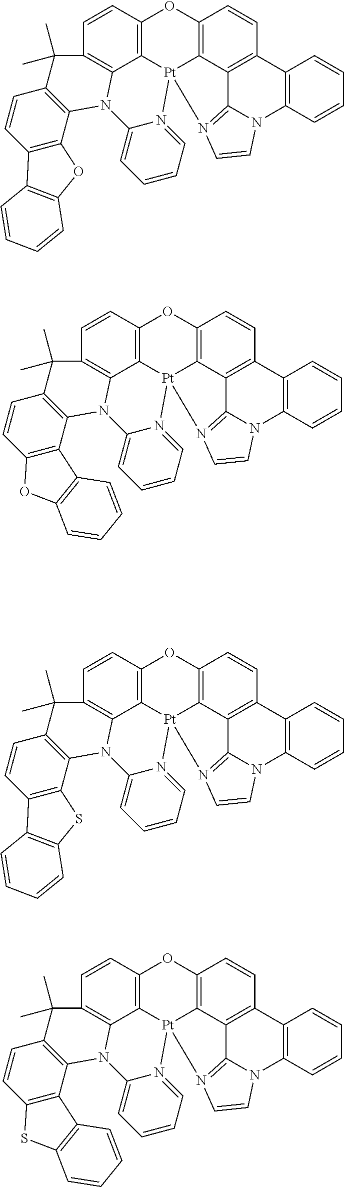

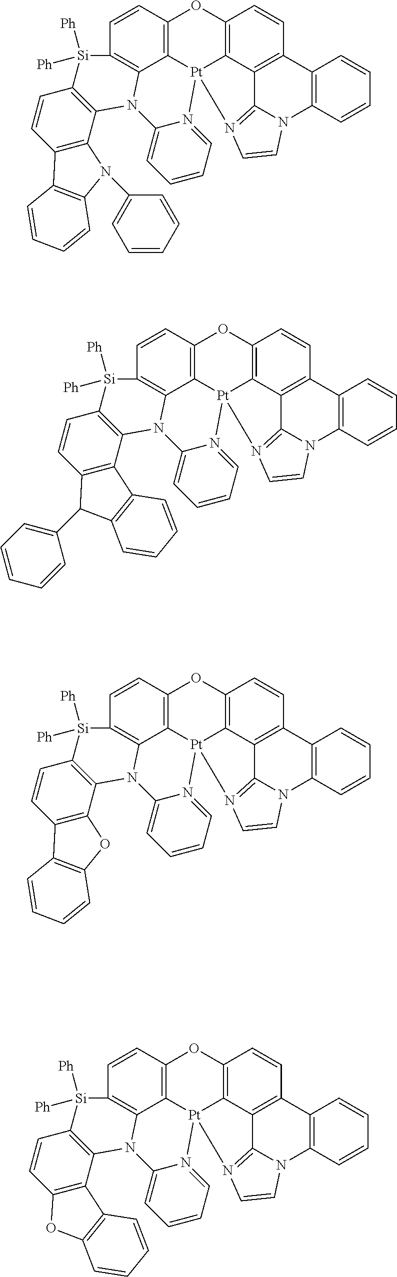

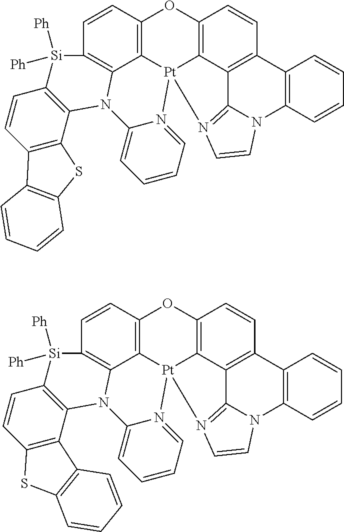

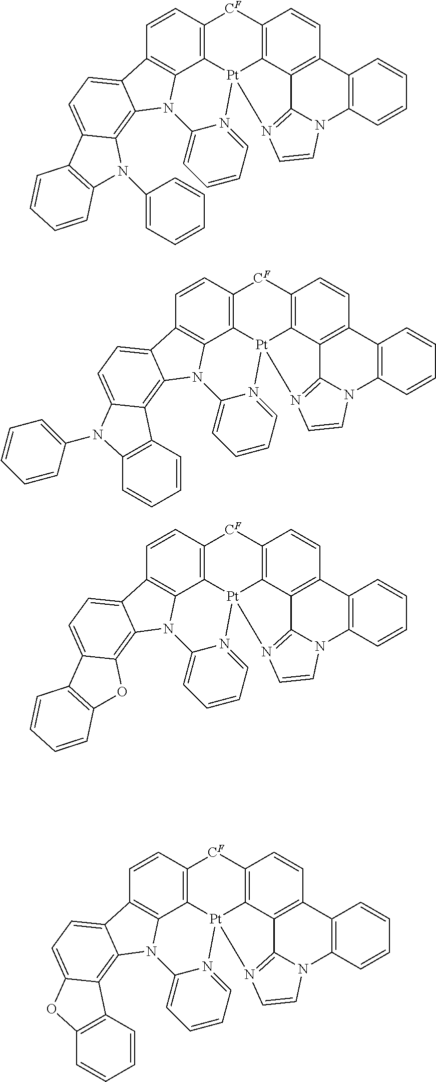

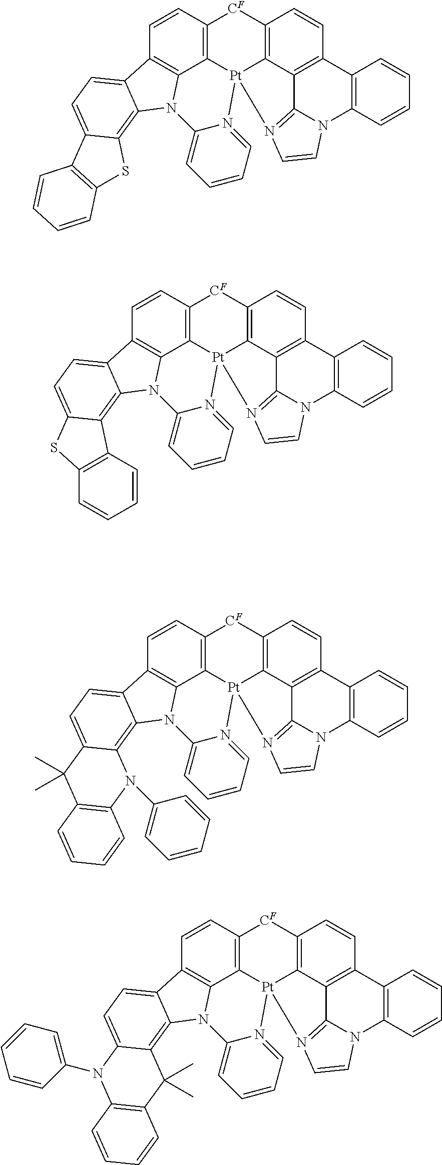

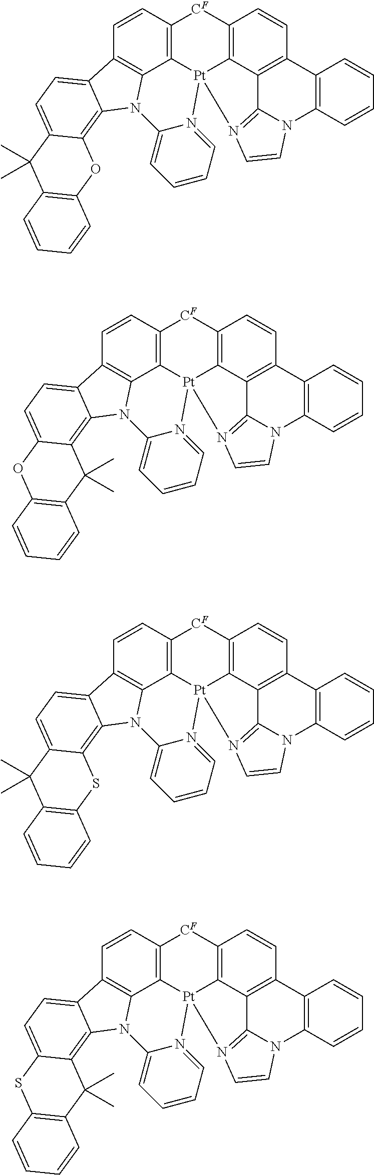

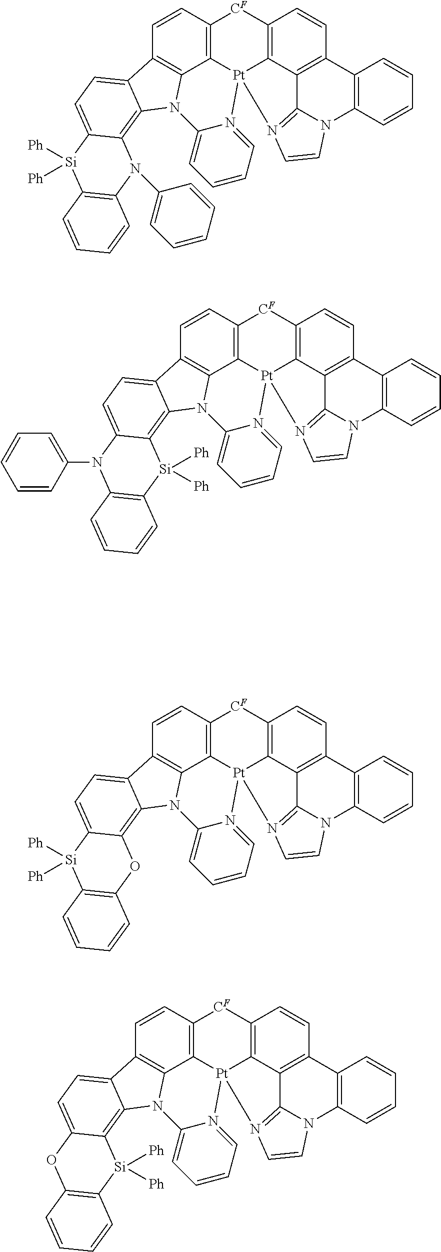

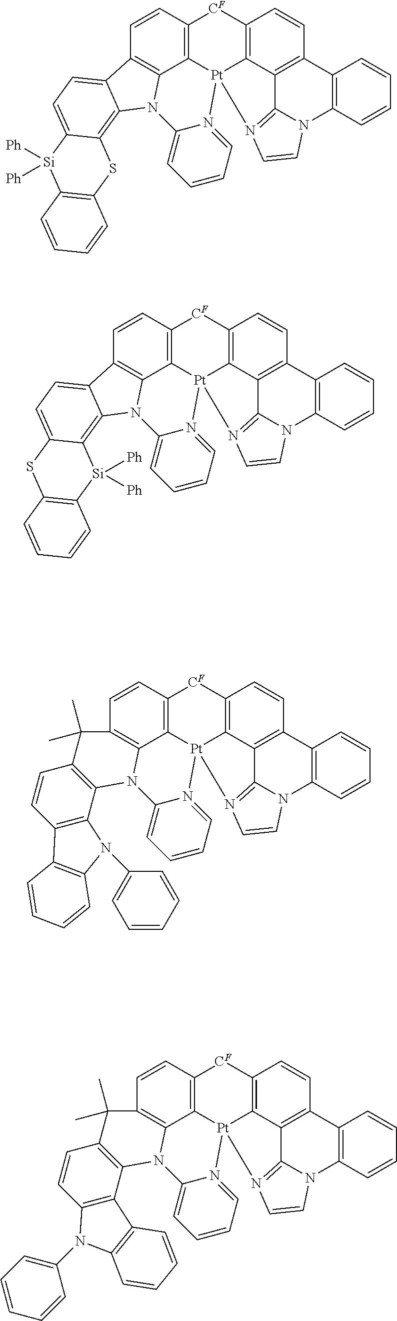

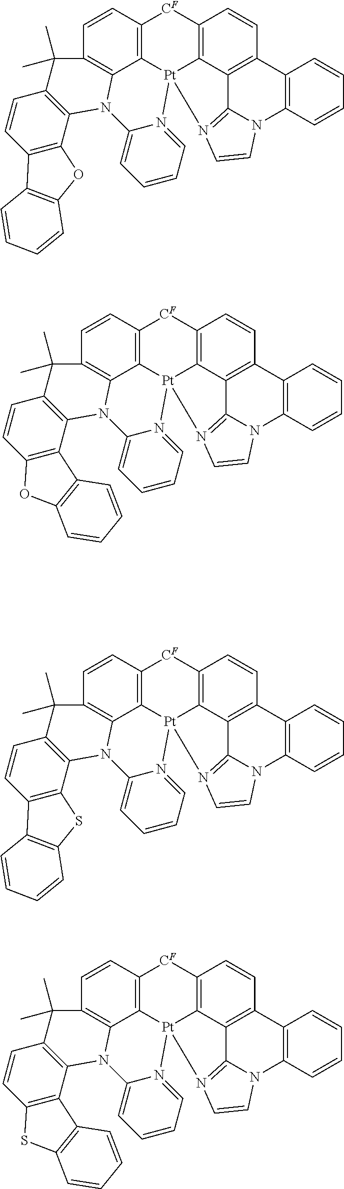

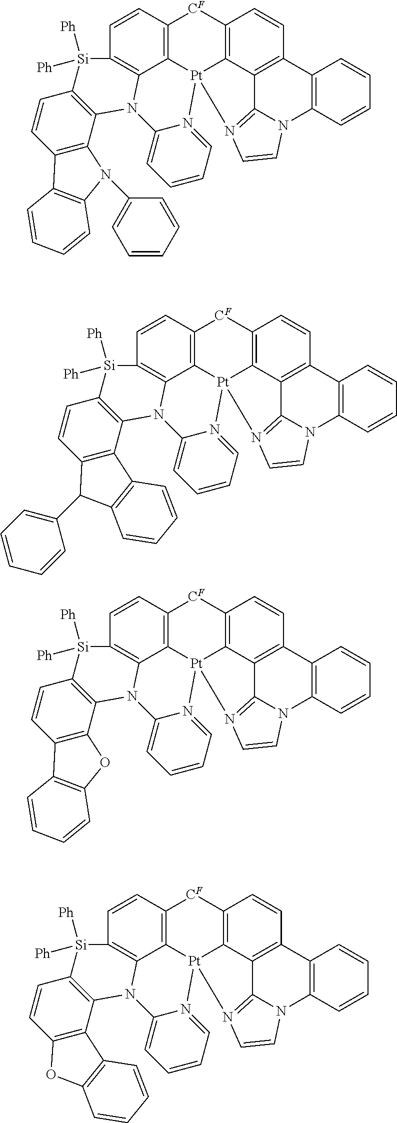

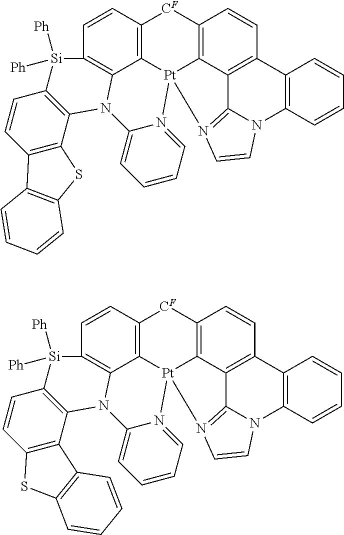

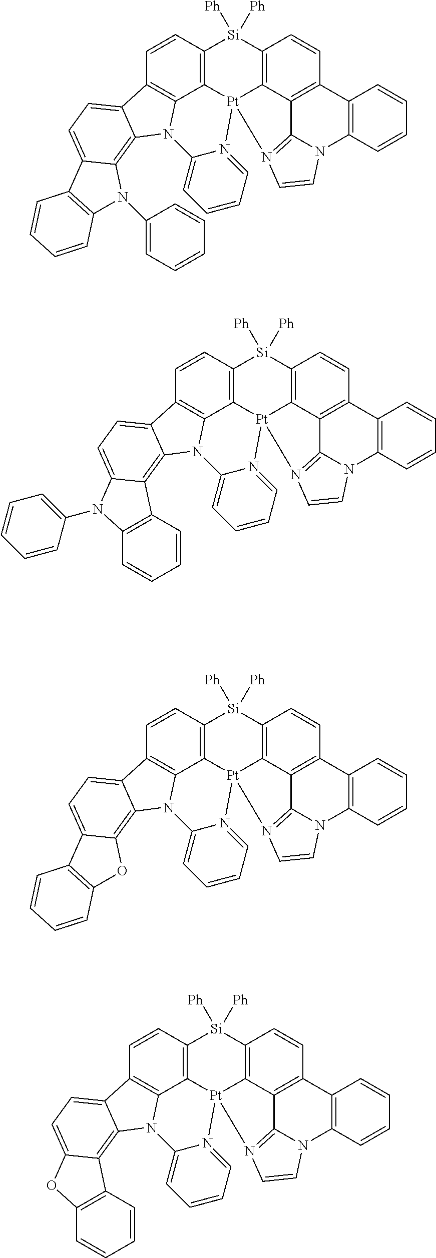

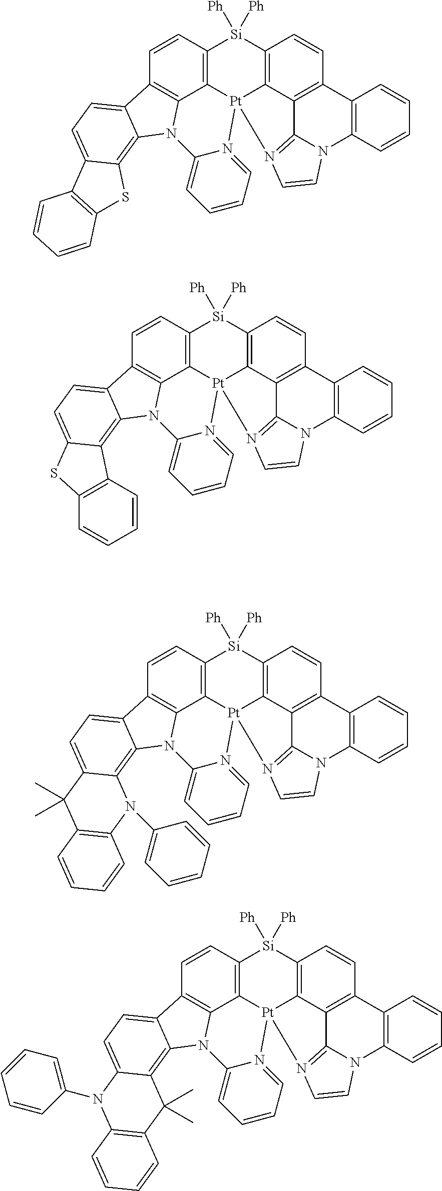

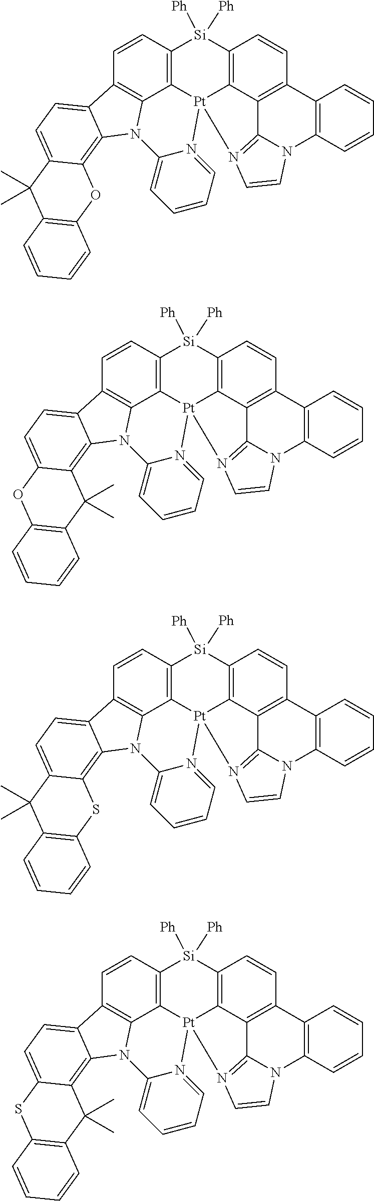

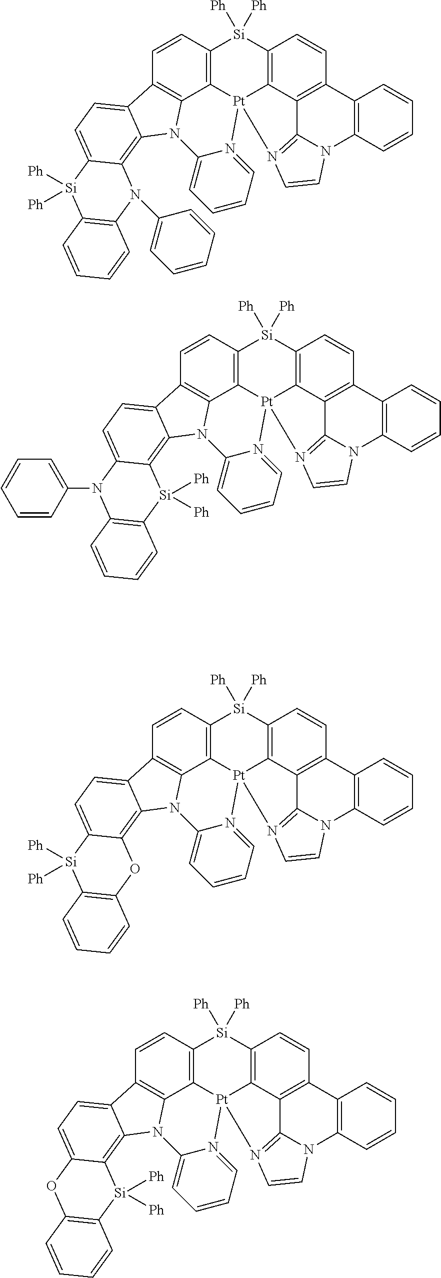

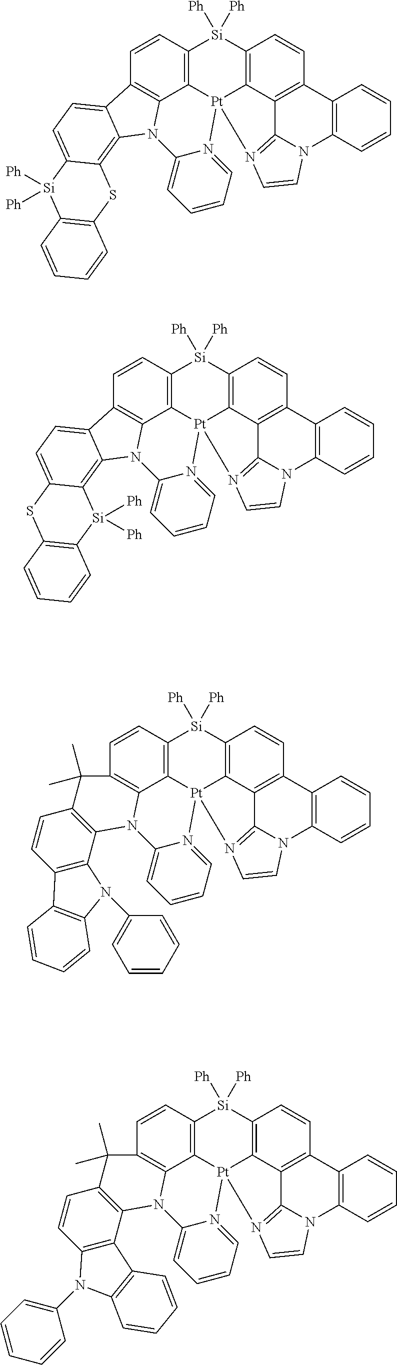

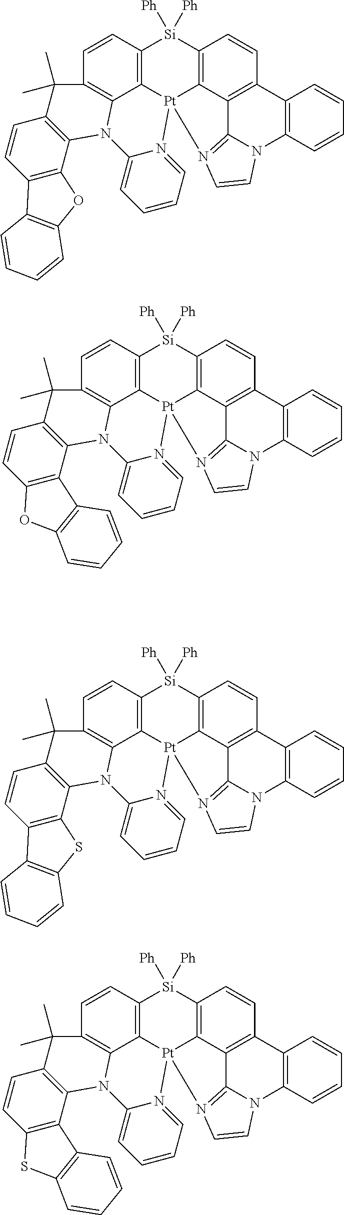

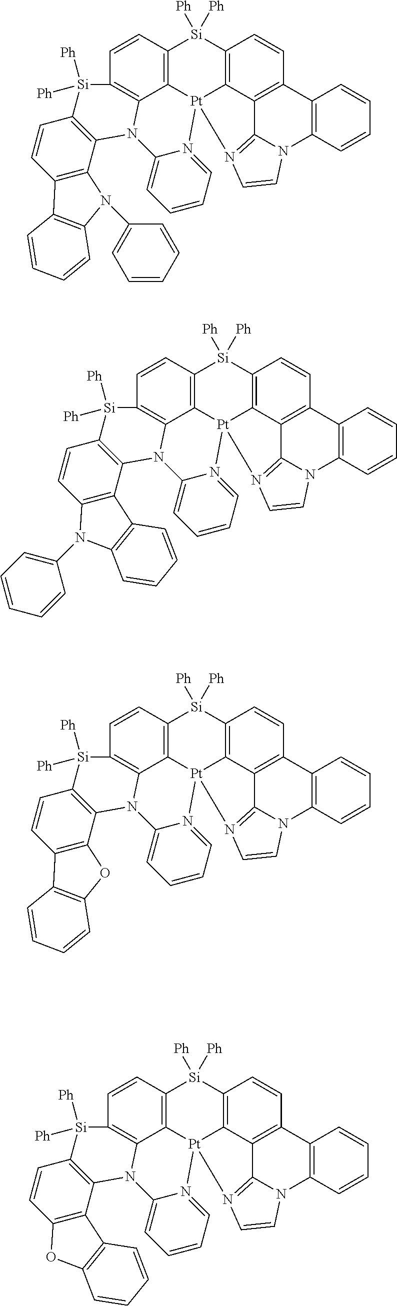

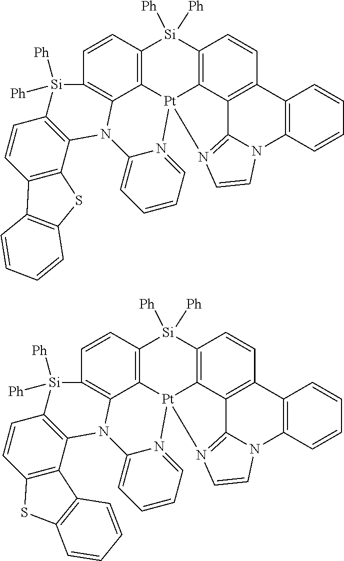

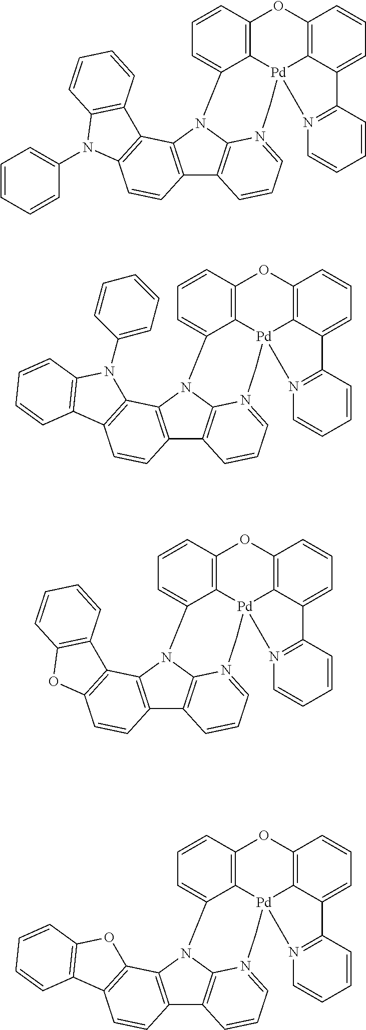

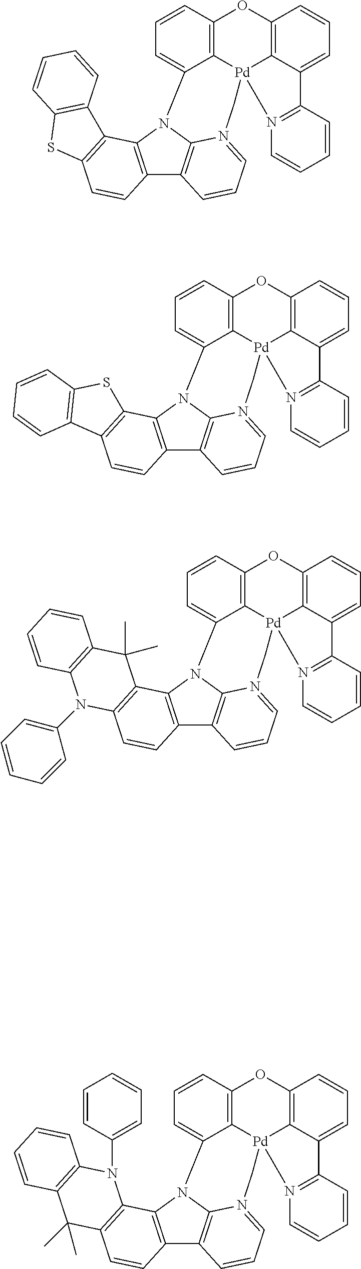

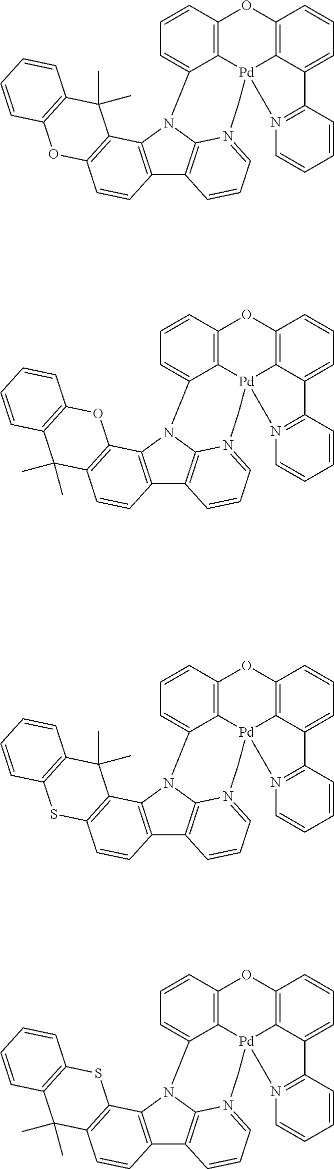

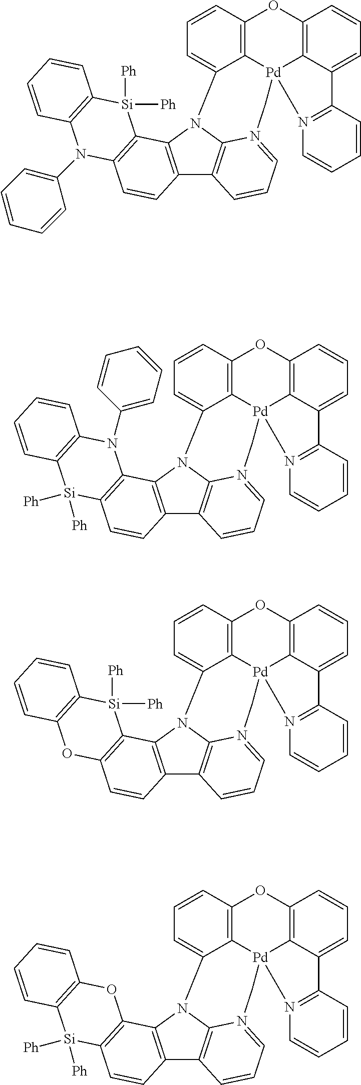

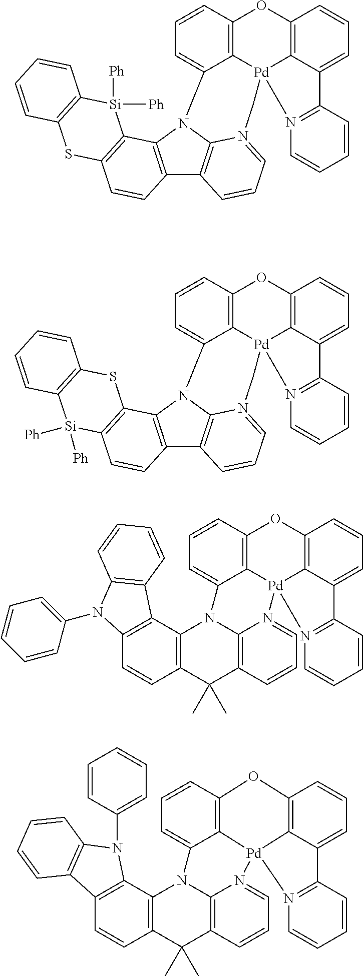

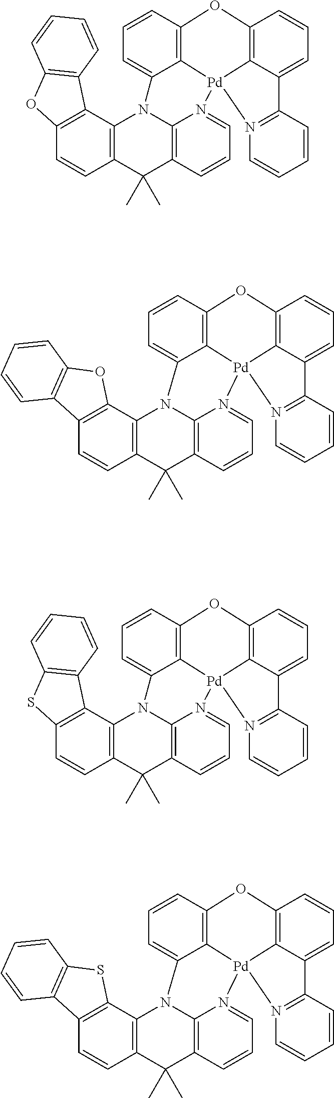

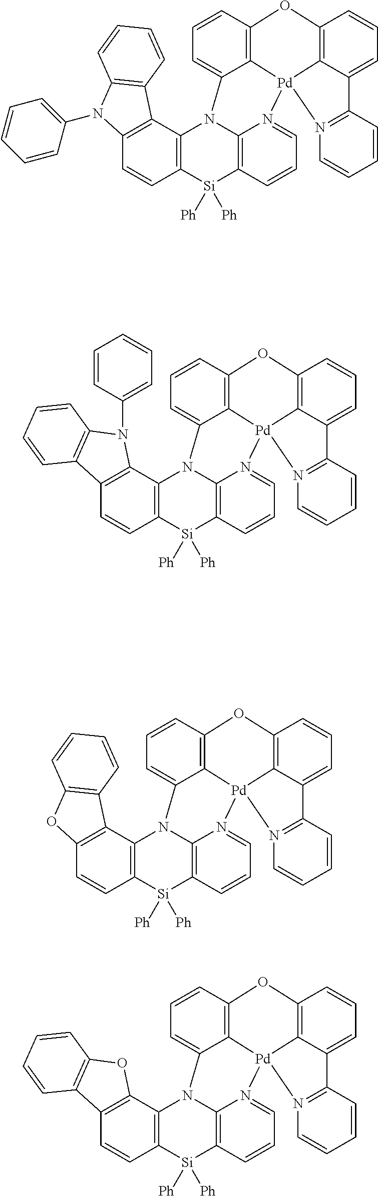

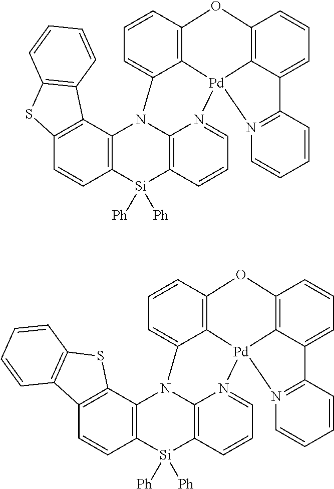

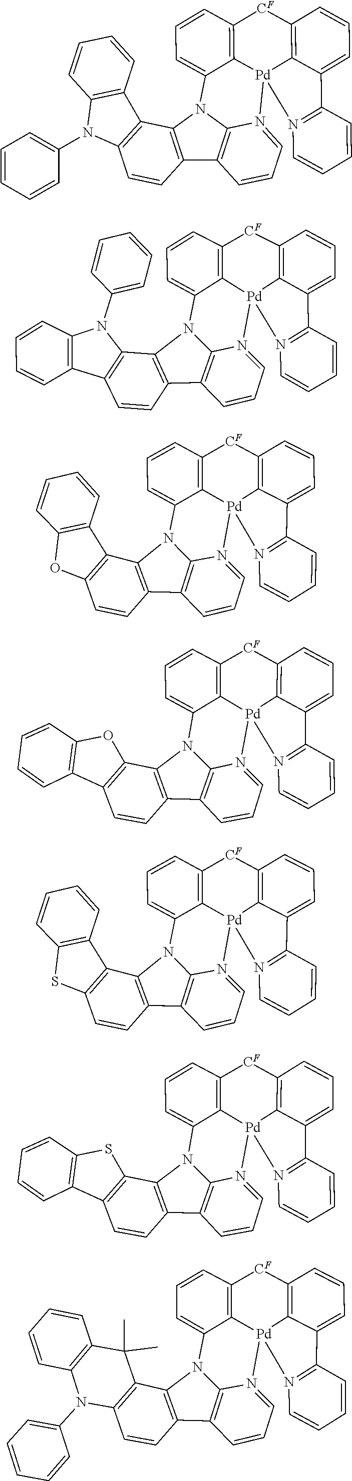

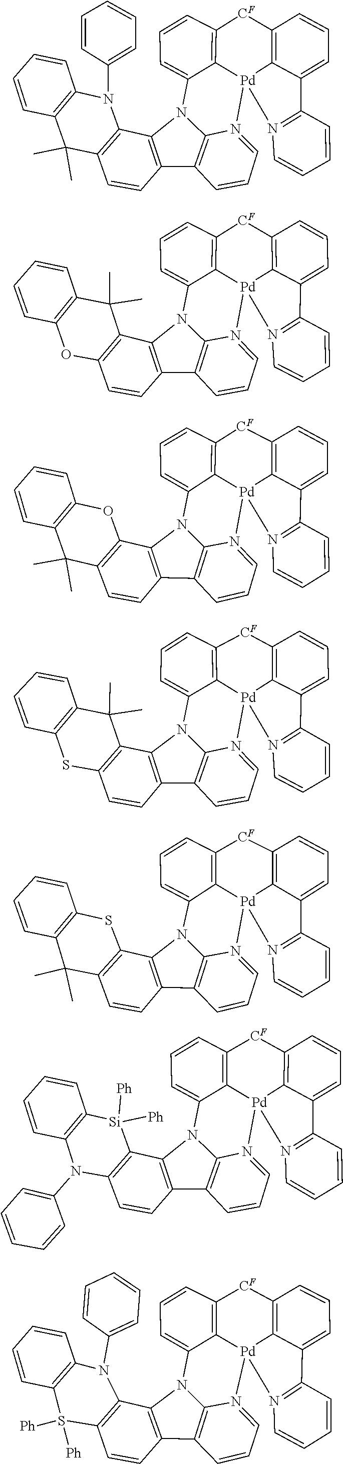

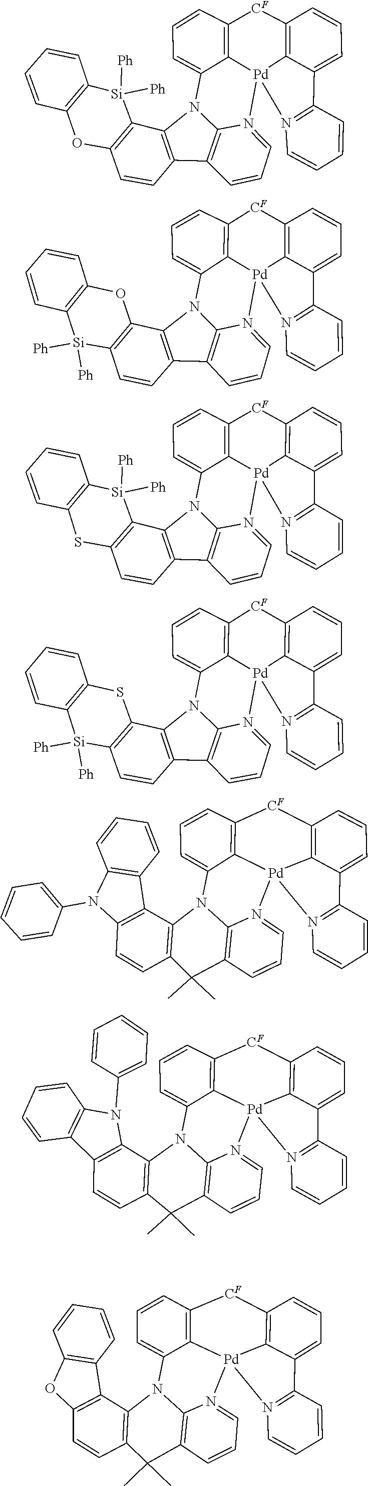

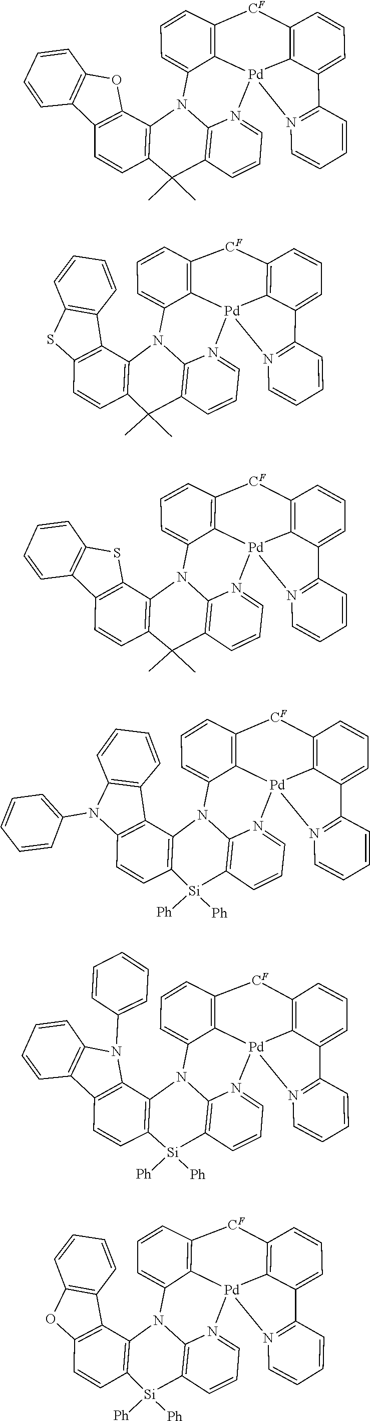

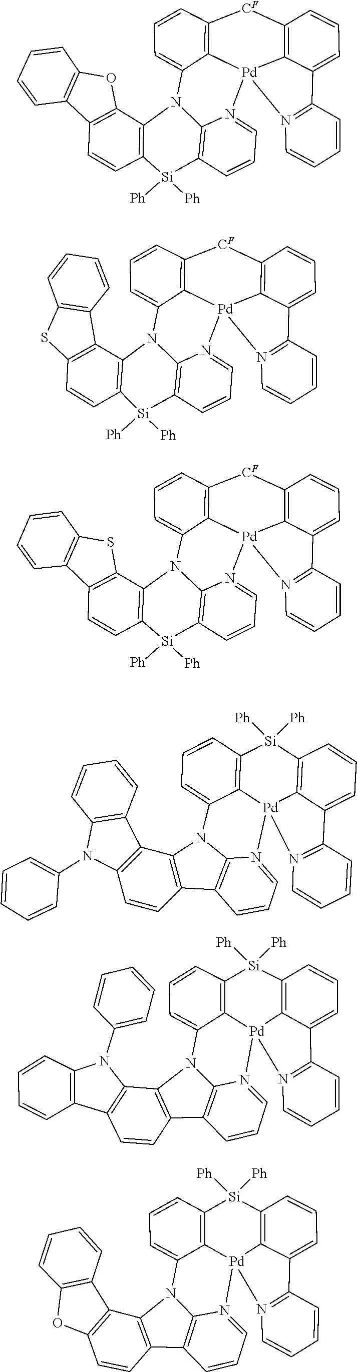

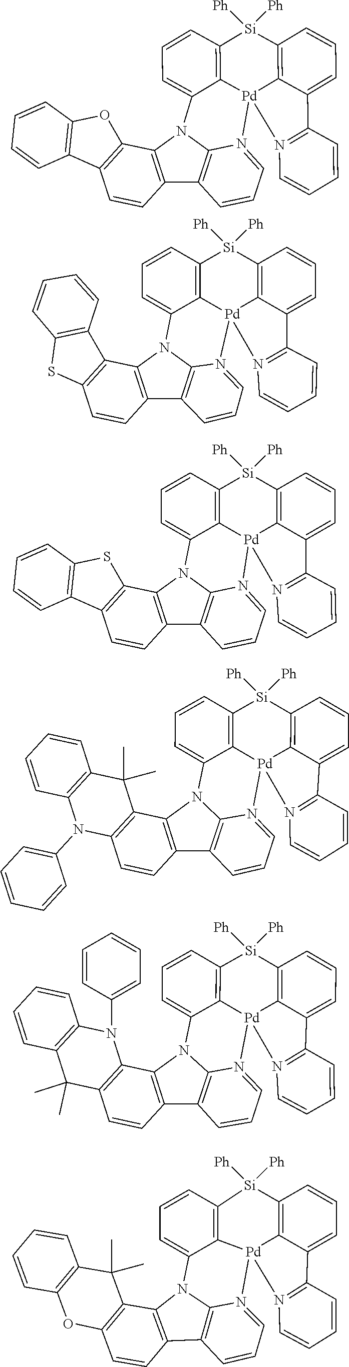

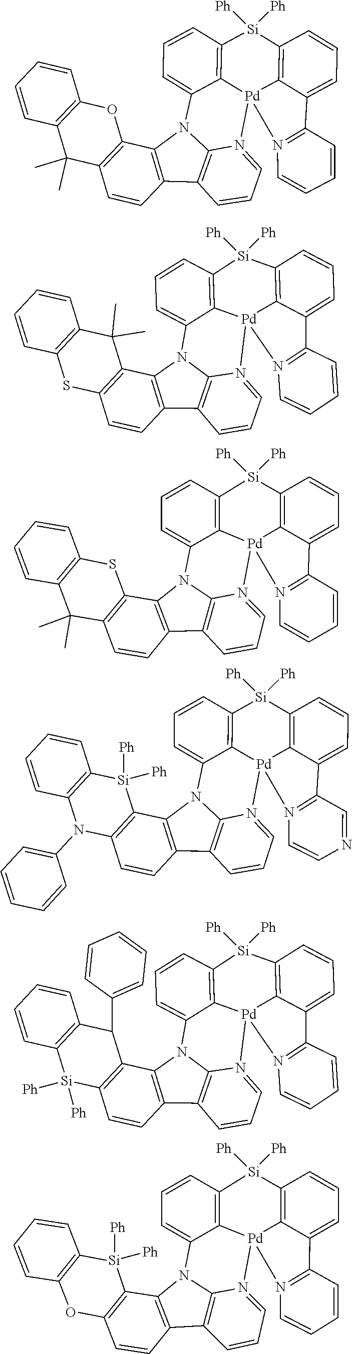

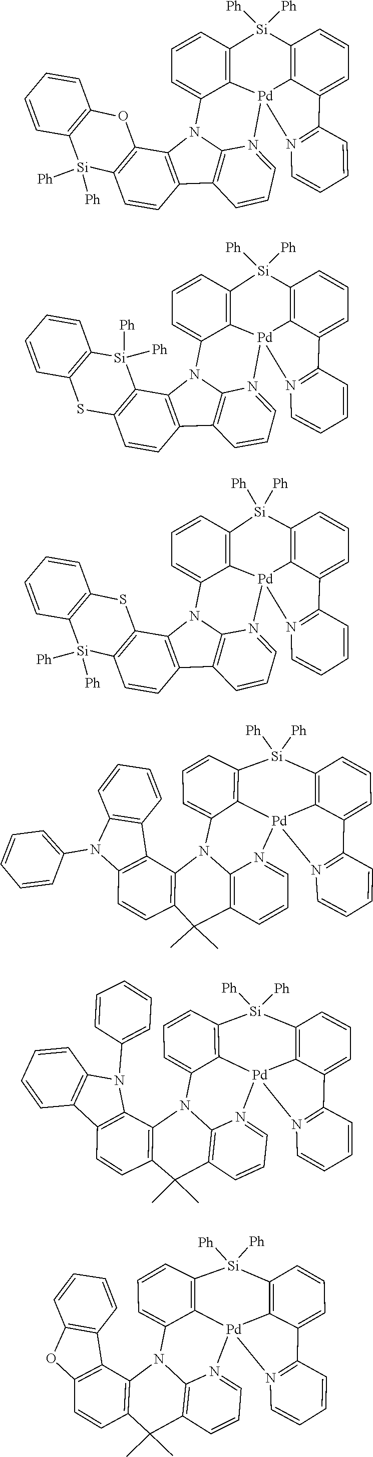

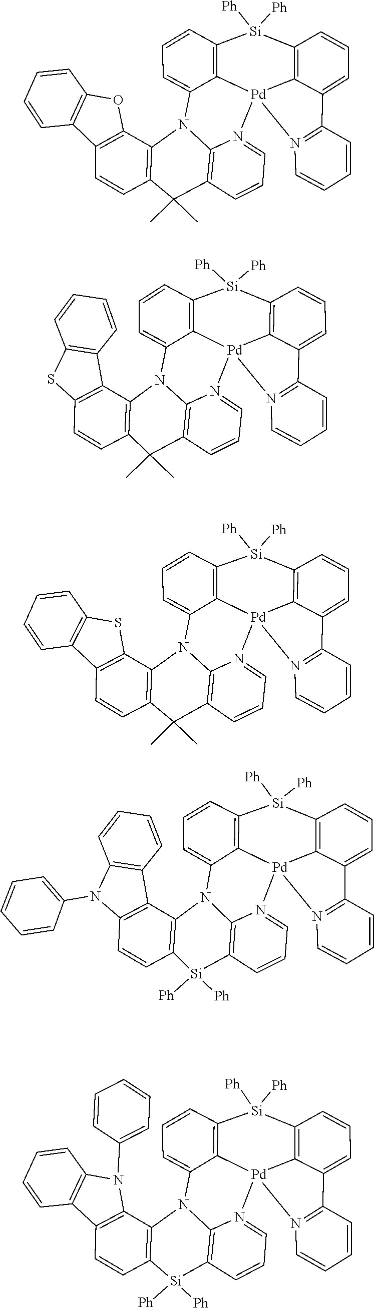

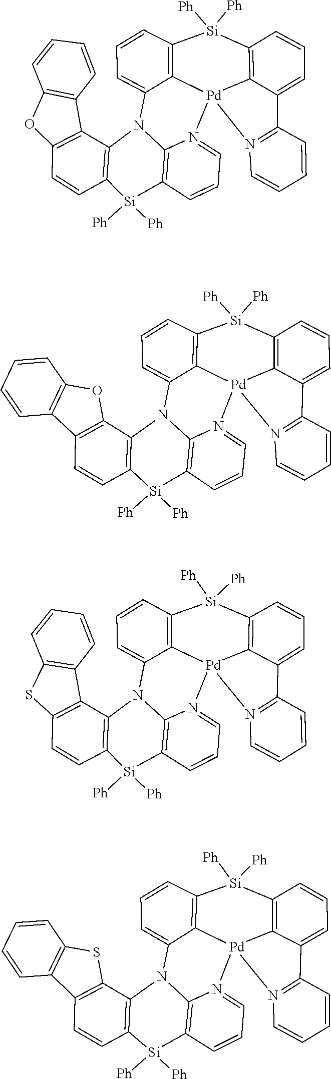

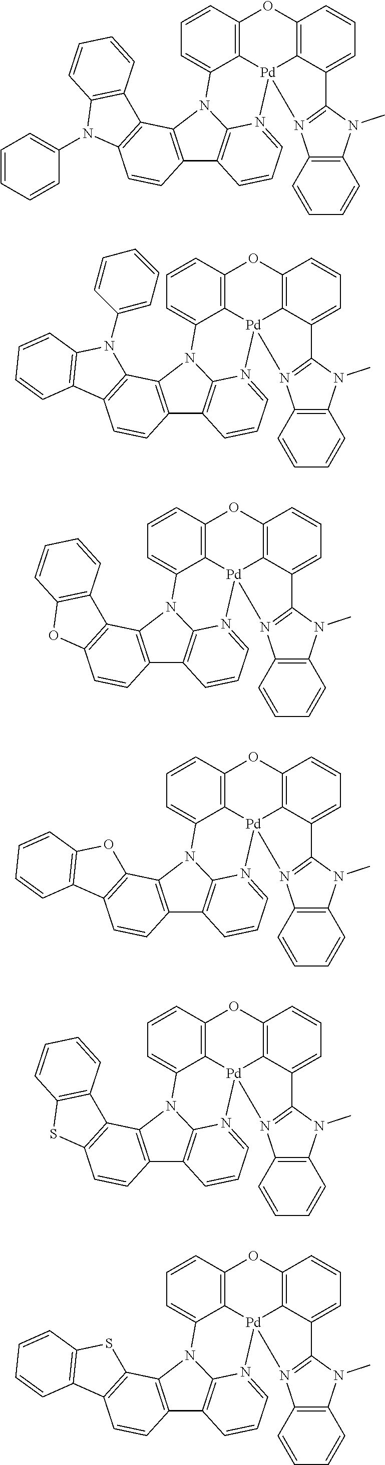

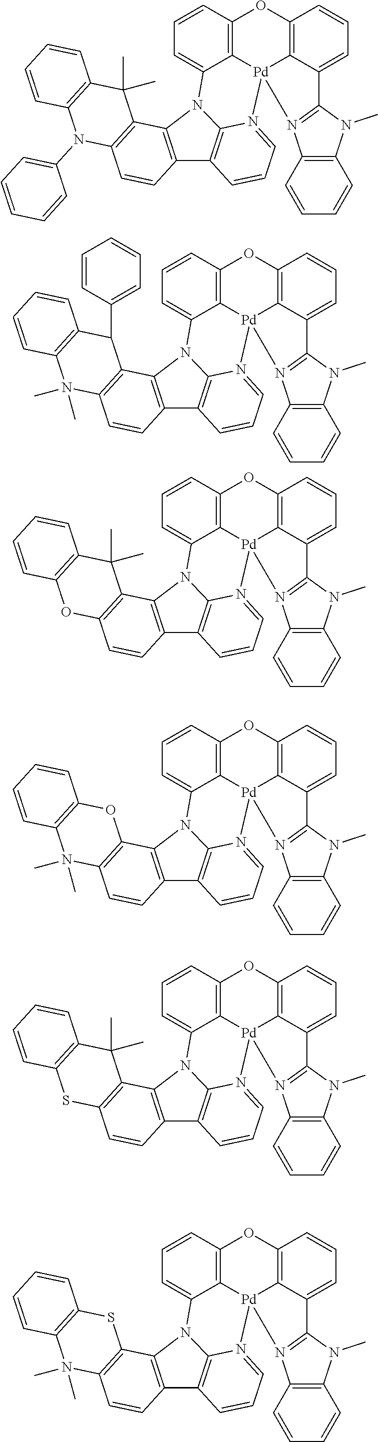

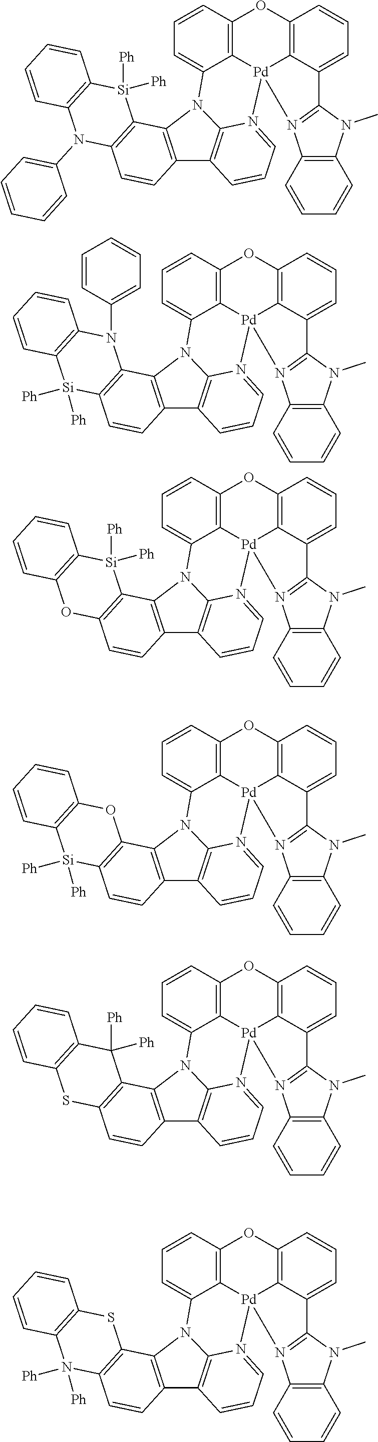

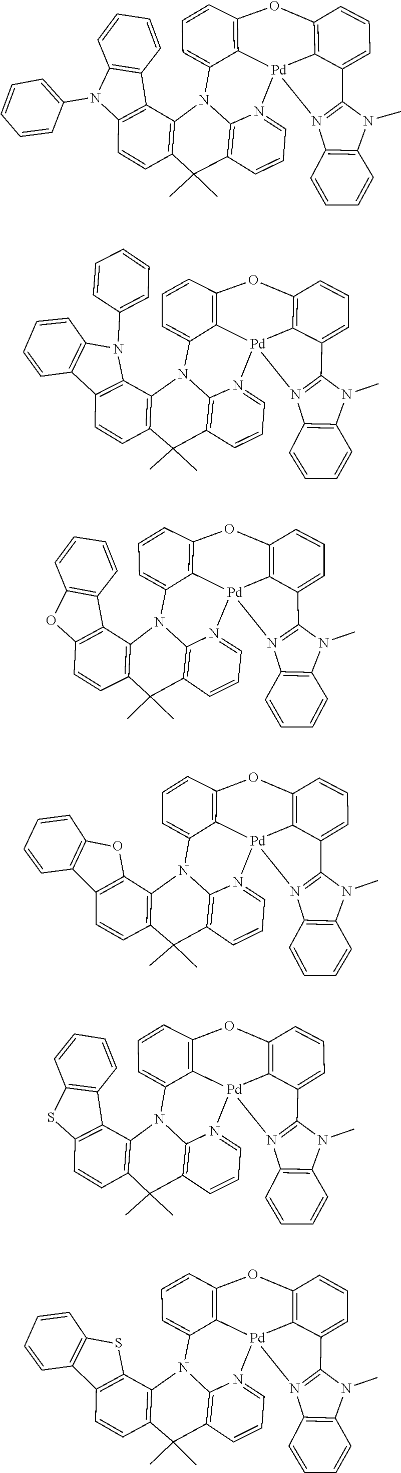

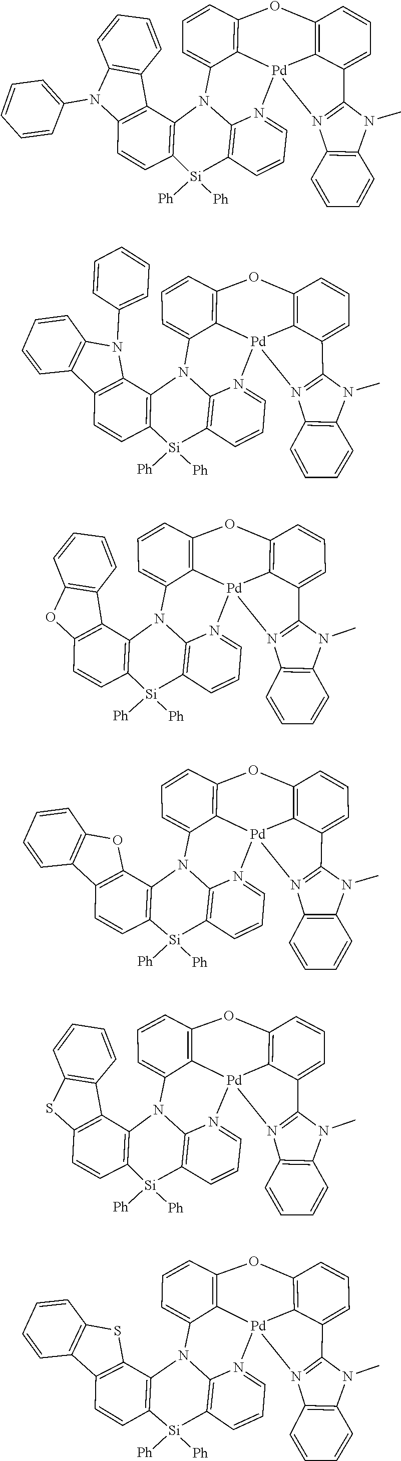

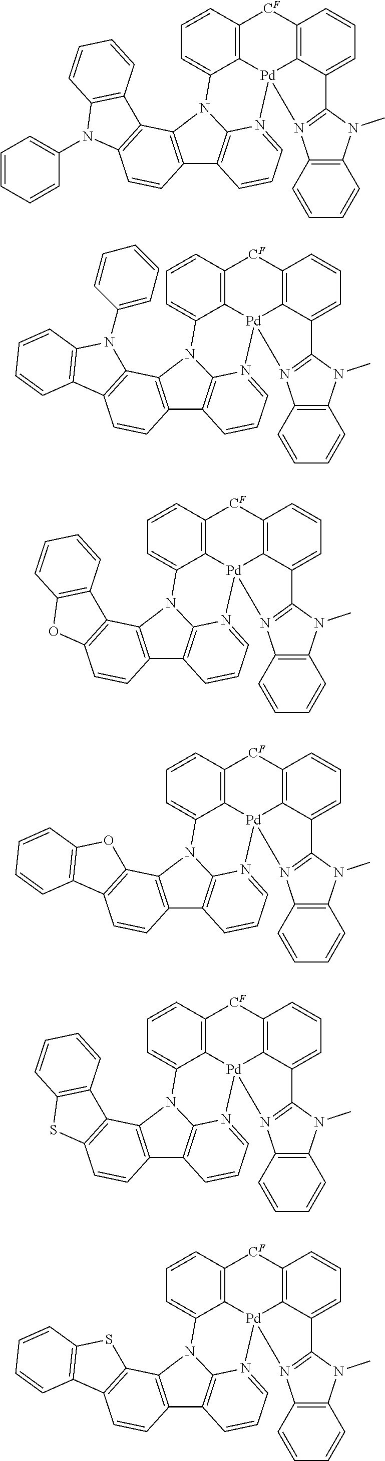

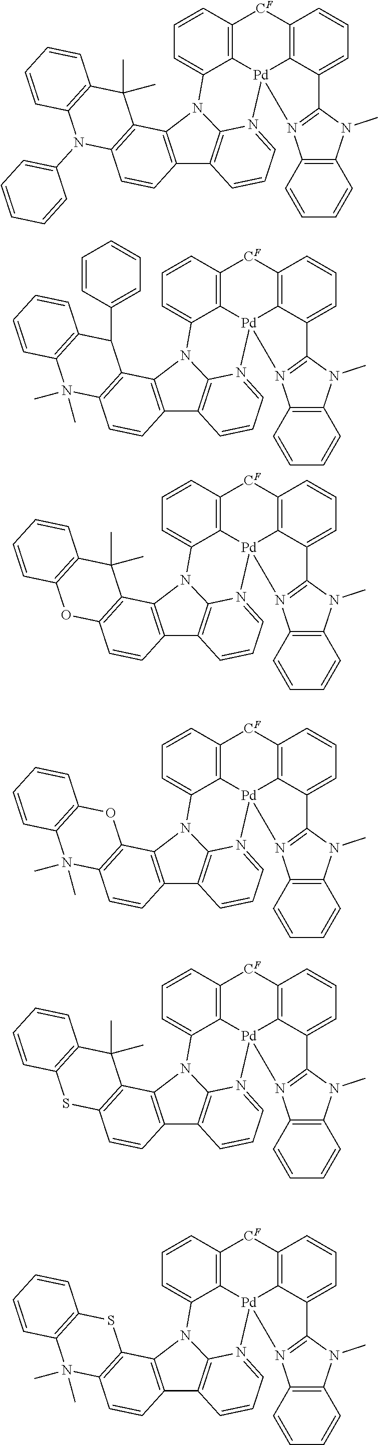

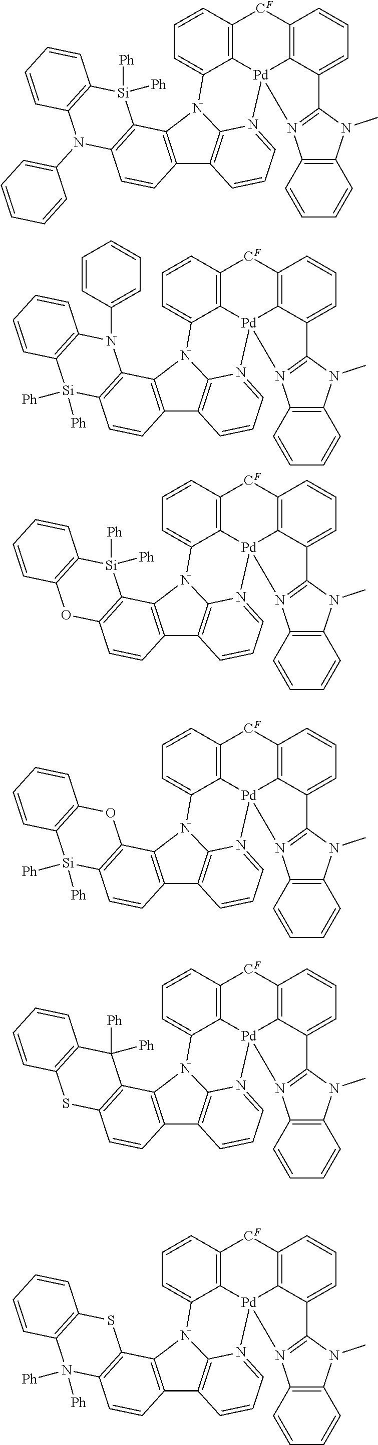

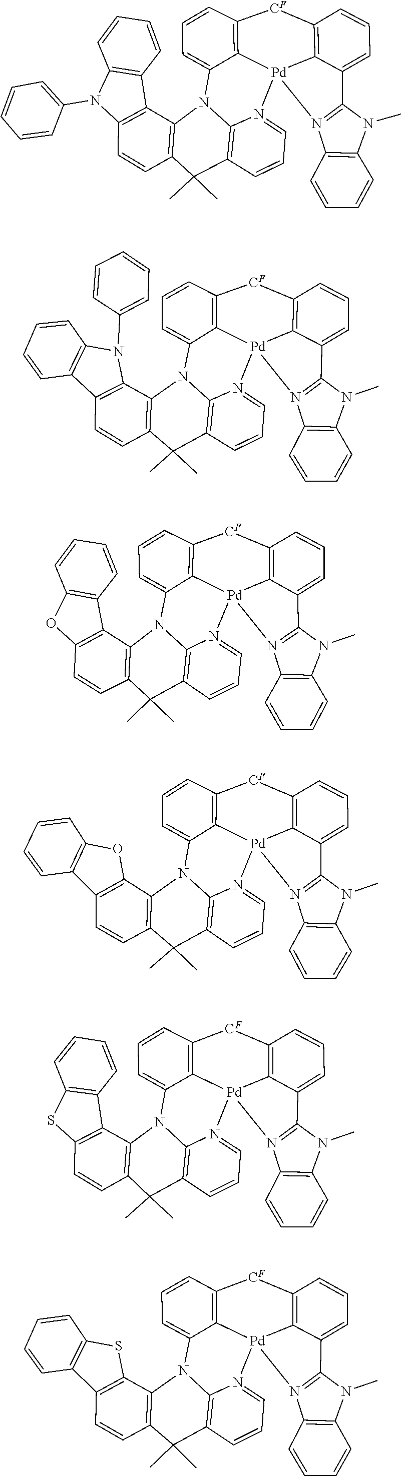

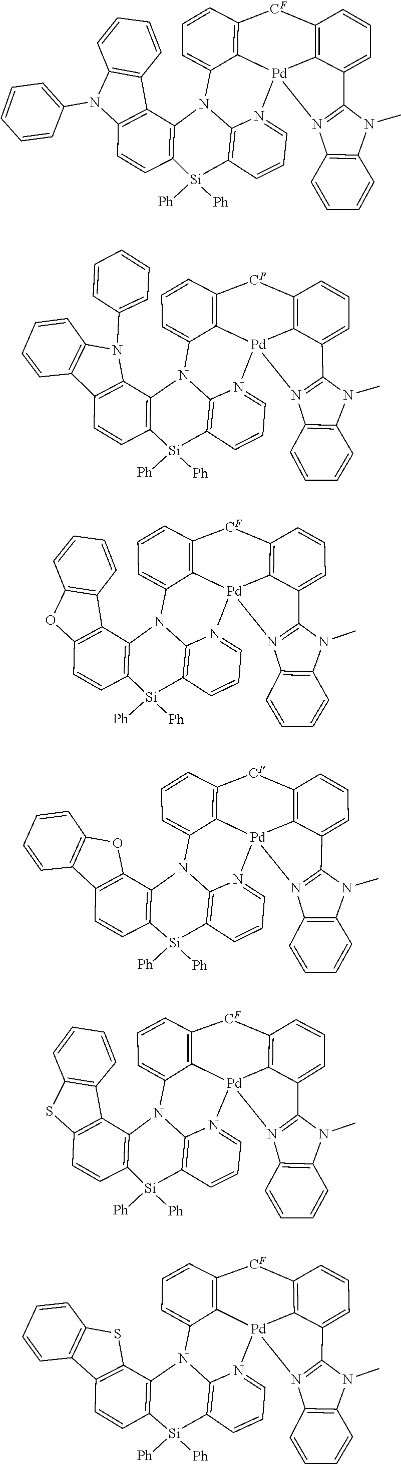

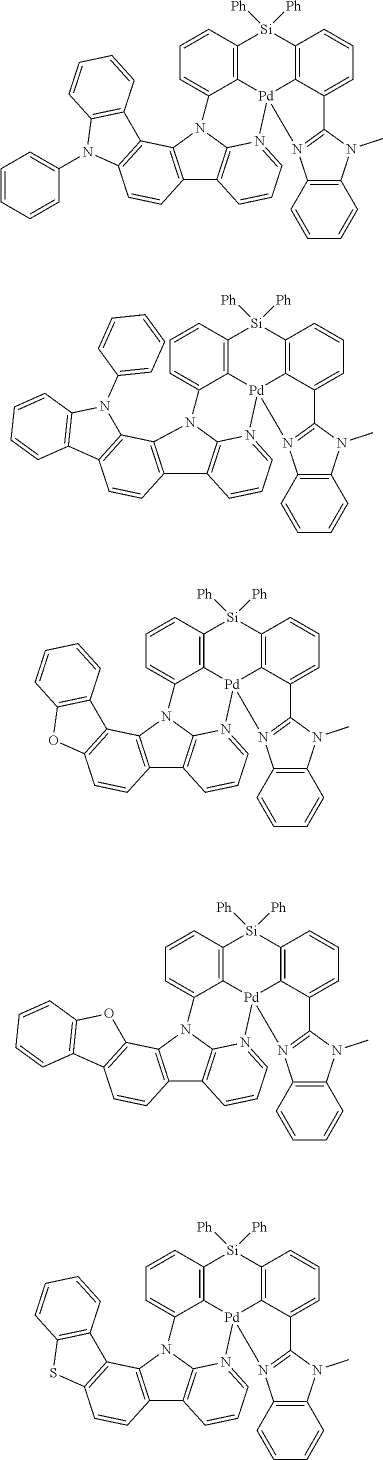

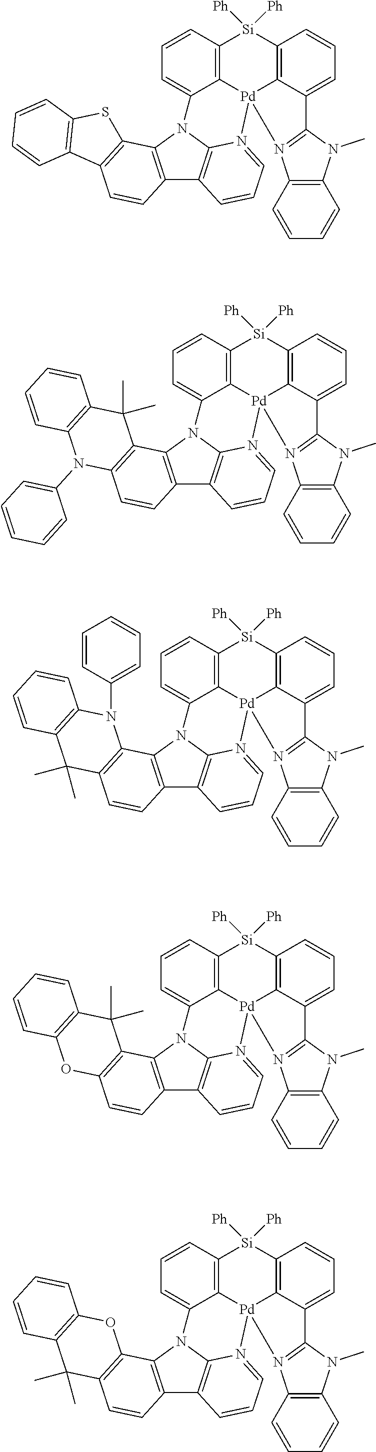

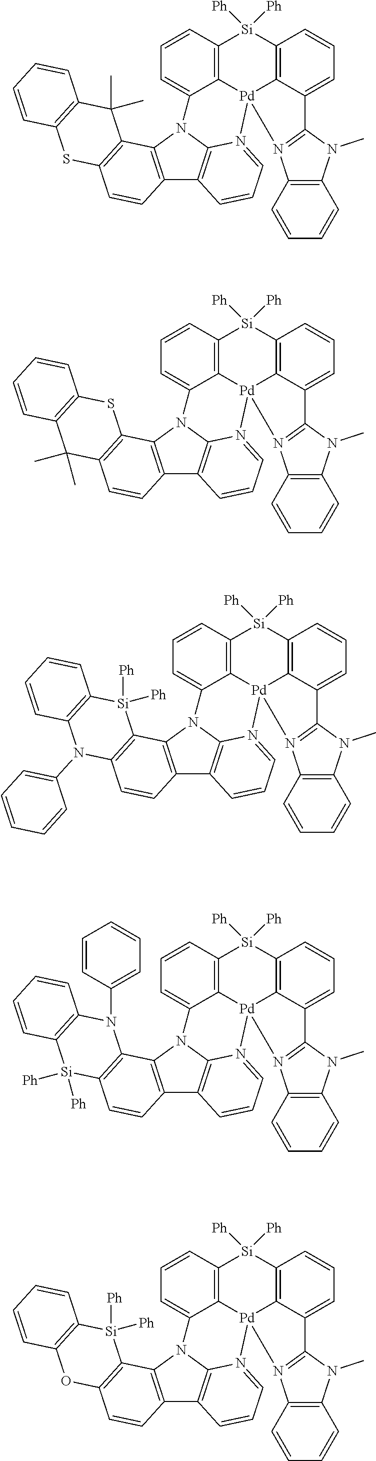

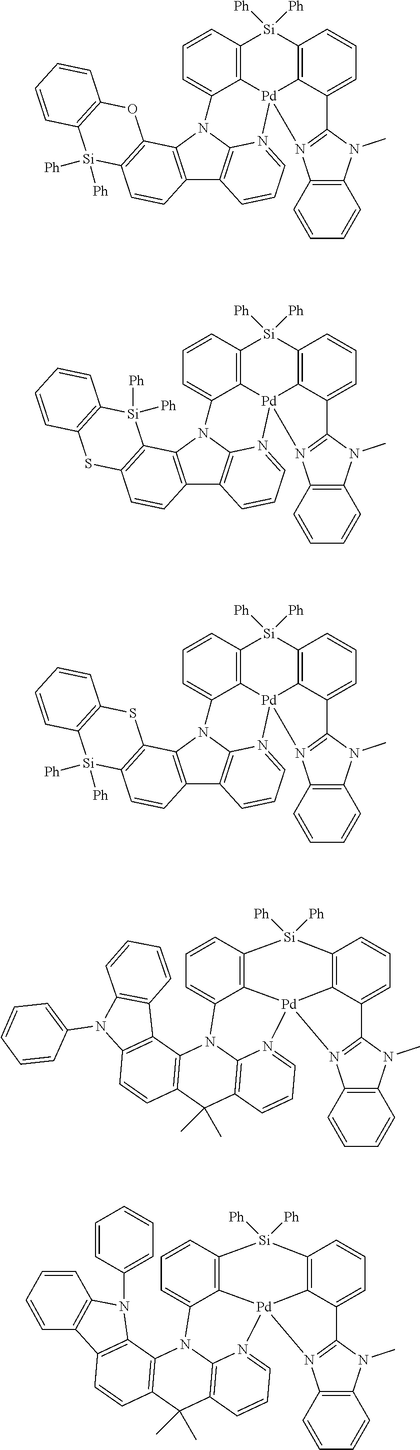

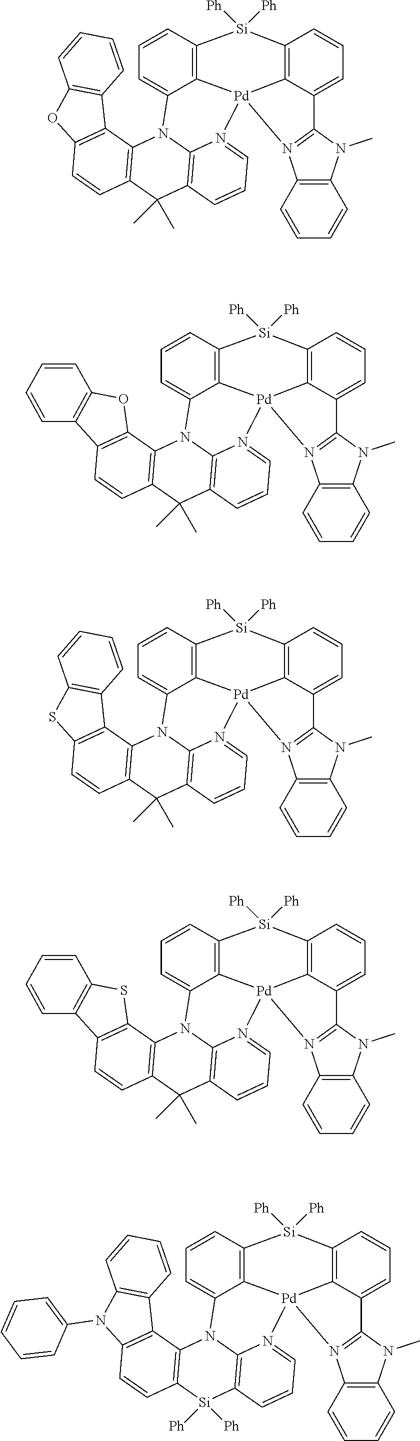

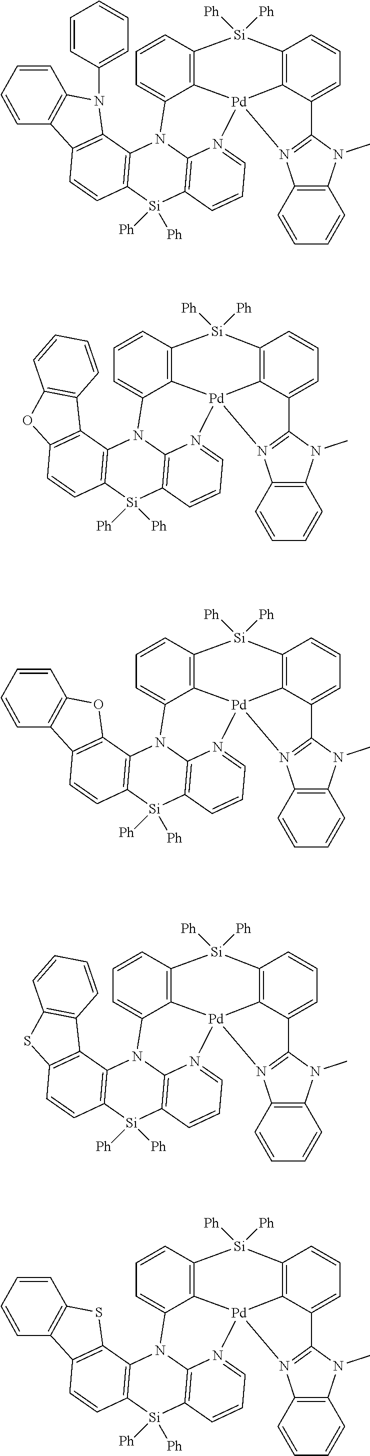

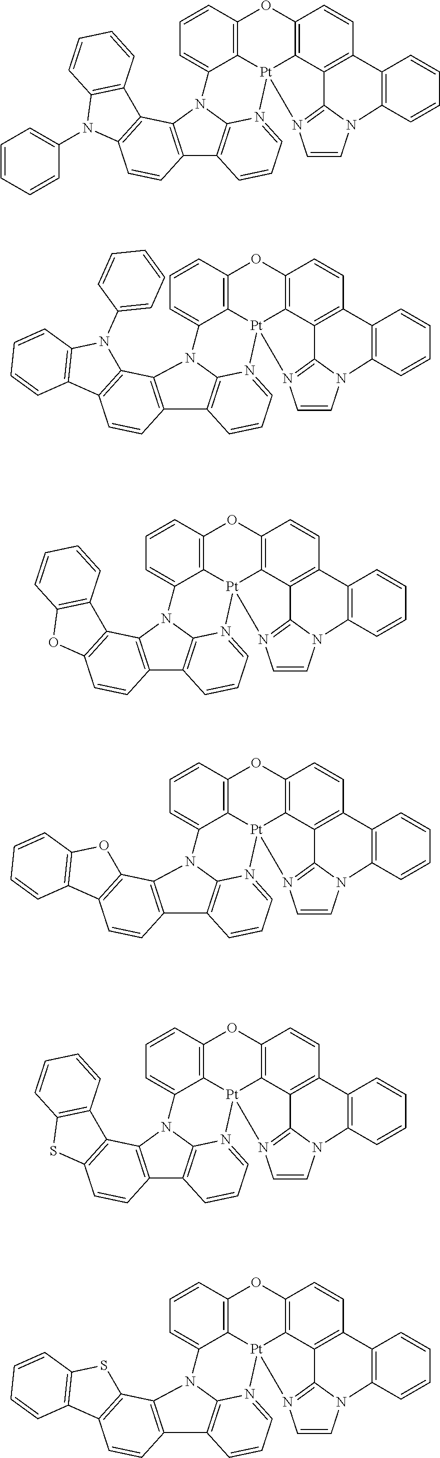

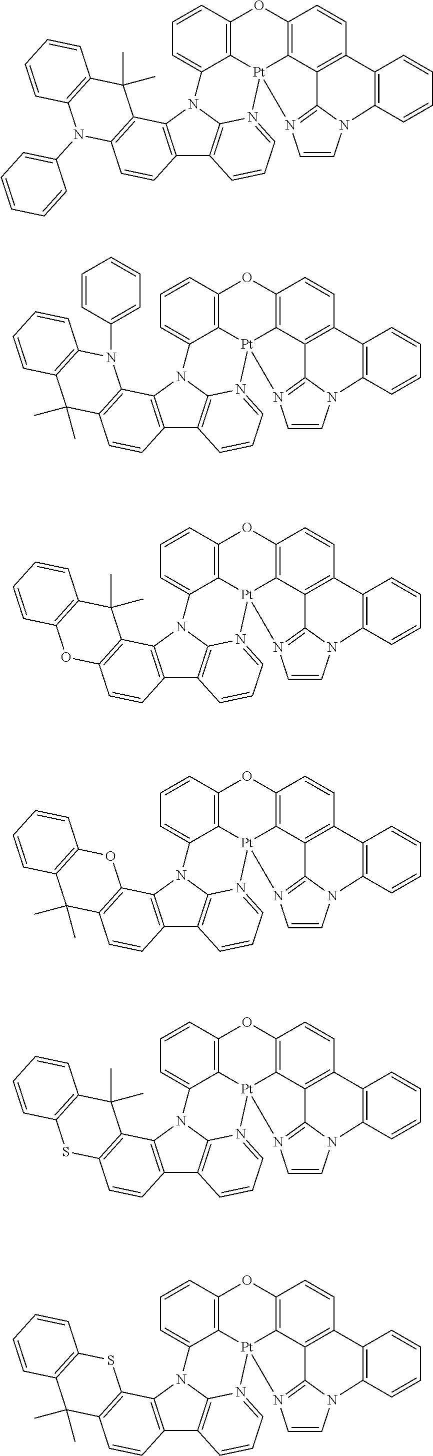

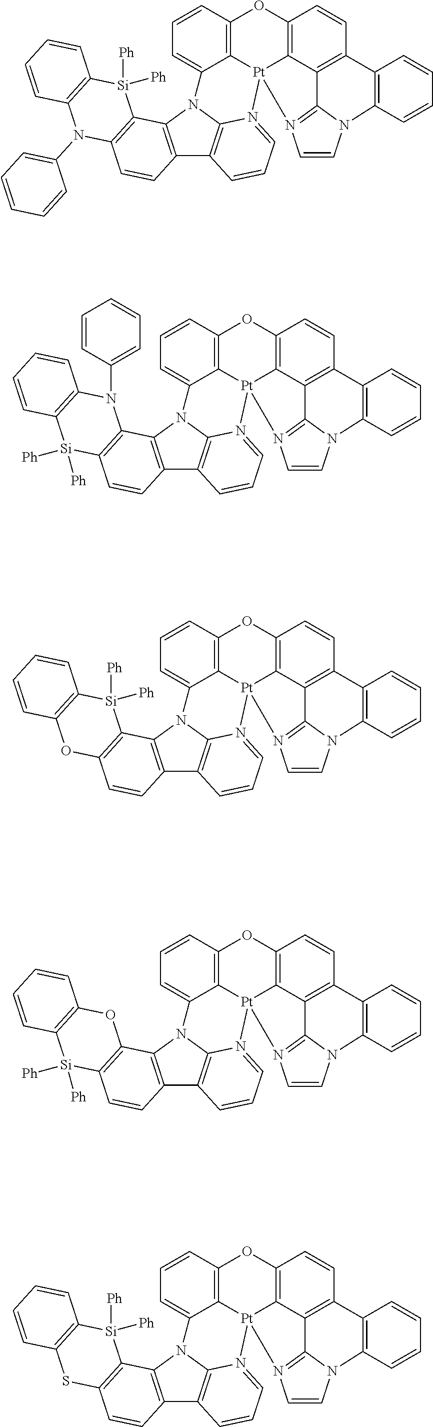

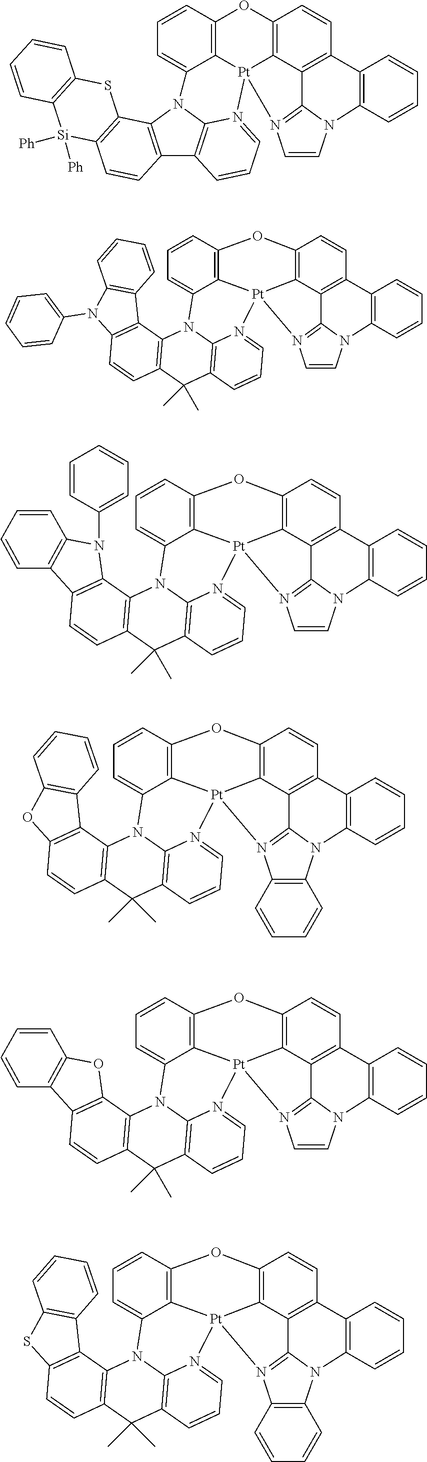

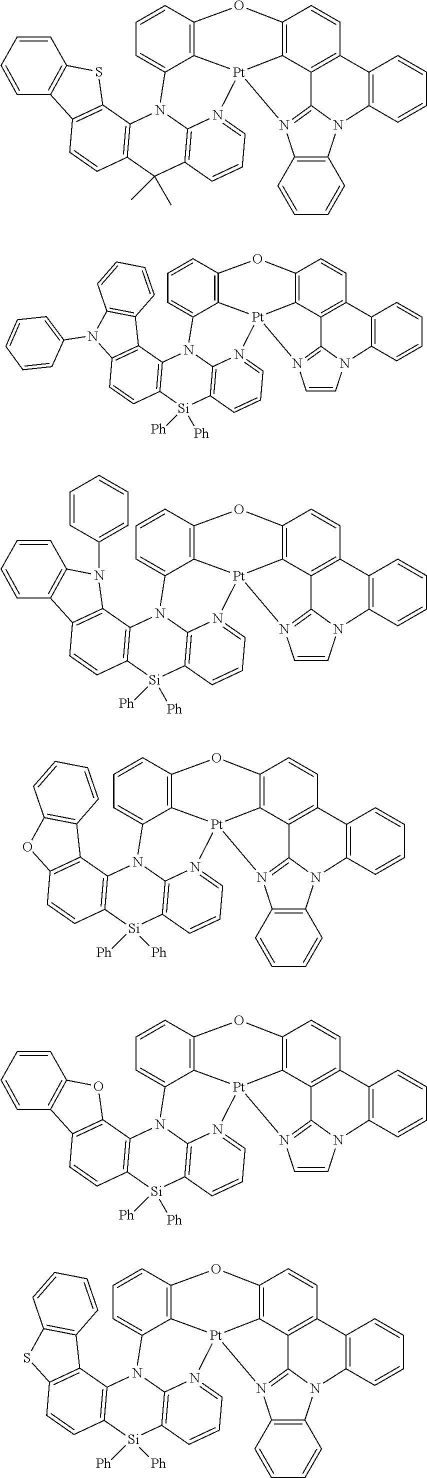

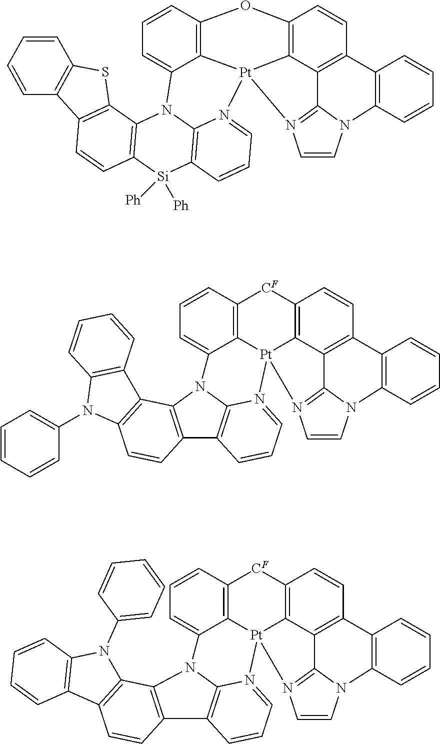

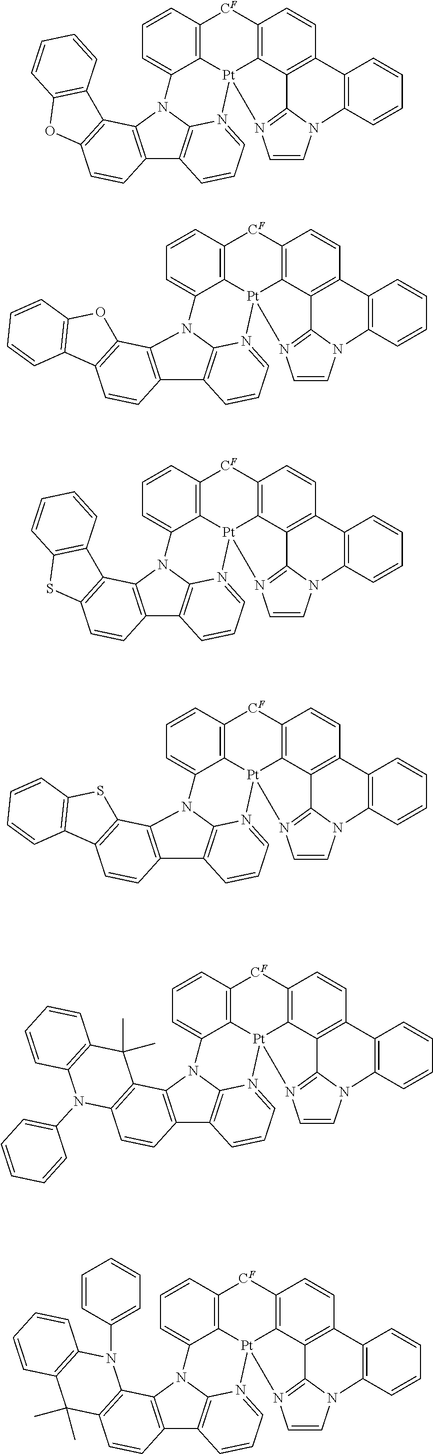

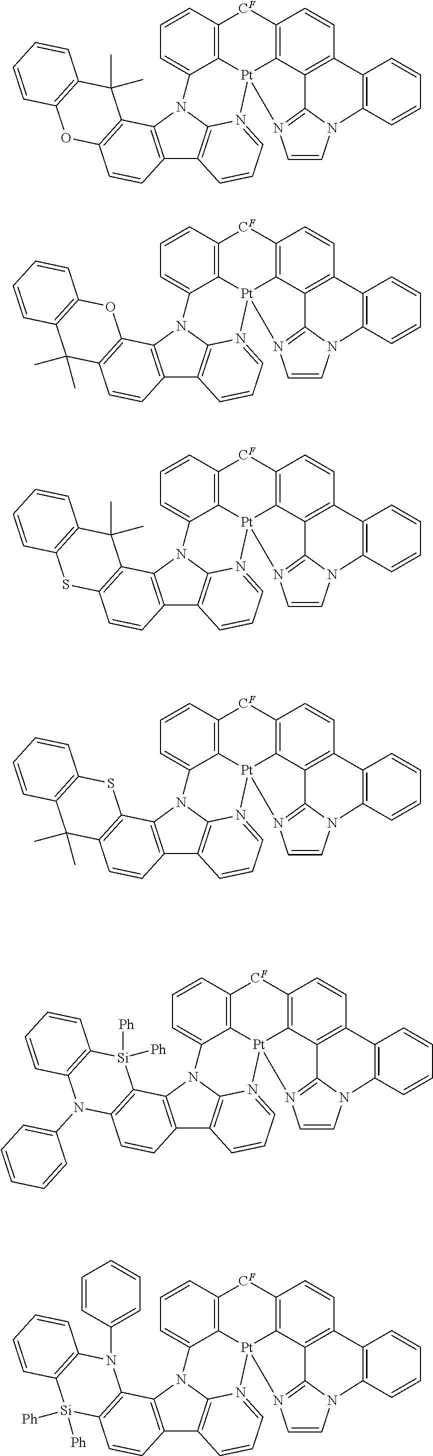

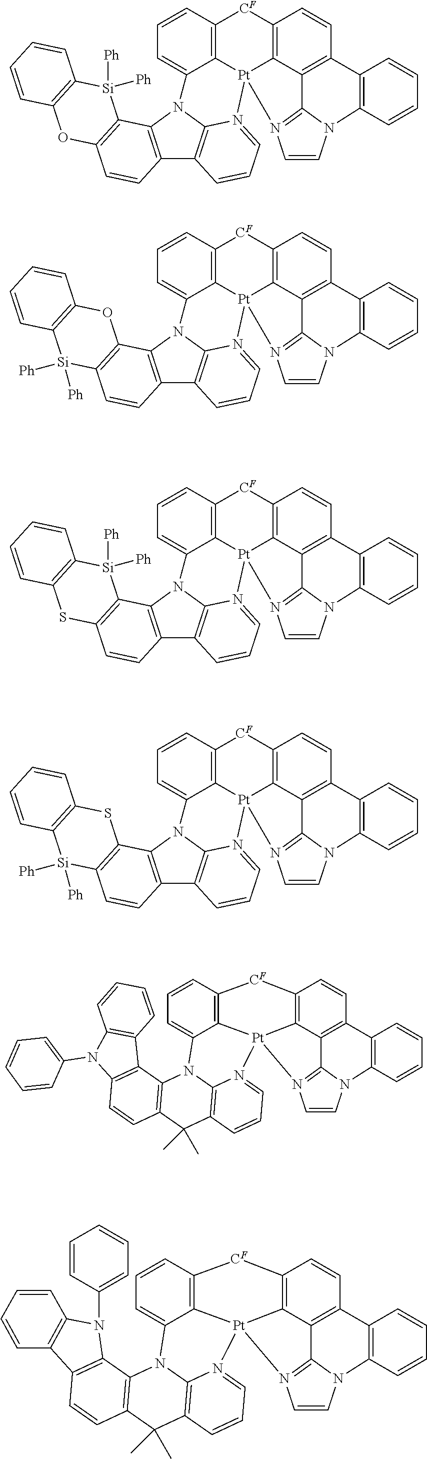

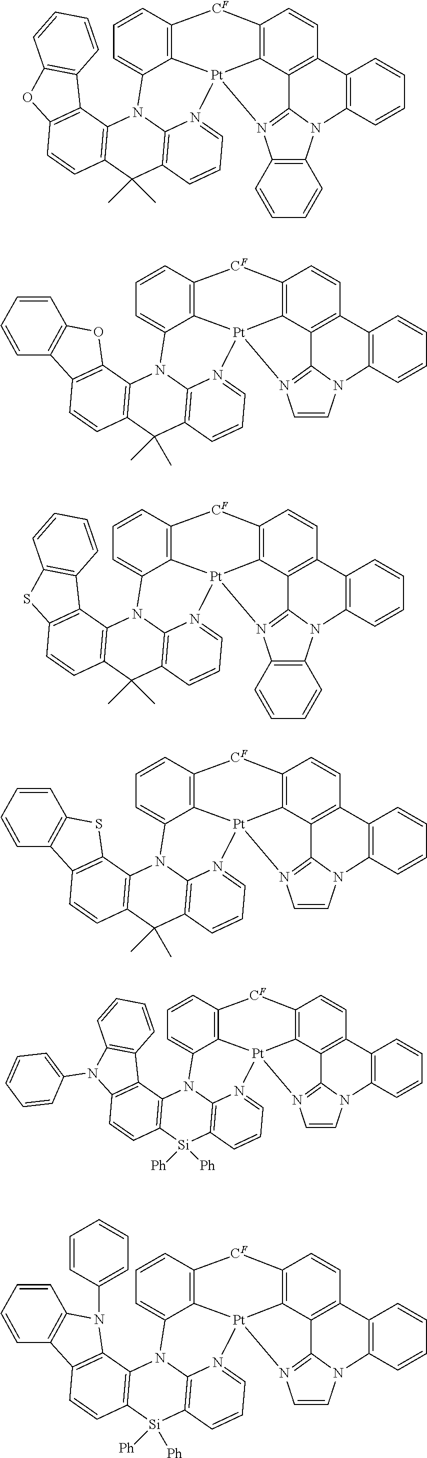

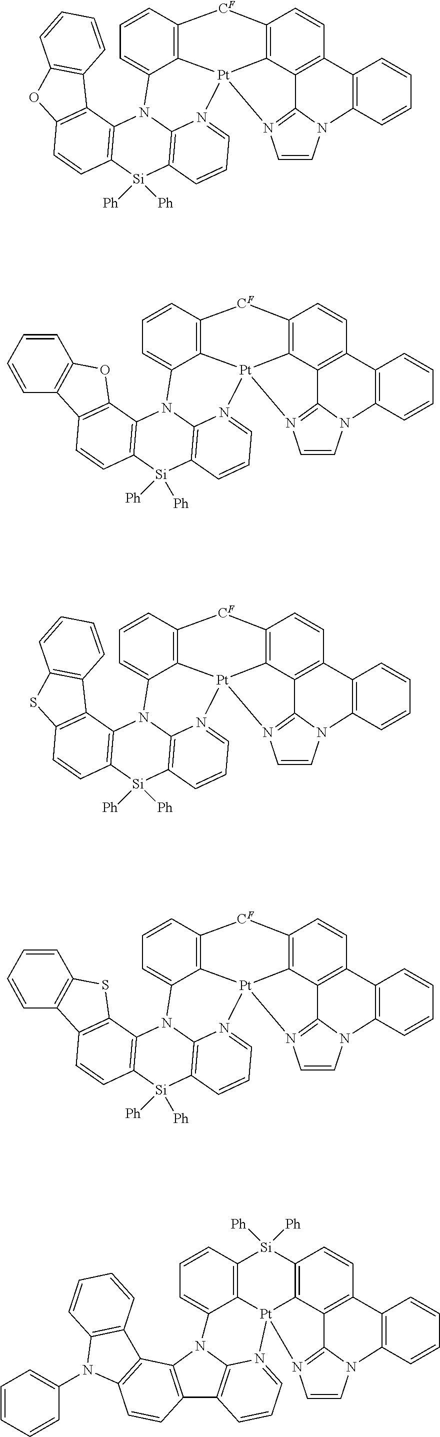

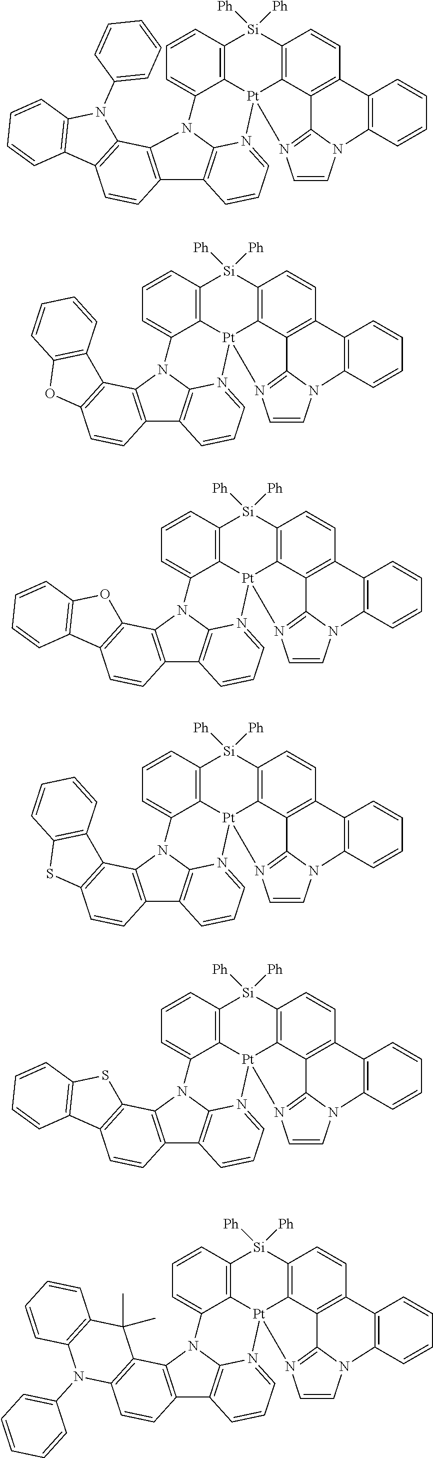

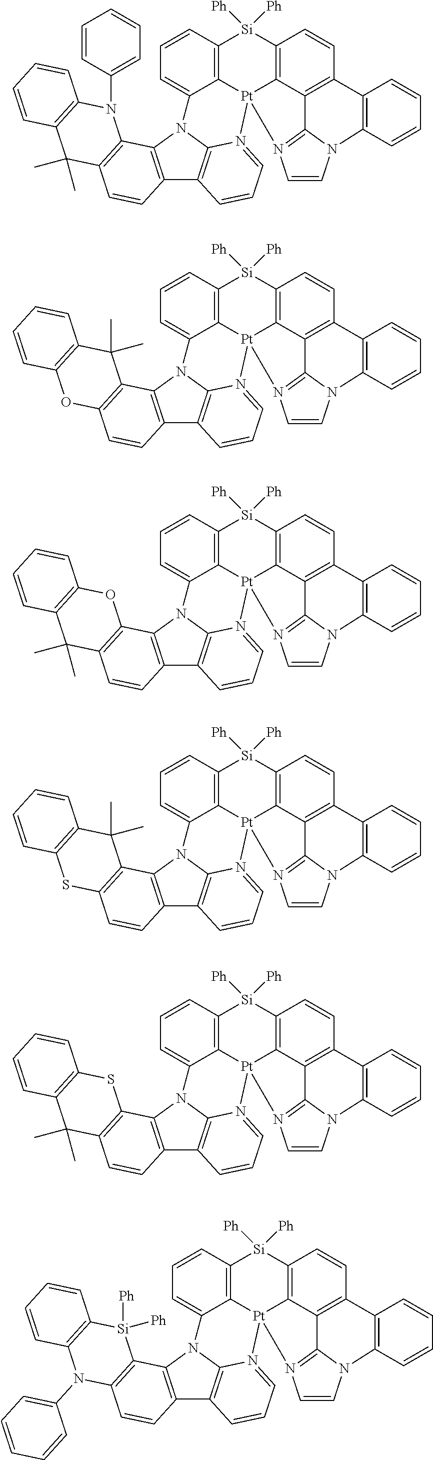

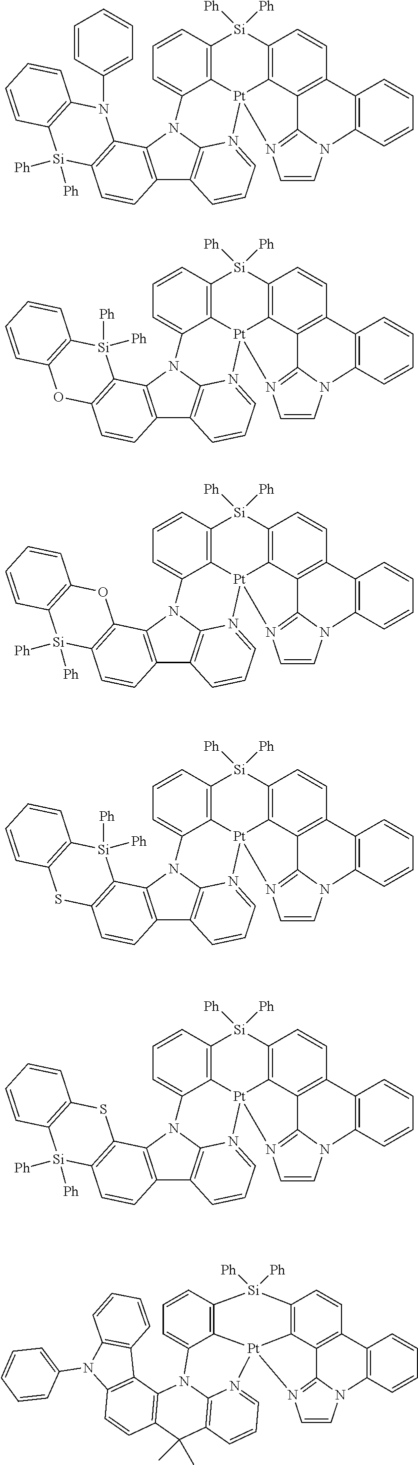

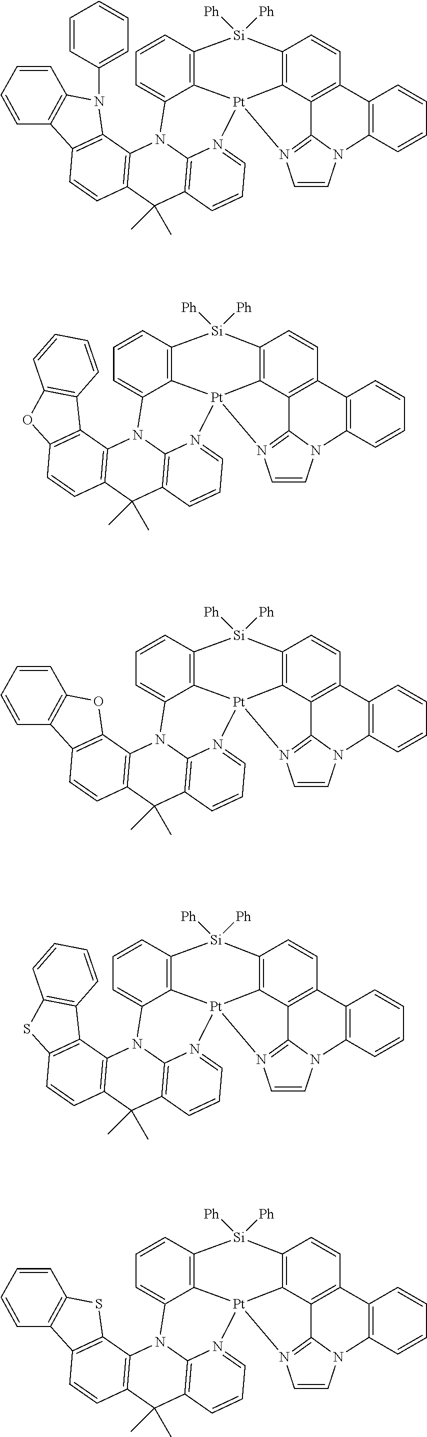

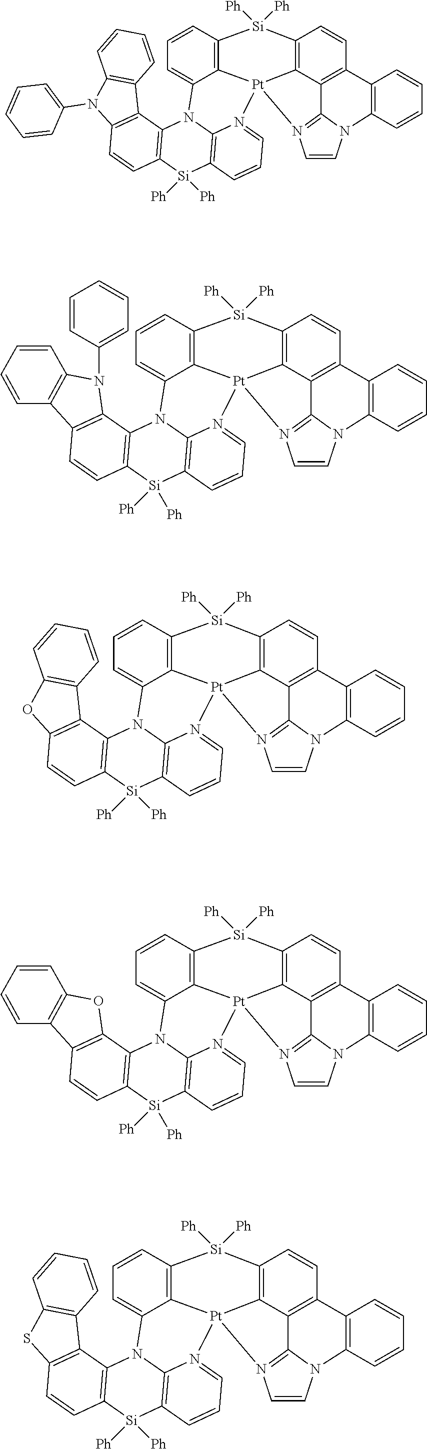

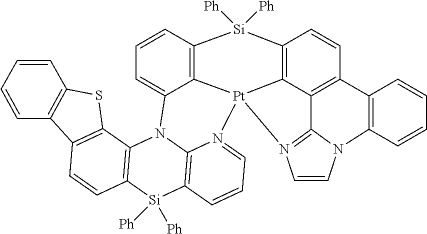

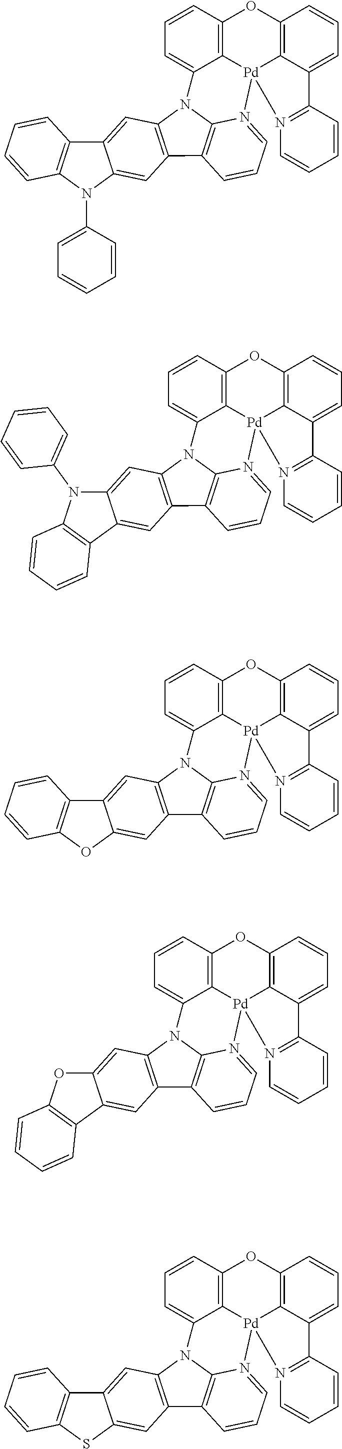

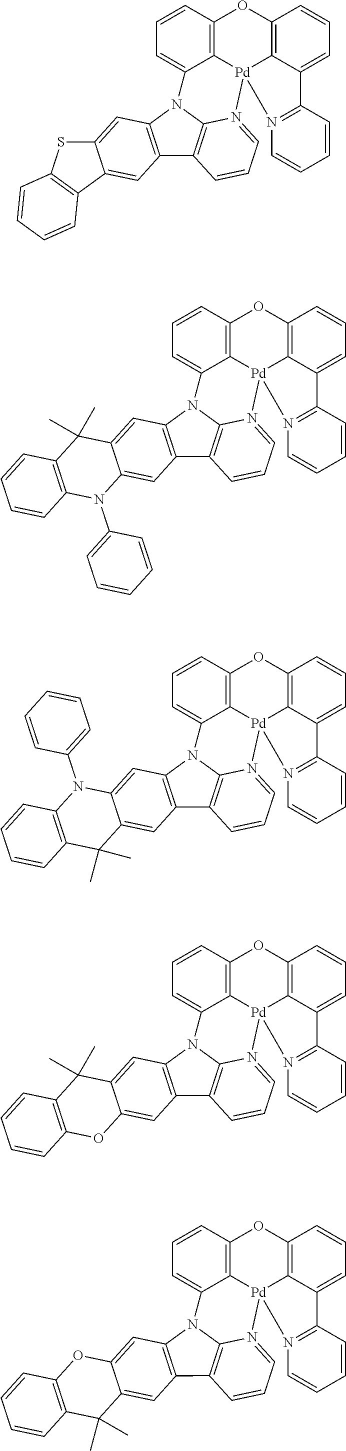

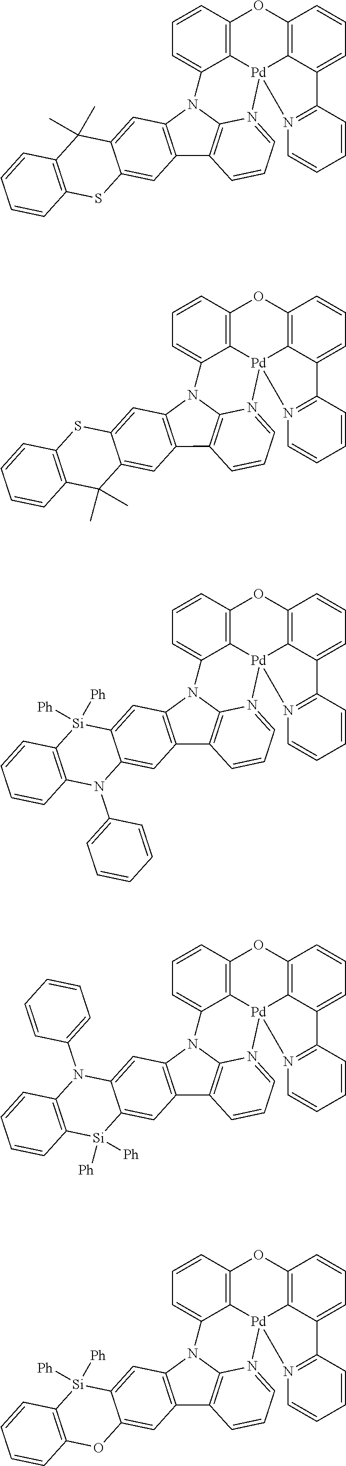

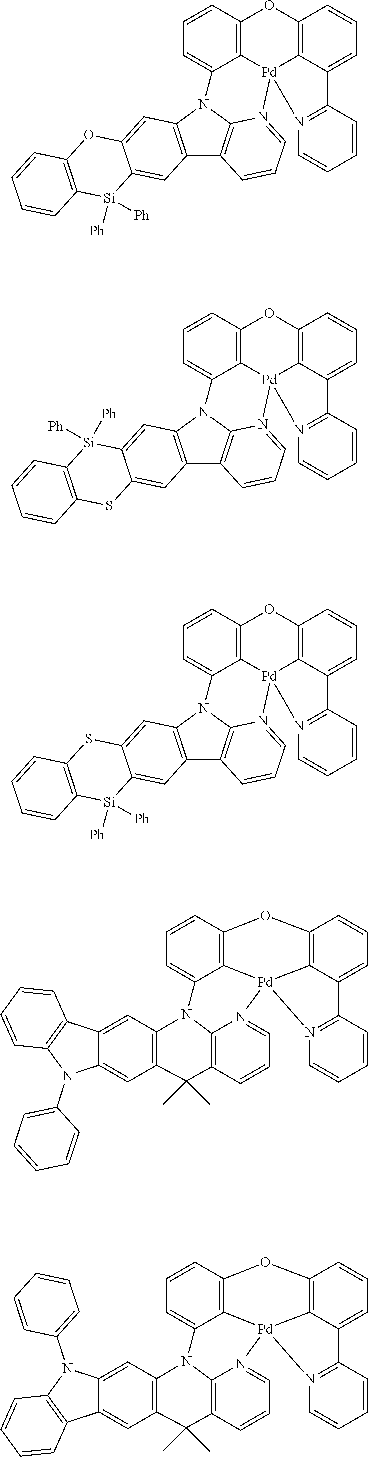

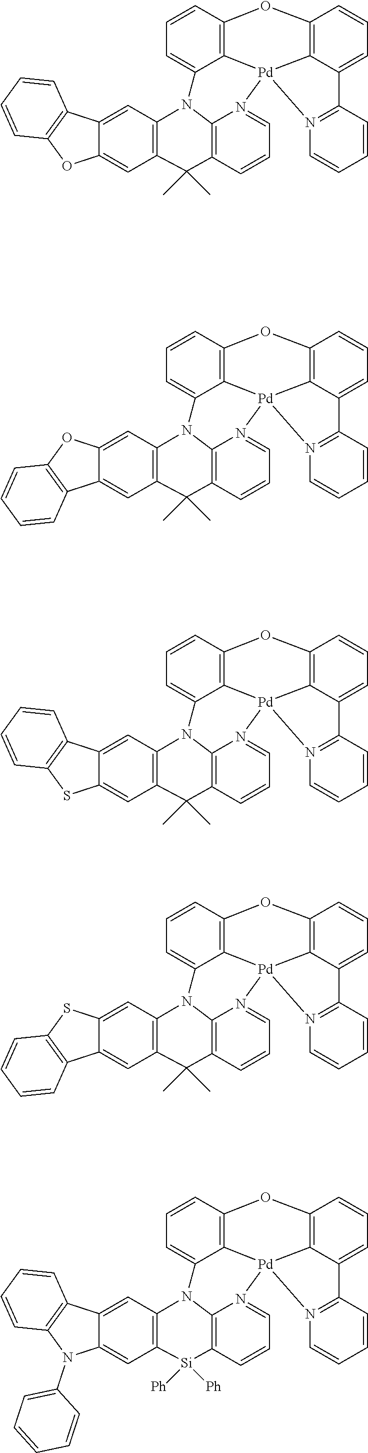

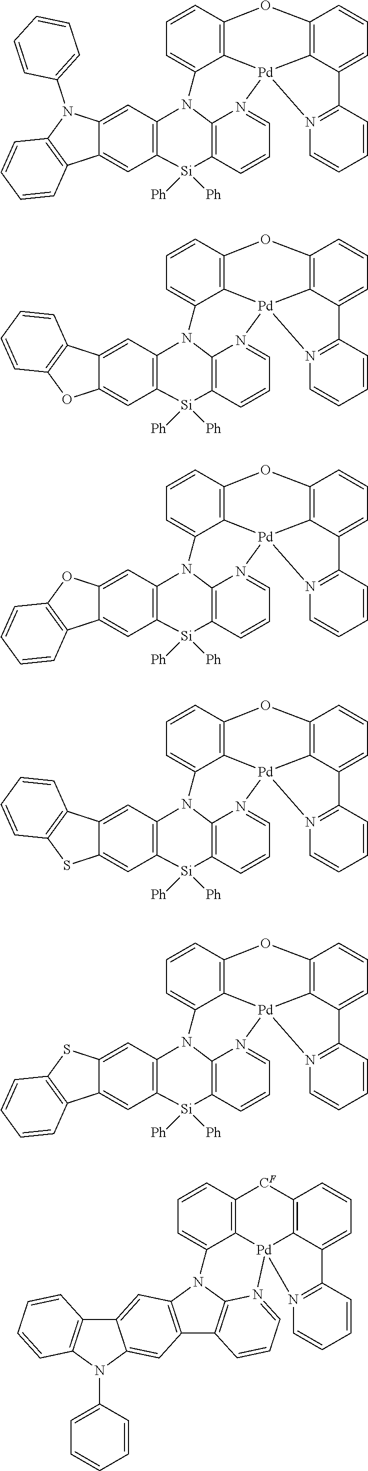

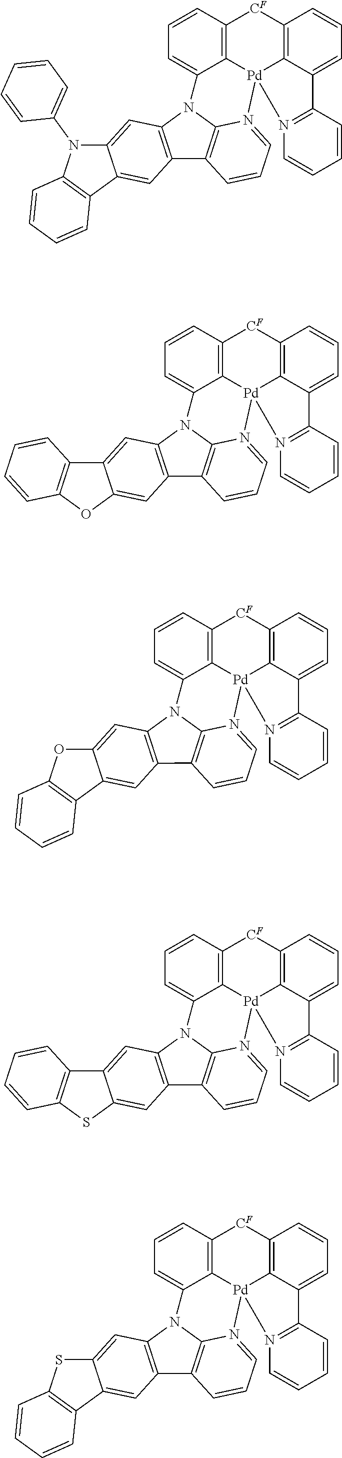

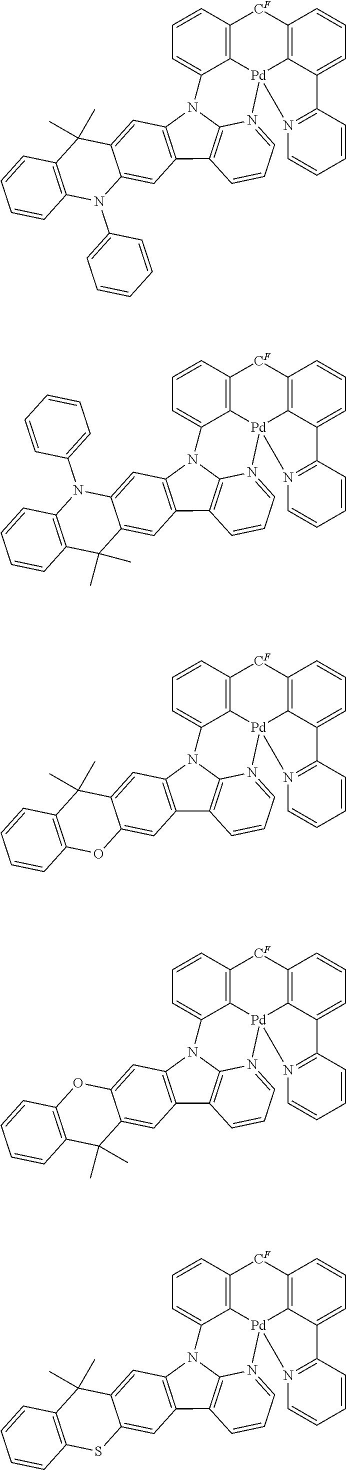

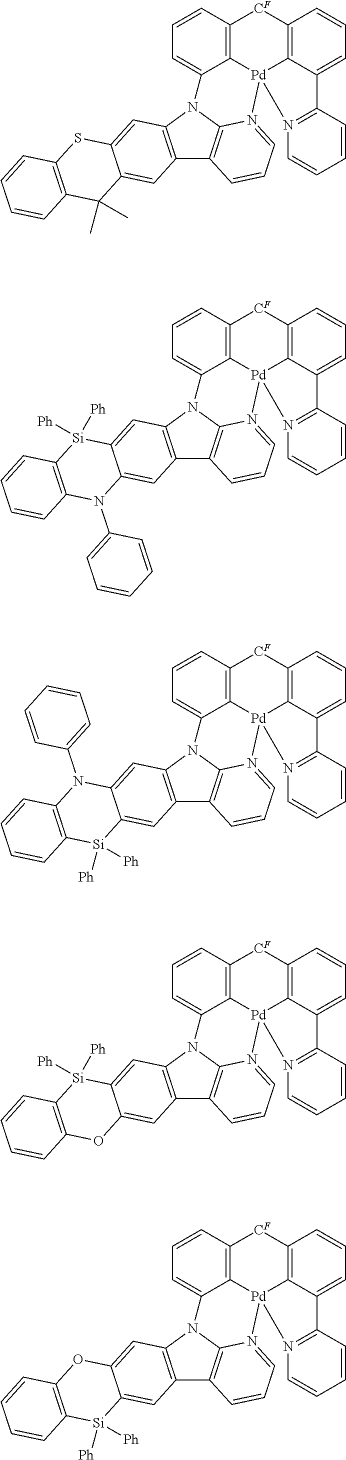

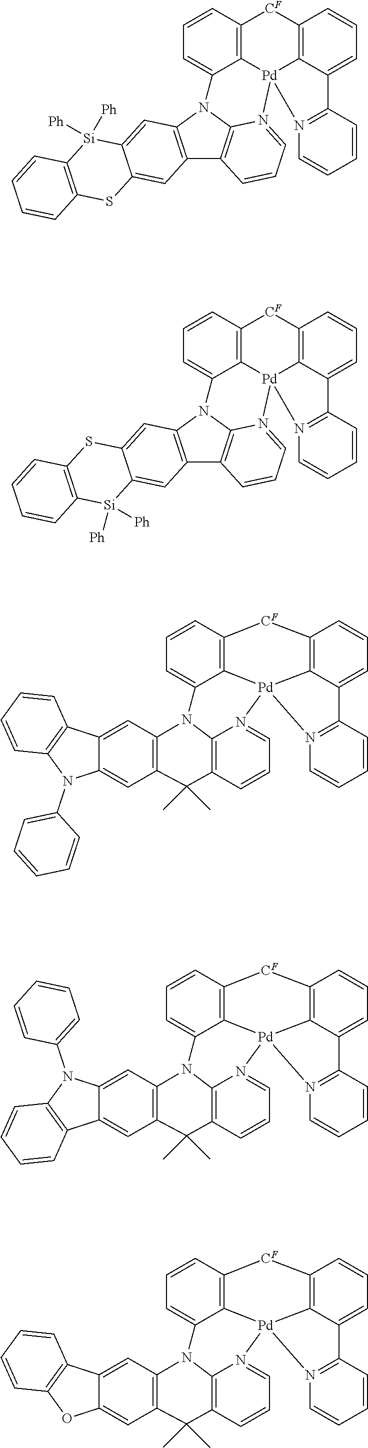

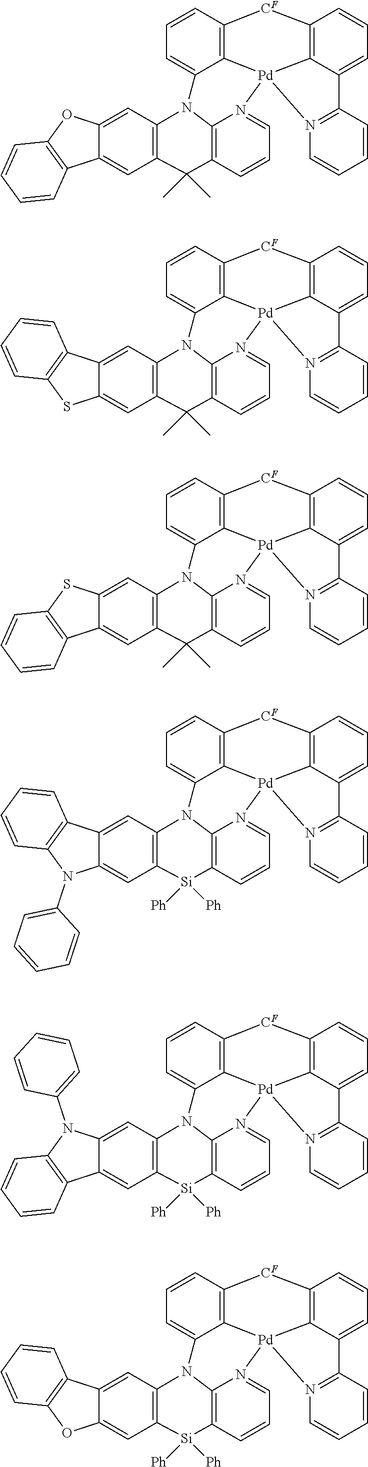

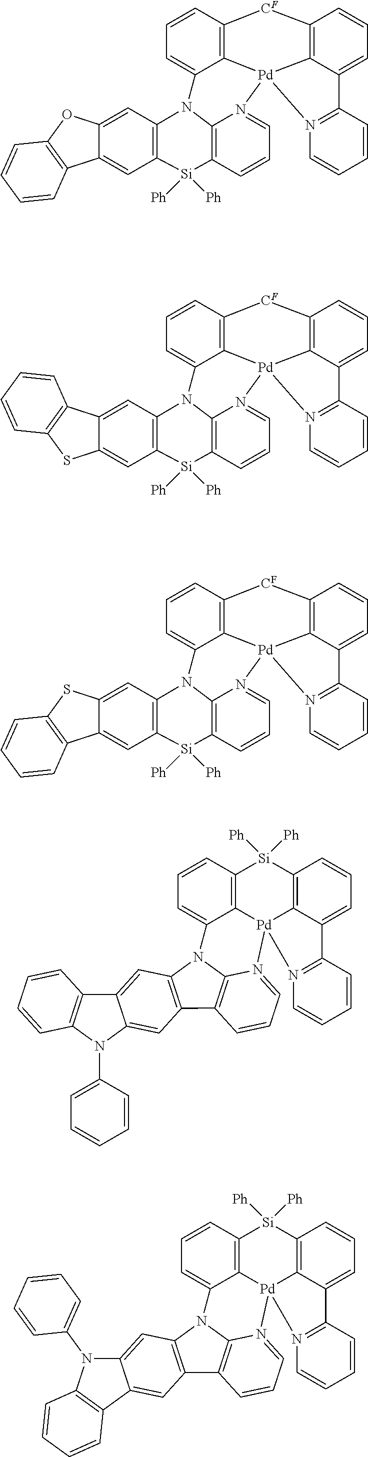

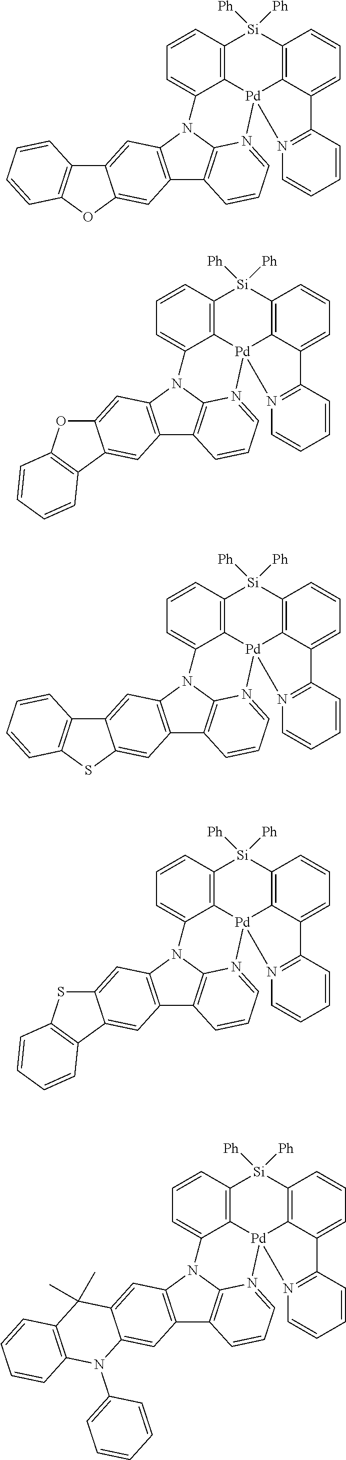

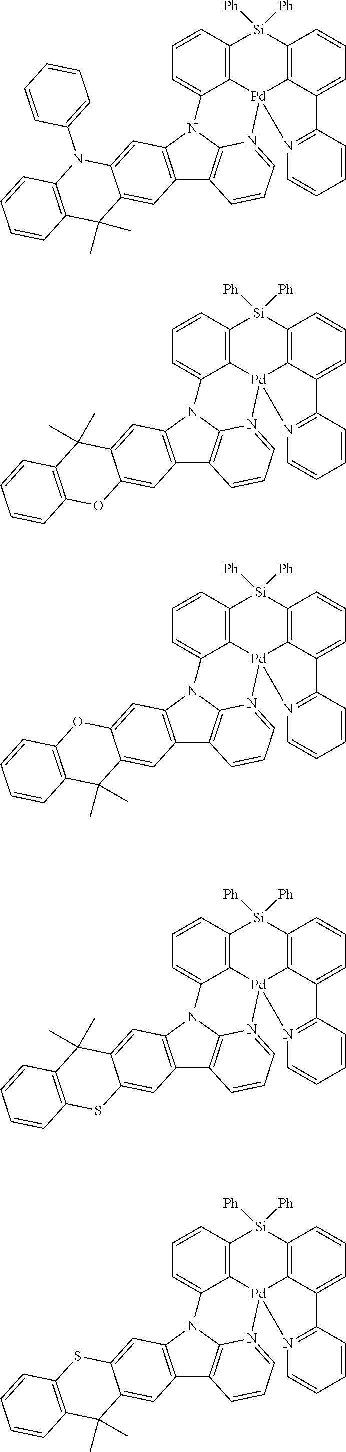

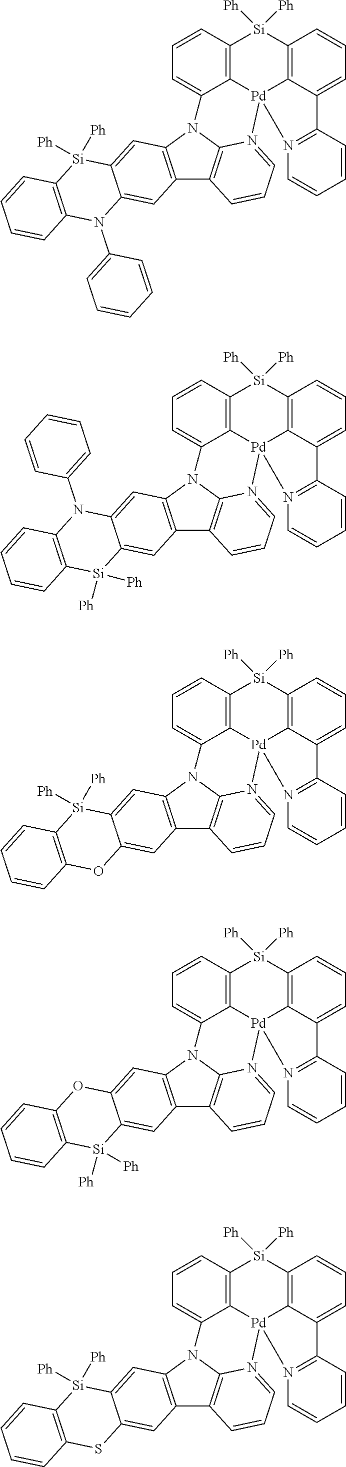

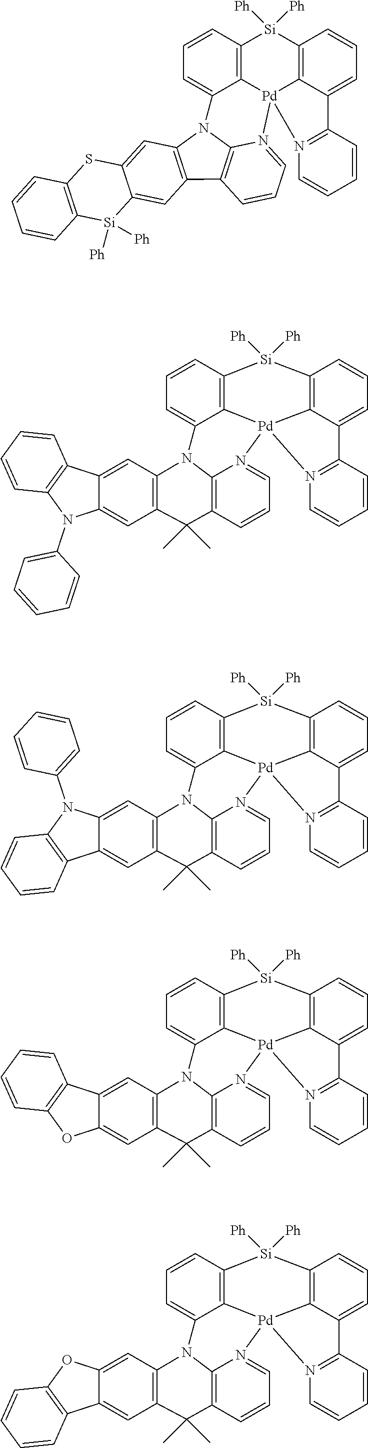

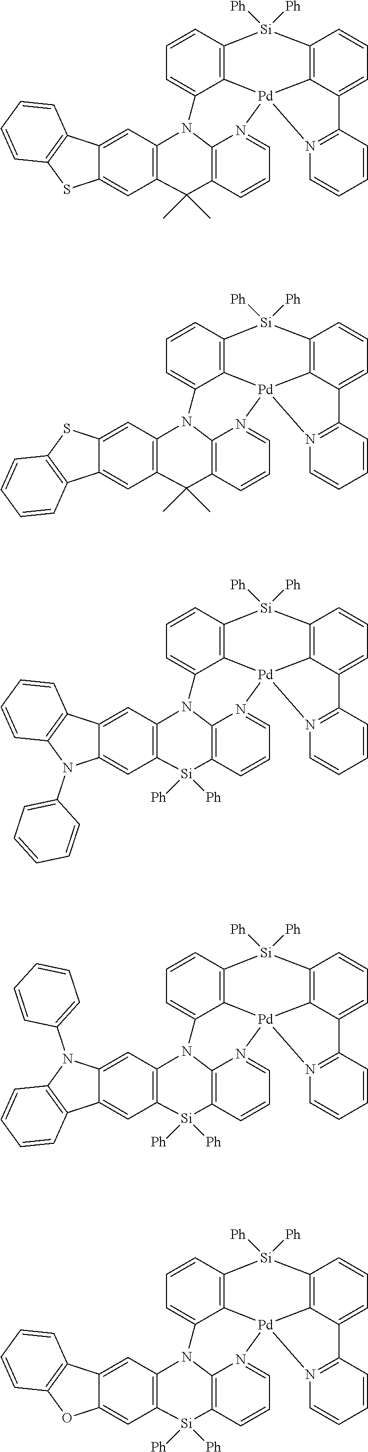

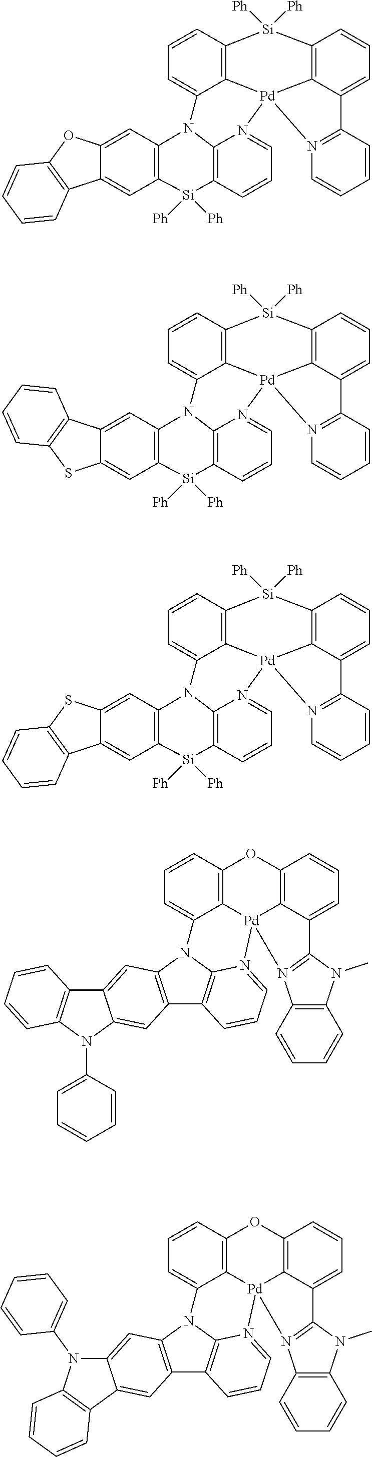

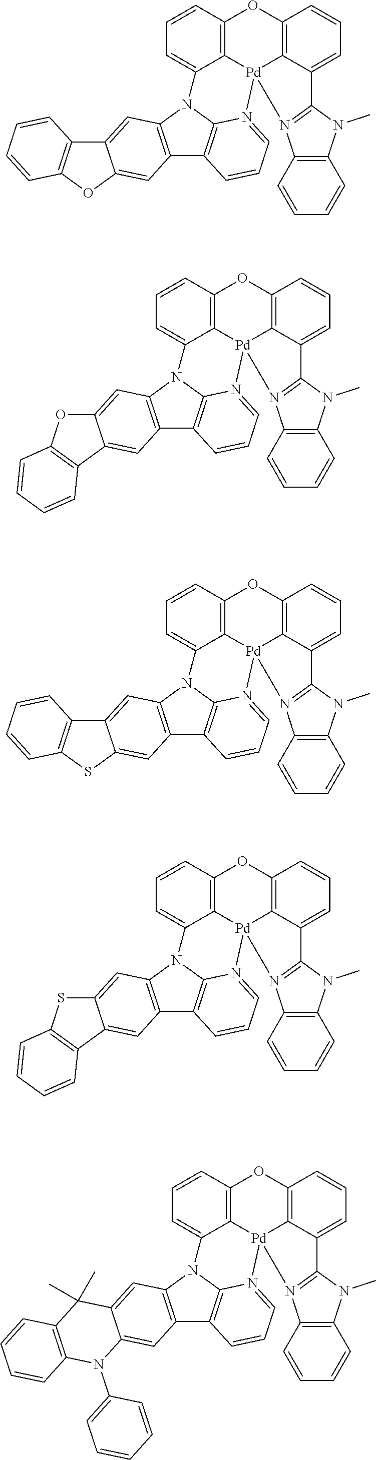

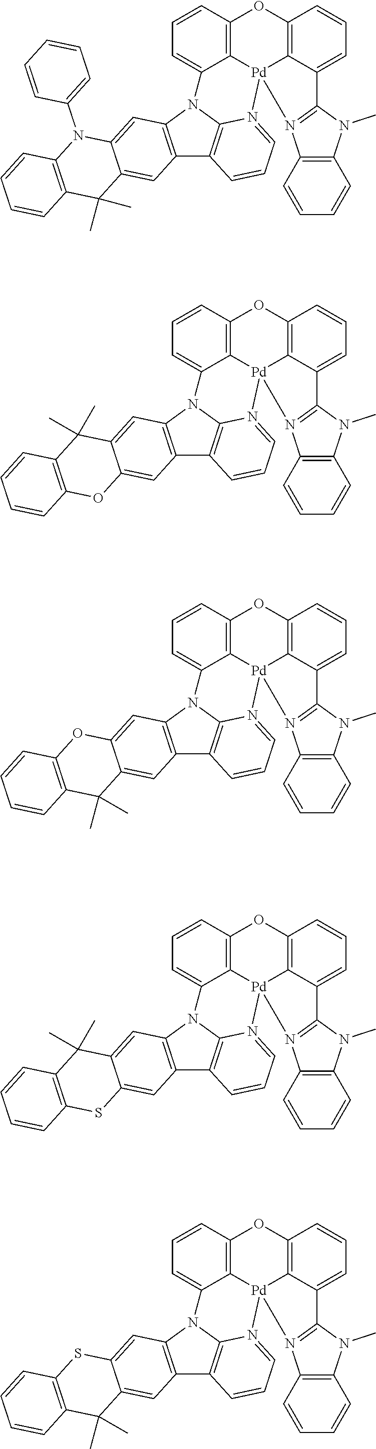

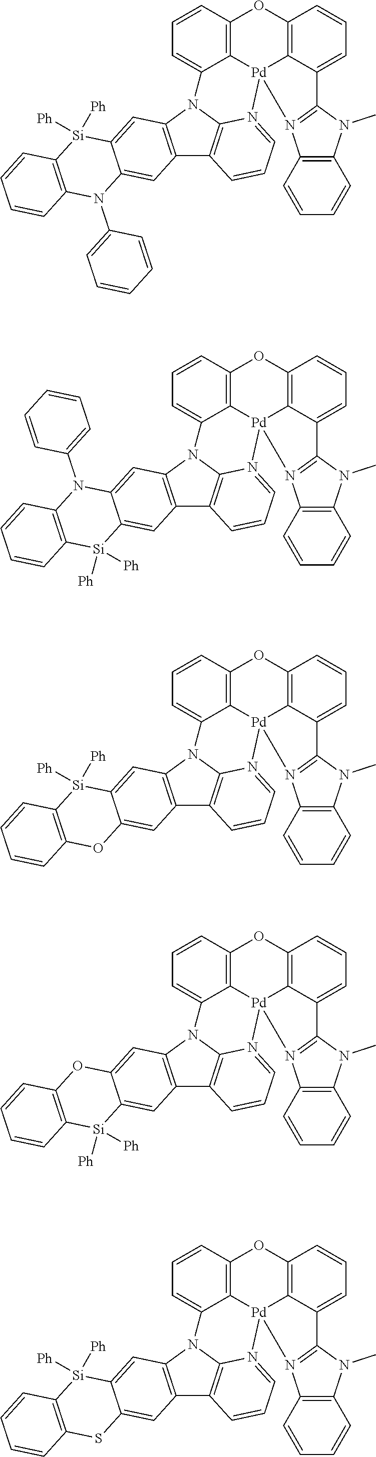

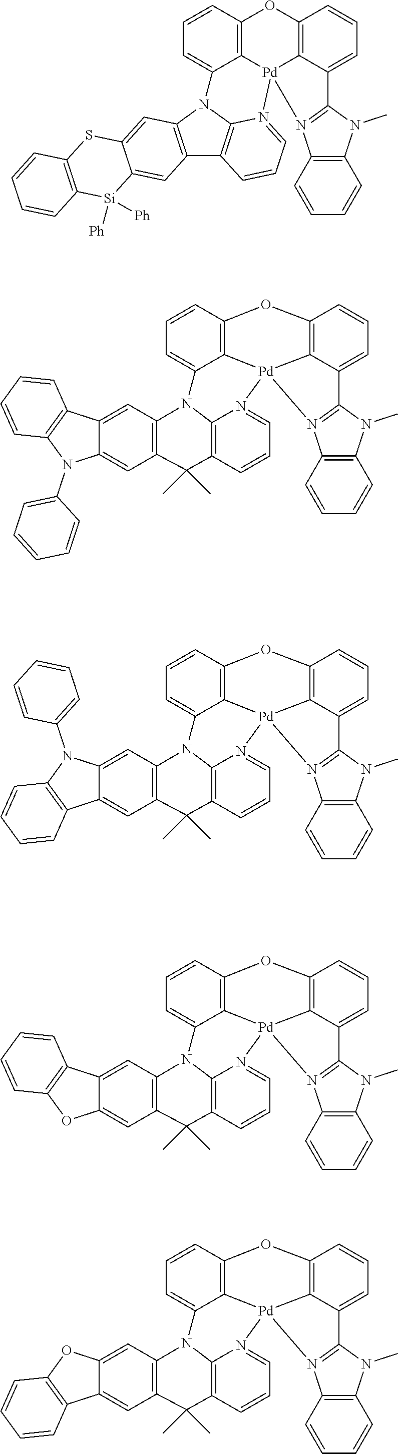

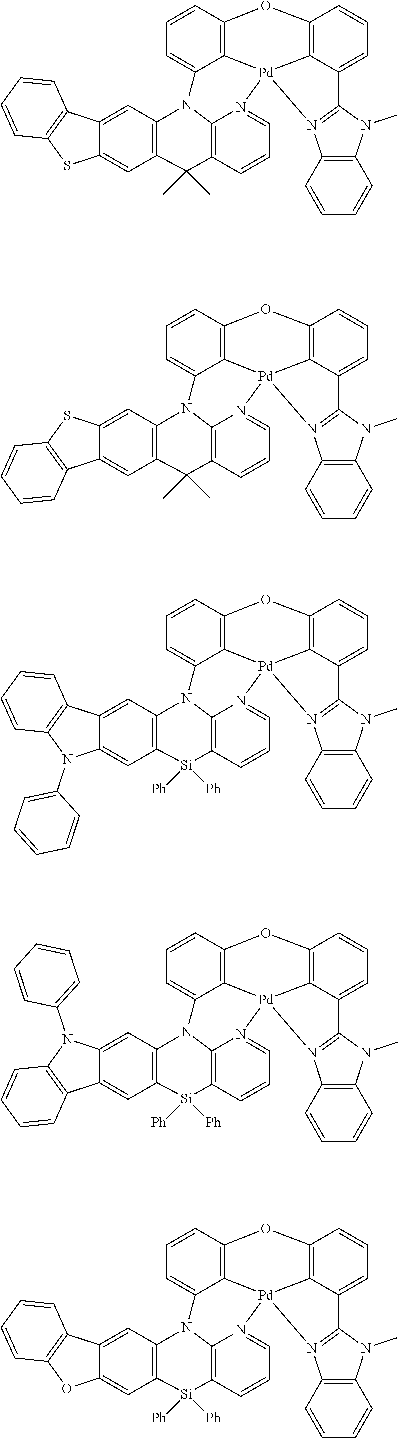

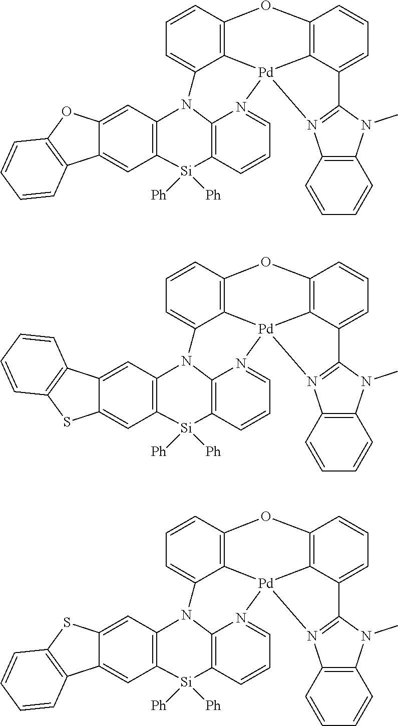

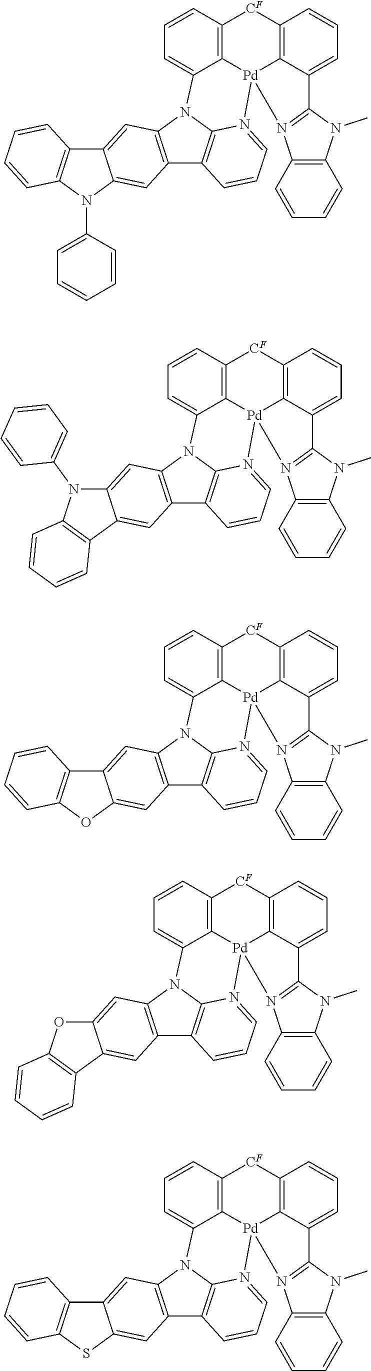

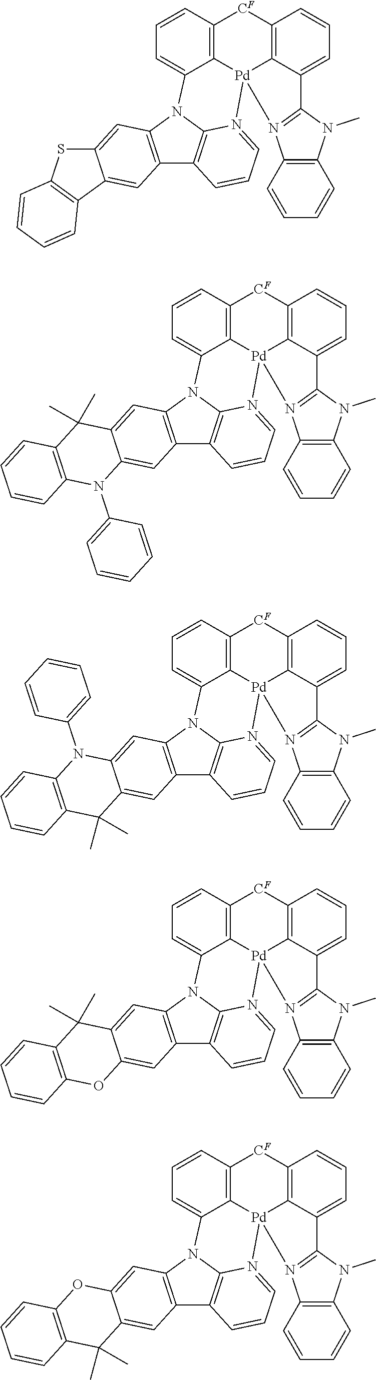

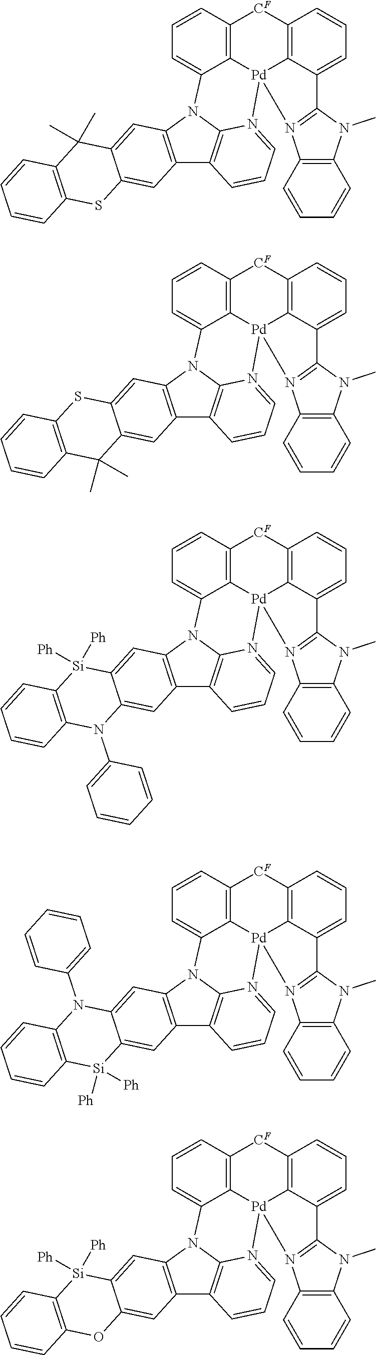

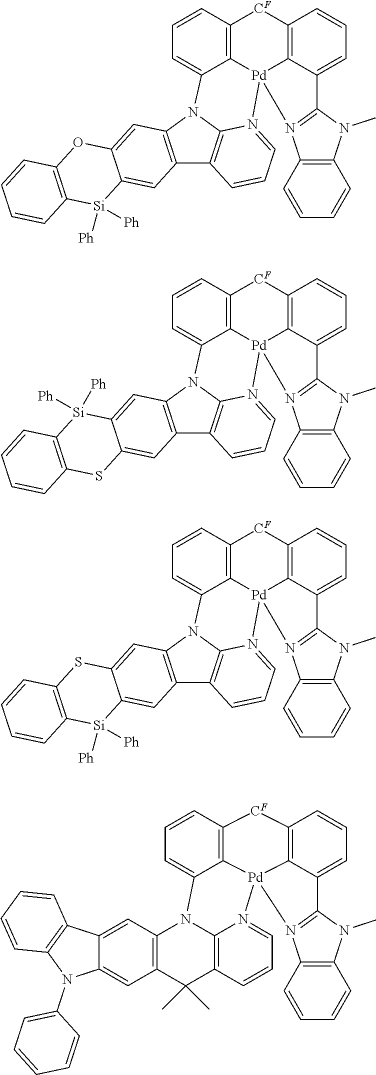

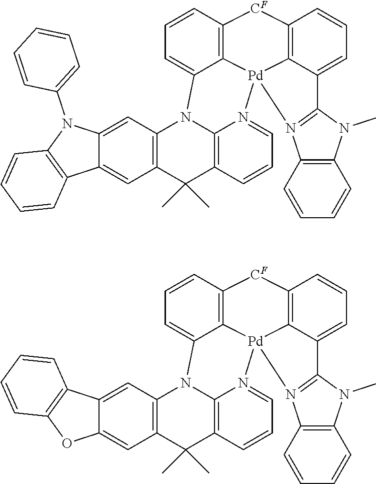

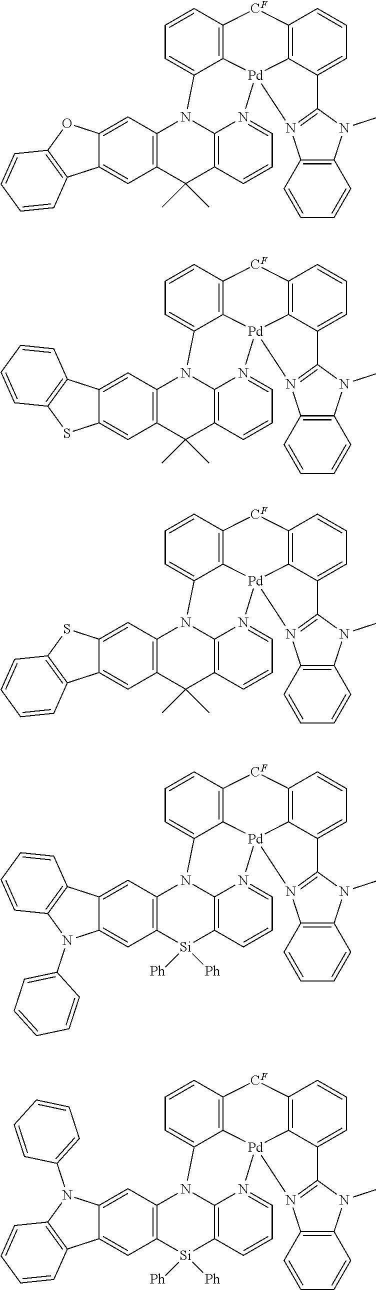

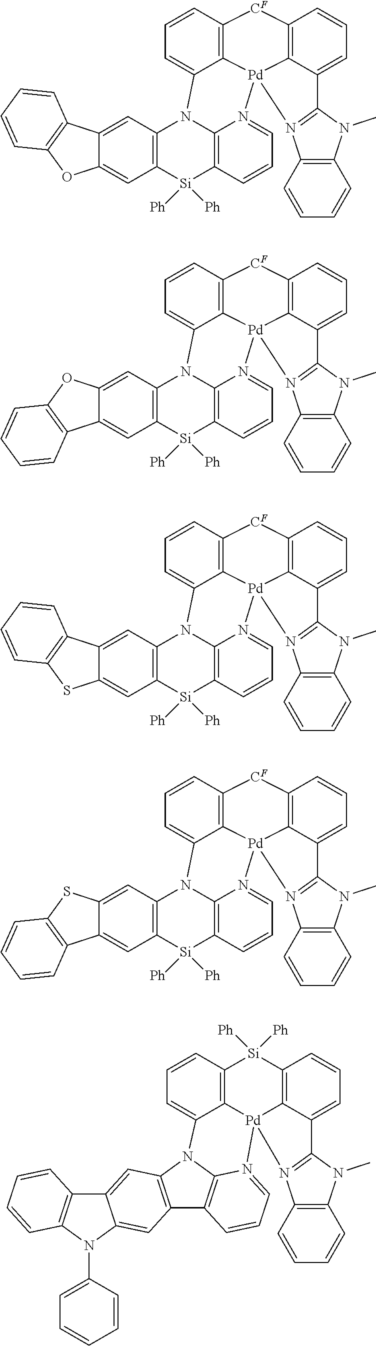

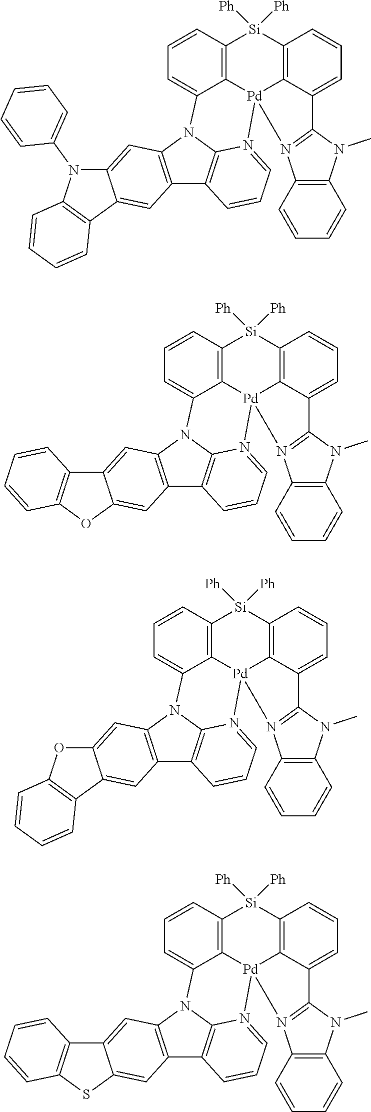

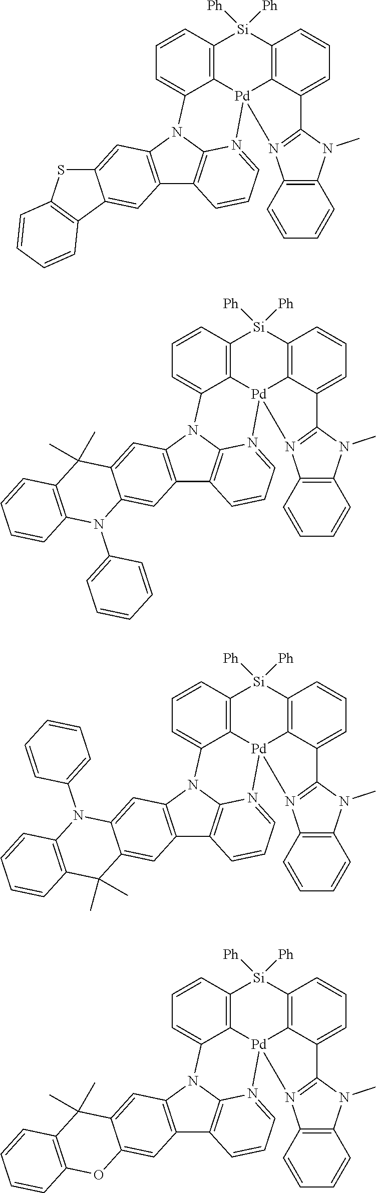

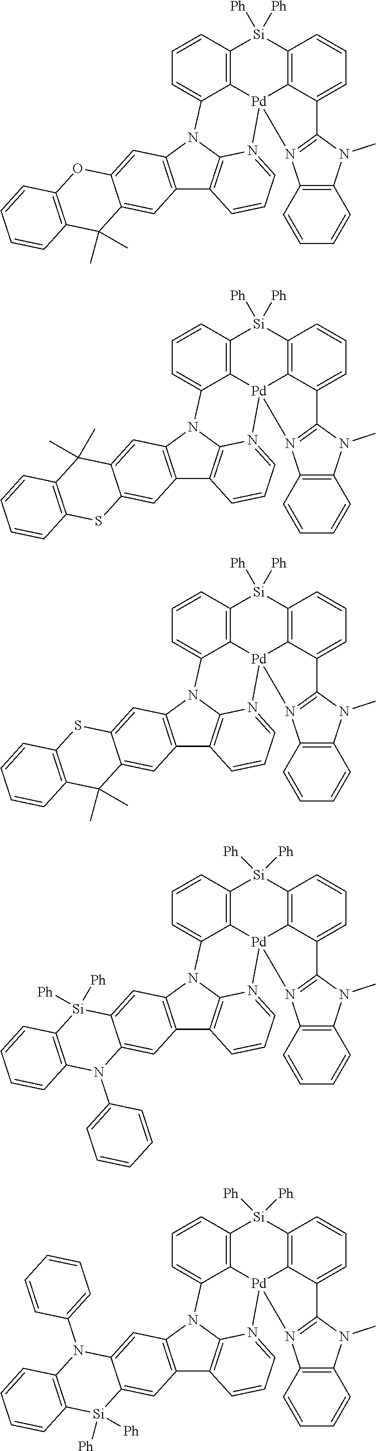

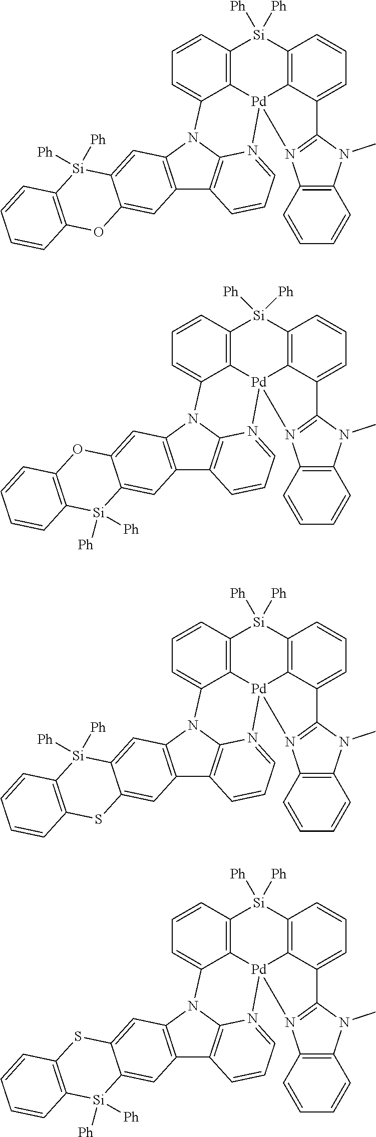

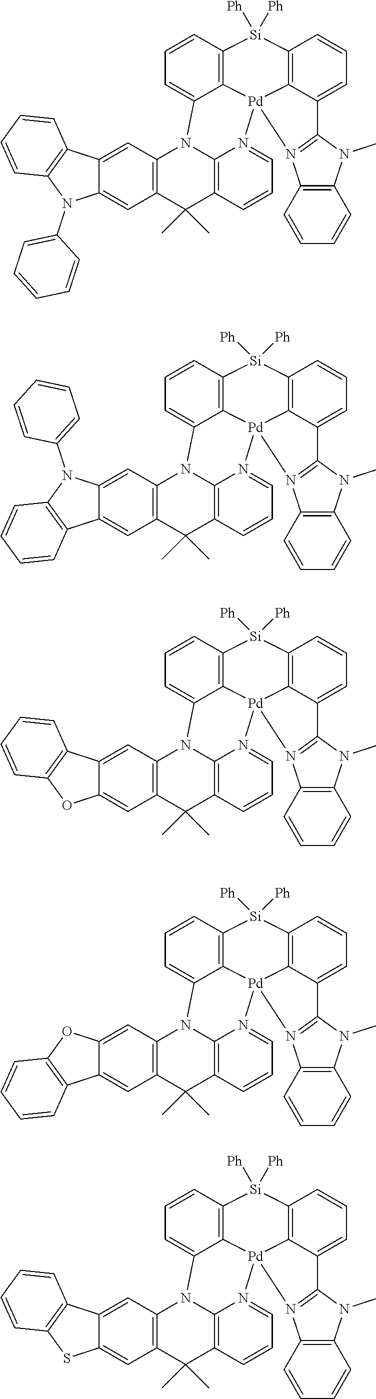

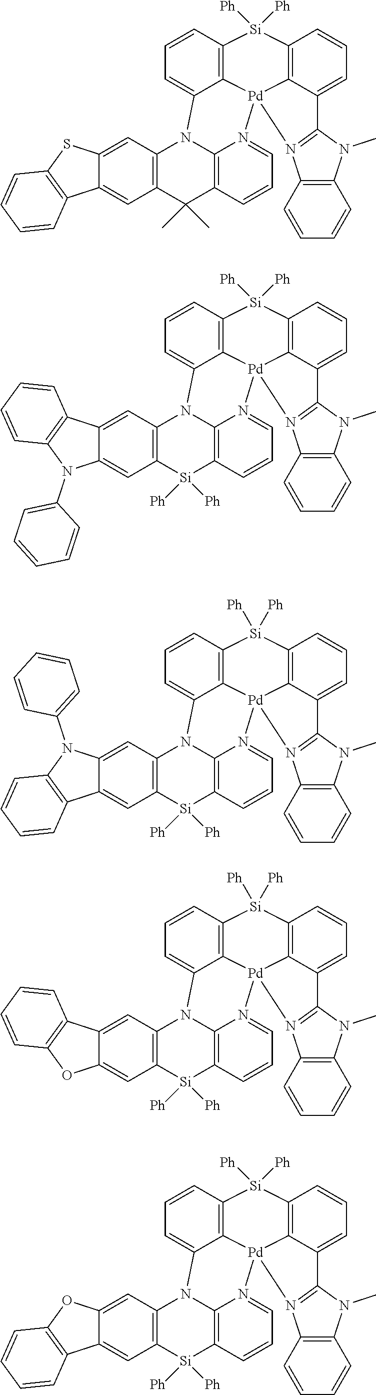

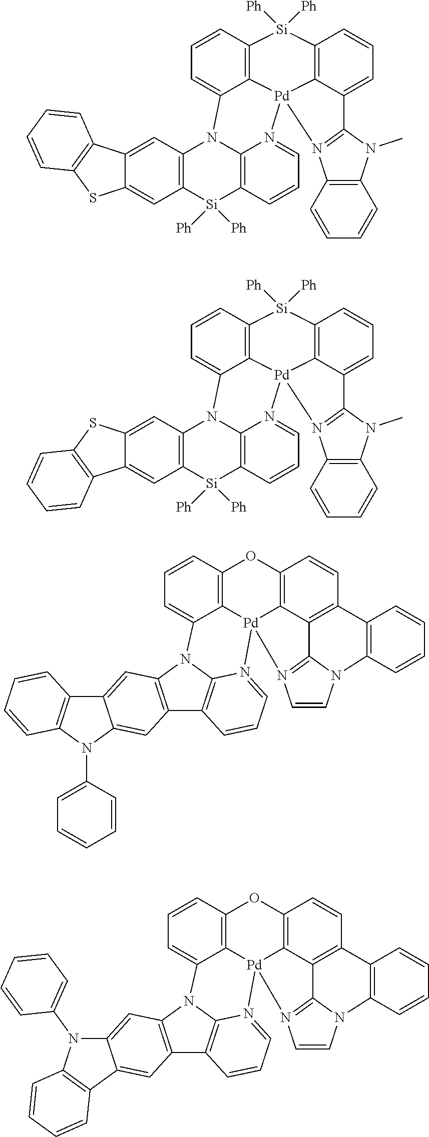

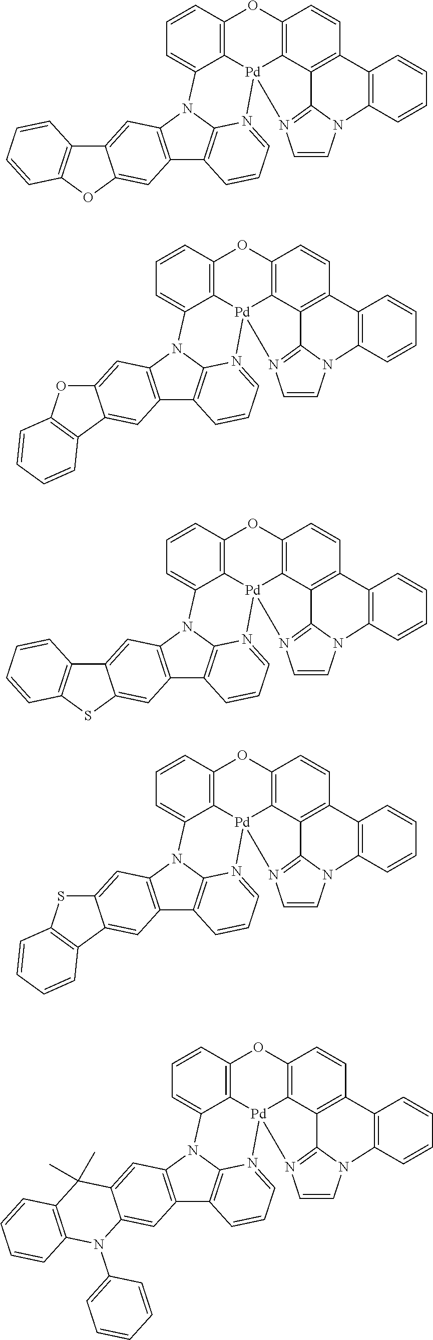

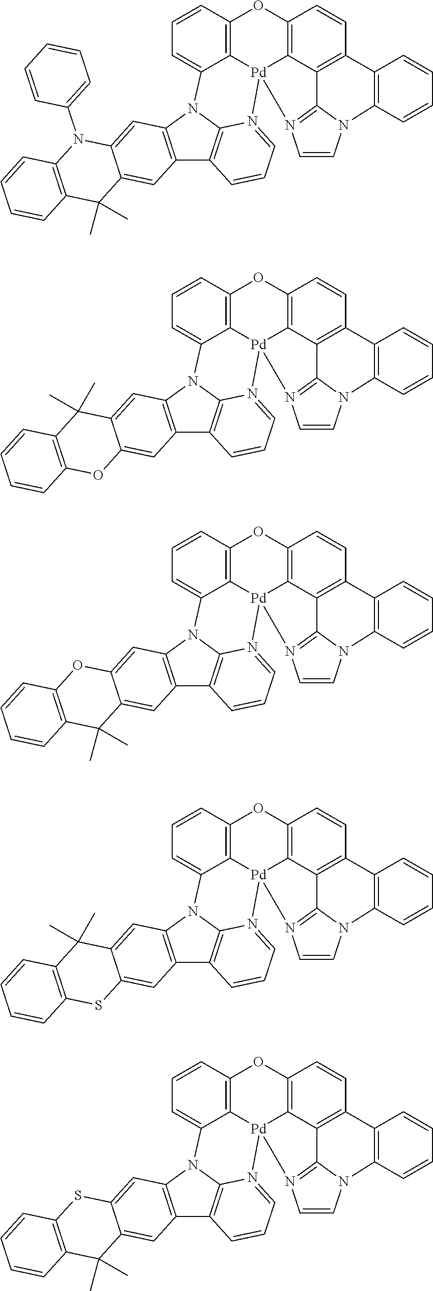

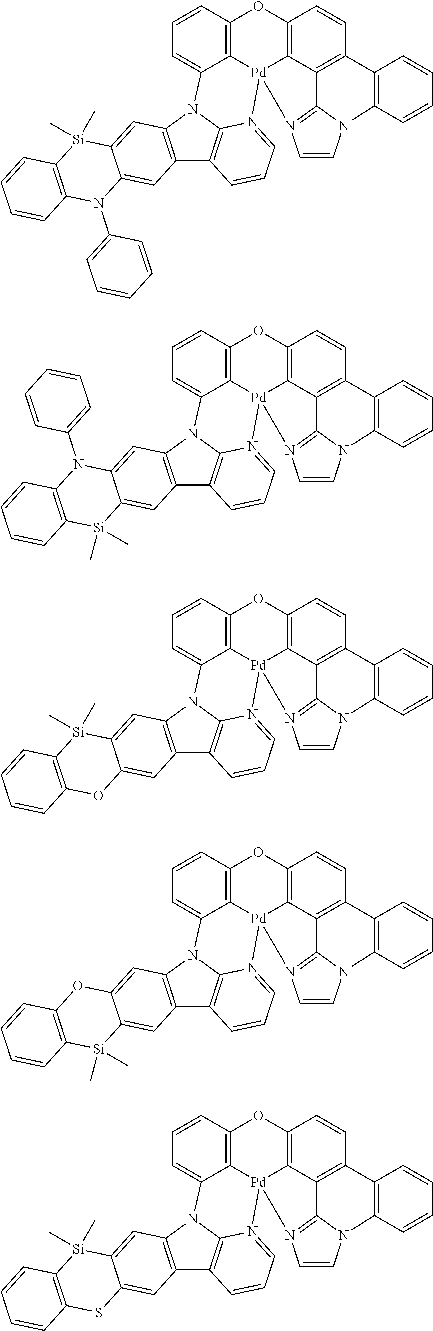

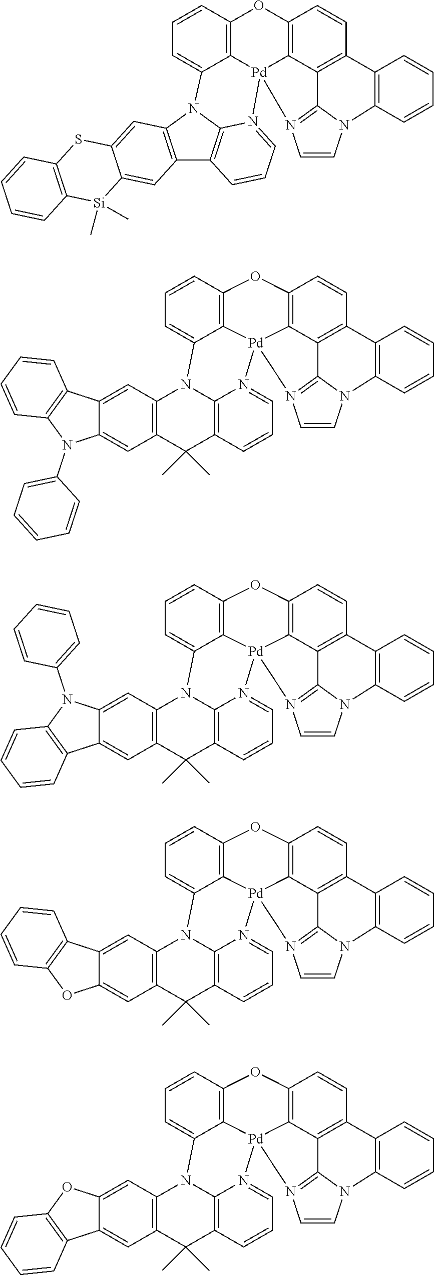

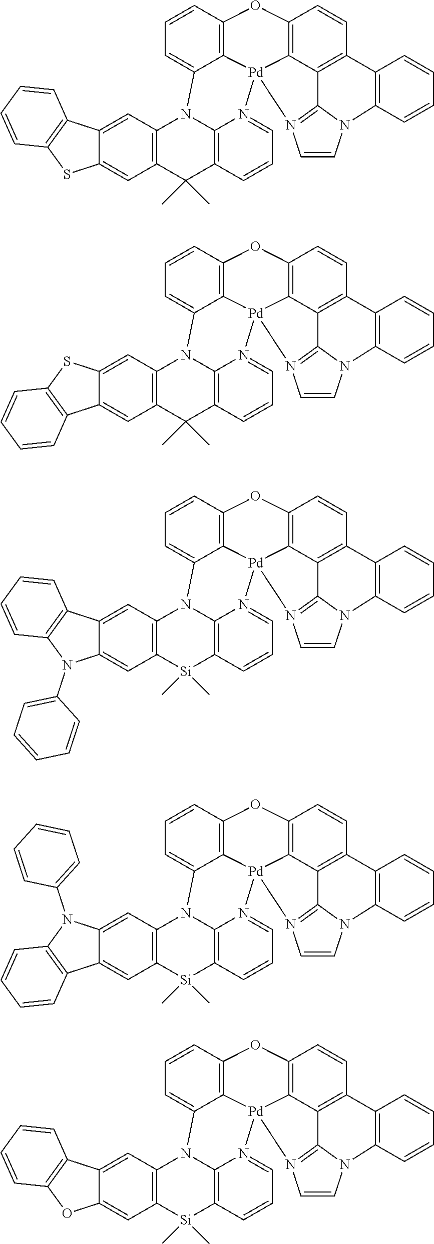

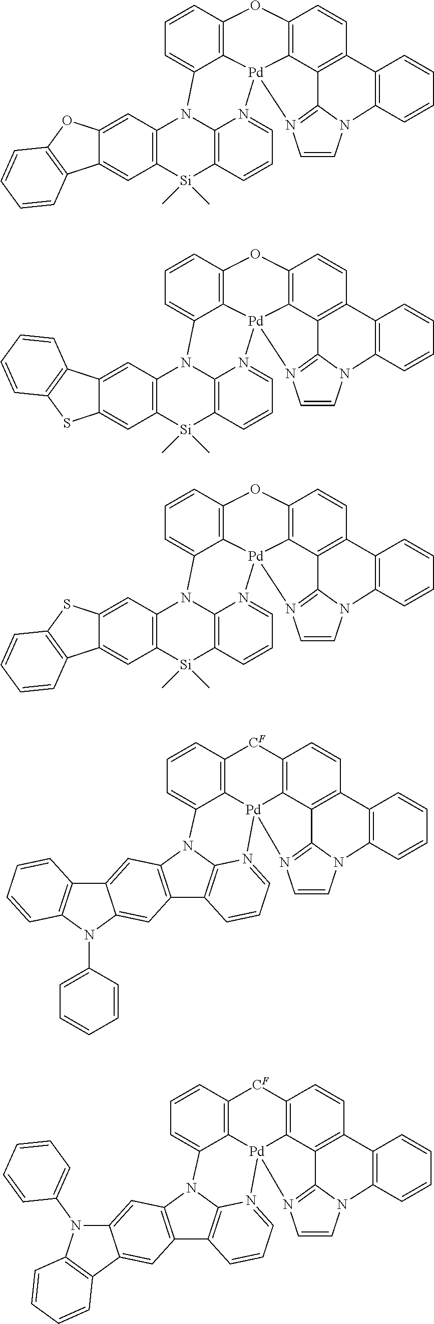

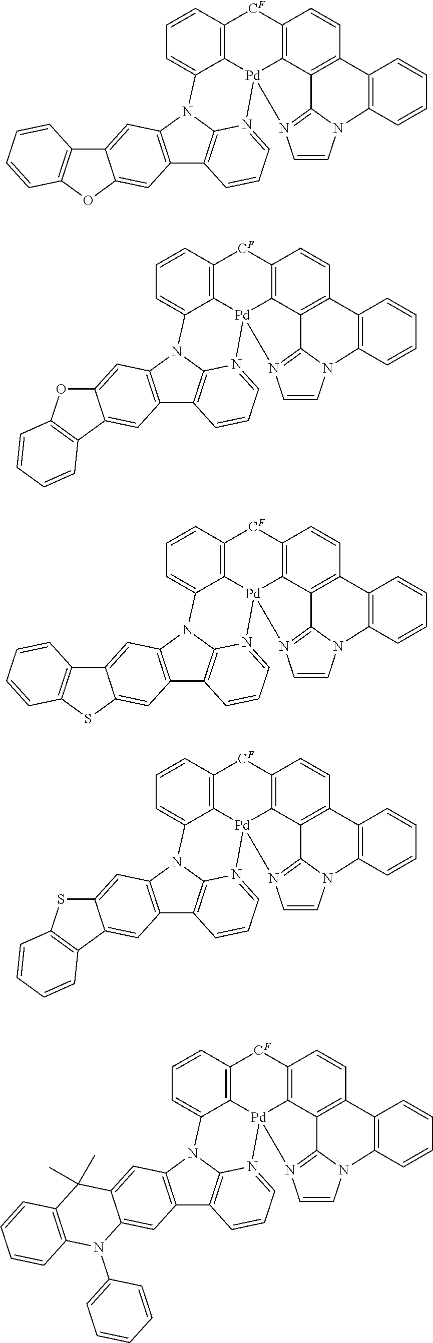

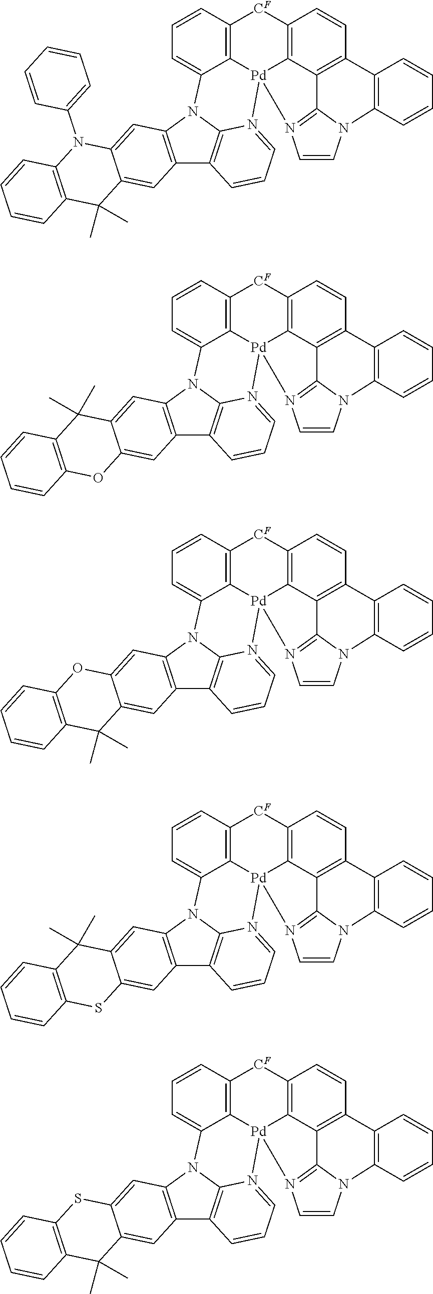

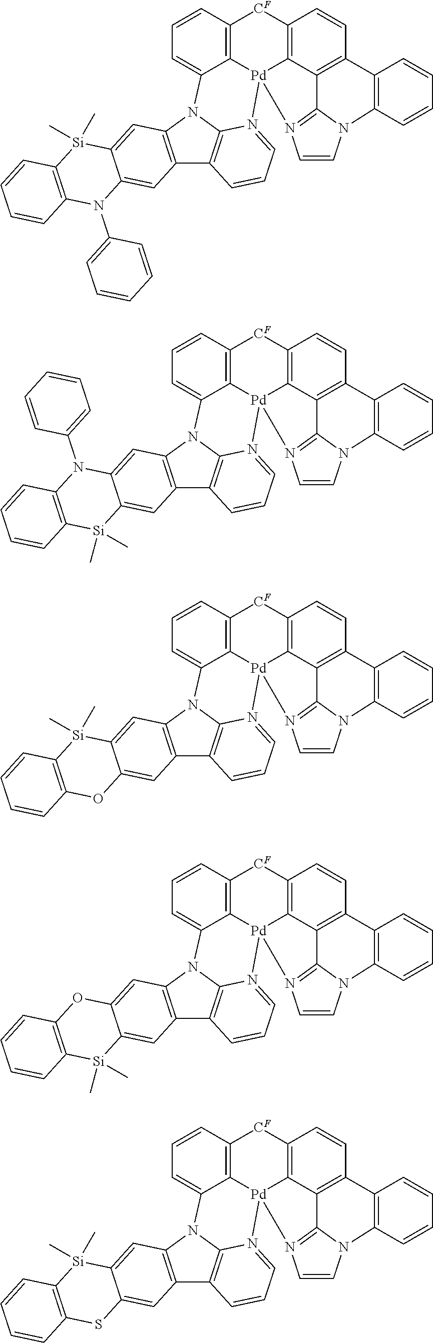

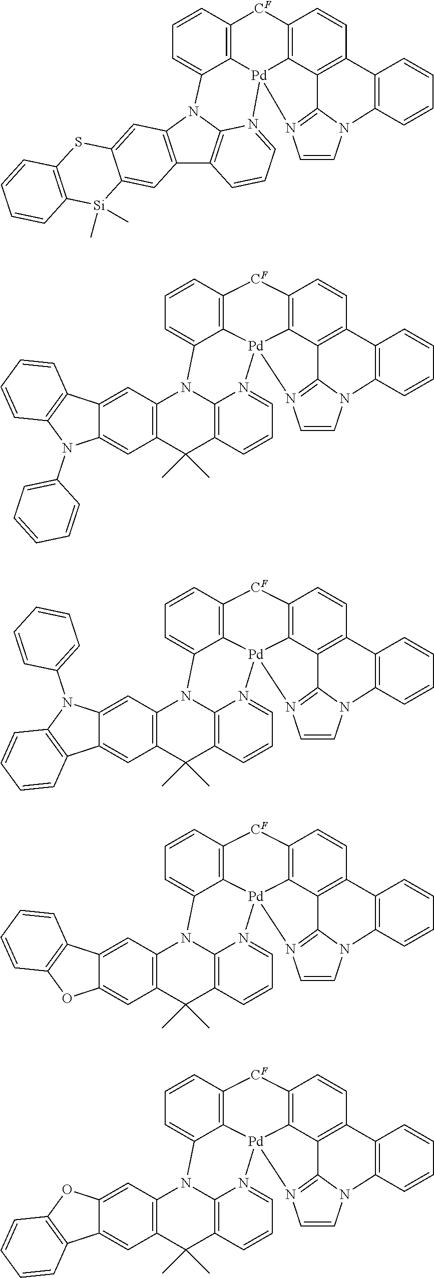

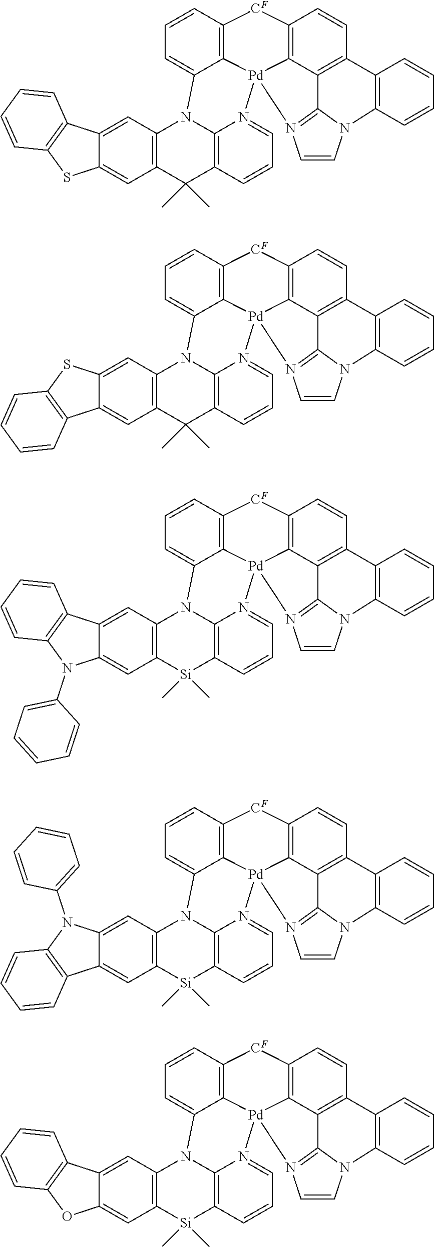

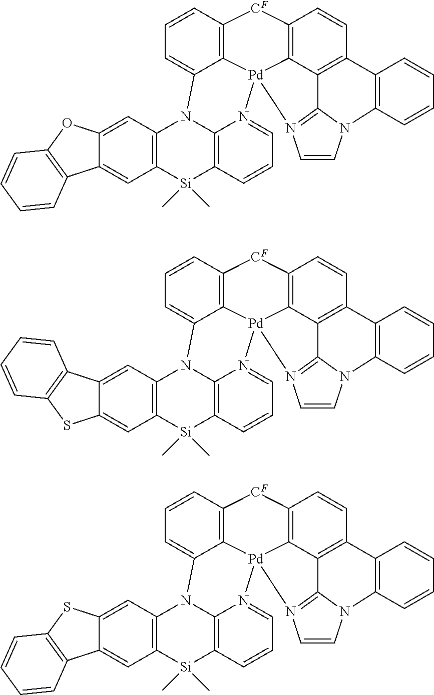

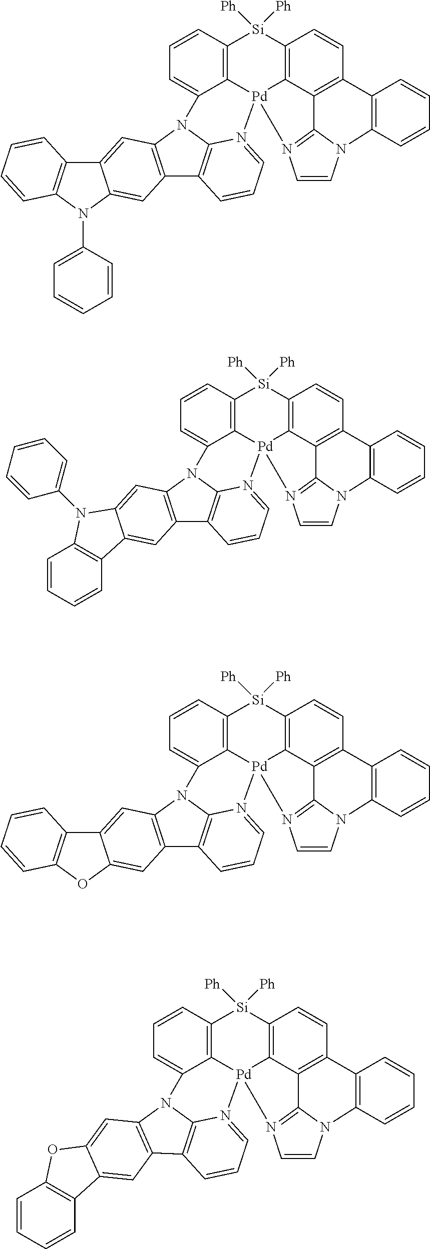

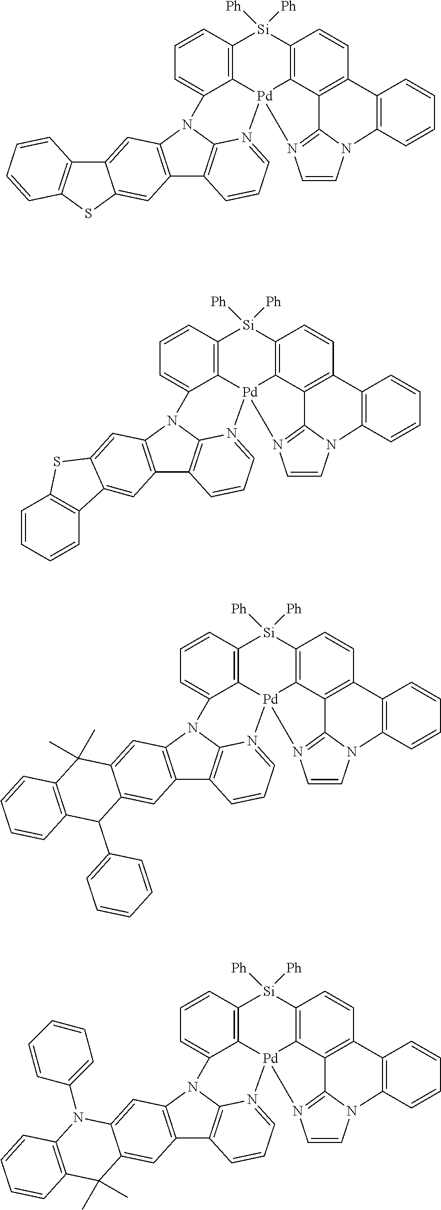

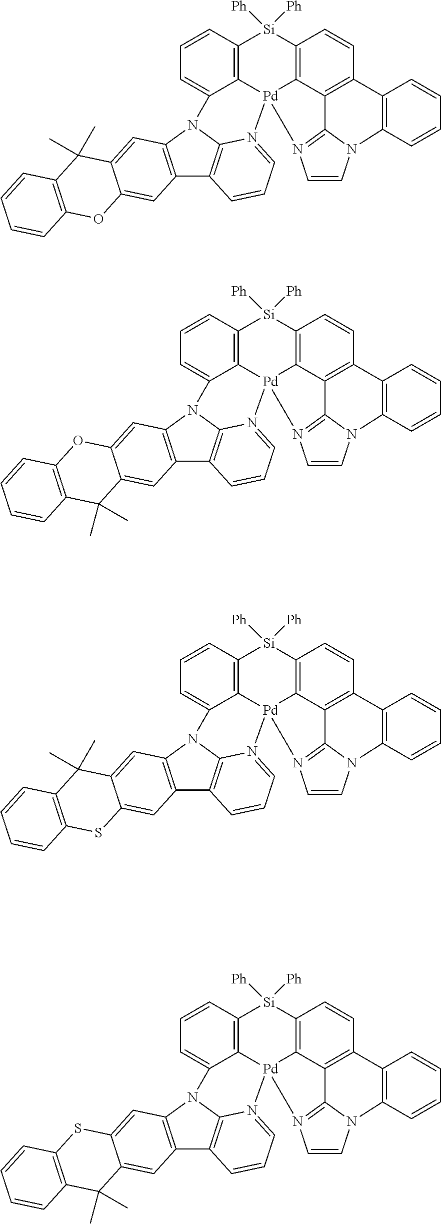

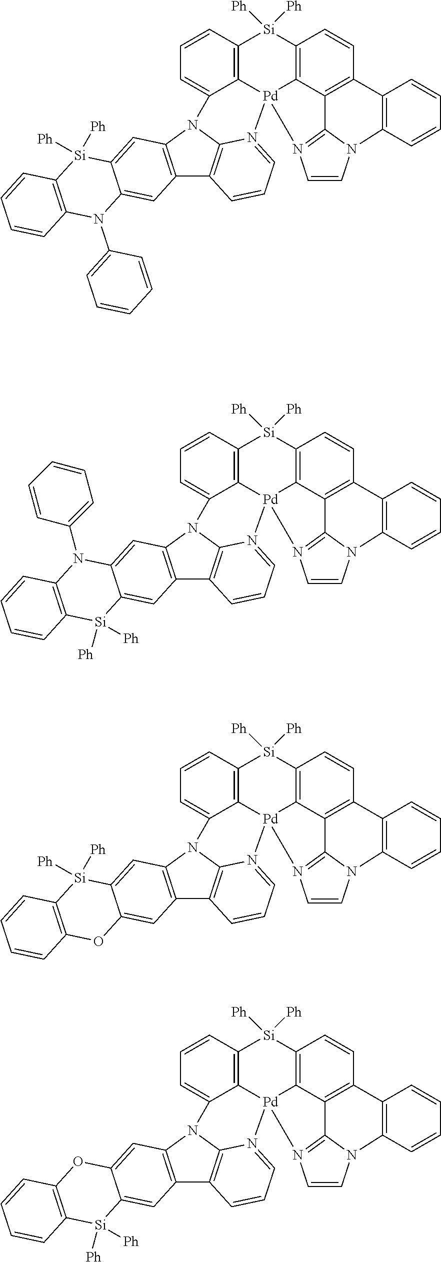

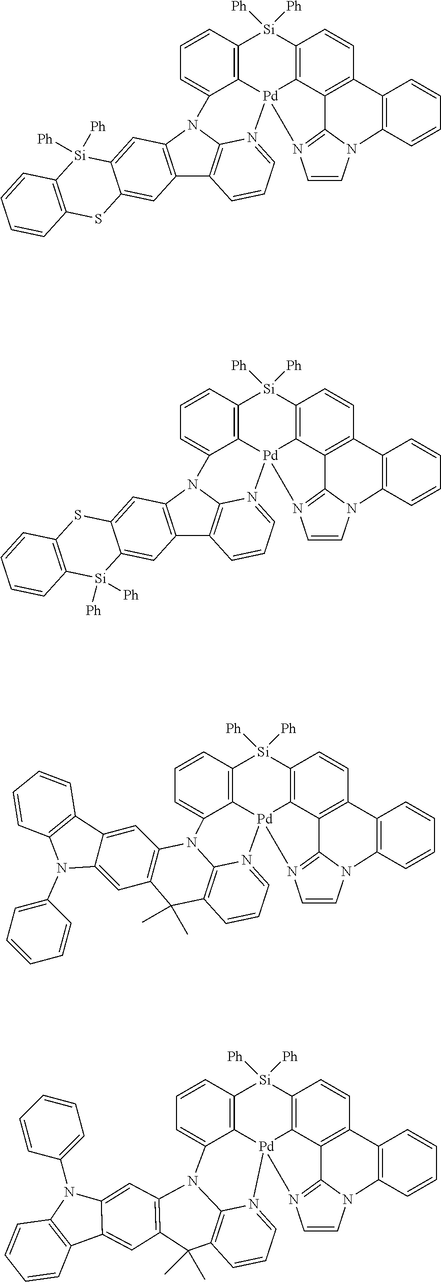

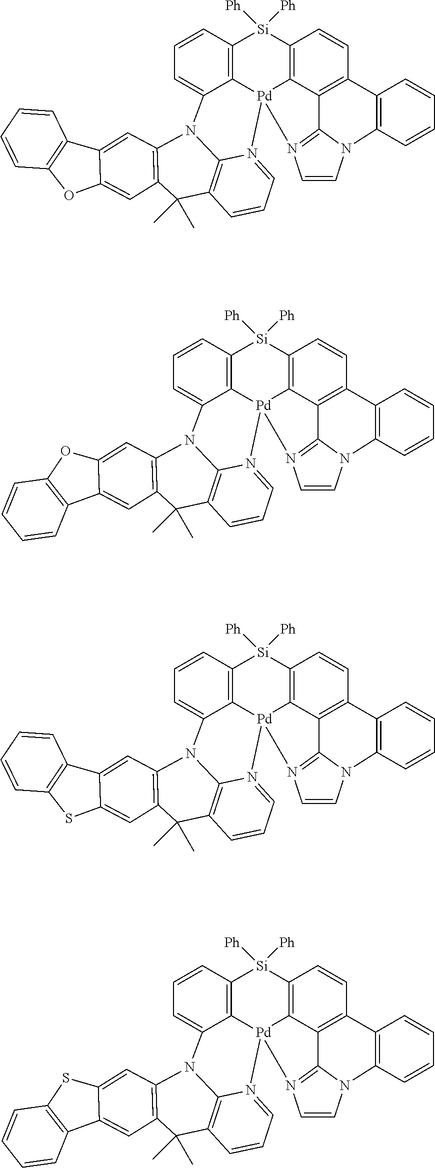

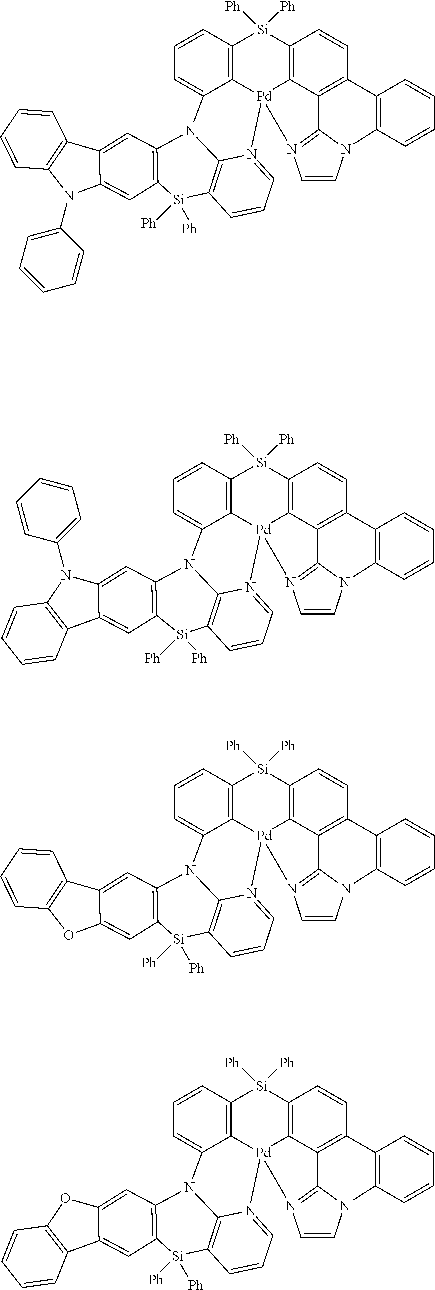

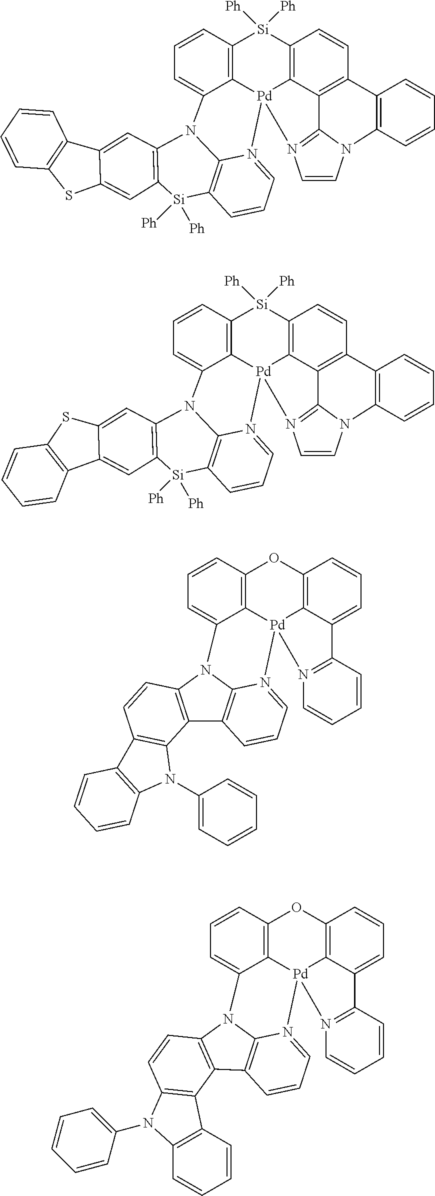

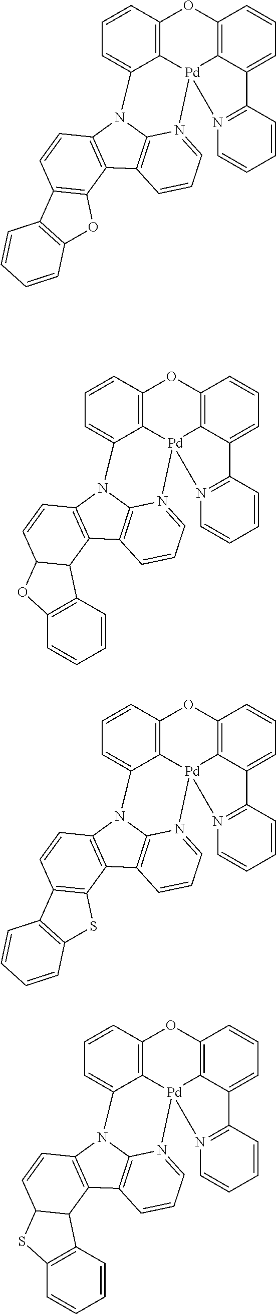

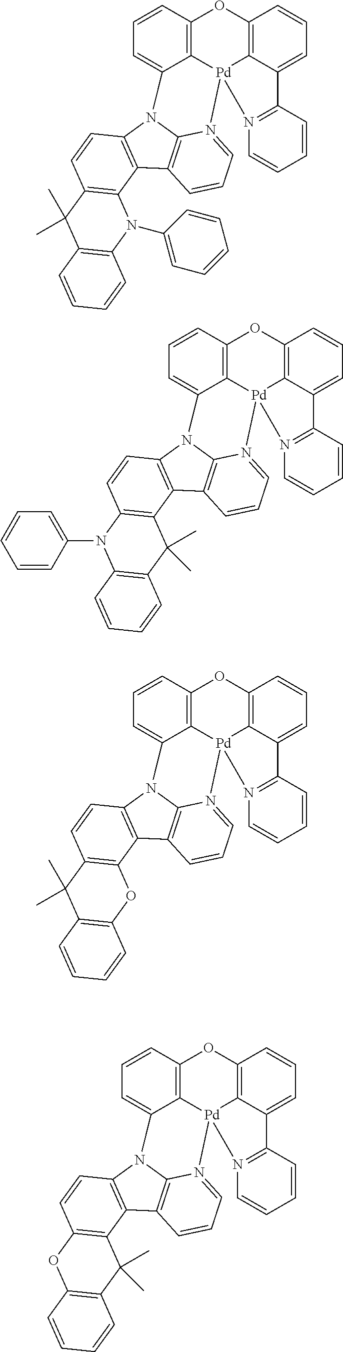

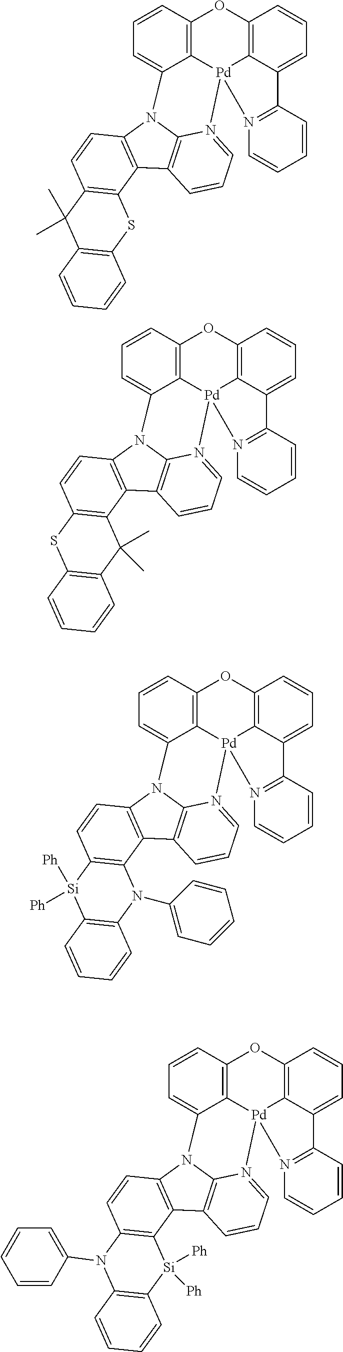

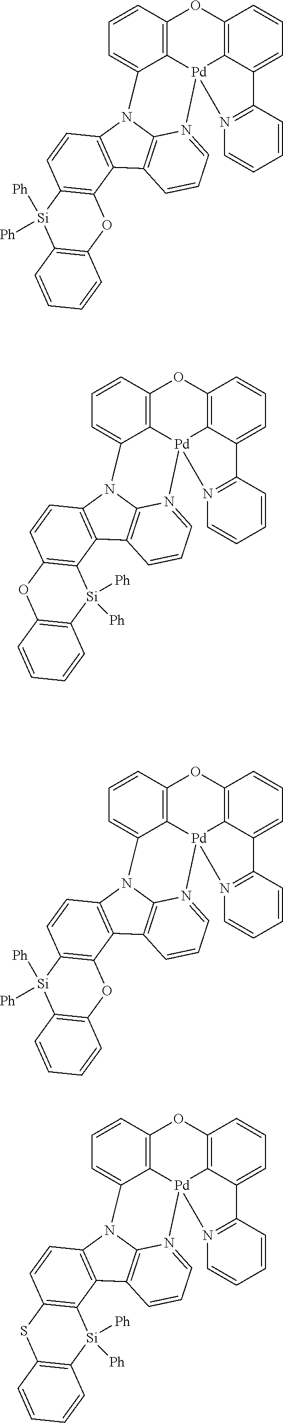

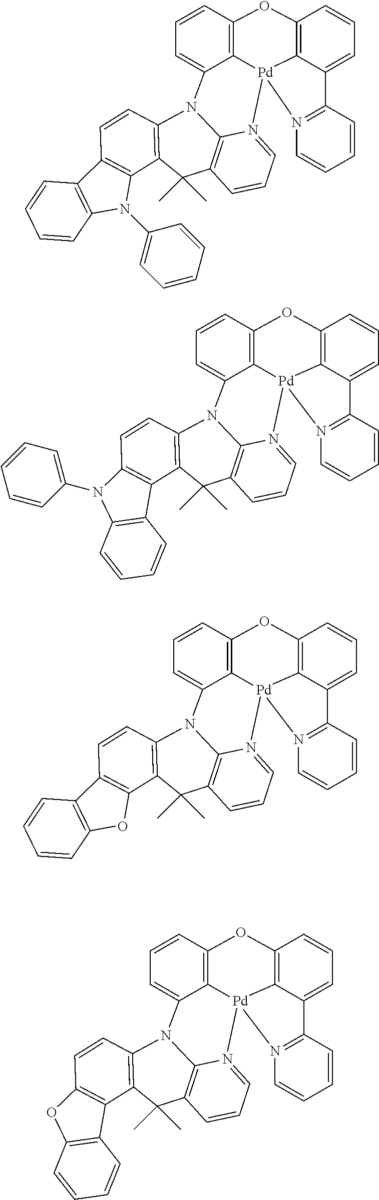

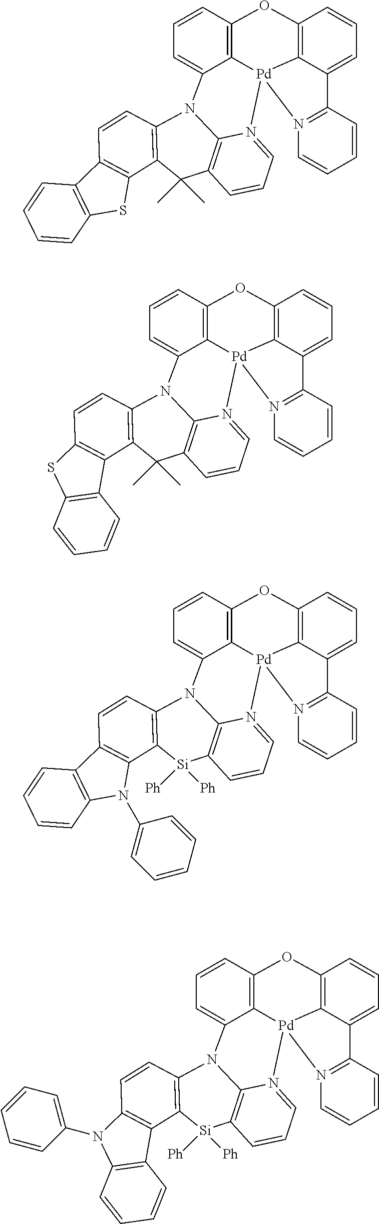

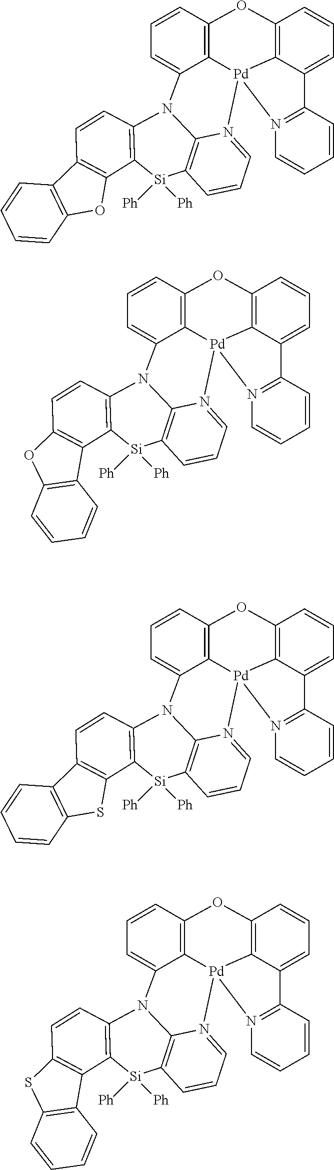

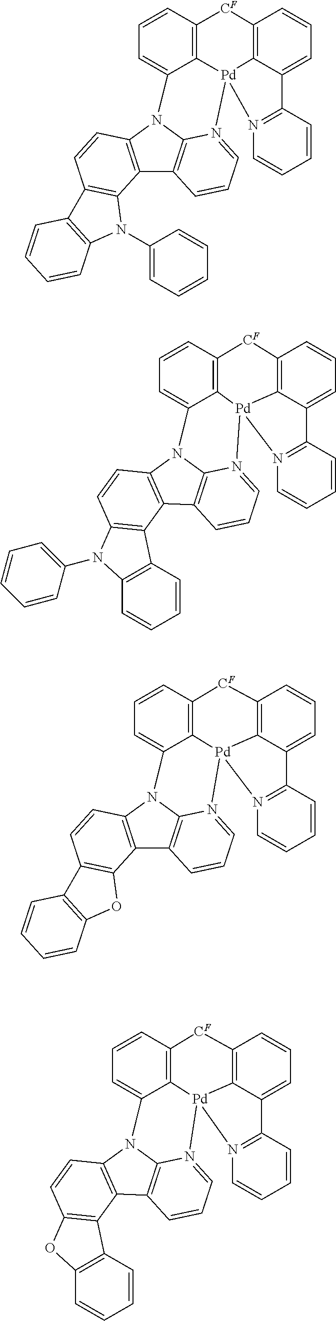

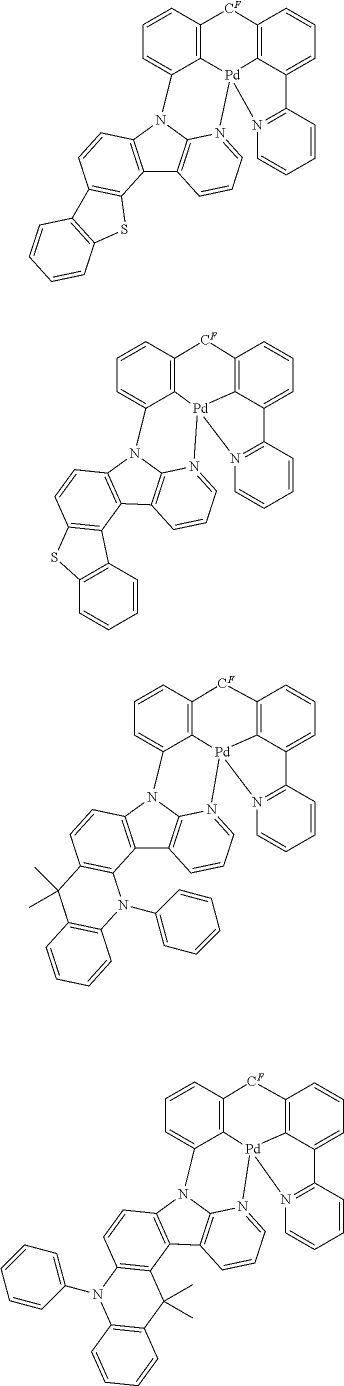

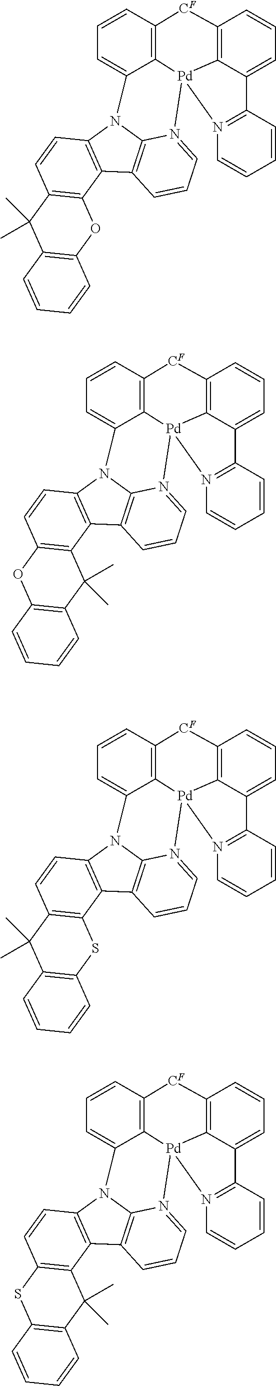

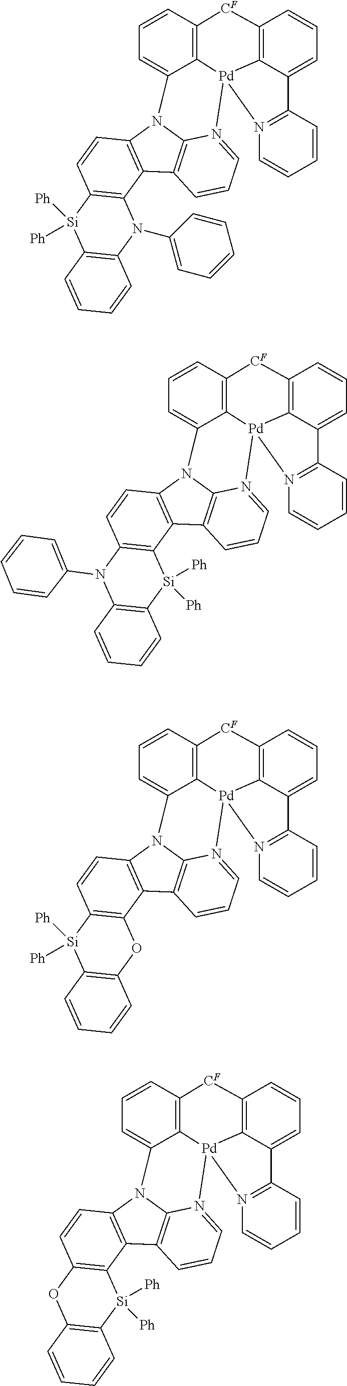

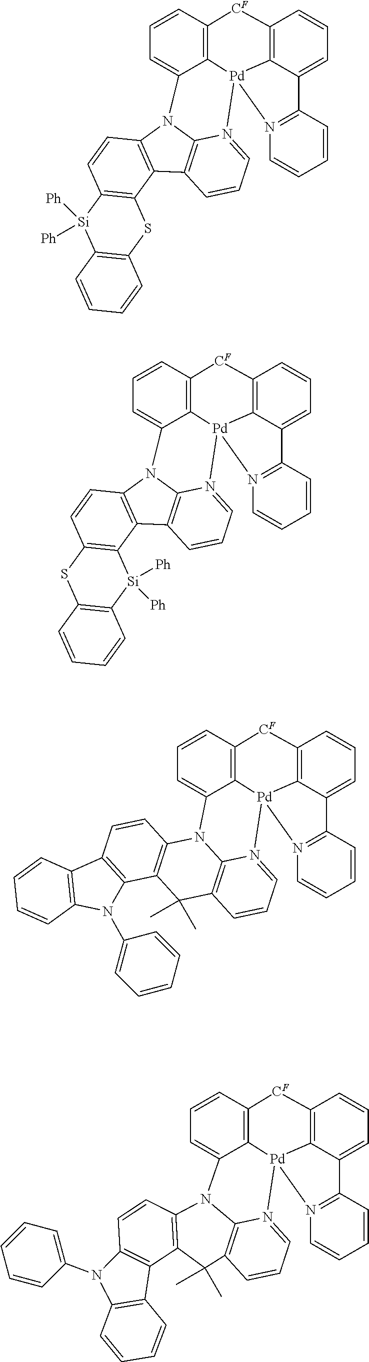

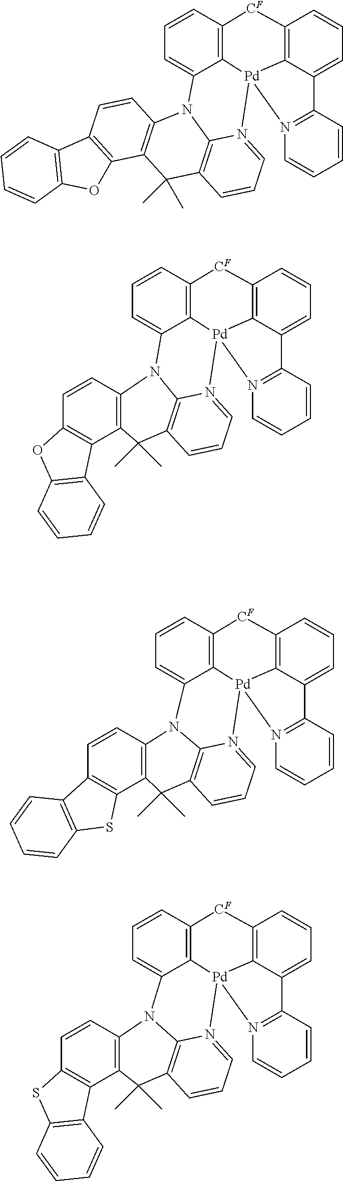

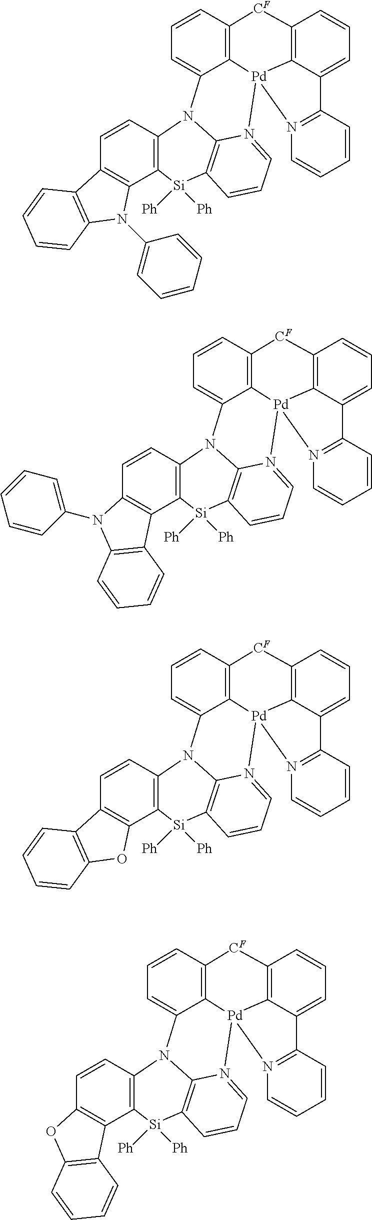

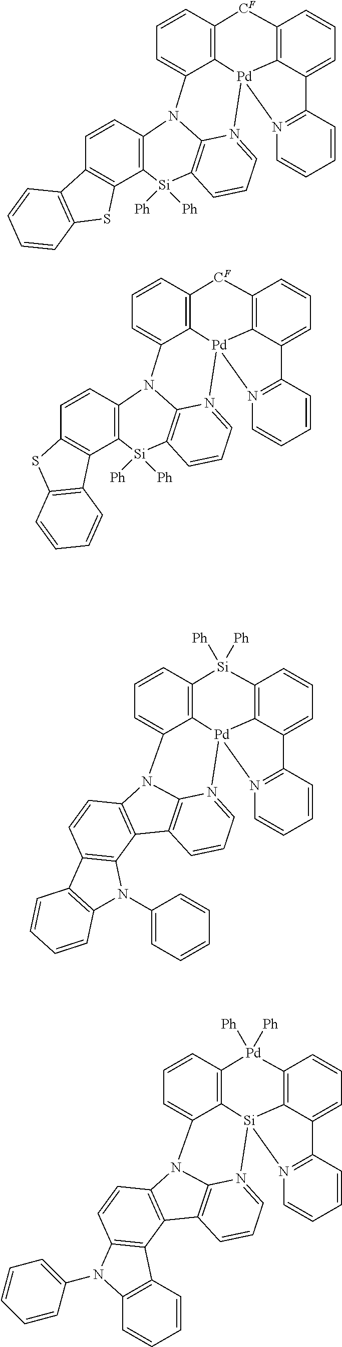

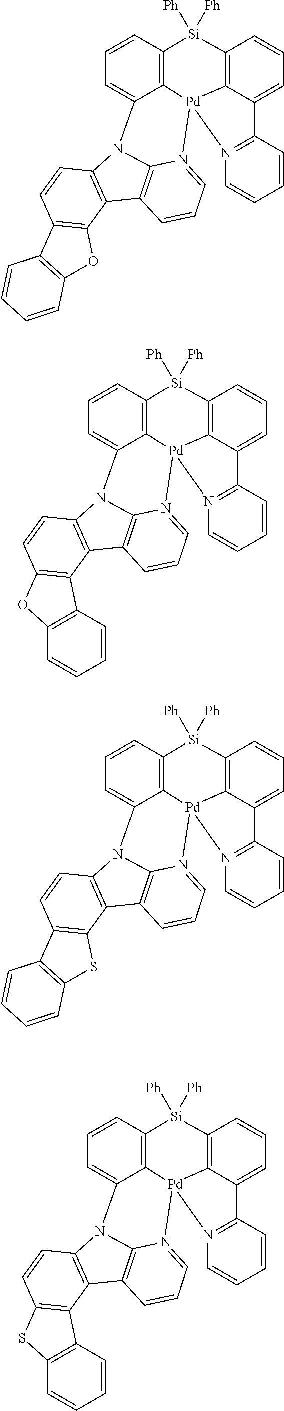

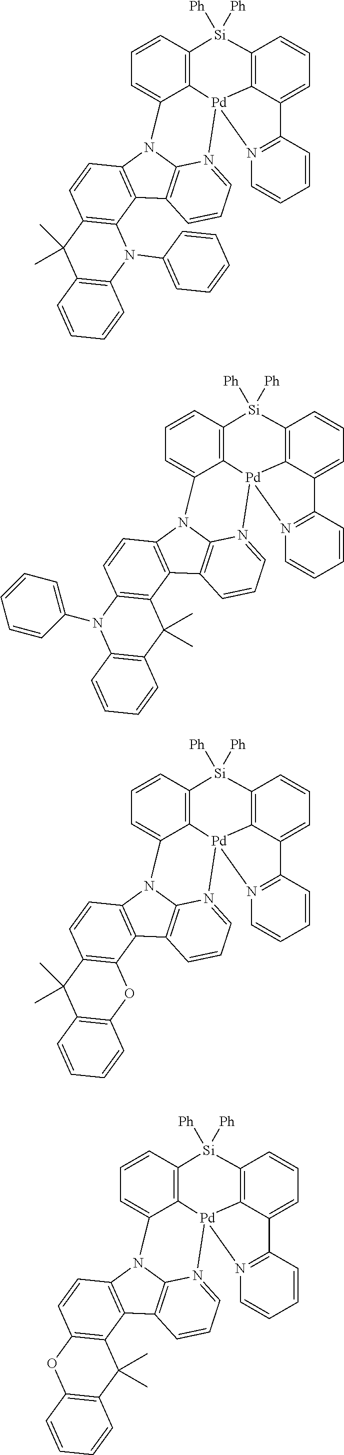

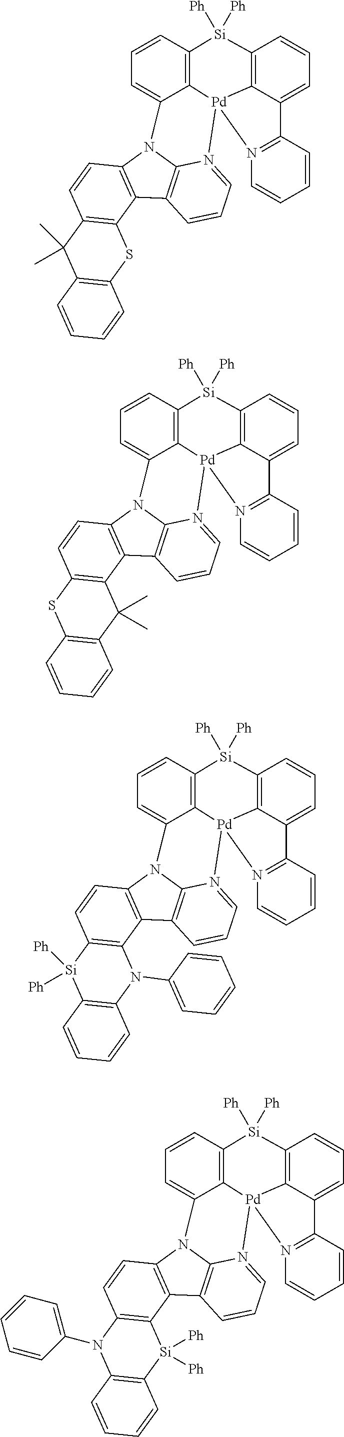

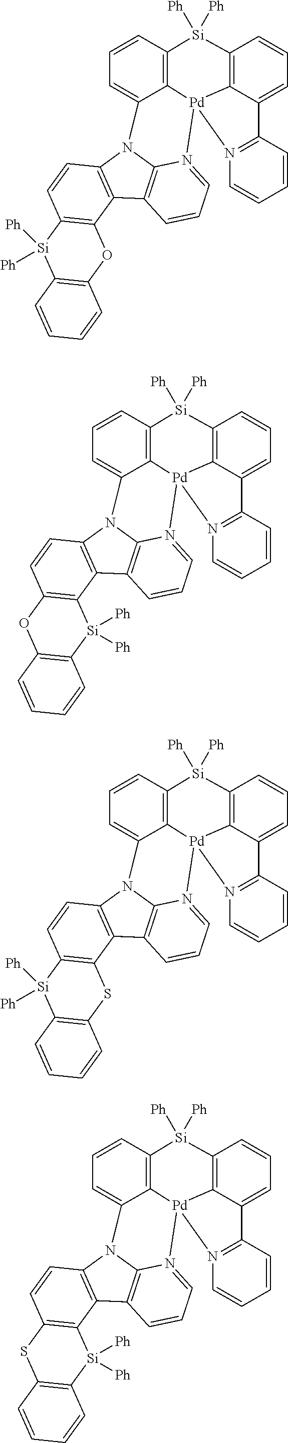

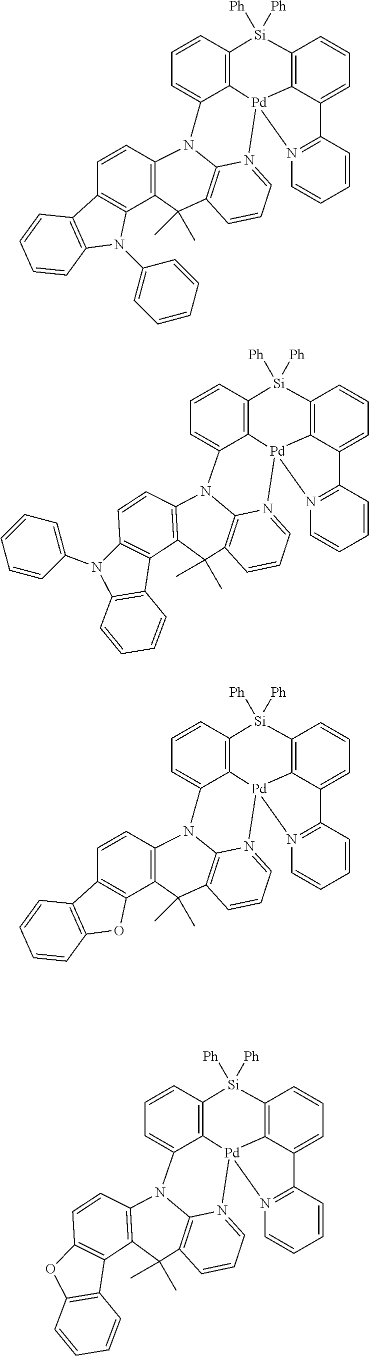

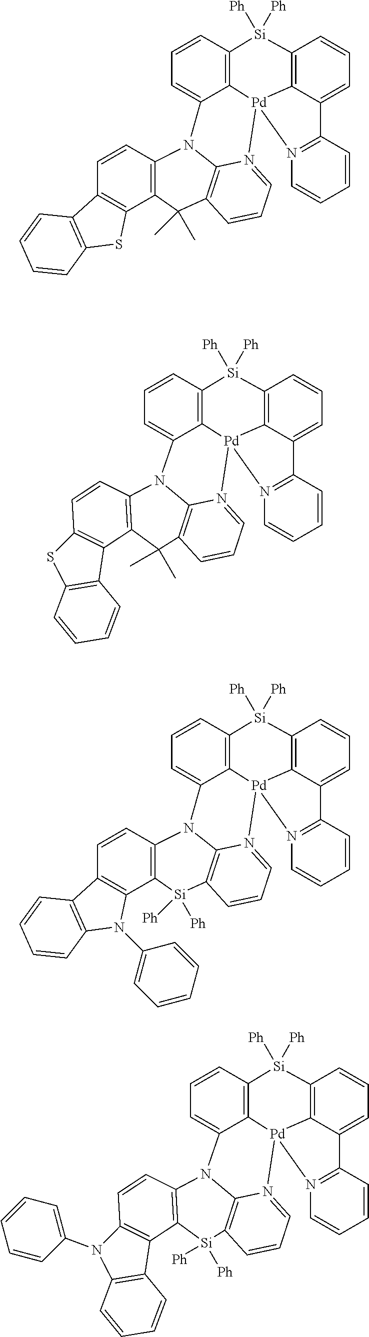

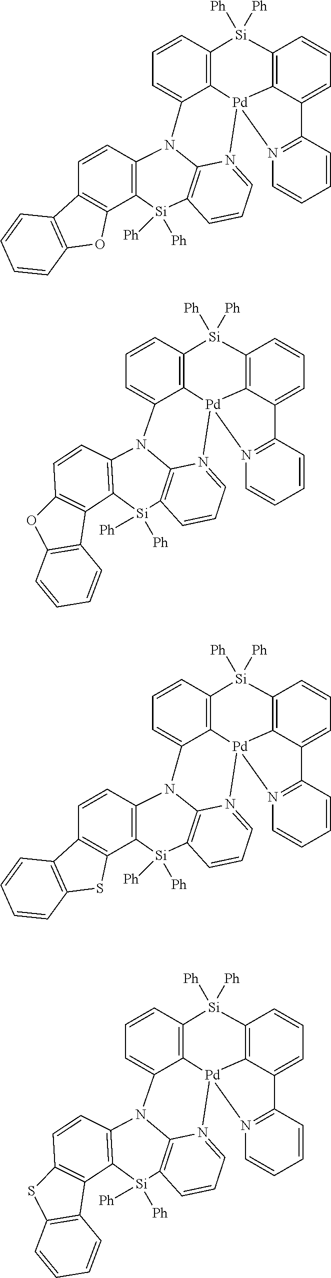

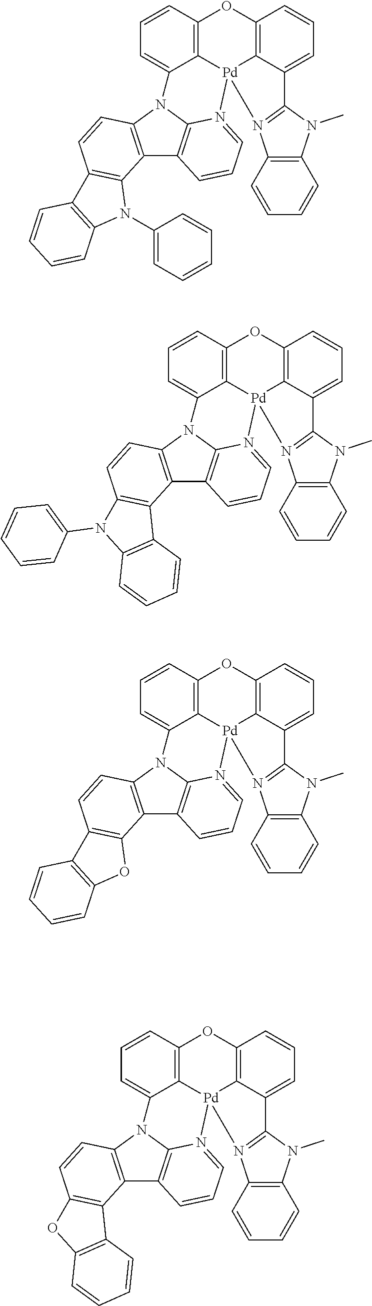

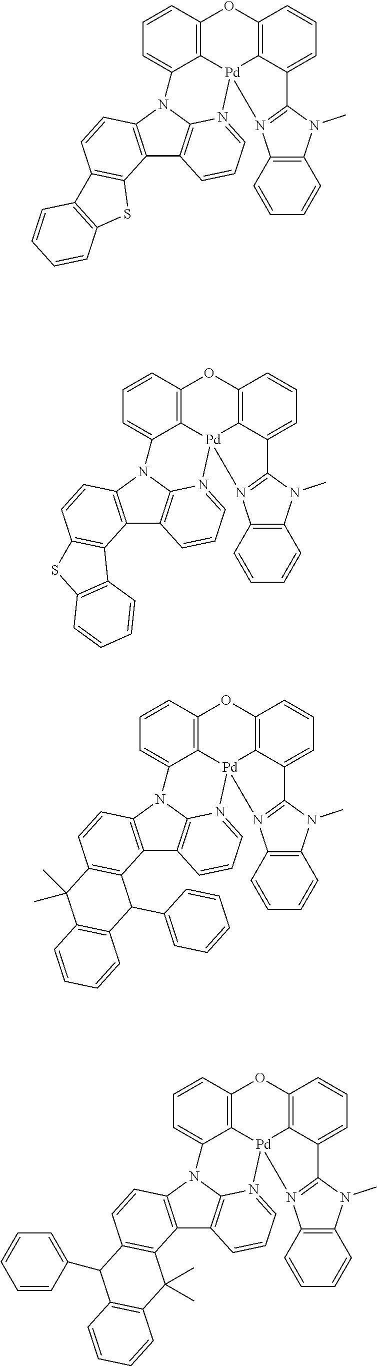

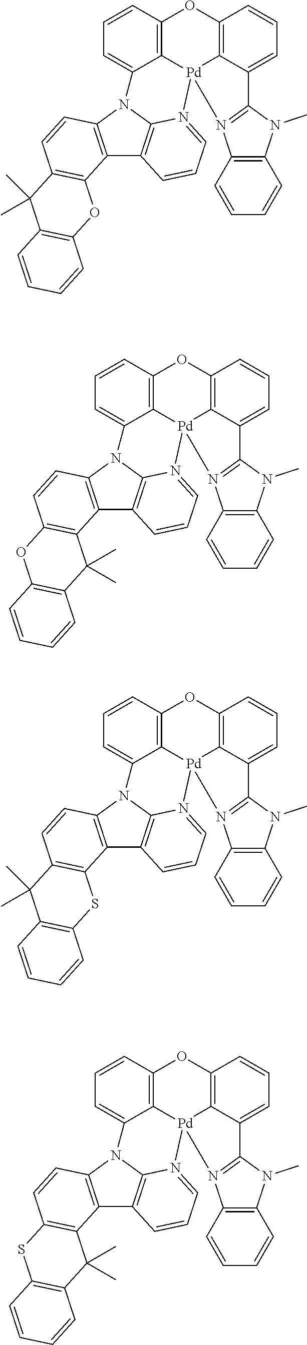

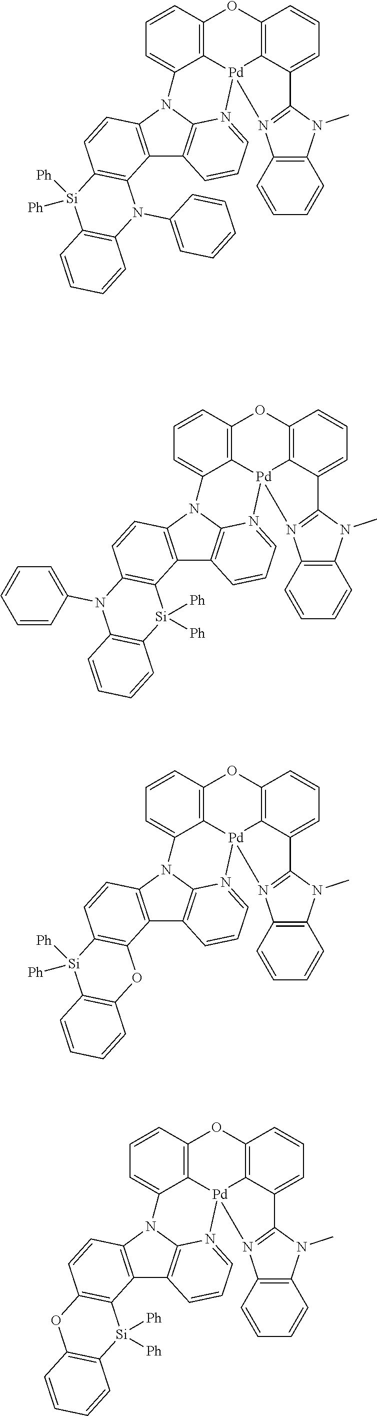

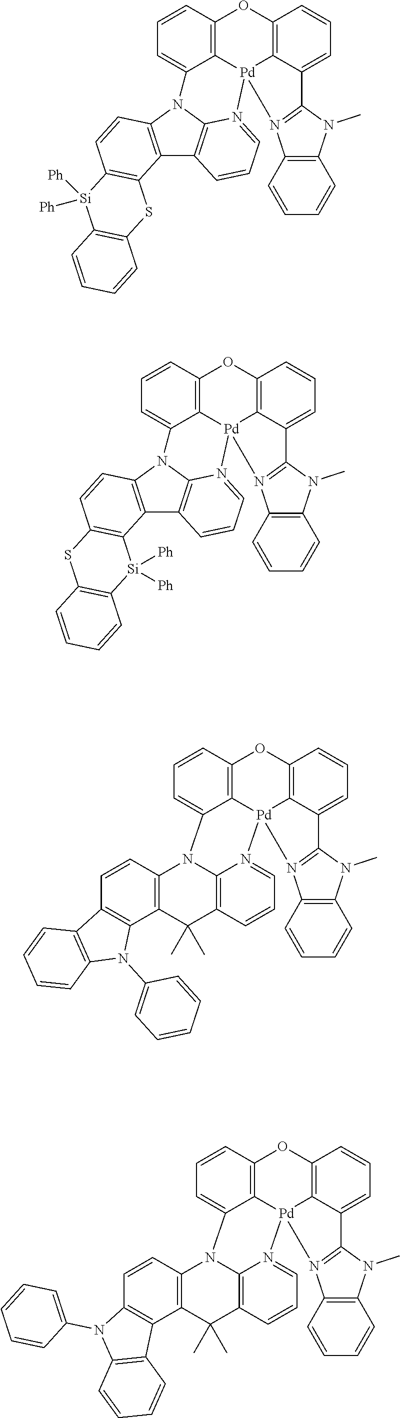

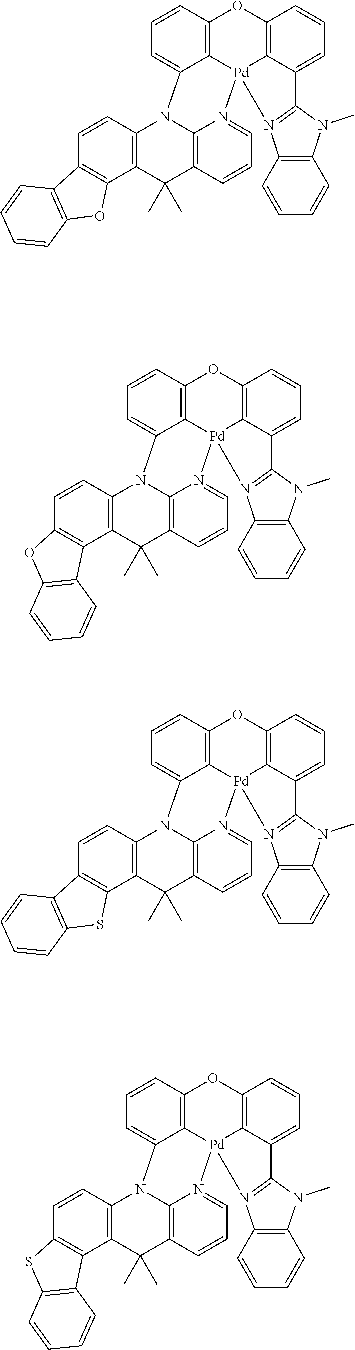

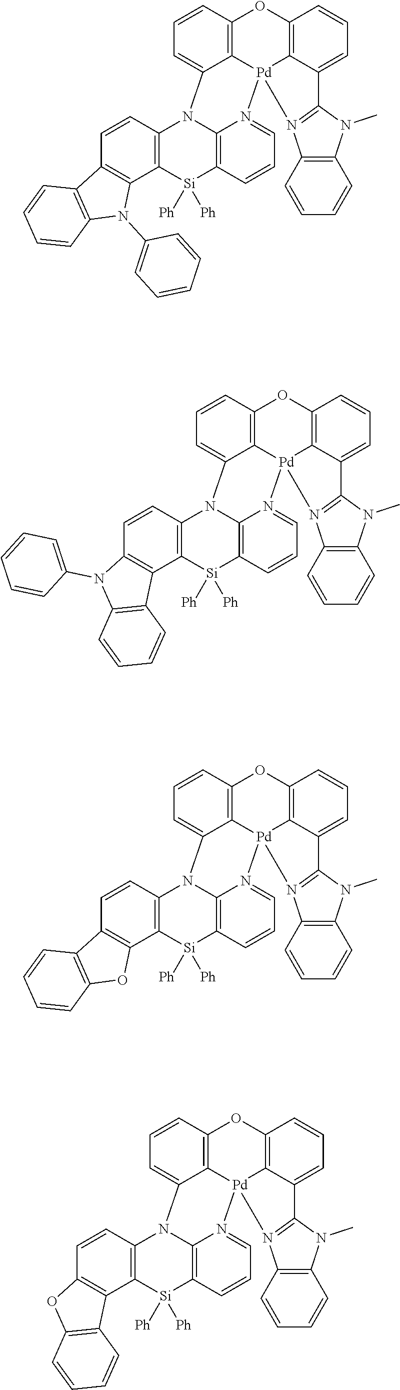

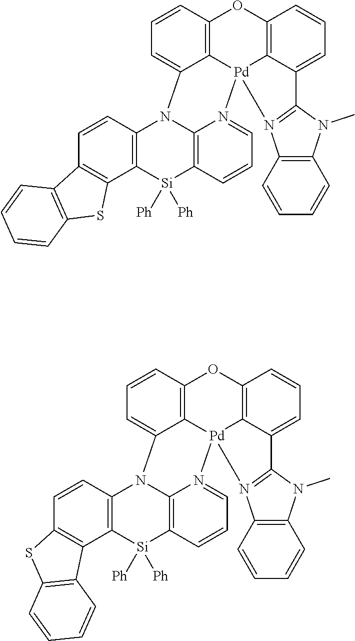

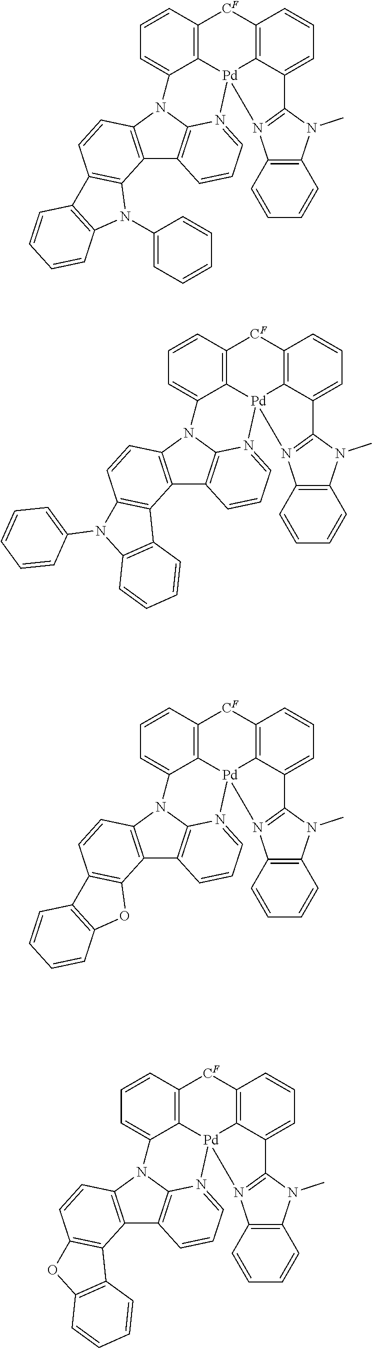

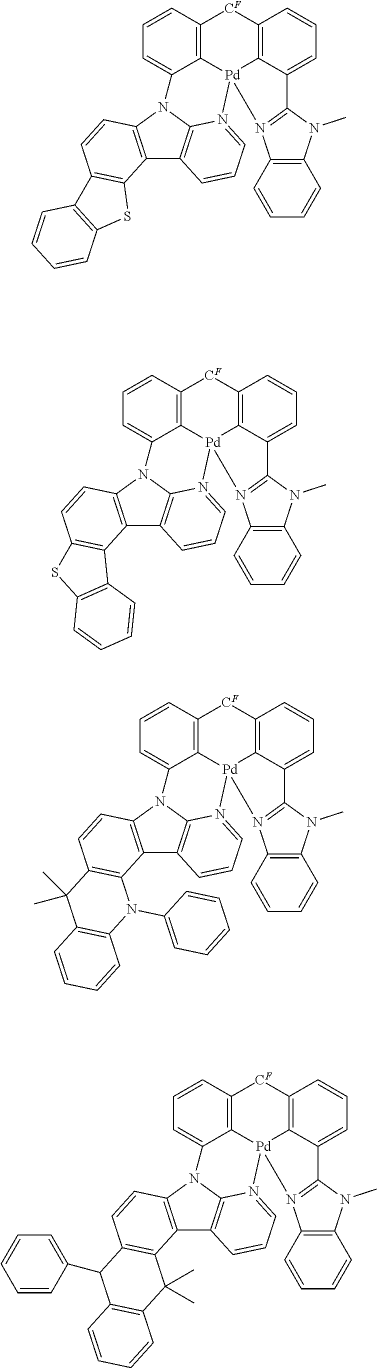

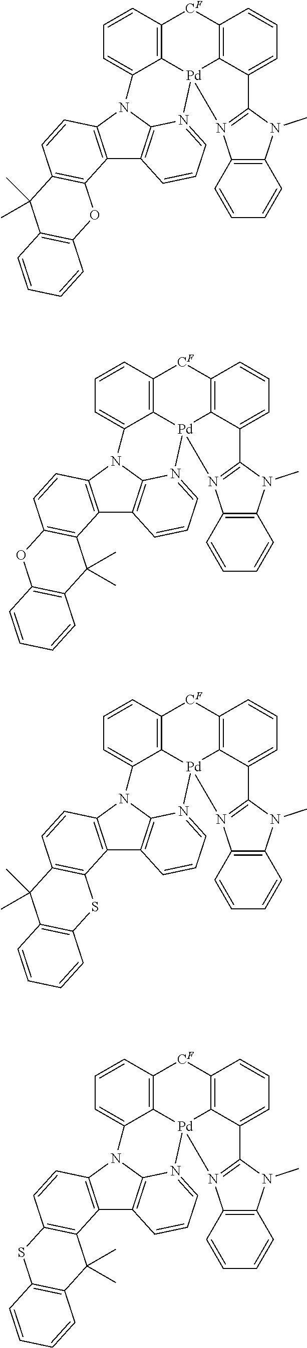

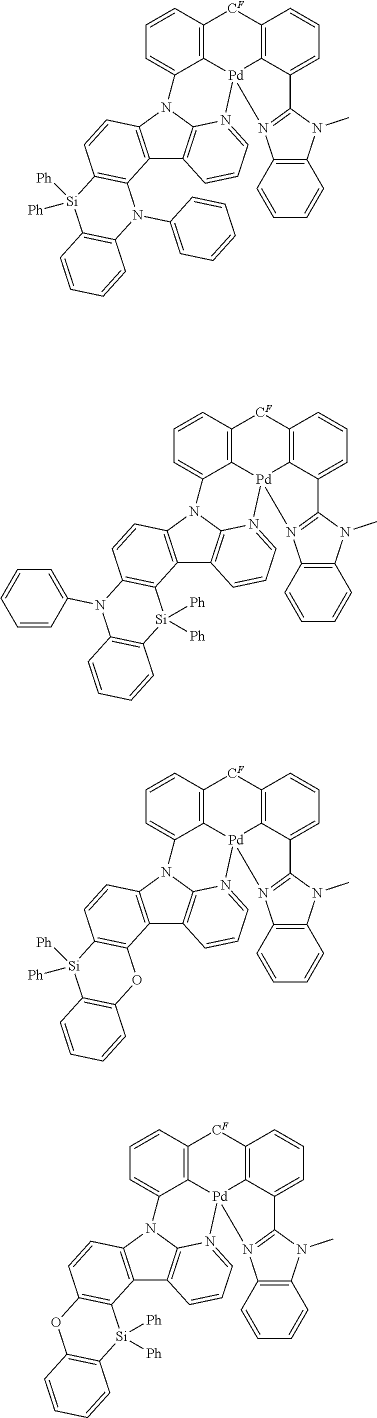

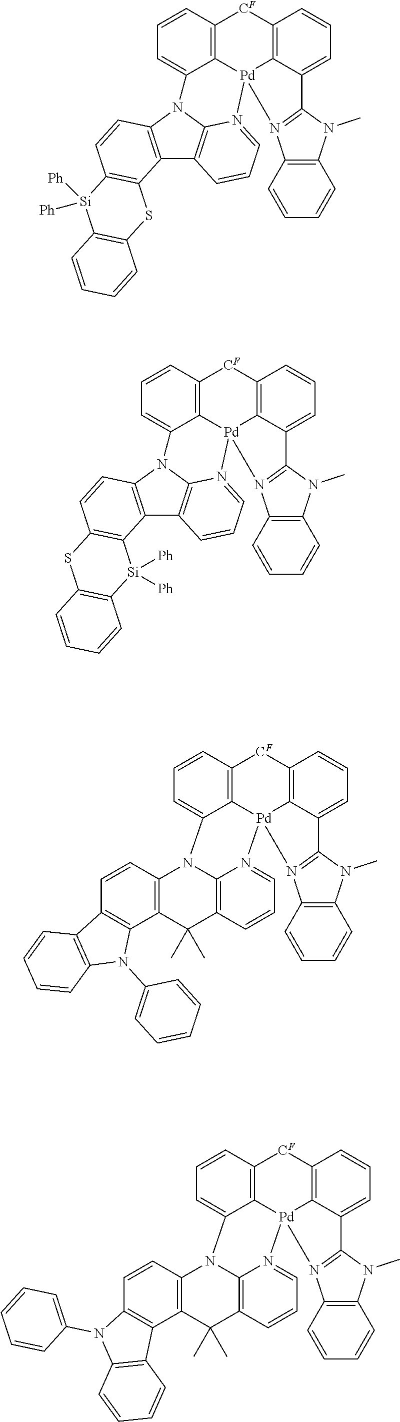

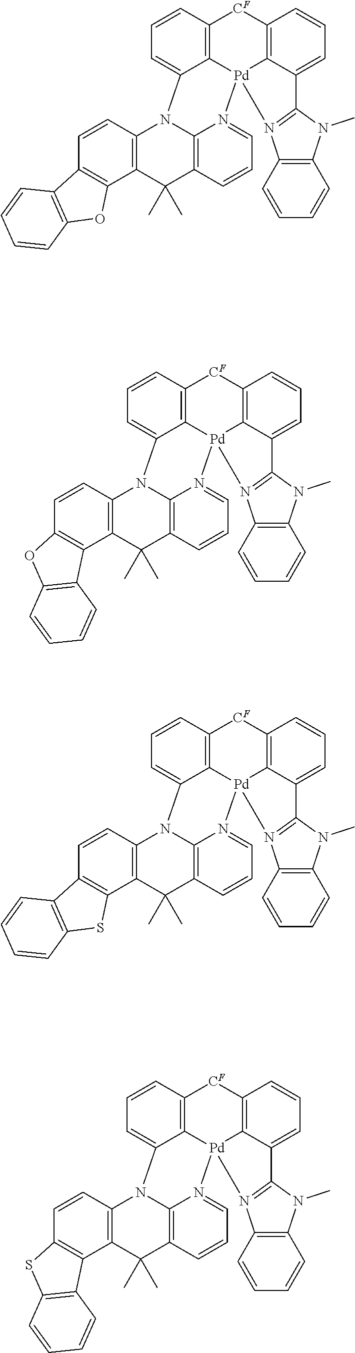

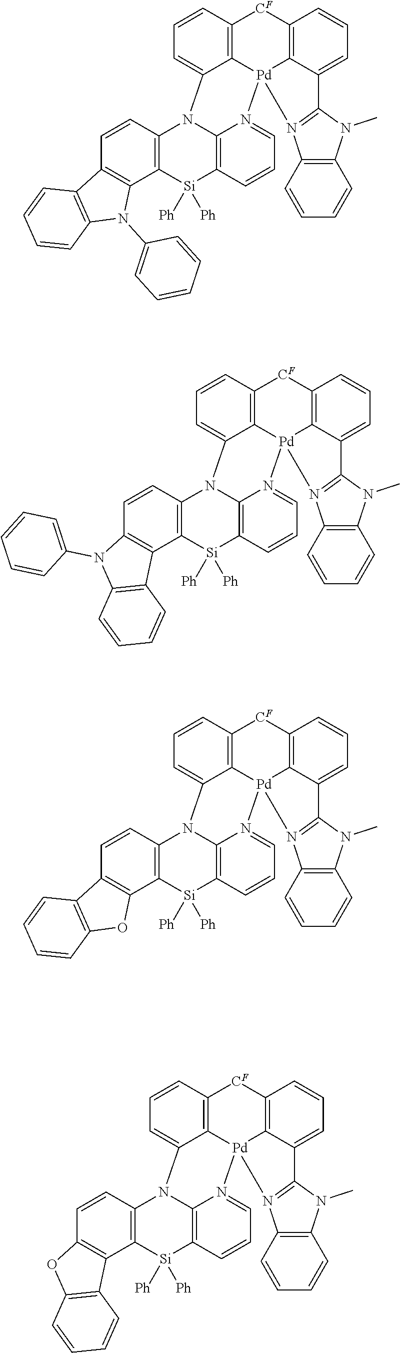

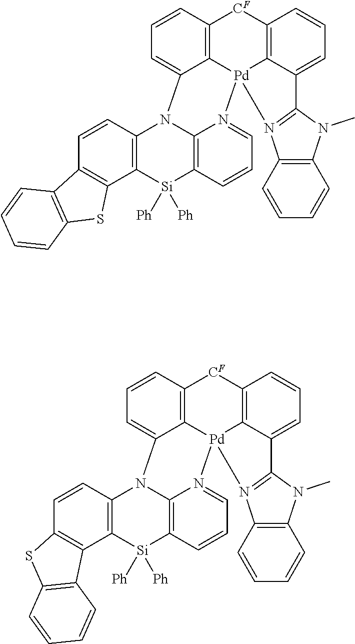

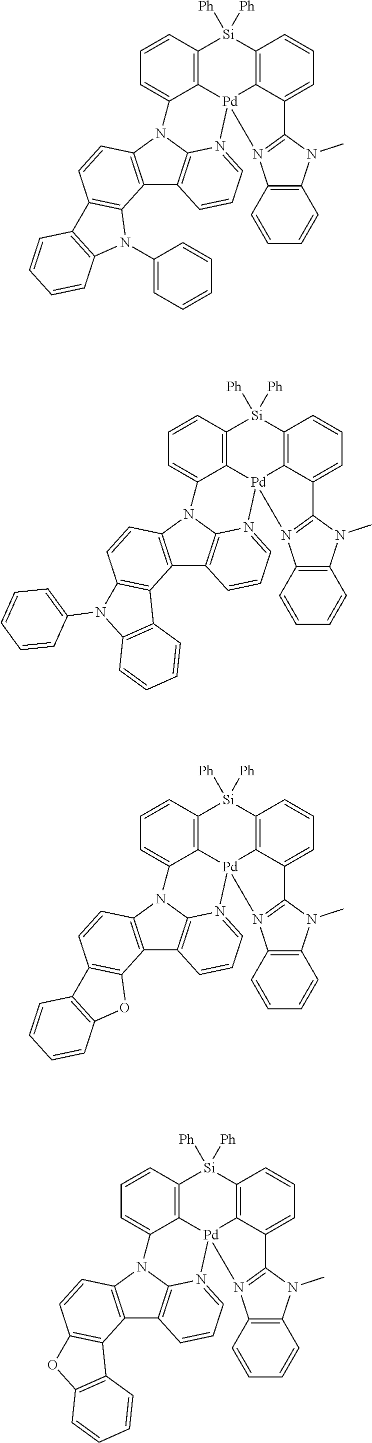

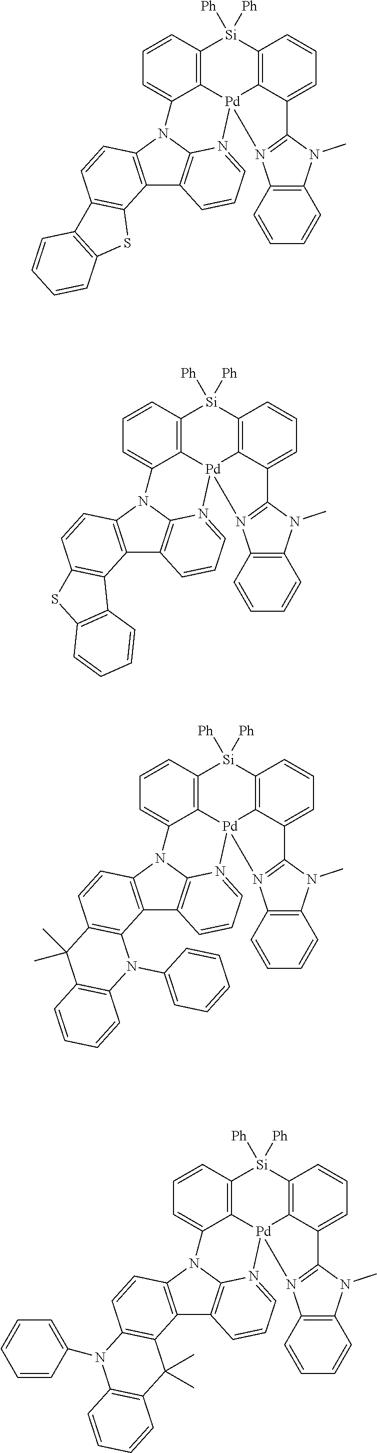

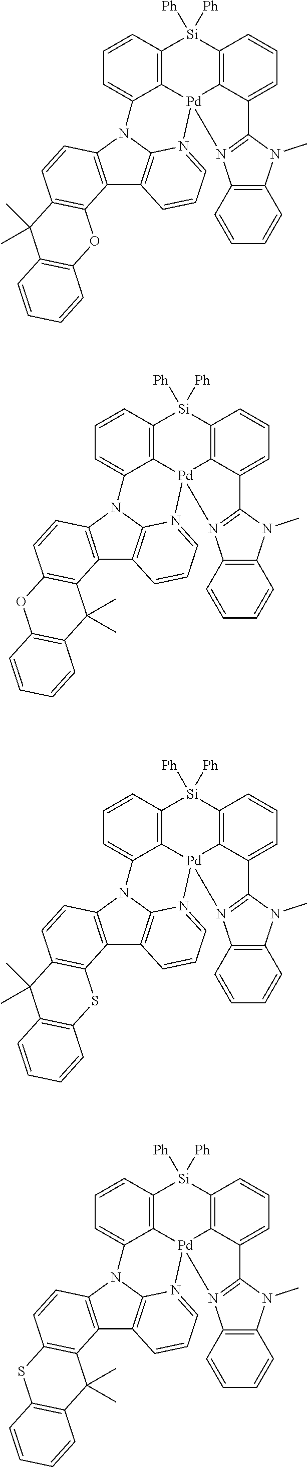

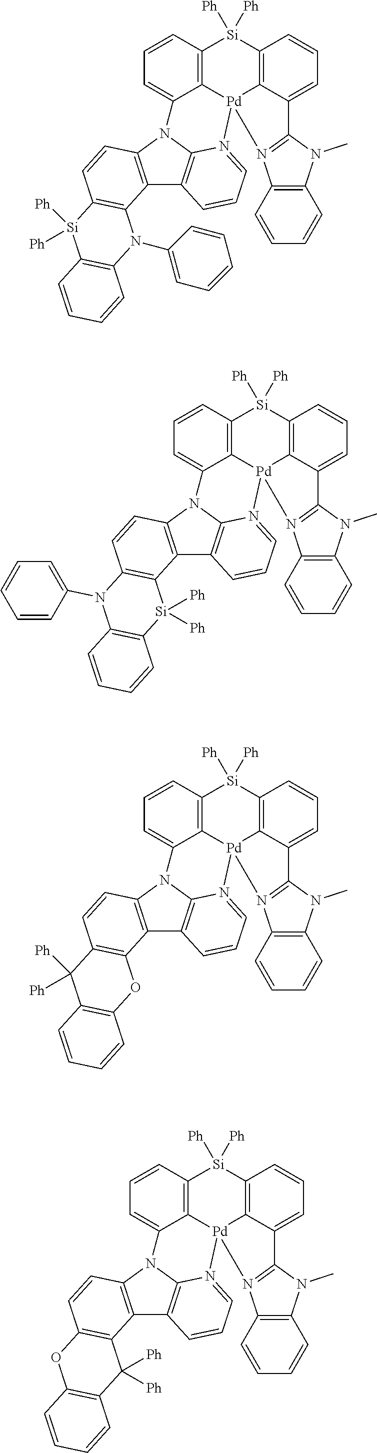

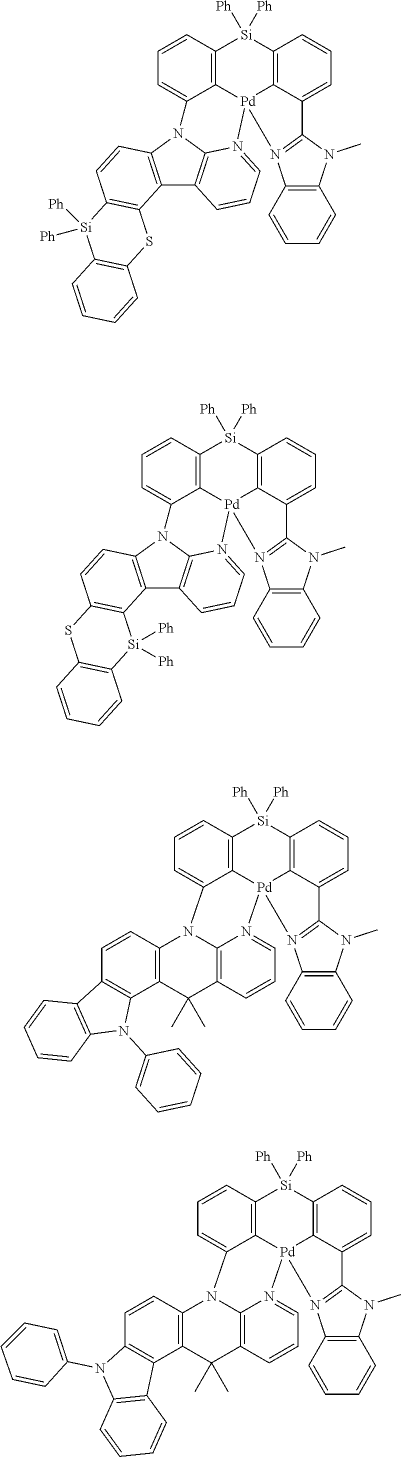

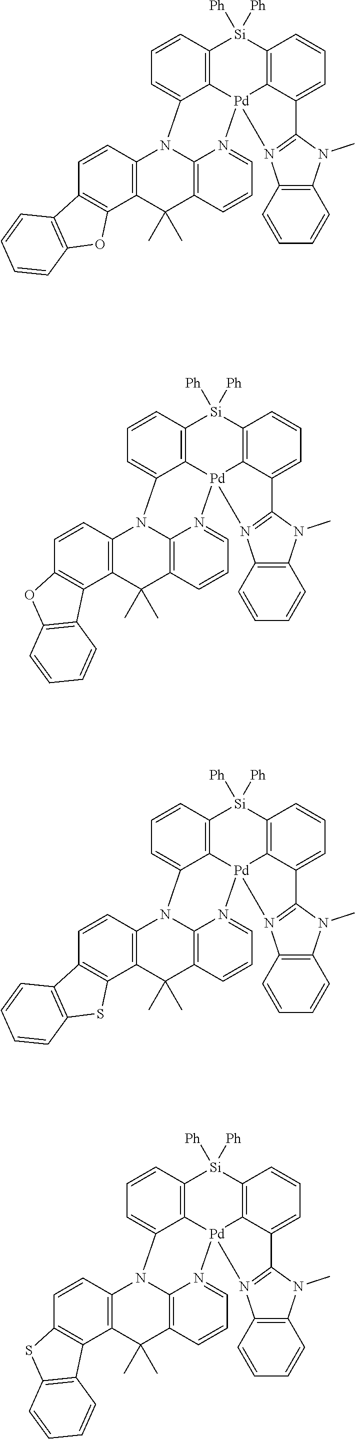

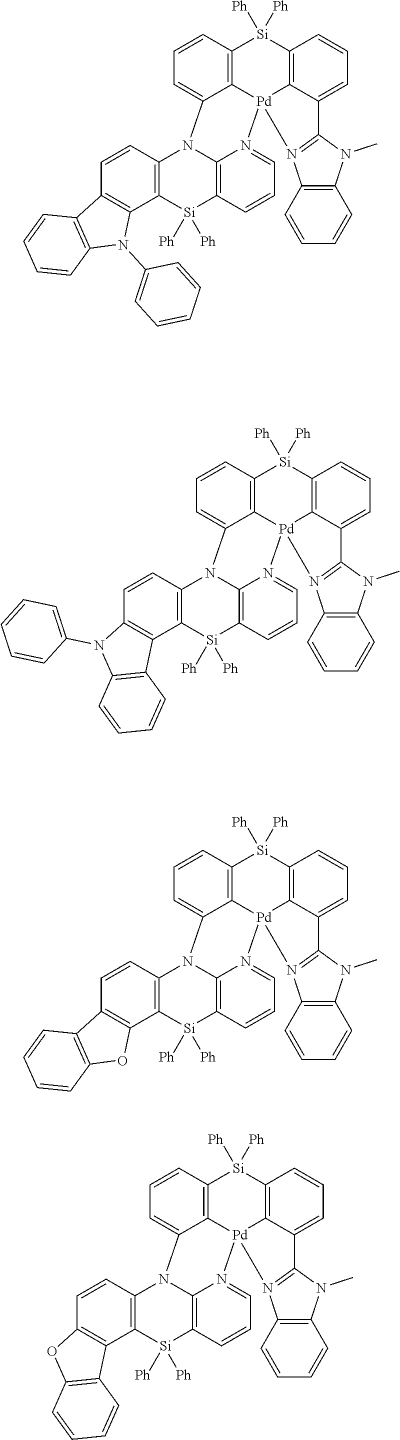

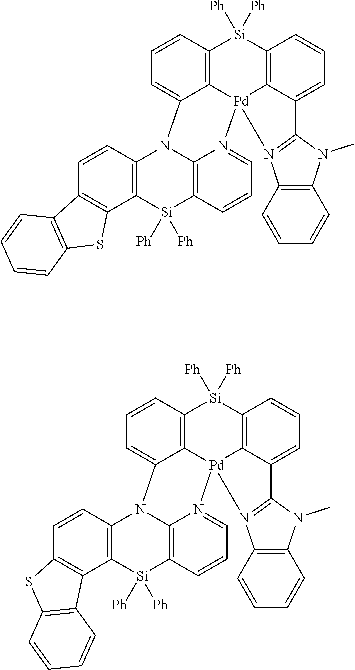

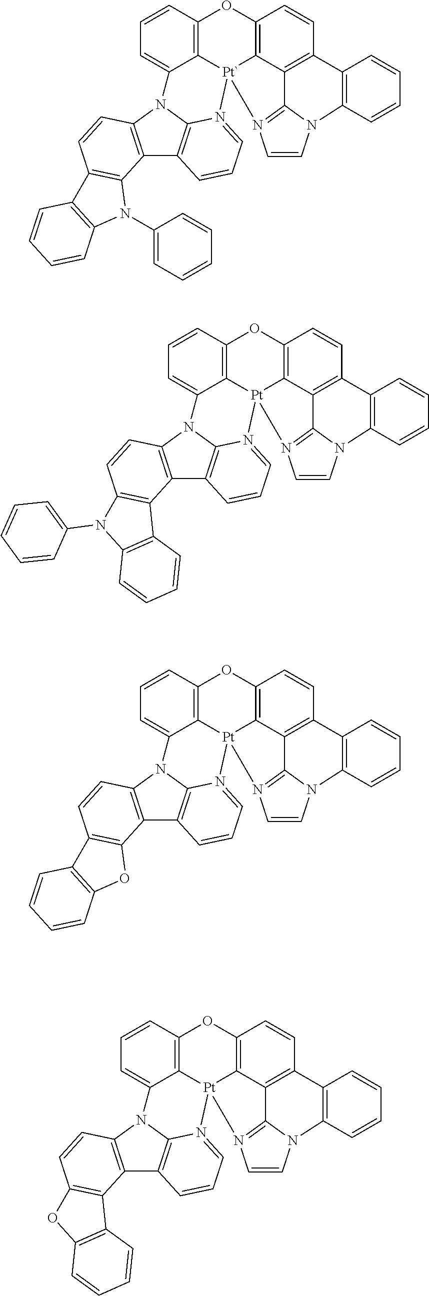

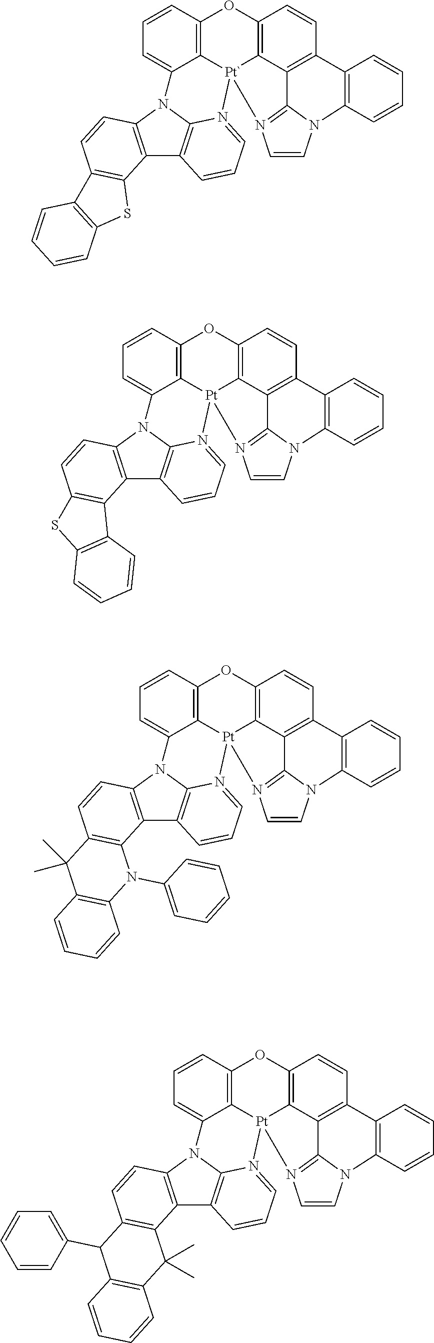

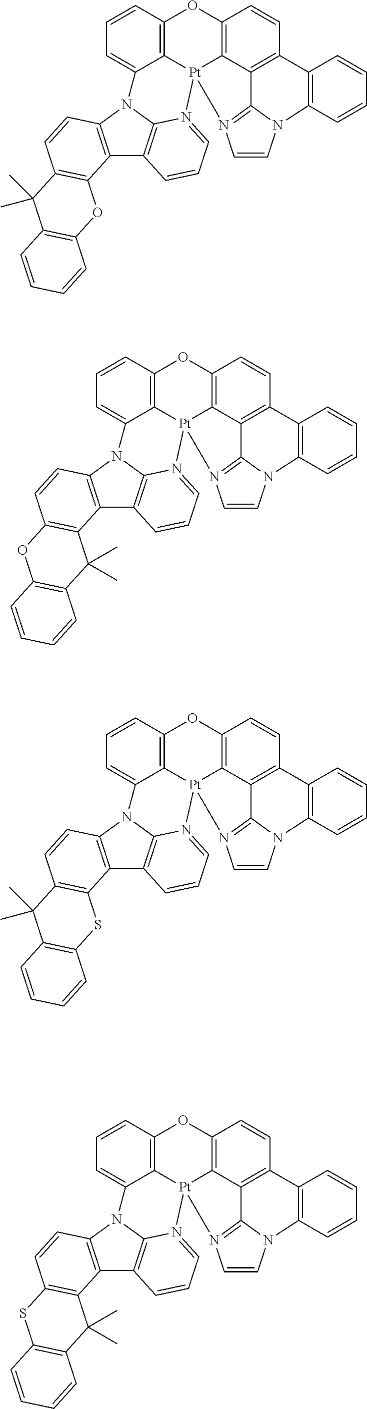

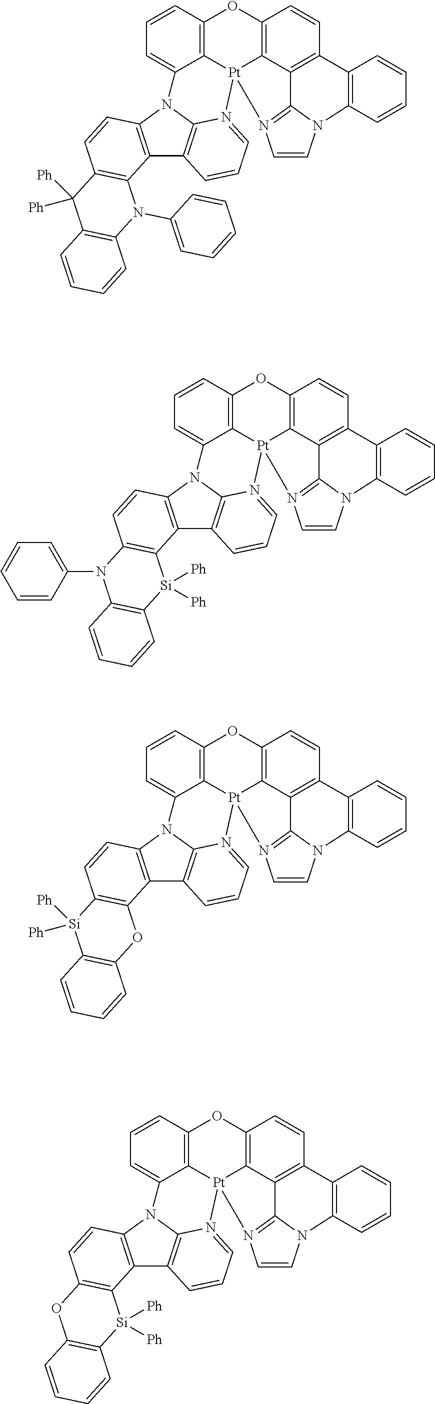

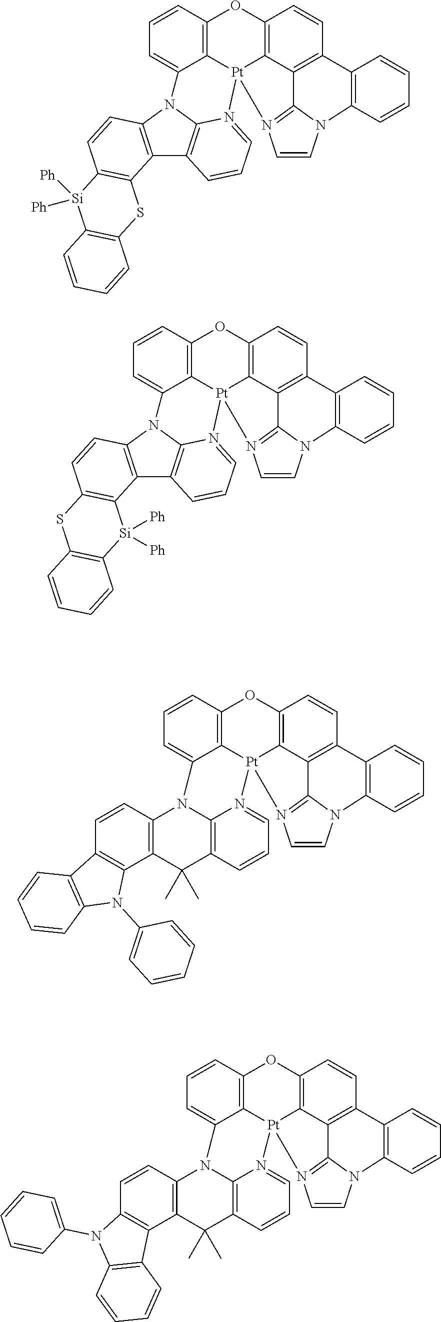

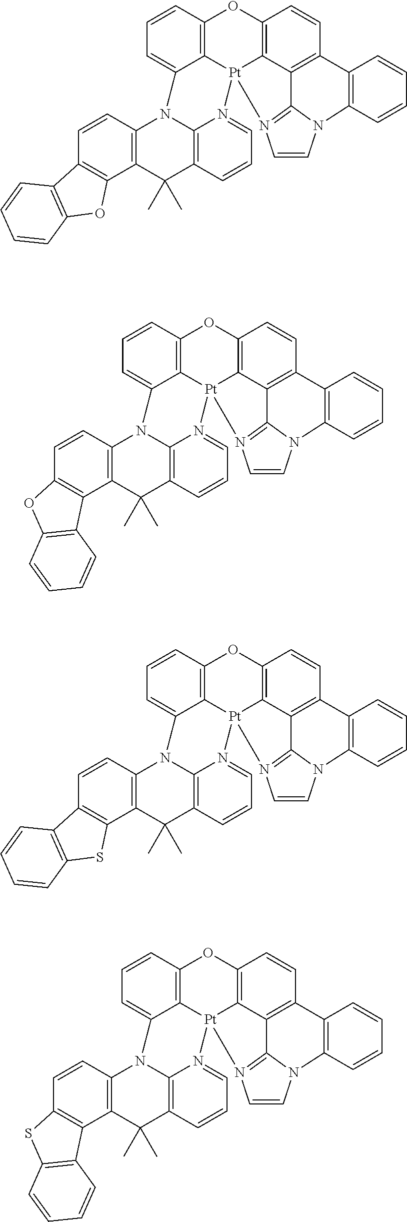

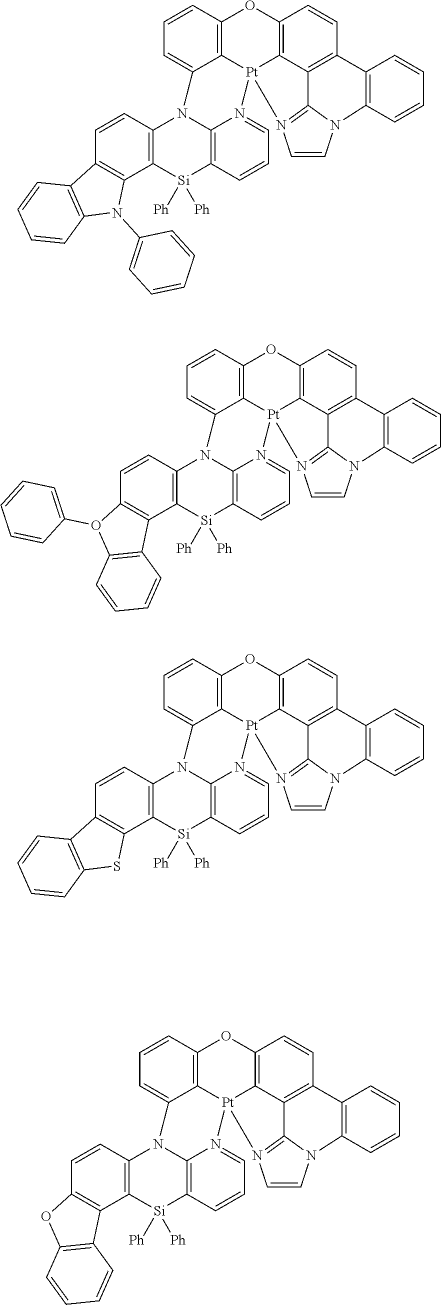

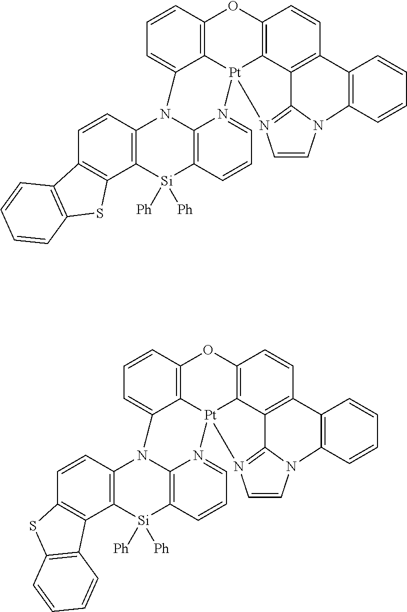

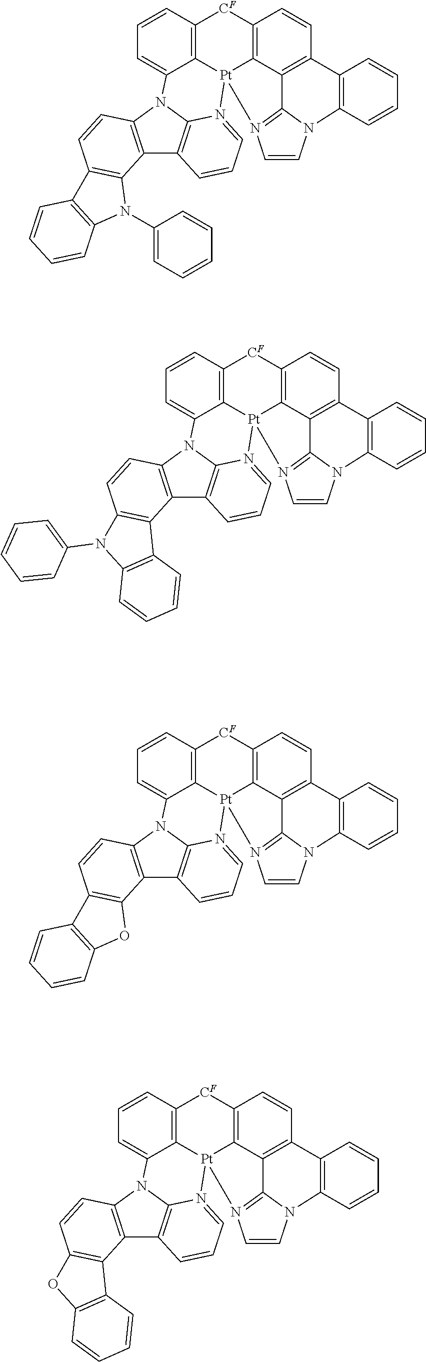

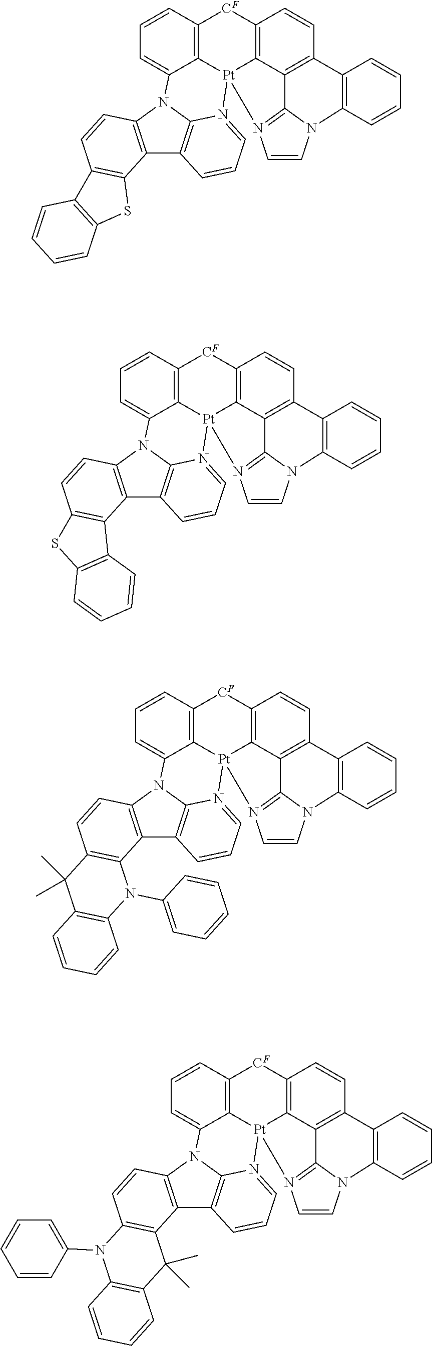

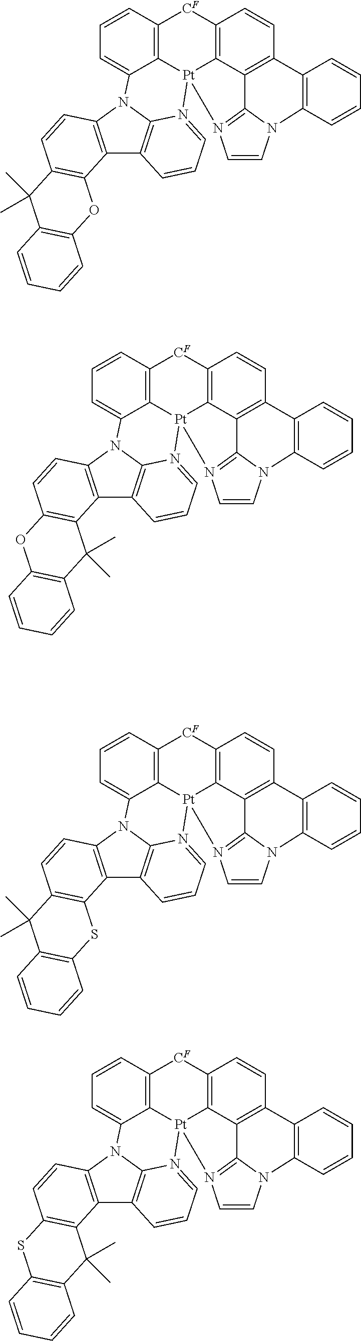

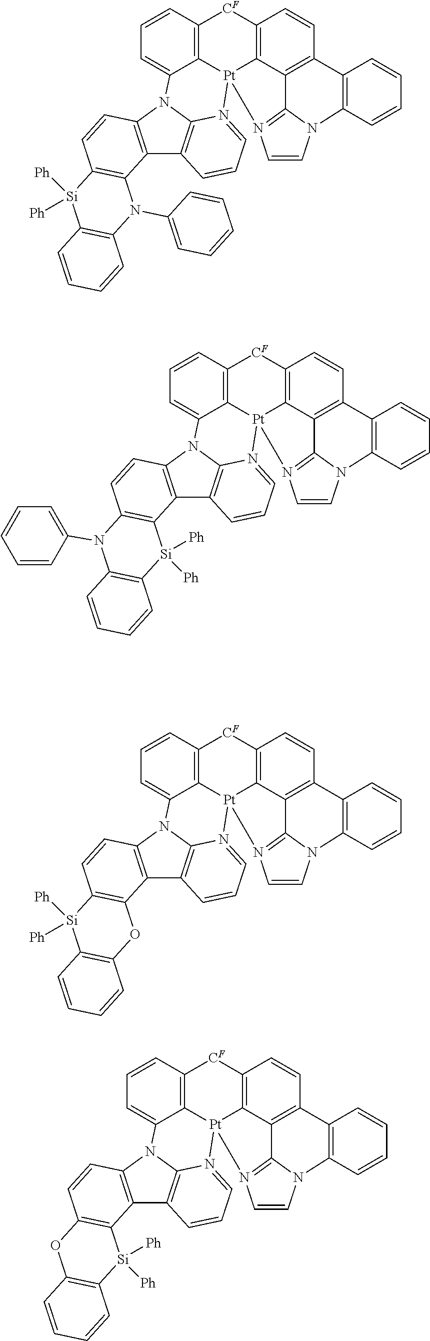

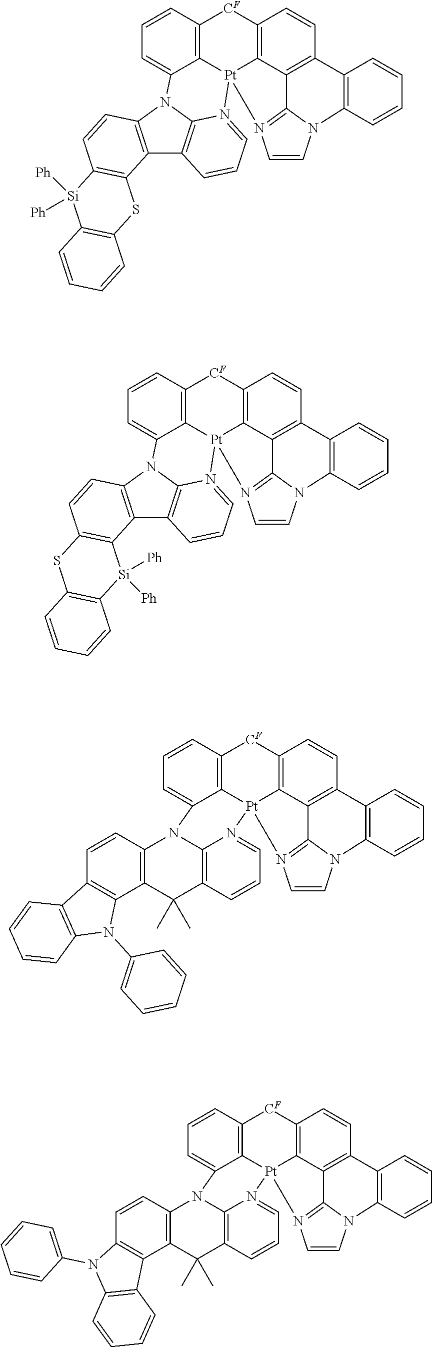

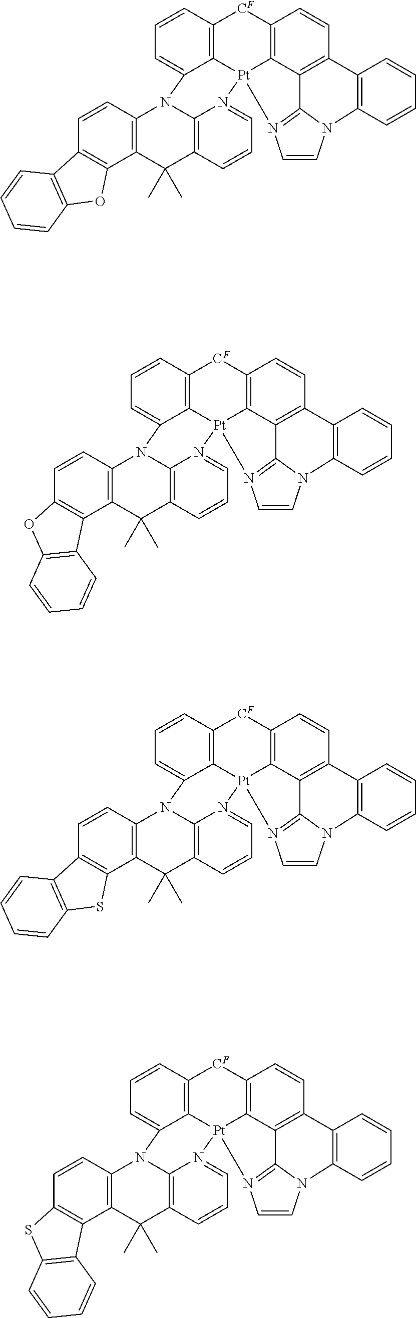

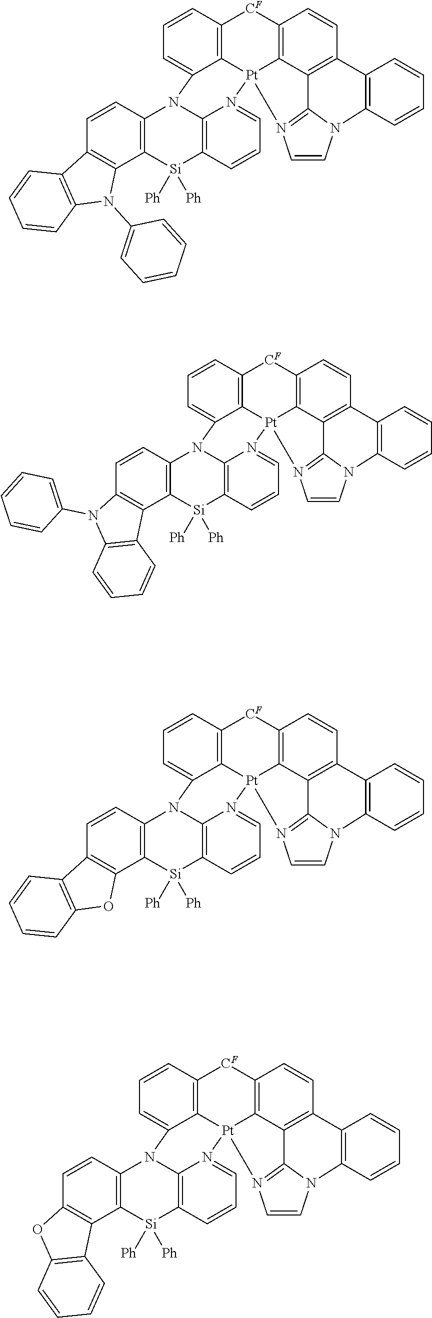

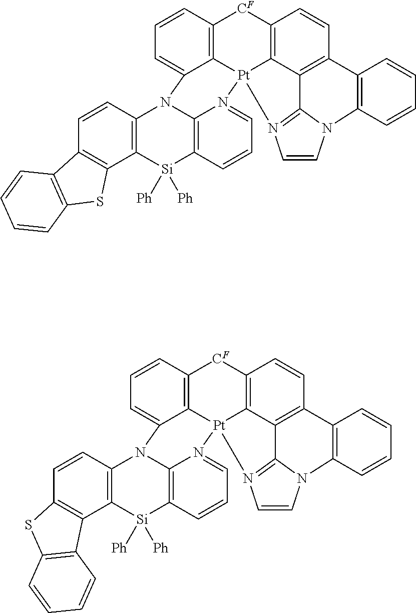

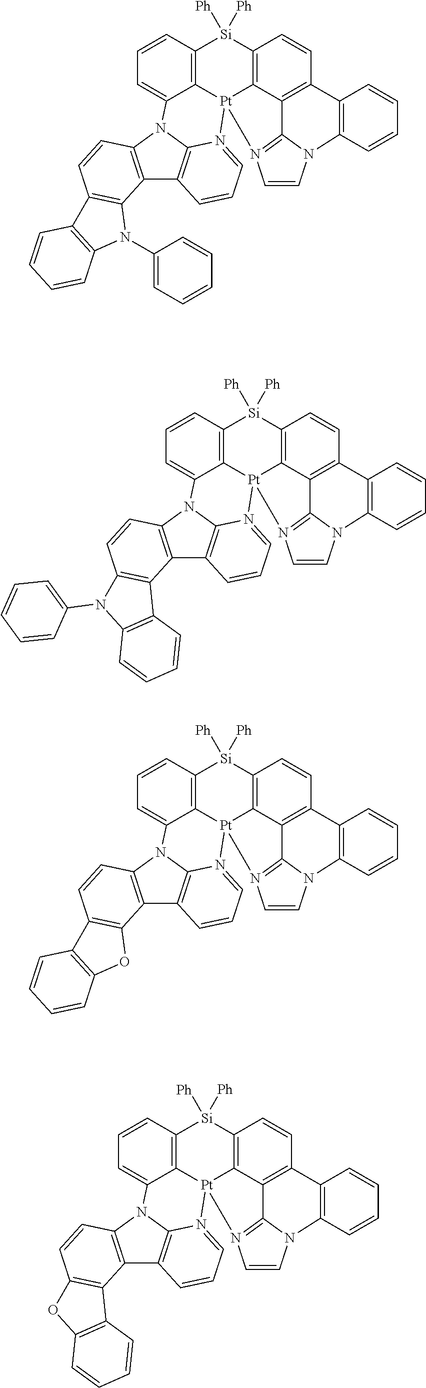

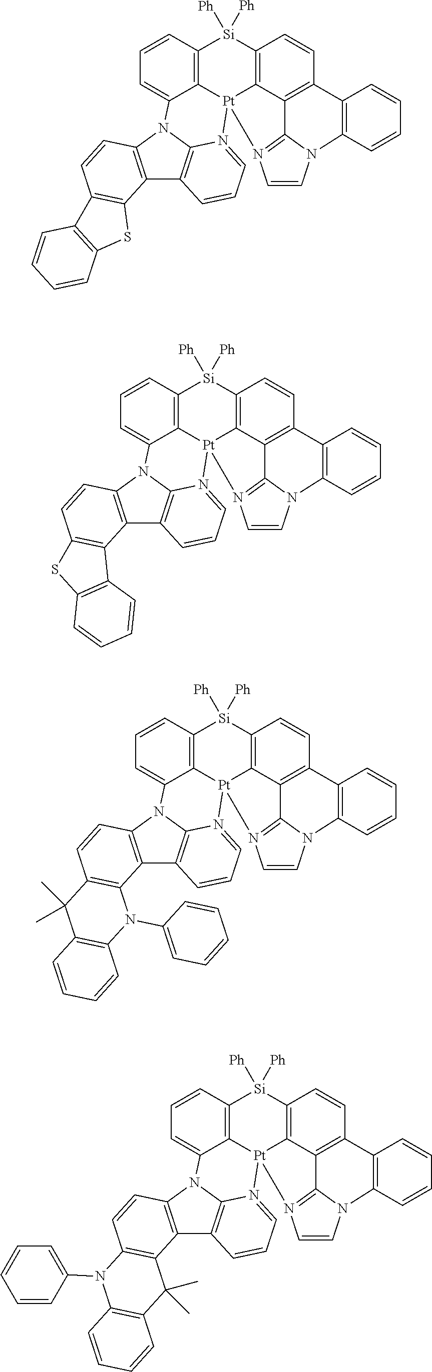

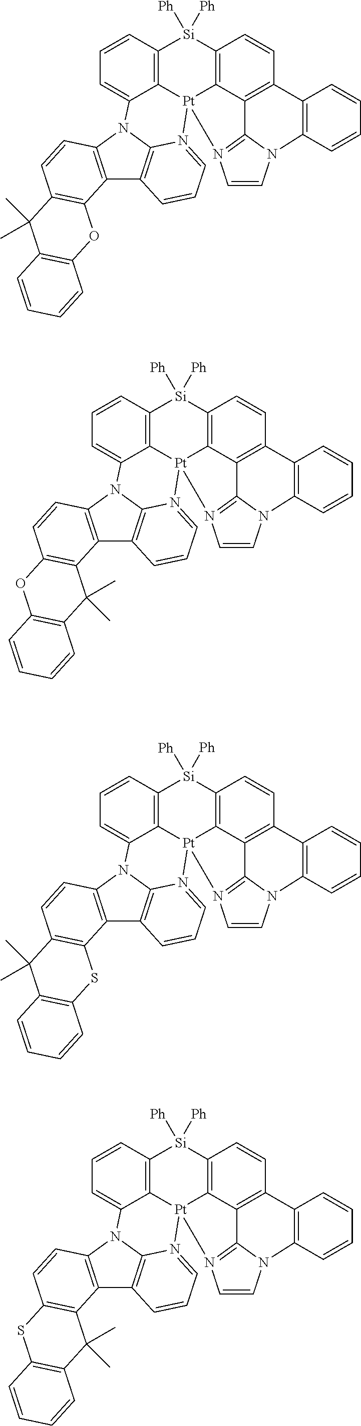

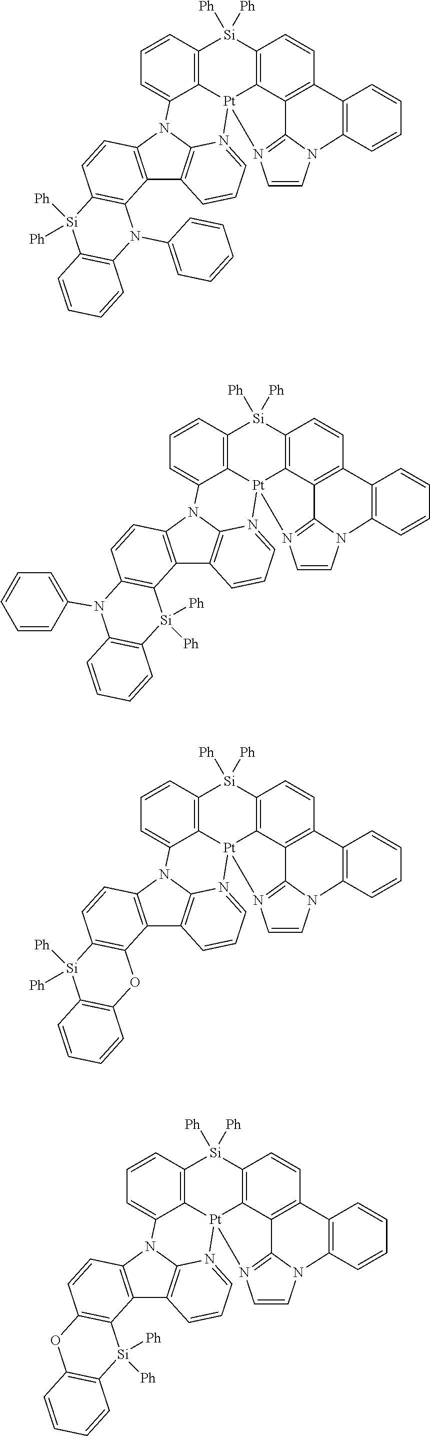

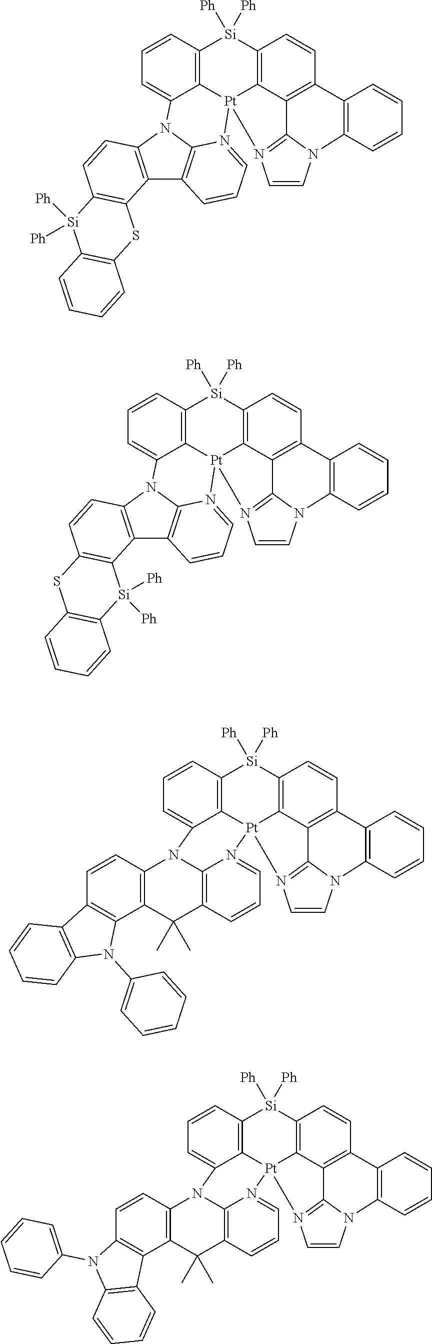

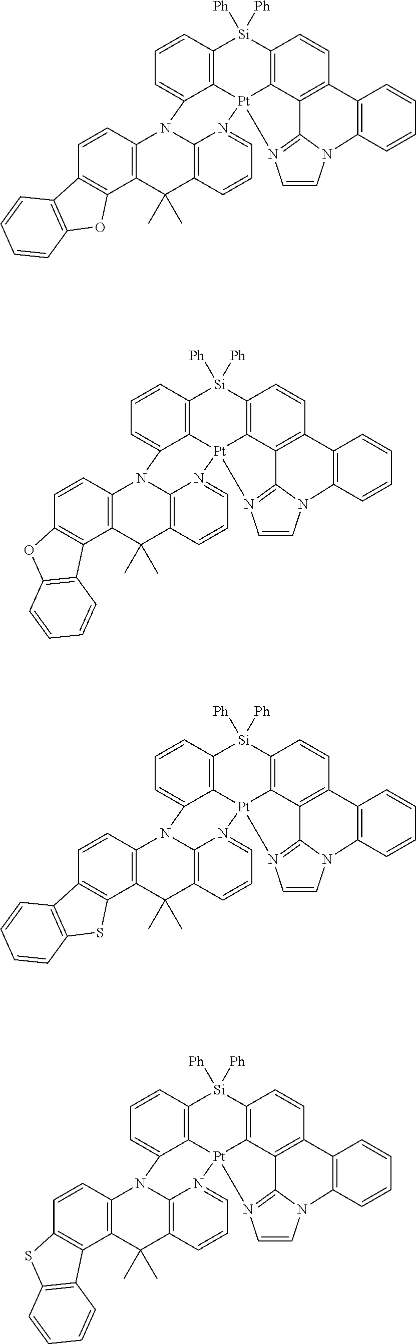

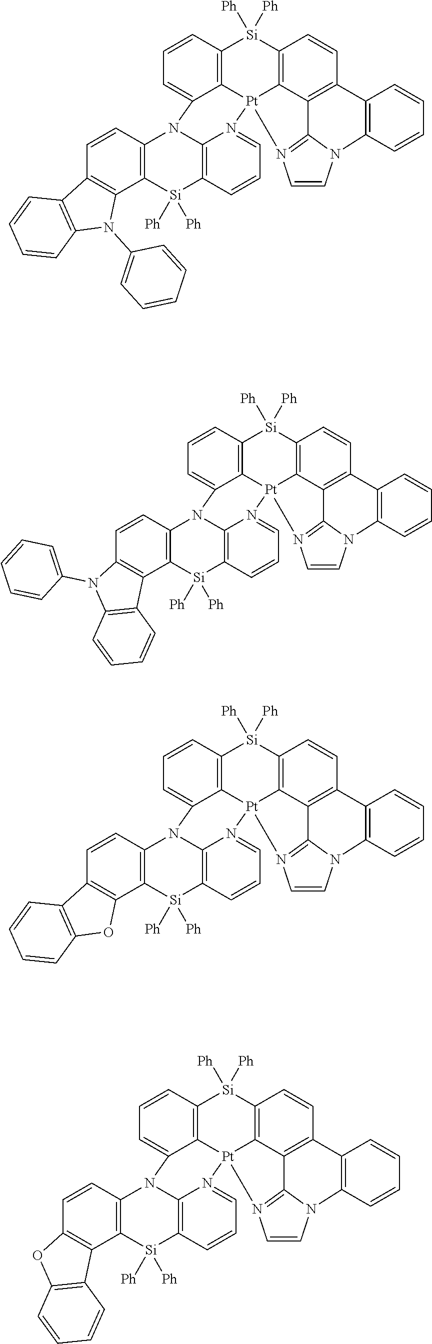

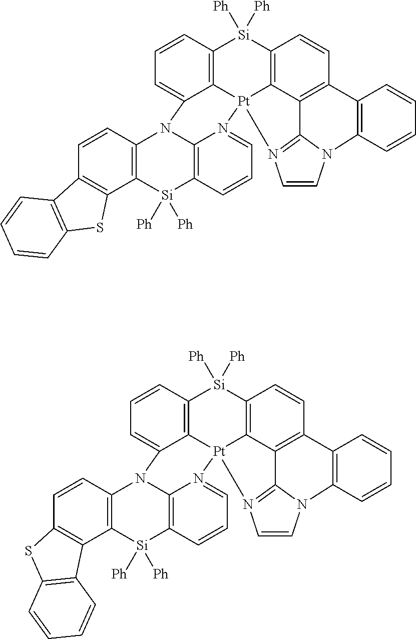

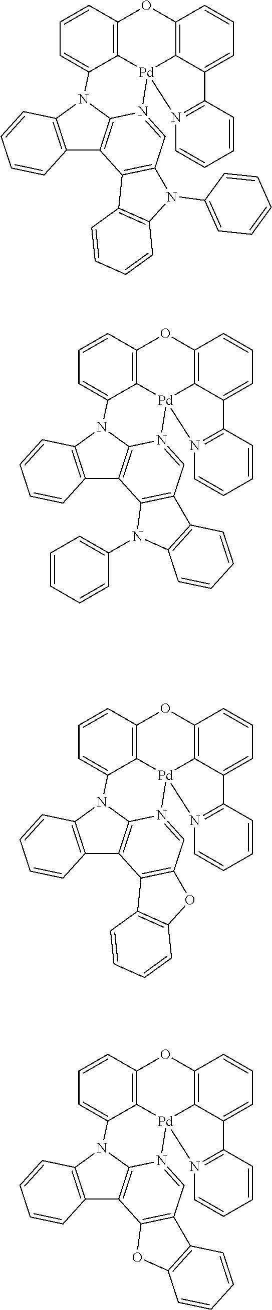

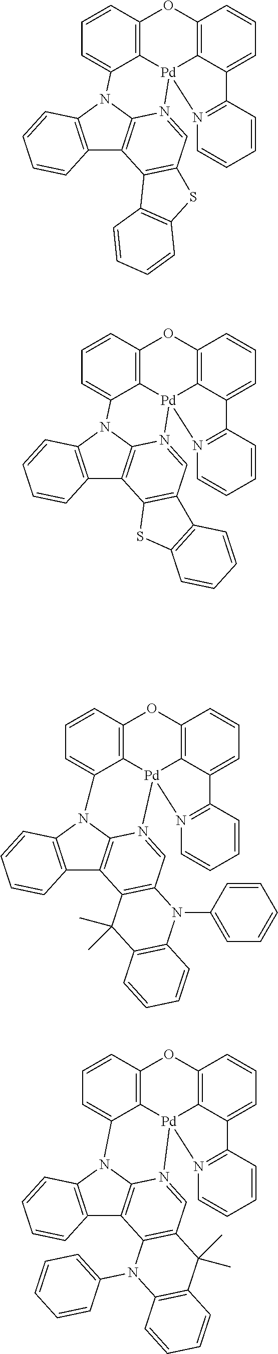

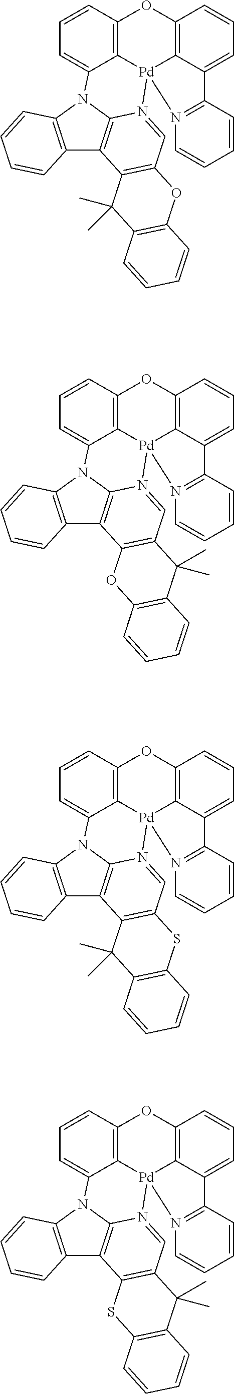

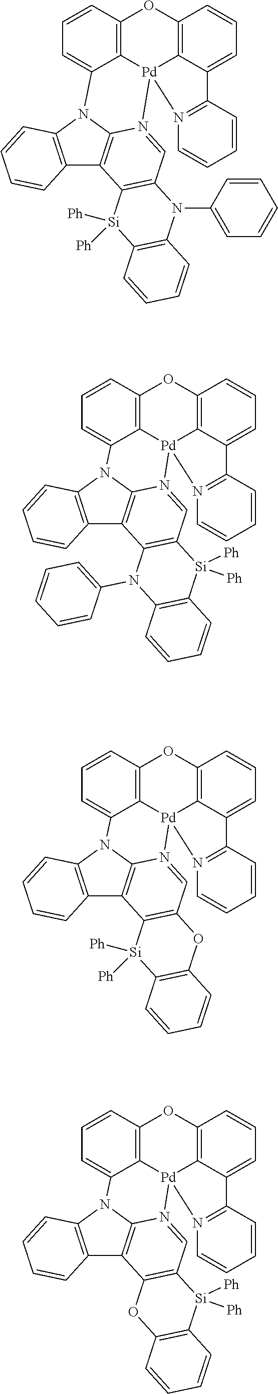

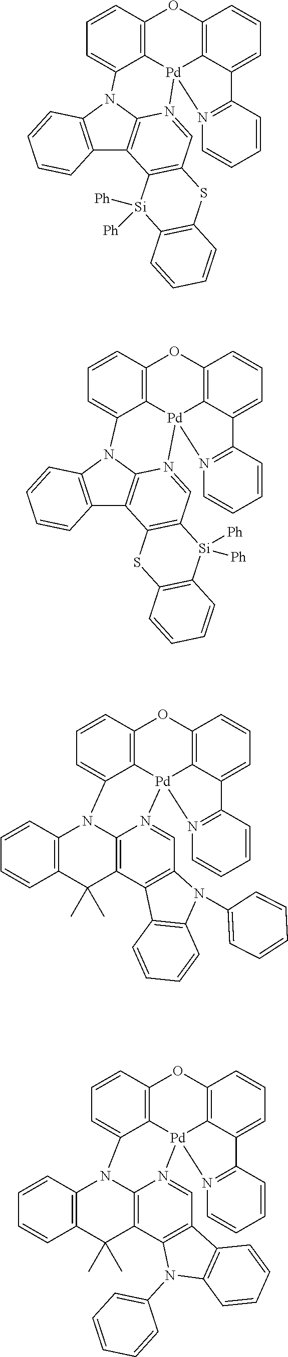

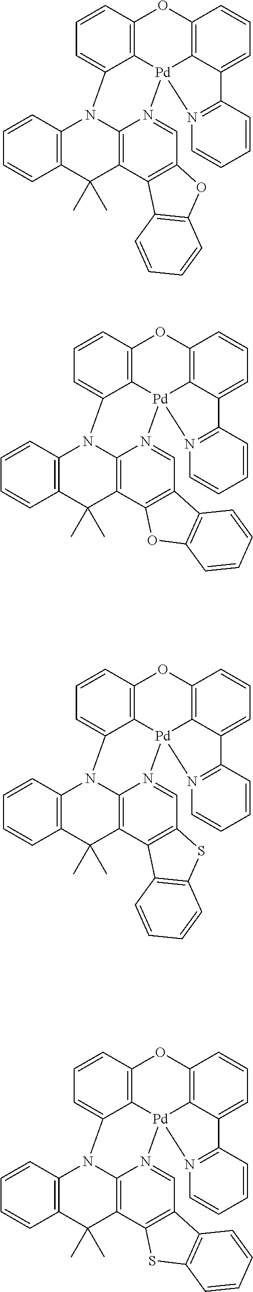

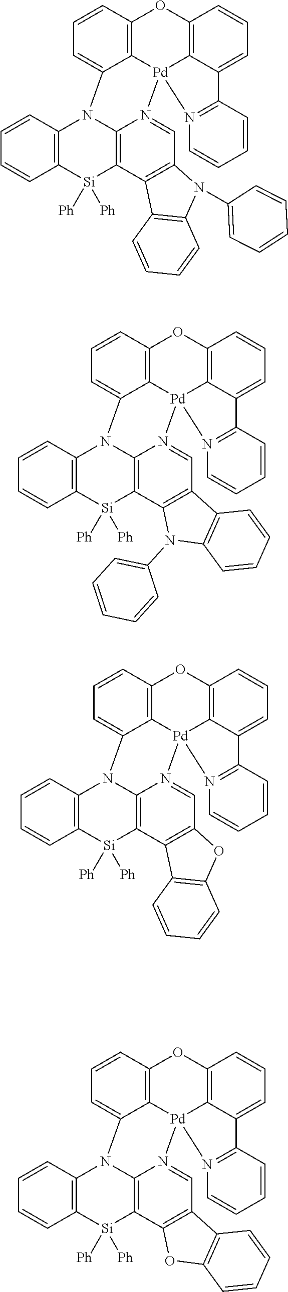

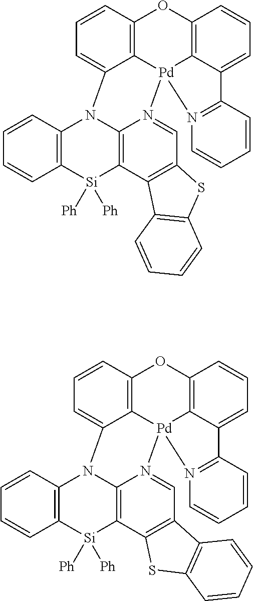

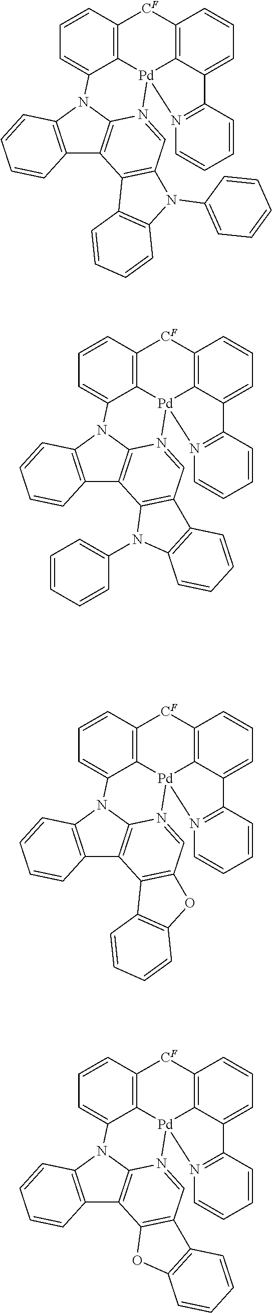

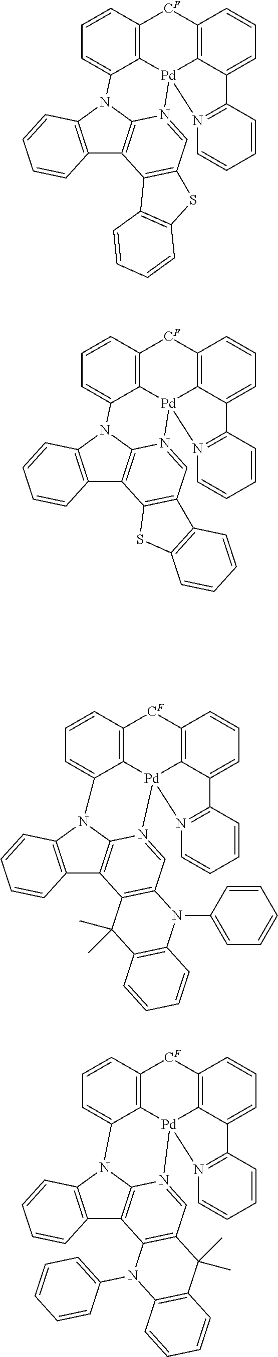

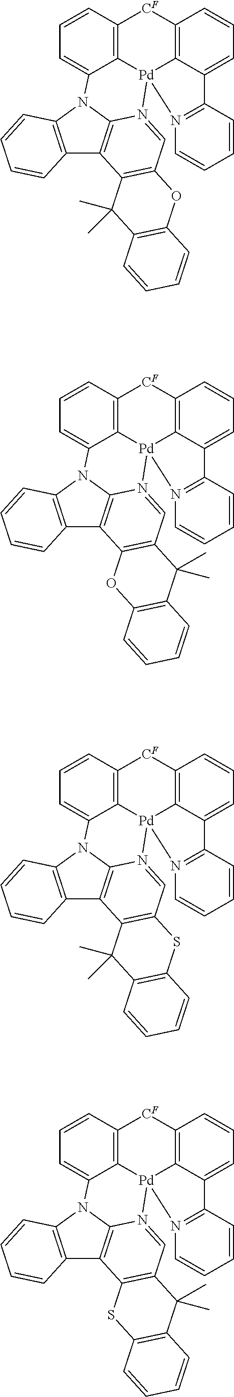

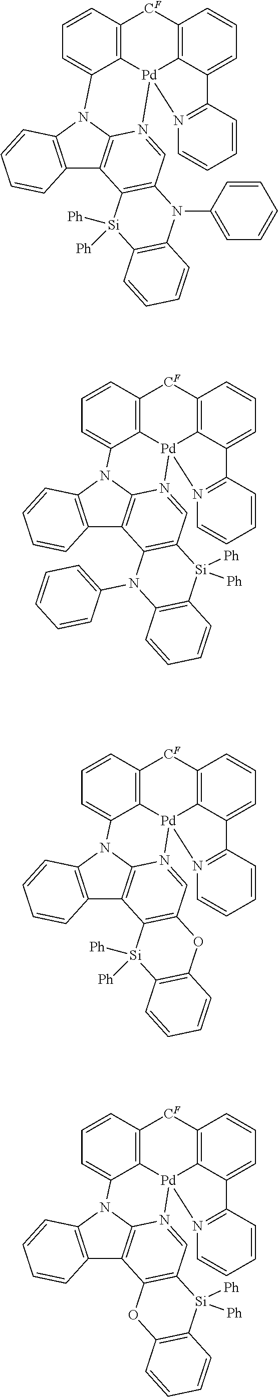

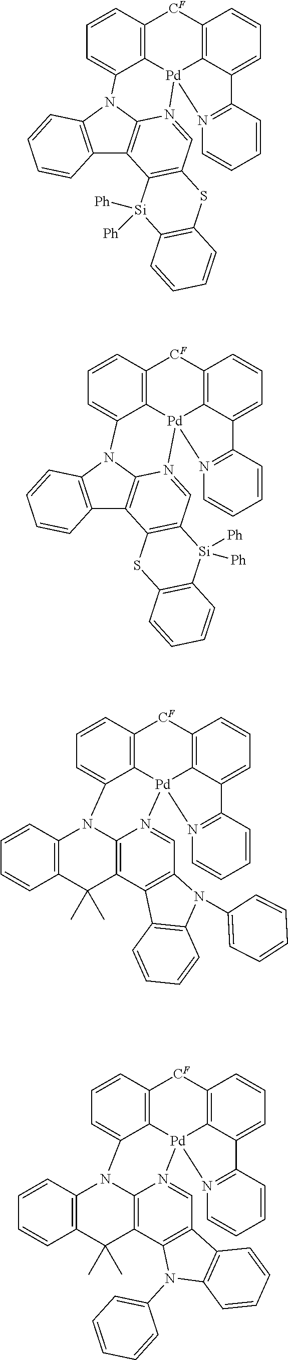

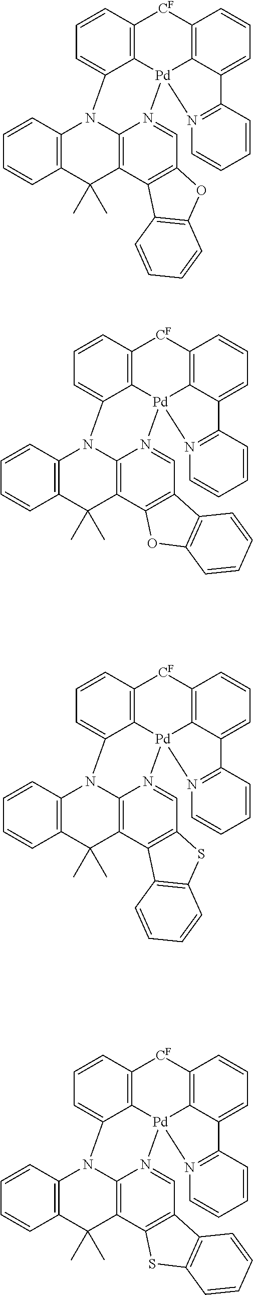

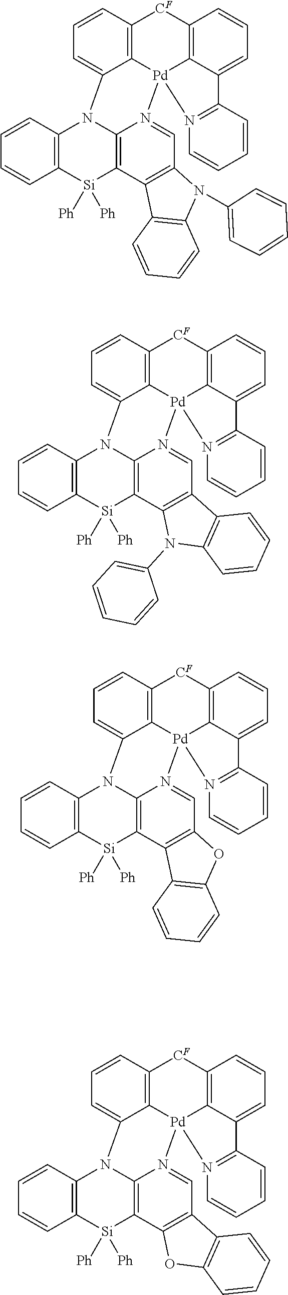

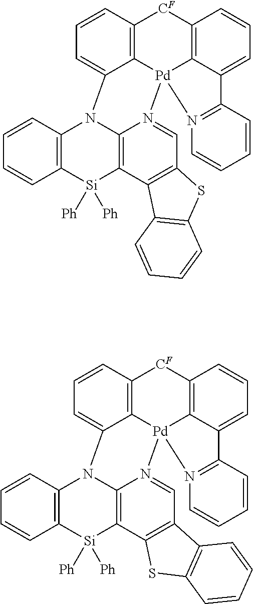

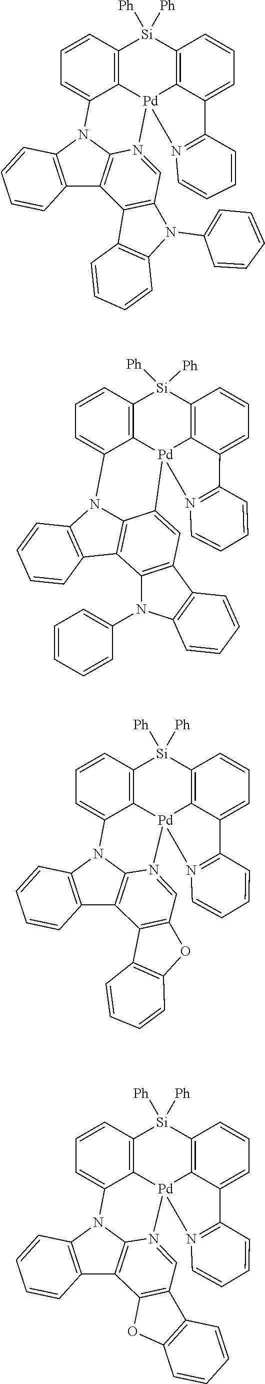

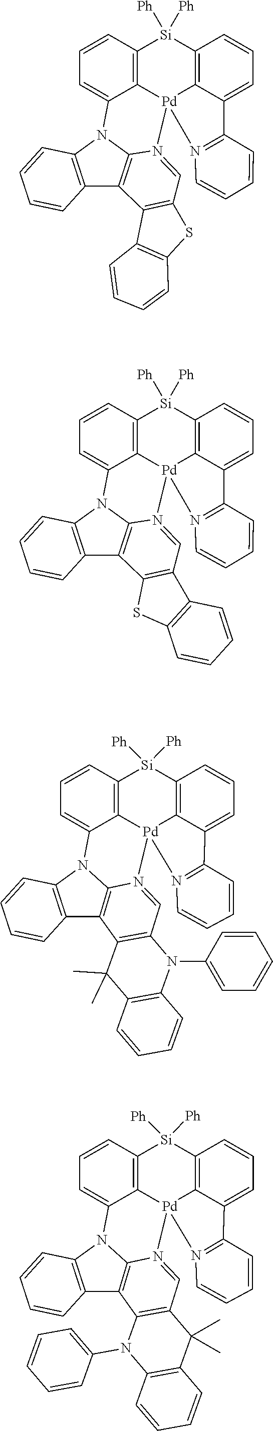

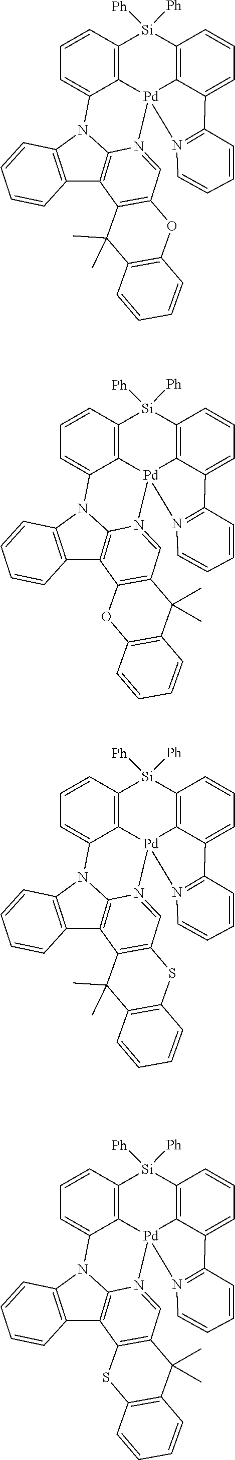

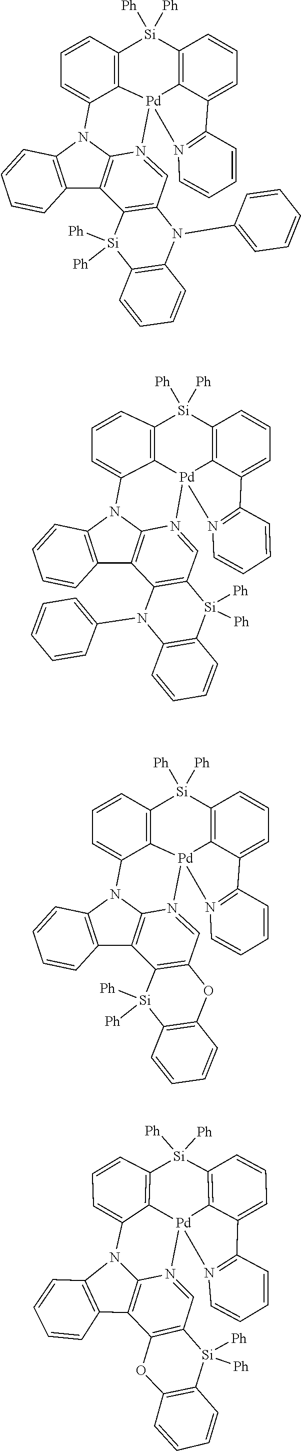

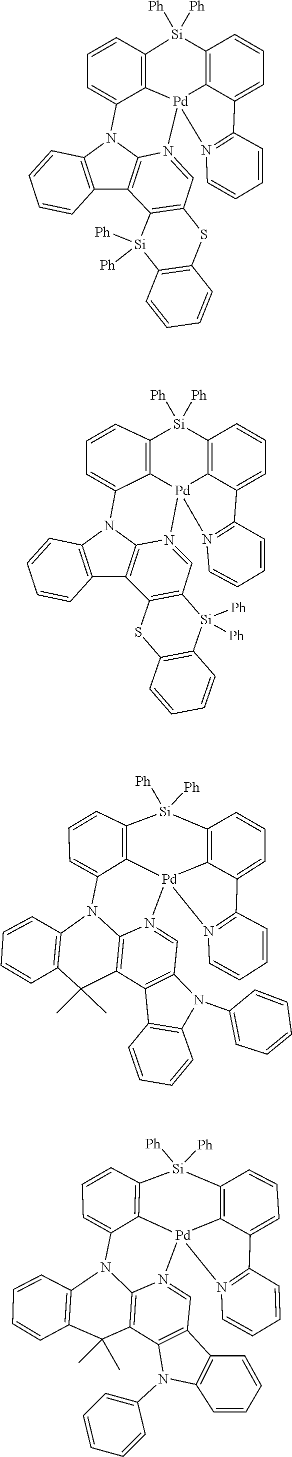

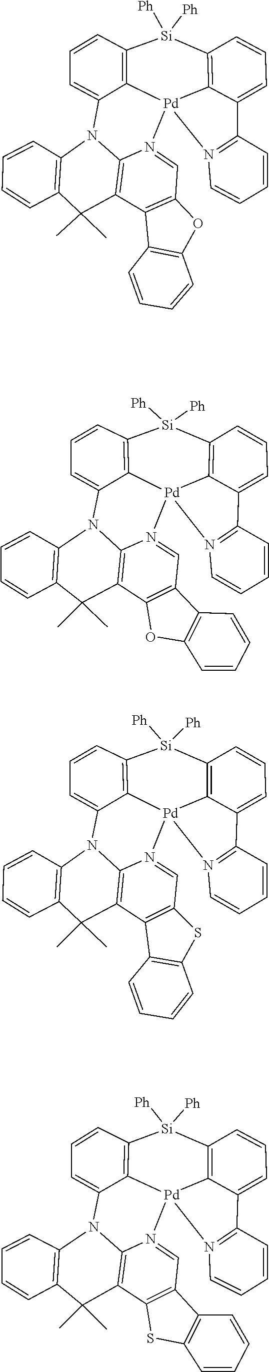

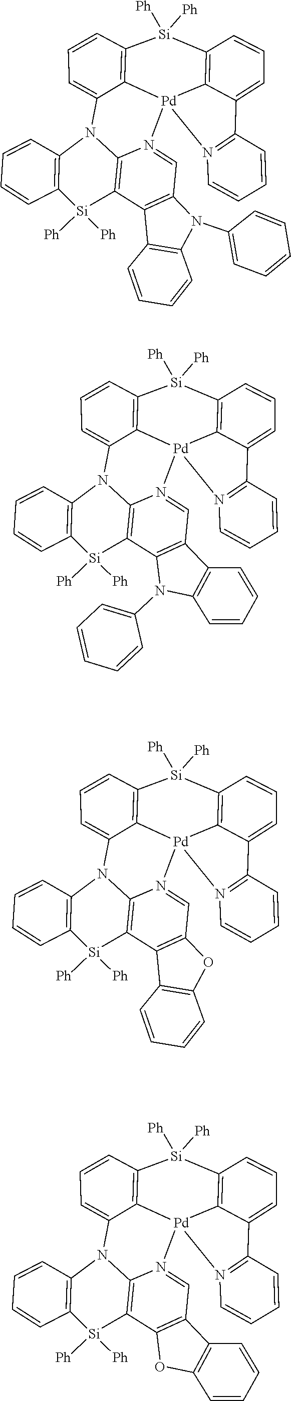

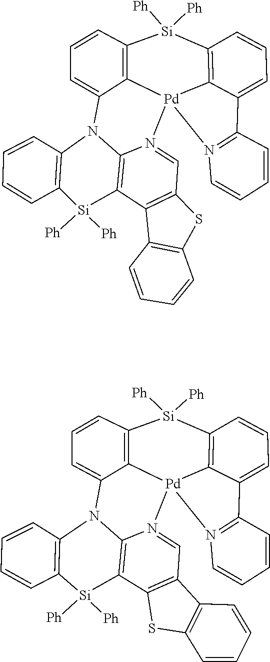

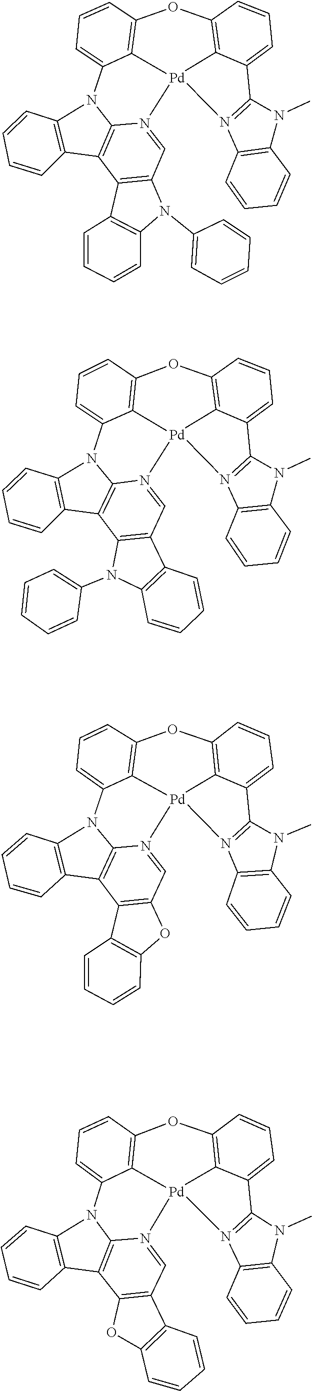

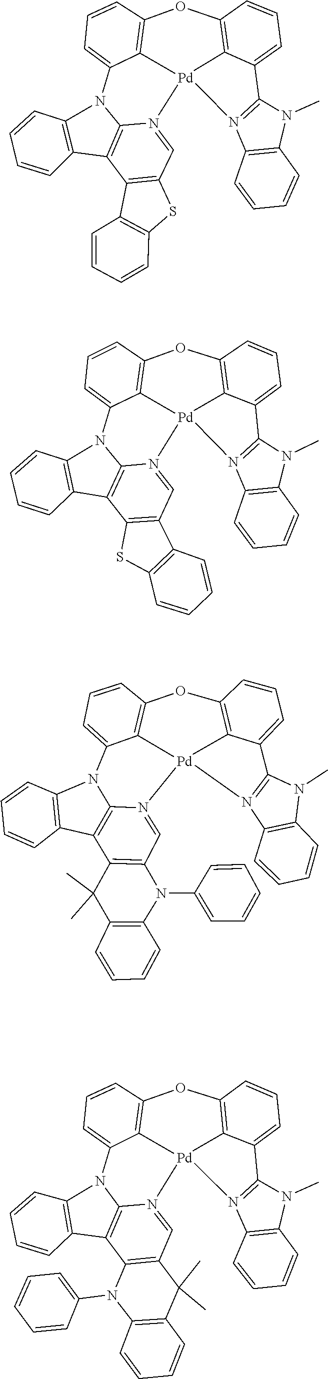

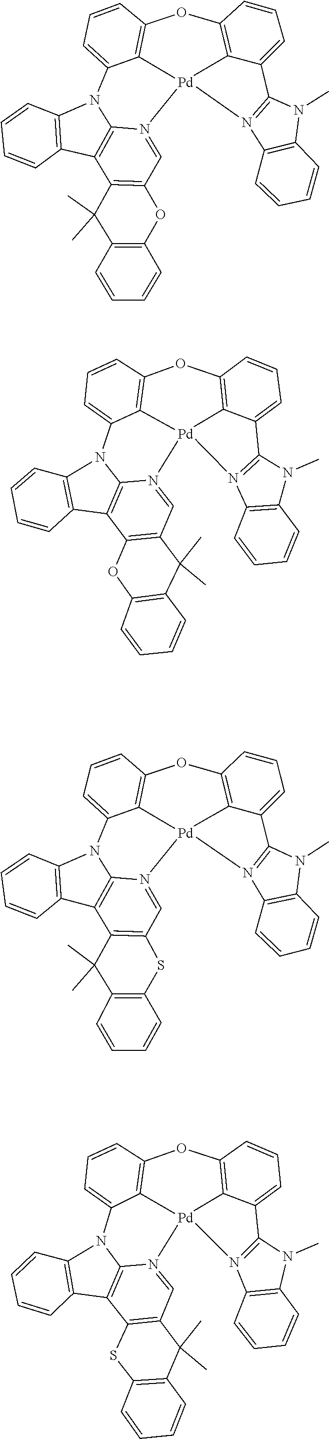

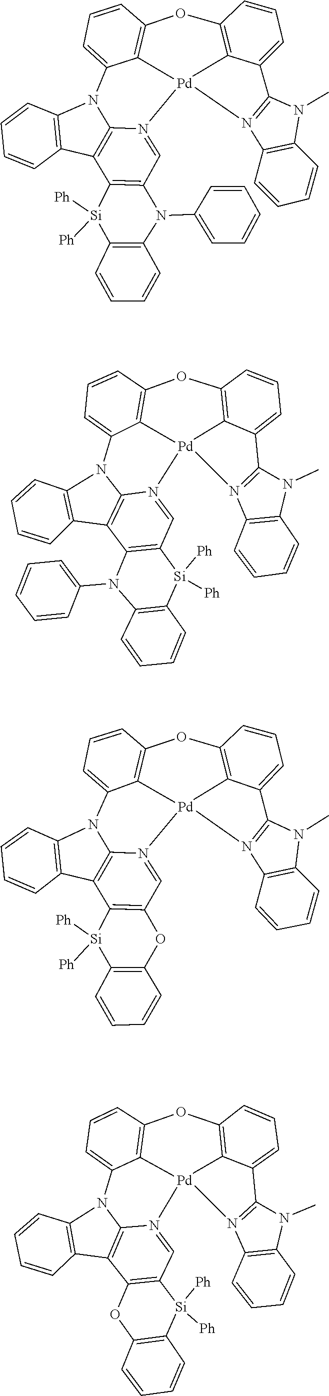

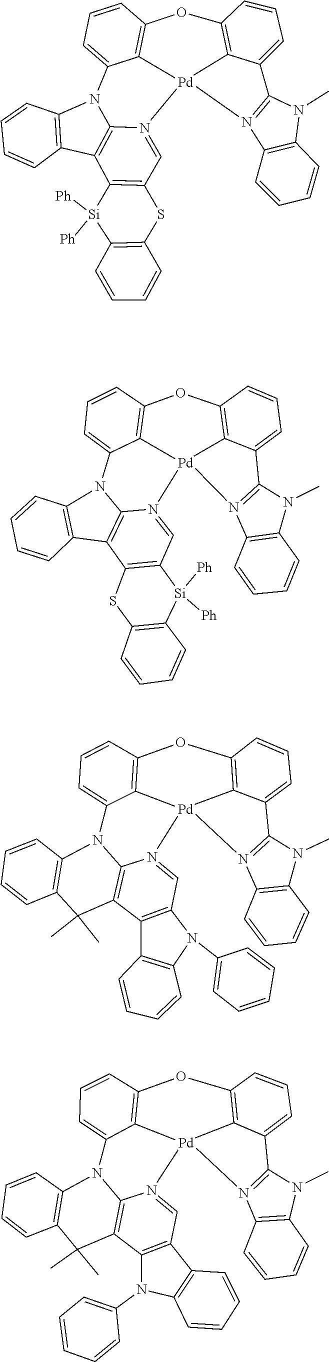

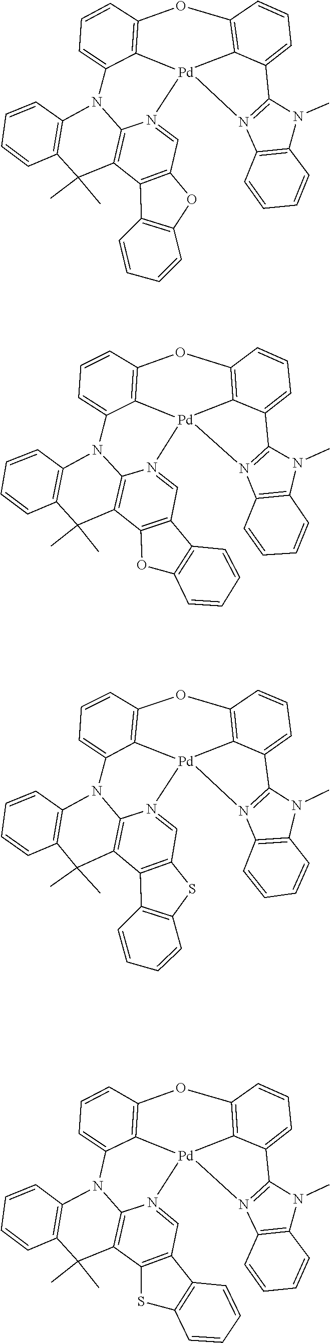

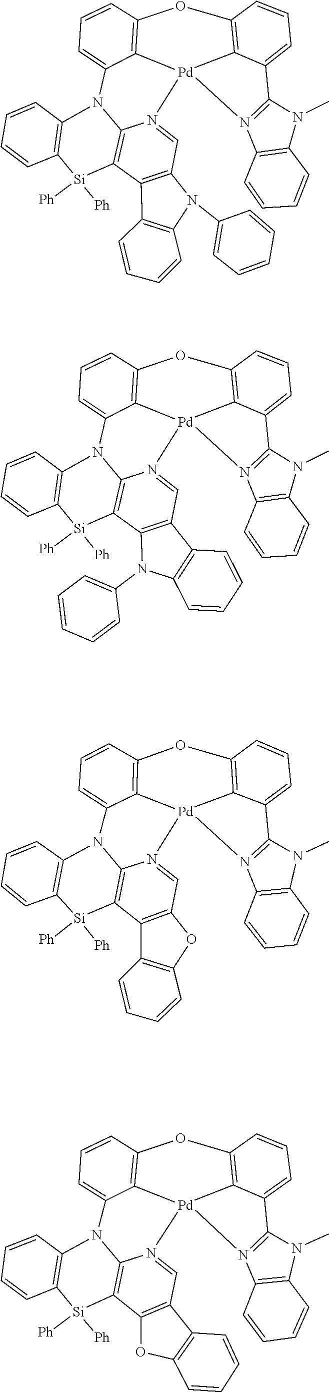

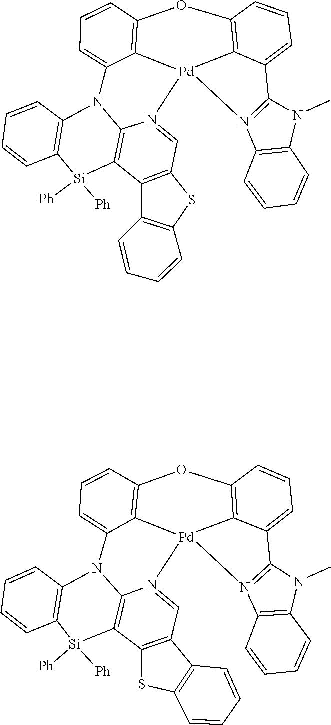

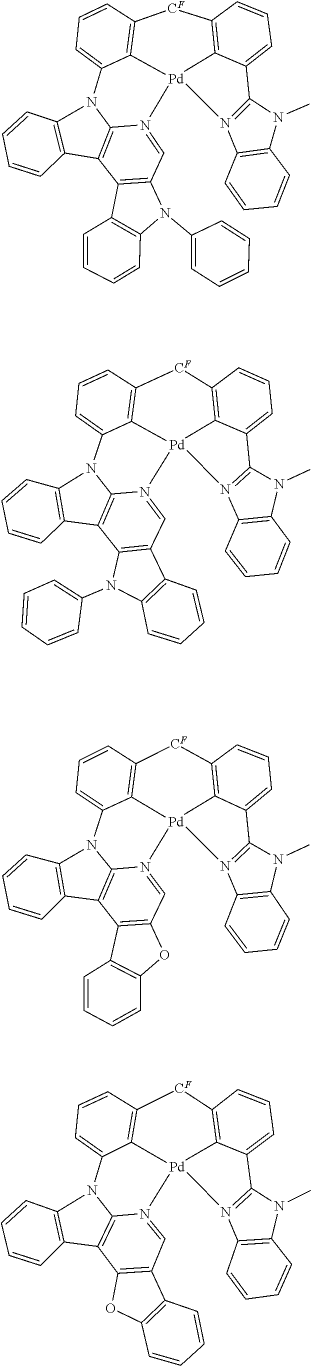

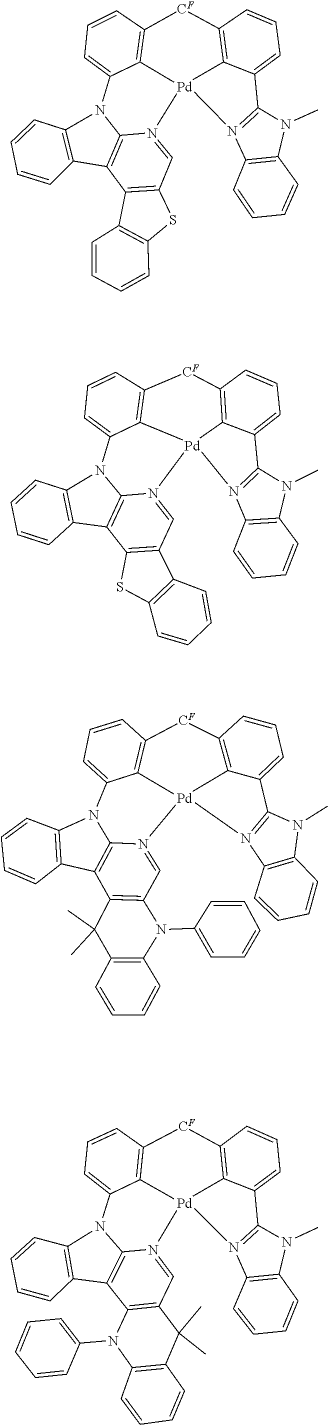

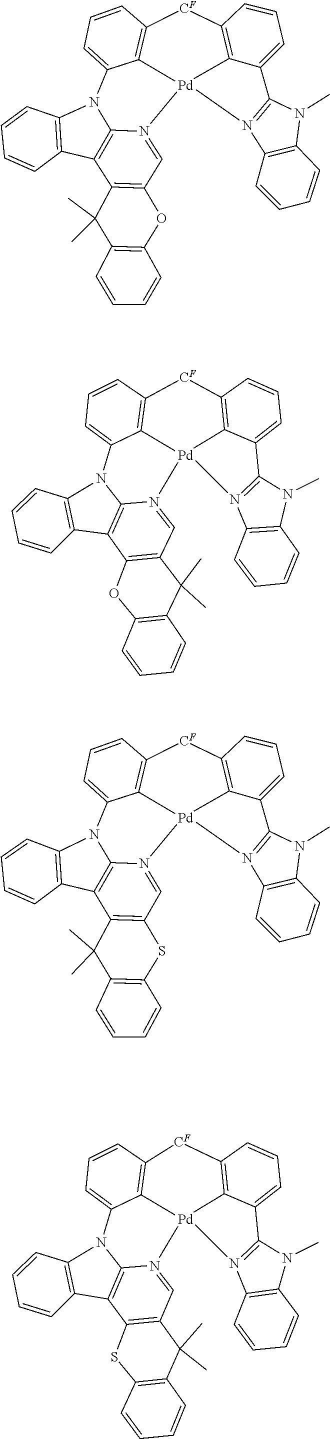

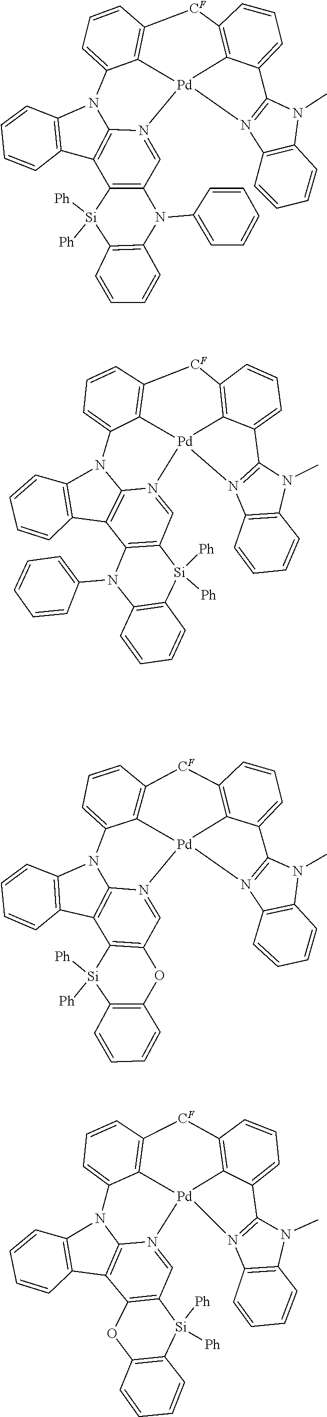

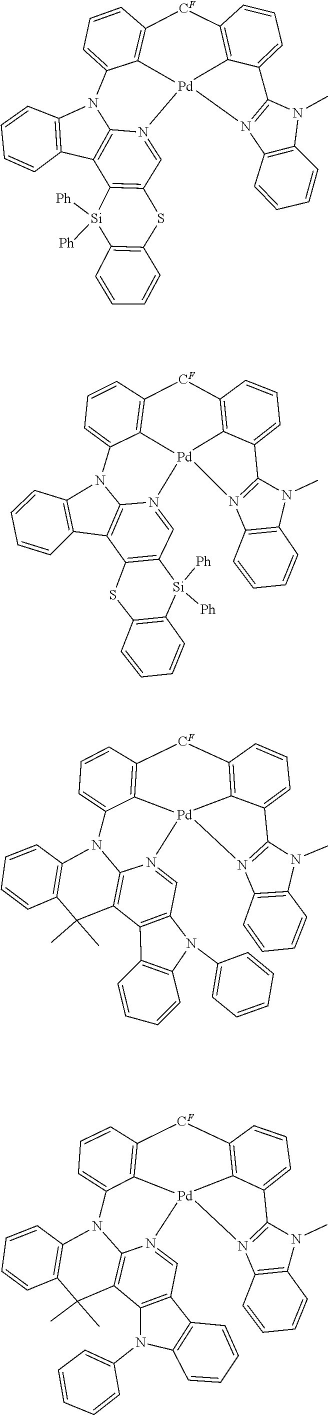

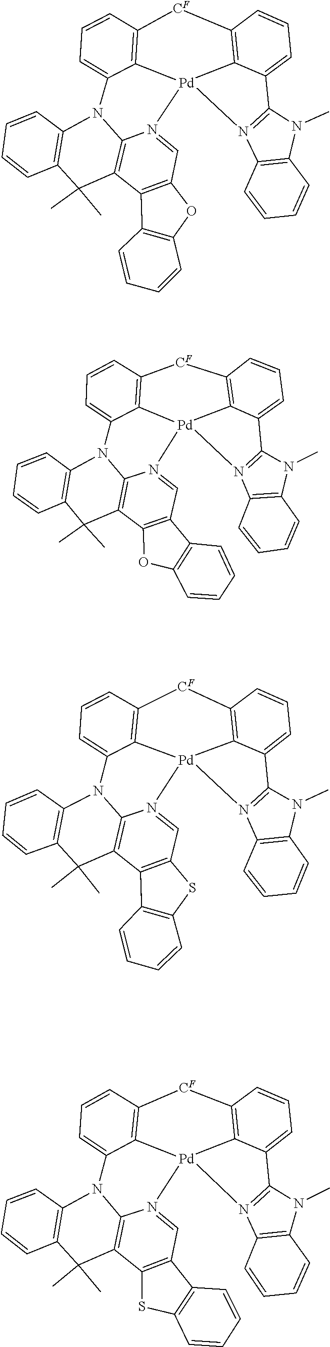

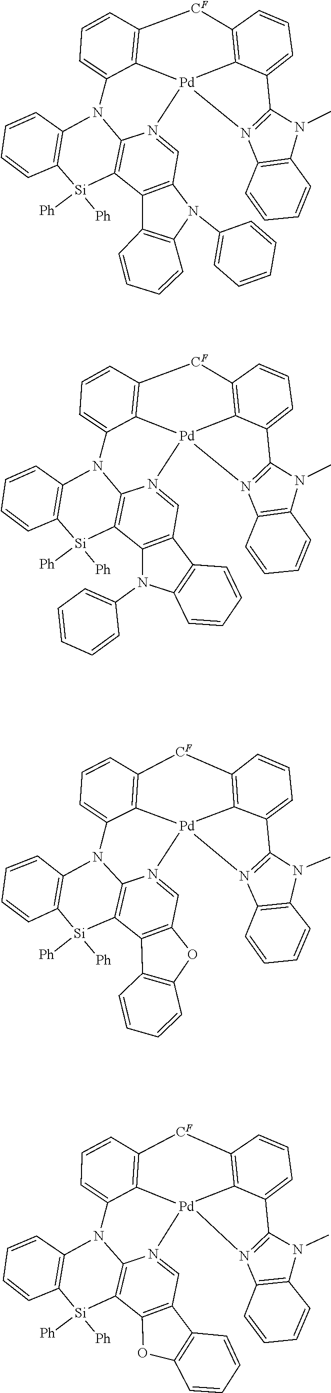

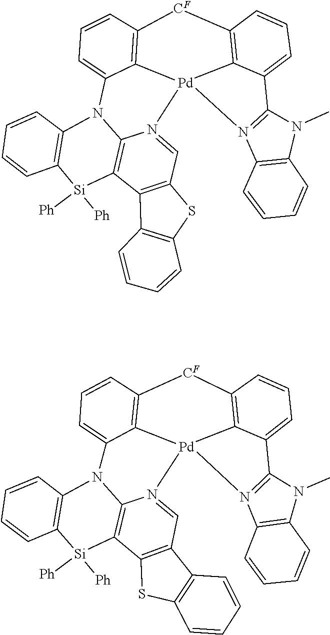

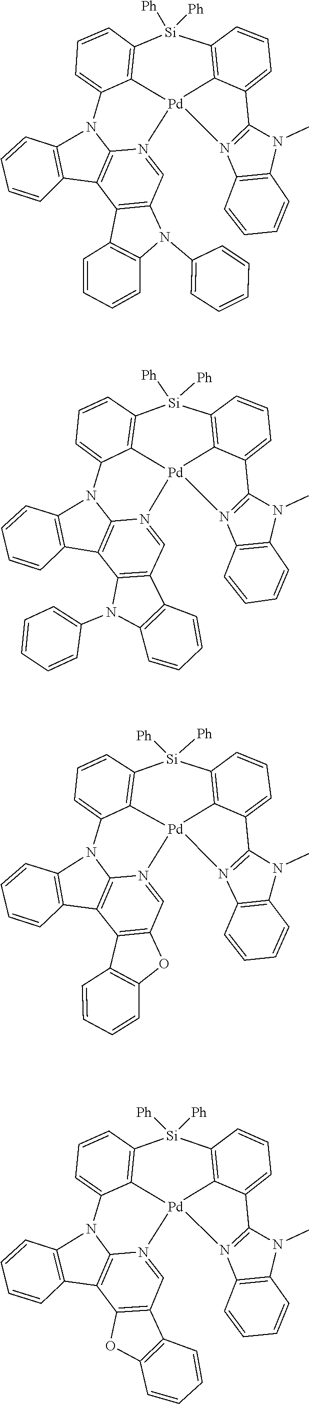

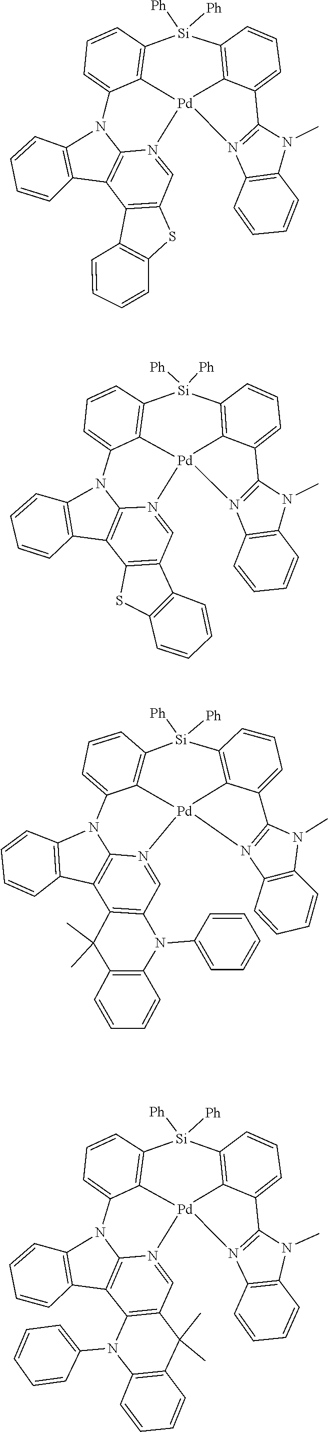

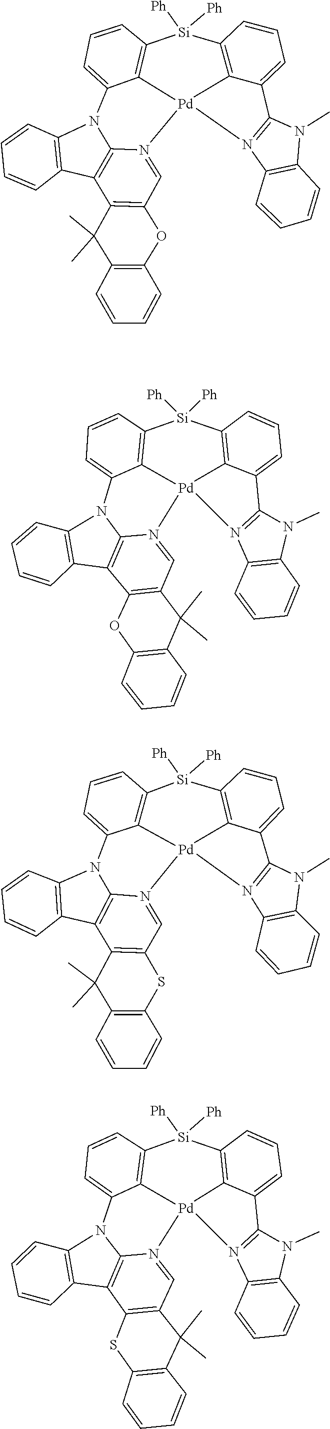

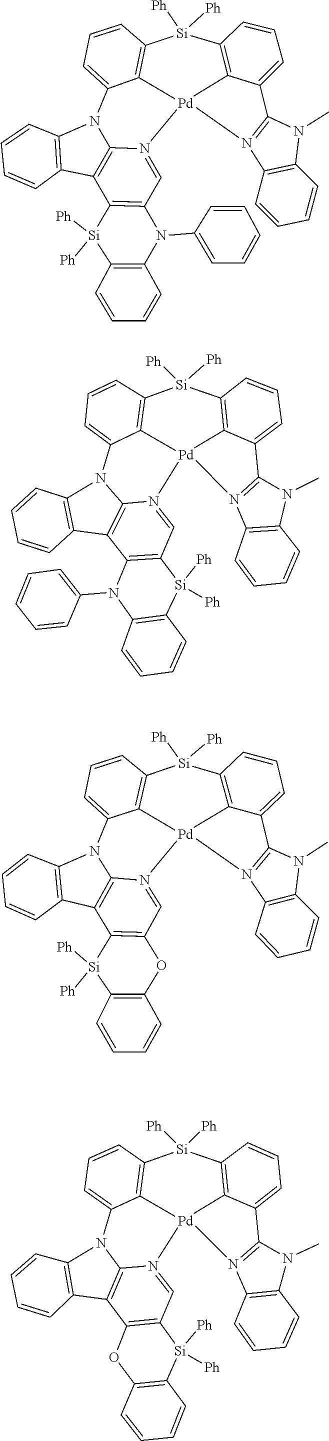

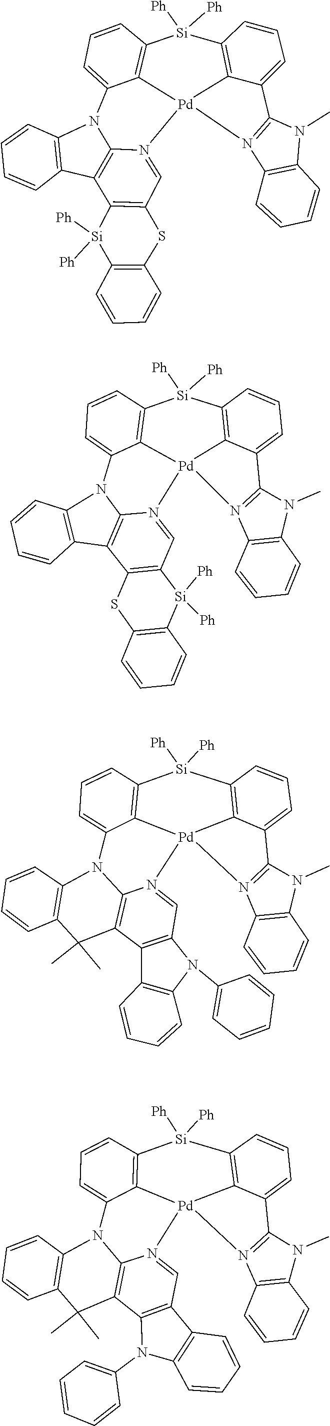

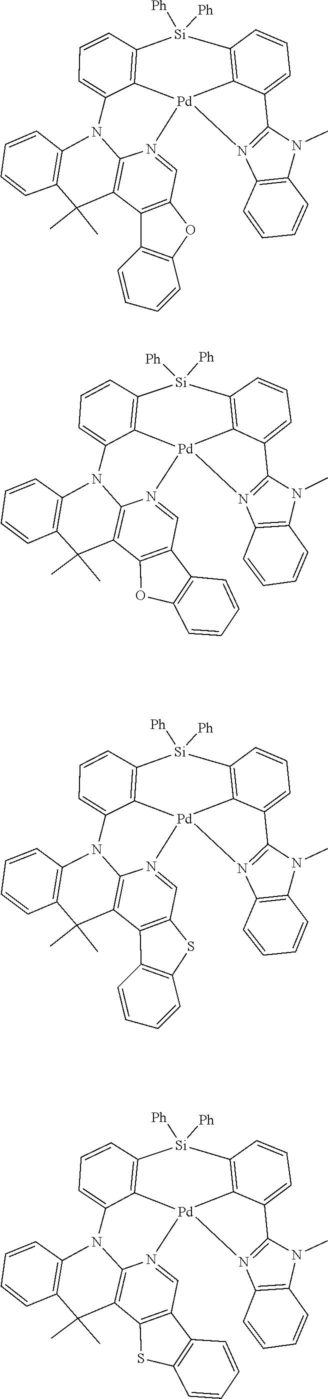

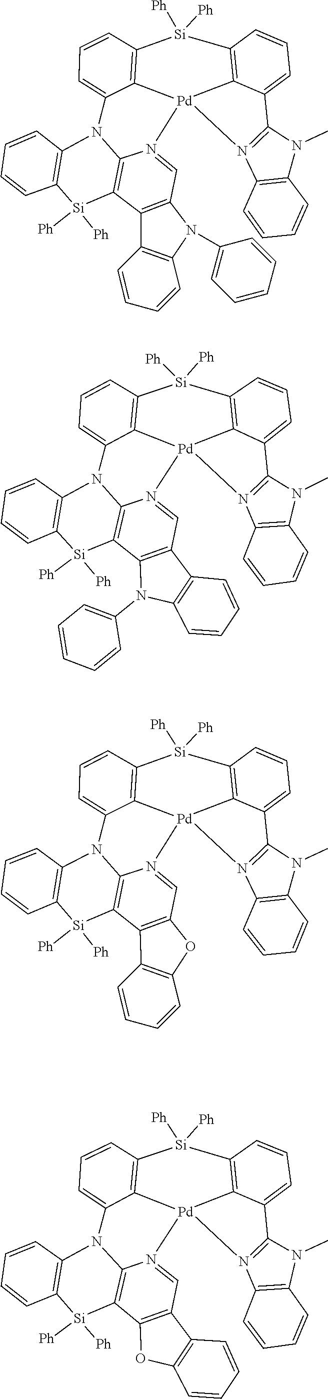

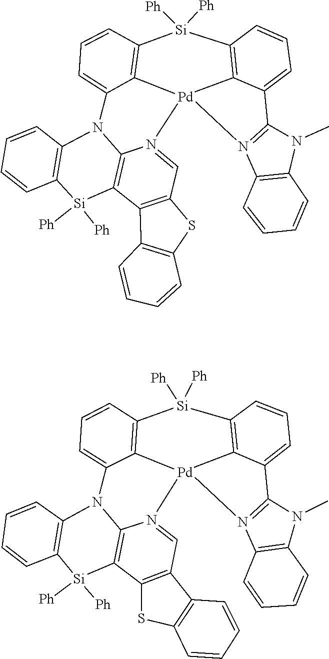

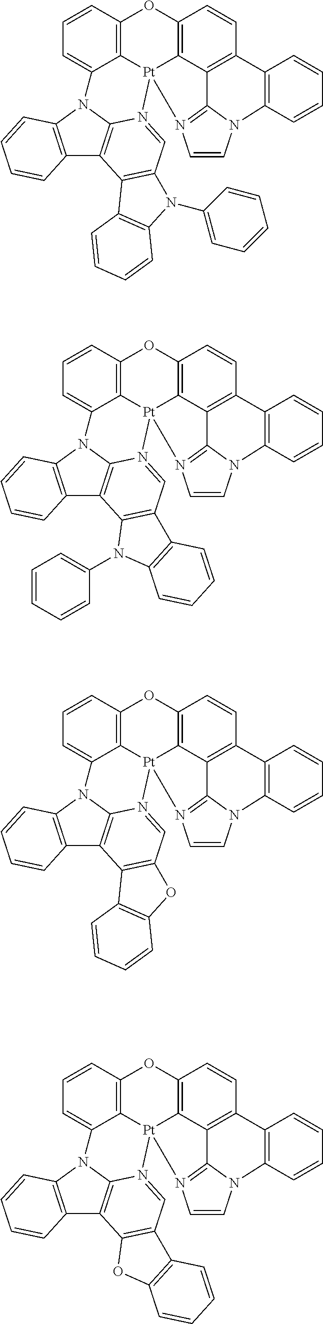

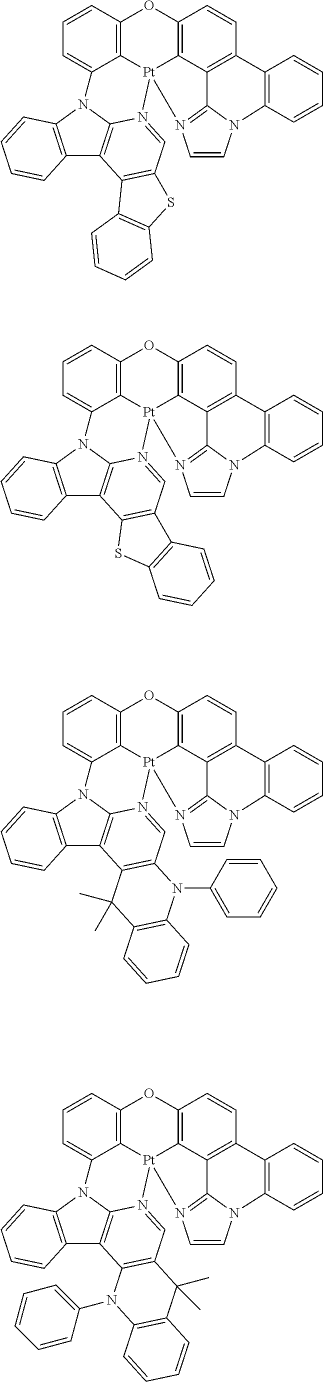

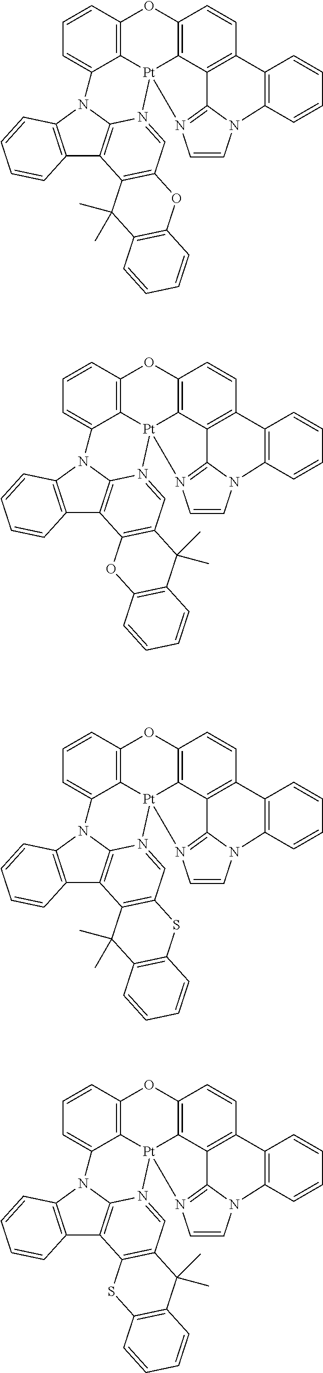

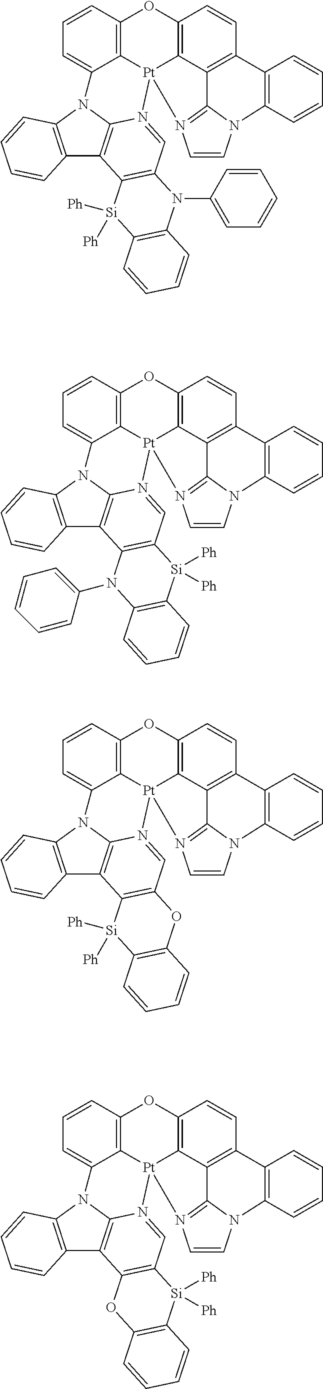

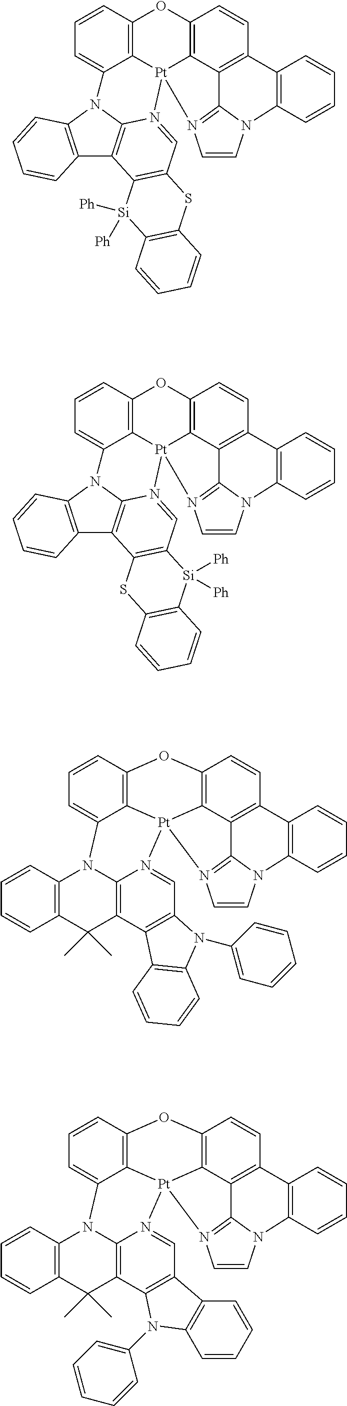

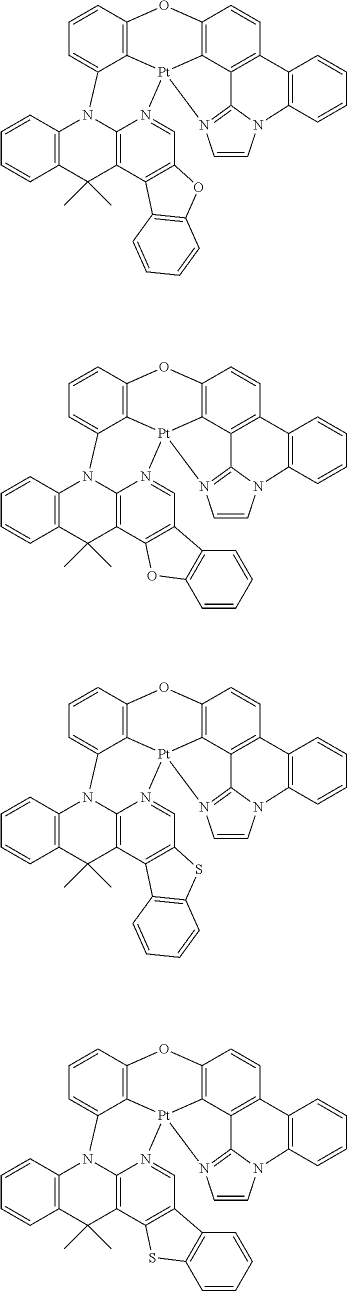

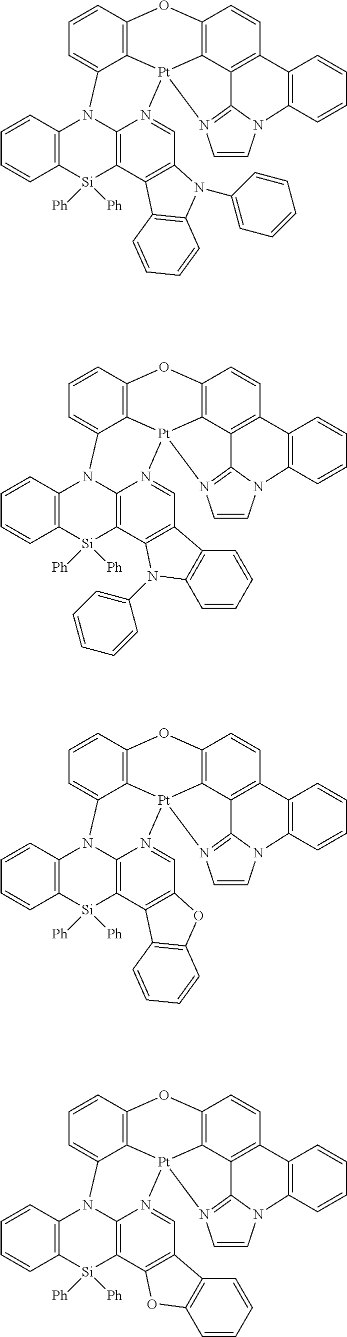

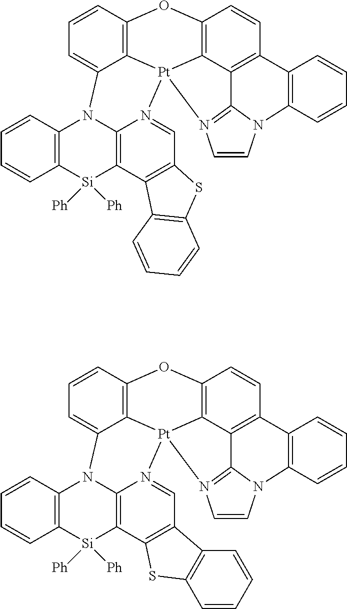

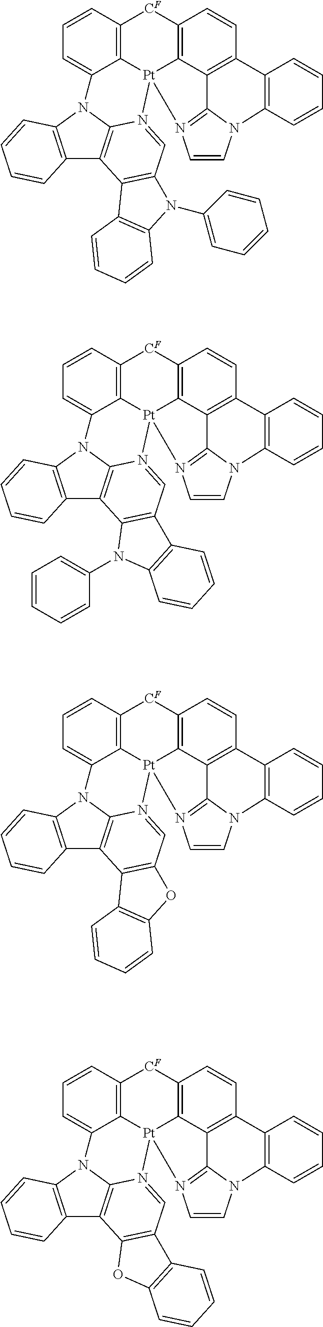

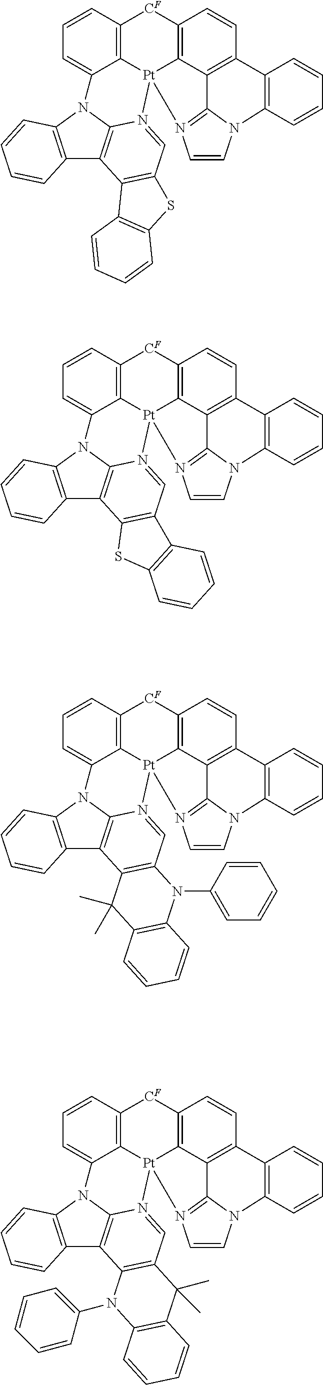

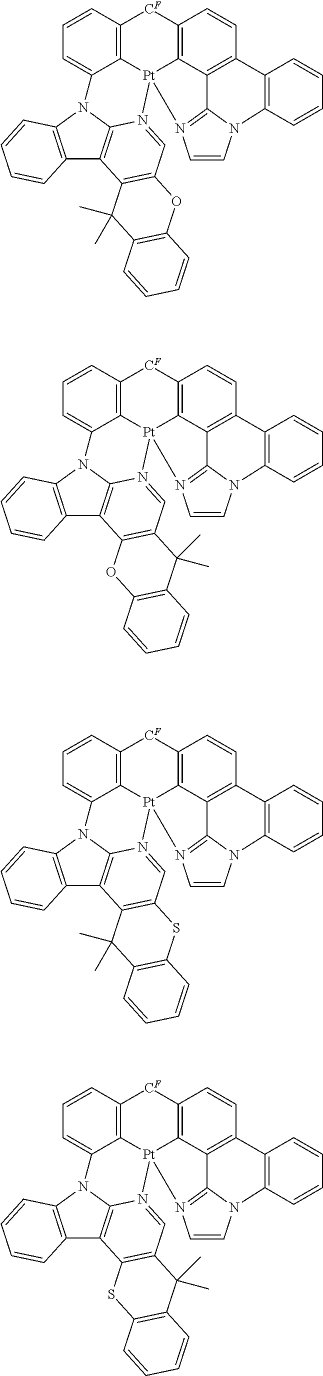

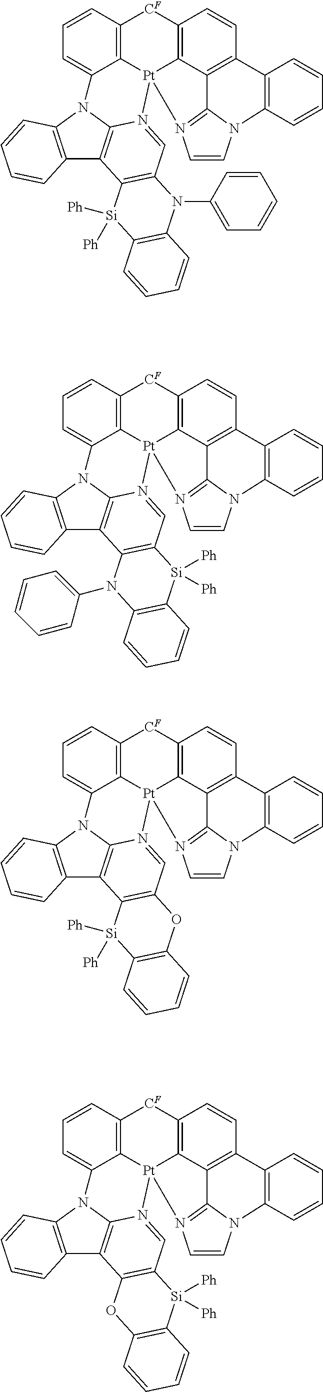

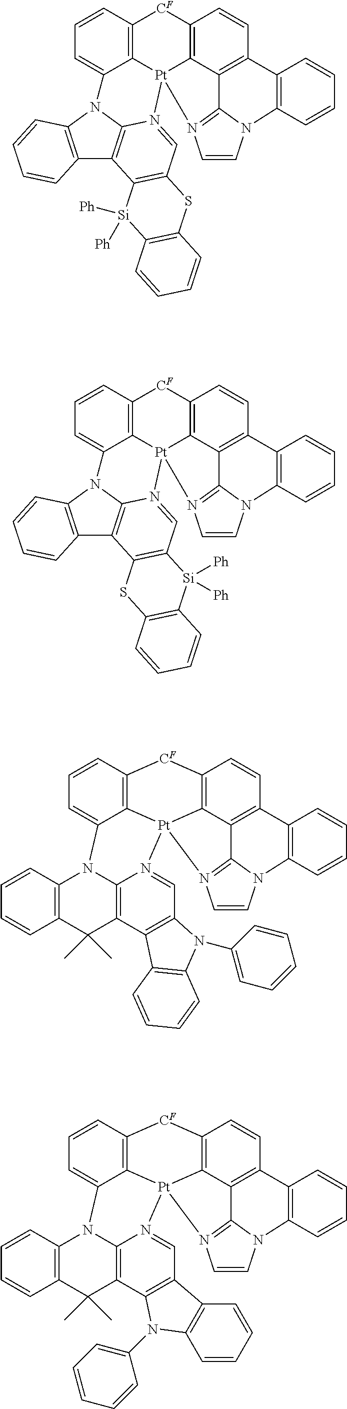

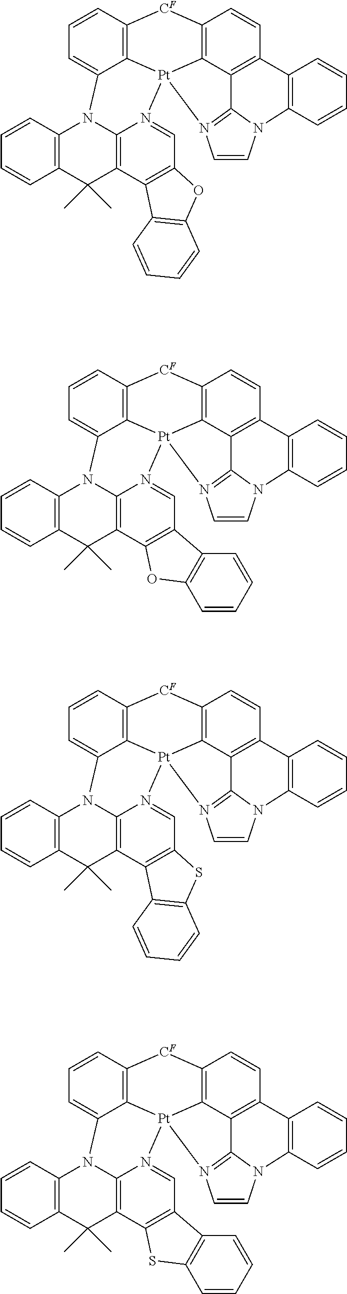

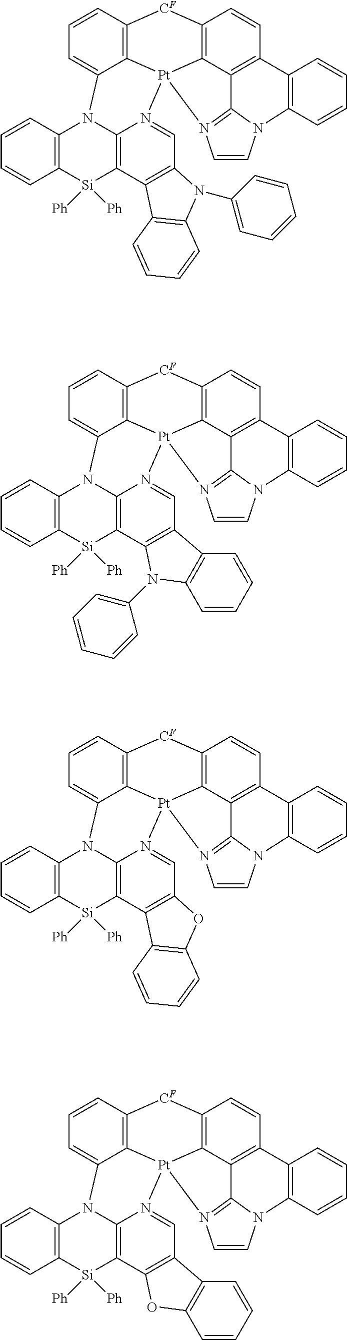

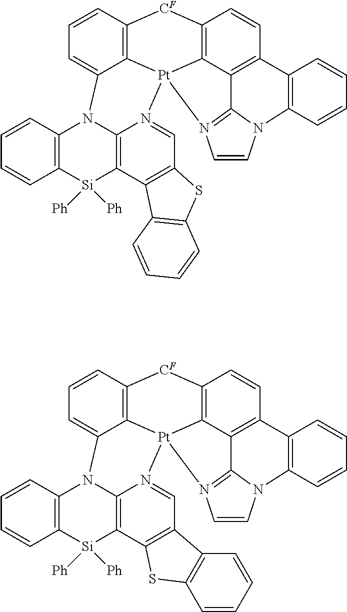

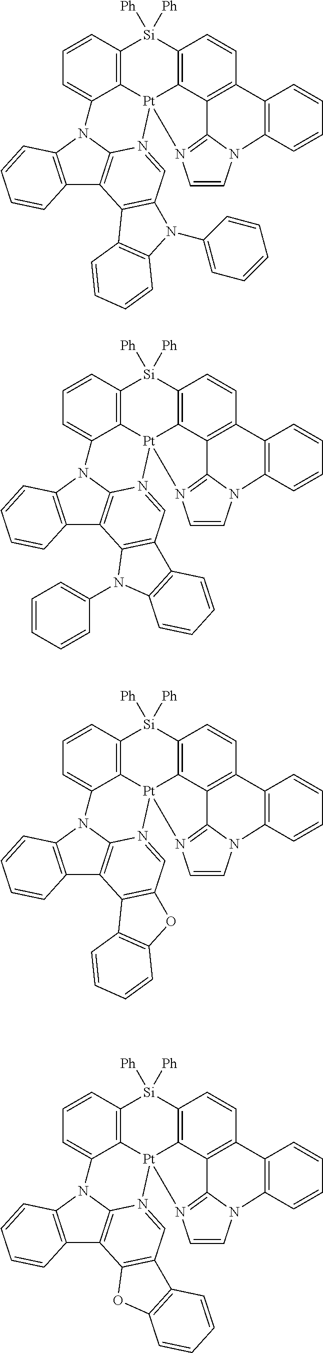

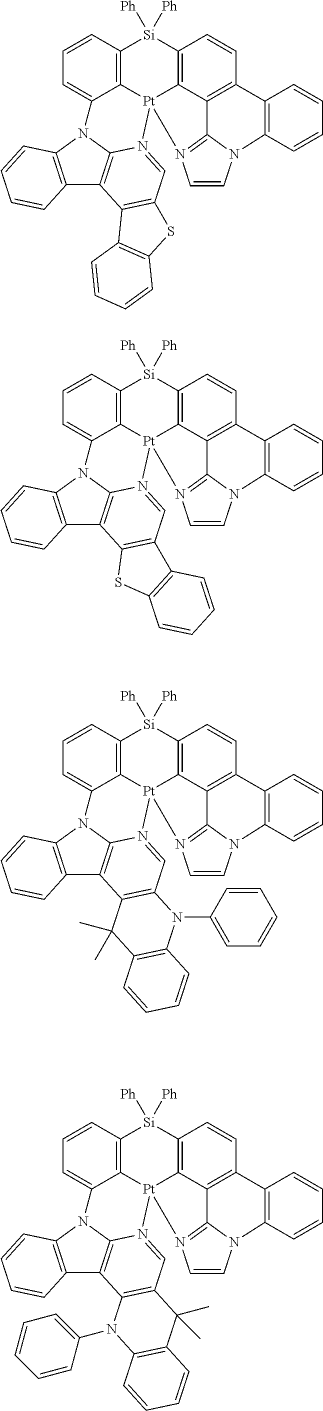

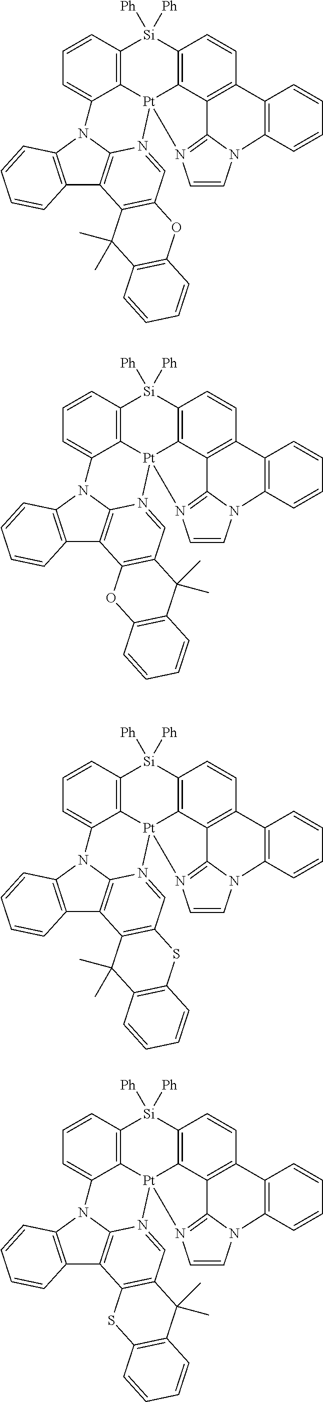

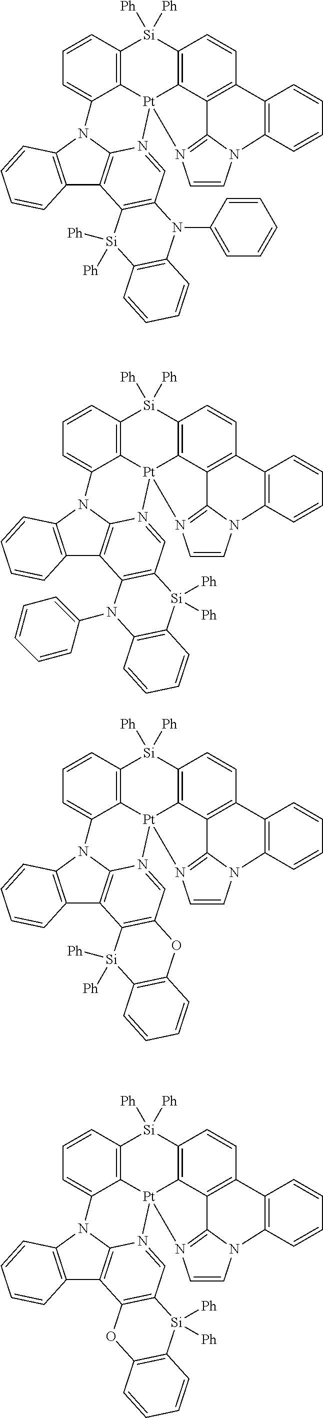

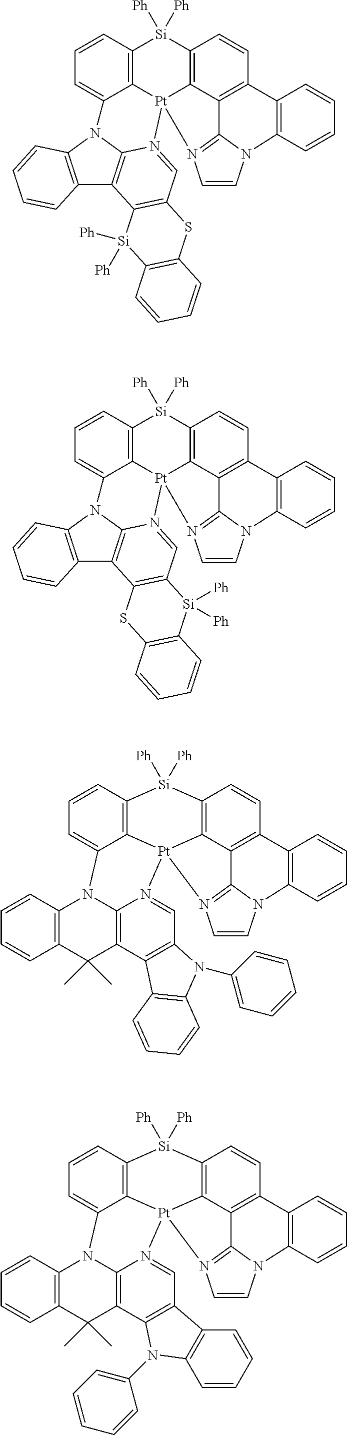

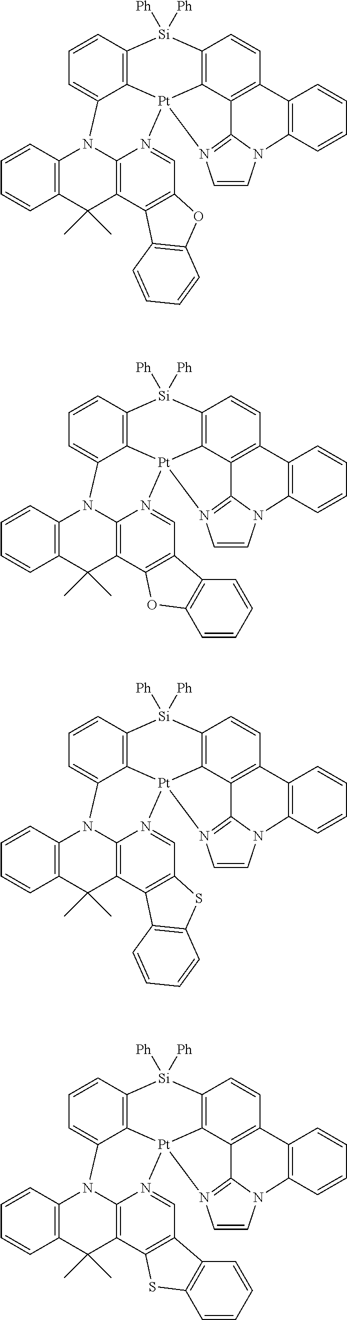

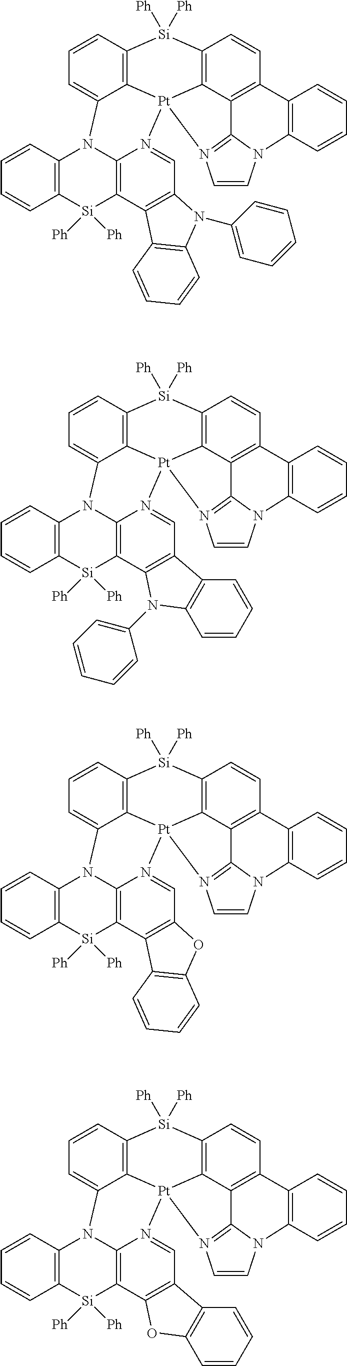

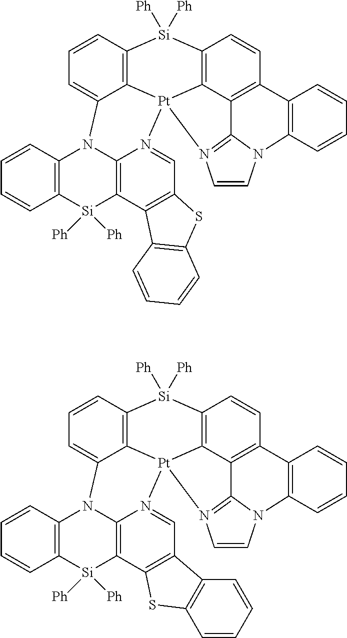

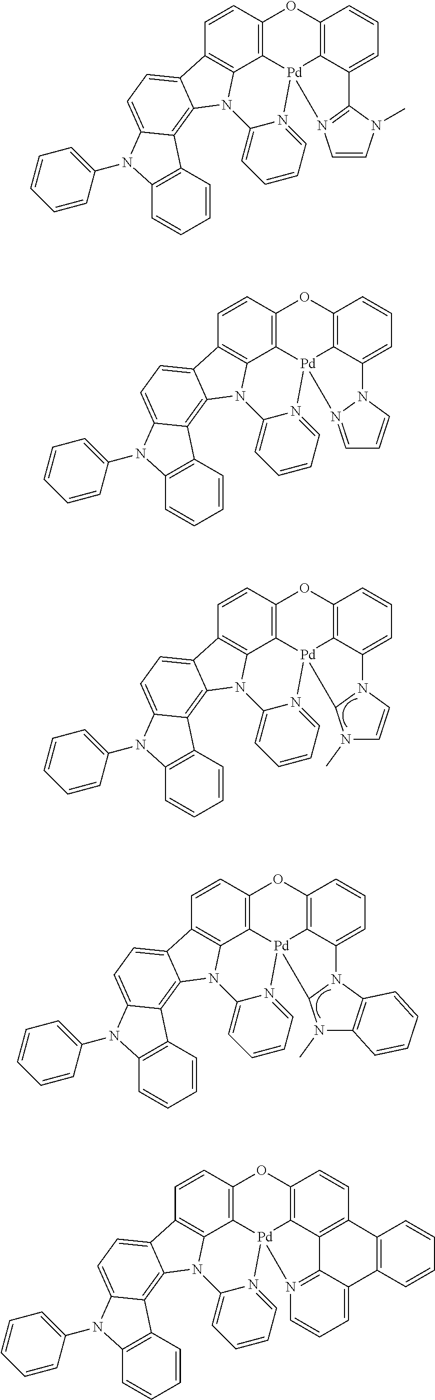

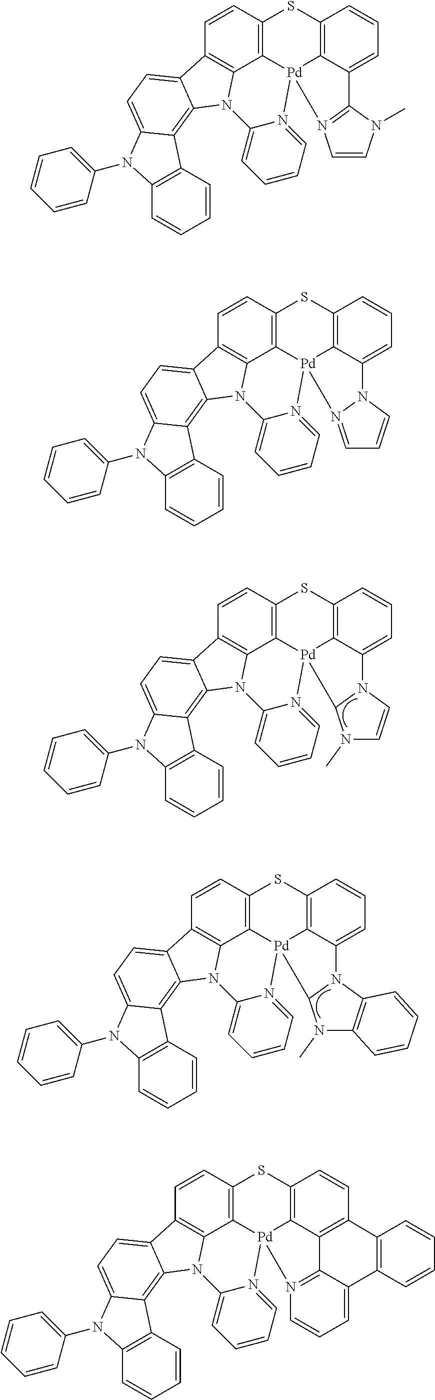

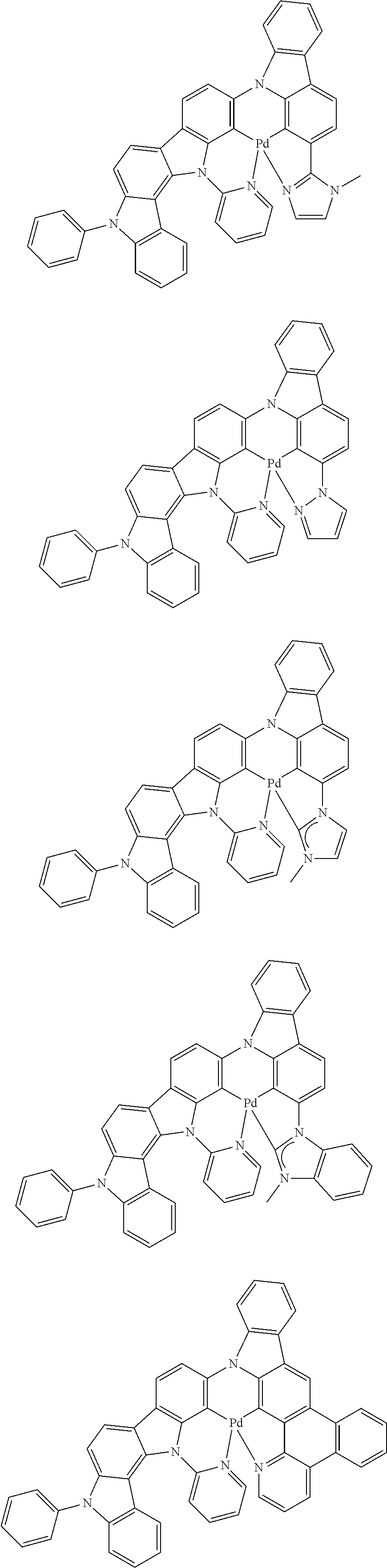

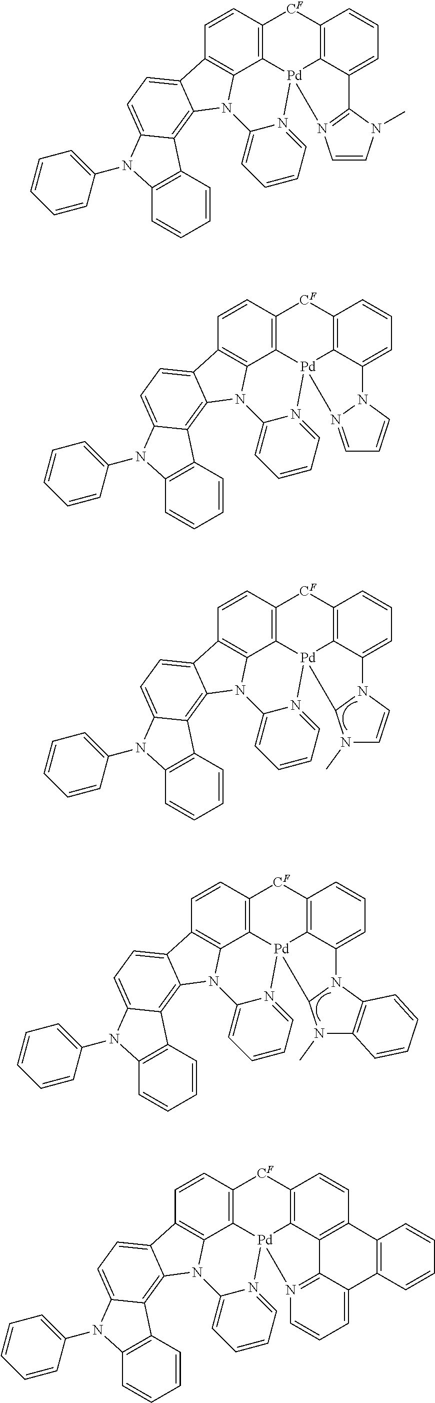

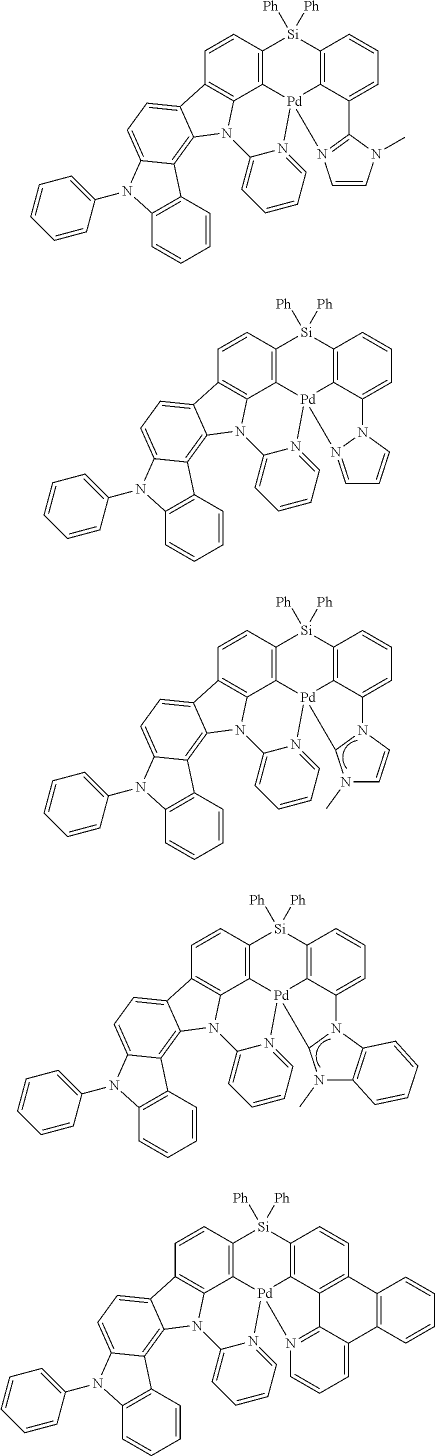

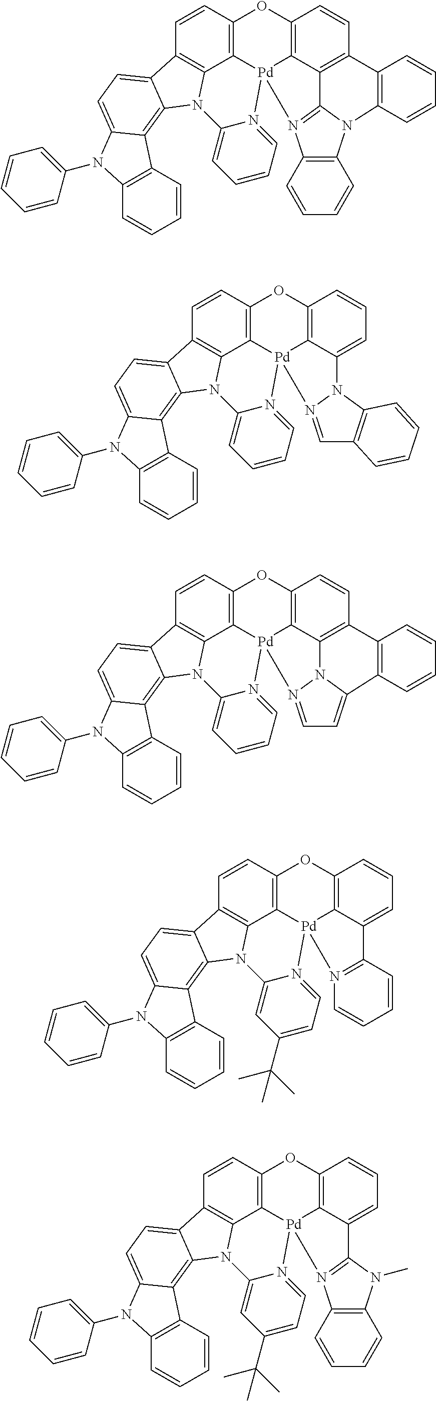

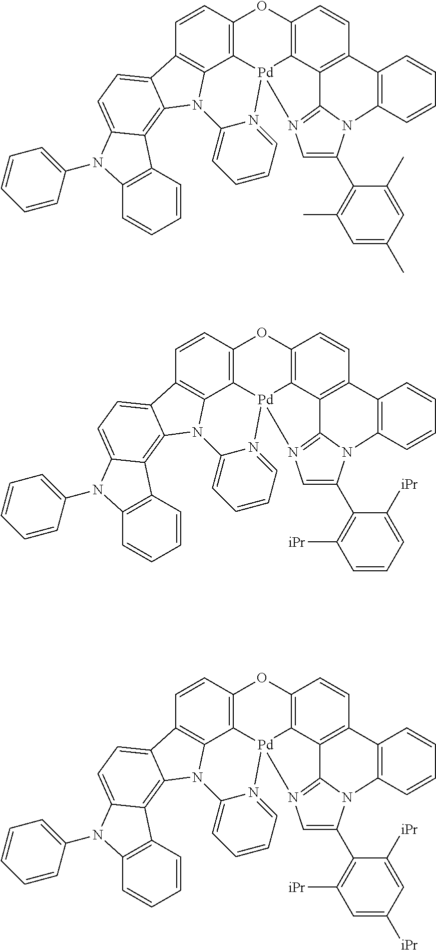

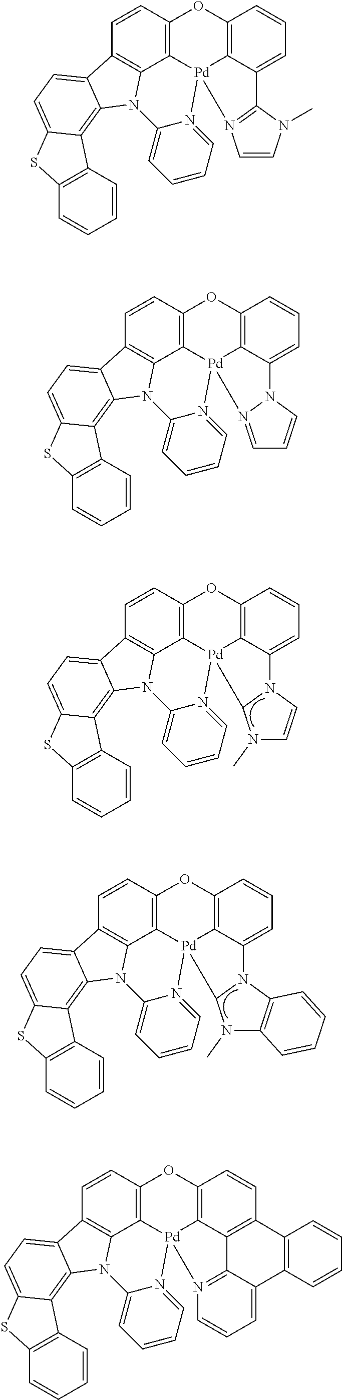

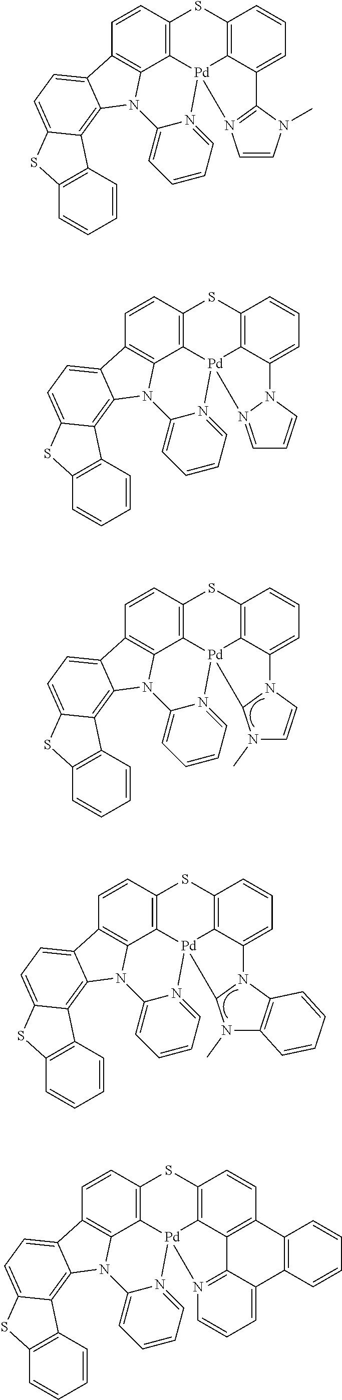

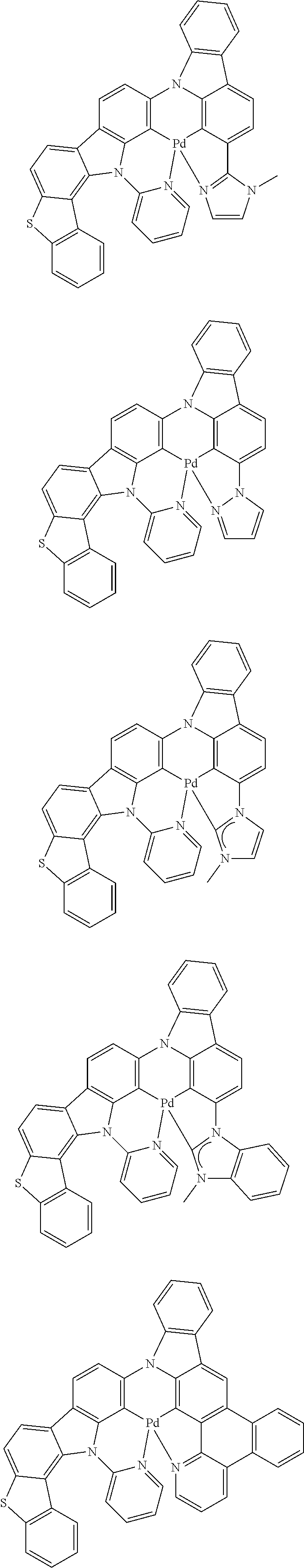

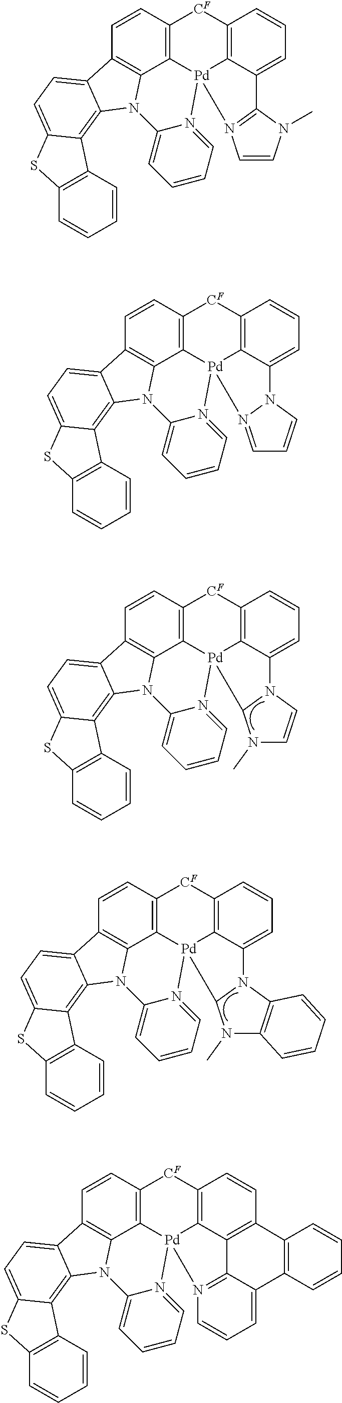

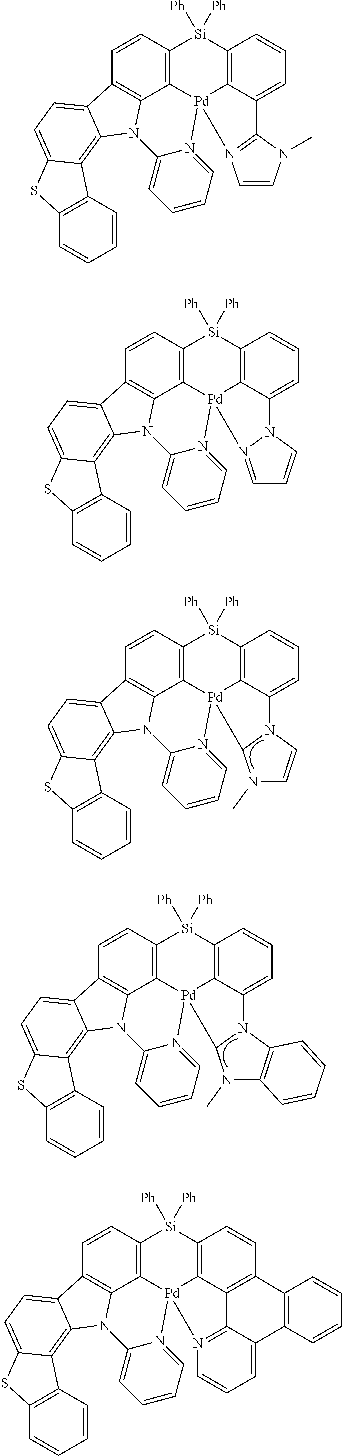

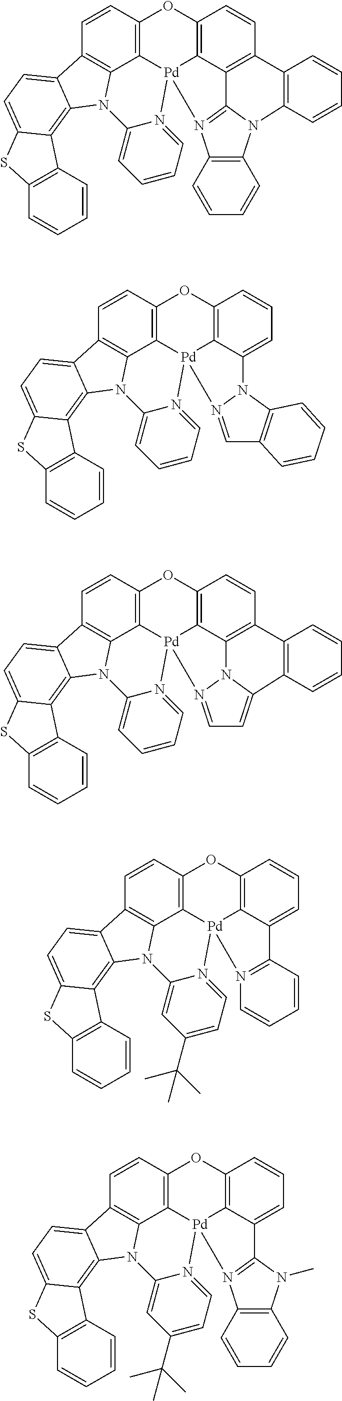

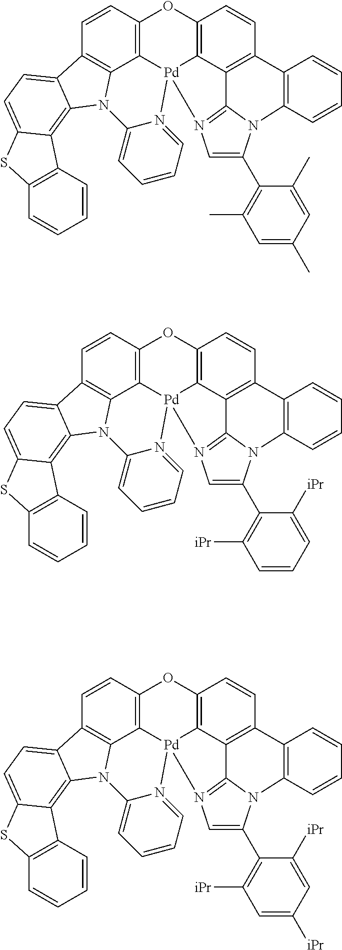

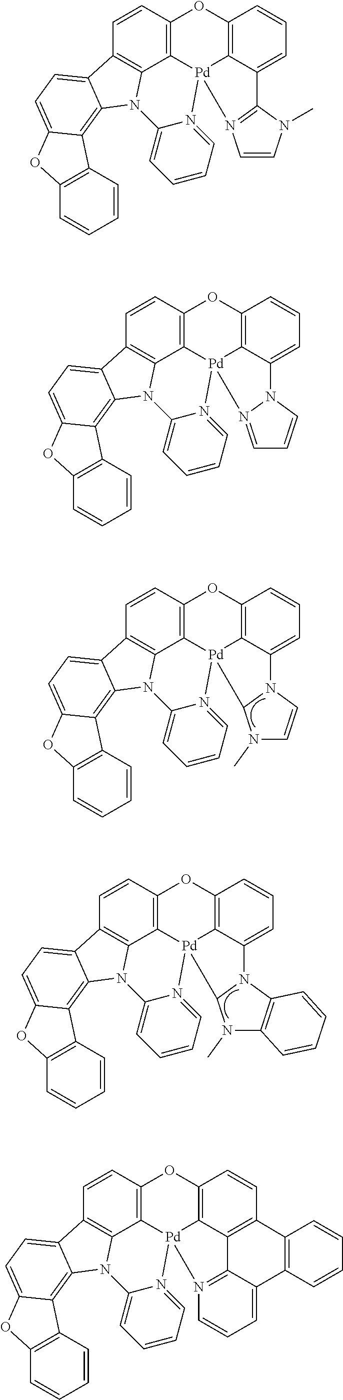

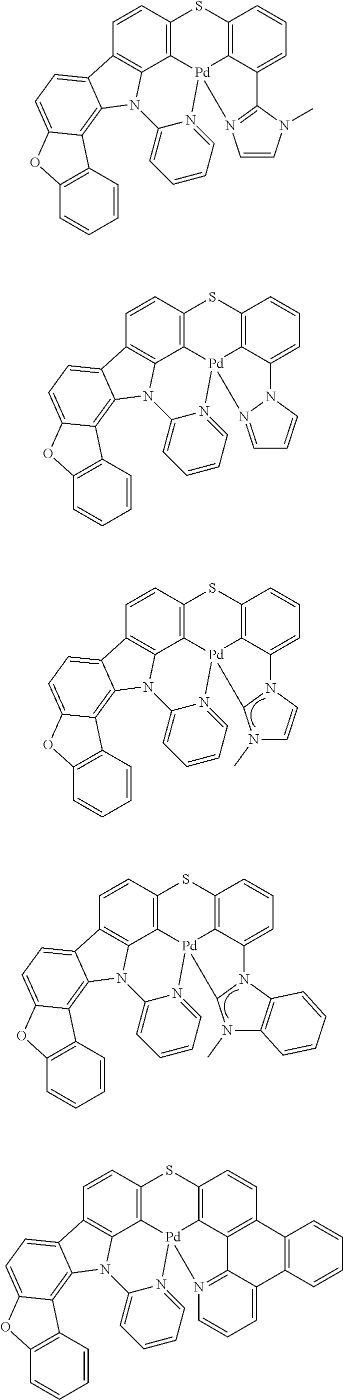

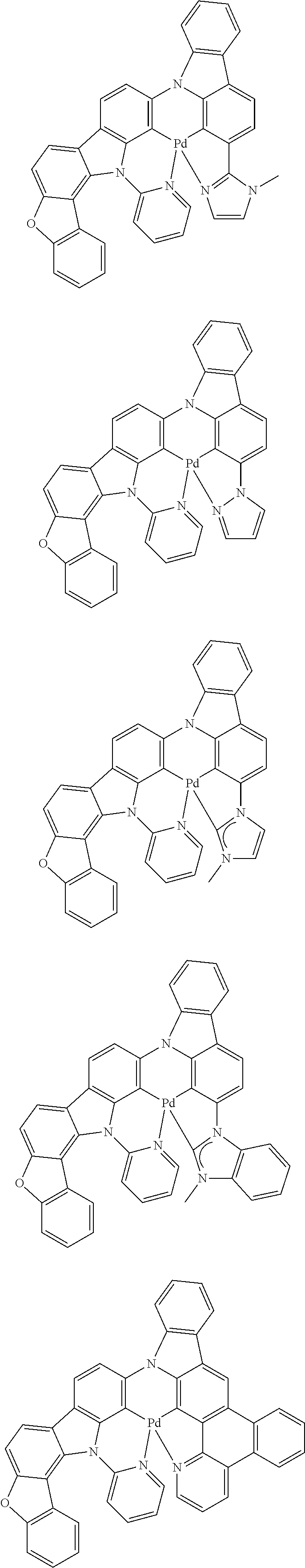

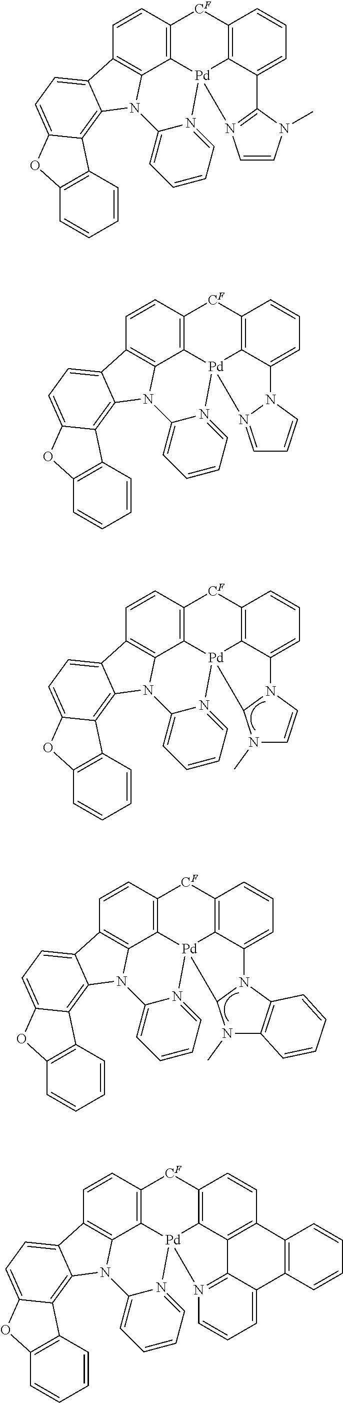

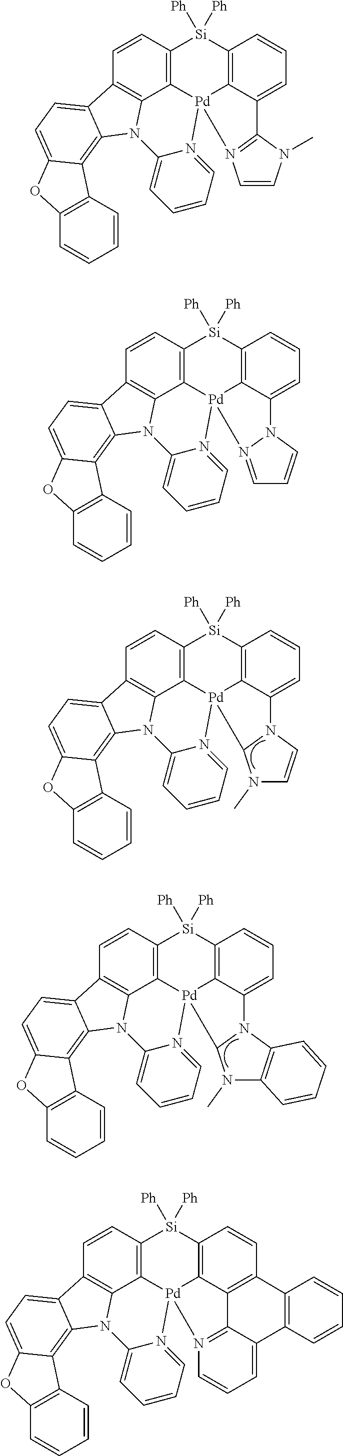

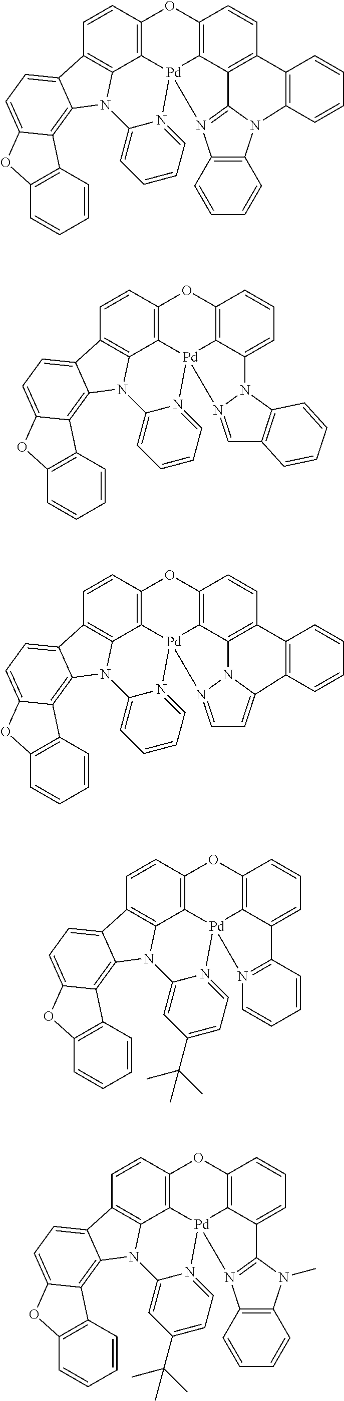

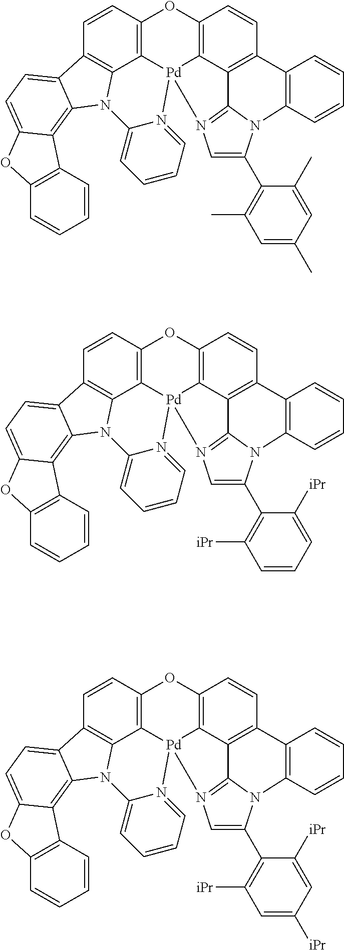

As referred to herein, a linking atom or group connects two atoms such as, for example, an N atom and a C atom. A linking atom or group is in one aspect disclosed as I, L², L³, etc. herein. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include amine, amide, thiol, aryl, heteroaryl, cycloalkyl, and heterocyclyl moieties. The term “cyclic structure” or the like terms used herein refer to any cyclic chemical structure which includes, but is not limited to, aryl, heteroaryl, cycloalkyl, cycloalkenyl, heterocyclyl, carbene, and N-heterocyclic carbene.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

In defining various terms, “A¹”, “A²”, “A³”, “A⁴” and “A⁵” are used herein as generic symbols to represent various specific substituents. These symbols can be any substituent, not limited to those disclosed herein, and when they are defined to be certain substituents in one instance, they can, in another instance, be defined as some other substituents.

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹-OA² or —OA¹-(OA²)ₐOA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “aldehyde” as used herein is represented by the formula —C(O)H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula OC(O)A¹ or C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula -(A¹O(O)C-A²-C(O)O)ₐ— or -(A¹O(O)C-A²-OC(O))ₐ—, where A¹ and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” or “halo” as used herein refers to the halogens fluorine, chlorine, bromine, and iodine.

The term “heterocyclyl,” as used herein refers to single and multi-cyclic non-aromatic ring systems and “heteroaryl as used herein refers to single and multi-cyclic aromatic ring systems: in which at least one of the ring members is other than carbon. The terms includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N₃.

The term “nitro” as used herein is represented by the formula —NO₂.

The term “cyanide” as used herein is represented by the formula —CN.

The term “silyl” as used herein is represented by the formula —SiA¹A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ can be hydrogen or an alkyl, cycloalkyl, alkenyl, cycloalkenyl, alkynyl, cycloalkynyl, aryl, or heteroaryl group as described herein.

Throughout this specification “S(O)” is a short hand notation for S═O. The term “sulfonyl” is used herein to refer to the sulfo-oxo group represented by the formula —S(O)₂A¹, where A¹ can be hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula SH.

“R,” “R¹,” “R²,” “R³,” “Rⁿ,” where n is an integer, as used herein can, independently, possess one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

Compounds described herein may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. In is also contemplated that, in certain aspects, unless expressly indicated to the contrary, individual substituents can be further optionally substituted (i.e., further substituted or unsubstituted).

In some aspects, a structure of a compound can be represented by a formula:

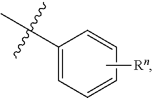

which is understood to be equivalent to a formula:

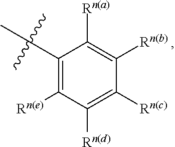

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

The complexes disclosed herein are suited for use in a wide variety of devices, including, for example, organic light emitting diodes (OLEDs) for full color displays and lighting applications.

Also disclosed herein are compositions including one or more complexes disclosed herein. The present disclosure provides light emitting devices that include one or more compositions described herein. The present disclosure also provides a photovoltaic device comprising one or more complexes or compositions described herein. Further, the present disclosure also provides a luminescent display device comprising one or more complexes described herein.

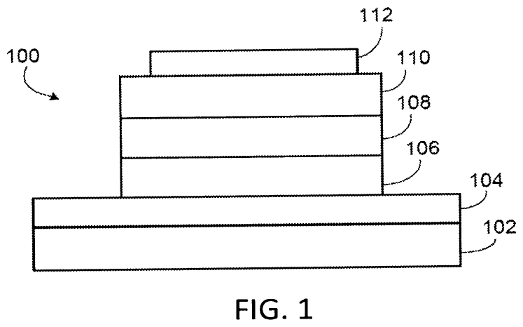

Complexes described herein can be used in a light emitting device such as an OLED. FIG. 1 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more complexes of the present disclosure optionally together with a host material. The host material can be any suitable host material known in the art. The emission color of an OLED is determined by the emission energy (optical energy gap) of the light processing material 108, which can be tuned by tuning the electronic structure of the emitting complexes, the host material, or both. Both the hole-transporting material in the HTL layer 106 and the electron-transporting material(s) in the ETL layer 110 may include any suitable hole-transporter known in the art.

### EXAMPLES

The following examples are put forth so as to provide those of ordinary skill in the art with a complete disclosure and description of how the complexes, compositions, articles, devices and/or methods claimed herein are made and evaluated, and are intended to be purely exemplary and are not intended to be limiting in scope. Some of these synthetic examples have been performed. Others are based on an understanding of related synthetic procedures and are predictive in nature. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

Various methods for the preparation method of the complexes described herein are recited in the examples. These methods are provided to illustrate various methods of preparation, but are not intended to limit any of the methods recited herein. Accordingly, one of skill in the art in possession of this disclosure could readily modify a recited method or utilize a different method to prepare one or more of the complexes described herein. The following aspects are only exemplary and are not intended to be limiting in scope. Temperatures, catalysts, concentrations, reactant compositions, and other process conditions can vary, and one of skill in the art, in possession of this disclosure, could readily select appropriate reactants and conditions for a desired complex.

### Example 1

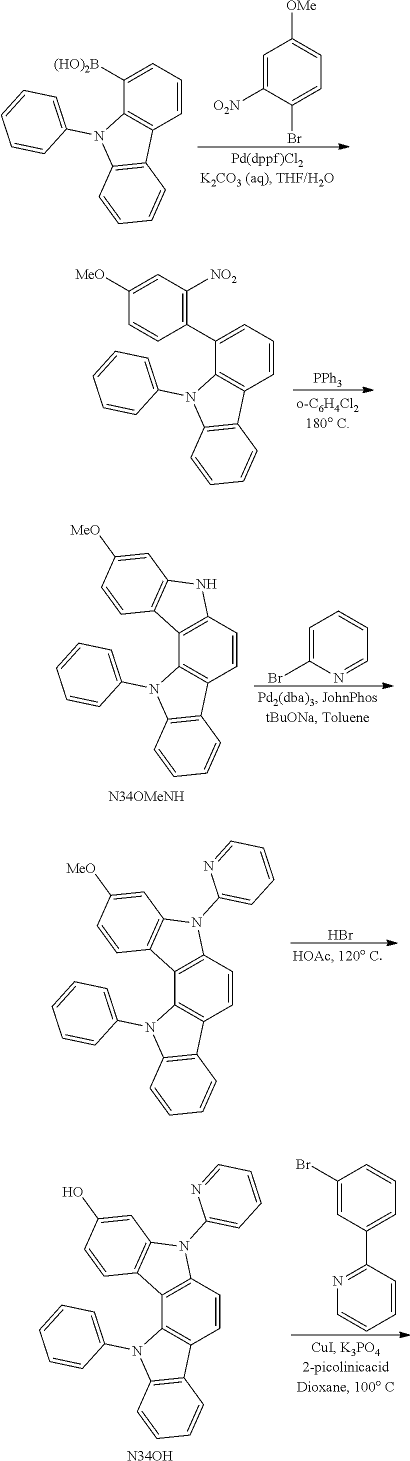

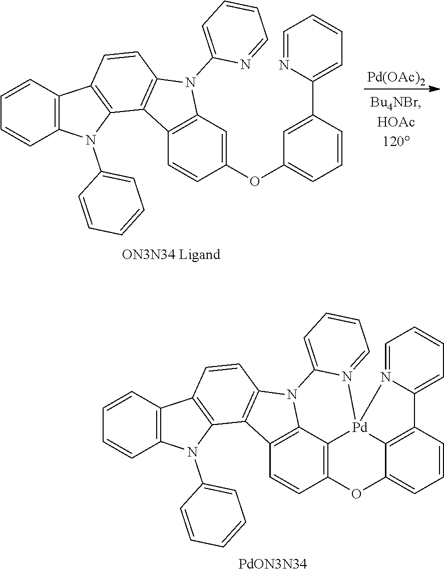

### Synthesis of ON3N34 Ligand

To a solution of 2-(3-bromophenyl)pyridine (1.5 eq) in dioxane (0.1 M) were added N340H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 76% yield.

### Synthesis of PdON3N34

To a solution of ON3N34 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N34 in 65% yield.

### Example 2

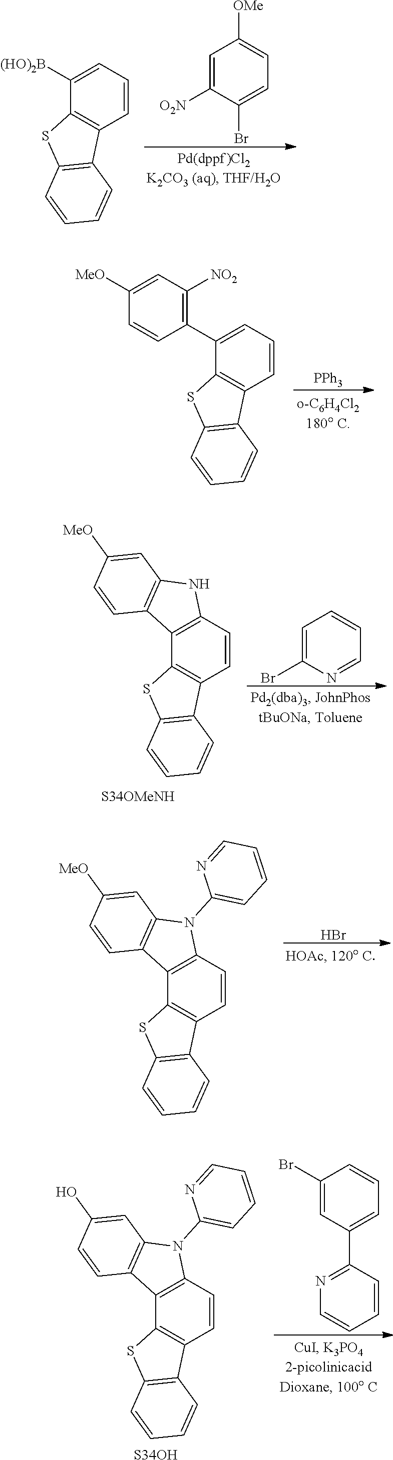

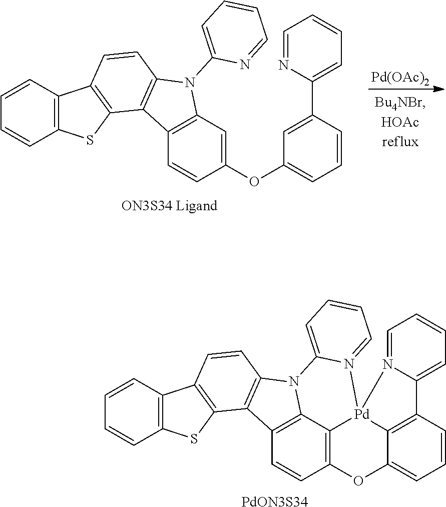

### Synthesis of ON3S34 Ligand

To a solution of 2-(3-bromophenyl)pyridine (1.5 eq) in dioxane (0.1 M) were added S340H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 84% yield.

### Synthesis of PdON3S34

To a solution of ON3S34 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S34 in 72% yield.

### Example 3

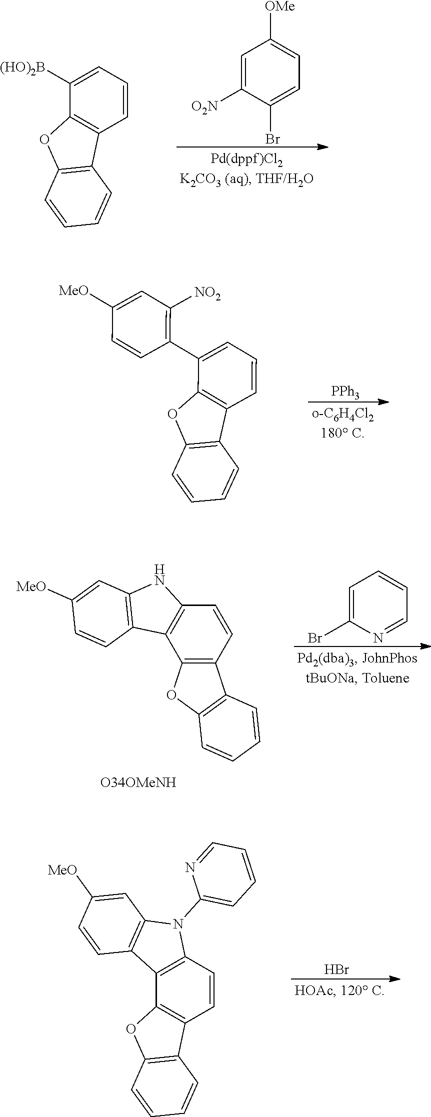

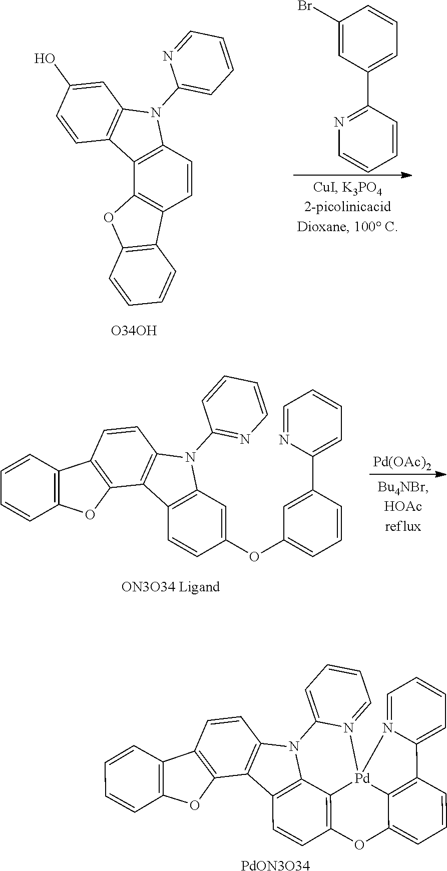

### Synthesis of ON3034 Ligand

To a solution of 2-(3-bromophenyl)pyridine (1.5 eq) in dioxane (0.1 M) were added 0340H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 77% yield.

### Synthesis of PdON3O34

To a solution of ON3034 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3O34 in 65% yield.

### Example 4

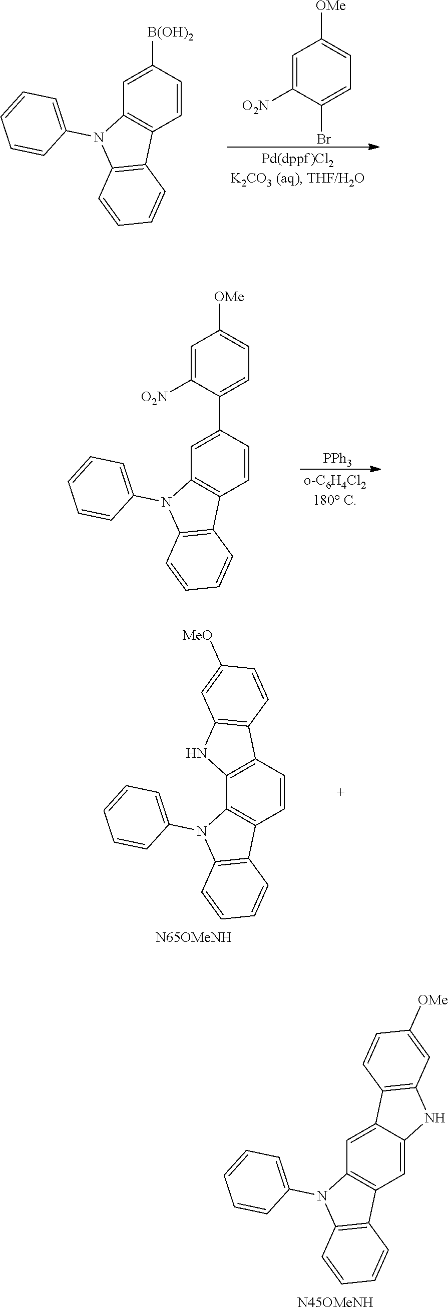 [SMILES: OB(O)c1ccc2c3ccccc3n(-c3ccccc3)c2c1 ; COc1ccc(Br)c([N+](=O)[O-])c1 ; COc1ccc(-c2ccc3c4ccccc4n(-c4ccccc4)c3c2)c([N+](=O)[O-])c1 ; COc1ccc2c(c1)[nH]c1c2ccc2c3ccccc3n(-c3ccccc3)c21 ; COc1ccc2c(c1)[nH]c1cc3c4ccccc4n(-c4ccccc4)c3cc12 ; "PPh3"]

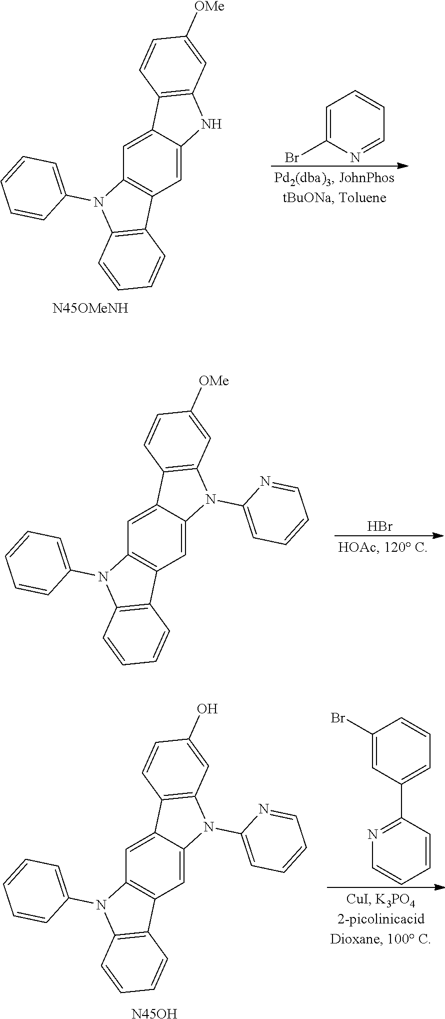

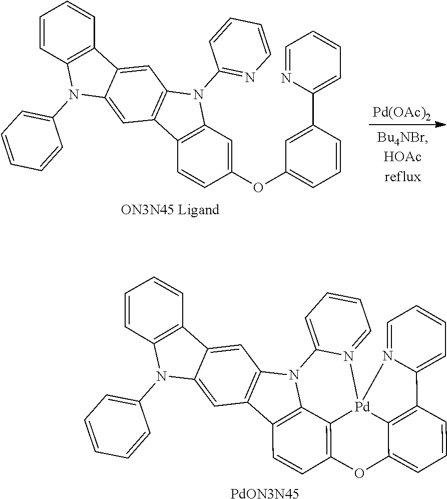

### Synthesis of ON3N45 Ligand

To a solution of 2-(3-bromophenyl)pyridine (1.5 eq) in dioxane (0.1 M) were added N450H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 73% yield.

### Synthesis of PdON3N45

To a solution of ON3N45 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N45 in 69% yield.

### Example 5

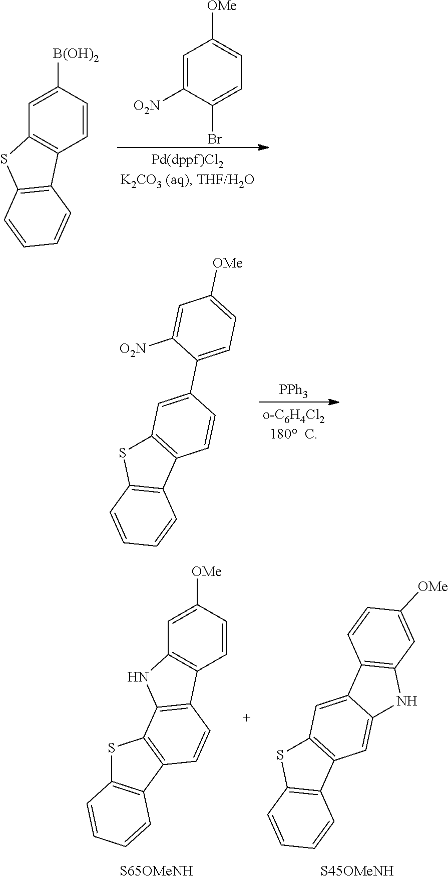 [SMILES: OB(O)c1ccc2c(c1)sc1ccccc12 ; COc1ccc(Br)c([N+](=O)[O-])c1 ; COc1ccc(-c2ccc3c(c2)sc2ccccc23)c([N+](=O)[O-])c1 ; COc1ccc2c(c1)[nH]c1c2ccc2c3ccccc3sc21 ; COc1ccc2c(c1)[nH]c1cc3c(cc12)sc1ccccc13 ; "PPh3"]

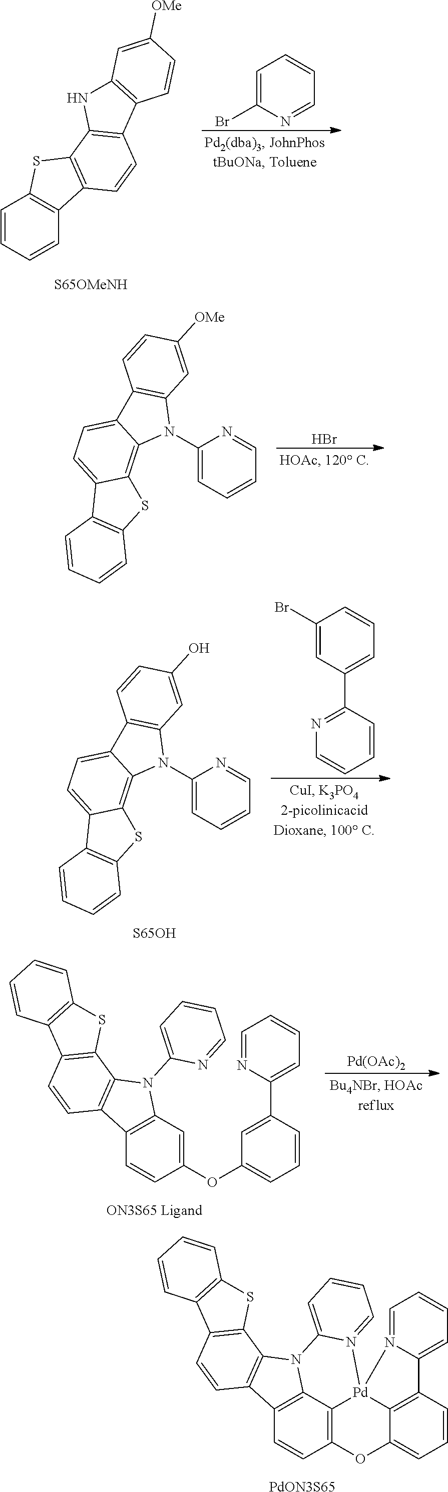

### Synthesis of ON3S65 Ligand

To a solution of 2-(3-bromophenyl)pyridine (1.5 eq) in dioxane (0.1 M) were added S650H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 67% yield.

### Synthesis of PdON3S65

To a solution of ON3S65 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S65 in 65% yield.

### Example 6

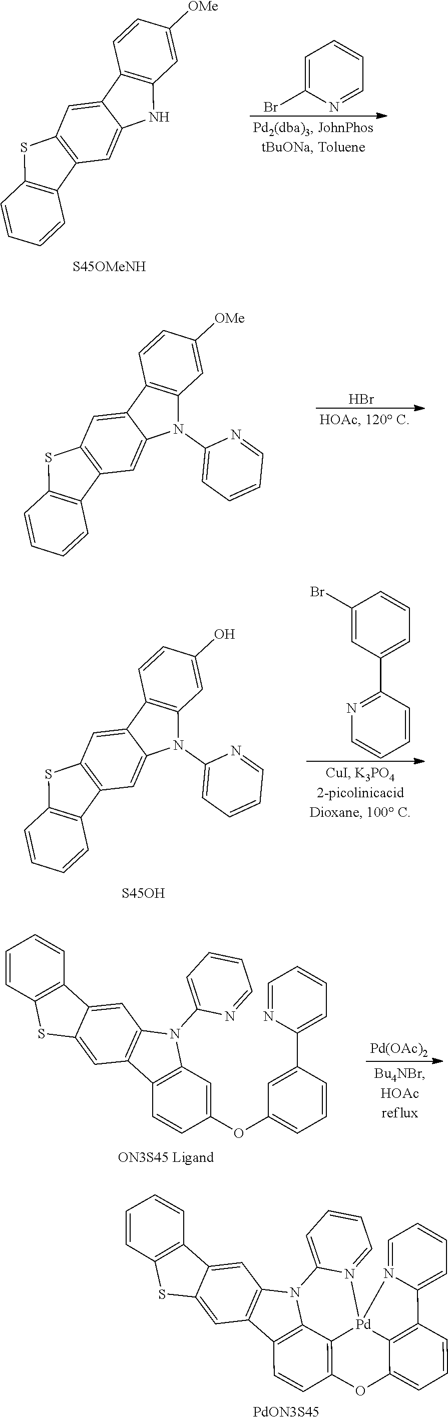

### Synthesis of ON3S45 Ligand

To a solution of 2-(3-bromophenyl)pyridine (1.5 eq) in dioxane (0.1 M) were added S450H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 75% yield.

### Synthesis of PdON3S45

To a solution of ON3S45 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S45 in 71% yield.

### Example 7

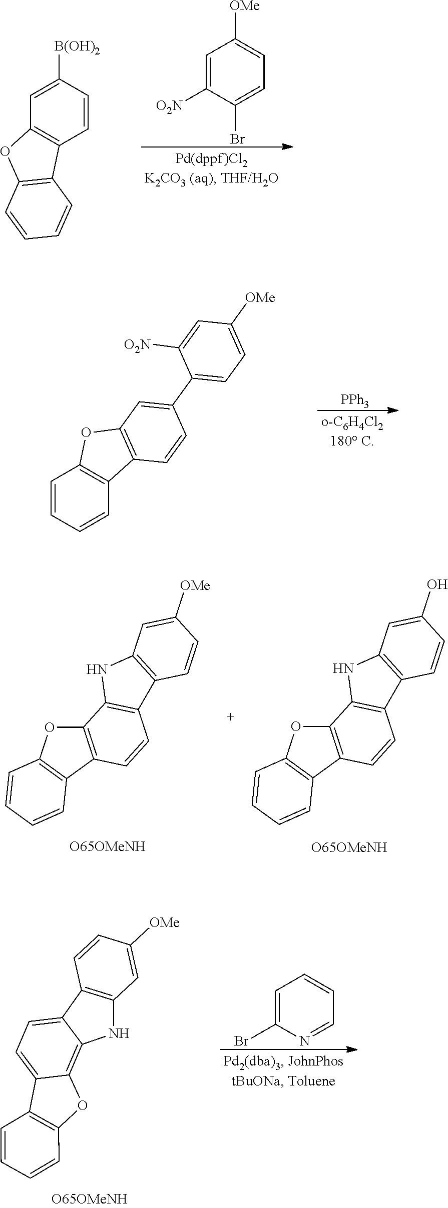

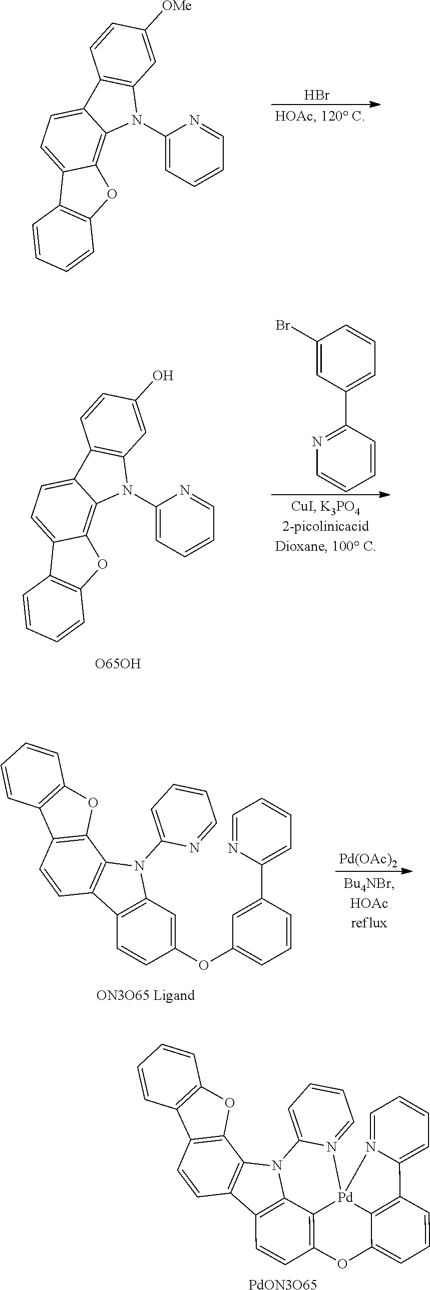

### Synthesis of ON3O65 Ligand

To a solution of 2-(3-bromophenyl)pyridine (1.5 eq) in dioxane (0.1 M) were added 0650H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 70% yield.

### Synthesis of PdON3O65

To a solution of ON3O65 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3O65 in 59% yield.

### Example 8

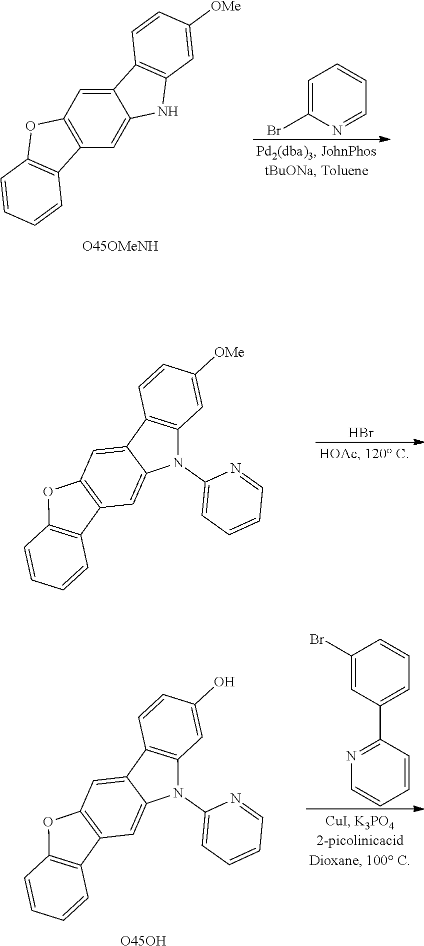

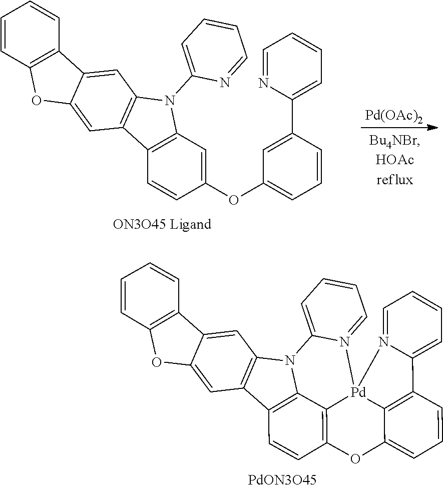

### Synthesis of ON3045 Ligand

To a solution of 2-(3-bromophenyl)pyridine (1.5 eq) in dioxane (0.1 M) were added 0450H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 66% yield.

### Synthesis of PdON3O45

To a solution of ON3045 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3O45 in 69% yield.

### Example 9

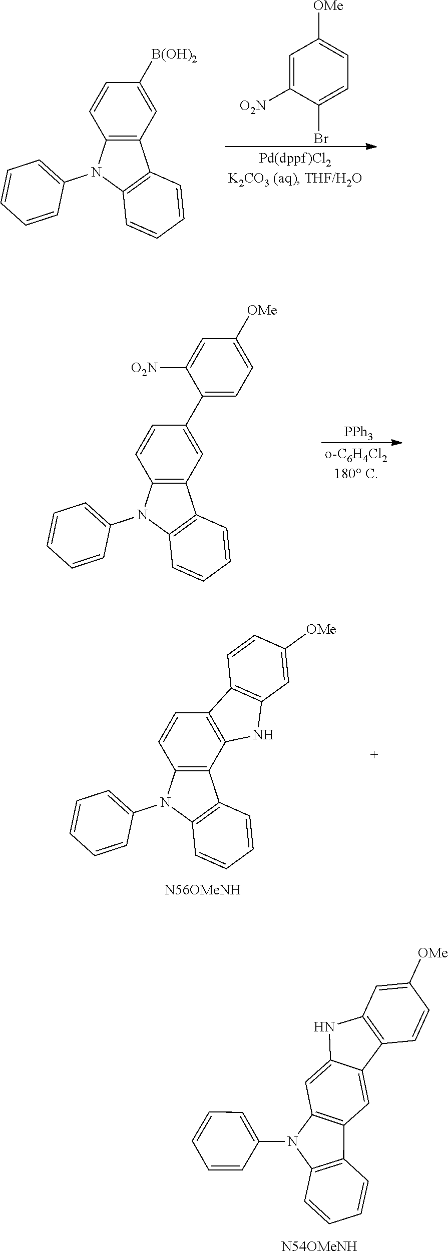 [SMILES: OB(O)c1ccc2c(c1)c1ccccc1n2-c1ccccc1 ; COc1ccc(Br)c([N+](=O)[O-])c1 ; COc1ccc(-c2ccc3c(c2)c2ccccc2n3-c2ccccc2)c([N+](=O)[O-])c1 ; COc1ccc2c(c1)[nH]c1c2ccc2c1c1ccccc1n2-c1ccccc1 ; COc1ccc2c(c1)[nH]c1cc3c(cc12)c1ccccc1n3-c1ccccc1 ; "PPh3"]

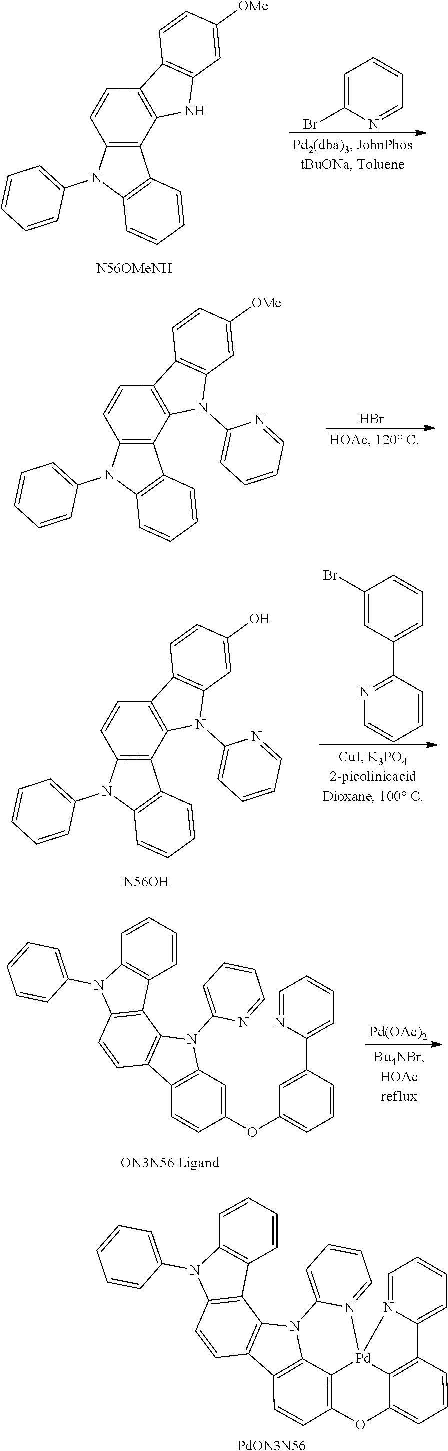

### Synthesis of ON3N56 Ligand

To a solution of 2-(3-bromophenyl)pyridine (1.5 eq) in dioxane (0.1 M) were added N560H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 78% yield.

### Synthesis of PdON3N56

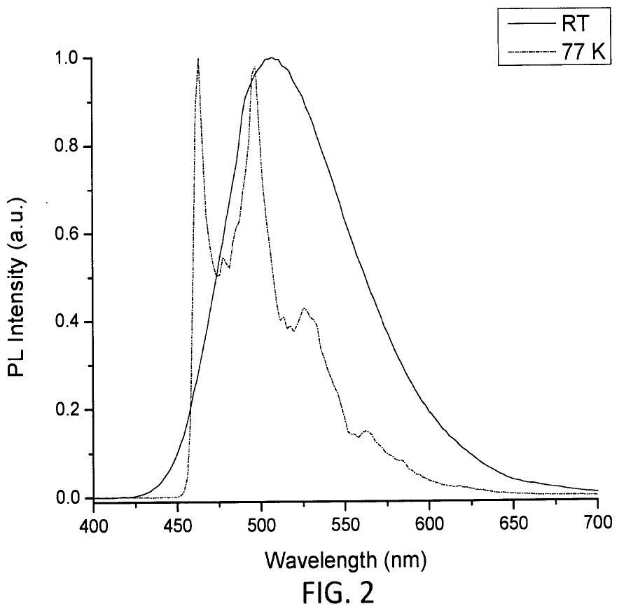

To a solution of ON3N56 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N56 in 74% yield. FIG. 2 shows PL spectra of PdON3N56 measured in CH₂Cl₂ at room temperature and in 2-MeTHF at 77K.

### Example 10

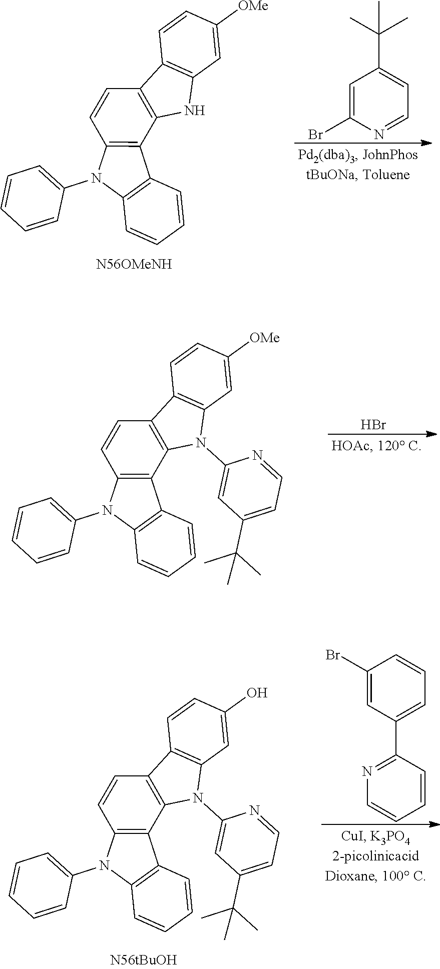 [SMILES: COc1ccc2c(c1)[nH]c1c2ccc2c1c1ccccc1n2-c1ccccc1 ; CC(C)(C)c1ccnc(Br)c1 ; COc1ccc2c3ccc4c(c5ccccc5n4-c4ccccc4)c3n(-c3cc(C(C)(C)C)ccn3)c2c1 ; Br ; CC(C)(C)c1ccnc(-n2c3cc(O)ccc3c3ccc4c(c5ccccc5n4-c4ccccc4)c32)c1 ; Brc1cccc(-c2ccccn2)c1]

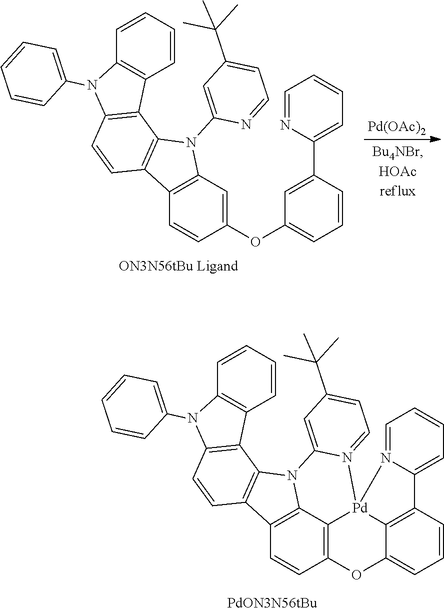

### Synthesis of ON3N56tBu Ligand

To a solution of 2-(3-bromophenyl)pyridine (1.5 eq) in dioxane (0.1 M) were added N56tBuOH (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 65% yield.

### Synthesis of PdON3N56tBu

To a solution of ON3N56tBu ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N56tBu in 58% yield.

### Example 11

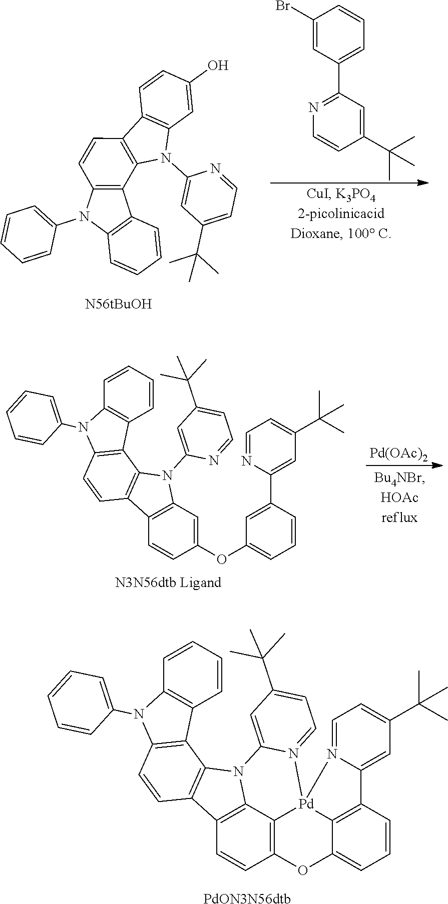

### Synthesis of ON3N56dtb Ligand

To a solution of 2-(3-bromophenyl)-4-(tert-butyl)pyridine (1.5 eq) in dioxane (0.1 M) were added N56tBuOH (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 72% yield.

### Synthesis of PdON3N56dtb

To a solution of ON3N56dtb ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N56dtb in 63% yield.

### Example 12

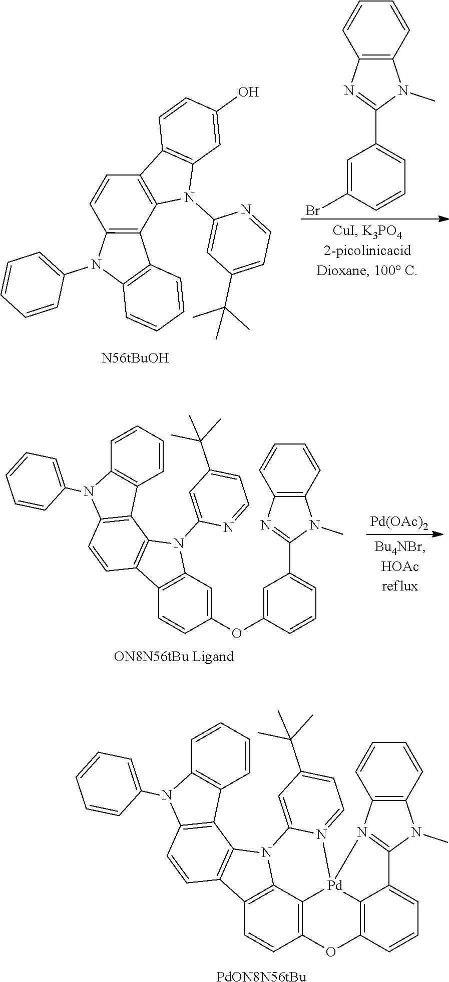

### Synthesis of ON8N56tBu Ligand

To a solution of 2-(3-bromophenyl)-1-methyl-1H-benzo[d]imidazole (1.5 eq) in dioxane (0.1 M) were added N56tBuOH (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 68% yield.

### Synthesis of PdON8N56tBu

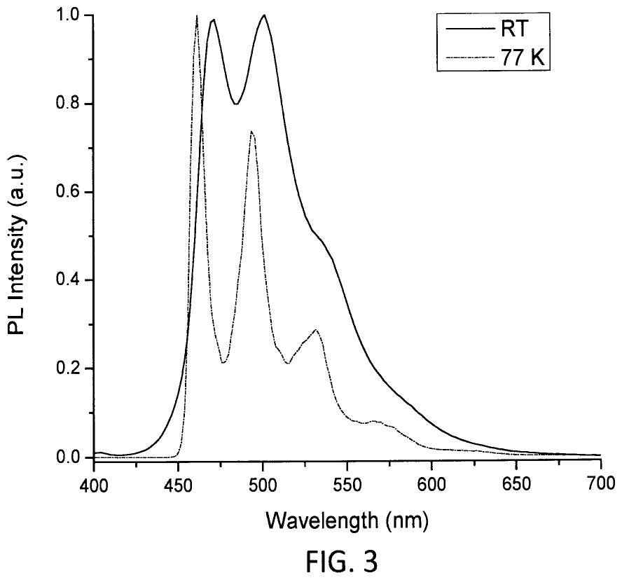

To a solution of ON8N56tBu ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON8N56tBu in 57% yield. FIG. 3 shows PL spectra of PdON8N56tBu measured in CH₂Cl₂ at room temperature and in 2-MeTHF at 77K.

### Example 13

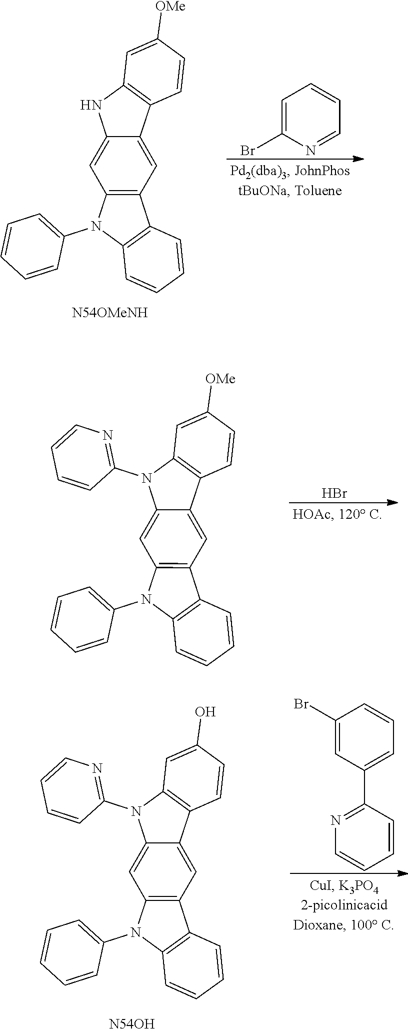

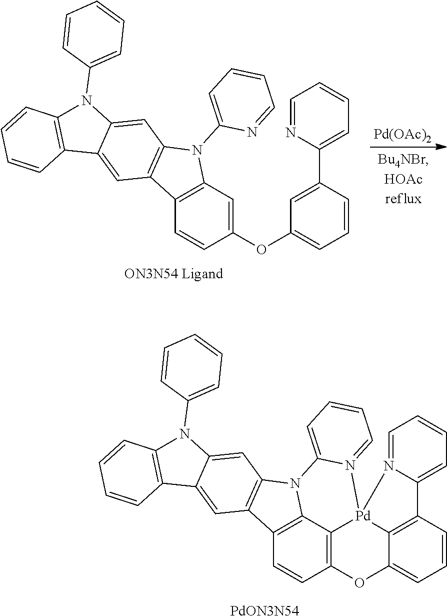

### Synthesis of ON3N54 Ligand

To a solution of 2-(3-bromophenyl)pyridine (1.5 eq) in dioxane (0.1 M) were added N540H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 74% yield.

### Synthesis of PdON3N54

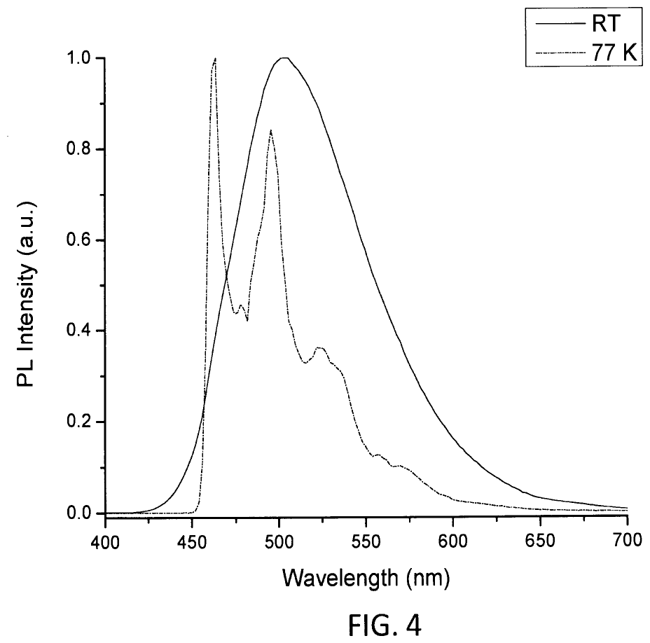

To a solution of ON3N54 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N54 in 67% yield. FIG. 4 shows PL spectra of PdON3N54 measured in CH₂Cl₂ at room temperature and in 2-MeTHF at 77K.

### Example 14

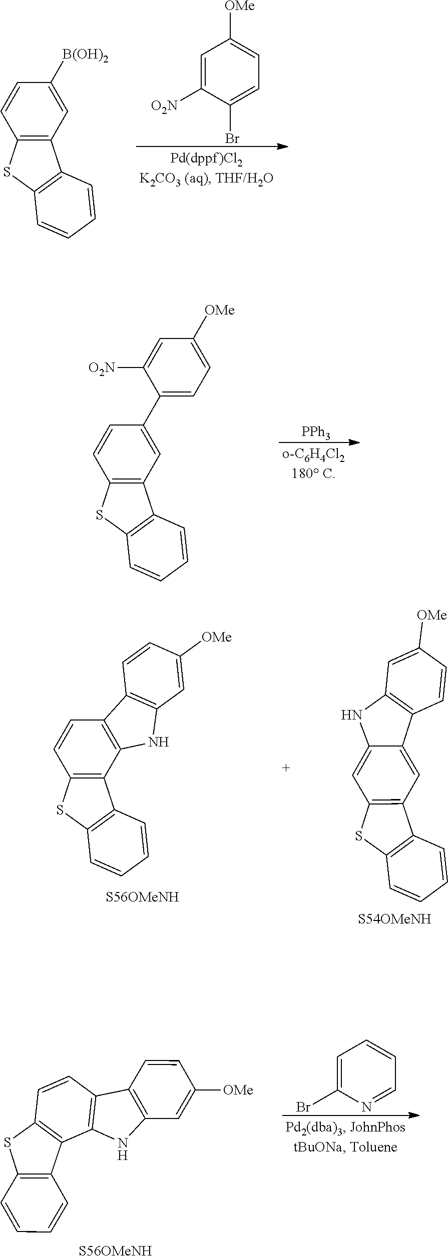

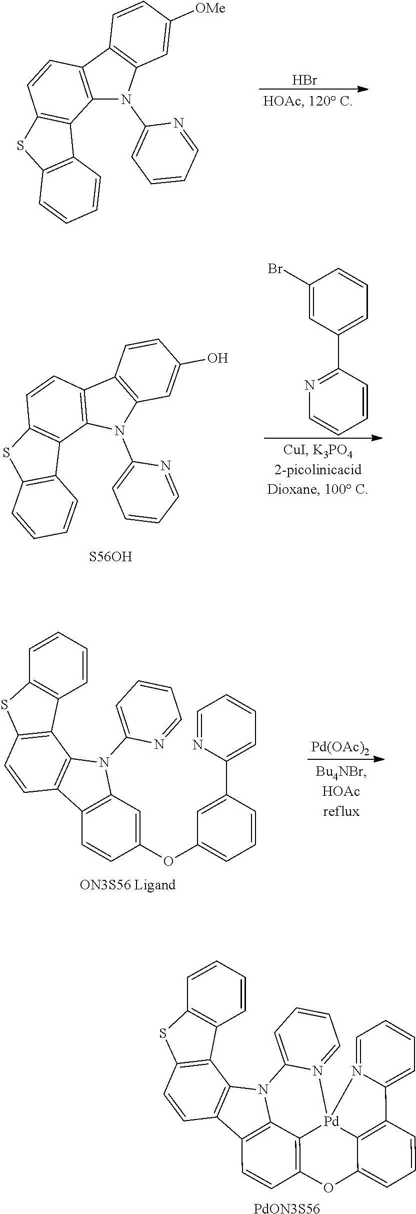

### Synthesis of ON3S56 Ligand

To a solution of 2-(3-bromophenyl)pyridine (1.5 eq) in dioxane (0.1 M) were added S560H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 71% yield.

### Synthesis of PdON3S56

To a solution of ON3S56 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S56 in 63% yield.

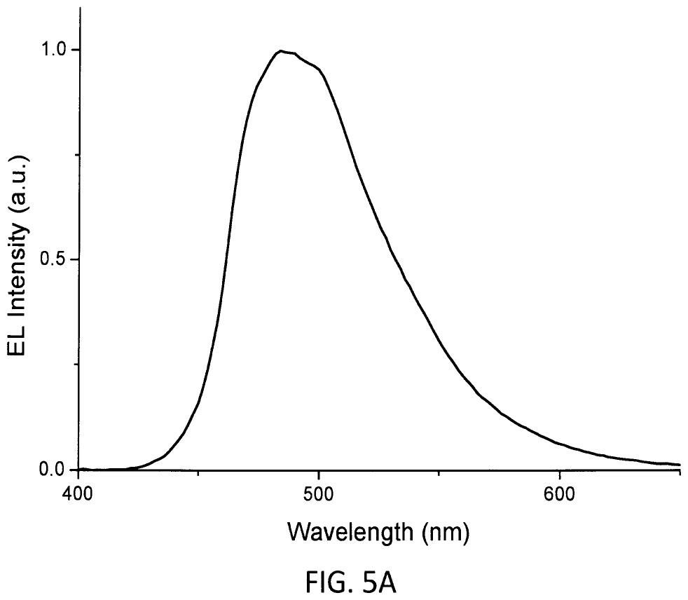

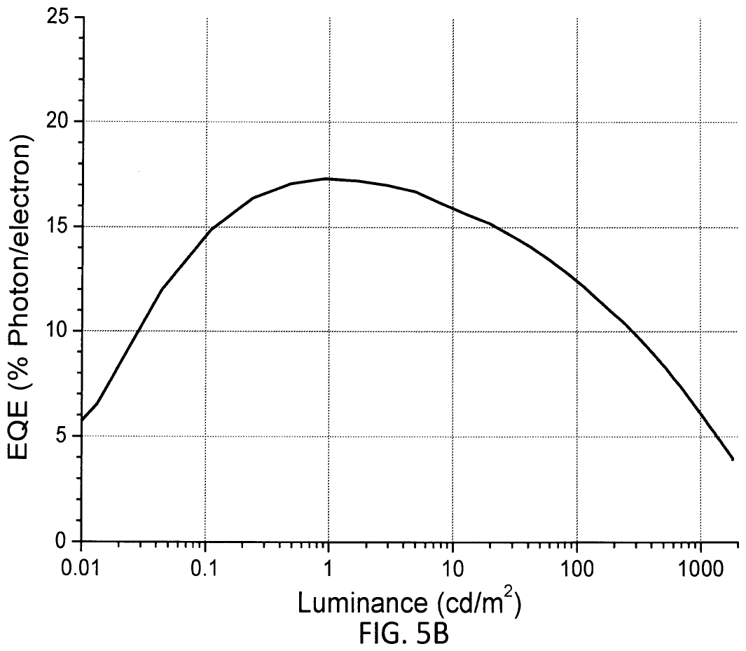

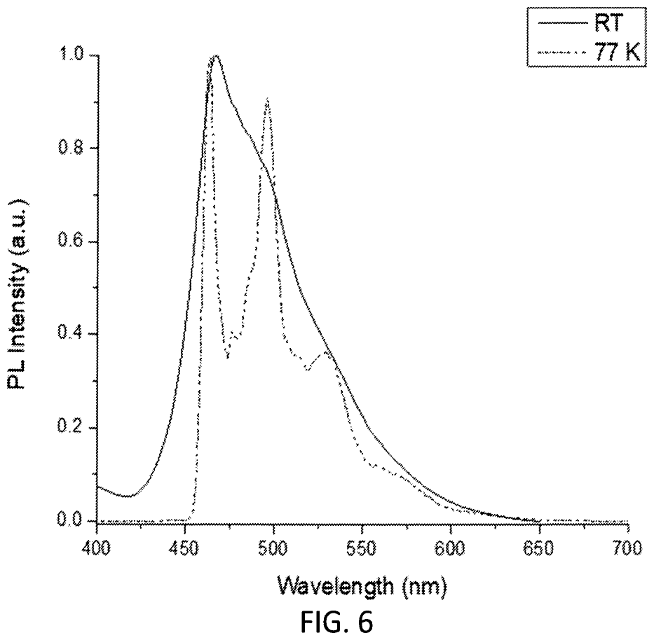

FIGS. 5A and 5B show an electroluminescence (EL) spectrum and a plot of EQE vs. luminance, respectively, of PdON3S56 in a device having the structure: ITO (40 nm)/HATCN (10 nm)/NPD (40 nm)/BisPCz (10 nm)/10% PdON3S56:mCBP (25 nm)/PO15 (10 nm)/BPyTP (40 nm)/Liq (2 nm)/Al (100 nm), where HATCN is 1,4,5,8,9,12-hexaazatriphenylene-hexacarbonitrile, NPD is N,N′-diphenyl-N,N′-bis(1-naphthyl)-1,1′-biphenyl-4,4″-diamine, BisPCz is 9,9′-diphenyl-9H,9′H-3,3′-bicarbazole, mCBP is 3,3′-di(9H-carbazol-9-yl)-1,1′-biphenyl, P015 is dibenzo[b,d]thiophene-2,8-diylbis(diphenylphosphine oxide) and BPyTP is 2,7-di(2,2′-bipyridin-5-yl)triphenylene. FIG. 6 shows photoluminescence (PL) spectra of PdON3S56 measured in CH₂Cl₂ at room temperature and in 2-MeTHF at 77K.

### Example 15

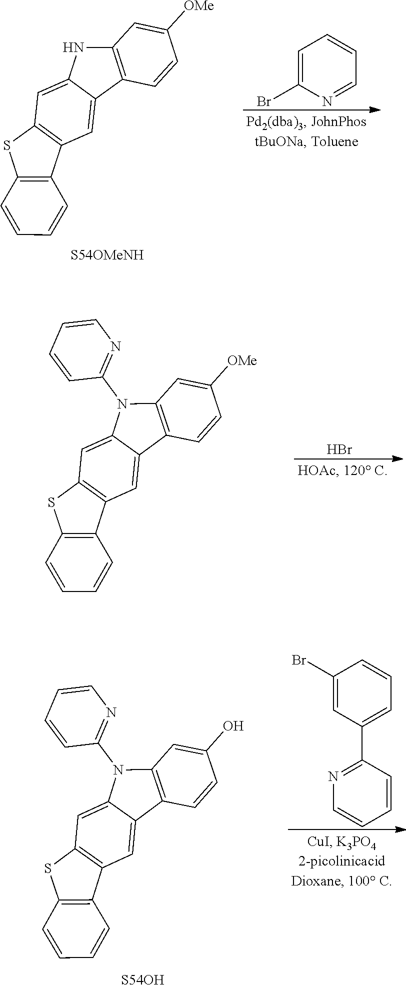

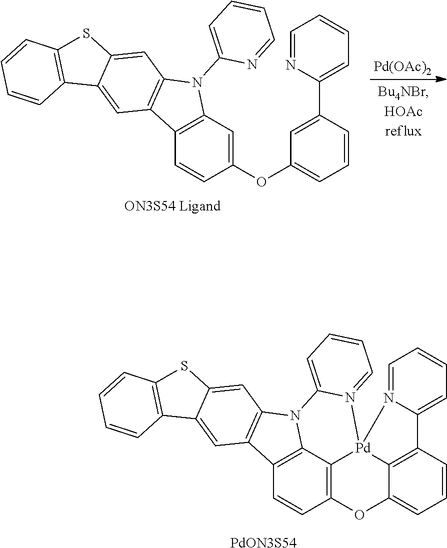

### Synthesis of ON3S54 Ligand

To a solution of 2-(3-bromophenyl)pyridine (1.5 eq) in dioxane (0.1 M) were added S540H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 77% yield.

### Synthesis of PdON3S54

To a solution of ON3S54 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S54 in 65% yield.

### Example 16

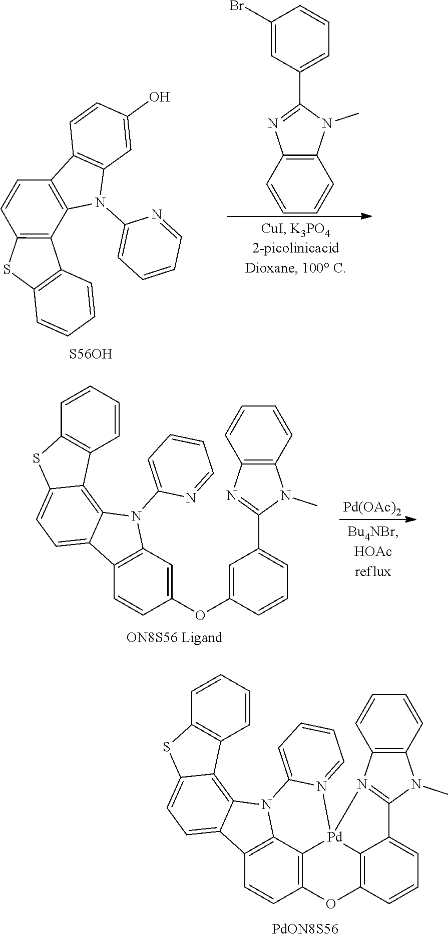

### Synthesis of ON8S56 Ligand

To a solution of 2-(3-bromophenyl)-1-methyl-1H-benzo[d]imidazole (1.5 eq) in dioxane (0.1 M) were added S560H (1 eq), CuI (0.1 eq), 2-picolinic acid (0.2 eq), and K₃PO4 (2 eq). The mixture was heated to 100° C. and maintained at this temperature for 24 hours. The mixture was then cooled to room temperature. The solvent was evaporated under reduced pressure. The residue was then purified by flash column chromatography to give the product in 78% yield.

### Synthesis of PdON8S56

To a solution of ON8S56 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON8S56 in 64% yield.

### Example 17

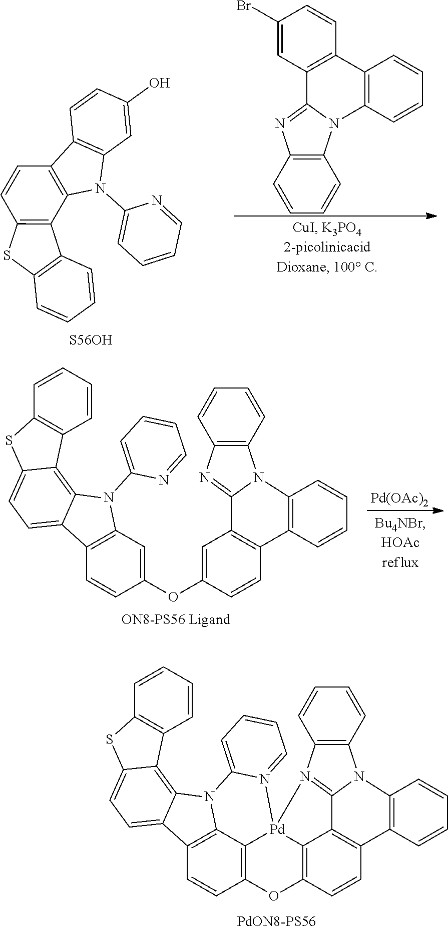

### Synthesis of ON8-PS56 Ligand

To a solution of 7-bromobenzo[4,5]imidazo[1,2-f]phenanthridine (1.5 eq) in dioxane (0.1 M) were added S560H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 72% yield.

### Synthesis of PdON8-PS56

To a solution of ON8-PS56 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON8-PS56 in 58% yield.

### Example 18

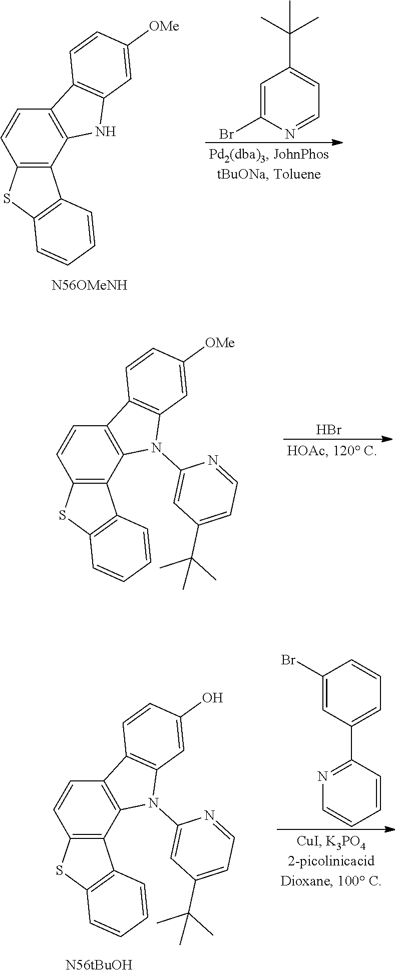 [SMILES: COc1ccc2c(c1)[nH]c1c2ccc2sc3ccccc3c21 ; CC(C)(C)c1ccnc(Br)c1 ; COc1ccc2c3ccc4sc5ccccc5c4c3n(-c3cc(C(C)(C)C)ccn3)c2c1 ; Br ; CC(C)(C)c1ccnc(-n2c3cc(O)ccc3c3ccc4sc5ccccc5c4c32)c1 ; Brc1cccc(-c2ccccn2)c1]

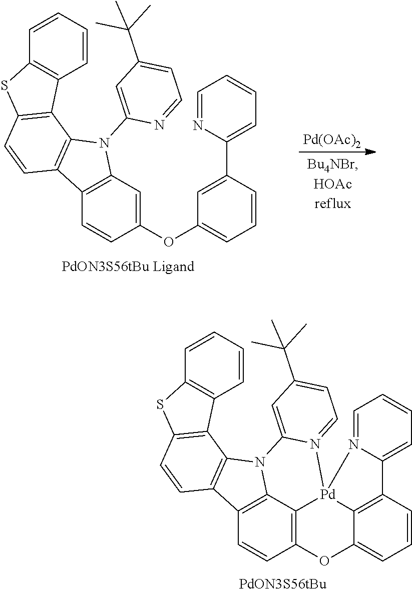

### Synthesis of ON3S56tBu Ligand

To a solution of 2-(3-bromophenyl)pyridine (1.5 eq) in dioxane (0.1 M) were added S56tBuOH (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 72% yield.

### Synthesis of PdON3S56tBu

To a solution of ON3S56tBu ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S56tBu in 61% yield.

### Example 19

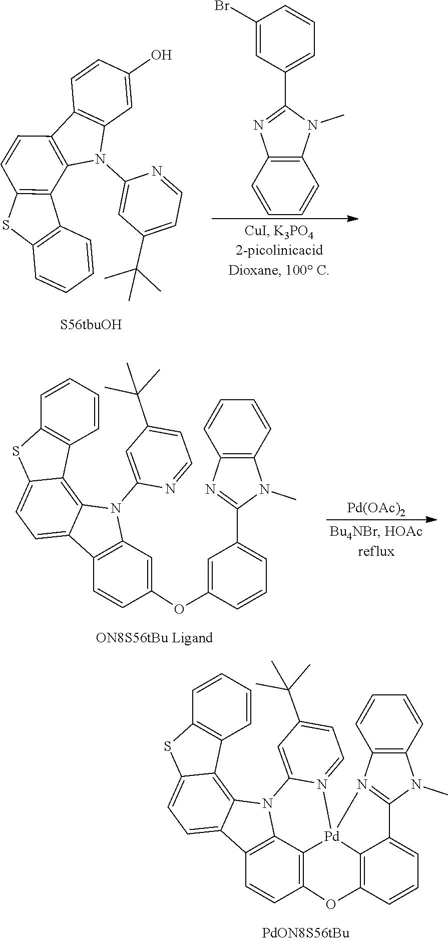

### Synthesis of ON8S56tBu Ligand

To a solution of 2-(3-bromophenyl)-1-methyl-1H-benzo[d]imidazole (1.5 eq) in dioxane (0.1 M) were added S56tBuOH (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 72% yield.

### Synthesis of PdON8S56tBu

To a solution of ON8S56tBu ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON8S56tBu in 67% yield.

### Example 20

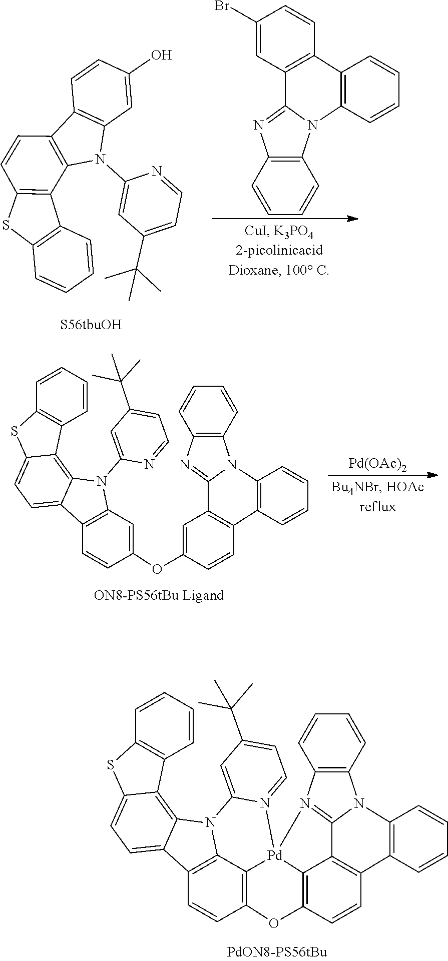

### Synthesis of ON8-PS56tBu Ligand

To a solution of 7-bromobenzo[4,5]imidazo[1,2-f]phenanthridine (1.5 eq) in dioxane (0.1 M) were added S56tBuOH (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 75% yield.

### Synthesis of PdON8-PS56tBu

To a solution of ON8-PS56tBu ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON8-PS56tBu in 63% yield.

### Example 21

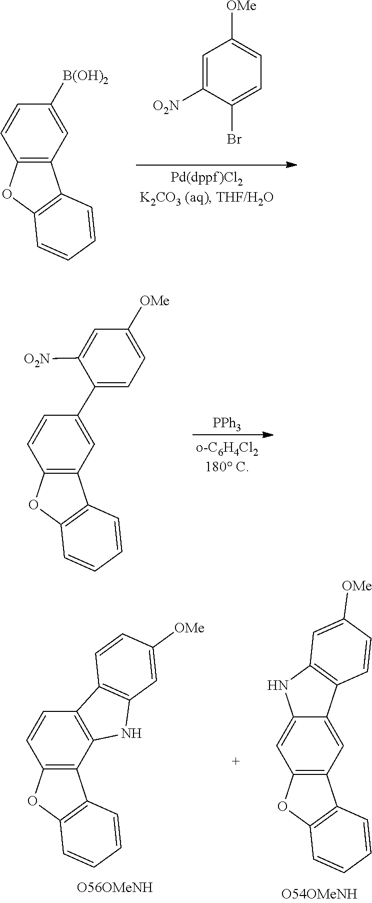 [SMILES: OB(O)c1ccc2oc3ccccc3c2c1 ; COc1ccc(Br)c([N+](=O)[O-])c1 ; COc1ccc(-c2ccc3oc4ccccc4c3c2)c([N+](=O)[O-])c1 ; COc1ccc2c(c1)[nH]c1c2ccc2oc3ccccc3c21 ; COc1ccc2c(c1)[nH]c1cc3oc4ccccc4c3cc12 ; "PPh3"]

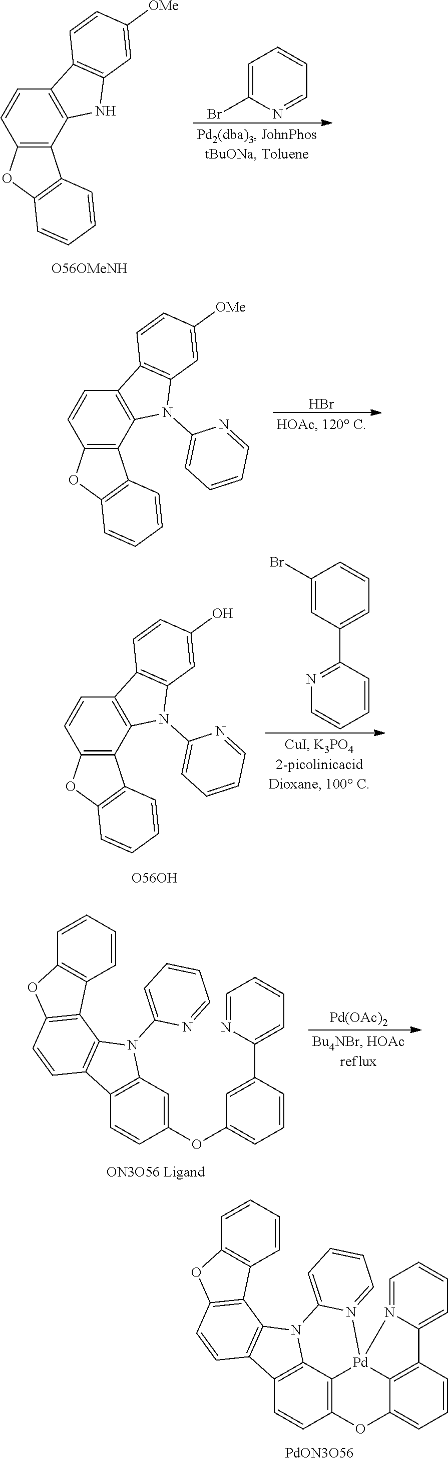

### Synthesis of ON3056 Ligand

To a solution of 2-(3-bromophenyl)pyridine (1.5 eq) in dioxane (0.1 M) were added 0560H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 76% yield.

### Synthesis of PdON3O56

To a solution of ON3056 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3O56 in 68% yield.

### Example 22

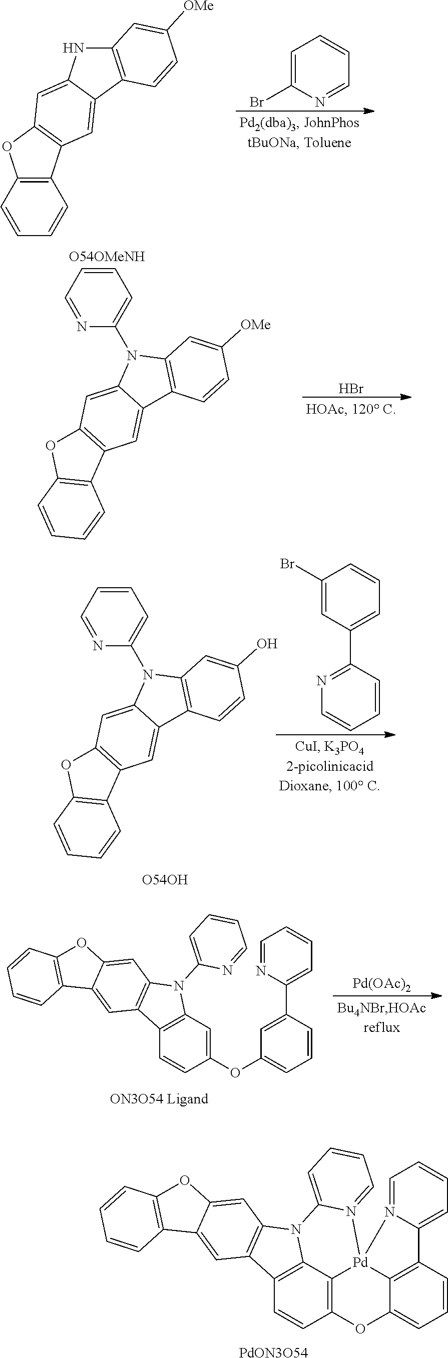

### Synthesis of ON3054 Ligand

To a solution of 2-(3-bromophenyl)pyridine (1.5 eq) in dioxane (0.1 M) were added S560H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 81% yield.

### Synthesis of PdON3O54

To a solution of ON3054 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3O54 in 69% yield.

### Example 23

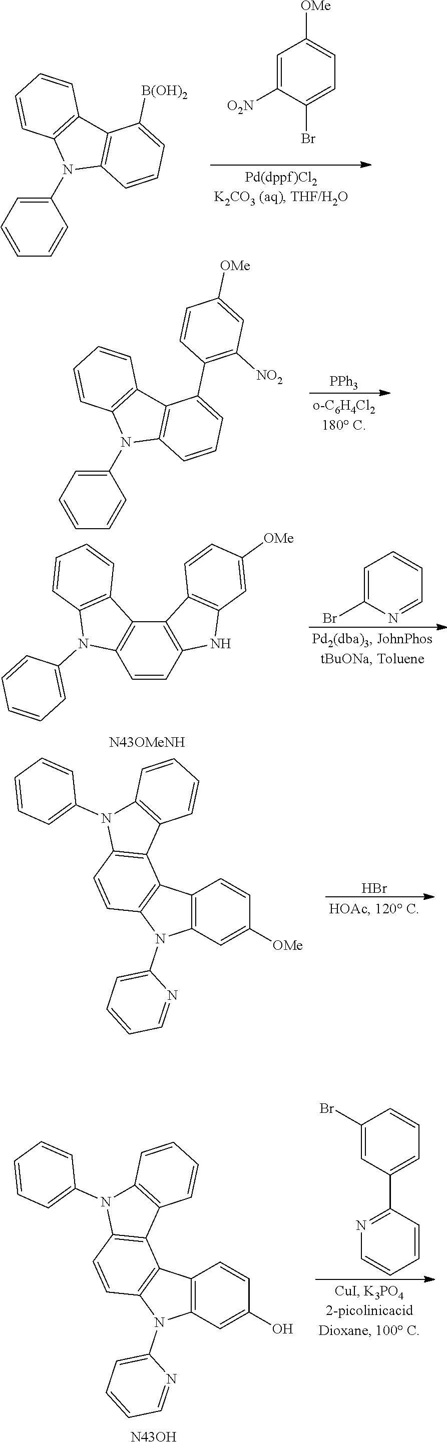

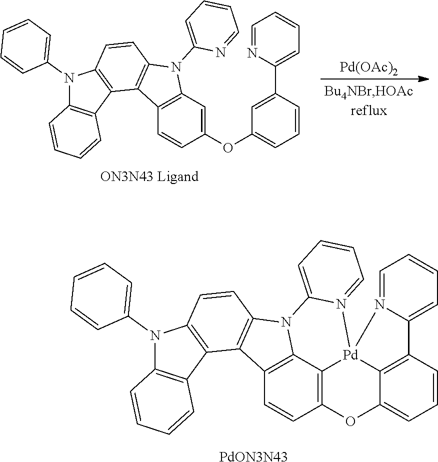

### Synthesis of ON3N43 Ligand

To a solution of 2-(3-bromophenyl)pyridine (1.5 eq) in dioxane (0.1 M) were added N430H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 78% yield.

### Synthesis of PdON3N43

To a solution of ON3N43 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3N43 in 66% yield.

### Example 24

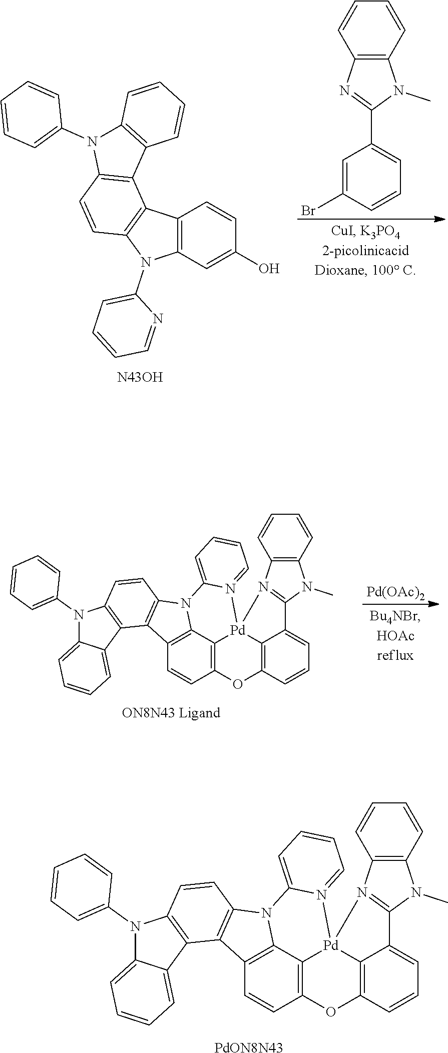

### Synthesis of ON8N43 Ligand

To a solution of 2-(3-bromophenyl)-1-methyl-1H-benzo[d]imidazole (1.5 eq) in dioxane (0.1 M) were added N430H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 66% yield.

### Synthesis of PdON8N43

To a solution of ON8N43 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON8N43 in 57% yield.

### Example 25

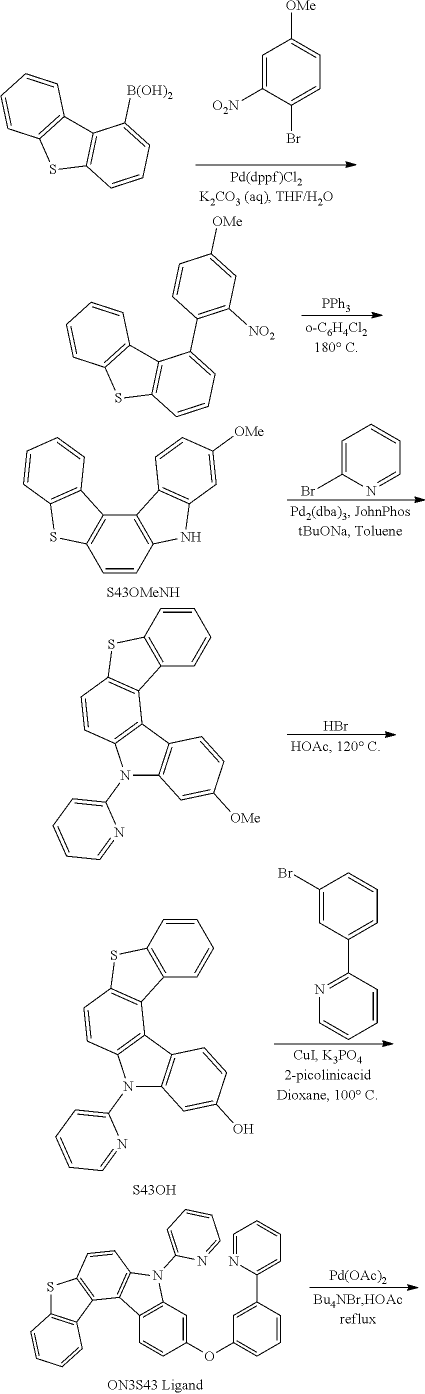

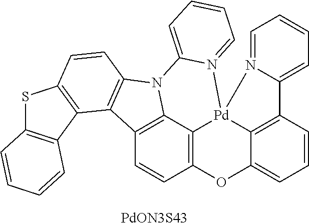

### Synthesis of ON3S43 Ligand

To a solution of 2-(3-bromophenyl)pyridine (1.5 eq) in dioxane (0.1 M) were added S430H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 73% yield.

### Synthesis of PdON3S43

To a solution of ON3S43 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3S43 in 61% yield.

### Example 26

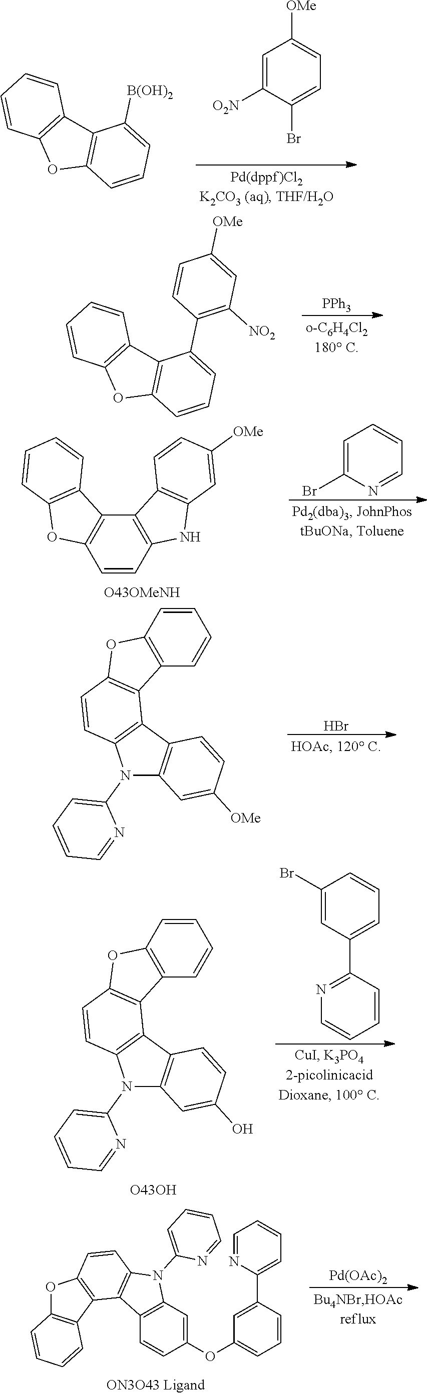

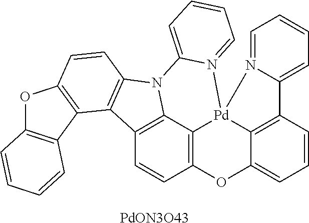

### Synthesis of ON3043 Ligand

To a solution of 2-(3-bromophenyl)pyridine (1.5 eq) in dioxane (0.1 M) were added S430H (1 eq), CuI (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 77% yield.

### Synthesis of PdON3O43

To a solution of ON3043 ligand (1 eq) in HOAc (0.02 M) were added Pd(OAc)₂ (1.2 eq) and n-Bu₄NBr (0.1 eq). The mixture was heated to reflux and maintained at this temperature for 2 days. The reaction mixture was cooled to room temperature. The solvent was then removed under reduced pressure. Purification by column chromatography (hexanes:DCM) gave the PdON3O43 in 65% yield.

### Example 27

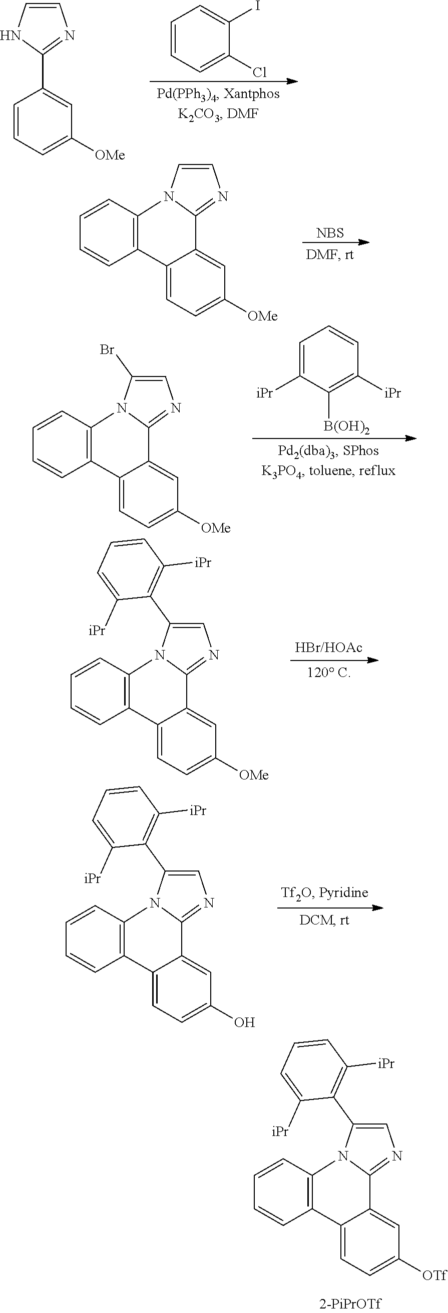

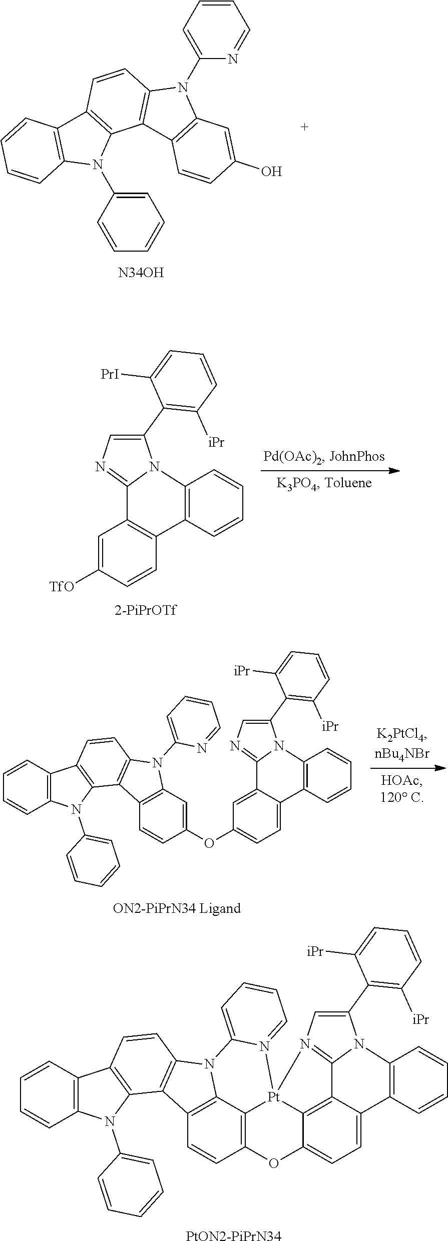

### Synthesis of ON2-PiPrN34 Ligand

To a solution of 2PiPrOTf (1.5 eq) in toluene (0.1 M) were added N340H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 31% yield.

### Synthesis of PtON2-PiPrN34

To a solution of ON2-PiPrN34 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrN34 in 48% yield.

### Example 28

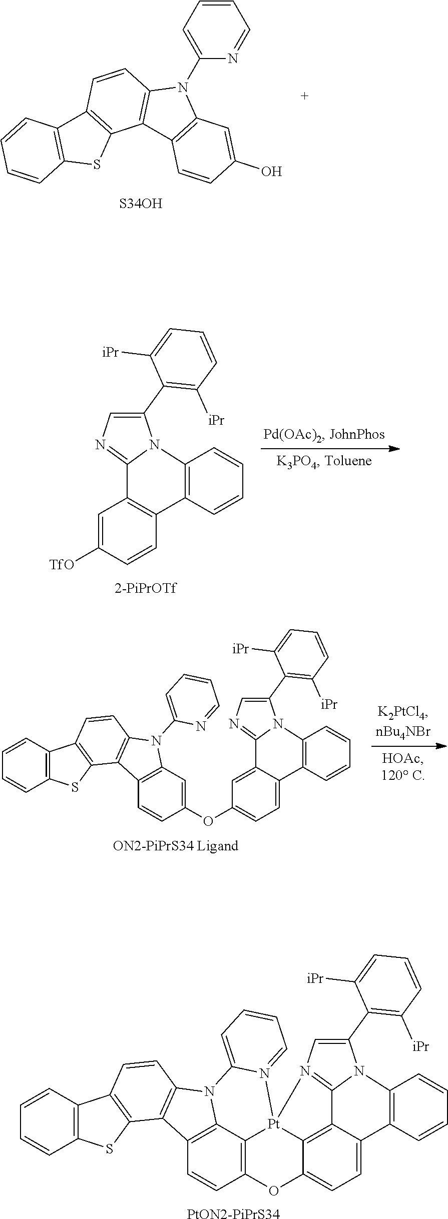

### Synthesis of ON2-PiPrS34 Ligand

To a solution of 2PiPrOTf (1.5 eq) in toluene (0.1 M) were added S340H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 28% yield.

### Synthesis of PtON2-PiPrS34

To a solution of ON2-PiPrS34 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrS34 in 41% yield.

### Example 29

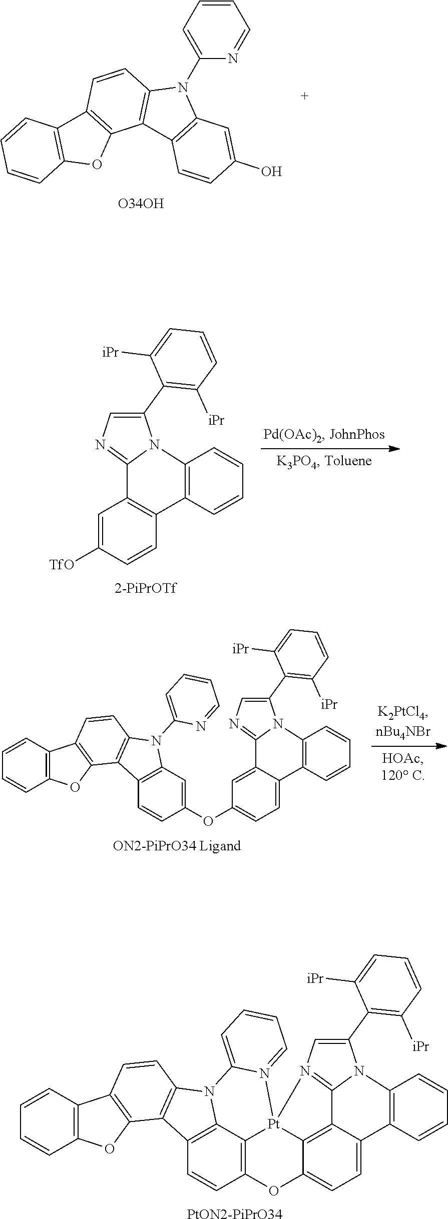

### Synthesis of ON2-PiPrO34 Ligand

To a solution of 2PiPrOTf (1.5 eq) in toluene (0.1 M) were added 0340H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 25% yield.

### Synthesis of PtON2-PiPrO34

To a solution of ON2-PiPrO34 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrO34 in 44% yield.

### Example 30

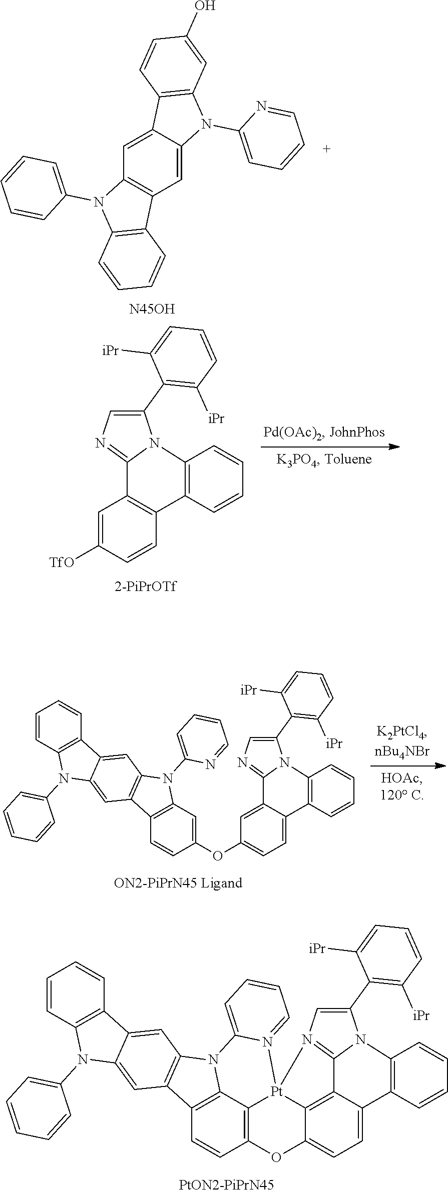

### Synthesis of ON2-PiPrN45 Ligand

To a solution of 2PiPrOTf (1.5 eq) in toluene (0.1 M) were added N450H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 27% yield.

### Synthesis of PtON2-PiPrN45

To a solution of ON2-PiPrN45 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrN45 in 38% yield.

### Example 31

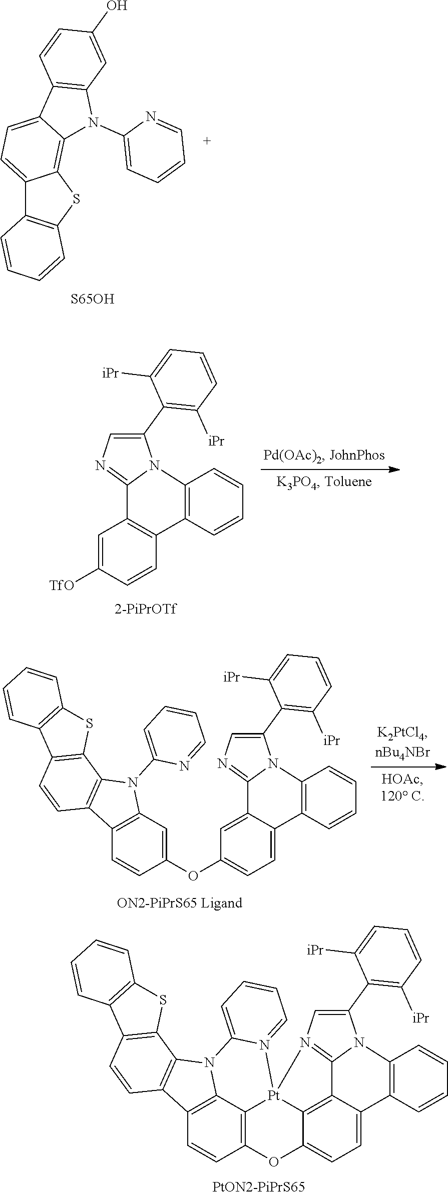

### Synthesis of ON2-PiPrS65 Ligand

To a solution of 2PiPrOTf (1.5 eq) in toluene (0.1 M) were added S650H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 25% yield.

### Synthesis of PtON2-PiPrS65

To a solution of ON2-PiPrS65 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrS65 in 44% yield.

### Example 32

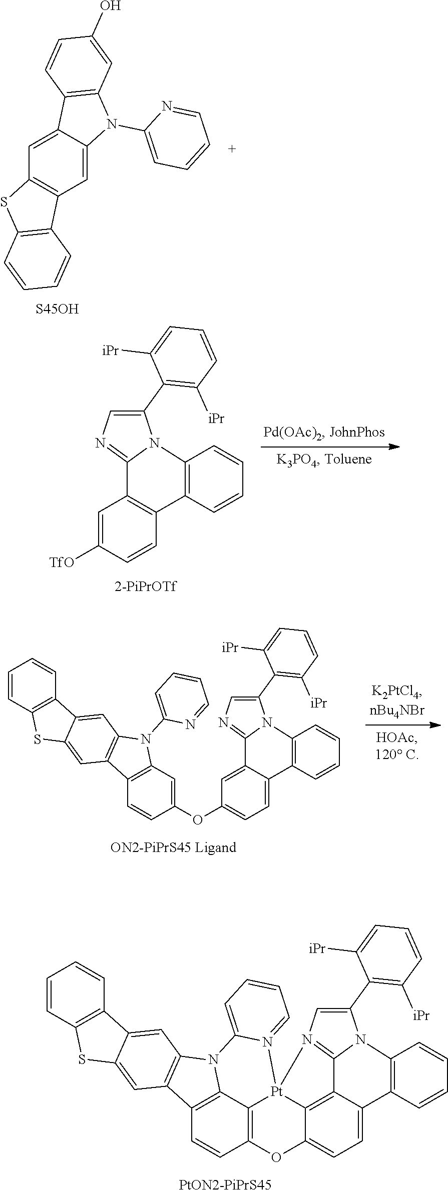

### Synthesis of ON2-PiPrS45 Ligand

To a solution of 2PiPrOTf (1.5 eq) in toluene (0.1 M) were added S450H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 32% yield.

### Synthesis of PtON2-PiPrS45

To a solution of ON2-PiPrS45 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrS45 in 47% yield.

### Example 33

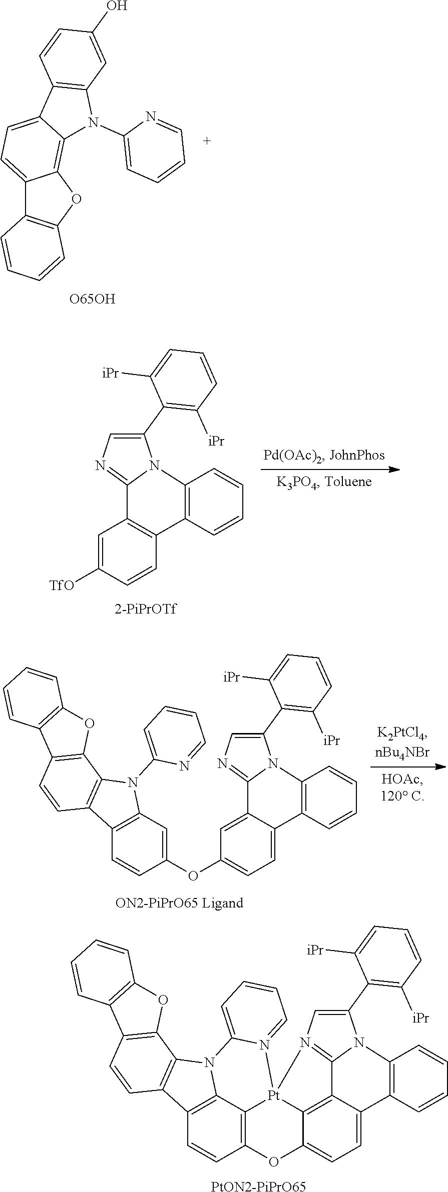

### Synthesis of ON2-PiPrO65 Ligand

To a solution of 2PiPrOTf (1.5 eq) in toluene (0.1 M) were added 0650H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 27% yield.

### Synthesis of PtON2-PiPrO65

To a solution of ON2-PiPrO65 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrO65 in 42% yield.

### Example 34

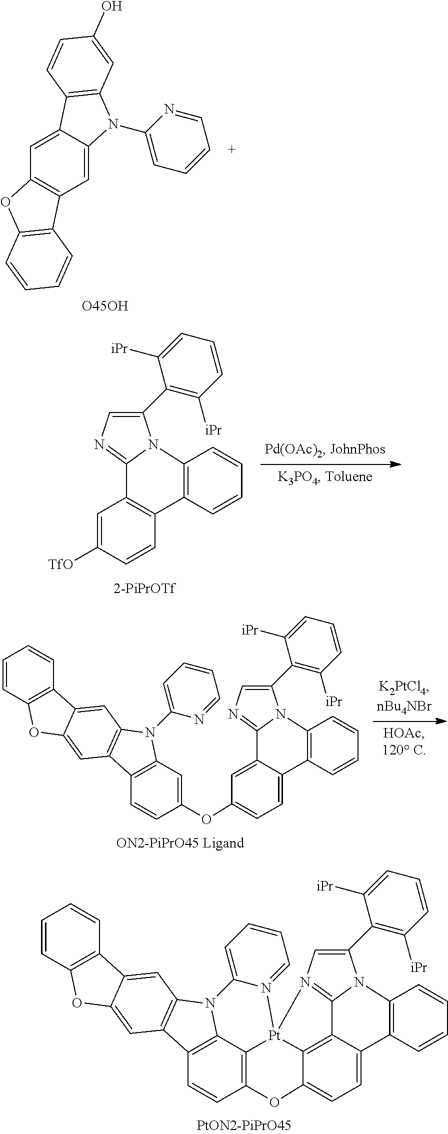

### Synthesis of ON2-PiPrO45 Ligand

To a solution of 2PiPrOTf (1.5 eq) in toluene (0.1 M) were added 0450H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 25% yield.

### Synthesis of PtON2-PiPrO45

To a solution of ON2-PiPrO45 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrO45 in 44% yield.

### Example 35

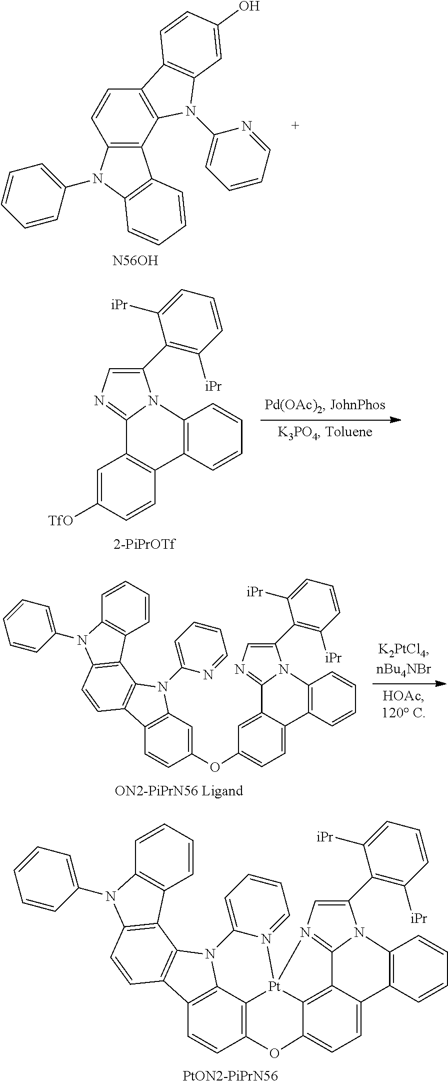

### Synthesis of ON2-PiPrN56 Ligand

To a solution of 2PiPrOTf (1.5 eq) in toluene (0.1 M) were added N560H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 28% yield.

### Synthesis of PtON2-PiPrN56

To a solution of ON2-PiPrN56 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrN56 in 41% yield.

### Example 36

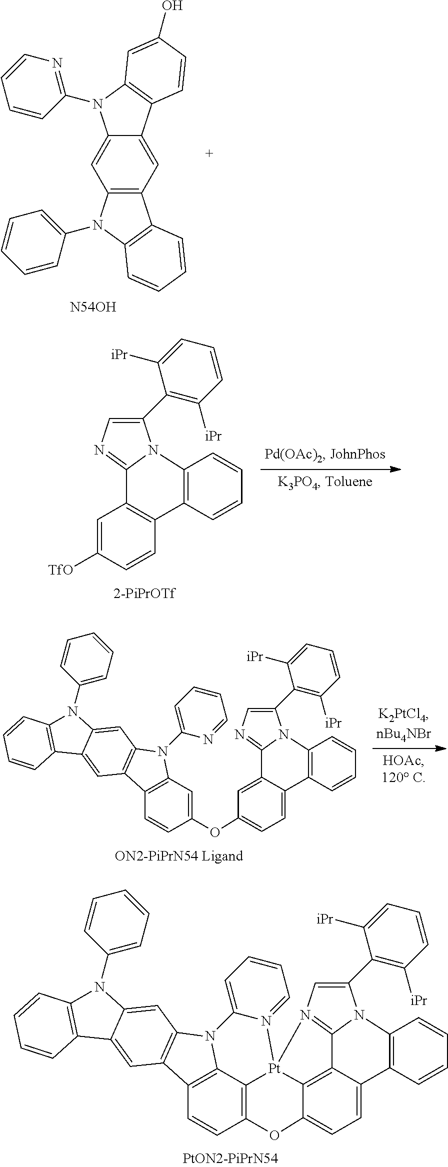

### Synthesis of ON2-PiPrN54 Ligand

To a solution of 2PiPrOTf (1.5 eq) in toluene (0.1 M) were added N540H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 24% yield.

### Synthesis of PtON2-PiPrN54

To a solution of ON2-PiPrN54 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrN54 in 49% yield.

### Example 37

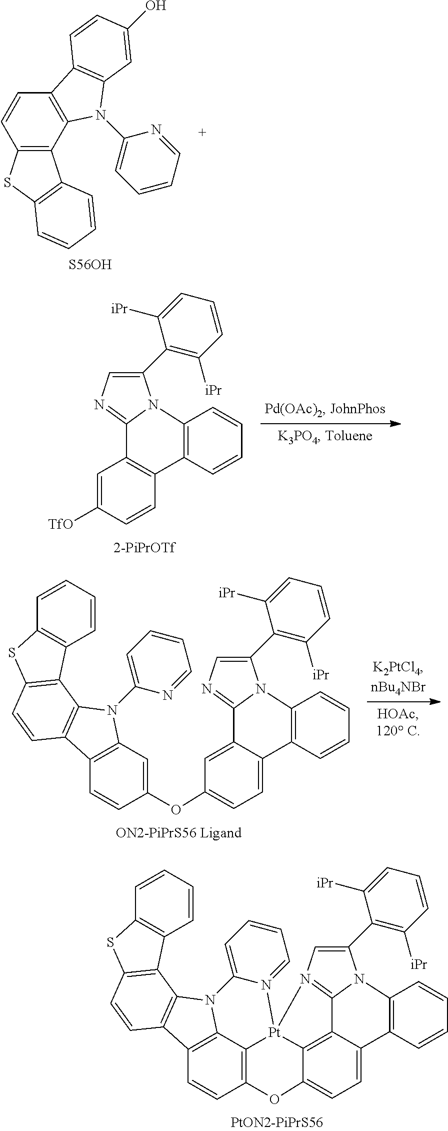

### Synthesis of ON2-PiPrS56 Ligand

To a solution of 2PiPrOTf (1.5 eq) in toluene (0.1 M) were added S560H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 27% yield.

### Synthesis of PtON2-PiPrS56

To a solution of ON2-PiPrS56 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrS56 in 53% yield.

### Example 38

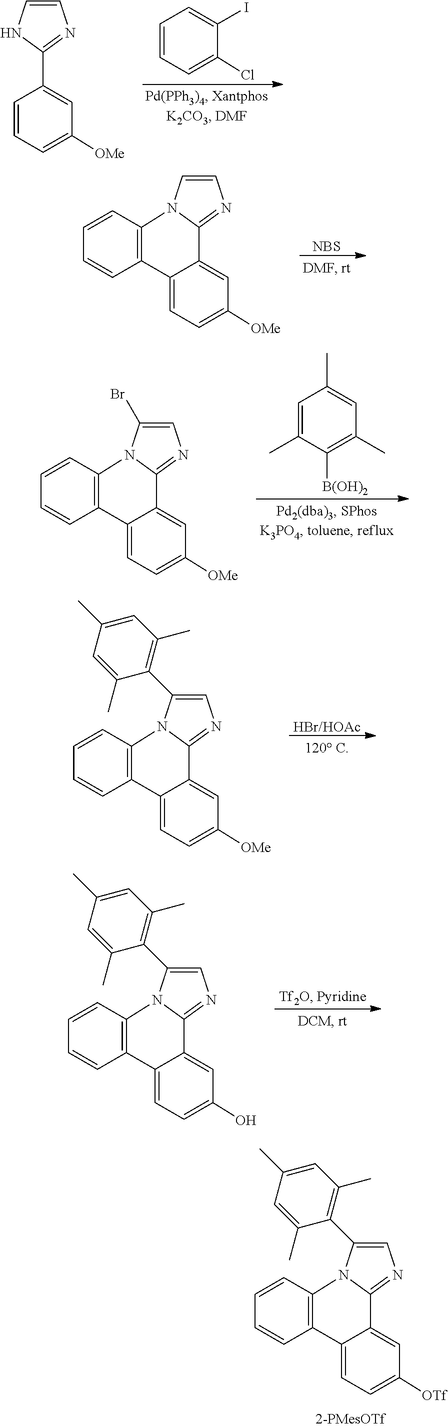

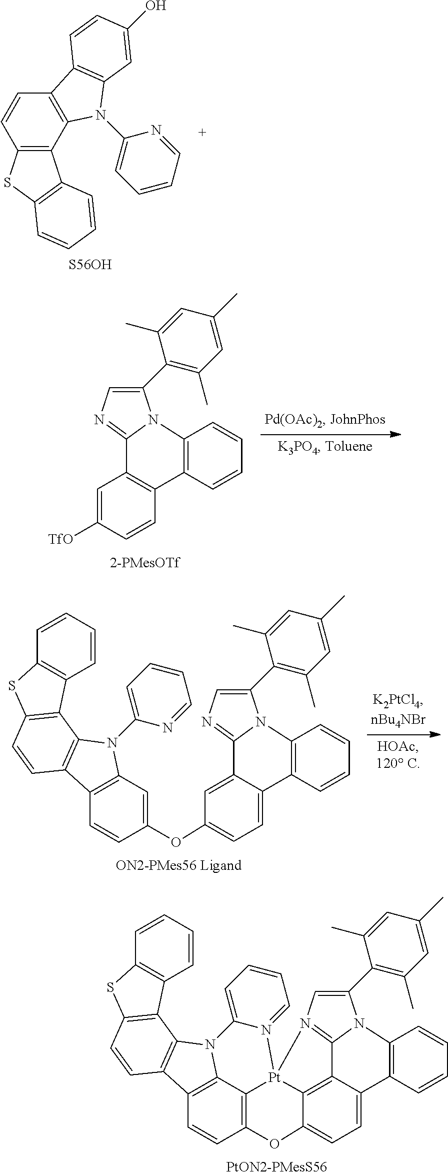

### Synthesis of ON2-PiPrS56 Ligand

To a solution of 2-PMesOTf (1.5 eq) in toluene (0.1 M) were added S560H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 29% yield.

### Synthesis of PtON2-PMesS56

To a solution of ON2-PMesS56 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PMesS56 in 49% yield.

### Example 39

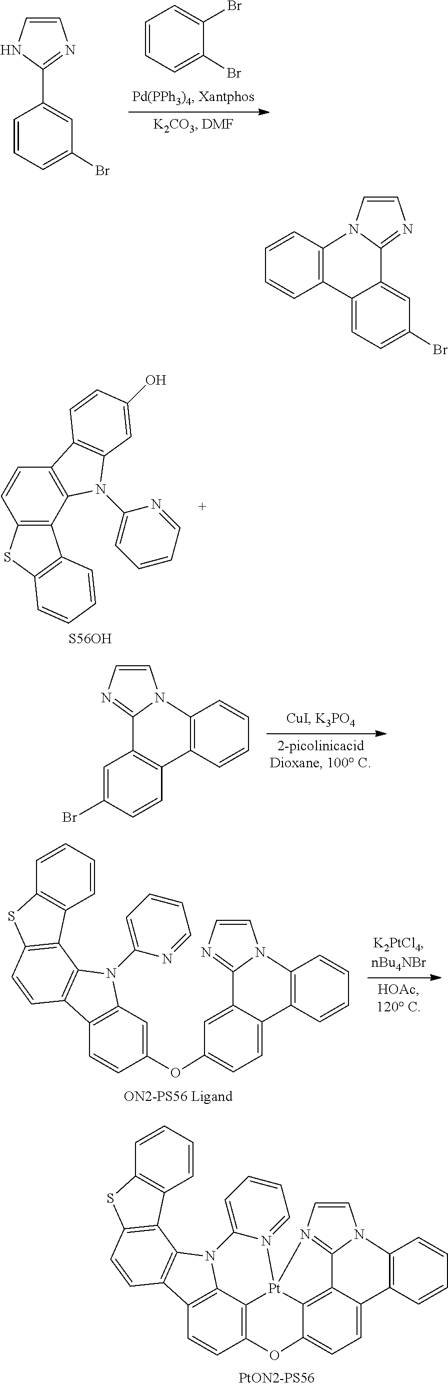

### Synthesis of ON2-PS56 Ligand

To a solution of 11-bromoimidazo[1,2-f]phenanthridine (1.5 eq) in dioxane (0.1 M) were added S560H (1 eq), Pd(OAc)ₐ(0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 72% yield.

### Synthesis of PtON2-PS56

To a solution of ON2-PS56 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PS56 in 49% yield.

### Example 40

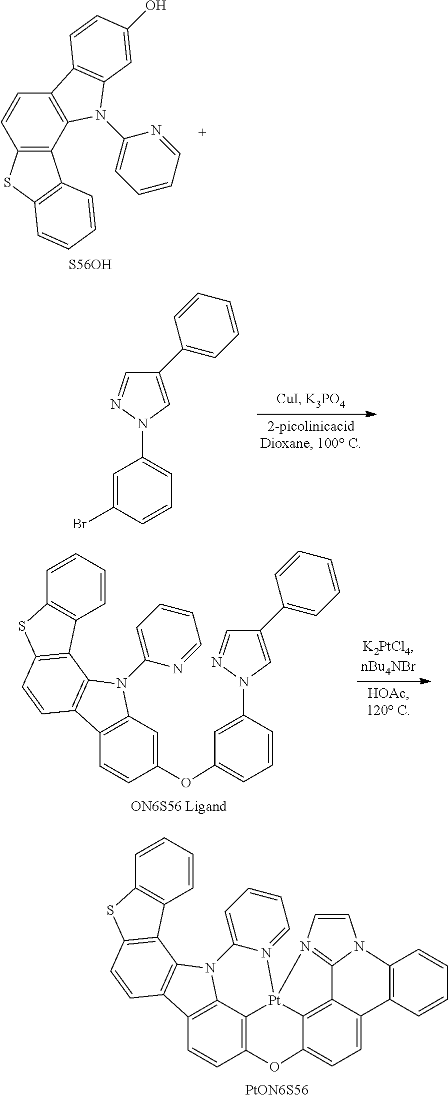

### Synthesis of 6N6S56 Ligand

To a solution of 1-(3-bromophenyl)-4-phenyl-1H-pyrazole (1.5 eq) in dioxane (0.1 M) were added S560H (1 eq), Pd(OAc)₂ (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product in 77% yield.

### Synthesis of PtON6S56

To a solution of ON6S56 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON6S56 in 39% yield.

### Example 41

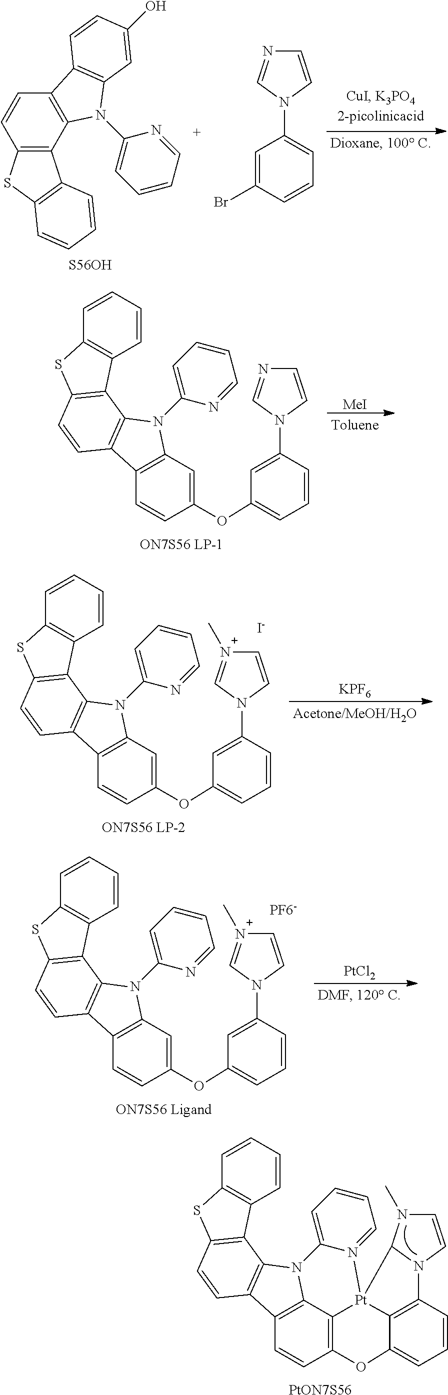

### Synthesis of ON7S56 Ligand

To a solution of 1-(3-bromophenyl)-1H-imidazole (1.5 eq) in dioxane (0.1 M) were added S560H (1 eq), Pd(OAc)₂ (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product ON7S56 LP-1 in 79% yield.

To a solution of ON7S56 LP-1 (1 eq) in toluene (0.1M) was added CH₃I (1.05 eq). The reaction mixture was heated at 40° C. and maintained at this temperature until the TLC shows the complete consumption of ON7S56 LP-1. The reaction mixture was then cooled to room temperature and the precipitate was collected by filtration to give the ON7S56 LP-2 in 85% yield.

ON7S56 LP-2 was dissolved in a mixture of water, methanol and acetone (1:1:1, 0.05-0.1 M) and treated with an aqueous solution of KPF₆ (1.2 eq). After 12 h, acetone and methanol were removed at reduced pressure. The precipitate was filtered and washed with water. The water layer was extracted with CH₂Cl₂. The precipitate was dissolved in the combined organic layer, washed with water and evaporated under reduced pressure to give the product ON7S56 Ligand in 87% yield.

### Synthesis of PtON7S56

To a solution of ON7S56 ligand (1 eq) in DMF (0.02 M) were added PtCl₂ (1.2 eq). The mixture was heated to 120° C. and maintained at this temperature for 3 days. The reaction mixture was cooled to room temperature. The solvent was then removed under reduced pressure. Purification by column chromatography (hexanes:DCM) gave the PtON7S56 in 23% yield.

### Example 42

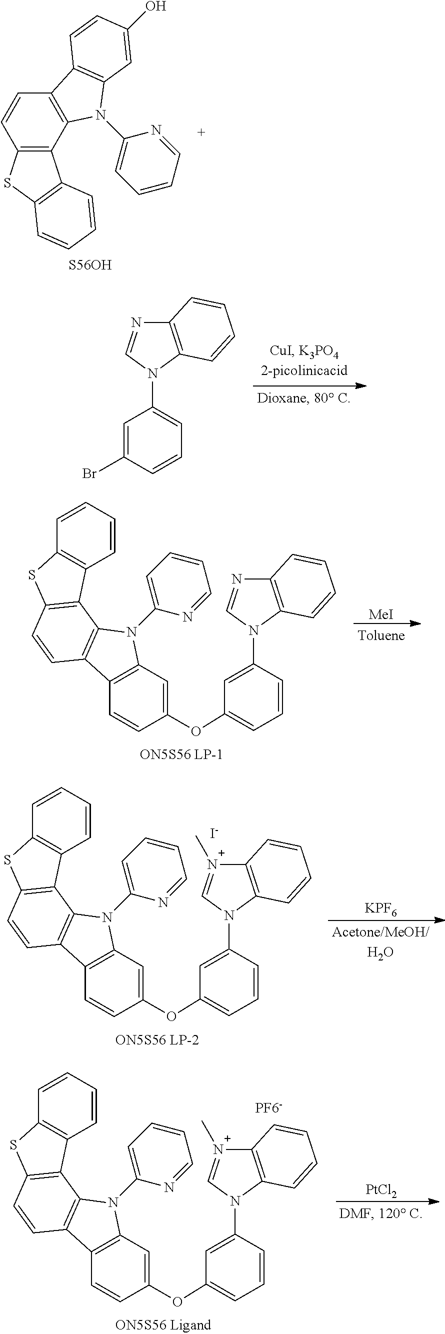

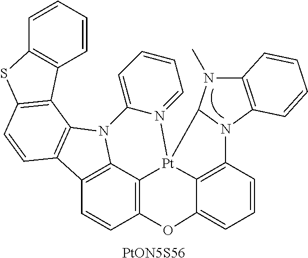

### Synthesis of ON5S56 Ligand

To a solution of 1-(3-bromophenyl)-1H-imidazole (1.5 eq) in dioxane (0.1 M) were added S560H (1 eq), Pd(OAc)₂ (0.1 eq), 2-picolinic acid (0.2 eq), and K₃PO₄ (2 eq). The mixture was heated to 100° C. and maintained at this temperature for 24 hours. The mixture was then cooled to room temperature. The solvent was evaporated under reduced pressure. The residue was then purified by flash column chromatography to give the product ON5S56 LP-1 in 81% yield.

To a solution of ON5S56 LP-1 (1 eq) in toluene (0.1M) was added CH₃I (1.05 eq). The reaction mixture was heated at 40° C. and maintained at this temperature until the TLC shows the complete consumption of ON5S56 LP-1. The reaction mixture was then cooled to room temperature and the precipitate was collected by filtration to give the ON5S56 LP-2 in 83% yield.

ON5S56 LP-2 was dissolved in a mixture of water, methanol and acetone (1:1:1, 0.05-0.1 M) and treated with an aqueous solution of KPF₆ (1.2 eq). After 12 h, acetone and methanol were removed at reduced pressure. The precipitate was filtered and washed with water. The water layer was extracted with CH₂Cl₂. The precipitate was dissolved in the combined organic layer, washed with water and evaporated under reduced pressure to give the product ON5S56 Ligand in 89% yield.

### Synthesis of PtON5S56

To a solution of ON5S56 ligand (1 eq) in DMF (0.02 M) were added PtCl₂ (1.2 eq). The mixture was heated to 120° C. and maintained at this temperature for 3 days. The reaction mixture was cooled to room temperature. The solvent was then removed under reduced pressure. Purification by column chromatography (hexanes:DCM) gave the PtON5S56 in 27% yield.

### Example 43

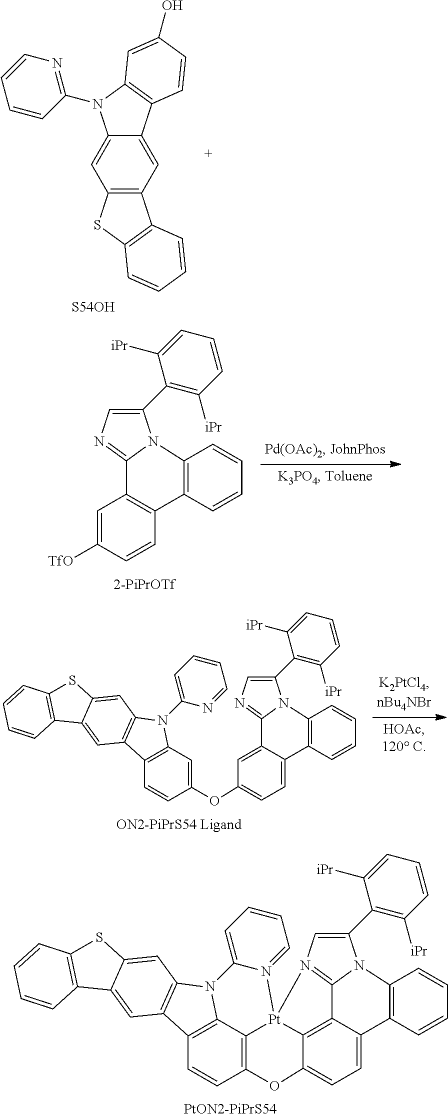

### Synthesis of ON2-PiPrS54 Ligand

To a solution of 2PiPrOTf (1.5 eq) in toluene (0.1 M) were added S540H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 33% yield.

### Synthesis of PtON2-PiPrS54

To a solution of ON2-PiPrS54 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrS54 in 46% yield.

### Example 44

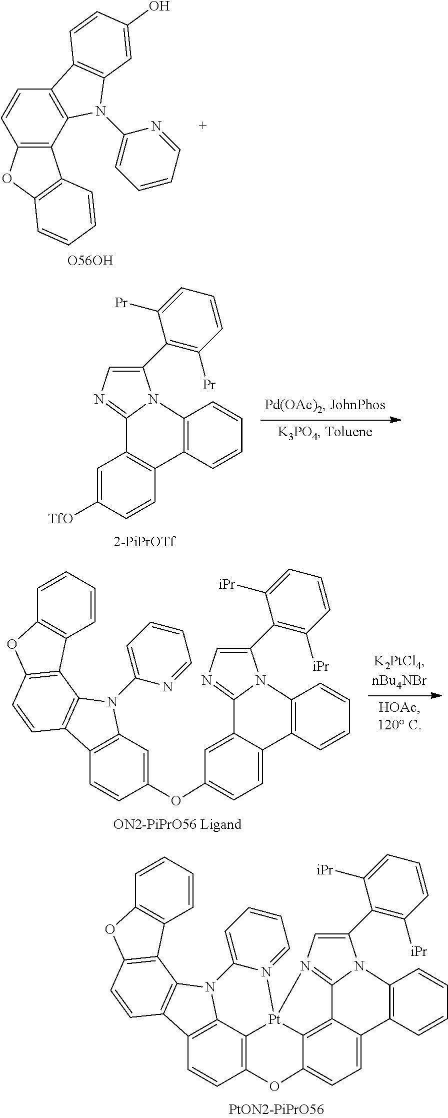

### Synthesis of ON2-PiPrO56 Ligand

To a solution of 2PiPrOTf (1.5 eq) in toluene (0.1 M) were added 0560H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 28% yield.

### Synthesis of PtON2-PiPrO56

To a solution of ON2-PiPrO56 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrO56 in 54% yield.

### Example 45

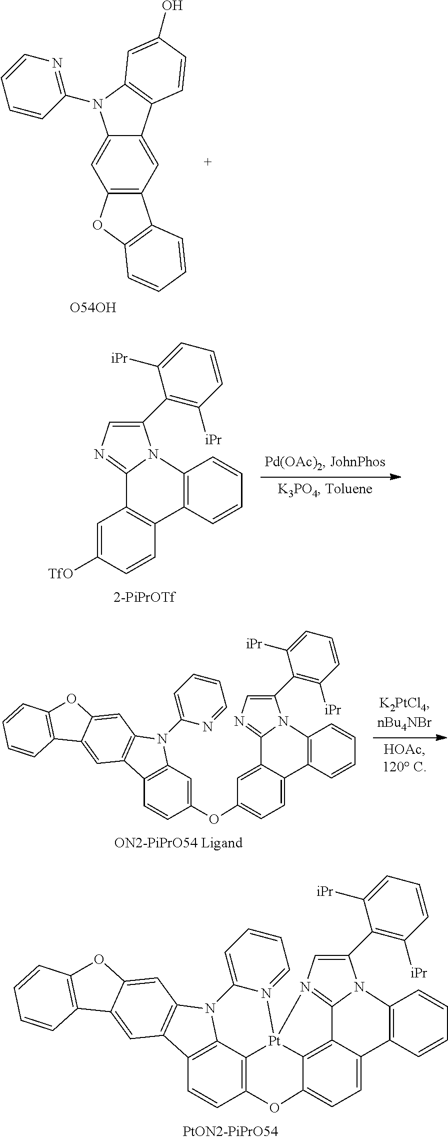

### Synthesis of ON2-PiPrO54 Ligand

To a solution of 2PiPrOTf (1.5 eq) in toluene (0.1 M) were added 0540H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 24% yield.

### Synthesis of PtON2-PiPrO54

To a solution of ON2-PiPrO54 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrO54 in 49% yield.

### Example 46

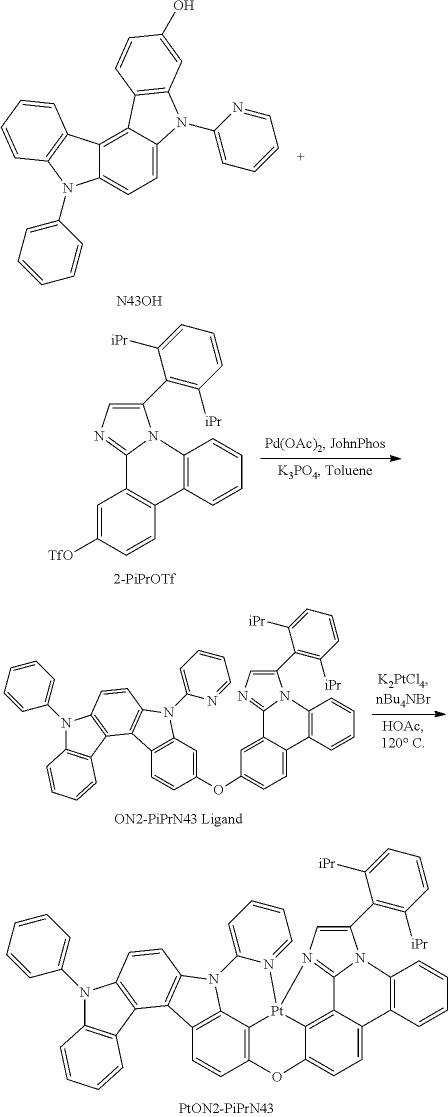

### Synthesis of ON2-PiPrN43 Ligand

To a solution of 2PiPrOTf (1.5 eq) in toluene (0.1 M) were added N430H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 28% yield.

### Synthesis of PtON2-PiPrN43

To a solution of ON2-PiPrN43 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrN43 in 41% yield.

### Example 47

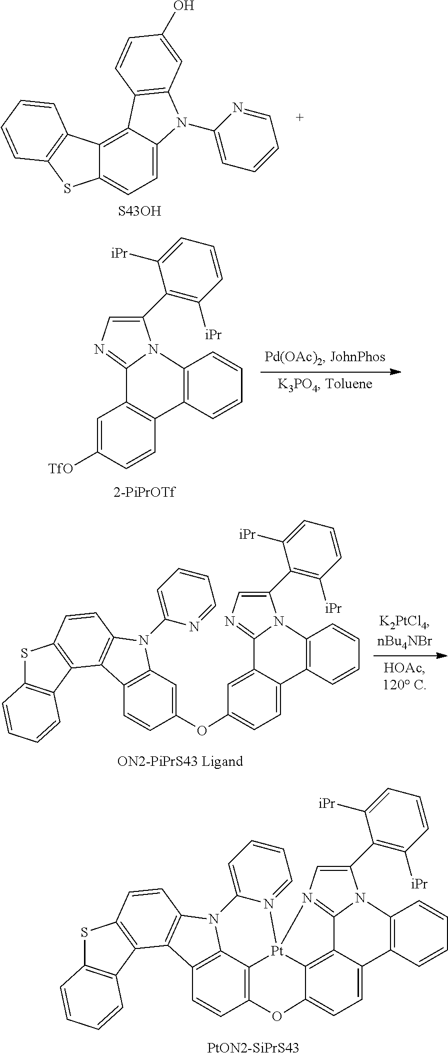

### Synthesis of ON2-PiPrS43 Ligand

To a solution of 2PiPrOTf (1.5 eq) in toluene (0.1 M) were added S430H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 32% yield.

### Synthesis of PtON2-PiPrS43

To a solution of ON2-PiPrS43 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrS43 in 46% yield.

### Example 48

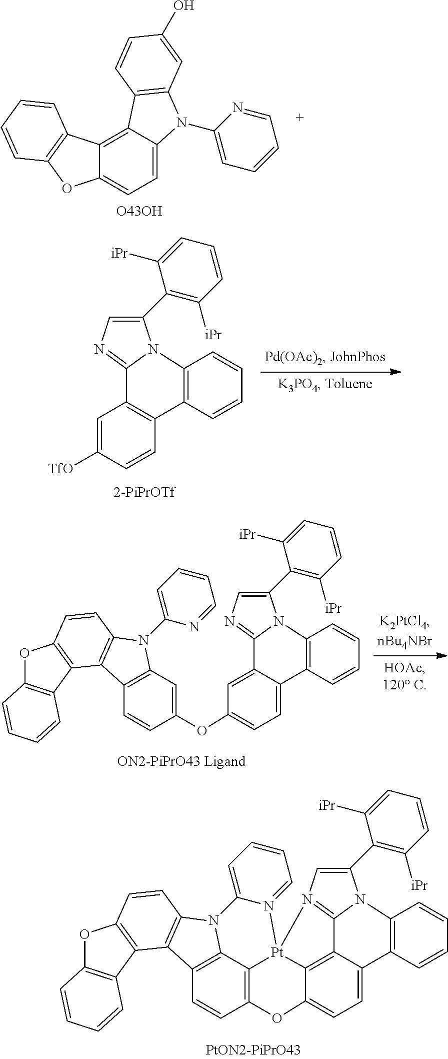

### Synthesis of ON2-PiPrO43 Ligand

To a solution of 2PiPrOTf (1.5 eq) in toluene (0.1 M) were added 0430H (1 eq), Pd(OAc)₂ (0.1 eq), JohnPhos (0.2 eq), and K₃PO₄ (2 eq). The mixture was heated to reflux and maintained at this temperature for 48 hours. The mixture was then cooled to room temperature. The solvent was evaporated under reduced pressure. The residue was then purified by flash column chromatography to give the product in 25% yield.

### Synthesis of PtON2-PiPrO43

To a solution of ON2-PiPrO43 ligand (1 eq) in HOAc (0.02 M) were added K₂PtCl₄ (1.2 eq) and n-Bu₄NBr (0.1 eq). The mixture was heated to reflux and maintained at this temperature for 3 days. The reaction mixture was cooled to room temperature. The solvent was then removed under reduced pressure. Purification by column chromatography (hexanes:DCM) gave the PtON2-PiPrO43 in 51% yield.

Only a few implementations are described and illustrated. Variations, enhancements and improvements of the described implementations and other implementations can be made based on what is described and illustrated in this document.

1.-4. (canceled)

5. A complex represented by one of General Formulas I-VI: 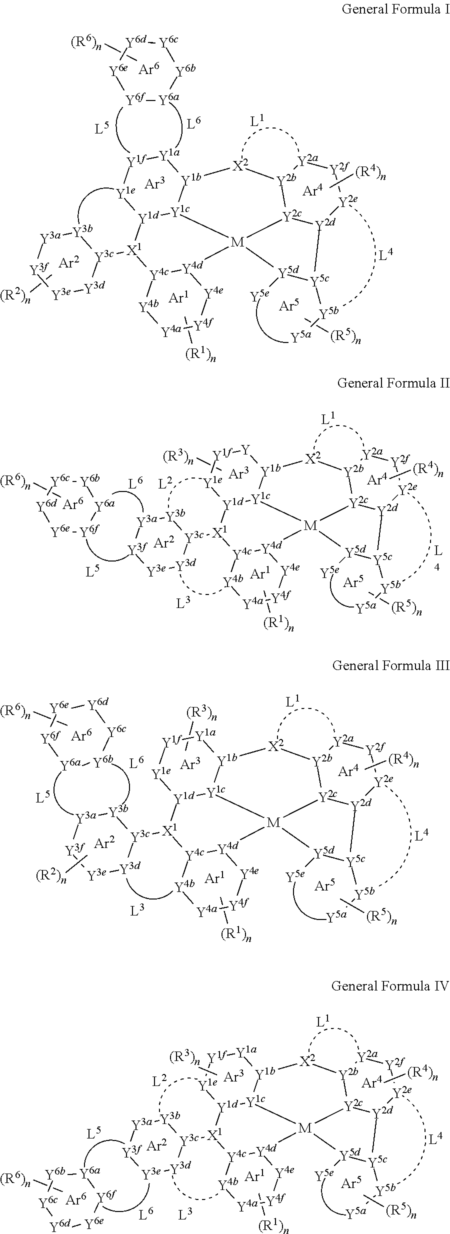 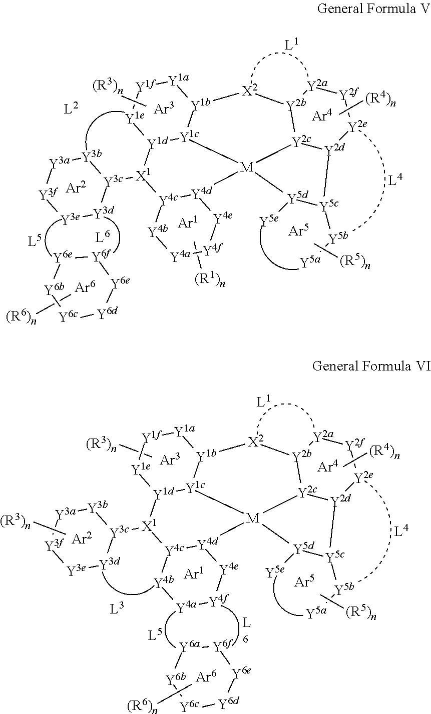
wherein:
M is Pt²⁺ or Pd²⁺,
each R¹, R², R³, R⁴, R⁵, and R⁶ independently represents hydrogen, halogen, hydroxy, amino, nitro, cyanide, thiol, or optionally substituted C₁-C₄ alkyl, alkoxy, or aryl,
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{3a}, Y^{3b}, Y^{3c}, Y^{3d}, Y^{3e}, Y^{3f}, Y^{4a}, Y^{4b}, Y^{4c}, Y^{4d}, Y^{4e}, Y^{4f}, Y^{5a}, Y^{5b}, Y^{5c}, Y^{5e}, Y^{5f}, Y^{6a}, Y^{6b}, Y^{6c}, Y^{6d}, Y^{6e}, and Y^{6f} each independently represents C, N, Si, O, or S,
Y^{5d} represents C,
each of X¹ and X² is present or absent, and each X¹ and X² present independently represents a single bond, NR, PR, CRR′, SiRR′, CRR′, SiRR′, O, S, S═O, O═S═O, Se, Se═O, or O═Se═O, and wherein R and R′ each independently represents hydrogen, cyanide, halogen, hydroxy, amino, nitro, thiol, or optionally substituted C₁-C₄ alkyl, alkoxy, aryl,
L¹, L², L³, L⁴, L⁵, and L⁶, where indicated by a solid line is present, and where indicated by a dashed line is each independently present or absent, and each of L¹, L², L³, L⁴, L⁵, and L⁶ present independently represents a substituted (valency permitting) or unsubstituted linking atom or group comprising alkyl, alkoxy, alkenyl, alkynyl, hydroxy, amine, amide, thiol, aryl, heteroaryl, cycloalkyl, and heterocyclyl moieties,
each Ar¹, Ar², Ar³, Ar⁴, and Ar⁶ present is independently an aryl group,
Ar⁵ is a carbene, and
each n is independently an integer, valency permitting.

6. The complex of claim 1, wherein Ar⁵ represents imidazole carbene, benzimidazole carbene, or triazole carbene.

7. The complex of claim 1, wherein L¹ is present.

8. The complex of claim 1, wherein L⁴ is present.

9. The complex of claim 1, wherein the complex is represented by General Formula I.

10. The complex of claim 1, wherein the complex is represented by General Formula II.

11. The complex of claim 1, wherein the complex is represented by General Formula III.

12. The complex of claim 1, wherein the complex is represented by General Formula IV.

13. The complex of claim 1, wherein the complex is represented by General Formula V.

14. The complex of claim 1, wherein the complex is represented by General Formula VI.

15. The complex of claim 1, wherein the complex is represented by one of the following: 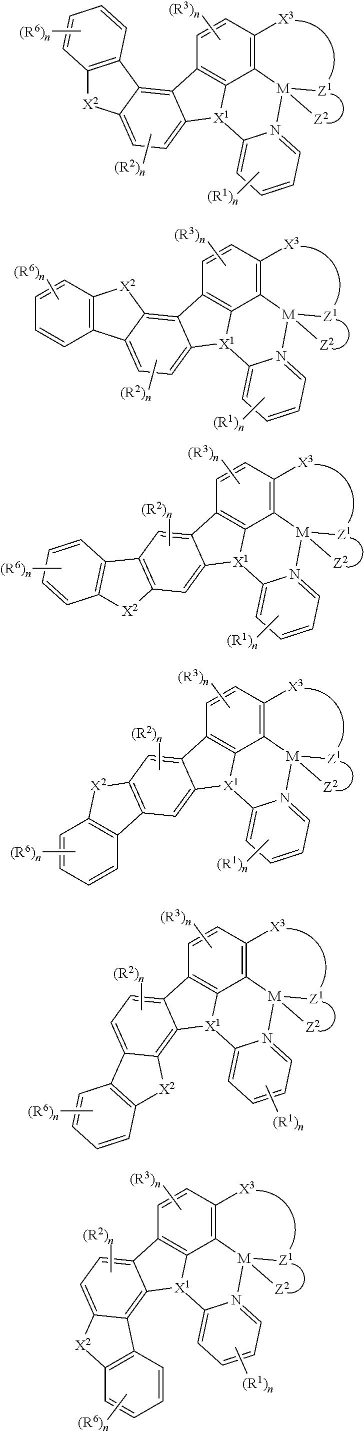 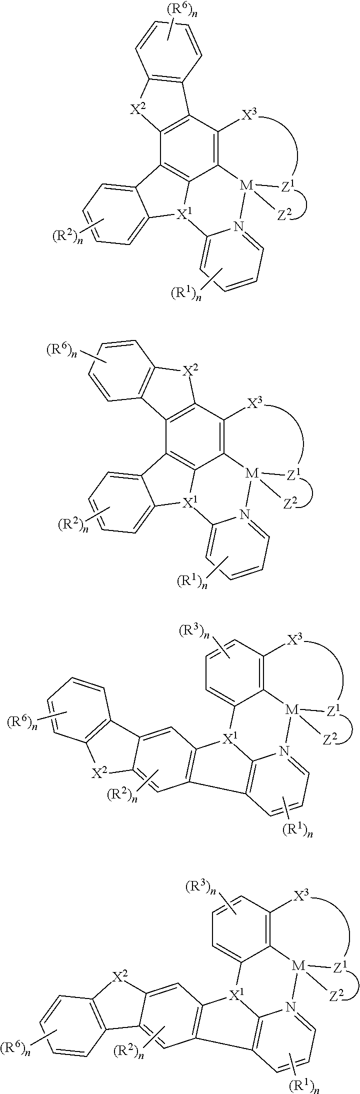 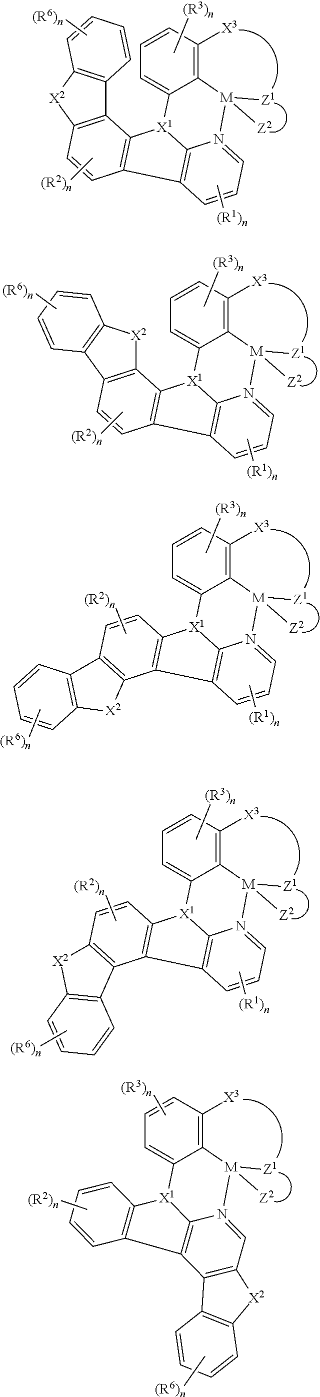 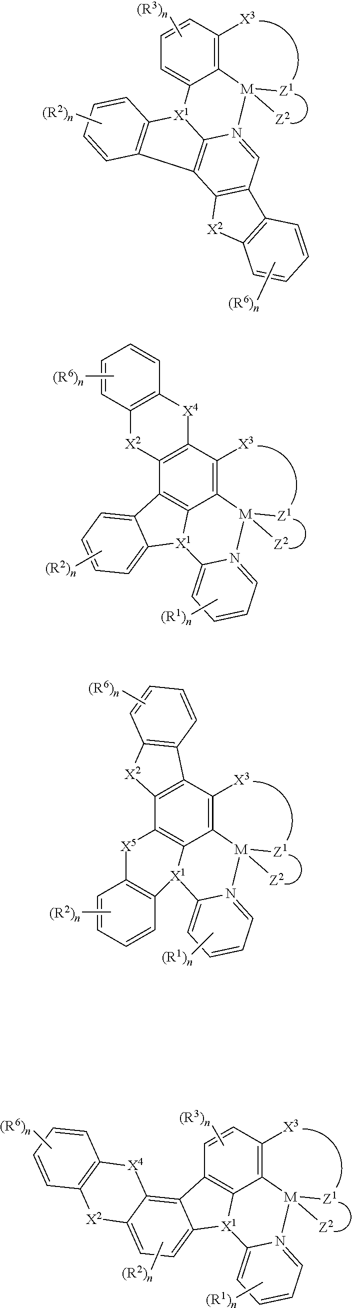 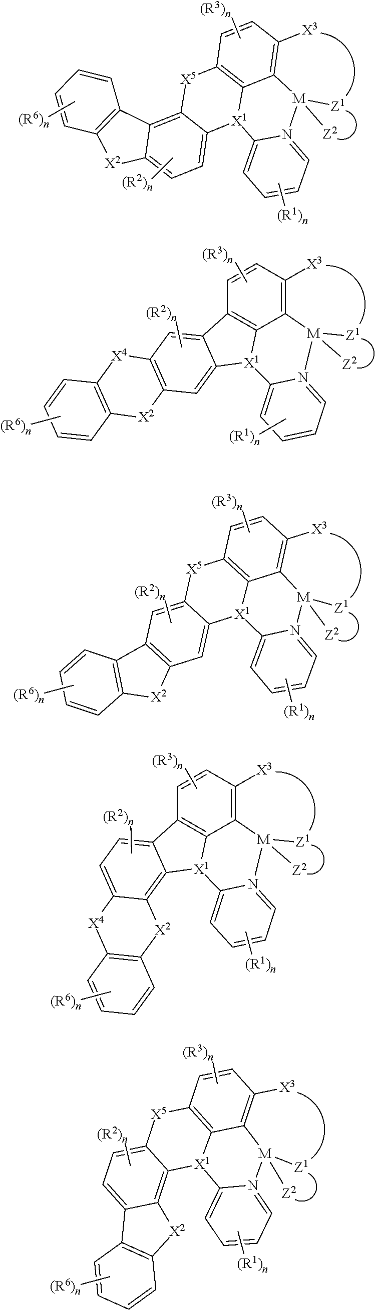 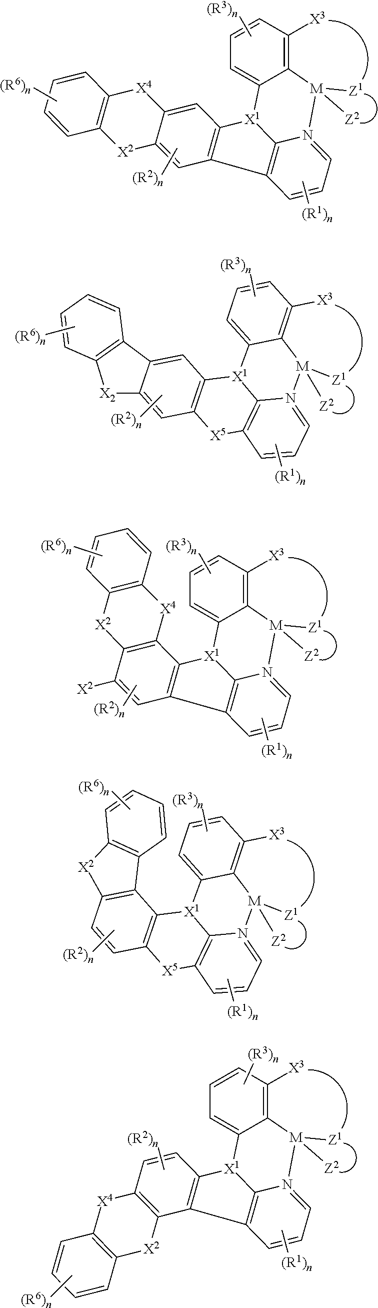 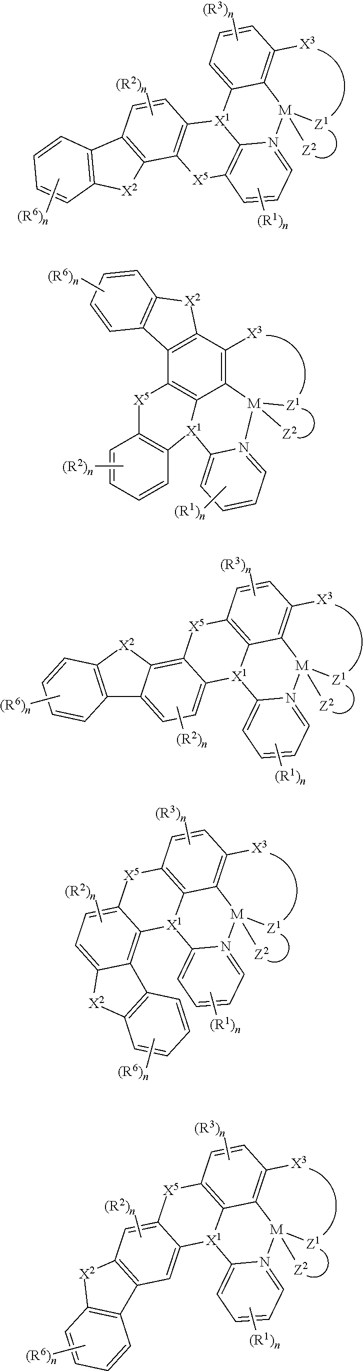 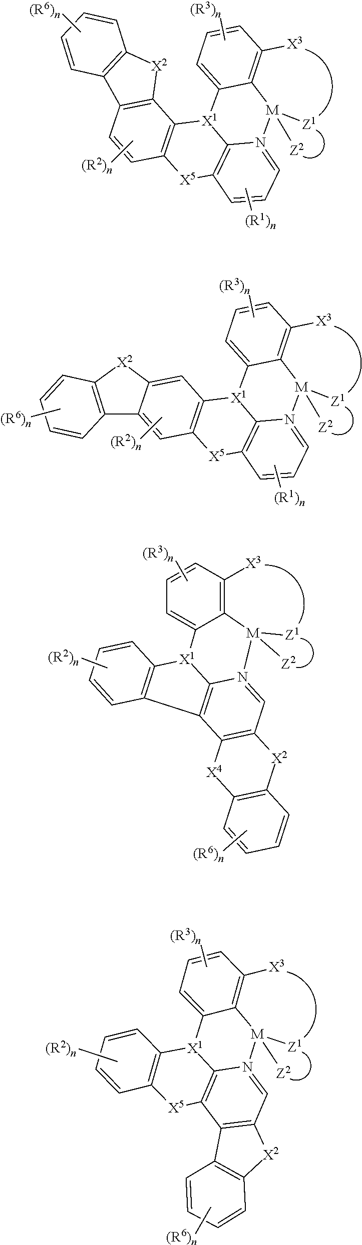 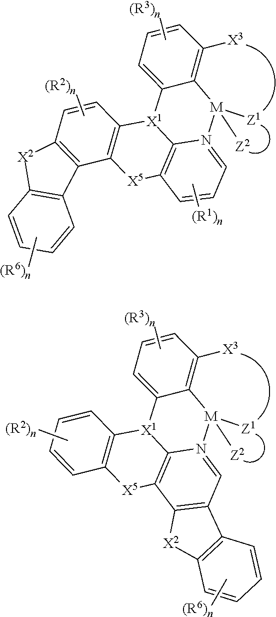
wherein: 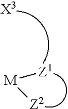
represents one of following: 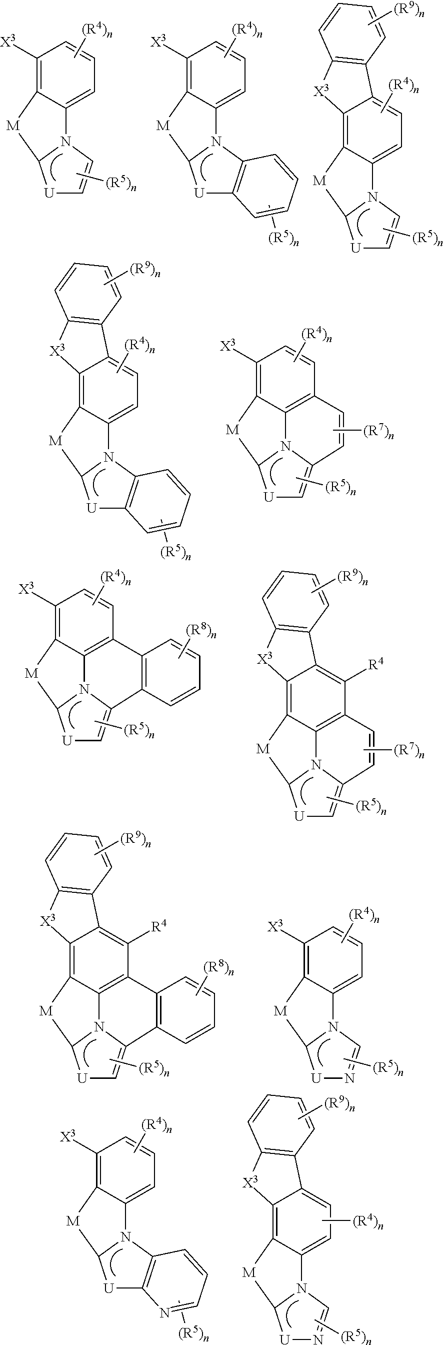 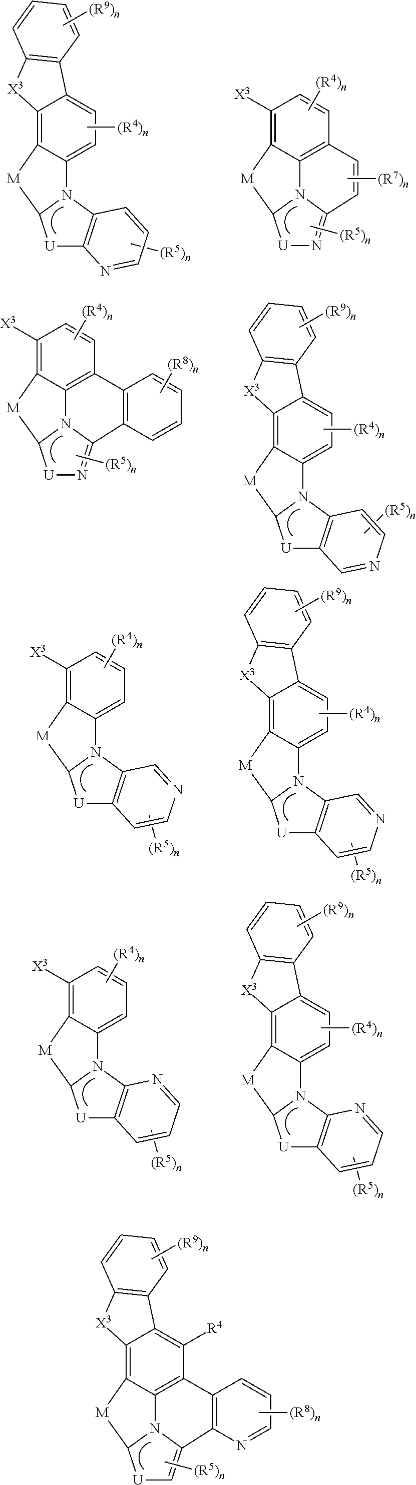 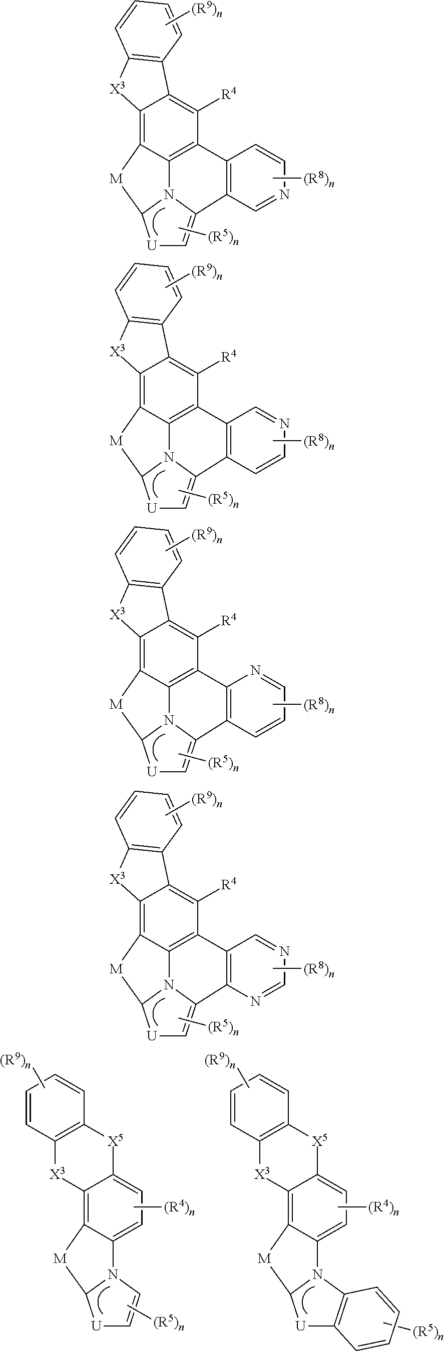 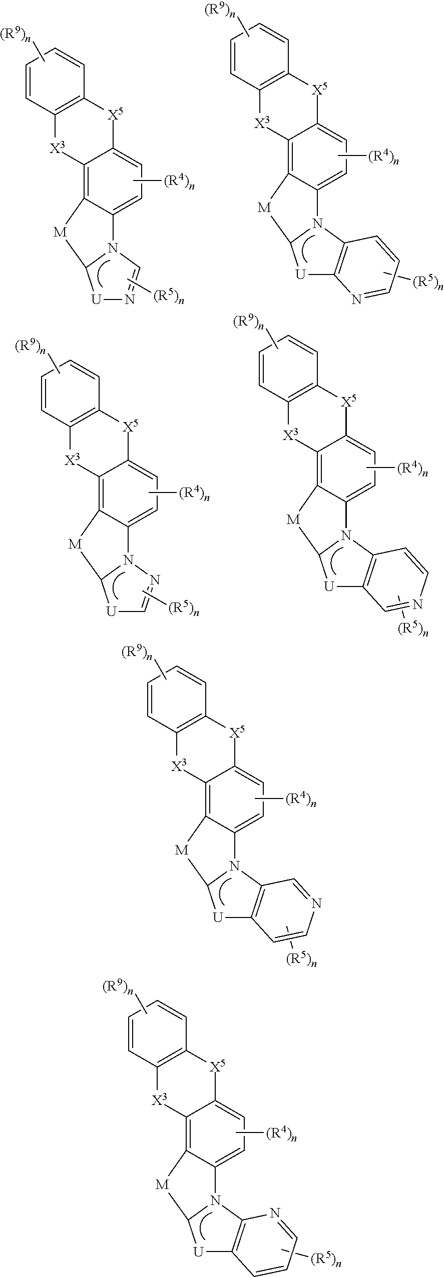
wherein:
X³ and X⁵ each independently represents NR, PR, CRR′, SiRR′, CRR′, SiRR′, O, S, S═O, O═S═O, Se, Se═O, or O═Se═O, where R and R′ each independently represents hydrogen, cyanide, halogen, hydroxy, amino, nitro, thiol, or optionally substituted C₁-C₄ alkyl, alkoxy, aryl,
R⁴, R⁵, R⁷, R⁸, and R⁹ each independently represents hydrogen, halogen, hydroxy, amino, nitro, cyanide, thiol, and substituted or unsubstituted C₁-C₄ alkyl, alkoxy, or aryl,
U represents O, S, NR, or PR, where R represents hydrogen, cyanide, halogen, hydroxy, amino, nitro, thiol, or optionally substituted C₁-C₄ alkyl, alkoxy, aryl, and
each n is independently an integer, valency permitting.

16. The complex of claim 1, wherein the complex is represented by one of the following structures: 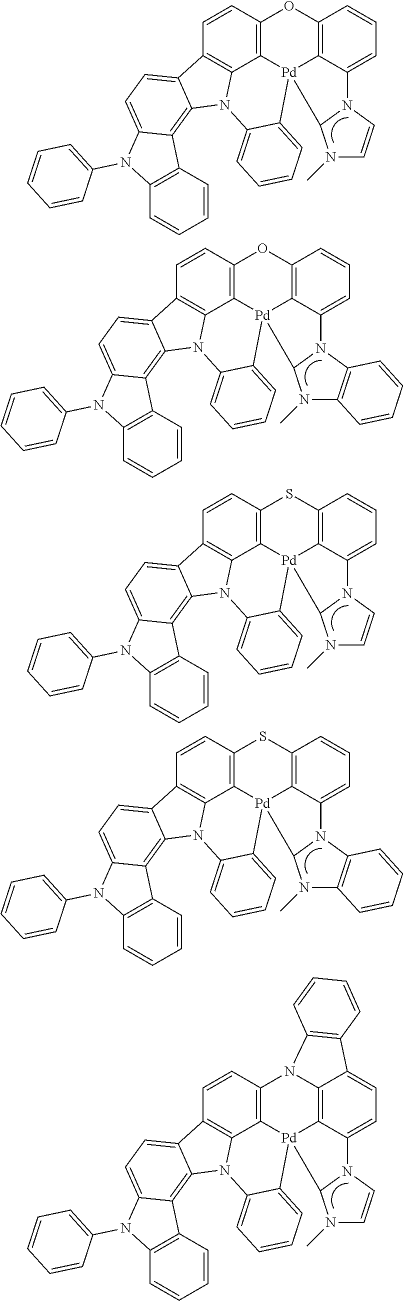 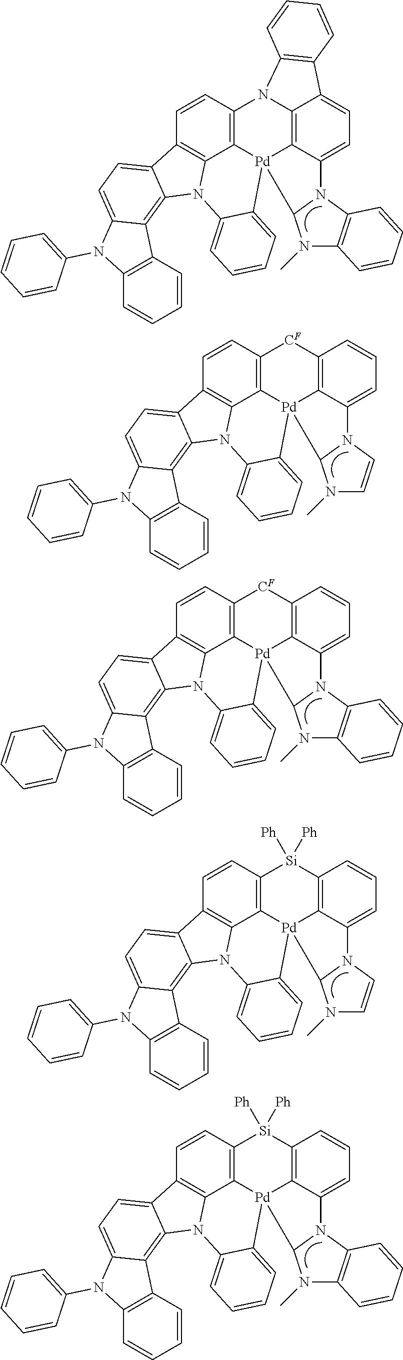 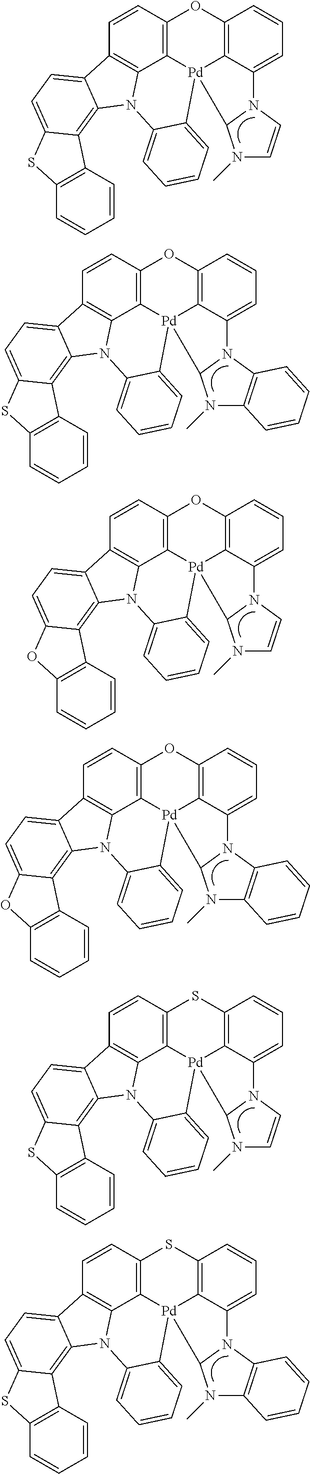 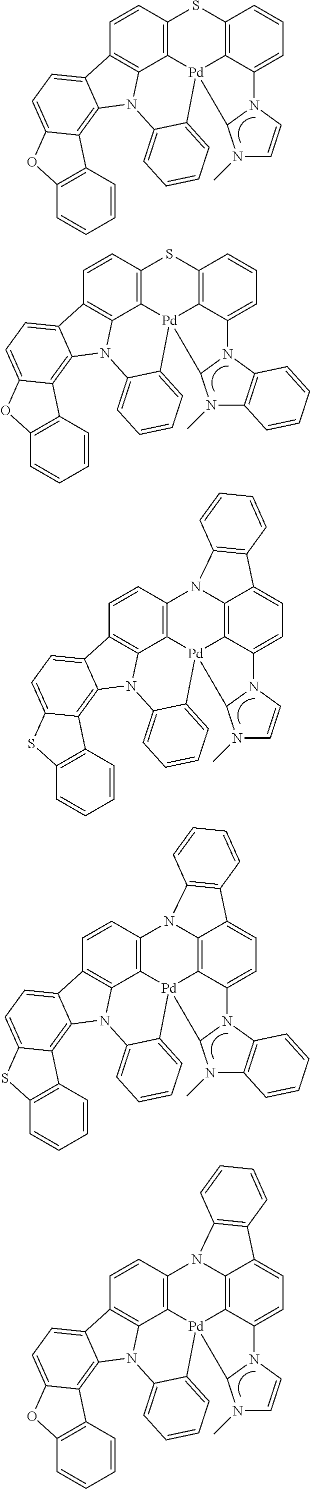 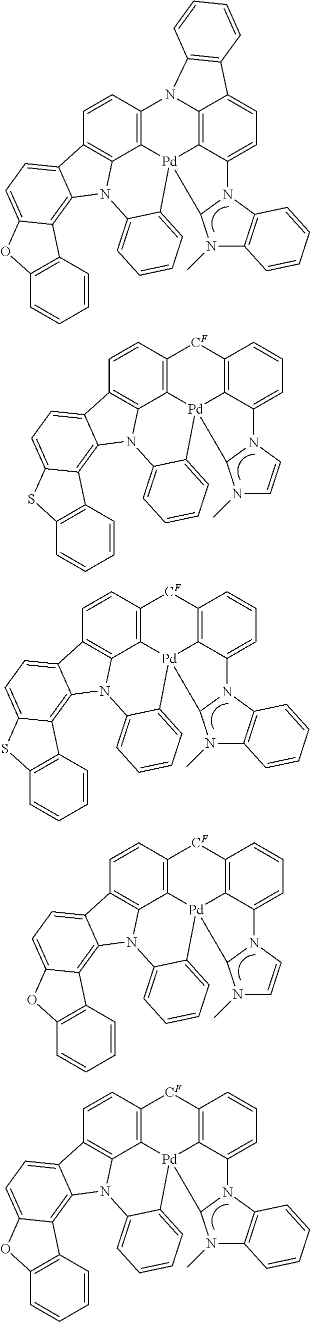 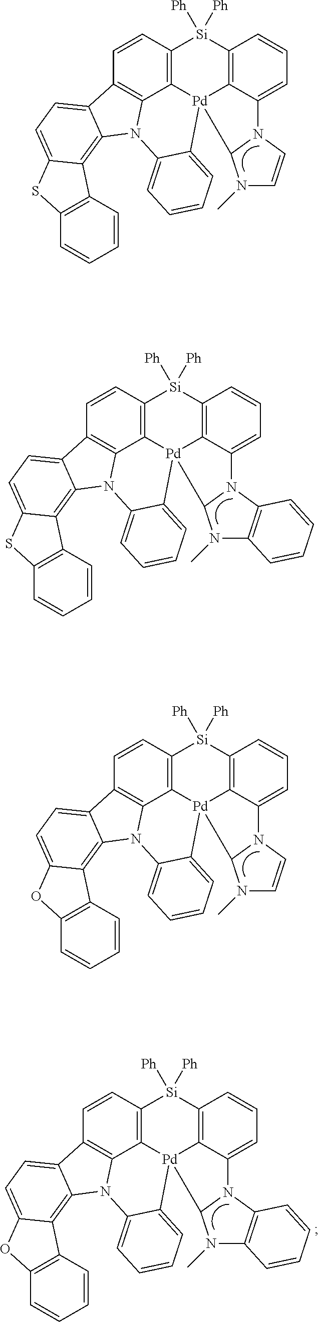
wherein Ph is phenyl and

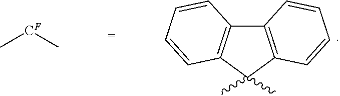

17. A light emitting diode comprising the complex of claim 1.

18. The light emitting diode of claim 16, wherein the light emitting diode further comprises a host material.

19. A light emitting device comprising the light emitting diode of claim 16.
